(19) United States
(12) Patent Application Publication
(10) Pub. No.: US 2025/0037955 A1
(43) Pub. Date: Jan. 30, 2025

(54) ELECTRONIC FUSE FOR A VEHICLE AND USE THEREOF IN A VEHICLE

(71) Applicant: ELMOS Semiconductor SE, Dortmund (DE)

(72) Inventors: André Sudhaus, Recklinghausen (DE); Christian SCHMITZ, Castrop-Rauxel (DE); Hanno SEILER, Bielefeld (DE); Fikret Abaza, Duisburg (DE); Peter Maurer, Velbert (DE); Frank Stehr, Mettmann (DE)

(73) Assignee: ELMOS Semiconductor SE, Dortmund (DE)

(21) Appl. No.: 18/710,164

(22) PCT Filed: Nov. 17, 2022
(86) PCT No.: PCT/EP2022/082346

§ 371 Date: May 14, 2024

(30) Foreign Application Priority Data
Nov. 18, 2021 (DE) 10 2021 130 107.6
May 2, 2022 (DE) 10 2022 110 713.2
Oct. 4, 2022 (DE) 10 2022 125 574.3
Oct. 5, 2022 (DE) 10 2022 125 617.0
Oct. 6, 2022 (DE) 10 2022 125 768.1
Oct. 27, 2022 (DE) 10 2022 128 524.3
Nov. 8, 2022 (DE) 10 2022 129 487.0

(51) Int. Cl. H01H 85/055; B60R 16/03; G01K 3/00; H01H 85/165

(52) U.S. Cl. CPC H01H 85/055; B60R 16/03; H01H 85/165; G01K 3/005

(57) ABSTRACT

An electronic fuse includes a housing, a first housing terminal and a second housing terminal. The electronic fuse further includes a circuit breaker including a first terminal of the circuit breaker and a second terminal of the circuit breaker. The first terminal of the circuit breaker is electrically connected to the first housing terminal of the electronic fuse. The second terminal of the circuit breaker is electrically connected to the second housing terminal of the electronic fuse. A thermal protection is arranged in a current path between the first housing terminal and the second housing terminal in series with the circuit breaker. The thermal protection interrupts the current path when a temperature of the circuit breaker or a temperature within the housing of the electronic fuse and/or a temperature of the housing of the electronic fuse exceeds a switch-off temperature.

### CROSS-REFERENCE TO RELATED APPLICATIONS

This application is a National Phase Application of International Application Number PCT/EP2022/082346, filed Nov. 17, 2022, which claims priority to: German patent application number 10 2021 130 107.6, filed Nov. 18, 2021; German patent application number 10 2022 110 713.2, filed May 2, 2022; German patent application number 10 2022 125 574.3, filed Oct. 4, 2022; German patent application number 10 2022 125 617.0, filed Oct. 5, 2022; German patent application number 10 2022 125 768.1, filed Oct. 6, 2022; German patent application number 10 2022 128 524.3, filed Oct. 27, 2022; and German patent application number 10 2022 129 487.0, filed Nov. 8, 2022, the subject matter of each of which is incorporated by reference in the present application in its entirety.

### BACKGROUND

The disclosure deals with “intelligent” electronic fuses for vehicles and the use of such fuses in vehicles for a wide variety of applications.

The decarbonization of mobile road traffic will require an efficient power distribution within vehicles.

Automobile manufacturers today use central fuse boxes (switchboxes or fuse boxes) in their vehicles with the fuses of a car and typically place them at an accessible location in the car. Complex cable harnesses centrally distribute the electrical power from there. Decentralized fuse boxes with power supply sub-networks are expected to replace this star-shaped structure over the long term.

A platform concept is in the focus here. The automobile manufacturers can thereby adapt the cable harnesses more easily to individual customer requirements. A plug-and-play concept is desirable in this case. The thought here is a platform having a central power supply network. The aim is a modular system for electrical supply networks in the car. This reduces the supply networks in the car as a result and enables a modular system for the supply networks. According to the concept discussed here in this document, the electronic fuses are intended to be placed on the circuit boards of higher-level computer systems of the controllers. These circuit boards where applicable are to comprise insertion slots for the fuse housings of the electronic fuses.

Previous topologies of a power distribution system of the supply networks had a central star configuration with a switch box with the electronic fuses in the star center point of the supply network. In addition, previous topologies of a power distribution system of the supply networks have power loads at the star radial ends of the supply network. Future topologies of a power distribution system of the supply networks are supposed to optionally have a tree structure. Optionally, a plurality of electronically controllable electronic fuses is connected in series, one behind the other. A tree structure of the supply network branches out from the central starting point of the supply network toward the loads. The branches (supply branches) of the tree of the supply network are the supply lines. The various supply branches or various supply sub-networks have differing importance, in particular with regard to functional safety. Each of or at least a plurality of the line sections of the supply branches or supply sub-networks is optionally provided with electronic fuses. These electronic fuses optionally carry out a method for protecting the supply sub-tree of the supply network, respectively downstream thereof, or the corresponding supply sub-network downstream thereof. The protection strategy of these electronic fuses depends on the importance of the downstream supply sub-tree or the downstream supply sub-network, and its importance for the reliability of the operation of the vehicle with regard to state and availability. Depending on the significance and importance of the connected loads, each electronic fuse executes a method that detects electrical parameters of the current flow in the relevant line section of the relevant supply branch or of the relevant supply sub-network and where applicable of the potential on the supply side against a reference potential. If necessary, the computer core of the control device of the electronic fuse exchanges data with other computer cores of the control devices of other electronic fuses in downstream and upstream branches of the proposed supply tree or in downstream and upstream supply sub-networks of the supply network. This data exchange can take place via a special fuse data bus (hereinafter referred to as a fuse data bus) or another data bus. Such a data bus can comprise, for example, a Lin data bus or a DSI3 data bus or a PSI5 data bus or a CAN data bus or a CAN-FD data bus or an Ethernet data bus or a Flexray data bus or an LVDS data bus or otherwise a wired data bus. If the disclosure describes the data bus 9, a wireless data transmission path is also included in the data bus 9 as an implementation option which communicates wirelessly, for example via Bluetooth or WLAN or the like. To date, the cable harness of a supply network of a vehicle has been manufactured in one piece supplied as a component and mounted in the vehicle. The document submitted hereby now proposes to enable more flexible structures. This flexibility can be accomplished first by software flags and secondly by the insertion of further components and supply sub-spaces and supply sub-networks.

An electric vehicle will typically have a first supply tree or a first supply sub-network, which the vehicle will then operate at approximately 48 V, i.e., less than 50 V.

An electric vehicle will typically have a second supply tree or a second supply sub-network, which the vehicle then operates at approximately 800 V, i.e., at significantly more than 50 V.

One idea for using the electronic fuses (e-fuses) is to enable the addition of the current supply to sub-components and/or sub-devices of the vehicle. For this purpose, the client, which typically should be a user or driver of the vehicle, optionally transmits a command to a server, for example to the server of the automobile manufacturer. The client optionally authenticates itself to the server. For example, the client can provide identification data of his mobile phone or his vehicle or another personalized device, which data enable the legally compliant conclusion of a contract.

A typical control device for operating an electronic fuse also comprises the so-called system basis chip functionality. This functionality provides all functions required to operate a computer core, for example a microcontroller. This may include, for example, the voltage supply, the emergency power supply, the provision of a data bus interface in the form of a bus transceiver, and a watchdog timer (also referred to for short as watchdog) for monitoring the correct function of the computer core of the control device of the fuse. These are optionally part of the control device of the fuse. In this case, the watchdog timer, as the general monitoring device, takes over where applicable further monitoring specifications within the meaning of the disclosure.

The detection of non-extinguishing arcs in the 48 V network is an important function which such an integrated control device for an electronic fuse has to perform. The computer core of such a control device of a fuse is therefore intended:
individually and/or
in cooperation with the computer cores of the other control devices of the other fuses and/or
in cooperation with one or more higher-level computer systems to detect such a non-extinguishing arc independently. The computer core of such a control device of a fuse is therefore further intended:
individually and/or
in cooperation and/or
in cooperation with the computer cores of the other control devices of the other fuses and/or
in cooperation with one or more higher-level computer systems through countermeasures, such as the temporary switching off of power sources, loads, and/or supply sub-networks, to address the recognized problem, and optionally control it.

A spectral analysis of the electrical current on the line section to be protected, in which the electronic fuse is inserted, is known from the prior art here. For this purpose, the electronic fuse, by means of a current measuring means, for example a shunt resistor 24, detects the time characteristic of typically successive values of the electrical current through the line section to be protected and carries out a spectral analysis of this value characteristic. If certain structures are present in the frequency spectrum determined in this way, the computer core of the control device of the electronic fuse deduces an arc and, where applicable, switches off the current flow by means of the circuit breaker of the fuse, which is typically a fuse transistor. Instead of the computer core of the control device of the fuse, a higher-level computer system, for example a controller of the vehicle, or a computer core of a control device of a different electronic fuse can optionally also carry out this evaluation and initiate, carry out and/or coordinate the necessary countermeasures. For this purpose, the computer core of the control device of the electronic fuse transmits suitable data to this other device, i.e., for example, the higher-level controller of the vehicle or the other computer core of the control device of the other electronic fuse. Suitable data can be, for example, the raw measured values or further processed measured values, in particular voltage and/or current values.

For the necessary temporal resolution of the temporal current value characteristic, however, an increased sampling rate of analog-to-digital converters of the control devices of the relevant fuses is typically necessary for applying such a spectral analysis.

Optionally, distributed measurement methods are also appropriate and necessary. In this case, the control devices of a plurality of electronic fuses optionally detect one or more measured values by means of corresponding measuring devices of these control devices of these fuses. The electronic fuses optionally each have a corresponding timer. Optionally with the aid of the corresponding timer, the control device of the corresponding electronic fuse optionally determines a time stamp value for optionally each measured value or for a group of measured values that they determine. The control device of the relevant fuse transmits these measured values together with the associated time stamps optionally to a higher-level computer unit, for example a higher-level controller, or to the computer core of a different electronic fuse. The higher-level computer unit or the computer core of the control device of the other electronic fuse compare the measured values of optionally similar time stamps to one another and can thus deduce, for example, power losses in line sections between two electronic fuses. Such a loss of power may possibly indicate the said arc. The control devices of the fuses, or the higher-level computer system, optionally take into account a possibly occurring ground offset of the reference potential terminal. If the measured values or the ratio of the measured values to one another or a difference of such measured values or variables derived therefrom do not correspond to one or more expected values, the higher-level computer unit, or the computer core of the evaluating control device of the evaluating electronic fuse can adopt the countermeasures. These can correspond to the previously described countermeasures. The data communication can in turn take place via the fuse data bus or one of the aforementioned data buses or via a wireless interface depending on requirements.

Monitoring the current and/or voltage characteristics enables a so-called health management for the vehicle. For example, the system of the supply network can then recognize changes in the current consumption or the spectra of voltage characteristic, current characteristic or power transport which possibly do not correspond to the expected characteristics or values. If necessary, the system of the supply network can thereby inform the repair shop or the vehicle owner or another person or institution via the Internet, etc., or an indicator, about the state or the wear or potential damage or the imminent failure of electrical loads. Such data are of particular interest to the vehicle manufacturer. It is therefore conceivable for the computer core of a control device of a fuse to transmit detected measured values and/or operating data via the data bus and via a higher-level computer system and the Internet to a server of the automobile manufacturer. The server of the automobile manufacturer, for example, collects this data, processes the data further and optionally evaluates the data. In this way, the automobile manufacturer can, for example, obtain data for preventive maintenance work and indications of future improvements of its vehicles.

In the context of the disclosure, power-generating components are loads in which either the current direction or the voltage direction is reversed relative to these directions in the event of a power-dissipating load.

Particular states, so-called ECO modes, are known for cars, in which a higher-level computer system of the vehicle selectively switches off individual loads. Nowadays, the higher-level computer system switches these individual loads by means of a command via the data bus to the load. According to the proposal, the higher-level computer system can, however, also carry out this shutdown of individual loads in such a way that the higher-level computer system interrupts the complete supply of a supply branch or a supply sub-network by an electronic fuse which opens its circuit breaker at the command of the higher-level computer system. As a result, the so-called standby currents of the plurality of loads, which supplies this supply sub-branch or this supply sub-network with electrical power, are eliminated for this supply sub-network.

If a load at a different, higher priority point in the supply network of the vehicle temporarily requires a greater amount of power, the higher-level computer system of a higher-level controller, or the computer core of a control device of an electronic fuse, can temporarily switch off other supply sub-trees of the supply tree or other supply sub-networks of the supply network via the data bus, to which the computer cores of the control devices of the relevant fuses are connected, or via a functionally equivalent other data transmission path. A supply tree is in other respects a supply network within the meaning of the disclosure.

If, at a different, higher-priority point in the supply network of the vehicle, the supply network is to briefly transport a greater amount of power via a line section to one or more first loads, the higher-level computer system of a higher-level controller, or the computer core of a control device of an electronic fuse, can temporarily switch off other supply sub-trees of the supply tree or other supply sub-networks of the supply network via the data bus, to which the computer cores of the control devices of the relevant fuses are connected, or a functionally equivalent other data transmission path. This disconnection increases the proportion of the current-carrying capacity of the relevant line section used by the first loads in the power supply in favor of the first loads. If the short-term additional demand is past, the higher-level computer system of the higher-level controller, or the computer core of the control device of the electronic fuse, can possibly restore the original state via the data bus or the said data connection. This is therefore a temporary disconnection of loads in order to achieve a kick down, for example.

It is known from the prior art that, for example, relays for disconnecting a high-voltage supply sub-network (HV network) are unsuitable. Here, supply sub-networks are meant which are at voltages more than 400 V above the reference potential. In such disconnections, switch-off currents of 5 kA can occur. Today, the relays in electric cars switch only between the “Charge Mode” and Drive Mode operating states.

The SiC transistors customary today are typically connected via smart FETs in the prior art. These are FET transistors with little integrated logic. There is therefore a need for adequate control of SiC transistors by suitable control devices of the fuses when using such SiC transistors as circuit breakers in fuses.

### SUMMARY

### Motivation Factors

Motivational factors for the use of an electronic fuse (e-fuse) include:
weight reduction of the car,
flexibility of the architecture,
creative power management,
functional safety,
better system reliability.

The following disadvantages result when electronic fuses are used:
The melting fuse is always cheaper.

### For Weight Reduction of the Car

The production of electronic fuses is possible with high precision. The computer systems of a vehicle can precisely model the switching behavior of the electronic fuses in contrast to the switching behavior of conventional melting fuses. This precise predictability of the switching behavior makes it possible to reduce the safety margins in the design of the conductor cross sections of the line sections in the supply tree and to reduce similar tolerances, which can reduce the use of material for the cable harness in the vehicle and thus the vehicle weight. A lower vehicle weight results in reduced power consumption.

Optionally, workshops and end users can enlarge the supply trees and supply networks in the vehicle by plug-in modules.

However, this fully modular and non-hierarchical supply network concept is still a long way off. In a first step, the first supply networks comprising the electronic fuses retain the central fuse box (junction box) in the vehicle. It is intended to provide the electronic fuses as pluggable modules. The installation of the electronic fuses as pluggable modules instead of the previous melting fuses in the junction box is possible. These pluggable fuse modules optionally have a pluggable terminal for a data bus connector which connects the data bus of the computer core of the control device of the electronic fuse via a data interface of the control device of the electronic fuse to a data bus of the junction box or of the vehicle and thus to a higher-level computer system of the vehicle, for example to a controller of the vehicle.

It is thus optionally an evolutionary procedure that the functionality of the junction box further develops by the junction box becoming more intelligent in a first step. Later, it is conceivable to divide the junction box into different small junction boxes within the vehicle and finally to equip the loads and power sources of the vehicle with individual electronic fuses in the last step. An electronic fuse within the meaning of the proposal discussed here thus does not just perform the fuse function, which performs the interruption of the circuit in which the fuse is inserted when a current passing through is exceeded over a longer period of time. An electronic fuse within the meaning of the disclosure furthermore provides a) also measuring devices for example for detecting measured current values of the relevant line section and/or b) also measuring devices for detecting voltage measured values of the relevant line section and c) actuators for changing the state of the relevant line section and d) communication options with other electronic fuses and d) communication options with higher-level computer systems and e) communication options with other device parts of the vehicle, in particular controllers, and f), time-related data and, if necessary, further advantageous services and device parts.

In particular, for very high pulse currents, the melting fuse does not react adequately. The tolerances require a large safety range, which requires an increase in the line cross section and thus more material and vehicle weight.

The insertion of electronic fuses can safeguard different market needs.

First, the electronic fuse, depending on the electrical current which flows through the line protected by the electronic fuse, can simulate the behavior of a melting fuse precisely in a practically tolerance-free manner compared to the melting fuse. For this purpose, the electronic fuse, by means of a measuring aid within the electronic fuse, always continually detects the value of the electrical current through the circuit breaker of the electronic fuse in the relevant supply line section. The computer core of the control device of the electronic fuse optionally calculates an intermediate value using a zero, first, second- or third-degree polynomial. A polynomial of a degree greater than one is preferred here in order to model the quadratic dependence of the electrical power fed into the protected line section on the value of the electrical current more precisely. The variables of this polynomial are typically the values of the electrical current detected by the measuring means of the electronic fuse. Optionally, the computer core of the control device of the electronic fuse integrates this intermediate value over time into a second intermediate value. Optionally, the polynomial is a second-degree polynomial. This second intermediate value can then emulate the thermal heating of the fuse wire of a melting fuse in the case of correct parameterization using suitable polynomial coefficients, for example. The advantage is that by a suitable calibration the behavior of the electronic fuse is practically tolerance-free. If the second intermediate value exceeds a predeterminable threshold value, the computer core of the control device of the electronic fuse switches off the circuit breaker of the electronic fuse in this model, which circuit breaker is connected into the line to be protected of the supply branch of the supply tree. In this variant, the electronic fuse optionally comprises one or more devices which emulate a melting fuse. In this case, it is typically characteristic that the electronic fuse comprises one or more device parts which optionally square and integrate the values of the electrical current. In the context of the description presented here, this is the case if the device part has a function which corresponds to or is functionally equivalent to the processing of the measured values of the current through the circuit breaker of the fuse in the line section to be protected by means of a polynomial of an at least second degree and a subsequent integration. That is to say, an analog and/or digital circuit and/or an analog or hybrid computer can expressly perceive this function. This analog and/or digital circuit and/or the analog or hybrid computer can be part of the control device of the electronic fuse. The electronic fuse optionally has one or more device parts which carry out monitoring of essential parameters. These parts are optionally parts of a control device of the fuse. In this case, it is typically characteristic that the electronic fuse comprises one or more device parts which process the values of the electrical current and/or the voltage of the potential of the line section to be protected against a reference potential only by means of a first-degree polynomial, i.e., linearly. In the context of the description presented here, this is the case if the device part has a function which corresponds to or is functionally equivalent to the processing of the measured values of the current and/or the voltage in the line section to be protected by means of a polynomial of a degree less than the second degree. That is to say, an analog and/or digital circuit and/or an analog or hybrid computer can expressly perceive this function, wherein this can be part of the control device of the electronic fuse. These parts optionally comprise time filters which temporally filter and/or temporally integrate these signals. Typically, a particularly favorable filter time of 500 ns can be assumed as a filter time constant of a low-pass filter (filtering time).

In addition to the emulation of a melting fuse, the proposed electronic fuse optionally also performs a rapid disconnection of the circuit breaker of the electronic fuse if the value of the current that the measuring means of the control device of the electronic fuse detects exceeds a permitted maximum value or is not plausible for the usage situation. The plausibility monitoring is optionally carried out by a computer core of the control device of the fuse and/or a higher-level computer system outside the electronic fuse. Optionally, a higher-level computer system of a higher-level controller or the computer core of another electronic fuse can change this maximum value depending on the usage situation and/or on the required power distribution within the vehicle by means of a control command via a wireless and/or wired data transmission path to the electronic fuse. The disclosure describes this wireless and/or wired data transmission path below only in summary as a data bus.

What is important here is that the control device of the electronic fuse, i.e., typically the computer core of the control device or a functionally equivalent device part of the electronic fuse, switches the circuit breaker of the fuse off or on and does not limit the electrical current through the circuit breaker by changing the internal resistance of the circuit breaker, because this would lead to a high power loss in the circuit breaker. Optionally, the circuit breaker is to be switched off in such switch-off situations of the supply network, of which the electronic fuse is a part, in a few nanoseconds.

The automobile manufacturers are currently adhering less to this fast shutdown and currently are typically assuming a shutdown within a period of several milliseconds.

The automobile manufacturers and the relevant automobile suppliers typically are concerned with dynamic loads in the vehicle. They therefore need the electronic fuse to behave like a melting fuse in order to avoid unforeseen cross effects if electronic fuses replace melting fuses in new, modern designs. Therefore, within a certain context, the fuse should also allow the current values to be exceeded up to a maximum value of the electrical current in the electrical line to be protected. That is to say, the shutdown curve of the electronic fuse should be substantially parabolic in the main usage range.

A proposal within the disclosure is therefore an electronic fuse with a rapid shutdown of the circuit breaker of the fuse within a time less than 200 ms, better, less than 100 ms, better less than 50 ms, better less than 20 ms, better less than 10 ms, better less than 5 ms, better less than 2 ms, better less than 1 ms, better less than 500 μs, better less than 200 μs, better less than 100 μs, better less than 50 μs, better less than 20 μs, better less than 10 μs, better less than 5 μs, better less than 2 μs, better less than 1 μs, better less than 500 ns, better less than 200 ns, better less than 100 ns, better less than 50 ns, better less than 20 ns, better less than 10 ns, better less than 5 ns, better less than 2 ns, better less than 1 ns. In this context, the circuit breaker is inserted into the electrical line to be protected within the electronic fuse as an isolator. The computer core of the control device of the electronic fuse optionally executes this shutdown by means of corresponding sub-devices of the control device of the electronic fuse when a maximum permissible current exceeds a maximum current value, and/or when a voltage of the line against a reference potential falls below a minimum voltage value. The special feature of the proposal described here is that, and at the same time otherwise, switching off after a permissible time based on the emulation of a melting fuse characteristic takes place as described above.

The computer core of the control device of the electronic fuse could perform the current measurement by use of a shunt resistor in the line and an analog-to-digital converter of the control device of the fuse. However, this is associated with many disadvantages.

Optionally, the computer core of the control device of the electronic fuse, by use of the analog-to-digital converter of the control device of the fuse, detects voltages between the terminals of the circuit breaker and/or voltages between the terminals of an auxiliary circuit breaker, which is connected in parallel to the circuit breaker and is connected in series with a shunt resistor, or detects functionally equivalent values of physical parameters, and determines therefrom a value for an electrical current through the circuit breaker of the fuse, which circuit breaker is switched on in the electrical line to be protected.

When measuring the current through the circuit breaker of the fuse, the computer core of the control device of the electronic fuse can feed an additional test current into the circuit breaker of the electronic fuse by means of a first test current source. The time characteristic of the value of this additional test current is optionally modulated with a modulation signal. The modulation signal optionally has a known amplitude and a known frequency and phase. The modulated additional current thus optionally has a maximum amplitude. The control device of the electronic fuse detects the time characteristic of the electrical current through the circuit breaker and checks whether the signal of the time characteristic of the measured values of this electrical current comprises signal components the modulation of which correlates to the modulation of the modulation signal. For this purpose, a synchronous demodulator, for example, can carry out the correlation between the time characteristic of the measured values of this electrical current and the time characteristic of the modulation signal. This can, for example, appear such that the synchronous demodulator multiplies the modulation signal or a signal derived therefrom or a signal which is in a fixed temporal relationship with the modulation signal, with the signal of the time characteristic of the measured values of this electrical current or a signal derived therefrom, and the signal resulting from the multiplication is subsequently filtered, optionally low-pass filtered. Instead of a synchronous demodulator, the control device can also comprise a matched filter optimized to the modulation signal and/or a matched filter and/or a Kalman filter or another estimation filter.

The Needs of Automobile Manufacturers and their Suppliers Include:
1. There must be no overcurrent in the protected supply line section. This function is novel, because a melting fuse only ensures thermal overload protection, but not protection from short-term overcurrents.
2. There must be no overloading of the line in the protected supply line section. In this case, the electronic fuse should behave like a melting fuse from the prior art in order to ensure a plug-and-play functionality and in order not to create new problems due to side effects. New designs are intended to maximally utilize the SOA (safe operating area) of the line as the safe operating range, in order to minimize the use of material in the form of the line diameter of the line to be protected. (Protective function of the electronic fuse, i.e., of the e-fuse)
3. The aforementioned organizations have an interest in detecting further parameters in the supply network in order, for example, to be able to carry out a current measurement without a temperature sensor and thus to be able to deduce the temperature of the lines in the supply network, if necessary.
4. The device parts of a vehicle are to be supplied in the parked state with the lowest possible quiescent current consumption. For an electronic fuse, this means that this low residual current consumption has to be carried out with minimum protection and that the loads following the electronic fuse in the supply sub-tree are to be able to wake up from time to time.
5. The automobile manufacturers desire ideal diodes in order to be able to control and/or prevent the return flow of electrical power.

The disclosure proposes, for realizing ideal diodes, that the computer core of the control device of an electronic fuse can optionally detect the electrical current through the circuit breaker in the direction from the power source to the loads, but also in the reverse current direction, by suitable measuring means of the fuse and/or the control device of the fuse. For this purpose, the computer core of the control device of an electronic fuse can detect, for example, the voltage drop across the circuit breaker by means of an analog-to-digital converter or the like and switch off this circuit breaker when the electrical current through the circuit breaker is reversed. The proposed electronic fuse and/or the control device of the electronic fuse should therefore comprise means for capturing and detecting a reverse-flowing current. Typically, the computer core of the control device of the electronic fuse evaluates the measured values thus detected, and forwards these measured values or measured values derived therefrom to other computer cores of other electronic fuses of the supply network via a fuse data bus or the like or to a higher-level computer system, for example a controller of the vehicle.

The disclosure relates, inter alia, to an electrical fuse device comprising, alternatively, the features according to a first set of claims, individual examples of this electrical fuse device according to the disclosure being the subject matter of a second set of claims, a supply network according to a third set of claims, an electronic fuse according to a fourth set of claims, individual examples of this electronic fuse being the subject matter of claims a fifth set of claims, an electronic fuse according to a sixth set of claims, individual examples of this electronic fuse being the subject matter of a seventh set of claims, a supply system comprising the features of an eight set of claims, individual examples of this supply system being the subject matter of a ninth set of claims, an electronic fuse comprising the features according to a tenth set of claims, individual examples of this electronic fuse being the subject matter of an eleventh set of claims, an electronic fuse comprising the features of a twelfth set of claims, an electronic fuse comprising the features of a thirteenth set of claims, individual examples of this electronic fuse being the subject matter of a fourteenth set of claims, and an electronic fuse according to a fifteenth set of claims, an example of this electronic fuse being the subject matter of a sixteenth set of claims, wherein each set of claims includes one or more claims.

A feature of the electronic fuse device according to certain claims can be seen in that this fuse device can be integrated into a supply network of a vehicle one or more times in order to be able to reconfigure the topology of the supply network. The lines of the supply network that are connected to the input and output side can be interconnected as desired, wherein an advantage consists in that the operating parameters are detected and monitored within the fuse device by the electronic fuses. For this purpose, the electronic fuses are connected to a higher-level control or computer system. This system controls the electronic fuses according to the requirements given for the currently required transfer of electrical output or electrical power through the network. The circuit breakers, which are used according to the disclosure, are controlled for switching on and off, i.e., depending on current operating parameters. Current operating parameters can be the magnitude of the current flowing across the relevant circuit breaker and/or the voltage dropping across the relevant circuit breaker or a different voltage in the electrical connection, the electrical output (integrated over time), the electrical power that is transported, the temperature, in particular of the line or electrical connection (keyword it loading) and/or the deformation of the electrical line which could expand, for example, under the influence of heat, which can be detected via electrical parameters such as current or voltage.

A special feature of the electronic fuse according to certain claims is in the galvanic isolation of the supply network in which the circuit breaker of the electronic fuse is connected, and the control of the electronic fuse. Both systems (data communication and higher-level control or computer system on the one hand and supply network on the other hand) can be operated at significantly different voltages. In particular, it is customary in vehicles to connect and process not only extra-low voltages in the range of <=50 V AC or <=120 V DC, in particular in the range of 40 V to 120 V DC and/or low voltages in the range of <=1000 V AC or <=1500 V DC and in particular in the range of 400 V to 1500 V DC (see, for example, Wikipedia, https://de.wikipedia.org/wiki/Kleinspannung), while the data communication is operated at significantly lower voltages. Should there be a shorting of electronic components within an electronic fuse and thus short circuits or a similar situation with increased current, the result of to the galvanic isolation (the data interface operates non-electrically) cannot be an impairment of the functionality of the communication system.

The non-electrically operating data interface of the control device of the electronic fuse optionally operates optically or inductively. The optical radiation can be designed as described in the aforementioned claims. In particular, the optical data transmission can take place by particle radiation or even individual particle radiation. Thus, PQK (post quantum cryptography) or QKD (quantum key distribution) concepts can now be realized (as described, for example, with regard to QKD in the PCT application of the applicant PCT/DE2022/100724).

A special feature of the supply network according to the features of certain claims can be seen in active power management. The operating parameters given there, such as current, voltage, temperature, output, power, etc., are continuously monitored for different points or regions of the supply network by the electronic fuses arranged distributed over the supply network, and signaled to the higher-level control or computer system. A calculation is made between the current power requirement of all loads or some loads or groups of loads on the one hand and the current power supply capacity of all the power sources or selected power sources on the other hand in order to decouple individual loads or even individual parts of the supply network depending on imminent emergency situations due to, for example, excessively high thermal loadings or excessively high electrical loadings of parts of the supply network. The fact that electrical power is additionally provided during operation of the vehicle by, for example, recuperation or solar installations can also be taken into account here.

The electronic fuse comprising the features according to certain claims is characterized, for example, in that thermal monitoring takes place, and specifically does not necessarily relate to the electronic fuse itself, but rather to its surroundings or also to the line into which the electronic fuse is connected. At excessively high temperatures, the electronic fuse can automatically switch off, which is signaled to the control or computer system. The temperature values are also signaled to this system or are only reported if a certain temperature threshold, which is optionally below the switch-off threshold, is exceeded. A certain pre-warning is thus output in this regard.

The thermal protection can be realized as a thermal fuse with the single-use cutoff (irreversible cutoff) or else by a thermal switch which can be reversibly switched off and then switched back on.

Finally, an essential feature of the electronic fuse according to certain claims can be seen in that the electronic fuse can be transferred to another operating mode as a safeguard of the relevant electrical connection or line or power source or the relevant load by either a bypass switch or a drain off switch or a current drain off switch. The electronic fuse with bypass switch, which is optionally situated parallel to the circuit breaker, can thus be used to still ensure a current flow, i.e., to prevent an interruption even though the circuit breaker is switched off. Such an electronic fuse can be used, for example, in a battery in which individual battery cells or individual groups of battery cells (battery modules) are protected by electronic fuses and, in the event of a defect, such defective cells or modules can be shunted by opening the circuit breaker and closing the bypass switch. Alternatively, the bypass switch can be connected to a different terminal of the electronic fuse, for example, than the circuit breaker. A load connected to the circuit breaker can thus be disconnected from the supply network by opening the circuit breaker, while the electronic fuse itself can further supply electrical power, via its bypass switch, further via lines connected via this bypass switch, to other regions of the supply network or to other loads. In this respect, the electronic fuse is then to be understood as an actual electronic fuse with an additional switch.

Another possibility of the electronic fuse is that, when there are currents flowing in reverse, i.e., currents flowing from the load to the electronic fuse, currents of this type are already diverted to a current sink at the load-side terminal of the electronic fuse. This prevents damage to the electronic fuse and components of the supply network which are directly or indirectly connected to the power-source-side terminal of the electronic fuse.

All aspects of the above-described variants of the disclosure and of the variants still to be described below are based on the use of one or more electronic fuses which have at least one circuit breaker which can be controlled via a control device. The control device is thereby connected via a data interface to a higher-level control or computer system. The control device does not necessarily have to be part of the electronic fuse; it can also be arranged externally of the electronic fuse and in particular control the circuit breakers of a plurality of electronic fuses. If the control device is part of the electronic fuse, this can also have an effect, optionally via the data communication bus, on the control of the circuit breakers of other electronic fuses. This behaves similarly in some ways to the measuring device of the electronic fuse for detecting an operating parameter of the circuit breaker and/or an electrical connection or a line in which the circuit breaker is arranged, wherein the operating parameter is the magnitude of a current and/or a voltage and/or an electrical output and/or an electrical power, or it is the temperature and/or a measured value representing the deformation of the electrical connection. Such a measuring device can be provided per electronic fuse; if the electronic fuse has a plurality of circuit breakers, a measuring device expediently serves to detect the operating parameters of each of the circuit breakers or of each electrical connection into which the relevant circuit breaker is connected. However, the measuring device does not necessarily have to be an integral part of the electronic fuse. The measuring device could thus also be provided externally in order to communicate, optionally via the data interface, with the control devices of a plurality of electronic fuses.

The disclosure relates to a method for operating a supply network, comprising compression and encryption of the first fuse data of a first electronic fuse in the first electronic fuse and compression and encryption of the sensor data of a further sensor and comprising transmission of the compressed and encrypted first fuse and sensor data to a higher-level computer system and comprising decryption and decompression of the compressed and encrypted first fuse and sensor data to form received first fuse and sensor data in the higher-level computer system. Moreover, the method comprises the fusion of the received first fuse and sensor data in the higher-level computer system.

Various application scenarios for electronic fuses in vehicles and various examples of such fuses are described below.

### Battery

Electronic fuses are also suited for monitoring batteries. The disclosure therefore proposes a battery with a diagnostic function. Optionally, at least one terminal of the battery is provided with an electronic fuse, as proposed here. For example, the battery can comprise a supply tree and/or a supply network having one or more supply branches. For example, a plurality of electronic fuses within the battery can be connected in series in a supply branch of a supply tree and/or of a supply network. For example, a supply tree and/or a supply network can also comprise only one supply branch with a plurality of electronic fuses which are inserted into the supply branch. Optionally, a battery comprises one or more battery cell modules. Optionally, one or more battery cell modules are electrically connected in series. Optionally, one or more electronic fuses are connected between battery cell modules of the battery. Optionally, precisely one electronic fuse is connected between two battery cell modules, which are interconnected in series. Optionally, an electronic fuse is provided for each battery cell module. Optionally, one electronic fuse is optionally assigned to each battery cell module or to one or more groups, in particular of battery cell modules connected in series. Optionally, one or more or all of these electronic fuses have a first circuit breaker which, if open, is suitable for preventing the current flow through the battery cell module or the relevant group of battery cell modules, i.e., the electrical connection between a first battery cell module and a second battery cell module or a first group of battery cell modules and a second group of battery cell modules which are interconnected in series. Optionally, one or more or all of these electronic fuses of the battery have a second circuit breaker which is suitable for shunting the battery cell module or the group of battery cell modules when a second circuit breaker is closed.

The computer core of the control device of the electronic fuse can in this case optionally only close the second circuit breaker if the first circuit breaker is securely opened. For this purpose, the computer core of the control device of the electronic fuse optionally checks the switching state of the first circuit breaker before the second circuit breaker is closed, for example by feeding a test current into the first circuit breaker and by drawing this test current downstream of the first circuit breaker and by detecting and checking the voltages at the terminals of the circuit breaker.

The computer core of the control device of the electronic fuse can in this case optionally only close the first circuit breaker if the second circuit breaker is securely opened. For this purpose, the computer core of the control device of the electronic fuse optionally checks the switching state of the second circuit breaker before the first circuit breaker is closed, for example by feeding a test current into the second circuit breaker and by drawing this test current downstream of the second circuit breaker and by detecting and checking the voltages at the terminals of the second circuit breaker.

Optionally, the interconnection between the battery cell module or the group of battery cell modules and the first circuit breaker and the second circuit breaker comprises three electrical nodes. The first circuit breaker here is optionally connected to a first node by a first terminal of the first circuit breaker. The first circuit breaker here is optionally connected to a second node by a second terminal of the first circuit breaker. The second circuit breaker here is optionally connected to a third node by a first terminal of the second circuit breaker. The second circuit breaker here is optionally connected to the second node by a second terminal of the second circuit breaker. A first terminal of the battery cell or of the group of battery cells is optionally connected here to the third terminal. A second terminal of the battery cell or of the group of battery cells is optionally connected here to the first terminal. Optionally, the electronic fuses have a housing for use in a battery. Optionally, electronic fuses have an optical interface for use in a battery. Optionally, said housing of an electronic fuse comprises an optical window or an optical subsystem for the entry of electromagnetic radiation for the transport of data to this electronic fuse. Optionally, said housing of an electronic fuse comprises an optical window or an optical subsystem for the emission of electromagnetic radiation for the transport of data from the computer core of the control device of the electronic fuse to the computer core of the control device of a different electronic fuse or to a higher-level computer system. The electromagnetic radiation is optionally laser radiation and/or radiation of an LED. Optionally, the electronic fuse comprises a laser or an LED in particular for this purpose. Optionally, the electronic fuse comprises a photodetector, for example a photodiode, for receiving optical signals which transport data. The optical windows are sub-devices of one or more optical data interfaces of the control device of the relevant electronic fuse. Optical waveguides and/or other optical functional elements optionally interconnect the computer cores of the control devices of one or more electronic fuses via these optical data interfaces of these electronic fuses. Optionally, one or more electronic fuses are connected to a higher-level computer system via such an optical interface, and an optical waveguide is connected to an optical interface of the higher-level computer system. One or more electronic fuses can also be connected with data technology to the higher-level computer system by means of a different data interface, in particular by means of the aforementioned one. The battery cell module or the group of battery cell modules optionally supply the control device of the electronic fuse and the other parts of the electronic fuse that is associated with this battery cell module or this group of battery cell modules with electrical power for the operation thereof. A battery cell module or a group of battery cell modules can first of all optionally supply electrical power to the control device of the electronic fuse and, secondly, the other parts of the electronic fuse and, thirdly, those battery cell modules or that group of battery cell modules with which this electronic fuse is associated and which this fuse follows or precedes in the supply branch for the operation of this electronic fuse. The battery thus optionally comprises an electronic fuse per battery cell module or per group of battery cell modules. The computer core of the control device of the electronic fuse optionally detects voltage values and/or current values by means of measuring means of the control device of the electronic fuse. The electronic fuse optionally performs a fuse function. Optionally, the computer core of the control device of the electronic fuse, by means of the circuit breaker of the electronic fuse, interrupts the current flow through the circuit breaker of the electronic fuse if a disconnect condition is satisfied. Such a disconnect condition can be, for example, the exceeding of a maximum value of the electrical current through the circuit breaker of the fuse or the like. The computer core of the control device of the electronic fuse by means of the circuit breaker of the electronic fuse optionally interrupts the current flow and shunts the battery cell module or the group of battery cell modules if a disconnect condition is satisfied and a shunting condition is satisfied. The computer cores of the control devices of one or more electronic fuses optionally transmit one or more measured values and/or values derived therefrom and/or state values and/or state information of the corresponding electronic fuses to a higher-level computer system. One or more control devices of the electronic fuses optionally comprise one or more temperature sensor evaluation devices optionally having one or more temperature sensors. The electronic fuse optionally comprises one or more temperature sensors. The electronic fuse can additionally comprise a thermal fuse which comprises a melting fuse having a tensioned spring, which switches off the circuit breaker of the electronic fuse if the circuit breaker exceeds a maximum temperature. The computer core of the control device of the melting fuse optionally evaluates temperature measured values of the one or more temperature sensor evaluation devices which detect them with the aid of temperature sensors external to the electronic fuse and/or with the aid of temperature sensors of the electronic fuse.

Optionally, one or more electronic fuses comprise two data interfaces which can be optical. Optionally, the computer cores of the control devices of the electronic fuses in devices with increased requirements for the galvanic isolation are connected with data technology via an optical data bus in which the data interfaces of the control devices of the electronic fuses are each inserted.

Data interfaces of the control devices of the electronic fuses are optionally connected with data technology in a wired and/or wireless manner at least by an electronic one-wire data bus and/or by a two-wire data bus and/or a different data bus and/or a different data communication means. The data interfaces of the control devices of the electronic fuses are inserted into such a data bus. The data buses can be connected together in a star-shaped or linear manner in a chain or a closed ring. Depending on the type of data bus, the data buses can in some cases also have branches. In a particularly preferred data bus within a battery, it can be an optical data bus ring of optical data buses connected in a ring. The optical waveguides of the optical data bus are optionally designed with electrical insulation. The control device of an electronic fuse can optionally comprise a silicon-based LED as an LED. An optical data interface of the control device of an electronic fuse can also comprise, for example, a silicon-based LED as an LED. Such a silicon-based LED can be a silicon avalanche LED. For example, the silicon-based LED can be a SPAD diode which operates the control device of the fuse as an LED with sufficient reverse voltage in the breakdown region. Optionally, the control device of the electronic fuse then comprises a driving device which generates the operating voltage for the silicon LED, in particular the SPAD diode, from the operating voltage of the electronic fuse by means of a voltage converter. The technical teaching presented here also proposes, among other things, to operate the silicon LED periodically as a receiver. For this purpose, the computer core of the control device of the electronic fuse isolates the silicon LED from the electrical supply of the voltage converter by means of an isolating switch of the control device of the electronic fuse and uses the voltage signal and/or photocurrent signal of the silicon LED as an input signal for an optical data receiver of the control device of the electronic fuse.

### Flexibility of the Architecture

An electronic fuse, as proposed by the disclosure, can reduce the effort in the design of the automotive fuse box (the junction box). Because, in particular, a higher-level computer system can access the computer cores of the control devices of the electronic fuses by means of data buses via the controllers of the vehicle, new designs can position the electronic fuses at different locations in the vehicle and thus minimize the wiring complexity for the supply network. This enables the electronic fuses to be decentralized. Optionally, new designs implement one or more supply branches of the supply network for supplying electrical loads within the vehicle with electrical power as a ring of a supply line, if the body serves as a return ground line, and/or in the other case is implemented as two rings of two supply lines. The corresponding circuit breakers of the respective electronic fuses are optionally inserted into the corresponding supply line of the supply network. Two fuses are optionally inserted into the corresponding supply line for each load at the corresponding tapping point of the electrical power for this load into the corresponding supply line. As a result, in the event of an error at a supply line section, the corresponding computer cores of the corresponding control devices of the two electronic fuses associated with this faulty load open their corresponding circuit breakers, so that this opening of the circuit breakers of the fuses isolates the defective line section. As a result, in the event of an error on a load, the corresponding computer cores of the corresponding control devices of the two electronic fuses associated with this load typically open their corresponding circuit breakers, so that this opening of the circuit breakers isolates the faulty load. Thus, such a fault does not impair the supplying of the other loads with electrical power.

### Active Power Generation Configuration and Active Power Distribution Configuration (Active Power Management)

The so-called active power management comprises, for example:
adaptive management of the line state,
adaptive current management by means of adaptive switch-off thresholds,
reduction of the quiescent current in HV domains,
efficient park system states,
remote recovery,
preventive maintenance (AI).

Particularly optionally, the corresponding computer cores of the corresponding control devices of a plurality of electronic fuses detect the corresponding electrical current through their corresponding circuit breakers and where applicable the corresponding potential of one or more terminals of this circuit breaker among one another and/or against a reference potential of a reference potential contact as a reference potential. Depending on the current value of the energization of the corresponding circuit breaker of the corresponding fuse, the corresponding computer core of the corresponding control device of the corresponding fuse optionally calculates a theoretical ground offset by means of model formation and where, applicable, corrects the corresponding voltage measured values detected thereby.

This calculation of the computer core of the control device of the fuse can also be carried out by other computer cores of other control devices of other electronic fuses in the overall system or by higher-level computer systems of the vehicle, etc.

Individual computers or a plurality of computers of the overall system, which can also be computer cores of the control devices of the electronic fuses and/or the higher-level computer system, can, for example, deduce state parameters of the supply line sections with the aid of the parameters thus detected, such as current values and voltage values. This can include, for example, resistance loads per unit length and/or temperatures and/or thermal deflections etc. of the supply line sections. The state parameters of a supply line section can include the temperature thereof. The computer cores of the control devices can determine the temperature in the case of copper lines, for example, very well with the aid of the known temperature coefficients of copper and the known design data of the supply line section and/or by means of the power fed into the supply section and/or by means of the power absorbed in the supply line section. The same applies for other materials.

The use of electronic fuses enables the programming of equipment variants. In order to prevent improper activation or deactivation of the power supply option of sub-trees of the supply tree and/or sub-supply-networks of the supply network, the communication between the computer core of a control device of an electronic fuse and the computer core of the control device of a different electronic fuse is optionally encrypted. In order to prevent improper activation or deactivation of the power supply option of sub-trees of the supply tree and/or sub-supply-networks of the supply network, the communication between the computer core of a control device of an electronic fuse and a higher-level computer system is optionally encrypted. The activation and/or the deactivation of an electronic fuse, i.e., switching the circuit breaker on or off, optionally require the transmission of a digital password from the computer core of the control device of a different electronic fuse or from the higher-level computer system via a data bus to the computer core of the control device of an electronic fuse. The communication between the computer core of the control device of an electronic fuse and its environment is via such data connections is optionally encrypted. A data connection of this type is optionally encrypted using a PQC method. (PQC=post quantum cryptography). The communication via the data bus can take place, for example, by means of a PSI5-like protocol or the like. Optionally, the electronic fuses that are sub-devices of a supply network also communicate with one another by means of power-line communication via the supply network or their possibly separate supply voltage lines.

After a substantial change of the operating state of the vehicle, optionally not all electronic fuses simultaneously change the switching state of their circuit breakers. Such a significant change in the operating state of the vehicle can be, for example, the switch-on process if the vehicle is transferred from the parking state to the driving state. Electronic fuses optionally receive a start signal from a central controller, for example a higher-level computer system. If necessary, the higher-level computer system distributes beforehand the values of waiting times which the electronic fuses are intended to wait between the arrival of the start signal from the controller and the closing of its corresponding circuit breaker. These respective values of the respective waiting times can also be programmed into a non-volatile memory of the corresponding electronic fuse. This programming can be done at the factory or via the higher-level computer system or a different computer of the vehicle, thus also via the computer core of a different electronic fuse. As a result, the typically very high starting current of the electrical system of a vehicle decreases massively. This starting current is also referred to as an in-rush current. Because the in-rush current gets lower, new designs with electronic fuses can implement the wiring network for supplying the electrical loads in the vehicle in turn with weaker current and with cables that are less thick. This reduces the weight of the vehicle.

### Increase in System Reliability

The disclosure proposes that the computer cores of the control devices of the electronic fuses check the corresponding voltages between these terminals and a reference node and/or between one another at the corresponding terminals of their corresponding circuit breakers which are located on the power-source side. If any of these respective voltages falls below a corresponding minimum value and at the same time the corresponding electrical current through the corresponding circuit breaker of the corresponding electronic fuse exceeds a predetermined threshold value, the corresponding power supply delivers more power than intended into the corresponding supply sub-network protected by this corresponding electronic fuse. The corresponding electronic fuse then optionally switches off the electrical supply of this supply sub-network by switching off its corresponding circuit breaker. This results in a limitation of the corresponding voltage sag due to the speed of the corresponding electronic fuse.

Depending on the safety scheme, the computer core of the control device of the electronic fuse can perform one or more switch-on attempts after a switch-off. If the number of unsuccessful switch-on attempts exceeds a predefined number, the computer core of the control device of the electronic fuse optionally transmits an error message to the computer core of the control device of a different electronic fuse or to a higher-level computer system.

Electronic fuses for power supply sub-networks and supply branches with as high an availability as possible are intended to have this possibility of single or multiple switch-on attempts (retry) when switching off as a result of overcurrent or the like.

### Fuse Data Bus (Fuse Bus)

As already described above, it is expedient if the computer cores of the control devices of the electronic fuses can communicate with other computer cores of the control devices of other fuses in the supply network of the vehicle or with higher-level computer systems of the vehicle. Typically, there is a communication requirement for configuration data (read-write), switch commands (read-write), diagnostic data (read-write), measured values (read), comparison value settings (read-write).

The computer cores of the control circuits of the electronic fuses optionally use a fuse data bus for communication with one another in the vehicle or within a fuse box. The fuse data bus is optionally a two-wire data bus. The fuse data bus is optionally a differential data bus because considerable mass flows and ground offsets can occur in the body of a vehicle. The fuse data bus is optionally a CAN data bus or a data bus with a physical interface of a CAN data bus, a CAN FD data bus, or a Flexray data bus or an LVDS data bus or the like. The fuse data bus is optionally bidirectional. Optionally, the control devices of the electronic fuses comprise two data bus interfaces for the fuse data bus, so that new designs can insert the electronic fuses into the fuse data bus by means of these two data bus interfaces. As a result, the electronic fuses can form a linear chain of electronic fuses along the fuse data bus, so that a higher-level computer system—for example a controller—which is connected at the beginning of the fuse data bus, transmits the fuse addresses as bus node addresses to the computer cores of the control devices of the electronic fuses by means of auto addressing for controlling the computer cores of the control devices of the electronic fuses.

The computer cores of the control devices of the electronic fuses optionally transmit parameters of the connected supply sub-networks and/or individual nodes of the supply sub-networks and/or individual supply line sections of the supply network of the supply lines of the vehicle to other computer cores of the control devices of other electronic fuses and/or one or more higher-level computer systems—e.g., controllers of the vehicle. If necessary, such parameters can be directly accessible parameters, such as temperature of a temperature sensor, voltage of a node of the supply network against a reference potential, or the value of an electrical current in a supply line section of the supply network. A computer core of a control device of an electronic fuse can also detect parameters derived by application of Kirchhoff equations to data which the computer core of the control device of the electronic fuse has determined by means of measuring devices of this electronic fuse or which the computer core of the control device of this electronic fuse has received from the computer cores of the control devices of other electronic calculations or from higher-level computer systems (e.g., controllers of the vehicle), such parameters including, for example, leakage currents against other electrical nodes in the vehicle or electrical resistances of supply voltage line sections.

In particular, the computer core of a control device of an electronic fuse can estimate the temperature of a downstream supply voltage section if its ohmic resistance, its heat capacity, thermal leakage resistances, and the ambient temperature in the region of the supply line section are approximately known to the computer core, for example by estimation. This procedure typically utilizes the fact that the power fed into the supply line section substantially corresponds to the time integral of the supplied electrical output of the supply line section. This is typically proportional to the square of the current magnitude of the electrical current flowing into the supply line section.

Other Ideas that this Document Presents

### Registering the Power Supply

A first idea is registering the supply of electrical power to previously unsupplied loads in the supply network by users. In this case, the user, for example via a data connection to the server of a service provider, purchases an activation code from a provider, who generates and/or has generated this activation code with the aid of authentication data according to an established method and keeps it ready and transmits it to the user via a data transmission channel. One or more computer cores of the control devices of one or more electronic fuses optionally detect the power which the battery of an electric car feeds into a supply sub-branch of the supply network, for example. In this model, the battery is the property of the utility company. Optionally, a higher-level computer system, for example a controller of the vehicle, reads the determined amount of power from the computer core and/or a memory of the control device of the electronic fuse and/or the underlying measured values and transmits this data via a data transmission path, which is optionally encrypted, to the utility company or a subcontractor, who then creates an invoice on the basis of this data. It is conceivable that the supply sub-network also enables services of further service providers which, where applicable, determine their invoice data in a similar manner and invoice the user.

### Diagnostic Ring

New designs optionally provide a supply network which is annular in parts and in which the loads optionally draw electrical power from the supply network at different locations of the annular supply network. The supply line of the annular supply network to the left and right of the electrical power extraction point is optionally interrupted by an electronic fuse, but at least an electronic fuse which is inserted with its corresponding circuit breaker into the supply line of the supply line section between two extraction points for electrical load power. If an error occurs, these fuses can first isolate the affected supply line section and/or the affected load. A higher-level controller can determine the status of the electronic fuses by response of the computer cores of the control devices of the electronic fuses, and thereby contain the cause of a fault without this fault being able to affect further loads. Typically, the engagement of the fuses takes place so quickly that the fault only impairs a few sensor values of sensors and/or measuring devices that are attached to the supply network in such a way that their values are unusable. The electronic fuses optionally record the faults in the form of a log table, which can also comprise only a few bits. The control apparatuses of the electronic fuses optionally provide the entries of the log table with time stamps of a timer unit of the control device of the electronic fuse. In this case, the control device of the electronic fuse optionally also records with a time stamp the time from which the fault was no longer present. A higher-level computer system optionally queries this data regularly or in the event of a fault. The higher-level computer system can thus determine which supply sub-network or which supply line was disrupted, when and how it was disrupted and how long this fault persisted. As a result, the higher-level computer system can identify potentially affected sensors and measuring systems and mark or even discard the measured values acquired thereby within the relevant time period as potentially faulty. A further advantage of an annular structure of such a supply network with electronic fuses is improved reliability by redundancy. It is therefore particularly possible for safety-relevant applications.

Satellites with Electricity Meter

As already explained, it is useful in many cases if individual loads are equipped with a watt meter or the like. For this purpose, an electronic fuse detects the voltage of a node on the circuit breaker of the electronic fuse or a node associated therewith and optionally the current through the circuit breaker of the electronic fuse by means of a voltmeter, and thereby determines the electrical current flowing into the load or a downstream supply tree or a downstream supply line section. The computer core of the control device of the electronic fuse optionally transmits these data via a data bus to the computer core of the control device of another electronic fuse or to a higher-level computer system.

### Activating Individual Loads

It is conceivable to enable the electrical supply of individual loads in the supply network of a vehicle by means of activation codes as described above. In this case, a server of the automobile manufacturer or a service provider transmits, based on authentication data, which can comprise data of the vehicle, of the car key, of a SIM card, of a password input, biometric user data, etc., to the vehicle or the user which then transmits these data in the vehicle via a terminal or a data interface to the vehicle. Depending on the activation code, a higher-level computer system of the vehicle then transmits commands for closing the circuit breakers to selected electronic fuses of the supply network, as a result of which the supply network then supplies electrical power to activation-code-specific supply-sub-networks.

Transmission of the Power Utilization Data to Power Providers and/or Automobile Manufacturers

As described above, a higher-level computer system of the vehicle can transmit the thus determined utilization and configuration data of the system consisting of electronic fuses and supply sub-networks and supply line sections as transmission of power utilization data to power providers and/or automobile manufacturers and/or other service providers.

### Detecting a Hot Plug Event

An electronic fuse is optionally placed in the vicinity of a plug for supplying an electrical load in the vehicle with electrical power. A problem can now arise if users and/or workshops, etc., before removing the device, do not de-energize this device, as prescribed, before plugging it in or disconnecting it. This document refers to such an event below as a hot plug event. This de-energizing is optionally performed by means of a software command via a data bus from a controller, i.e., a higher-level computer system, to a computer core of a control device of an electronic fuse, which then opens its circuit breaker. If this is not done beforehand and incorrect operation nevertheless triggers a hot plug event, the control circuit of the associated electronic fuse can detect such a hot plug event by monitoring the transient time characteristic of the voltage of the potential of a node of the circuit breaker against the potential of a reference node and/or by observing the transient characteristic of the current through the circuit breaker and switch off the circuit breaker quickly enough that this rapid shutdown minimizes plasma formation. In addition, the electronic fuse can signal such an event to the associated controller, for example a higher-level computer system, via a data line. The higher-level computer system can, if applicable, continue to report this event so that it is first displayed in a terminal (e.g., by means of a human-machine interface) or is transmitted to the automobile manufacturer via a data transmission path.

### Distributed Measurement Methods

It was apparent that it is expedient for the control device of an electronic fuse to exchange the aforementioned measured values with other control devices of other electronic fuses via a data bus. The control device can generally not ensure that the data transmission takes place very quickly. It is therefore expedient if the control device of the fuse, apart from the measured values, also transmits a time stamp for one or more measured values. For this purpose, the electronic fuses optionally have a clock or a timer. A higher-level computer system optionally determines one-time correction factors for correcting the time stamp values of the non-synchronous clocks of the different control devices of the different electronic fuses. Another method is the recurring synchronization of these clocks and/or timers. The synchronization can comprise resetting to a common starting value. The synchronization can, alternatively, comprise the correction of the frequencies of the oscillators and/or clock pulses, which can be adjusted by the synchronization process, for example, by adjusting the dividers of a base frequency. In this case a higher-level computer system, by means of a data bus command in broadcasting mode, can cause, for example, the different control devices of the different electronic fuses to carry out the same measurements at the same instants, wherein “same” here refers to the sameness of the clock states of the corresponding clocks of the different control devices of the different electronic fuses. It is thus a distributed measurement method with synchronous measurement by means of synchronized local clocks within the control devices of the various electronic fuses. This enables the substantially time-synchronous measurement of ohmic resistances of supply line sections.

### Coupling Communication Network and Supply Network

It is expedient to couple a communication network with a supply network. Reference is made here to the above-described fuse data bus.

### Dynamic Assignment of Current Paths

In the development, it was recognized that, in the case of redundancy, the dynamic assignment of power and power transport paths within a vehicle can be useful. For this purpose, a higher-level computer system of the vehicle determines the power requirements of the potential power loads of the vehicle. The supply lines are optionally designed as a supply network, wherein two or more supply lines are routed parallel at least in sections and/or intersect at at least two points in the vehicle. As an example, we now study the intersection of a first supply line with a second supply line. The supply network optionally comprises two electrical nodes at these points of intersection. For better clarity, the disclosure refers to these two electrical nodes at the point of intersection as the first node of the first point of intersection and the second node of the point of intersection. The point of intersection divides the first supply line into a power-source-side first part of the first supply line and a load-side part of the first supply line. The point of intersection divides the second supply line into a power-source-side first part of the second supply line and a load-side part of the second supply line.

In the following, we now describe an electronic cross-over fuse which comprises four electronic fuses. In the following example, the electronic fuses of the electronic cross-over fuse are implemented on the power-source side. It is also conceivable to implement the electronic fuses, conversely, on the load side. The designs can provide electronic fuses on the load side and power-source side.
A first electronic fuse connects or disconnects the power-source-side first part of the first supply line to/from the first node depending on the switching state of the circuit breaker of the first electronic fuse.
A second electronic fuse connects or disconnects the power-source-side first part of the second supply line to/from the first node depending on the switching state of the circuit breaker of the second electronic fuse.
The circuit breaker of the first fuse is optionally only closed if the circuit breaker of the second fuse is open. The circuit breaker of the second fuse is optionally only closed if the circuit breaker of the first fuse is open.
A third electronic fuse connects or disconnects the power-source-side first part of the first supply line to/from the second node depending on the switching state of the circuit breaker of the third electronic fuse.
A fourth electronic fuse connects or disconnects the power-source-side first part of the second supply line to/from the second node depending on the switching state of the circuit breaker of the fourth electronic fuse.
The circuit breaker of the third fuse is optionally only closed if the circuit breaker of the fourth fuse is open. The circuit breaker of the fourth fuse is optionally only closed if the circuit breaker of the third fuse is open.
The load-side part of the first supply line is connected to the first node.
The load-side part of the second supply line is connected to the second node.

An alternative example of the cross-over fuse implements the electronic fuses on the load side:
A first electronic fuse connects or disconnects the load-side first part of the first supply line to/from the first node depending on the switching state of the circuit breaker of the first electronic fuse.
A second electronic fuse connects or disconnects the load-side first part of the second supply line to/from the first node depending on the switching state of the circuit breaker of the second electronic fuse.
The circuit breaker of the first fuse is optionally only closed if the circuit breaker of the second fuse is open. The circuit breaker of the second fuse is optionally only closed if the circuit breaker of the first fuse is open.
A third electronic fuse connects or disconnects the load-side first part of the first supply line to/from the second node depending on the switching state of the circuit breaker of the third electronic fuse.
A fourth electronic fuse connects or disconnects the load-side first part of the second supply line to/from the second node depending on the switching state of the circuit breaker of the fourth electronic fuse.
The circuit breaker of the third fuse is optionally only closed if the circuit breaker of the fourth fuse is open. The circuit breaker of the fourth fuse is optionally only closed if the circuit breaker of the third fuse is open.
The power-source-side part of the first supply line is connected to the first node.
The power-source-side part of the second supply line is connected to the second node.

These cross-over fuses can dynamically assign alternative and redundant current paths of specific loads depending on the determined power requirement. For this purpose, a controller of the vehicle transmits configuration commands suitable for the electronic fuses of the cross-over fuses of the supply network, which commands effect the opening and closing of circuit breakers of the electronic fuses and thus dynamically adjust the electrically effective topology of the supply network of the supply lines according to the power requirement and according to the current safety requirements.

Switching Off Sub-Regions of the Supply Network within a Vehicle

A further idea is to switch off sub-regions of the network for maintenance and secure access. For this purpose, the person who wants to carry out maintenance enters a predetermined security code into a higher-level computer system by means of a terminal or another human-machine interface (HMI). In some cases, the person receives this security code from a server of the automobile manufacturer or a service provider. For this purpose, the person transmits authentication data to the server, which comprises, for example, authentication data of the person, the organization for which the person is working, or authentication data of the vehicle or car key or the like. A controller then de-energizes parts of the supply network with the aid of electronic fuses. Optionally, at least one electronic fuse is provided in each sub-supply network that can be isolated in this way, which fuse short circuits the sub-supply network isolated by opening the circuit breakers of the disconnecting electronic fuses by closing the circuit breaker of this one fuse with a reference voltage line, for example a ground, and thus discharges it.

### Depending on the Output of the Satellites on the Basis of the Line Supplying Power

The reconfiguration of the network topology was described above, for example by means of differently configurable node fuses. For a system emergency operation, it is now expedient if the current consumption of a relevant load is adapted to the weakest supply line in the path between the power source and the relevant load. For this purpose, the higher-level computer system, which has initiated the reconfiguration of the supply network by corresponding commands to the electronic fuses via one or more data buses, signals to the relevant load how much power this load may consume in order not to abandon this weakest line. In the simplest case, the load can have two states. A state in which it consumes more power and a state in which it consumes less power.

Network with Reduced Cross-Section of the Cable Harness

According to the proposal, due to the optimizations carried out the improved designs can provide supply lines of the supply network with a smaller cross-section than would normally be possible without electronic fuses.

### Rapid Shutdown

An essential idea is the rapid shutdown of a circuit breaker of an electronic fuse when a maximum permissible current through the circuit breaker is exceeded. If this maximum permissible current through the circuit breaker of an electronic fuse is not exceeded, the switch-off of the circuit breaker optionally takes place only after a period of time, wherein this time generally depends in a parabolically dropping relationship on the level of the current through the circuit breaker. The control device of the electronic fuse optionally emulates the behavior of a melting fuse. For this purpose, the control device of the electronic fuse detects the value of the electrical current through the circuit breaker. The control device optionally squares the value of the electrical current through the circuit breaker and integrates this value over time. In general, the integration is a low-pass filtering or the like. If the filter output value exceeds a threshold value, the control device opens the circuit breaker of the electronic fuse. This is therefore an electronic fuse with emulation of a melting fuse characteristic.

Fuse with Prevention of the Reverse-Flowing Current.

The electronic fuse optionally prevents the return flow of electrical power away from the load to the power source. For this purpose, the electronic fuse optionally detects the direction of the flowing electric current. If the current does not flow to the load, but rather in the direction of the power source, the electronic fuse optionally opens the circuit breaker, whereby this current flow is stopped. It is conceivable that the control device in such a case closes a third circuit breaker of the electronic fuse which is otherwise open during normal operation. Optionally, the then closed third circuit breaker then closes the load-side supply line by closing the third circuit breaker, for example with the reference potential line, which is to say the ground, whereby the returning current is now dissipated in the system ground.

### Using Silicon LEDs

Optionally, the electronic fuse comprises one or more silicon LEDS. Optionally, the silicon LEDs are part of an optical data interface of the computer core of the control device of the electronic fuse. These silicon LEDs are optionally also used as photodetectors of the optical data interface. The use of such silicon LEDs is particularly advantageous for the use of electronic fuses in batteries.

In this case, the housings of the electronic fuses optionally have optical windows by which the light of the silicon LEDs can exit.

Electronic Fuse with Authentication

The electronic fuse optionally has means for verifying the admissibility of a command which the control device of the electronic fuse has received via a data bus. For example, these can be methods of encryption and decryption which safeguard a secure communication between a higher-level computer system and the control device of an electronic fuse. This is therefore an electronic fuse with authentication for modern business models such as the connection of components by software on a paid basis.

### Plausibility Check of the Configuration for Identification

A further recognized point is the plausibility check of the configuration for identifying manipulations on the supply network. Depending on the task, the electrical currents within the supply network on the supply lines are in more or less known or pre-calculable ranges. If the current value of a supply line now leaves the expected value range, either an error or a manipulation is present.

### Detection of the Switchability of the Electronic Fuse

Optionally, an electronic fuse also comprises means for detecting the switchability of the electronic fuse. This can be, for example, the feeding of a test current into a first terminal of the circuit breaker from a second terminal of the circuit breaker. If the control device of the electronic fuse cannot extract this electrical current from the other terminal of the circuit breaker, the circuit breaker is not open or is not present. The control device of the electronic fuse optionally changes the switching state of the circuit breaker one or more times. The current conductivity of the circuit breaker, which the control device of the electronic fuse determines in each case, should correlate with the expected switching state of the circuit breaker.

If no switchability is provided, the control device of the electronic fuse optionally signals an error to a higher-level computer system of the vehicle.

Self-Configuring Fuse with Auto Addressing

The electronic fuses are optionally inserted into a data bus arranged linearly like a string of pearls. As a result, the electronic fuses have, in relation to this linear data bus, a unique physical bus position that can be counted by the higher-level computer system that drives the data bus. By means of an auto addressing method, the higher-level computer system can now assign a fuse address to each electronic fuse, so that the higher-level computer system can address each fuse one-to-one. The electronic fuses can thus now detect the location at which they are physically located in the data bus. A configuration of threshold values and switch-off thresholds is optionally predetermined for each conceivable physical data bus position within the vehicle. Based on the knowledge of the physical data bus position, these electronic fuses can now be configured according to their data bus position with the aid of said factory data. These are therefore self-configuring electronic fuses with an auto addressing, in which the configuration of the electronic fuse depends on the detected physical data bus position.

Electronic Fuse with AI

According to the disclosure, it was recognized that the plurality of values that the electronic fuses detect enable the evaluation by a computer core of the control device of an electronic fuse or by a computer of a higher-level computer system. For this purpose, the evaluating unit uses the values that one or more control devices of one or more electronic fuses determine(s) by means of corresponding measuring means as input values of a neural network model which the computer of the evaluating unit executes. The neural network model is optionally trained with suitable training data from the development time. For example, it can be expedient in this way to detect a failure of one or more loads or other defects of the system before they themselves actually manifest it.

Power Line Communication Via an Electronic Fuse (e-Fuse)

A further idea is communication via the data line, wherein the circuit breaker of the electronic fuse serves as a transmitting transistor. This is therefore a power line communication via the electronic fuse (e-fuse).

Spectral Analysis for the Load Current of an Electronic Fuse (e-Fuse) for Predictive Maintenance

A further idea is the detection of the time characteristic of the electrical current through the circuit breaker of an electronic fuse and in some cases of the time characteristic of the voltage between a terminal of the circuit breaker and a reference potential. Optionally, a device carries out a spectral analysis of these data of the electronic fuse. If there are substantial deviations from expected values, the evaluating devices can draw conclusions which, among other things, the user and/or workshops can use for preventive maintenance of the vehicle.

Checking System Availability Across the Spectrum of the Electronic Fuse (e-Fuse), Expected Characteristic (Positive Test)

In an analogous manner, the evaluating device can check the system availability across the spectrum of the electronic fuse by means of the determined spectra. If the characteristic of the spectra matches the expected values within permitted bandwidths, then the relevant load is likely available. It is thus a positive test.

### Reduction of the Inrush Current

A further idea is not to close the circuit breakers of the electronic fuses simultaneously but rather in a time-delayed manner, at a system start. As a result, the electrical devices connected to the corresponding electronic fuses do not start simultaneously. As a result, the so-called inrush current is reduced by the shift and desynchronization of the switch-on curves of the supply sub-networks.

### Limiting Voltage Sags

Optionally, the electronic fuses measure not only the electrical current through their circuit breaker, but also the voltage at a terminal of the circuit breaker against a reference potential. A voltage sag due to a short-circuit in a supply sub-network is particularly dangerous, for example. An electronic fuse therefore optionally switches off particularly quickly in the event of a voltage drop in the measured voltage values and a simultaneous increase in current. This avoids interference from sensors of the vehicle. Such an electronic fuse is thus a device for limiting the voltage drop in the event of faults in the voltage system of the individual network. The electronic fuse optionally switches so quickly that the voltage does not drop too far and thus such an event does not interfere with other systems or only slightly interferes with them. Optionally, an electronic fuse in such switch-off conditions switches off the circuit breaker faster than within 1 μs and thereby opens it. The disconnection can also depend on the time derivative of the voltage change (dU/dt sensitivity.)

### Accident Protection

Optionally, the higher-level computer system switches off supply sub-networks that are not needed or are dangerous by means of electronic fuses via corresponding commands to electronic fuses via the data bus if a higher-level computer system of the vehicle has come to the conclusion that an accident of the vehicle is likely. This is therefore the shutdown of systems of the vehicle by means of one or more electronic fuses before a predicted accident, wherein the determined probability for such an accident should be above a threshold value.

### Expecting a High Current Consumption

Similarly, a higher-level computer system, for example a controller, can open one or more circuit breakers of one or more electronic fuses of one or more sub-trees of the supply network via a data bus if, for whatever reasons, this higher-level computer system also ever expects an increased current consumption of a different device. As a result, the switched-off electrical loads are omitted, and their now unused power margin for the overall energy budget is now available to this other device with expected increased current consumption. This is therefore a preventive shutdown of electrical loads if a high power consumption of the other device is expected.

### Shutdown of Systems According to Voltage Level

The disclosure proposes that the electronic fuses detect the voltage between a first terminal of the circuit breaker, which is optionally on the power-source side, and a reference potential by means of suitable measuring means. Because in the design of the vehicle it is generally already known which loads the supply network supplies with electrical power, the function of these loads and the importance of this function, and via which supply line of which electronic fuse the supply takes place, it makes sense for the control devices of the electronic fuses to compare the measured voltage values to predefined threshold values and to open the circuit breaker of the electronic fuse when these threshold values are undershot. This results in a disconnection of electrical loads of the vehicle depending on the voltage level. The vehicle then optionally operates only the necessary systems at very low voltage levels. As a result, the vehicle can provide the minimum functionalities up to the last second in which a minimum of power is still present.

### Limiting the Voltage Sag

An important requirement is the limitation of a voltage sag. This is done through the speed of the switch-off process of the circuit breaker of the electronic fuse. In an electronic fuse with voltage tripping, this disconnection takes place in the range of μs.

### Fuse Data Bus in Electric Cars

Electric cars nowadays typically use supply networks with voltages less than 50 V (LV networks) and supply networks with voltages greater than 50 V (HV networks). A problem arises in that the electronic fuses should be able to communicate via data buses across the domain boundaries of the LV networks and the HV networks. If no optical data buses are used, it is expedient to provide a data bus with galvanic isolation at the domain boundary between a HV supply network and an LV supply network, for example by means of transformers. It is then a fuse data bus with potential isolation between LV network and HV network.

### Cascading

The cascading of electronic fuses is particularly advantageous. This cascading enables, for example, the division of a supply line into different sub-supply lines. The more important loads are optionally arranged in the part of the supply line closer to the power source, while the less important loads are arranged in the part located further away from the power source. If one of the less important loads then fails and disturbs the power distribution via the supply line, an electronic fuse inserted into the supply line can disconnect this defective part of the supply line and thus continue to keep the other devices operative. More than one electronic fuse can reduce the number of loads unnecessarily shed. The disclosure thus discloses the concatenation of at least two or more electronic fuses. The advantage is that new designs in different sections of a supply line can provide thinner lines as supply lines. The necessary switch-off times of the electronic fuses can thus be different depending on the position of the electronic fuse. If the distance from the power source is further, the corresponding electronic fuse should switch off more quickly. Optionally, therefore, an adaptation to the switch-off characteristic of the corresponding electronic fuse to the position of this electronic fuse in the supply network takes place.

Electronic Fuse with Timer or Counter

The electronic fuse optionally comprises a timer or counter which, for example, enables the synchronization of measurements, as described above. Furthermore, the electronic fuse optionally also comprises elements for debouncing the electronic fuse.

### Kirchhoff Equations

Optionally, different electronic fuses determine at different locations in the supply network, for example, for current and/or voltage, as described above. Optionally, the control devices provide these measured values with a time stamp based on the counter value of an internal counter or an internal clock. Alternatively, the synchronization of these clocks is possible, and a higher-level computer system specifies for the control devices of the electronic fuses when the measurements have to be carried out. For example, small leakage currents from supply lines to other electrical nodes of the vehicle can be detected with such data.

Electronic Fuses without Computer Core

It is conceivable that not all control devices of all electronic fuses have a computer core. In other words, the computer core of a different electronic fuse then generally controls the control device of such a stripped-down electronic fuse without a computer core. Because the communication between the computer core of the controlling electronic fuse and the control device of the electronic fuse without a computer core can be lost, this stripped-down version of an electronic fuse without a computer core optionally has fail-safe properties which allow this electronic fuse to ensure at least basic protection of the connected supply line.

### Functional Signaling (Alive Signaling)

As already mentioned, it is expedient if the electronic fuses transmit a signal to a control device via a fuse data bus that may be present, which signal signals that a) the corresponding electronic fuse still exists and b) is ready for operation. This is what is known as live signaling on the fuse data bus.

It is advantageous if the fuse data bus is differentially designed. This results in increased robustness against a ground offset. In addition, polarity reversal resistance is useful in order to ensure robustness against negative voltage at the inputs and outputs of the control device. Exemplary data buses with such a common mode strength would be the PSI5 data bus and the LVDS data bus.

The fuse data bus optionally has so-called collision detection (bus collision detection) in order to detect bus collisions. The data bus protocol can also use a time-slice method for the bus arbitration for the operation of the data bus.

### Melting Fuse Simulation

The simulation of a melting fuse by the electronic fuse is particularly useful. This simulation is optionally based on a temperature energy simulation.

In the example of the above figure, an input amplifier detects the voltage drop across a shunt resistor which converts the current through the supply line into a measuring voltage. A downstream analog-to-digital converter converts this value into a digital signal. This value is then squared and then integrated. Further filters may follow. In the above example, a plurality of comparators compares the values to threshold values.

### Temperature Estimation of the Lines

As described above, the computer core of the control device of an electronic fuse optionally carries out a temperature estimation of the protected supply line.

### Quantum Random Number Generator

The quantum random number generator of the control device of the fuse, which the computer core of the fuse can address via the internal data bus, optionally has at least one first SPAD diode and at least one second SPAD diode and at least one optical waveguide. Such a quantum random number generator can also be located in the higher-level computer system of the supply network, for example. The quantum random number generator is optionally a quantum-process-based generator for true random numbers (QRNG). The quantum-process-based generator for true random numbers (QRNG) optionally comprises a first SPAD diode as a light source for an optical quantum signal and a second SPAD diode as a photodetector for the optical quantum signal. Furthermore, the quantum-process-based generator for true random numbers (QRNG) optionally comprises at least the processing circuit and the optical waveguide. The at least one optical waveguide optionally optically couples the at least one first SPAD diode to the at least one second SPAD diode. An operating circuit optionally in the form of said voltage supply supplies the first SPAD diode with electrical power in the manner that the first SPAD diode emits light. The emission of light requires that the voltage supply (operating circuit) provides sufficient electrical bias of the first SPAD diode. A processing circuit detects the signal of the second SPAD diode and forms the random number therefrom. The processing circuit then optionally provides via a data bus the random number formed in this way to one or more of the one or more computer cores of control circuits of fuses in the supply network and/or the higher-level computer system of the supply network and possibly further devices in the supply network and/or in the vehicle.

The control circuit of the fuse is optionally designed to be monolithic as a micro-integrated CMOS circuit. A semiconductor crystal, which is optionally a silicon crystal, optionally comprises the control circuit and possibly the shunt resistor for measuring the current through the auxiliary circuit breaker of the fuse.

The semiconductor crystal optionally has a surface. Typically, the semiconductor crystal has a semi-conducting material below its surface. Particularly when conventional semiconductor circuit manufacturing processes, such as CMOS processes, bipolar processes, and BiCMOS processes are used, the surface of the semiconductor crystal typically has a metallization stack as structured metal layers and electrical insulation layers. The structured metal layers, for example made of aluminum or copper or the like, typically form the conductor tracks which are electrically separated from one another by the optically transparent insulation layers, for example made of silicon dioxide or the like. Thus, the metallization stack has one or more typically structured and optically transparent and electrically insulating layers as insulation layers. At least a section of these typically structured, transparent and electrically insulating layers and at least parts of these layers of the surface optionally form the optical waveguide for optical connection of the first SPAD diode to the second SPAD diode. The first SPAD diode typically radiates light from the semi-conducting material of the semiconductor substrate into this optical waveguide. That is, in contrast to the prior art, the first SPAD diode usually radiates perpendicular to the surface of the semi-conducting material substantially upwardly and not to the side into the semiconductor substrate of the semiconductor crystal which has high attenuation. Nevertheless, the emission of the photons of the first SPAD diode in the optical waveguide is not directed. In particular, the emission via the substrate of the semiconductor material is highly attenuated, because visible light has a very high absorption in the semiconductor material. Due to the design with the optical waveguide in the metallization stack of the micro-integrated circuit, the device can couple more photons of the first SPAD diode directly to the second SPAD diode and radiate them into the second SPAD diode. The optical waveguide transports these photons of the first SPAD diode in the optical waveguide in a practically loss-free manner to the second SPAD diode compared to the prior art. The optical waveguide irradiates the second SPAD diode with these photons of the first SPAD diode in such a way that the light from inside the optical waveguide penetrates back into the semi-conducting material of the semiconductor substrate from out of the surface and there hits device parts of the second SPAD diode. The second SPAD diode then generates a received signal depending on the irradiation with these photons.

Typically, at least one operating circuit, i.e., the voltage supply of the control circuit of the fuse, for example, supplies the at least one first SPAD diode with electrical power at least temporarily. When supplying sufficient electrical power, the at least one first SPAD diode then feeds photons into the at least one optical waveguide. The optical waveguide then further transports these photons. The at least one optical waveguide then radiates the transported photons as photons moving substantially perpendicularly into the second SPAD diode. Because this transport of the photons from the first SPAD diode 54 to the second SPAD diode loses significantly fewer photons due to the low attenuation in the optical waveguide than in the design from the prior art, which uses the strongly absorbing semiconductor substrate, the quantum efficiency is massively higher. This increases the bit rate at which the device can generate random numbers. Therefore, in the design presented here, a pair made up of a single first SPAD diode and a single second SPAD diode is already sufficient. The prior art always uses a plurality of SPAD diodes.

### Secure Software Download

The disclosure also describes a system for a vehicle which makes it possible to execute SW programs, in particular SW programs of third-party providers, in a secure manner in the supply network of the vehicle, namely in the electronic fuses of the supply network. Furthermore, the disclosure relates to a method for executing SW programs in these electronic fuses.

When integrating a SW program in the control device of the fuse of a supply network and/or in the higher-level computer system of the supply network of a vehicle, it must be ensured that the safety of the supply network is not impaired by the SW program. On the other hand, it may be necessary to protect at least parts of the SW program (e.g., parts with confidential information, such as billing data, activation codes, encrypted program commands, and encrypted configuration and access data) from impermissible reading and/or writing accesses. These requirements can lead to a relatively high integration effort.

The present document therefore also deals with the technical object of providing a system and a method which enable flexible and secure integration of SW programs in control devices of fuses of a supply network and/or a higher-level computer system of a supply network of a vehicle.

The disclosure describes a system for providing an application by means of a SW (software) program in a supply network. The application can be designed, for example, to network the vehicle with a server 710 of a service provider and/or with an electronic device (e.g., a smartphone) outside the vehicle via the higher-level computer system of the supply network or a different data interface in the supply network. Furthermore, the application can be designed to automatically integrate the supply network and/or supply sub-networks into a service (e.g., activation of special loads, etc.). The SW program can thereby be provided by a server 710 of a service provider for the corresponding service/equipment variant of the vehicle.

The system comprises a first HW (hardware) platform and a second HW platform. In this case, the first HW platform and the second HW platform can comprise separate computers for providing particularly reliable isolation between the two HW platforms. For example, the first HW platform can be part of a higher-level computer system of the supply network of the vehicle. On the other hand, the second HW platform can be separated from the higher-level computer system of the vehicle, in particular from an operating system of the higher-level computer system of the supply network. Typically, the second HW platform is a control device of a fuse of the supply network.

Alternatively, or additionally, the second HW platform can comprise a non-volatile memory (e.g., for storing data) and/or a volatile memory (e.g., for operating a SW module) that is separated from the first HW platform. Furthermore, the memory of the second HW platform, i.e., the control device of the fuse, can be protected by means of one or more safety measures. In this case, the memory of the control device of the fuse can be protected by one or more safety measures which are not used to protect the first HW platform. The memory (both the “runtime” memory and the “storage” memory) of the second control device of the fuse can be protected by one or more safety measures in such a way that the memory cannot be manipulated from the outside (or from an unsecure application).

The control device of the fuse is subject to one or more safety measures to which the first HW platform is not subject. The one or more safety measures can, for example, comprise a check of SW code of a SW module which is executed on the control device of the fuse by the computer core of the control device. In particular, the SW code can be checked by a manufacturer of the vehicle and/or by a unit of the control device of the fuse separate from the provider of the SW program. It can thus be ensured that no safety-relevant data is released by a SW module on the control device of the fuse and/or no safety-relevant function (of the supply network) is impaired. Alternatively, or additionally, the one or more safety measures can comprise a limitation of data which can be transferred to a SW module or from a SW module which is executed on the control device of the fuse. The flow of data to the control device of the fuse and/or from the control device of the fuse can thus be limited.

The SW program comprises at least one base module and at least one safety-relevant module. The safety-relevant module accesses safety-relevant data and/or a safety-relevant function. On the other hand, the base module typically does not access safety-relevant data and/or a safety-relevant function or accesses it only via defined interfaces. The SW program can thus be divided into one or more safety-critical parts and into one or more safety-uncritical parts.

The base module (i.e., the one or more safety-uncritical parts) can then be executed on the first HW platform, and the safety-relevant module (i.e., the one or more safety-critical parts) can be executed on the control device of the fuse.

The system thus makes it possible to provide SW programs for applications in a supply network of a vehicle in a reliable, safe, and efficient manner.

The at least one safety-relevant module (i.e., the one or more safety-critical parts) optionally comprises 20%, 10% or less of the SW code of the SW program and the at least one base module (i.e., the one or more safety-uncritical parts) optionally comprises 80%, 90% or more of the SW code of the SW program. The one or more safety measures can thus be implemented in an efficient manner with respect to the control device of the fuse.

The first HW platform is optionally designed in such a way that a SW module (i.e., a base module) executed on the first HW platform does not have access to a safety-relevant function of the supply network or has access to it only via a defined interface. On the other hand, the control device of the fuse is optionally designed such that a SW module executed on the control device of the fuse has access to a safety-relevant function of the supply network. A reliable execution of SW programs in the supply network can thus be enabled in a reliable manner.

The base module can be configured, when the SW program is executed, to call up the safety-relevant module and to initiate an execution of the safety-relevant module on the control device of the fuse. In the execution of the SW program, data can be transferred from the base module to the safety-relevant module. Furthermore, data can be transferred from the safety-relevant module to the base module. The safety-relevant module can have a standardized interface via which the data can be transferred to the safety-relevant module or from the safety-relevant module. A secure execution of SW programs by external SW providers can thus be enabled in a control device of the fuse. In particular, the mixing of fuses of different manufacturers in the supply network of a vehicle is thereby possible.

According to a further aspect, a method for executing a SW program in a supply network is described. The method comprises executing a base module of the SW program on a first HW platform, for example the higher-level computer system of the vehicle. In addition, the method comprises calling up, from the base module, a safety-relevant module of the SW program, wherein the safety-relevant module accesses safety-relevant data and/or a safety-relevant function. The method further comprises executing the safety-relevant module on a control device of the fuse of the vehicle, wherein the control device of the fuse is subject to one or more safety measures to which the first HW platform is not subject.

According to a further aspect, a vehicle (in particular a road motor vehicle, for example a passenger car, a truck, or a motorcycle) is described which comprises the supply network described in this document.

As explained at the outset, the present document deals with the flexible and secure integration of SW programs for different applications on an HW platform of a vehicle.

An SW program for an application can be installed, for example, on a smartphone of a user, and the smartphone can be connected to the vehicle via a data connection. On the other hand, an SW program can be installed and executed directly on a controller (e.g., the head unit) of a vehicle. These two options are associated with disadvantages. For example, it may be undesirable for a user to install software from possibly unknown providers on a personal smartphone. On the other hand, the direct integration of SW programs on the higher-level computer system of a vehicle typically requires high integration expenses. In this case, complete control and/or checking of the installed SW is in some cases not possible due to the high complexity. Furthermore, the safety of data from a SW program may in some cases not be sufficiently safeguarded within a head unit.

It is therefore proposed to provide a trusted environment (i.e., a secure ecosystem) for third-party software in a vehicle. By providing such a trusted environment, it can be ensured to an external provider of a SW program that safety-relevant parts of the SW program (e.g., cryptographic keys) are protected from access. Furthermore, it can be ensured in an efficient manner that a SW program of an external provider does not impair the safety of the vehicle.

### Fire Protection

In the event of a failure of the power transistor 17, the power transistor 17 is no longer switchable and can continue to be conductive with a non-negligible residual resistance. If the load is, for example, a resistive load, which, even in the event of a reduction in voltage, does not ever or does not yet switch off for whatever reason, a high power can be implemented in the circuit breaker 17. This can lead to plasma development and/or to a fire. This is possible in particular if, for whatever reasons, combustible impurities are also in contact with the circuit breaker and/or the then typically heated safety housing 535.

The disclosure therefore proposes an electronic fuse 1 comprising a first terminal 18 and a second terminal 19 and comprising a circuit breaker 17) with a first terminal (26) of the circuit breaker 17 and comprising a second terminal 28 of the circuit breaker 17. The circuit breaker 17 is thereby electrically connected by its first terminal 26 to the first terminal 18 of the electronic fuse 1 and by its second terminal 28 to the second terminal 19 of the electronic fuse 1. A thermal protection 5710, 5740 is now inserted into the current path between the first terminal 18 of the fuse 1 and the second terminal 19 of the fuse 1 for additional protection. According to the proposal, the thermal protection 5710, 5740 interrupts the current path between the first terminal 18 of the fuse 1 and the second terminal 19 of the fuse 1 if the temperature of the circuit breaker 17 and/or the temperature within the housing 535 of the fuse 1 and/or the temperature of the housing 535 of the fuse 1 exceeds a switch-off temperature. The protection can be a temperature fuse 5740) or a temperature switch 5710, wherein a temperature fuse 5740 is preferred, because it does not switch back on after being triggered. The fuse has a temperature path of action 5720 between the circuit breaker 17 and the protection 5710, 5740 with a optionally low thermal resistance, so that the temperature of the circuit breaker 17 can change a switching state of the protection 5710, 5740, so that an overtemperature leads to the switching off of the protection 5710, 5740. This temperature path of action can be, for example, a direct thermal contact between the circuit breaker 17 and the temperature switch 5710 and/or a thermal bridge in the form of a common heat sink or the like.

The proposed fuse 1 optionally comprises a control device 4 which detects the switching state of the protection 5710, 5740, for example by means of a temperature switch/thermal fuse monitoring device 5750 of the control device 4.

The control device 4 optionally signals a detected state of the protection 5710, 5740 (e.g., closed/open) and/or data derived from these data, in particular alarms, to a higher-level computer system 12 and/or the server 710 of a service provider, and/or the server 710 of an automobile manufacturer or the like, or to a terminal 740 of a user 730 and/or to a terminal 740 of the fire department or a server 710, the fire department or similar rescue services via a data bus of the supply network 200 of which the electronic fuse 1 is a part, wherein this signaling of other computers in the signaling path can in some cases be modified.

The supply network 200 and/or the fuse can, for example, be part of a vehicle in relation to this idea of fire protection by means of an additional protection 5710, 5740.

For example, a computer core 2 of the control device 4 of a fuse 1 in the supply network 200 and/or a higher-level computer system 12 in the supply network 200 and/or a different computer in said vehicle can determine the position of the supply network or of the vehicle by means of a position detection system, for example by means of a GPS sensor, and/or different information present in the supply network. This computer core 2 of the control device 4 of that fuse 1 in the supply network 200, and/or the higher-level computer system 12 in the supply network 200, and/or the aforementioned other computer in the said vehicle can then signal this position information to the higher-level computer system 12 and/or the server 710 of a service provider and/or the server 710 of the automobile manufacturer or the like or to the terminal 740 of the user 730 and/or to the terminal 740 of the fire department or to the server 710 of the fire department or to similar rescue services, as described above.

### Data Compression

As described above, it is conceivable that the control device 4 transmits the sampling values of physical parameters of the fuse 1 directly to the higher-level computer system 12 via the data bus 9. Within the meaning of the disclosure, such physical parameters of the fuse 1 can, for example, be voltage values at node pairs of nodes, which the control device 4 can detect, for example, by means of its analog-to-digital converter 570. Within the meaning of the disclosure, such physical parameters of the fuse 1 can, for example, be values of the currents (32, 24) which the control device 4 can detect, for example, by means of its analog-to-digital converter 570 in line sections within and/or outside the fuse 1. Particularly optionally, the control device 4 of the fuse 1 should transmit not only individual sporadically detected values of these physical parameters of the fuse 1, but also their time characteristics to the higher-level computer system 12. This enables the higher-level computer system 12 to identify faults such as short circuits 1510 or arcs between different line sections 1505, 1905 by correlating two signal characteristics of different fuses 1975, 1980, 825, within a supply network 1900 (see FIG. 19).

A further idea of the disclosure is therefore that the control device 4 of the fuse 1 detects one or more temporal signal characteristics of one or more physical parameters, optionally within a time sampling window in a first step as a data set of sampling values of the values of this physical parameter within this time sampling window. The sampling window has a temporal start and a temporal end. After detection of the time characteristics of the physical parameters in question to be transmitted in the first time sampling window, the control device 4 of the fuse detects the temporal signal characteristics of the physical parameters optionally within a subsequent further time sampling window in a new first step as a further data set of sampling values of the values of this physical parameter in this further time sampling window. Optionally, the control device 4 of the fuse continues with the detection of the sampling windows, sampling window by sampling window, so that the control device 4 of the fuse 1 detects the corresponding time characteristic of the corresponding physical parameters which the fuse detects more or less quasi-continuously. The sampling windows can be selected specifically for the corresponding physical parameter. In this case, the control device samples the value of the corresponding physical parameter at a sampling rate which typically depends on a clock pulse of the control device 4 of the fuse. The sampling rates of different physical parameters can be different. The sampling rates can depend on the state of the fuse 1 and/or on states in the supply network 1900 (see FIG. 19). It is possible for the temporal end of the preceding time sampling window to be essentially the same as the temporal beginning of the further, subsequent time sampling window. The immediately preceding sampling window optionally overlaps with the subsequent sampling window by a temporal overlap length. This temporal overlap length is optionally substantially the same for all sampling windows of the sampling of the value characteristic of a physical parameter. Optionally, the control device 4 of the fuse 1 transmits the value of the temporal overlap length to a higher-level computer system 12 or the higher-level computer system 12 transfers to the control device 4 of the fuse 1 via the data bus 9 the value of this temporal overlap length by means of a data message. Temporal overlapping lengths that are negative (=gaps between the sampling windows) or zero are possible. Temporal overlapping lengths that are positive are preferred. The control device 4 optionally stores the detected sampling values of the time characteristics of the value characteristics of the physical parameters in a memory of the control device 4 during this first step.

According to the further idea of the disclosure, in a second step, the control device 4 of the fuse 1 compresses the sampling values of the time characteristics to be transmitted of the physical parameters detected by the control device 4 to form compressed signal characteristics.

In a third step, the control device 4 of the fuse 1 optionally transmits one or more of these compressed signal characteristics to a higher-level computer system 12.

In a fourth step, the higher-level computer system 12 optionally decompresses the one or more compressed signal characteristics received from the control device 4 of the fuse 1 via the data bus 9 to form one or more decompressed signal characteristics.

In a fifth step, the higher-level computer system 12 optionally analyzes one or more decompressed signal characteristics in a fifth step and generates an analysis result.

In a sixth step, the higher-level computer system 12 adopts measures or no measures depending on the analysis result. The measures can relate to different levels of measures.
i) At the lowest level if the analysis result discloses no events or only insignificant events, no measure takes place. On a further exemplary level of measure if the analysis result discloses insignificant events which should, however, be kept ready for analysis purposes, the higher-level computer system 12 stores the analysis result in a memory or the like, for example in a log file, optionally with a time stamp, and in this way optionally keeps the analysis result on hand for a later query and/or evaluation.
ii) At a further exemplary level of measure, if the analysis result discloses events that need to be reported and which should be analyzed centrally for a plurality of supply networks, for example a plurality of vehicles, the higher-level computer system 12 optionally first of all stores the analysis result in a memory or the like, for example in a log file, optionally with a time stamp, and in this way optionally keeps on hand the analysis result for a later query and/or evaluation, and, secondly, the higher-level computer system 12 optionally transmits the analysis result, optionally with a time stamp, to a human-machine interface of a terminal 740 for appropriate display and/or output in a form that is discernible by humans, for example to the indicator of a dashboard of the vehicle, so that the user 730 of the vehicle is aware of the analysis result of the higher-level computer system 12 and can possibly carry out measures.
iii) At a further exemplary level of measures, if the analysis result discloses events that need to be reported and which should be analyzed centrally for a plurality of supply networks, for example a plurality of vehicles, the higher-level computer system 12 optionally first of all stores the analysis result in a memory or the like, for example in a log file, optionally with a time stamp, and in this way optionally keeps on hand the analysis result for a later query and/or evaluation, and, secondly, the higher-level computer system 12 optionally transmits the analysis result in, optionally with a time stamp, via a data connection 720 to a server 710, for example of a vehicle manufacturer, which server in this way optionally keeps the analysis result on hand for a subsequent query and/or evaluation via the data of a plurality of supply networks.

In the following, the disclosure now explains possibilities for compressing the temporal value characteristic of the physical parameters. A first possibility is the reduction of the volume of data by omitting sampling values depending on the physical parameter. Optionally, the control device 4 of the fuse 1 then transmits the sampling values of these physical parameters together with a time stamp to the higher-level computer system 12 of the supply network 1900. Another possibility for compression is the reduction of the bit width of the sampling values. A means for reducing the bit width is that the control device, instead of all bits of a sampling value of a physical parameter, transmits only the significant bits of the sampling values of this physical parameter. These are typically the bits that generally showed any change at all in the logic value of this bit in the test phase of the fuse and/or of the safety type and/or of the supply network and/or of the supply network type and/or of the vehicle and/or of the vehicle type. It is also unnecessary to transmit bits of which the bit change would never result in the need to initiate a measure via the higher-level computer system 12 in the test phase of the fuse and/or of the fuse type and/or of the supply network and/or of the supply network type and/or of the vehicle and/or of the vehicle type, and with which, due to theoretical considerations, such a need for a measure of the higher-level computer system 12 can be reliably ruled out due to a bit change of the relevant bit. This can relate, for example, to LSB of the conversion result of the analog-to-digital converter 570 of the control device 4 of the fuse 1, which can in some cases only show irrelevant noise.

A further idea of the technical teaching of the disclosure is that the control device 4 of the fuse 1 changes the compression method and adapts to the necessary precision if the control device 4 of the fuse or the higher-level computer system 12 of the supply network 1900 also always detects the need for a compression with lower information loss for whatever reasons. For example, the method and/or the degree of this compression can depend on the state of the fuse 1 and/or on the state of other fuses in the supply network 1900 and/or on parameter values and/or temporal parameter value characteristics of physical parameters which the fuse 1 or other fuses in the supply network 1900 detect. Exemplary parameters that detect the control device 4 of the electronic fuses 1 in the supply network 1900 are mentioned by the technical teaching of this document at various points of the description.

A further proposed compression method is compression by reduction of the temporal parameter characteristic of a physical parameter detected by the control device 4 of the fuse 1 to form predefined parameter characteristics. These can be wavelets, for example. The disclosure thus proposes that the control device 4 of the fuse 1 carries out the detection of structures in the temporal parameter value characteristic of these parameters or other events with the aid of that which is already in the fuse 1. The disclosure mentions these structures in the parameter value characteristic of the detected parameters in the following objects. For example, such an object can be a triangular signal characteristic with which a spike resulting from an arc can be modeled. Such a triangular object has a time position, width, and height, which characterize the triangle. The advantage is that the control device then only has to transmit the type of object—in this case a triangle—and its parameters—in this case position, width and height—to the higher-level computer system 12 in order to enable the higher-level computer system, in a reconstructed parameter value characteristic, to approximate the parameter value characteristic of this parameter in the temporal range of this object by means of such an object parameterized corresponding to the object parameter data received by the fuse 1. The control device 4 of the fuse transmits these object data (object type, and object parameters) after detection of the objects to the higher-level computer system 12. In the context of the development of the technical teaching of the disclosure, the inventors have recognized that synergy effects when using the data of a plurality of fuses would be lost if the higher-level computer system 12 were to always analyze only the data of one fuse by itself. Rather, the inventors have recognized that it makes sense that it is not advantageous for the control device 4 of the fuse 1 to transmit only the evaluation results of the parameter characteristics of the detected parameters, but instead to evaluate all data, and only to evaluate the data of a plurality of control devices 4 of a plurality of electronic fuses 1 in the higher-level computer system 12. For this purpose, however, the compression of the data of the electronic fuses for transmission via the data bus 9 with a lower bus bandwidth is optionally carried out differently only by bit reduction and sampling rate adaptation. As a result, the proposed supply network 1900 can then develop synergy effects. For example, it is conceivable that a vehicle has more than one electronic fuse 1 in its supply network 1900. In contrast to the prior art, however, both fuses are now intended to have mutually correlating objects in the parameter characteristics of the physical parameters detected by the control devices 4 of these fuses 1. These then indicate events that relate both to the supply line protected by the one of the two fuses and to the other supply line protected by the other fuse. For example, these can be arcs between the supply lines. A supply line within the meaning of the disclosure can also be the body of a vehicle. Optionally, the power is drawn from the reference potential line 201, i.e., for example, the body of a vehicle, within the meaning of the disclosure, by its own electronic fuse 1. Optionally, the control devices 4 of the two fuses each detect, for example, one or more parameter characteristics of one or more physical values and/or values derived therefrom. The control devices 4 of the two fuses optionally each detect, for example, the same, one parameter value characteristic or the same plurality of parameter value characteristics of one or more physical values and/or values derived therefrom in the same time sampling windows. The control devices 4 of the two fuses optionally transmit the detected one or more parameter characteristics of one or more physical values and/or values derived therefrom in compressed form to the higher-level computer system 12 as one or more compressed parameter characteristics. The higher-level computer system 12 decompresses the one or more compressed parameter characteristics received from the control devices 4 of the fuses 1 via the data bus 9 to form one or more reconstructed, i.e., decompressed, parameter characteristics. Only after reconstruction (decompression), the higher-level computer system 12 performs the detection of the states of the supply network 200, 1900 and/or the incidents in the supply network 200, 1900. This also enables the fuse data thus obtained (reconstructed parameter value characteristics) to be fused with the parameter value characteristics of further sensors and sensor systems, which transmit data directly or indirectly via data buses, data transmission paths, and/or the data bus 9 to the higher-level computer system 12. For example, a sensor fusion can appear such that the higher-level computer system 12 correlates the time characteristics of value characteristics of parameters that detect further sensors and sensor systems with reconstructed parameter value characteristics of control devices 4 of fuses. For this purpose, the higher-level computer system 12 interpolates missing sampling values on the basis of valid sampling values of the reconstructed parameter value characteristics to form interpolated, reconstructed parameter value characteristics. Furthermore, on the basis of valid sampling values of the value characteristics of those parameters that the further sensors and sensor systems detect, the higher-level computer system 12 interpolates interpolated value characteristics of those parameters that the further sensors and sensor systems detect. At least one sampling value of the interpolated value characteristics of those parameters that the further sensors and sensor systems detect optionally corresponds in time to each sampling value of the interpolated, reconstructed parameter value characteristics. As a result, the higher-level computer system 12 can search correlations in the form of conspicuous, typically more or less synchronous events both in the reconstructed parameter value characteristics and in the value characteristics of those parameters that the further sensors and sensor systems detect. For example, mechanical defects of mechanical devices—e.g., electric motors—can become noticeable in acceleration values—e.g., vibrations, torque vibrations, etc.—and at the same time in corresponding fluctuations of currents 29, 36 through the electronic fuses associated with these mechanical devices. (See also FIG. 59). In this context, the disclosure points to the document by Wolfgang Koch, “Tracking and Sensor Data Fusion: Methodological Framework and Selected Applications (Mathematical Engineering),” Springer 1st ed. 2014 Edition (Aug. 23, 2016) ISBN-10: 3662520168, ISBN-13: 978-3662520161 as an arbitrary example from the vast amount of publications on sensor fusion.

The disclosure thus proposes a method for transmitting fuse data from a control device 4 to a higher-level computer system 12 via the data bus 9. The method is particularly suitable for the use of transmitting data of a temporal parameter value characteristic from a control device 4 of a fuse 1 to a controller as a higher-level computer system 12 of a supply network 1900 in a vehicle.

The method is explained with reference to FIG. 60.

According to the proposed method, in a first step 6010 a control device 4 of a fuse 1 closes the circuit breaker 17 of the fuse 1.

In a second step 6020, the control device 4 of the fuse detects the physical parameter to be detected by first means which, for example, can comprise the analog-to-digital converter 570 of the control device 4 and/or the shunt resistor 24 and/or the auxiliary circuit breaker 23. The physical parameters to be detected can comprise, for example, voltages between circuit nodes within and outside the fuse 1 and/or electrical currents through lines within the fuse 1 and/or temperatures in the fuse 1 and/or in the surroundings thereof.

In a third step 6030, the control device 4 of the electronic fuse 4 then analyzes and compresses the temporal parameter value characteristic of the detected physical parameter that is detected in this way in order to minimize the data bus capacity of the data bus 9 that is necessary for the data transmission and to provide free space for status messages and further control commands of the higher-level computer system 12 to the control device 4 of the fuse 1 or for status messages and further data transmissions of the control device 4 of the fuse 1 to the higher-level computer system 12.

In a fourth step 6040, the control device 4 of the electronic fuse 1 then transmits the compressed, detected temporal parameter value characteristic of the physical parameter to be signaled to the higher-level computer system 12 via the data bus 9.

In a fifth step 6050, the higher-level computer system 12 decompresses the compressed, detected temporal parameter value characteristic received from the control device 4 of the fuse 1 via the data bus 9 to form a decompressed, detected temporal parameter value characteristic, which is ultimately a reconstructed, detected temporal parameter value characteristic that is associated with the control device 4 of the fuse 1 within the higher-level computer system 12.

In a sixth step 6060, the higher-level computer system 12 compares and/or correlates the reconstructed, detected temporal parameter value characteristic which is associated with the control device 4 of the fuse 1 within the higher-level computer system 12 to one or more other reconstructed, detected temporal parameter value characteristics which are associated with the control devices 4 of other fuses 1 within the higher-level computer system 12. In this case, the higher-level computer system 12 optionally detects events which can be attributed to the same causes optionally in temporal correlation.

In a seventh step 6070, the higher-level computer system 12 then, if necessary, adopts measures depending on the events detected.

The associated method thus serves to transmit parameter value characteristic data, in particular of a control device 4 of a fuse 1, from a control device 4 of a fuse 1 to a higher-level computer system 4 of a supply network 1900, 200, in particular in a vehicle.

In said second step 6020, the control device 4 of the electronic fuse, by said means and optionally time-discrete sampling based on a clock pulse of the control device 4 of the electronic fuse 1, optionally detects two or more temporal parameter characteristics of two or more physical parameters in the detection range of the fuse 1 in said time sampling window. The detection range of a physical parameter means here that the fuse can detect values of the relevant physical parameter.

In said third step 6030, the control device 4 of the electronic fuse optionally analyzes and compresses the two or more detected temporal parameter value characteristics and forms therefrom one or more compressed temporal parameter value characteristics.

The disclosure thus proposes to detect the temporal parameter characteristics of two or three or a plurality of temporal parameter characteristics or the time characteristics of temporal parameter characteristics derived therefrom and to transmit them to the higher-level computer system in compressed form.

The control device 4 of the electronic fuse 1 optionally converts the electrical analog signals-which are generated by the means for detecting the physical parameters (e.g., temperature sensors 586 for detecting the temperature, shunt resistors 24 for detecting electrical currents 36, potential lines for detecting electrical potentials, analog-to-digital converters 570, etc.), by sampling in a first sub-step 6021 of the second step 6020 (see FIG. 61)—into sampled temporal parameter value characteristics, which comprise a time-discrete flow of sampling values of the parameter values of the relevant physical parameter and any associated time stamps of these sampling values. Typically, the control device 4 of the fuse 1 optionally assigns to each sampling value and/or each of the sampling values a sampling instant as a time stamp of this sampling value at optionally equal time intervals.

In a second sub-step 6022 of the second step 6020, the control device 4 of the fuse can, for example, carry out a wavelet transform or another compression method and convert the sampled temporal parameter value characteristics into compressed temporal parameter value characteristics.

For this purpose, the control device 4 of the fuse 1 can compare the detected parameter value characteristics of the physical parameters and/or parameters derived from these derived time characteristics to predetermined parameter value characteristic basic forms, which are stored, for example, in a library in a prototype database 62115 in a memory of the control device 4 of the fuse, by forming a correlation integral (see also Wikipedia regarding this term) between the predetermined parameter value characteristic basic forms on the one hand and, on the other hand, the detected parameter value characteristics of the physical parameters and/or the parameters derived from these derived time characteristics. The disclosure refers to the predetermined parameter value characteristic basic forms in the following also as “signal object classes.” These prototypical parameter value characteristics of the physical parameters and/or the parameters derived from these derived time characteristics are optionally stored as prerecorded sampling values as a prototype-specific data set (prototype data) of the parameter value characteristic basic forms in said library—i.e., a prototype database 62115—in a memory of the control device 4 of the fuse 1 for optionally each individual signal object class. An individual prototype-specific index value is optionally associated with such an entry of the library, i.e., the prototype data of the signal object class, which index value is used only once in the entire prototype database 62115 and thus uniquely identifies the signal object class and the associated data set of the prerecorded sampling values. By forming the correlation integral between the predetermined prerecorded sampling values of the prototype-specific data sets (prototype data) of the parameter value characteristic basic forms on the one hand and the detected parameter value characteristics of the physical parameters and/or the parameters derived from these derived time characteristics on the other hand, the control device 4 of the fuse 1 optionally determines associated spectral values of this prototypical signal object class for each of these prototypical signal object classes. Because this continuously takes place sampling window by sampling window, the spectral values themselves represent a flow of time-discrete instantaneous spectral values, wherein the control device 4 of the fuse 1 optionally in turn assigns a time stamp to each spectral value.

The method described above of storing the sampling values in the prototype database 62115 has the disadvantage that the required size of the prototype database 62115 can very quickly overwhelm the size of the physically or commercially realizable memory in the control device 4. It is therefore useful to compress this prototype database 62115 by means of so-called “feature vectors.” This does not include the time characteristics of the parameter values, but instead the feature vectors that correspond to them. The disclosure explains this compression of the prototype database 62115 and the uses thereof in more detail below.

An alternative but mathematically equivalent method is the use of one matched filter, better a plurality of matched filters per predetermined signal object class (signal basic form) by the control device 4 of the fuse. In a first sub-step 6031 of the third step, the matched filters of the control device 4 of the electronic fuse 1 analyze the temporal parameter value characteristic of the parameters detected by the control device 4 of the electronic fuse 1 and/or of the time characteristic of parameters derived therefrom. Optionally, each matched filter forms a value in each case of a vector component of a current feature vector.

These matched filters are optionally device parts of the control device 4 of the fuse 1 or are emulated by device parts of the control device 4 of the fuse, for example the computer core 2 of the control device 4 of the fuse 1. Because the control device 4 of the fuse 1 generally has a plurality of prototypical signal object classes in its memory and uses them for the compression, and can also be subjected to different temporal spreads (see also “wavelet analysis”), this typically results in a time-discrete flow of multidimensional vectors of spectral values of different prototypical signal object classes and their different corresponding temporal spreads, which optionally comprises the current feature vector as vector components. Optionally, the control device 4 of the fuse 12 in turn assigns a time stamp to each of these multi-dimensional current feature vectors as part of the current feature vector, which the control device 4 of the fuse 1 generates in a comprehensible and optionally known manner for the higher-level computer system 12. Each of these multidimensional vectors is a so-called feature vector. (See also Wikipedia, https://de.wikipedia.org/wiki/Mustererkennung”.) This is therefore a time-discrete flow of feature vectors. In the context of the disclosure, the last feature vector generated by the control device 4 of the electronic fuse is the current feature vector. The control device 4 of the fuse optionally assigns to each of these feature vectors in turn the corresponding time stamp in a second sub-step 6032 of the third step 6030. The current feature vector can comprise, for example, spectral values as vector components.

Due to the fact that the control device 4 of the fuse 1 continuously shifts the sampling windows over time, a time dimension thus also results. As a result, the control device 4 of the fuse 1 can in some cases can also supplement the current feature vector with values of the feature vectors of the past that are no longer current or values that depend thereon. Values of the no longer current feature vectors of the past or values that depend on these can be, for example, temporal integrals or derivatives or filter values of one or more of these values, etc. As a result, the control device 4 of the fuse 1 can further increase the dimension of these feature vectors within the feature vector data stream. In order to keep the effort minimal in the following, the limitation to a few prototypical signal object classes during the extraction of the current feature vectors from the detected parameter value characteristics of the physical parameters and/or the parameters derived from these derived time characteristics is therefore helpful.

Thus, the control device 4 of the fuse 1 can then use, for example, the said matched filters in order to continuously monitor the occurrence of the prototypical signal object classes in the detected parameter value characteristics of the physical parameters and/or in the parameters derived from these derived time characteristics. Information on matched filters can be found, for example, under Wikipedia, “https://de.wikipedia.org/wiki/Optimalfilter”.

As particularly simple prototypical signal object classes, the disclosure indicates, by way of example, a temporal parameter value characteristic in the form of an isosceles triangle and a parameter value characteristic in the form of a dual peak in order to specify the concept. When matched filters or the like are used, a prototypical signal object class generally consists of a predefined spectral coefficient vector as part of the current feature vector, i.e., a predetermined prototypical feature vector. In this case, the feature vector optionally comprises a plurality of values as vector components, wherein each of the corresponding values of the spectral coefficient vector within the current feature vector is typically the value of a corresponding spectral coefficient, which then determines a corresponding matched filter associated with this corresponding spectral coefficient from the detected parameter value characteristics of the physical parameters and/or the parameters derived from these derived time characteristics.

The control device 4 of the electronic fuse 1 next determines the relevance of the spectral coefficients of a current feature vector of the detected parameter value characteristics of the physical parameters and/or the parameters derived from these derived time characteristics. For this purpose, the control device 4 of the electronic fuse 1 can determine, for example, the distance of the currently determined current feature vector from one of the prototypical feature vectors of the prototype database 62115 in a third sub-step 6033 of the third step 6030.

The prototype database 62115 optionally comprises re-indexed prototypical feature vectors. Each of these prototypical feature vectors of the prototype database 62115 corresponds to a feature vector that the previously described feature vector extraction generates in the second sub-step 6032 of the third step 6030 when the associated prototypical temporal parameter value characteristic and/or prototypical time characteristic of the parameter derived from these parameter value characteristics are presented to said database and to the matched filters of the control device 4 as an input. Thus, the values of the prototype database 62115 are ultimately compressed, prototypical temporal parameter value characteristics and/or compressed prototypical time characteristics of the parameters derived from these parameter value characteristics. Each of these prototypical time parameter value characteristics and/or prototypical time characteristics of the parameters derived from these parameter value characteristics in turn corresponds to one of the aforementioned signal objects, which the control device 4 of the fuse is intended to recognize in the current temporal parameter value characteristics and/or the current time characteristics of the parameters derived from these parameter value characteristics, wherein the control device 4 of the fuse 1 detects these current temporal parameter value characteristics and/or these current time characteristics of the parameters derived from these parameter value characteristics. Thus, the index, which the control device 4 of the fuse 1 has associated with a prototypical feature vector of the prototype database 62115, therefore in turn represents one of the aforementioned signal objects that the control device 4 of the fuse is intended to detect in the current temporal parameter value characteristics and/or the current time characteristics of the parameters derived from these parameter value characteristics of the physical parameters that the control device 4 of the fuse 1 detects. Thus, the index, which the control device 4 of the fuse 1 has associated with a prototypical feature vector of the prototype database 62115, therefore represents the corresponding prototypical temporal parameter value characteristic and/or the corresponding prototypical time characteristics of the parameters derived from prototypical parameter value characteristics of the physical parameters. Optionally, the control device 4 of the fuse 1 forms a Euclidean distance between the current feature vector, which is derived from the current temporal parameter value characteristics and/or the current time characteristics of the parameters from these parameter value characteristics of the physical parameters, on the one hand, and each prototypical feature vector of the prototype database 62115 on the other hand. Instead, for example, the control device 4 of the fuse 1 can also form the value of the corresponding scalar product square of each possible corresponding feature difference vector between the current feature vector, which is extracted from the current parameter value characteristics and/or the current time characteristics of the parameters derived from these parameter value characteristics of the physical parameters, on the one hand, minus correspondingly a prototypical feature vector of the prototypical feature vectors of the prototype database 62115 on the other hand. Optionally, the control device 4 of the fuse 1 uses this value of the corresponding scalar product square or a mathematically equivalent implementation as a distance in the further method. This has the advantage that the control device 4 of the fuse 1 does not have to form a square root. In addition, the control device 4 of the electronic fuse 1 can cancel the calculation if, in the summation of the squares of the individual vector components of the corresponding feature difference vector to form the scalar product square, an intermediate sum of these squares exceeds a threshold value. Such a prototype of the prototype database 62115 with the corresponding prototypical feature vector of the prototype database 62115 and the associated index for this prototypical feature vector in the prototype database 62115 then does not represent the current feature vector. In this way, the control device 4 of the fuse 1 then optionally searches the prototypical feature vector of the prototype database 62115 with the smallest distance between the prototypical feature vector of the prototype database 62115 and the current feature vector. The prototype database 62115 optionally also comprises prototypes in the form of prototypical feature vectors, which represent prototypical time parameter value characteristics and/or prototypical time characteristics derived therefrom from normal operation without special events.

In the example discussed here in this document, the vector components (values) of the current feature vector optionally comprise, among other things, the instantaneous spectral coefficients (feature vector). The control device can optionally approach the current feature vector by means of weighted vector sum formation from a plurality of prototypical feature vectors of the prototype database 62115, each multiplied by a corresponding associated real scalar weighting factor. Typically, the current feature vector can thus be regarded approximately as a combination of a plurality of prototypical feature vectors of said prototype database 62115. Each of these prototypical feature vectors of the prototype database 62115 represents a prototypical signal object class. The index of the prototypical feature vector of the prototype database 62115 of the control device 4 of the fuse in the prototype database 62115 thus represents this prototypical feature vector of the prototype database. The set of indices of the prototype database of which the feature vectors in weighted sum come particularly close to the current feature vector therefore represent a good compression of the current feature vector together with said weighting factors associated with these indices. Optionally, the control device 4 of the fuse 1 normalizes the spectral coefficients or the vector components of the current feature vector before the correlations with the prototypical feature vectors of the prototype database. However, this means that the control device 4 of the electronic fuse 1 optionally does not necessarily analyze the structure of the parameter value characteristics of the detected parameters that it has detected or of the time characteristics of the values of parameters derived therefrom and not the absolute amplitude. In the above-described distance determination, the control device 4 of the fuse 1 can determine the distance of the current feature vector from one of the prototypical feature vectors of the prototype database 62115, for example also from the sum of the amounts of all the differences between a spectral coefficient of the predetermined prototypical feature vector (prototypes or prototype vector) of the prototype database 62115, on the one hand, minus the corresponding normalized spectral coefficient or vector component of the current feature vector. In this case, even the squaring is dropped. It has been found that this further lowers the necessary computing power required by the control device 4 and typically leads to sufficient results. By contrast, the control device 4 of the fuse 1 would have to calculate a Euclidean distance using the square root from the sum of the squares of all differences between, respectively, a spectral coefficient or a vector component of the specified prototypical feature vector (prototypes or prototype vector) of the prototype database 62115 and the corresponding normalized spectral coefficient or the corresponding normalized vector component of the current feature vector. However, this calculation of distance is generally too complicated. It is also conceivable for the control device 4 to use other methods of distance calculation. The control device 4 of the electronic fuse 1 can then be associated with each predetermined prototypical feature vector (prototype or prototype vector) of the prototype database 62115 as a symbol for this prototypical feature vector and, in some cases, also a parameter, e.g., the previously determined distance value and/or the Euclidean length of the current feature vector before the normalization. If the distance of the current feature vector determined in this way to any of the predetermined prototypical feature vectors (prototypes or values of the prototype vectors) falls below a first threshold value and if the this distance is the smallest distance of the current feature vector to any of the predetermined prototypical feature vectors (prototypes or values of the prototype vectors), optionally of all predetermined prototypical feature vectors (prototypes or values of the prototype vectors) in the prototype database, then the index of this prototypical feature vector, hereinafter the detected prototypical feature vector, is used in the prototype database 62115 as a symbol of the detected prototype of one or more parameter characteristics of one or more physical parameters to be detected by the control device. A triple made up of detected prototypes in the form of a detected prototypical feature vector and the index of the detected prototypical feature vector in the prototype database 62115 and a time stamp of the current feature vector is thus produced. The control device optionally also determines the scalar product between the current feature vector and the detected prototypical feature vector as a weighting factor of the detected prototypical feature vector.

The data are then optionally transmitted in said fourth step 6040. Optionally, the control device 4 of the fuse 1 transmits the determined symbol-which represents the index of the detected prototypical feature vector in the prototype database 62115 of the control device 4 of the fuse 1—via the data bus 9 to the higher-level computer system 12. For example, the control device 4 of the fuse 1 can also transmit the instant of the occurrence (time stamp) of the detected prototypical feature vector in the flow of the extracted feature vectors to the higher-level computer system 12 via the data bus 9. For example, the control device can also transmit the weighting factor for this detected prototypical feature vector of the prototype database 62115 to the higher-level computer system 12, which describes the intensity with which the signal pattern corresponding to the detected prototypical feature vector was present in the signal characteristic of the parameter value characteristic of the parameters detected by the control device 4 of the fuse 1 or parameter value characteristics derived therefrom at the instant of pattern recognition.

Optionally, the control device 4 of the electronic fuse transmits the compressed values to the higher-level computer system 12 in the fourth step 6040 only if the distance of the detected prototypical feature vector of the prototype database 62115 is below the first threshold value for the current feature vector and the detected prototypical feature vector of the prototype database 62115 represents a signal object to be transmitted. Optionally, each data set for each one prototype in the prototype database 62115 of the control device 4 comprises not only the corresponding index and the corresponding prototypical feature vector, but in some cases further data. These data may, for example, comprise information as to whether the control device 4 of the fuse 1 when this prototypical feature vector is detected is intended to be transmitted to the higher-level computer system 12 in the current feature vector as a detected prototypical feature vector, inter alia, the aforementioned information (index, time stamp, weighting factor). It may be the case, specifically, that even prototypes which cannot be detected are stored in the form of prototypical feature vectors of the prototype database 62115 that cannot be detected, for example, for noise, i.e., for example, the presence of faults, fluctuations, short circuits, etc. in the prototype database 62115 of the control device 4 of the fuse 1. This data is typically irrelevant for the problem detection and is therefore not to be transmitted from the control device 4 of the fuse 1 to the higher-level computer system 12.

For example, data sets for a prototype in the prototype database 62115 of the control device 4 can each comprise not only the particular index and the particular prototypical feature vector, but possibly also pointers to program instructions and/or corresponding indices of measurement which cause the computer core 2 of the control device 4 to execute a method when a detected prototypical feature vector is detected, which method is defined by the pointer to program instructions for the computer core 2 of the control device 4 of the electronic fuse and/or by the corresponding index of measurement of the data set of the detected prototypical feature vector. As a result, the detected prototypical feature vector can, for example, cause the computer core 2 of the control device 4 of the fuse 1 to increase a signal object counter for the occurrence of the signal object corresponding to this detected prototypical feature vector, for example, in order to increase a specific signal object counter increment defined for this prototypical feature vector in the associated data set of the prototype database 62115, wherein the signal object counter increment can also be one, zero, and/or negative. When a signal object counter threshold, optionally also defined for this prototypical feature vector in the associated data set of the prototype database 62115, is reached or crossed, the computer core 2 of the control device 1 optionally executes a method that is also defined in the above-described manner in said data set of the prototype database 62115. For example, the computer core 2 of the control device 4 of the fuse 1 can then transmit a predefined data message with predefined content to the higher-level computer system 12.

The control device 4 of the fuse detects a prototypical feature vector of the prototype database 62115, thus optionally as a detected prototypical feature vector in a fourth sub-step 6034 of the third step 6030 if the determined distance between the current feature vector and the predetermined prototypical feature vector (prototype or value of the prototype vector) is below this first distance threshold value.

According to the technical teaching of the disclosure, the control device 4 of the electronic fuse 1 thus no longer transmits the sampling values of the parameter value characteristics of the parameter values of the parameters to be detected to the higher-level computer system 12. Instead, in a fourth step 6040, the control device 4 of the fuse transmits only one sequence of symbols (indices) for detected typical time parameter value characteristics of the parameter values of the physical parameters to be monitored and, if applicable, time stamps associated with these parameter value characteristics, and, if applicable, weightings associated with these parameter value characteristics in a certain time segment. In the fourth step 6040, the control device 4 of the fuse 1 thus transmits instead only a sequence of symbols (indices) for detected prototypical feature vectors, which represent these typical, temporal parameter value characteristics of the parameter values of the physical parameters to be monitored, and, if applicable, time stamps associated with the occurrence instant of these prototypical feature vectors and, if applicable, weightings associated with the occurrence intensity of these prototypical feature vectors in a specific time segment of the relevant time sampling window.

The control device 4 of the electronic fuse 1 then optionally transmits to the higher-level computer system only one symbol (index) for the detected prototypical feature vector of the prototype database 62115 (detected signal form prototypes), the parameters thereof (e.g., weighting factor and/or temporal extent) and a temporal reference point of the occurrence of this detected signal form prototype (the time stamp) as a detected signal object for each detected signal object (detected prototypical feature vector of the prototype database).

The transmission of the individual sampling values, etc. is omitted. In this way, this selection of the relevant prototypical feature vectors of the prototype database 62115 leads to a massive data compression and to a reduction in the bus bandwidth required on the data bus for transmitting the parameter value characteristics to the higher-level computer system 12.

A quantitative detection of the presence of a combination of properties is thus carried out to form an estimated value—in this case, for example, the inverse distance between the representative of the prototypical signal object class in the form of the predetermined prototypical feature vector (prototype or prototype vector) of the prototype database—and the subsequent transmission of the compressed data to the higher-level computer system 12 if this estimated value (e.g., inverse distance) is above a second threshold value or the inverse estimated value is below a first threshold value. The control device 4 of the fuse 1 thus carries out a data compression of the parameter value characteristics of the detected parameter values of the detected physical parameters of the fuse 1 for generating compressed data.

The higher-level computer system 12 optionally comprises a prototype database which optionally has the same content as the prototype database 62115 of the control device 4 of the fuse 1.

The control device 4 of the fuse 1 optionally signals the start of the transmission of the compressed data of a time sampling window to the higher-level computer system 12.

The higher-level computer system 12 optionally provides reconstructed sampling values of the reconstructed parameter value characteristic of the reconstructed parameter values of the reconstructed physical parameters. At the beginning of the decompression process, these reconstructed parameter values typically correspond to predefined starting values for these reconstructed parameter values.

In an exemplary reconstruction method, the higher-level computer system 12 now receives data sets from the control device 4 of the fuse, which data sets each comprise the index of a detected prototypical feature vector of the prototype database 62115 and a weighting factor and a time stamp. The higher-level computer system multiplies a prototypical characteristic of the reconstructed parameter value characteristic of the reconstructed parameter values of the reconstructed physical parameters from the prototype database, the index of which in the prototype database 62115 corresponds to the index transmitted by the control device 4 of the fuse 1, and shifts it over time by a temporal displacement vector which depends on the time stamp which the higher-level computer system 12 has received from the control device 4 of the fuse, so that the computer system receives a detected and weighted and time-shifted reconstructed parameter value characteristic of the reconstructed parameter values of the reconstructed physical parameters for this detected feature vector of the prototype database 62115, which vector corresponds to the received index. The detected and weighted and temporally shifted reconstructed parameter value characteristic of the reconstructed parameter values of the reconstructed physical parameters for this detected feature vector of the prototype database 62115 comprises substantially reconstructed sampling values of this detected and weighted and time-shifted reconstructed parameter value characteristic of the reconstructed parameter values of the reconstructed physical parameters for this detected feature vector of the prototype database. The higher-level computer system 12 now adds the detected and weighted and temporally shifted reconstructed parameter value characteristic of the reconstructed parameter values of the reconstructed physical parameters for this detected feature vector of the prototype database 62115 for each of the detected reconstructed sampling values to the previously described reconstructed sampling values of the reconstructed parameter value characteristic of the reconstructed parameter values of the reconstructed physical parameters which the higher-level computer system 12 has provided.

The computer system then receives the next data set and on the basis of the received data set adds the detected and weighted and time-shifted reconstructed parameter value characteristic of the reconstructed parameter values of the reconstructed physical parameters for the then transmitted detected feature vector of the prototype database 62115 for each of the detected reconstructed sampling values to the above-described reconstructed sampling values of the reconstructed parameter value characteristic of the reconstructed parameter values of the reconstructed physical parameters which the higher-level computer system 12 has provided.

The computer system 12 continues this until the control device 4 of the fuse 1 signals the end of the transmission of the compressed data for this sampling window.

For better clarity, the disclosure explains the distance determination again here:

This distance determination is also known as a classification from the signal processing of statistical signals. In this case, logistic regression, the cuboid classifier, the distance classifier, the nearest neighbor classifier, the polynomial classifier, the clustering method, artificial neural networks, and latent class analysis are mentioned as classifier examples.

A classifier example is shown in FIG. 62.

An exemplary physical interface 62101 of the control device 4 controls means 62100 for detecting the physical parameters of the fuse 1. These means 62100 can be, for example, shunt resistors 24 and/or the circuit breaker 17 and/or the auxiliary circuit breaker 23 and further device parts of the fuse 1 and/or of the control device 4. The physical interface 62101 can comprise, for example, the analog-to-digital converter 570 of the control device 4 and/or the gate drive circuit 16 of the control device 4 for controlling and monitoring the circuit breaker 17. As already described above, the physical parameters may, for example, be values of electrical currents 29, 36 and/or voltage values and/or output values and/or temperatures. Device parts of the control device 4 of FIG. 62 can be implemented in hardware or can be emulated as software by the computer core 2 of the control device. The program commands and program data of this software are optionally in a memory of the control device 4.

In FIG. 62, for better clarity, not all appropriate and in some cases customary device components are shown. Furthermore, device components that the reader can assume, depending on the application, as possibly present in FIG. 62 can be found, for example, in FIGS. 1, 5, 6, 9, 24, 41, 42, 52, 53, 54, 55, 57 and 58. The combination of the device parts of the Figure described here with those of these figures is expressly part of the disclosure of the disclosure.

The means 62100 for detecting the physical parameters of the fuse 1 convert the values of the physical parameters that the fuse 1 is intended to detect into signals 62102 of the temporal parameter value characteristics and/or the corresponding time characteristics of the parameters derived from these parameter value characteristics of the physical parameters. The physical interface 62101 converts these signals 62102 of the temporal parameter value characteristics and/or the corresponding time characteristics of the parameters derived from these parameter value characteristics of the physical parameters, typically by filtering and/or amplification into a parameter signal 62103. Optionally, sequences of sampling values form the parameter signal 62103. The feature vector extraction 62111 extracts the current feature vector from this parameter signal 62103. Optionally, the physical interface 62101 transmits the parameter signal 62103 to the feature vector extraction 62111 as a time-discrete signal consisting of a sequence of sampling values. A temporal datum (time stamp) is optionally assigned to each sampling value. In the example of FIG. 62, the feature vector extraction 62111 has a plurality of m matched filters 62104.1 to 62104.m. The number m is a positive integer. These m matched filters 62104.1 to 62104.m serve to determine m intermediate parameter signals 62123.1 to 62123.m. The m intermediate parameter signals 62123.1 to 62123.m each optionally signal the presence of precisely one signal basic object optionally associated with the corresponding intermediate parameter signal of the m intermediate parameter signals 62123.1 to 62123.m optionally with the aid of a suitable filter (for example a matched filter) from the sequence of sampling values of the parameter signal 62103. The disclosure first of all intends signal basic object to mean a temporal prototypical parameter value characteristic and/or the time characteristic of a parameter of the prototype database derived from these parameter value characteristics of the physical parameters if the prototype database 62115 comprises such temporal prototypical parameter value characteristics and/or such time characteristics of a parameter derived from these parameter value characteristics of the physical parameters as part of the data sets of the prototype database 62115. The disclosure, secondly, intends signal basic object to mean a prototypical feature vector of the prototype database if the prototype database 62115 comprises such prototypical feature vectors as part of the data sets of the prototype database 62115. In FIG. 62, the m intermediate parameter signals 62123.1 to 62123.m are combined to form an intermediate parameter signal bundle 62123 by way of example for better clarity. The resulting m intermediate parameter signals 62123.1 to 62123.m are optionally designed as a time-discrete sequence of corresponding intermediate parameter signal values of a corresponding intermediate parameter signal of the m intermediate parameter signals 62123.1 to 62123.m. These intermediate parameter signal values of the corresponding intermediate parameter signal of the m intermediate parameter signals 62123.1 to 62123.m are optionally each correlated with a datum (time stamp). Thus, optionally every intermediate parameter signal value of the corresponding intermediate parameter signal of the m intermediate parameter signals 62123.1 to 62123.m is assigned precisely one temporal datum (time stamp). Intermediate parameter signal values of the m intermediate parameter signals 62123.1 to 62123.m of the intermediate parameter signal bundle 62123 with the same time stamp each form an intermediate parameter signal value vector. The intermediate parameter signal bundle 62123 thus transmits a stream of intermediate parameter signal value vectors to the downstream signal processing block, the significance increase unit 62125.

The downstream significance increase unit 62125 optionally executes a matrix multiplication of the current intermediate parameter signal value vector with a so-called LDA matrix 62126. The designers of such a fuse 1 typically specify the LDA matrix 62126 at the time of design by means of statistical methods of statistical signal processing and pattern recognition. For this purpose, the designers who want to rework the technical teaching presented here in this document execute, for example, a discriminant analysis. (see also https://de.wikipedia.org/wiki/Diskriminanzanalyse) in English, the term “linear discriminant analysis” (https://en.wikipedia.org/wiki/Linear_discriminant_analysis) is customary. In this case, the document submitted here refers by way of example to the book by Mohssen Mohammed, “Machine Learning: Algorithms and Applications” CRC Press (Jun. 30, 2020), ISBN-10: 0367574675; ISBN-13: 978-0367574673 and the book by Alan J. Izenman, “Modern Multivariate Statistical Tech-niques: Regression, Classification, and Manifold Learning (Springer Texts in Statistics)” Springer; 1st. ed. 2008, corr. 2nd printing 2013 Edition (Aug. 28, 2008); ISBN-10 038778188; ISBN-13 978-0387781884. In this way, the significance increase unit 62125 generates the signal of the current feature vector 62138. In this case, the significance increase unit 62125 maps the current m intermediate parameter signal values of the current intermediate parameter signal vector to n parameter signal values of the signal of the current feature vector 62138. In this case, n represents a positive integer which can deviate from m or is equal to m. However, n<m optionally applies. The signal of the current feature vector 62138 therefore typically comprises n parameter signals. The signal of the current feature vector 62138 is thus, among other things, as a time-discrete sequence of ascertained feature vectors. Each of these feature vectors comprises n vector components of the relevant feature vector. These n vector components of the relevant feature vector each represent n parameter signal values of the optionally n parameter signals of the signal of the current feature vector 62138, which included the parameter signal values as vector components of the relevant feature vector and further parameter signal values each having the same temporal datum (time stamp). Here, n is the dimension of the individual feature vectors. This dimension n of the feature vectors is optionally the same from one feature vector to the next downstream feature vector. A feature vector is in this sense a vector having a time stamp which comprises a plurality of, optionally n, parameter signal values as vector components of this feature vector. The feature vector extraction 62111 of the control device 4 of the fuse 1 of this corresponding temporal datum, i.e., this time stamp, is associated with each feature vector formed in this way.

The evaluation of the time characteristic of the signal of the current feature vector 62138 in the resulting n-dimensional phase space now follows in the signal path. In addition, this is followed by the deduction of a detected signal basic object while determining an evaluation value (e.g., the distance). For understanding the term “signal basic object,” the disclosure refers to the preceding text.

The disclosure first of all intends signal basic object to mean a temporal prototypical parameter value characteristic and/or the time characteristic of a parameter of the prototype database derived from these parameter value characteristics of the physical parameters if the prototype database 62115 comprises such temporal prototypical parameter value characteristics and/or such time characteristics of a parameter derived from these parameter value characteristics of the physical parameters as part of the data sets of the prototype database 62115. The disclosure, secondly, intends signal basic object to mean a prototypical feature vector of the prototype database if the prototype database 62115 comprises such prototypical feature vectors as part of the data sets of the prototype database 62115.

A distance determination device (or classifier) 62112 now compares the current feature vector of the signal of the current feature vector 62138 to a plurality of prototypical feature vectors that are typically stored beforehand in the prototype database 62115 61115 during the design phase. The disclosure explains this in more detail below. The distance determination device or classifier 62112 determines, for example, an evaluation value for each of the examined prototypical feature vectors of the prototype database 62115, which indicates the extent to which the corresponding prototypical feature vector of the prototype database 62115 resembles the current feature vector. The disclosure also denotes this evaluation value in the text of the description as a distance. The distance can be a Euclidean distance but does not have to be. Optionally, the prototypical feature vectors of the prototype database 62115 are each optionally associated with precisely one signal basic object. The prototypical feature vector of the prototype database 62115 having the smallest distance from the current feature vector is then the best match. If its distance is less than a predefined threshold value, this prototypical feature vector of the prototype database 62115 represents the signal basic object 62121 detected with the highest probability. This prototypical feature vector of the prototype database 62115 is then the detected prototypical feature vector of the prototype database 62115.

This detection process is carried out multiple times over time, so that a determined signal basic object sequence typically results from the temporal sequence of the detected signal basic objects 62121 in the form of a temporal sequence of successively detected feature vectors. This makes it possible to detect and eliminate faults.

The determination of the signal object 62122 that is likely to be present then optionally follows by determination of that sequence of predetermined signal basic object sequences of a signal object sequence database 62116 which is most similar to the determined signal basic object sequence from the temporal sequence of the detected signal basic objects 62121. The signal object sequence database 62116 represents a lexicon of known prototypical temporal sequences of prototypical signal basic objects of the prototype database 62115. Such a known, prototypical, temporal sequence of signal basic objects of the prototype database 62115 is a prototypical signal object of the signal object sequence database 62116 within the meaning of the disclosure.

Within the meaning of the disclosure, a signal object consists of a temporal, defined sequence of signal basic objects. The disclosure also refers to this temporal, defined sequence of signal basic objects as a signal object sequence.

A signal object symbol in the signal object sequence database 62116 is typically associated with the signal object in a predefined manner. A data set of the signal object sequence database 62116 comprises, for example, the signal object symbol, the number of signal basic objects of this signal object sequence of this signal object and, for each signal basic object of the signal object sequence of the signal basic objects of this signal object, a signal basic object symbol, which denotes the relevant signal basic object of the prototype database 62115. The signal object sequence database 62116 thus comprises data sets which comprise prototypical signal object sequences from signal basic objects. Each of the data sets of the signal object sequence database 62116 describes a signal object as a sequence of signal basic objects. The signal basic object symbol is optionally the relevant index of the relevant signal basic object in the prototype database 62115. The signal object symbol is optionally the index of the signal object in the signal object sequence database 62116.

For example, a Viterbi estimator 62113 of the control device 4 can perform this estimation of the signal object sequence of the signal basic objects of the signal object. The Viterbi estimator 62113 is optionally a device part of the control device 4 of the fuse 1. Alternatively, a device part of the control device 4 of the fuse 1, for example the computer core 2 of the control device 4 of the fuse 1, can also emulate the Viterbi estimator 62113.

Within the meaning of the disclosure, correctly placed and detected signal basic objects are those which, in accordance with their position in the determined signal basic object sequence 62121 from the time sequence of the detected signal basic objects, correspond in sequence to the position of an expected signal basic object in an expected sequence of signal basic objects at this position, which sequence is predefined in the signal object database 62116 as a predefined signal object.

Within the meaning of the disclosure, signal basic objects that are NOT correctly placed and detected are those which, in accordance with their position in the determined signal basic object sequence 62121 from the time sequence of the detected signal basic objects, do NOT correspond in sequence to the position of an expected signal basic object in an expected sequence of signal basic objects at this position, which sequence is predefined in the signal object database 62116 as a predefined signal object.

In the simplest case, the Viterbi estimator 62113 uses the number of signal basic objects which are correctly placed and detected within a predefined time period minus the number of detected signal basic objects that are NOT correctly placed within the predefined time period as an evaluation value for the match of the determined signal basic object sequence 62121 with an expected sequence of signal basic objects, which sequence is predefined in the signal object database 62116 as a predefined signal object.

In this way, the Viterbi estimator 62133 optionally determines such an evaluation value for optionally each of the predefined signal objects of the signal object database 62116. The signal objects of the signal object database 62116 consist of predefined sequences of expected signal basic objects and are correlated with a corresponding signal object symbol.

Figuratively speaking, the Viterbi estimator 62133 checks here whether the point to which the n-dimensional signal of the current feature vector 62138 points in the n-dimensional phase space approaches predetermined points in this n-dimensional phase space closer than a predefined maximum distance during its path through the n-dimensional phase space in a predetermined temporal sequence. The signal of the current feature vector 62138 thus has a time characteristic. The Viterbi estimator 62133 then calculates an evaluation value (e.g., a distance) optionally for each of the prototypical signal objects of the signal object sequence database 62116. These evaluation values thus form an evaluation value vector. The dimension of the evaluation value vector optionally corresponds to the number of prototypical signal objects in the signal object sequence database 62116. The Viterbi estimator 62133 optionally calculates the probability of the presence of a certain prototypical sequence of the signal basic objects of a signal object of the signal object database 62116, i.e., of a prototypical signal object of the signal object sequence database 62116. Optionally, the Viterbi estimator 62133 in turn assigns this evaluation value vector to a temporal datum (time stamp). The Viterbi estimator 62113 compares this evaluation value vector with a optionally predetermined or set threshold vector to calculate results. The result is optionally Boolean. That is to say, the result can optionally have a first and a second value. If this Boolean result has the first value for this temporal datum (time stamp), the control device checks whether the signal object symbol of the detected prototypical signal object of the signal object sequence database 62116 requires the execution of a typically predetermined method, and which typically determined predetermined method the control device 4 and/or the computer core 2 of the control device 4 are intended to execute and with which parameters. This information is typically part of the data set of the detected prototypical signal object of the signal object sequence database 62116.

One possible method that the control device 4 of the fuse can execute after detection of the detected prototypical signal object of the signal object sequence database 62116 by the Viterbi estimator 62113 of the control device 4 of the fuse 1, for example, can be the transmission of the detected signal object symbol of the detected prototypical signal object of the signal object sequence database 62116 with the temporal datum (time stamp) associated with this signal object symbol from that of the control device 4 of the fuse 1 to the higher-level computer system 12.

One possible method that the control device 4 of the fuse can execute after detection of the detected prototypical signal object of the signal object sequence database 62116 by the Viterbi estimator 62113 of the control device 4 of the fuse 1, for example, can be the transmission of the detected signal object symbol of the detected prototypical signal object of the signal object sequence database 62116 with the temporal datum (time stamp) associated with this signal object symbol from that of the control device 4 of the fuse 1 to the control device 4 of a different fuse.

One possible method that the control device 4 of the fuse can execute after detection of the detected prototypical signal object of the signal object sequence database 62116 by the Viterbi estimator 62113 of the control device 4 of the fuse 1, for example, can be the transmission of the detected signal object symbol of the detected prototypical signal object of the signal object sequence database 62116 with the temporal datum (time stamp) associated with this signal object symbol from that of the control device 4 of the fuse 1 to a server 710. As a result, the operator of the server 710 receives knowledge of such events.

Optionally, the operator of the server can then use this data for further statistical evaluation.

The control device 4 of the fuse 1 transmits the detected prototypical signal object 62122 of the signal object sequence database 62116 optionally with its parameters. If necessary, the control device 4 of the fuse 1 can transmit further parameters depending on the detected prototypical signal object of the signal object sequence database 62116.

At this point, for better clarity, the disclosure again covers the processing of the signal of the current feature vector 62138.

Optionally, the parameter signal 62103 signals a sequence of quantization vectors in the form of sampling values of the values of the physical parameters in this time sampling window, which are determined by the physical interface 62101 of the control device 4 of the fuse in cooperation with the means 62100 for detecting physical parameters of the fuse 1. As explained above, namely, the physical interface 62101 converts the signals 62102 of the temporal parameter value characteristics and/or the corresponding time characteristics of the parameters derived from these parameter value characteristics of the physical parameters detected by the means 62100 for detecting physical parameters of the fuse 1, typically by filtering and/or amplification into a parameter signal 62103. Optionally, sequences of sampling values form the parameter signal 62103, the components of which, the measured parameters, will generally not be completely independent of one another, however. Each sampling value of the parameter signal 62103, per se, generally has too low a selectivity for the precise signal object determination in complex contexts. By the creation of one or more such quantization vectors from the continuous current of sampled analog physical values of the parameter signal 62103 at typically regular time intervals by the physical interface 62101 (see FIG. 62), the multi-dimensional parameter value characteristic data stream, which is quantized in time and value, is generated in the form of the parameter signal 62103.

In a first exemplary processing step, this multi-dimensional parameter signal 62103 obtained in this way in the form of one or more streams of quantization vectors is first of all subdivided into individual frames of defined length, the said sampling windows, filtered, normalized, then orthogonalized and, where applicable, suitably distorted by non-linear mapping—e.g., logarithmic conversion and cepstral analysis, etc.—. This is indicated by the block of the m matched filters 62104.1 to 62104.m in the feature vector extraction 62111 of FIG. 62. Instead of the block of the matched filters 62104.1 to 62104.m, it is thus also possible here to provide other signal conditioning structures for generating the intermediate parameter signals 62123.1 to 62123.m of the intermediate parameter signal bundle 62123. For example, derivatives of the sampling values of the multidimensional parameter signal 62103 generated in this way can also be formed here. Finally, the significance increase unit 62125 carries out a significance increase of the ascertained intermediate parameter signals 62123.1 to 62123.m of the intermediate parameter signal bundle 62123 with respect to the actual signal of the current feature vector 62138. The significance increase unit 62125 can carry out a significance increase of the ascertained intermediate parameter signals 62123.1 to 62123.m of the intermediate parameter signal bundle 62123, as described, for example by multiplying the multidimensional quantization sector of the intermediate parameter signal bundle 62123 with a so-called predetermined LDA matrix 62126.

The following step of detection in the distance determination device (or classifier) 62112 can be performed by this distance determination device (or classifier)62112, for example by means of different methods:
a) by a neural network or
b) by an H4M detector; or
c) by a Petri net

The disclosure describes, by way of example, an HMM detector (FIG. 62):

With the aid of said predefined LDA matrix 62126, the significance increase unit 62125 maps the intermediate parameter signals 62123.1 to 62123.m of the intermediate parameter signal bundle 62123 of the intermediate parameter data stream 62123 from the multidimensional input parameter space to a new parameter space. The matrix elements of the LDA matrix 62126 are selected in such a way that the significance is maximized and thus the selectivity grows to a maximum. The components of the new transformed feature vectors of the signal of the current feature vector 62138 obtained in this case are not selected according to real physical or other parameters, but rather according to maximum significance, which results in said maximum selectivity.

Optionally, the designers of such a fuse 1 calculate the LDA matrix (126) usually in advance of the time of design by a training step offline using sample data streams having known signal object data sets. Such known signal object data sets are, within the meaning of the disclosure, data sets which have been obtained with predefined structures of the signal characteristics of the temporal parameter value characteristics and/or of the corresponding time characteristics of the parameters derived from these parameter value characteristics of the physical parameters.

If it is ensured that all elements of the methods carried out by the distance determination device (or the classifier) 62112 execute at least locally reversible functions, deviations of the signal characteristic in the form of an approximately linear transform function can be taken into account.

The prototypical feature vectors from sample data streams for the specified prototypical signal characteristics (prototypical signal basic objects) of the temporal parameter value characteristics and/or of the corresponding time characteristics of the parameters derived from these parameter value characteristics of the physical parameters in the coordinates of the new parameter space are calculated in the design phase and deposited in the prototype database 62115 for later recognition. In addition to these statistical data, this can also contain instructions for the control device 4 of the fuse 1 and/or the higher-level computer system 12, which should take place in the event of a successful or unsuccessful detection of the corresponding prototypical signal basic object, i.e., for example, a prototypical feature vector.

The designers of a reworked device according to the technical teaching of the disclosure back up the values of the vector components of the signal of the current feature vector 62138, which are output by the feature vector extraction 62111 for these prototypical signal characteristics of the predefined signal basic objects of the parameter signal 62103 in the laboratory, in the prototype database 62115 as signal basic object prototypes, for example in the form of prototypical feature vectors.

During later operation, the control device 4 of the fuse 1 now compares the current feature vector of the signal of the current feature vector 62138 to these previously stored, i.e., learned signal basic object prototypes in the form of prototypical feature vectors of the prototype database 62115. The control device 4 of the fuse 1 carries out this comparison, for example by calculating the Euclidean distance between a quantization vector in the form of a current feature vector of the signal of the current feature vector 62138 in the coordinates of the new parameter space. The control device 4 of the fuse 1 compares the quantization vector in the form of a current feature vector of the signal of the current feature vector 62138 optionally with all of these previously stored signal basic object prototypes in the form of prototypical feature vectors of the prototype database 62115. For this purpose, the distance determination device or classifier 62112 optionally calculates a corresponding distance, optionally for each possible pair made up of the quantization vector in the form of a current feature vector of the signal of the current feature vector 62138, on the one hand, and, respectively, one of the previously stored signal basic object prototypes in the form of prototypical feature vectors of the prototype database 62115. In this case, the control device 4 of the fuse optionally provides at least two identifiers:
1. If the detected current feature vector of the signal of the current feature vector 62138 corresponds to one of the pre-stored signal basic object prototypes in the form of prototypical feature vectors of the prototype database 62115, or does not correspond thereto, and if it does: With what probability and/or reliability does the detected current feature vector of the signal of the current feature vector 62138 correspond to one of the pre-stored signal basic object prototypes in the form of prototypical feature vectors of the prototype database 62115?
2. If it is one of the already stored signal basic object prototypes in the form of prototypical feature vectors of the prototype database 62115, which of the already stored signal basic object prototypes in the form of prototypical feature vectors of the prototype database 62115 is it, and with what probability and reliability?

In order to provide the first identifier, dummy prototypes are generally also stored in the form of prototypical dummy feature vectors in the prototype database 62115 of the signal basic object prototypes. Optionally, the prototypical dummy feature vectors in the prototype database 62115 to a large extent cover all parasitic parameter combinations occurring during operation in normal operation without any events to be detected. The aforesaid signal basic object prototypes are stored in the form of prototypical feature vectors and/or prototypical dummy feature vectors in the prototype database 62115.

For the signal basic object prototypes in the form of prototypical feature vectors and/or prototypical dummy feature vectors of the prototype database 62115, the designers of a fuse 1 according to the technical teaching of the disclosure at the time of design can determine the corresponding distance for each pairing of two different signal basic object prototypes in the form of two different prototypical feature vectors and/or prototypical dummy feature vectors of the prototype database 62115 corresponding to the method applied in the distance determination device 62112. In this way, the designers of a fuse 1 in the design period determine a minimum prototype distance between two different prototypical feature vectors and/or prototypical dummy feature vectors of the prototype database 62115 that is possible with the present prototype database 62115 62155. The designers store this minimum distance in the prototype database 62115 or in the distance determination device 62112 optionally halved as half the minimum prototype distance. It is conceivable that, alternatively and/or additionally, the control device 4 of the fuse 1 determines this minimum distance of the two different prototypical feature vectors and/or prototypical dummy feature vectors of the prototype database 62115 during the system start of the fuse 1 and/or on the basis of an event such as a reset operation, and/or on the basis of a command of the higher-level computer system 12 or a computer core 2 of a control device 4 of a different fuse, and stores this minimum distance in the prototype database 62115 or in the distance determination device 62112 optionally halved as half the minimum prototype distance.

If, for example, this minimum half prototype distance is undershot by the distance determined by the distance determination 62112 between the current feature vector of the signal of the current feature vector 62138 and a signal basic object prototypes in the form of a prototypical feature vector of the prototype database 62115, this signal basic object prototype is evaluated as detected, and this prototypical feature vector is the detected prototypical feature vector for this current feature vector. From this instant, the control device 4 of the fuse 1 can exclude that further distances to other signal basic object prototypes calculated in the course of a further continued search, in the form of prototypical feature vectors of the prototype database 62115, can supply even smaller distances. The control device 4 of the fuse 1 can then cancel the search. This procedure of the control device 4 of the fuse 1 halves the time on average and thus protects the resources of the control device of the fuse.

The control device 4 of the fuse 1 can perform the calculation of the minimum Euclidean distance, for example according to the following formula:

$${Dist}_{FV\_CbE} = {{Min}^{1}}_{Cb\_cnt = Cb\_anz} [ {\sum }_{dim\_cnt = dim}^{1} {( {FV}_{dim\_cnt} - {Cb}_{Cb\_cnt , din\_cnt} )}^{2} ]$$

In this case, dim_cnt represents the dimension index that runs from 1 up to the maximum dimension dim of the current feature vector of the signal of the feature vector 62138.

FV_{dim_cnt} represents the parameter value of the vector component of the current feature vector of the signal of the feature vector 62138 corresponding to the index dim_cnt.

Cb_cnt represents the index value of the index of a signal basic object prototype in the form of a prototypical feature vector of the prototype database 62115.

Cb_{CB_cnt,dim_cnt} accordingly represents the parameter value corresponding to dim_cnt of the vector component of the entry of the signal basic object prototype in the form of the prototypical feature vector of the prototype database 62115, which is associated with the signal basic object prototypes corresponding to Cb_cnt in the form of the prototypical feature vector of the prototype database 62115.

Dist_{FV_CbE} represents the minimum Euclidean distance obtained, provided here by way of example. In the search for the smallest Euclidean distance, the control device 4 of the fuse 1 memorizes the number Cb_cnt of the index of that prototypical feature vector of the prototype database 62115 which produces the smallest distance from the current feature vector.

For the sake of clarity, the disclosure cites an exemplary assembler code:

| | |
|---|---|
| Start of code | |
| Mov Cb_cnt,#Cb_anz | initialize prototype database vector counter |
| Mov C, #0 | initialize register C with 0 |
| Mov dist, maxvalue | initialize the distance with maximum value |
| Mov num, not_valid_num | initialize the number of the nearest neighbor with non-valid |
| | value |
| Mov Cb_adr, Cb_badr | initialize prototype database address with the prototype |
| | database base address |
| Label_A: // next vector | |
| Mov SP, #0 | initialize cache memory |
| Mov dim_cnt, #dim | initialize dimension counter with the dimension of the feature |
| | vectorLabel B: // next dimension |
| MovA, $Cb_adr | load value absolutely from the prototype database 62115- |
| address | |
| SubA, $FV_adr, dim_cnt | subtracts the value absolutely relative from |
| | the feature vector value of the vector component of the |
| | feature vectorMov B A load B register with resultMulA B |
| | multiply A and B (=A²)AddA, SP add result to interme- |
| | diate resultMov SP, A and memorizeDec dim_cnt next |
| | vector component of the feature vectorInc Cb_adr in- |
| | crease prototype database pointer by one |
| jnz dim_cnt, Label B | only if it was not the last |
| Cmp SP, dist | rate the prototype database entry |
| | (signal basic object prototypes) |
| jmpgt Label C | |
| Mov dist, SP | if better entry than previous optimumMov num, Cb_cnt |
| | memorize entry number (index) and distance |
| Label C: | |
| dec_Cb_cnt | next prototype database entry |
| jnz_Cb_cnt,Label A | but only if it was not the last |
| End of code | |

The confidence measure for correct detection is derived from the spread of the underlying base data streams for a signal basic object prototype, i.e., a prototypical feature vector of the prototype database 62115, and the distance of the current feature vector of the signal of the feature vector 62138 from its centroid.

FIG. 63 illustrates various detection cases. For the sake of simplicity, the illustration is presented as a two-dimensional feature vector having two parameter values as vector components. Each feature vector comprises a first parameter value and a second parameter value as vector components of the corresponding feature vector. The limitation to two dimensions for the dimensions of the feature vectors serves here only to better represent the methodology on a two-dimensional sheet of paper. In reality, the feature vectors of the signal of the feature vectors 62138 are typically always multidimensional, with a significantly higher number of dimensions.

FIG. 63 further represents the centroids of various exemplary and arbitrary prototypical feature vectors (63141, 63142, 63143, 63144) by way of example. The prototype database 62115 63115 can, as described above, comprise half the minimum distance of these signal basic object prototypes, i.e., the prototypical feature vectors of the prototype database 62115, as a datum. This half minimum distance of these signal basic object prototypes is then optionally a global parameter which is typically equally valid for all signal basic object prototypes of the prototype database 62115. The control device 4 of the fuse carries out the above-described decision as to whether a distance is less than the minimal half distance, with the aid of this minimum distance. However, this presupposes that the spreads of the real representatives of these signal basic object prototypes used during the determination of the signal basic object prototypes—the training—are smaller than this minimum half distance. For the training, the designers or others possibly detect possibly all signal characteristics (signal basic objects) of the temporal parameter value characteristics and/or of the corresponding time characteristics of the parameters derived from these parameter value characteristics of the physical parameters. These captured data of the detected signal characteristics (signal basic objects) of the temporal parameter value characteristics and/or of the corresponding time characteristics of the parameters derived from these parameter value characteristics of the physical parameters form the so-called training data set. For this detection, the designers optionally record the parameter signal 62101 for as many real use situations of the fuse as possible in real operation and/or in laboratory situations. The designers then use a feature vector extraction 62111 corresponding to the feature vector extraction 62111 of the control device 4 of the fuse 1 in order to generate the signal of the current feature vector 62138 for optionally each of the temporal parameter value characteristics and/or the corresponding time characteristics of the parameters derived from these parameter value characteristics of the physical parameters. The designers optionally cluster the feature vectors thus obtained of the signal of the current feature vector 62138 into signal ground prototypes. Optionally, each of the signal ground prototypes is characterized by a prototypical feature vector and a spread ellipsoid which indicates the spread of the obtained feature vectors compared to the prototypical feature vector. Because the use of a spread ellipsoid is too complex, the disclosure recommends simplifying the spread ellipsoid to form a spread sphere. In this case, only one threshold value per prototypical feature vector of the prototype database 62115 must be observed. The disclosure proposes, for the sake of greater simplicity, using threshold ellipsoids with equal distances for all prototypical feature vectors of the prototype database 62115.

The prototypical feature vectors of the signal ground prototypes optionally mark the centroid positions (63141, 63142, 63143, 63144) of the obtained feature vectors that contribute to the formation of the prototypical feature vector. If the distance determination (or other evaluation) via the distance determination device 62112 (or classifier) is optimum, this is also the case. This would correspond to a circle around the centroid (63141, 62142, 63142, 63144), i.e., the prototypical feature vector of each of the signal basic object prototypes of the prototype database 62115.

However, this can be achieved in reality only rarely. An improvement in the detection power can therefore be achieved if the spread of the obtained feature vectors which contribute to a prototypical feature vector of the prototype database 62115, i.e., the corresponding signal basic object prototype of the prototype database 62115, were to each be stored together with the prototypical feature vector in a data set in the prototype database 62115. This would correspond to a prototype-specific circle around each of the signal basic object prototypes of the prototype database 62115 with a radius specific to the signal basic object prototypes. However, the disadvantage is an increase in the required computing power.

A further improvement of the detection power can be achieved if the control device 4 of the fuse 1 models the spread for the signal basic object prototypes of the prototype database 62115 by means of an ellipse. If the prototype database 62115 now comprises, instead of the radius as before, the main axis diameters of the spread ellipse and the tilting thereof in relation to the coordinate system in the prototype database 62115 are stored for optionally each of the signal basic object prototypes of the prototype database 62115. The disadvantage is a further, massive increase in the computing power and in the memory requirement.

Of course, the calculation can be further complicated, which, however, generally only massively increases the effort and no longer significantly raises the detection power for the signal basic object prototypes of the prototype database 62115.

It is therefore recommended here to rely on the simplest of the options described.

The position of the current feature vector of the signal of the feature vector 62138 that is determined by the distance determination 62112 in the, by way of example, two-dimensional parameter space of FIG. 63 can now be very different. It is thus conceivable that such a first such exemplary feature vector 63146 is too far removed from the centroid coordinates (63141, 63142, 63143, 63144) of the centroid of any signal basic object prototypes of the prototype database 62115. This distance threshold value can be, for example, the aforementioned minimum half prototype distance. It can also be that the variation ranges of the signal basic object prototypes overlap around their respective centroids 63143, 63142, and a second exemplary determined current feature vector 63145 of the signal of the feature vector 63138 is in the overlapping region. During later operation, the control device 4 of the fuse 1 can then recognize two different events if a current feature vector is within the variation range of two prototypical feature vectors of the prototype database 62115. FIG. 63 shows such a case as an example. The exemplary current feature vector 63145 of the signal of the feature vectors 62138 is there in the overlapping region of the variation ranges of the two exemplary signal basic objects of the prototype database 62115 with the exemplary centroid coordinates 63142 and 63143. In this case, the control device optionally creates a hypothesis list. The hypothesis list optionally comprises a plurality of data sets of the hypothesis list. Each data set of the hypothesis list optionally comprises the index of exactly one signal basic object prototype, i.e., of a prototypical feature vector of the prototype database 62115. This signal basic object prototype, i.e., the prototypical feature vector of the prototype database 62115, is thus associated with this data set. Furthermore, each data set of the hypothesis list optionally comprises a probability value which roughly indicates the probability that the current feature vector will correspond to the signal basic object prototype associated with the index of the data set, i.e., the prototypical feature vector of the prototype database 62115. Typically, the control device 4 of the fuse uses the distance between the current feature vector, on the one hand, and the signal basic object prototype assigned by the index of the data set, i.e., the prototypical feature vector of the prototype database 62115, on the other hand, as such a probability value. However, this is typically not the true, precise probability. Rather, shorter distances indicate a higher probability than longer distances. Optionally, the control device 4 of the fuse sorts the hypothesis list after it has examined all the signal basic object prototypes, i.e., all the prototypical feature vectors of the prototype database 62115, with regard to the distance or otherwise has completed this examination. In the example of the two signal ground prototypes 63143 and 63142 as representatives of the current feature vector 63145, the more probable signal ground prototype, which represents the current feature vector 63145, better represents the signal ground prototype 63143, because its distance to the current feature vector 63145 is smaller. In the example of the two signal ground prototypes 63143 and 63142 as representatives of the current feature vector 63145, the less probable signal ground prototype, which represents the current feature vector 63145 more poorly, is the signal ground prototype 63142, because its distance to the current feature vector 63145 is greater.

The hypothesis list can thus look like this:

| | | | |
|---|---|---|---|
| Number of | 2 | Current feature | 63145 |
| potential | | vector | |
| representative | | | |
| prototypical | | | |
| feature vectors | | | |
| of prototype | | | |
| database 62115 | | | |
| Time stamp | YYYY-MM-DD, | | |
| | HH:MM:SS.SSSSS | | |
| Hypothesis | Index of the | Distance | Rating |
| list index | prototypical feature | | |
| | vector of the | | |
| | prototype database | | |
| | 62115 | | |
| 1 | Index of | Distance | Danger level |
| | 63143 | value 63143 to | 63143 |
| | | 63145 | |
| 2 | Index of | Distance | Danger level |
| | 63142 | value 63142 to | 63143 |
| | | 63145 | |

Optionally, the data sets of the prototype database 62115 per data set of a prototypical feature vector comprise a danger value. It is indeed true that a first event, which represents a first prototypical feature vector 63143 of the prototype database 62115, can be less dangerous than a second event, which represents a second prototypical feature vector 63142 of the prototype database 62115. After creating the hypothesis list, the control device 4 can then still undertake measures against the more unlikely second event, which is represented by the second prototypical feature vector 63142, even though it is not the most likely, because its effect is more dangerous or otherwise more significant than the effect of an event which corresponds to the first prototypical feature vector 63143.

In the hypothesis list thus determined by the control device 4 via distance determination between the current feature vector 63145 and the prototypical feature vectors of the prototype database 62115, all the prototypical feature vectors of the prototype database 62115 of which the distance is less than a threshold value are then contained after completion of these distance determinations. In the example of FIG. 63, the hypothesis list for the current feature vector 63145 comprises two signal basic object prototypes 63143 and 63142 with a corresponding value for the different probabilities. For example, the value for the different probabilities can contain the different distances as an attached parameter. In this variant, the distance determination device or classifier 62112 of the control device 4 of the fuse 1 therefore does not transmit a signal basic object, the identified feature vector, as the most probable signal basic object to the Viterbi estimator 62113. In this variant, the distance determination device or classifier 62112 of the control device 4 of the fuse 1 then transfers said hypothesis list or a pointer to it. As described, this hypothesis list comprises possibly present signal basic objects and values that model the probability. Because the control device 4 of the fuse 1 continues to generate new current feature vectors in the signal of the feature vectors 62138, the distance determination device or classifier 62112 of the control device 4 of the fuse 1 generates a corresponding temporal sequence of hypothesis lists. A hypothesis list can also have only one prototypical feature vector of the prototypical feature vectors of the prototype database 62115. If the detection fails completely, a hypothesis list can also not have a prototypical feature vector of the prototypical feature vectors of the prototype database 62115. From this sequence of generated hypothesis lists, the Viterbi estimator 62113 then searches a possible sequence of prototypical feature vectors of the prototype database 62115 that have the greatest probability for one of the specified signal basic object sequences in the signal object sequence database 62116. Within the meaning of the disclosure, this means that the probability that the possible sequence of prototypical feature vectors of the prototype database 62115 is the correct one is the greatest, compared to the probabilities of all other possible paths through the signal basic objects of the recognized hypothesis lists 62121 that are recognized as possible. This is the sequence of hypothesis lists that the distance determination device 621122 communicates to the Viterbi estimator 62113 as determined signal basic object sequence 62121 from the temporal sequence of the detected signal basic objects. This path of the sequence of prototypical feature vectors that the Viterbi estimator 62113 determines for each hypothesis list runs here through precisely one detected signal basic object prototype of this hypothesis list.

In the best case, the current feature vector 63148 is in the variation range (threshold ellipsoid) 63147 around the centroid 63141 of a single signal basic object prototype 63141 of the prototype database 62115. The distance determination device 62112 thus detects this signal basic object prototype 63141 of the prototype database 62115 and as a detected signal basic object 62121 which best represents the current feature vector. The distance determination device 62112 thus generates a determined signal basic object sequence 62121 from the temporal sequence of the detected signal basic objects and forwards them to the Viterbi estimator (113). The signal basic objects correspond to prototypical feature vectors of the prototype database 62115.

It is conceivable, for improved modeling of the variation range of a single signal basic object prototype of the prototype database 62115, to model this by a plurality of signal basic object prototypes that are circular here, as a plurality of prototypical feature vectors of the prototype database 62115, with associated variation ranges. A plurality of signal basic object prototypes of the prototype database 62115 can thus represent the same signal basic object prototypes within the understanding of a signal basic object class. The risk here is that, due to the division of the probability of a signal basic object prototype into a plurality of such sub-signal basic object prototypes, the probability of the individual sub-signal basic object prototype can become smaller than that of a different signal basic object prototype, the probability of which was smaller than that of the original signal basic object prototype. Thus, this other signal basic object prototype may possibly be incorrectly asserted.

The computing power that the control device 4 of the fuse 1 must provide in order to reliably recognize the signal basic object prototypes of the prototype database 62115 furthermore represents a significant problem. This still merits some discussion:

A decisive point is that the computational effort with Cb_anz*dim increases.

In a non-optimized HMM detector, the number of assembly commands that the computer core 2 of the control device 4 of the fuse 1 must perform in order to calculate a vector component of the feature vector is about 8 steps.

The number A_Abst of the necessary assembler steps for calculating the distance of a single signal basic object prototype (CbE) of the prototype database 62115, i.e., of a prototypical feature vector of the prototype database 62115 to form a single feature vector (FV), is optionally calculated by the computer core 2 of the control device 4 of the fuse 1 approximately as follows:

$$A\_Abst = {FV\_Dimension}^{*} 8 + 8$$

This leads to the number A_CB of the assembler steps for determining the signal basic object prototype of the prototype database 62115 with the smallest distance:

$$A\_CB = {Cb\_anz}^{*} ( A\_Abst ) + 4 = {Cb\_anz}^{*} ( {FV\_Dimension}^{*} 8 + 8 ) + 4$$

Using the example of an average HMM detector with 50,000 signal basic object prototypes (number of signal basic object prototype entries in the prototype database=CB_anz) and, by way of example, 24 FV_dimensions (number of parameter values in a feature vector=feature-vector dimension=FV_dimension), the number of steps is:
50000*(24*8+8)+4˜10 million operations per feature vector of the signal of the feature vectors 62138.

At a relatively low sampling rate of 8 kHz=8000 feature vectors per second (feature vectors of the signal of the feature vectors 62124 per second), the computer core 2 of the control device 4 of the fuse 1 already requires a computing power of 8 GIPS (8 billion instructions per second).

In view of the challenges for energy saving in electromobility and/or for the reduction of the carbon footprint, this is not acceptable.

In the event that an optimized HMM detection method is carried out by the distance determination device 62112 or the classifier 62112, as already mentioned, the smallest distance between two signal basic object prototypes of the prototype database 62115 is therefore pre-calculated and stored in the prototype database 62115 or in the distance determination device 62112. This has the advantage that the search can then be terminated by the distance determination device or the classifier 62112 if a distance between a current feature vector of the signal of the feature vectors 62138 and a signal basic object prototype of the prototype database 62115 was found by the distance determination device or the classifier 62112 which is less than half of this smallest distance. The average search time for the distance determination device or classifier 62112 is thus halved. Further optimizations can be carried out if the prototype database 62115 is sorted in real parameter signals 62103 of a real fuse 1 according to the statistical occurrence of the signal basic object prototypes. It can thereby be ensured that the control device 4 of the fuse 1 finds the most frequent signal basic object prototypes in the prototype database 62115 significantly faster. This further lowers the computing time of the distance determination device 62112 or classifier 62112 and further lowers the power consumption. Because, as a rule, the computer core 2 of the control device 4 of the fuse emulates the distance determination device or classifier 61112, this also further lowers the computing time of the computer core 2 of the control device 4 of the fuse 1 and thus lowers the power consumption of the fuse 1.

For a distance determination device 62112 or classifier 62112, which executes such an optimized HMM detection process, the computing power requirement is then indicated as follows:

Again, there are 8 steps for calculating the distance of a vector component of the current feature vector to the corresponding vector component of the prototypical feature vector of the prototype database 62115. The steps for calculating the distance A_Abst of a signal basic object prototype entry (CbE)
of the prototypical feature vector in the prototype database 62115 to the current feature vector of the signal of the feature vector 62138 are in turn:

$$A\_Abst = {FV\_Dimension}^{*} 8 + 8.$$

The number of steps for determining the signal basic object prototype entry, i.e., the data set of the prototypical feature vector of the prototype database 62115 with the smallest distance A_CB with optimization is a little higher:

$$A\_CB = {Cb\_anz}^{*} ( A\_Abst ) + 4 = {Cb\_anz}^{*} ( {FV\_dimension}^{*} 8 + 10 ) + 4.$$

The two additional assembler commands are necessary in order to check whether the determined distance between the current feature vector and the just—examined prototypical feature vector of the signal basic object prototypes of the prototype database 62115 is below half the smallest distance between the prototypical feature vectors of the signal basic object prototypes of the prototype database 62115.

Furthermore, according to the technical teaching presented here, the number CB_Anz of the signal basic object prototype entries, that is to say the database entries, of the prototype database 62115 is limited to 4000 prototype database entries, i.e., data sets, of signal basic object prototypes in the prototype database 62115, or even less to 2000 prototype database entries to 1000 prototype database entries or higher limited to 8000 entries or higher to 16,000 entries. 400 entries have proven successful in the development of the technical teaching. In general, an adaptation to the specific application scenario of the specific supply network will be necessary here.

In addition, the number of feature vectors per second within the signal of the feature vectors 62138 is reduced by filtering in the feature extraction 62111 and by lowering the sampling rate in the feature extraction 62111.

This is explained in a simple example:

The control device 4 of the fuse 1 operates the said distance determination device 62112 or classifier 62112 of the control device 4 of the fuse 1, which device or classifier executes an average HM detection method, now with a prototype database 62115 with barely a tenth of the entries (data sets), e.g., with 4000 entries (CbE) and furthermore with 24 dimensions of the signal of the feature vectors 62138 (i.e., 24 parameter signals).

The number of steps is now:
4000*(24*8+10)+4˜808004 operations per feature vector
of the signal of the feature vectors 62138

When the feature vector rate is lowered to 100 feature vectors per second, extracted from a 10 ms time window (sampling window) in the feature vector extraction 62111, via, for example, 80 sampling values and with termination of the search if the distance of the current feature vector to the processed prototypical feature vector of the processed signal basic object prototype of the prototype database 62115 is below half the smallest prototype database entry distance, at least a halving of the effort results with a suitable sorting of the data sets of the prototypical feature vectors of the prototype database 62115.

The required computing power of the computer core 2 of the control device 4 of the fuse 1 then drops to <33DSP-MIPS (33 million operations per second). In reality, the sorting of the data sets of the prototype database 62115 leads to even lower computing power requirements of, for example, 30 MIPS. This is what makes the system of the electronic fuse real-time capable and able to be integrated into a single micro-integrated circuit for the control device 4 of the fuse 1 and thus into a fuse 1 in the first place.

By preselecting data sets of the prototype database 62115, the control device 4 of the fuse 1 can limit the search space. A precondition is a uniform distribution of the data=centroids of the quadrants in the geometric quadrant center.

The necessary reduction in the size of the prototype database 62115 has advantages and disadvantages:

A reduction in the number of entries of the prototype database 62115 increases the false acceptance rate (FAR), i.e., the wrong signal basic object prototypes-prototypical feature vectors—of the prototype database 62115, which recognizes the control device 4 of the fuse 1 as detected signal basic object prototypes on the basis of the current feature vector.

Secondly, a reduction in the number of entries of the prototype database 62115 increases the false rejection rate (FRR), i.e., the signal basic object prototypes-prototypical feature vectors—of the prototype database 62115, which the control device 4 of the fuse 1 would actually have to accept as detected signal basic object prototypes on the basis of the current feature vector, but does not accept them.

On the other hand, the resource requirement (computing power, chip surfaces, memory, power consumption, etc.) is thereby reduced.

In addition, the previous history, i.e., the previously detected signal basic object prototypes, can be used in hypothesis formation by the distance determination device or classifier 62112. A suitable model for this is, for example, the so-called hidden Markov model (HMM).

For each signal basic object prototype, i.e., each prototypical feature vector of the prototype database 62115, the distance determination device or classifier 62112 can thus derive a confidence measure and a distance to the measured current feature vector of the signal of the feature vectors 62138. The Viterbi estimator (113) can also further process the confidence measure and the distance. As described above in this document, it makes sense that the distance determination device or classifier 62112 outputs a hypothesis list for each of the detected signal basic object prototypes, i.e., each prototypical feature vector of the prototype database 62115. The distance determination device or classifier 62112 transmits this hypothesis list as part of the determined signal basic object sequence 62121 from the temporal sequence of the detected signal basic object prototypes to the Viterbi estimator 62113. For example, a hypothesis list can comprise the ten most probable signal basic object prototypes with the corresponding probability and reliability of the detection, which can represent the current feature vector more or less well.

Not every determined signal basic object sequence 62121 from the temporal sequence of the detected signal basic objects that occurs can be assigned to a signal object of the signal object sequence database 62116 as a temporal and spatial signal basic object sequence. Therefore, typically not every determined signal basic object sequence 62121 from the temporal sequence of the detected signal basic objects that occurs is useful. In order to remedy this deficiency, it is expedient to evaluate the temporal sequence of the hypothesis lists of the temporally successive sampling windows using a Viterbi estimator 62113. Optionally, a hypothesis list is also associated with each time sampling window.

In this case, the Viterbi estimator 62113 has the task of finding that sequence path of a signal object sequence of signal basic object prototypes of the prototype database 62115 via the data sets of the successive hypothesis lists which has the highest probability and is a prototypical signal object sequence of the signal object database 62116 of the Viterbi estimator 62113.

In this case, the Viterbi estimator 62113 in turn provides at least two identifiers:
1. If the most probable signal object sequence of signal basic object prototypes of the prototype database 62105 is one of the signal object sequences of signal basic object prototypes already stored in the signal object sequence database 62116 or not, and with what probability and reliability?
2. If it is one of the already stored signal object sequences of signal basic object prototypes, which one is it and with what probability and reliability?

For this purpose, a teaching program can feed such a signal object sequence in the form of an entry (data set) consisting of a predefined signal object sequence of signal basic object prototypes of the prototype database 62115 into a signal object sequence database 62116. On the other hand, a user can also enter such a signal object sequence in the form of an entry (data set) consisting of a specified signal object sequence of signal basic object prototypes of the prototype database 62105 into a signal object sequence database 62116 by means of a terminal 740, if necessary also manually via a so-called type—in tool. This makes it possible to enter these signal object sequences of signal basic object prototypes of the prototype database 62115 via a keyboard of the terminal 740.

The Viterbi estimator 62113 can determine the most likely of the predefined signal object sequences of signal basic object prototypes of the prototype database 62115 for a determined signal basic object sequence 62121 of the temporal sequence of the detected signal basic objects 62121 from the sequence of the hypothesis lists of the distance determination device or classifier 62112. This also applies in particular if the distance determination device 62112 or the classifier 62112 has incorrectly detected individual signal basic object prototypes due to measurement errors. As described above, an adoption by the Viterbi estimator 62113 of sequences from the hypothesis list from the distance determination device 62112 or classifier 62112 is in this respect very useful. The result is the signal object 62122 detected as the most probable or, analogous to the previously described emission calculation of the distance estimator 62112 or classifier 62112, a signal object hypothesis list.

The signal object hypothesis list can thus look like this:

| | | | |
|---|---|---|---|
| Number of | 2 | Current time | Sampling |
| potentially | | sampling | window |
| representative | | window | number |
| prototypical | | | |
| signal objects of | | | |
| the signal | | | |
| object sequence | | | |
| database 62116 | | | |
| Time stamp | YYYY-MM-DD, | | |
| | HH:MM:SS.SSSSS | | |
| Signal object | Prototypical signal | Distance | Rating |
| hypothesis | objects of the signal | | |
| list index | object sequence | | |
| | database 62116 | | |
| 1 | Index of the first | Evaluation | Danger of |
| | prototypical | value of the | the first |
| | signal object | first prototypical | prototypical |
| | | signal object | signal object |
| | | relative to the | |
| | | determined | |
| | | signal basic | |
| | | object sequence | |
| | | 62121 of | |
| | | the temporal | |
| | | sequence of | |
| | | the detected | |
| | | signal basic | |
| | | objects 62121 | |
| 2 | Index of | Evaluation value | Danger of |
| | the second | of the second | the second |
| | prototypical | prototypical | prototypical |
| | signal object | signal object | signal object |
| | | relative to | |
| | | the determined | |
| | | signal basic | |
| | | object sequence | |
| | | 62121 of | |
| | | the temporal | |
| | | sequence of | |
| | | the detected | |
| | | signal basic | |
| | | objects 62121 | |

Optionally, the data sets of the signal object sequence database 62116 per data set of a prototypical signal object comprise a danger value. It is indeed the case that a first event representing a first prototypical signal object of the signal object sequence database 62116 may be less dangerous than a second event representing a second prototypical signal object of the signal object sequence database 62116. The control device 4 can then still adopt measures against the more unlikely second event that is represented by the second prototypical signal object after the signal object hypothesis list has been created, even though it is not the most likely, because its effect is more dangerous or otherwise more significant than the effect of an event corresponding to the first prototypical signal object.

Finally, we consider the functional components of the signal object detection machine. In FIG. 62, this is entered as a Viterbi estimator 62113. This search of the Viterbi estimator 62113 of the control device 4 of the fuse 1 accesses the signal object sequence database 62116. A piece of teaching software of a higher-level computer system 12 or of a terminal 740 and, on the other hand, a piece of software of the higher-level computer system 12 or of the terminal 740, in which a user 730 can specify these sequences of signal basic object prototypes by entering text, generate the data sets for the signal object sequence database 62116 and/or enable the editing of the content of the data sets of the signal object sequence database 62116.

In production, optionally a test system optionally loads the data of the signal object sequence database 62116 into a memory of the control device 4 of the fuse 1 optionally at the end of tape.

The basis of the signal object sequence detection for the temporal sequence of the signal basic object prototypes in the Viterbi estimator 62119 is optionally a hidden Markov model. The model develops from different states. In the example indicated in FIG. 64, numbered circles symbolize these states. In the aforementioned example in FIG. 64, the circles are numbered from Zu1 to Zu6. Transitions exist between the states Zu1 to Zu6. These transitions are denoted in FIG. 64 by the letter a and two indices i, j. The first index i denotes the number of the starting node, the second index j the number of the target node. In addition to the transitions between two different nodes, transitions aᵢᵢ or a_{yi} also exist which lead back to the starting node. Furthermore, there are transitions which enable nodes to skip from the sequence, resulting in each case in a probability of actually observing a k-th observable bₖ. This results in sequences of observables, which can be observed with pre-calculable probabilities bₖ.

What is important here is that any hidden Markov model does not include observable states qⁱ. Between two states qⁱ and q^{j} exists the transition probability aᵢⱼ.

The probability p for the transition from qⁱ to q^{j} can be written as:

$$p ( {q}_{n}^{j} \vert {q}_{n - 1}^{i} ) ≡ {a}_{ij}$$

In this case, n represents a discrete instant. The transition thus takes place between step n with state qⁱ and the step n+1 with the state q^{j}.

The emission distribution bᵢ(Ge) depends on the state qⁱ. As already explained, this is the probability of observing the signal basic object Ge (the observable) if the system (hidden Markov model) is in the state qⁱ:

$$p ( Ge \vert {q}^{i} ) ≡ {b}_{i} ( Ge )$$

In order to be able to start the system, the initial states must be specified. This is done by a probability vector πᵢ. Accordingly, it can be indicated that a state qⁱ with the probability πᵢ is an initial state:

$$p ( {q}_{1}^{i} ) ≡ {π}_{i}$$

It is important that a new model must be created for each sequence of signal basic object prototypes. In a model M, the observation probability for a temporal observation sequence of signal basic object prototypes is to

$$G \vec{e} = ( G {e}_{1} , G {e}_{2} , … {Ge}_{N} )$$

be determined.

This corresponds to a time state sequence which cannot be observed directly and corresponds to the following sequence:

$$\vec{Q} = ( {q}_{1} , {q}_{2} , … {q}_{N} )$$

The probability p of observing this state sequence Q, which probability depends on the model M, the temporal state sequence Q, and the temporal observation sequence Ge, is:

$$p ( G \vec{e} \vert \vec{Q} , M ) = p ( G {e}_{1} , G {e}_{2} , … {Ge}_{N} \vert {q}_{1} , {q}_{2} , {q}_{N} ) = p ( G {e}_{1} \vert {q}_{1} ) \cdot p ( {Ge}_{2} \vert {q}_{2} ) \cdot … p ( {Ge}_{N} \vert {q}_{N} ) = {\prod }_{n = 1}^{N} p ( G {e}_{n} \vert {q}_{n} ) = {\prod }_{n = 1}^{N} {b}_{n} ( G {e}_{n} )$$

This results in the probability of a state sequence Q̅=(q₁, q₂, . . . q_{N}), in the model M:

$$p ( \vec{Q} \vert M ) = p ( {q}_{1} , {q}_{2} , … {q}_{N} \vert M ) = p ( {q}_{1} ) \cdot p ( {q}_{2} \vert {q}_{1} ) \cdot p ( {q}_{3} \vert {q}_{1} , {q}_{2} ) \cdot … p ( {q}_{N} \vert {q}_{1} , {q}_{2} , … {q}_{N - 1} ) = p ( {q}_{1} ) {\prod }_{n = 2}^{N} p ( {q}_{n} \vert {q}_{n - 1} ) = {π}_{1} {\prod }_{n = 2}^{N} {a}_{( n - 1 ) n}$$

This results in the probability of detecting a signal object equal to a sequence of signal basic object prototypes (see also FIG. 10):

$$p ( G \vec{e} \vert {M}_{j} ) = {\sum }_{all {Q}_{k}} p ( G \vec{e} \vert {Q}_{k} , {M}_{j} ) p ( {\vec{Q}}_{k} \vert {M}_{j} ) = {\sum }_{all {Q}_{k}} ( {{\prod }_{n = 1}}^{N} {b}_{n} ( {Ge}_{n} ) ) ( {π}_{1} {\prod }_{n = 2}^{N} {a}_{( n - 1 ) n} )$$

In this case, the most probable signal object model (signal object) is determined for the observed emission Ge by this summation of the individual probabilities over all possible paths Qₖ which lead to this observed sequence of signal basic object prototypes Ge.

$$p ( G \vec{e} \vert {M}_{j} ) = {\sum }_{all {Q}_{k}} p ( G \vec{e} \vert {Q}_{k} , {M}_{j} ) p ( {\vec{Q}}_{k} \vert {M}_{j} ) = {\sum }_{all {Q}_{k}} ( {{\prod }_{n = 1}}^{N} {b}_{n} ( {Ge}_{n} ) ) ( {π}_{1} {\prod }_{n = 2}^{N} {a}_{( n - 1 ) n} )$$

Due to the possible computing effort, the summation over all possible paths Q is not unproblematic. Usually, therefore, it is interrupted very early. It is therefore proposed to use only the most probable path Qₖ. This is discussed below.

The calculation is carried out by recursive calculation. The probability aₙ(i) at the instant n of observing the system in the state qⁱ can be calculated as follows:

$${α}_{n} ( i ) = p ( G {e}_{1} , G {e}_{2} , … {Ge}_{n} ; {q}_{n} = {q}^{i} ) ≡ p ( {Ge}_{i}^{n} , {q}_{n}^{i} ) {α}_{n + 1} ( j ) = [ {\sum }_{i = 1}^{S} {α}_{n} ( i ) \cdot {a}_{ij} ] {b}_{j} ( G {e}_{n + 1} )$$

A summation is made here of all S possible paths that lead into the state qⁱ⁺¹.

It is assumed that the overall probability of arriving at the state qⁱₙ₊₁ is dominated by the best path. The sum can then be simplified with little error.

$${α}_{n + 1}^{*} ( j ) = [ {max}_{i} ( {α}_{n}^{*} ( i ) \cdot {a}_{ij} ) ] {b}_{j} ( {c}_{n + 1} )$$

By tracking back from the last state, the best path is then obtained.

The probability of this path is a product. A logarithmic calculation therefore reduces the problem to a pure summation problem. The probability of detection of a signal object, which corresponds to the detection of a model Mⱼ, corresponds to the determination of the most probable signal object model for the observed emission X. This is then accomplished via the best possible path Q_{best}.

$$p ( G \vec{e} \vert {M}_{j} ) = {\sum }_{all {Q}_{k}} ( {{\prod }_{n = 1}}^{N} {b}_{n} ( {Ge}_{n} ) ) ( {π}_{1} {\prod }_{n = 2}^{N} {a}_{( n - 1 ) n} )$$

This consequently becomes:

$$p ( G \vec{e} \vert {M}_{j} ) = p ( G \vec{e} \vert {Q}_{b e s t} , {M}_{j} ) p ( {\vec{Q}}_{b e s t} \vert {M}_{j} ) = exp ( ln ( {π}_{1} ) + ln ( {b}_{1} ( {Ge}_{1} ) ) + {\sum }_{n = 2}^{N} ln ( {b}_{n} ( {Ge}_{n} ) ) + ln ( {a}_{( n - 1 ) n} ) )$$

It is now of particular importance that the prototype database 62115 contains only signal basic object prototypes, i.e., prototypical feature vectors.

The control device 4 of the fuse 1 transmits the indices of the detected signal objects optionally together with the parameters, in some cases detected, instead of the sampling values to the higher-level computer system 12 and/or to a control device 4 of a different fuse. This results in a massive compression of the data without leaving the signal character.

The control device 4 of the fuse 1 thus does not transmit the sampling values of the parameter characteristics or the characteristics derived therefrom, but rather the structures within these characteristics. The control device 4 of the fuse 1 thus uses a signal structure detection for transmitting the parameter characteristics of the physical parameters or the characteristics of parameters derived therefrom to the higher-level computer system 12 or the control device 4 of a different fuse. Only this enables the evaluation-free reconstruction of the signal in the higher-level computer system after the data is received.

The technical teaching of the disclosure thus pursues several objectives. First, prototypical signal basic objects are to be detected in the parameter characteristics of the physical parameters or the characteristics of parameters derived therefrom, and where applicable evaluated in order to immediately detect critical signal basic objects that correlate with critical events. The control device 4 of the fuse 1 should then immediately initiate suitable measures. Secondly, critical prototypical signal objects which correspond to a predefined, prototypical sequence of prototypical signal basic objects are to be detected and where applicable evaluated in order to immediately detect critical prototypical signal object sequences which correlate with critical events. The control device 4 of the fuse 1 should then immediately initiate suitable measures. Thirdly, the control device should be able to transmit the parameter characteristics of the physical parameters, or the characteristics of parameters derived therefrom with as little bus bandwidth as possible to the higher-level computer system and/or to a control device 4 of a different fuse 1. For this purpose, the control device 4 of the fuse compresses the data of the sampling values of the parameter characteristics of the physical parameters or of the characteristics of parameters derived therefrom. For this purpose, the control device 4 of the fuse determines the prototypical signal basic objects of the prototype database 62115 which best correspond to sections of the parameter characteristics of the physical parameters or of the characteristics of parameters derived therefrom. The control device can already transmit the indices of these signal basic objects and their distances to a higher-level computer system 12 and/or to a control device 4 of a different fuse via the data bus 9. The control device 4 of the fuse 1 can further compress this already compressed data by determining signal objects of the signal object sequence database 62116 detected for sequences of signal basic objects, which signal objects represent these sequences of signal basic objects particularly well. The control device 4 of the fuse then optionally only transmits the index of the detected signal object in the signal object sequence database 62116 to the higher-level computer system 12 and/or to the control device 4 of a different fuse.

The aim of the present proposal is thus also, rather, to compress and transmit the parameter signal 62103 itself in as loss-free a manner as possible by limitation to application-relevant signal waveform components.

The control device 4 of the fuse then transmits the data thus compressed, optionally only the codings (symbols) of the prototypes thus detected, the amplitude of which and/or temporal extent and the occurrence instant (time stamp), to the higher-level computer system 12 and/or to the control device 4 of a different fuse. This also minimizes the EMC loading by the data transmission via the data bus 9 between the fuse 1 and the higher-level computer system 12. In addition, the fuse 1 and the higher-level computer system 12 and any further fuses can transfer status data of the fuses and/or of the higher-level computer system 12 for system error detection in the time intervals to the higher-level computer system 12 and/or to the other fuses via the data bus 9 between fuse and higher-level computer system 12 and/or to the other fuses, which improves the latency. In the preparation of the proposal, it was recognized that the transmission of the data via the data bus 9 must be prioritized. However, this prioritization does not relate to prioritization with respect to other bus participants. Instead, the prioritization is therefore to be understood to mean which datum of the data determined by the control device 4 of the fuse 1 must be transmitted chronologically first to the higher-level computer system 12. Messages of safety-critical errors of the fuse 1 or of line sections to the higher-level computer system 12 and/or to other fuses have the highest priority here, because they impair the validity of the measurement data of the fuse with high probability. These data are transmitted by the fuse to the higher-level computer system 12 and/or other fuses. Requests from the higher-level computer system 12 and/or from other fuses for carrying out safety-relevant self-tests of the fuse have the second highest priority. Such commands are transmitted from the higher-level computer system 12 and/or the control devices 4 of other fuses to the control device 4 of the fuse via the data bus 9. The data of the fuse 1 itself has the third highest priority, because the latency is typically not permitted to increase. All other data have lower priority for transmission via the data bus 9.

It is particularly advantageous if the method for transmitting data of the fuse 1 from the control device 4 of the fuse 1 to the higher-level computer system 12 and/or to the control device 4 of a different fuse, in particular in a vehicle, typically comprises in some cases the closing 6010 of the circuit breaker 17 of the fuse 1 by the control device 4, and the detection 6020 of the parameter value characteristics and/or the characteristics of parameters derived therefrom, and the formation 6020 of a parameter signal 62103, and the analysis and compression 6030 of the parameter signal 62103, and the transmission 6040 of the compressed data of the fuse 1 via a data bus 9, in particular a one-wire data bus, or in particular a differential two-wire data bus, to the higher-level computer system 12 and/or the control device 4 of a different fuse by the control device 4 of the fuse 1.

Optionally, the transmission of the data from the control device 4 of the fuse 1 to the higher-level computer system 12 and/or to a control device 4 of a different electronic fuse begins with a start command of the higher-level computer system 12 and/or of the control device 4 of the other fuse from the higher-level computer system 12 or from the control device 4 of the other fuse to the control device 4 of the fuse 1 via the data bus 9. For example, the control device 4 of the fuse, after receiving the start command, can perform the transmission periodically continuing until an end of the data transmission. As a result, the control device 4 of the fuse optionally transmits the compressed data of the parameter characteristics of a time sampling window to the higher-level computer system and/or to the control device of a different fuse in bursts.

A further variant of the proposed method thus provides as a first step of the data compression the formation of a signal from feature vectors 62138 (stream of feature vectors with n vector components and n as a dimension of the feature vectors) from the parameter signal 62103. Such a signal of the feature vectors 62138 can comprise a plurality of data signals. It therefore represents a temporal sequence of more or less complex data/signal structures. In the simplest case, it can be understood as a vector signal consisting of a plurality of sub-signals.

For example, it may be expedient to form a first and/or higher time derivative of the parameter signal 62103 or the single or multiple integral of the parameter signal, which then are sub-signals within the signal of the feature vectors 62138.

Finally, it may be expedient to detect the occurrence of predetermined signal objects in the parameter signal 62105 by matched filters 62104.1 to 62104.n, and to form an intermediate parameter signal bundle 62123 from, for example, an intermediate parameter signals 62123.1 to 62123.n. An intermediate parameter signal of the intermediate parameter signals 62123.1 to 62123.n optionally signals the appearance of the corresponding signal object of some of the predetermined signal objects. However, because the number of signal objects that the control device 4 of the fuse 1 is to detect is generally very large, an intermediate parameter signal of the intermediate parameter signals 62123.1 to 62123.n typically signals the appearance of a signal object, the element of a set of predetermined signal objects. Typically, a signal object to be detected responds to the intermediate parameter signals of a plurality of matched filters. The disclosure understands a matched filter to be a filter that optimizes the signal-to-noise ratio (SNR). The control device 4 of the fuse 1 is intended to detect the predefined signal objects in the distorted parameter signal 62103. The terms correlation filter, signal-adapted filter (SAF) or just adapted filter are frequently also found in the literature for the matched filter. The matched filter serves to optimally determine the presence (detection) of the amplitude and/or the position of a known signal form, in this case the predetermined signal object, in the presence of faults (parameter estimation). These faults can, for example, be signals of EMC couplings of other lines or electromagnetic radiators, etc.

The n matched filter output signals of the n matched filters then form the n intermediate parameter signals 62123.1 to 62123.n of the intermediate parameter signal bundle 62123, which then optionally forms at least sub-signals within the signal of the feature vectors 62138 according to an affine mapping.

The feature vector extraction 62111 can signal specific events in separate additional sub-signals of the intermediate parameter signal bundle 62123. These events are optionally also signal basic objects within the meaning of the disclosure. Signal basic objects therefore comprise not only signal forms, such as square-wave pulses or wavelets or wave trains, but also prominent points in the characteristic of the parameter signal 60103 and/or in the characteristic of signals derived therefrom, which can obtain the feature extraction 62111, for example by filtering from the parameter signal 62103.

Another signal, which can be an additional sub-signal of the intermediate parameter signal bundle 62123, can detect, for example, whether a filtered parameter signal 62103 crosses a specified threshold value. This is also a signal that signals the presence of a signal basic object within the parameter signal by means of an intermediate parameter signal of the intermediate parameter signal bundle 62123.

Another signal, which can be an additional sub-signal of the intermediate parameter signal bundle 62123, can, for example, detect whether a filtered parameter signal 62103 crosses a specified threshold value, which can be identical to the aforementioned threshold value, in an ascending direction. It is therefore a signal that signals the presence of a signal basic object within the parameter signal 62103 by means of an intermediate parameter signal of the intermediate parameter signal bundle 62123.

Another signal, which can be an additional sub-signal of the intermediate parameter signal bundle 62123, can, for example, detect whether a filtered parameter signal 62103 crosses a specified threshold value, which can be identical to one or both of the threshold values specified immediately above, in a descending direction. It is therefore a signal that signals the presence of a signal basic object within the parameter signal 62103 by means of an intermediate parameter signal of the intermediate parameter signal bundle 62123.

Another signal, which can be an additional sub-signal of the intermediate parameter signal bundle 62123, can, for example, detect whether a filtered parameter signal 62103 has a maximum above a threshold value which can be identical to one or more of the aforementioned three threshold values. It is therefore a signal that signals the presence of a signal basic object within the parameter signal 62103 by means of an intermediate parameter signal of the intermediate parameter signal bundle 62123.

Another signal, which can be an additional sub-signal of the intermediate parameter signal bundle 62123, can, for example, detect whether a filtered parameter signal 62103 has a minimum above a threshold value which can be identical to one or more of the aforementioned four threshold values. It is therefore a signal that signals the presence of a signal basic object within the parameter signal 62103 by means of an intermediate parameter signal of the intermediate parameter signal bundle 62123.

The feature extraction 62111 optionally evaluates whether the at least one preceding maximum of the parameter signal 62103 has a minimum distance to the minimum in order to avoid detection of noise. Other filterings by feature extraction 62111 are conceivable at this point. The feature extraction 62111 can also optionally check whether the time interval between this minimum and a preceding maximum is greater than a first minimum time interval. When these conditions are satisfied, the feature extraction 62111 optionally sets a flag or signal, the value of which itself is in turn optionally an additional intermediate parameter signal of the intermediate parameter signal bundle 62123.

Likewise, the feature extraction 62111 should check in an analogous manner whether the temporal and amplitude-related and other distances of the other signal objects satisfy certain plausibility requirements, such as minimum time intervals and/or minimum distances. Even from these tests, the feature extraction 62111 can optionally derive further sub-signals as additional intermediate parameter signals of the intermediate parameter signal bundle 62123, which thus further increase the dimensions of the intermediate parameter signal bundle 62123.

If necessary, the significance increase unit 62125 can also transform the intermediate parameter signal bundle 62123 into a signal of the feature vectors 62138 that is increased in significance, e.g., by linear mapping or a higher-order matrix polynomial. The disclosure previously already mentioned the LDA matrix 62126 in this context.

According to the proposed method or the technical teaching of the disclosure, the distance determination device or classifier 62112 carries out the detection and classification of signal objects into recognized signal object classes within the parameter signal 62103 in cooperation with the feature extraction 62111 on the basis of the intermediate parameter signal bundle 62123 or the significant signal of the feature vectors 62138.

If, for example, the amplitude of the output signal of a matched filter is in the form of an intermediate parameter signal, and thus a sub-signal of the intermediate parameter signal bundle 62123 above any threshold specific to the matched filter, the control device 4 can already evaluate as detected the signal object for the detection of which the matched filter is optionally primarily designed. The control device 4 optionally also takes into account other parameters. If the higher-level computer system 12 has, for example, switched a load on or off at a different location in the supply network, the electrical current of which flows through the fuse, and if the higher-level computer system 12 has beforehand informed all fuses about the intention to switch this load on or off, the fuse then expects a change in current within an established period of time after receipt of this message or within a period of time which the higher-level computer system 12 optionally indicates with the message about the pending event. If the change in the signal form of the parameter signal 62103, for example the occurrence of a jump in the parameter signal 62103, corresponds locally to an expected signal form, this is the corresponding event.

The higher-level computer system 12 can, for example, instruct the control device 4 by means of a data command via the data bus 9 to signal the occurrence of the announced event to the higher-level computer system 12 by means of a data message via the data bus 9.

The higher-level computer system 12 can, for example, instruct the control device 4 by means of a data command via the data bus 9 to signal the non-occurrence of the announced event to the higher-level computer system 12 via the data bus 9 within an agreed or specified time window by means of a data message.

The higher-level computer system 12 can, for example, instruct the control device 4 by means of a data command via the data bus 9 to signal the non-occurrence of the announced event to the higher-level computer system via the data bus 9 within an agreed or specified time window with specified parameters 12 by means of a data message.

The higher-level computer system 12 can, for example, instruct the control device 4 by means of a data command via the data bus 9 to store the occurrence of the announced event in the log file of the fuse 1, for example together with a time stamp.

The higher-level computer system 12 can, for example, instruct the control device 4 by means of a data command via the data bus 9 to store the non-occurrence of the announced event within an agreed or specified time window in the log file of the fuse 1, for example together with a time stamp.

The higher-level computer system 12 can, for example, instruct the control device 4 by means of a data command via the data bus 9 to store the non-occurrence of the announced event within an agreed or specified time window with specified parameters in the log file of the fuse 1, for example together with a time stamp.

The higher-level computer system 12 can, for example, instruct the control device 4 by means of a data command via the data bus 9, to adopt certain measures, for example the opening of the circuit breaker 17, during the non-occurrence of the announced event within an agreed or specified time window.

The higher-level computer system 12 of the control device 4 of the fuse optionally signals the priority with which the control device 4 of the fuse is to transmit these data messages to the higher-level computer system 12 via the data bus depending on the monitoring result. The data messages of the control devices 4 of the fuses in the supply network 200 and the data messages of the higher-level computer system 12 optionally comprise information about the priority of the corresponding data message. The data bus and the data bus protocol are optionally a data bus system that allows a wired OR connection. The bus participants of the data bus 9 can then simultaneously transmit to the data bus 9 without physical damage to the data bus interfaces 10, 610 of the control devices 4 of the fuses or of the higher-level computer system 12 occurring. The bus participants transmit the information about the priority of the corresponding data message at the beginning of the data message. The information about the priority of the corresponding data message data is optionally used for the data message with the higher priority. The data bus interface of that bus participant which is currently transmitting a data message of low priority detects this bus collision, because the information about the priority of its data message is suppressed by the information about the priority of the data message with the higher priority. The data bus interface of this bus participant thus determines that there has been a bus collision and that obviously a bus participant is transmitting with a higher priority and immediately adjusts the transmission of its data packet so as not to endanger the transmission of the data message of a different bus participant with a higher priority. If the affected bus participant detects the end of the higher-priority data message, it starts the next transmission attempt.

The data of the compressed parameter signal characteristics of the physical parameters are transmitted via the data bus 9 from the control device 4 of the fuse 1 to the higher-level computer system 12 and/or to control devices 4 of other fuses optionally with differently prioritized data messages. The transmission of data of the compressed parameter signal characteristics of the physical parameters, which are safety-relevant information, is prioritized via the data bus 9 from the control device 4 of the fuse 1 to the higher-level computer system 12 and/or to control devices 4 of other fuses. Likewise, the commands from the higher-level computer system 12 to the fuses are transmitted with very high priority if commands are involved that are intended to terminate or contain the safety-endangering states or which are otherwise relevant to safety. Optionally, the communication takes place via the data bus 9.

In the detection of each detected signal object, the control device 4 typically assigns at least one associated signal object parameter or specifies this for this signal object. Optionally, the associated signal object parameter is optionally a time stamp which, for example, indicates when the control device 4 has detected the signal object. The time stamp can relate, for example, to the temporal beginning of the signal object in the parameter signal 62103 or the temporal end or the temporal position of the temporal centroid of the signal object in the parameter signal 62103, etc. Other signal object parameters, such as amplitude, stretching, etc., are also conceivable. In one variant of the proposed method, the control device 4 thus transmits at least one of the associated signal object parameters with a symbol for optionally at least one detected signal object of the signal object sequence database 62116. The signal object parameter is, for example, optionally a time value as a time stamp and indicates a time position which is suitable for being able to deduce the time of an event in the supply network throughout the supply network.

The control device 4 of the fuse finally then prioritizes the detected signal objects in the form of associated symbols with time stamps, optionally in each case together with the associated signal object parameters. The transmission can also be carried out in more complex data structures (records). For example, it is conceivable to first transmit the instants of the detected safety-relevant signal objects and then the detected signal objects of the safety-relevant signal objects. This further reduces the latency.

In one variant of the proposed method, the evaluation of the intermediate parameter signal bundle 62123 and/or the significant signal of the feature vectors 62138 can take place in such a way that one or more distances between the signal of the feature vectors 62138 and one or more signal basic object prototypes are formed for detectable signal basic objects. Such a distance can be Boolean, binary, discrete, digital, or analog. All distance values are optionally linked to one another in a nonlinear function. The control device 4 can thus discard this feature vector in certain combinations of values of vector components of a feature vector of the signal of the feature vectors 62138. Within the meaning of this disclosure, this discarding is a nonlinear process.

Conversely, signal basic objects and/or signal objects can also be different in the parameter signal 62103. This first relates to the amplitude of a signal object and/or signal basic object in the parameter signal 62103. If the amplitude is sufficient in the parameter signal 62103, a matched filter substantially optimized for the detection of a class of signal basic objects and/or signal objects provides an intermediate parameter signal above a specified threshold value. In this case, for example, this class of signal objects and/or signal basic objects (e.g., triangular signal) can then already be assigned a detected signal object or signal basic object at this instant of the exceeding. In this case, the distance between the current feature vector of the signal of the feature vectors 62138 and the prototypical feature vector of the prototype database 62115 falls below one or more predetermined distance values.

In a further variant of the method, at least one signal object class is wavelets, the presence of which in the parameter signal 62103 is estimated and thus detected by estimating devices (e.g., matched filters) and/or estimation methods (e.g., estimating programs that run in a digital signal processor), which the control device 4 of the fuse executes. The disclosure uses the term wavelet to denote functions which can be used as a basis for a continuous or a discrete wavelet transform. The word “wavelet” is a reformulation from the French “ondelette,” which means “small wave” and was translated into English in part literally (“onde”→“wave”), in part phonetically (“lette”→“let”). The term “wavelet” was coined in the 1980s in geophysics (Jean Morlet, Alex Grossmann) for functions which generalize the short-term Fourier transform, but has been used exclusively for its current standard meaning since the late 1980s. In the 1990s, a true wavelet boom occurred, triggered by the discovery of compact, constant (up to any order of differentiability) and orthogonal wavelets by Ingrid Daubechies (1988), and the development of the fast wavelet transform algorithm (FWT) with the aid of the multiscale analysis (multiresolution analysis—MRA) by Stephane Mallat and Yves Meyer (1989).

In contrast to the sine and cosine functions of the Fourier transform, the most widely used wavelets have not only locality within the frequency spectrum, but also in the time domain. “Locality” is to be understood in the sense of small spread. The probability density is the normalized square of the absolute value of the function in question or of the Fourier transform thereof. The product of both variances is always greater than a constant, analogous to the Heisenberg uncertainty principle. Arising from this limitation were, in the functional analysis, the Paley-Wiener theory (Raymond Paley, Norbert Wiener), a precursor to the discrete wavelet transform, and the Calderón-Zygmund theory (Alberto Calderón, Antoni Zygmund), which corresponds to the continuous wavelet transform.

Although the integral of a wavelet function is always 0 in professional use, the wavelet function therefore generally assumes the form of waves running outward (becoming smaller)(i.e., “small waves” =ondelettes=wavelets). However, within the meaning of this disclosure, wavelets which have an integral different from 0 should also be permissible. The rectangular and triangular wavelets described below are mentioned by way of example here. This further interpretation of the term “wavelet” is widespread where American English is spoken and is therefore known. This further interpretation shall also apply here in this document.

Important examples of wavelets having a 0-integral are the Haar wavelet (Alfréd Haar 1909), the Daubechies wavelet (around 1990) named after Ingrid Daubechies, the Coiflet wavelets, that she likewise designed, and the rather theoretically significant Meyer wavelet (Yves Meyer, around 1988).

Wavelets exist for spaces of any dimensions, and usually a tensor product of a one-dimensional wavelet base is used. Due to the fractal nature of the two-scale equation in the MRA, most wavelets have a complicated shape and usually do not have a closed form. This is of particular importance because the aforementioned feature vector signal is multi-dimensional, and therefore allows the use of multi-dimensional wavelets for signal object detection.

A special variant of the proposed method is therefore the use of multi-dimensional wavelets having more than two dimensions for signal object detection by the control device 4 of the fuse. The wavelets are signal basic objects within the meaning of the disclosure. In particular, the disclosure proposes the use of corresponding matched filters for detecting such wavelets having more than two dimensions in order to, in some cases, supplement the feature vectors of the signal of the feature vectors 62138 by further sub-signals suitable for detection. The feature extraction 62111 therefore optionally uses methods of the wavelet transform for generating the signal of the feature vectors 62138.

A particularly suitable wavelet for the analysis and compression of the parameter signal is, for example, a triangular wavelet. This is distinguished by a starting time of the triangular wavelet, a substantially linear rise in time in the wavelet amplitude that follows the starting time of the triangular wavelet in time up to a maximum of the amplitude of the triangular wavelet, and a substantially linear drop in time in the wavelet amplitude that follows the maximum of the triangular wavelet in time until reaching an end of the triangular wavelet.

A further particularly suitable wavelet is a rectangular wavelet, which also includes trapezoidal wavelets within the meaning of this disclosure. A rectangular wavelet is distinguished by a starting instant of the rectangular wavelet followed by a rise in the wavelet amplitude of the rectangular wavelet with a first temporal steepness of the rectangular wavelet up to a first plateau instant of the rectangular wavelet. Following the first plateau instant of the rectangular wavelet is a persistence of the wavelet amplitude with a second steepness of the wavelet amplitude up to a second plateau instant of the rectangular wavelet. The second plateau instant of the rectangular wavelet is followed by a drop with a third temporal steepness until reaching the temporal end of the rectangular wavelet. In this case, the magnitude of the second temporal steepness is less than 10% of the magnitude of the first temporal steepness and less than 10% of the magnitude of the third temporal steepness.

Instead of the wavelets described above, the use of other two-dimensional wavelets, such as a sine half-wave wavelet, which likewise has an integral unequal to 0, is also possible.

It is proposed that, when wavelets are used by the feature extraction 62111, the time shift of the relevant wavelet of the detected signal basic object is used as a signal basic object parameter. For example, the control device 4 can determine this shift by correlation. The control device 4 can calculate a correlation, for example, by means of a correlation integral or the like. The document submitted refers here to the website https://de.wikipedia.org/wiki/Korrelation_(Signalverarbeitung). The disclosure further proposes that, when wavelets are used, the control device 4 optionally uses the instant when the level of the output of a matched filter suitable for detecting the relevant wavelet is exceeded, i.e., the corresponding intermediate level signal, above a predefined tenth threshold value for this signal basic object or this wavelet.

A further possible signal object parameter that the control device 4 can determine is a temporal compression or extension of the relevant wavelet of the signal basic object. Likewise, the control device 4 can determine an amplitude of the wavelet of the signal basic object.

It was recognized in the development of the proposal for the method disclosed here that it is advantageous to transmit the data of the detected signal basic objects and detected signal objects of potentially safety-relevant events first from the control device 4 to the higher-level computer system 12 via the data bus 9, and only then the subsequent data of the signal basic objects and signal objects associated with less critical events. Within the scope of the detection process, the control device 4 can assign scores to the different signal objects and signal basic objects, which scores are relevant for a section of the parameter signal and indicate the probability, which the control device 4 assigns according to the estimation algorithm used, of this signal object or signal basic object being present in the parameter signal 62103. In the simplest case, such a score is binary. However, it is optionally a complex, real or integer number. For example, it can be the determined distance. If a plurality of signal objects or signal basic objects have a high score value, it is expedient that, in some cases, the control device 4 also transmits the data of detected signal objects and/or signal basic objects having lower score values to the higher-level computer system. In order to enable the higher-level computer system to handle these correctly, the control device 4 should transmit not only the datum (symbol) of the detected signal object or the detected signal basic object and the time stamp for the corresponding signal object, but also the determined score value. Instead of transmitting only the datum (symbol, index) of the detected signal object or of the detected signal basic object and the time stamp for the signal object or signal basic object corresponding to this symbol, the control device 4 can additionally also transmit the datum (symbol, index) of the signal object or signal basic object having the second smallest distance and its time stamp for the signal object or signal basic object corresponding to this second most probable symbol. Thus, in this case, the control device 4 transmits a hypothesis list of two signal basic objects or a signal object hypothesis list from two detected signal objects and their time positions and additionally associated score values to the higher-level computer system 12. Of course, the transmission of a hypothesis list consisting of more than two symbols for more than two detected signal basic objects and time positions thereof and additionally associated score values to the higher-level computer system 12 is also conceivable. Of course, the transmission of a signal object hypothesis list consisting of more than two symbols for more than two detected signal objects and time positions thereof and additionally associated score values to the higher-level computer system 12 is also conceivable.

Optionally, the data of the detected signal objects or of the detected signal basic objects and of the associated data, such as time stamps and score values of the corresponding detected signal objects or of the detected signal object parameters, i.e., of the associated signal object parameters or of the associated signal basic object parameters, is transmitted according to the FIFO principle. This ensures that the control device 4 always transmits the data of the events at the same priority with the least amount of delay to the higher-level computer system 12.

In addition to the transmission of measurement data of physical parameters and/or the associated temporal parameter characteristics, the control device 4 of a fuse 1 can also carry out the transmission of error states of the fuse 1. The control device 4 of the fuse signals the occurrence of an error state to the higher-level computer system 4, optionally in particular if the control device 4 of the fuse determines by one or more self-testing devices of the control device 4 and/or of the fuse that a defect is present and the data previously transmitted to the higher-level computer system 12 could be potentially faulty. The control device 4 of the fuse 1 thus ensures that the higher-level computer system 12 can become aware of a change in the evaluation of the measurement data of the fuse at the earliest possible instant and can discard it or treat it differently. This is of particular importance for safety-critical interventions that the higher-level computer system 12 could carry out. Such safety-critical interventions must be performed by the higher-level computer system 12 only if the underlying data of the fuses of the supply network 200 have a corresponding confidence level. In contrast, the transmission of the measurement data, i.e., for example, the datum of the detected signal object or of the detected signal basic object and/or the transmission of the one associated signal object parameter or of an associated signal basic object parameter, is reset and thus given lower priority. Of course, a termination of the transmission when an error occurs in the control device 4 of the fuse 1 is conceivable. In some cases, however, it may happen that an error appears, but its presence is uncertain. In this respect, in such cases, the continuation of a transmission by the control device 4 of the fuse 1 may be displayed under certain circumstances. The transmission of safety-critical errors of the fuse and/or connected supply lines is thus optionally given higher priority.

In addition to the wavelets already described having an integration value of 0 and the signal sections, which are additionally referred to here as wavelets, with an integration value different from 0, specific instants in the characteristic of the parameter signal can also be regarded as a signal basic object within the meaning of this document, which the control device 4 of the fuse can use for a data compression and which the control device 4 can transmit to the higher-level computer system instead of sampling values of the parameter signal. This subset in the set of possible signal basic objects is referred to below as signal instants. The signal instants are thus a special form of the signal basic objects within the meaning of the document presented.

A first possible signal instant and, thus, a signal basic object is an intersection of the amplitude of a parameter signal 62103 with the amplitude of a threshold signal within the control device 4 of the fuse 1 in the ascending direction.

A second possible signal instant and, thus, a signal basic object is an intersection of the amplitude of a parameter signal 62103 with the amplitude of a threshold signal within the control device 4 of the fuse 1 in the descending direction.

A third possible signal instant and, thus, a signal basic object is a maximum of the amplitude of a parameter signal 62103 above the amplitude of a threshold signal within the control device 4 of the fuse 1.

A fourth possible signal instant and, thus, a signal basic object is a minimum of the amplitude of a parameter signal 62103 above the amplitude of a threshold signal within the control device 4 of the fuse 1.

If necessary, it may be expedient for the control device 4 of the fuse 1 to use signal-instant-specific threshold signals for these four exemplary types of signal instants and further types of signal instants.

The temporal sequence of signal basic objects is typically not arbitrary. This is used in the technical teaching of the disclosure, because it is optionally not the signal basic objects, which are simpler in nature, that are to be transmitted, but instead detected patterns of sequences of these signal basic objects, which then represent the actual signal objects. If the control device 4 of the fuse 1 is expecting a triangular wavelet in a parameter signal 62103 of sufficient amplitude, for example, the control device 4, in addition to a corresponding minimum level at the output of a matched filter suitable for detection of such a triangular wavelet, can:
1. expect the occurrence of a first possible signal instant with an intersection of the amplitude of the parameter signal 62103 with the amplitude of a threshold signal in the ascending direction and next in time sequence
2. expect the occurrence of a third possible signal instant point with a maximum of the amplitude of the parameter signal 62103 above the amplitude of a threshold signal and next in time sequence
3. expect the occurrence of a second possible signal instant with an intersection of the amplitude of the parameter signal 62103 with the amplitude of a threshold signal in the descending direction
in temporal correlation to the exceeding of said minimum level at the output of said matched filter. In this example, the exemplary signal object of a triangular wavelet thus consists in the predefined sequence of four signal basic objects. These four signal basic objects are: the minimum level of the intermediate parameter signal at the output of the associated matched filter, as the first, and the detected three signal instants, as second to fourth. The control device 4 then replaces this signal basic object with a symbol which is typically the index of the signal object sequence database for this signal object. The control device 4 then optionally transmits this symbol together with its occurrence time, the time stamp, to the higher-level computer system 12. This exceeding of said minimum level at the output of said matched filter is, moreover, a further example of a fifth possible signal instant and, thus, a further possible signal basic object.

The resulting grouping and temporal sequence of detected signal basic objects can itself be detected, for example by the Viterbi estimator 62113, as a predefined, expected grouping or temporal sequence of signal basic objects and can thus itself represent in turn a signal basic object. A sixth possible signal instant and, thus, a signal basic object is thus the occurrence of such a predefined grouping and/or temporal sequence of other signal basic objects. It is thus conceivable to arrange a plurality of Viterbi estimators 62113 and associated databases one behind the other in the signal path.

If the control device 4 of a fuse 1 detects such a grouping of signal basic objects or temporal sequence of such signal object classes in the form of a signal object, the transmission of the symbol of this detected summarizing prototypical signal object of the signal object sequence database 62116 and at least the one associated signal object parameter optionally follows instead of the transmission of the individual signal basic objects, because this saves considerable data bus capacity on the data bus 9. However, there may also be cases in which the control device 4 transmits both to the higher-level computer system 12. In this case, the control device 4 transmits the datum (symbol) of the prototypical signal object, which is a predefined temporal sequence and/or grouping of other signal basic objects. In order to achieve a compression, it is advantageous if at least one signal object (symbol) is then not transmitted to at least one of these other signal basic objects.

A temporal grouping of signal basic objects in the form of a signal object is present in particular if the time interval of these signal basic objects does not exceed a predefined distance. In the aforementioned example, the propagation time of the signal should be considered in the matched filter. Typically, the matched filter should be slower than the comparators. Therefore, the change in the output signal of the matched filter should be in a fixed temporal relationship to the temporal occurrence of the relevant signal instants.

A method for transmitting fuse data from a fuse to a higher-level computer system 12, in particular in a vehicle, and/or the control device 4 of a different fuse is thus proposed here, which method begins with the formation of a time-discrete parameter signal 62103 consisting of a sequence of sampling values. A temporal datum (time stamp) is optionally assigned to each sampling value. The determination follows of at least two intermediate parameter signals in each case regarding the presence of a signal basic object substantially associated with the corresponding intermediate parameter signal with the aid of at least one suitable filter (for example a matched filter) from the sequence of sampling values of the parameter signal 62103. The resulting intermediate parameter signals are likewise designed as a time-discrete sequence of corresponding intermediate parameter signal values, which are each correlated with a datum (time stamp). Thus, precisely one temporal datum (time stamp) is optionally assigned to each intermediate parameter signal value. These intermediate parameter signals taken together are referred to below as intermediate parameter signal bundles 62123. The intermediate parameter signal bundle 62123 is thus designed as a time-discrete sequence of signal values of the intermediate parameter signal bundle 62123, each with n intermediate parameter signal values, which consist of the intermediate parameter signal values and further intermediate parameter signal values, each with the same temporal datum (time stamp). Here, n is the dimensionality of the individual signal values of the intermediate parameter signal bundle 62123, which are optionally the same from one vector value of the intermediate parameter signal bundle 62123 to the next vector value of the intermediate parameter signal bundle 62123. Each signal value thus formed of the intermediate parameter signal bundle 62123 is assigned this corresponding temporal datum (time stamp) by the control device 4 of the fuse 1. The evaluation follows of the time characteristic of the signal of the intermediate parameter signal bundle 62123 in the resulting n-dimensional phase space as well as the deduction of a detected signal object with determination of an evaluation value (e.g., the distance). As explained above, a signal object typically consists of a temporal sequence of signal basic objects. A symbol is typically assigned here to the signal object in a predefined manner. Metaphorically speaking, the control device 4 of the fuse 1 in this case checks whether the point, to which the n-dimensional signal of the intermediate parameter signal bundle 62123 points in the n-dimensional phase space, approaches predetermined points in this n-dimensional phase space closer than a predetermined maximum distance on its path through the n-dimensional phase space in a predetermined temporal sequence. The signal of the intermediate parameter signal bundle 62123 thus has a time characteristic. The control device 4 of the fuse 1 then calculates an evaluation value (e.g., a distance) which, for example, can reproduce the probability of the presence of a certain sequence of signal basic objects. The comparison of this evaluation value, which is in turn associated with a temporal datum (time stamp), is then carried out with a threshold vector to form a Boolean result that can have a first and a second value. If this Boolean result for this temporal datum (time stamp) has the first value, the symbol of the signal object and the temporal datum (time stamp) associated with this symbol are transmitted by the control device 4 of the fuse 1 from the control device 4 of the fuse 1 to the computer system. If necessary, the control device 4 can transmit further parameters depending on the signal object detected.

### Recursive Data Compression (FIG. 73)

The reconstruction of a reconstructed parameter signal model vector 74610 from the detected signal objects 62122 and the signal basic objects 62121 during the compression is particularly advantageous.

For this purpose, the control device of the fuse 1 optionally stores the q sampling values of the parameter signal 62103 of a temporal sampling window, which values the control device 4 has detected in the temporal sampling window, in a first sampling value memory 74601. The number q here is a positive integer which indicates the number of sampling values in the first sampling value memory 74601 of the control device 4 of the fuse 1. As soon as the sampling window is temporally at an end, the sampling value memory 74601 r deletes the oldest sampling values in its memory cells. The number r is a positive integer. Then, the first sampling value memory 74601 optionally shifts all the sampling values by the same number r of memory cells in the first sampling memory 74601 in such a way that the oldest non-deleted sampling value is in the memory cell of the first sampling memory 74601 in which the oldest, previously deleted sampling value was previously stored. As a result, after the end of a sampling window in a new temporal sampling window, the first sampling value memory 74601 is successively refilled with the new sampling values of the new sampling window, while it always discards the oldest sampling values in order to create space for these new sampling values that are moved up in the sequence.

The q sampling values in the first sampling value memory 74601 form a q-dimensional first sampling value vector 74620, which the first sampling value memory 74601 optionally outputs. Because the content of the first sampling value vector 74620 is unstable during the writing of the sampling values of the parameter signal 62103 into the first sampling value memory 73607, a second sampling memory 74625 adopts the sampling value vector 74620 from the first sampling value memory 74601 at the temporal end of each sampling time window.

The control device 4 of the fuse 1 generates the parameter signal model vector 74610 from the cumulative linearly superposed signal characteristic models of the individual detected signal objects and/or signal basic objects.

The control device 4 subtracts the values of the vector components of the stored parameter signal model vector 74635 from the second sampling value vector 74630 by means of a vector subtractor 74602 and thereby forms a vector residual signal 73660. This better suppresses signal objects similar to the selected signal object detected with a higher probability. As a result, the weaker signal objects and signal basic objects also emerge better in the vector residual signal 73660. The control device 4 can then better recognize the weaker signal objects and signal basic objects in the residual signal 73660. (See also FIG. 73). The method proposed in the technical teaching of the disclosure thus optionally also comprises a subtraction of the stored parameter signal model 74635 made up of the already detected signal objects and signal basic objects from the second sampling value vector 74630 in the second sampling value memory 74625 for forming the vector residual signal 73660. The control device 4 then in turn uses the vector residual signal 73660 thus formed for the formation of the signal of the feature vectors 62138 by means of the feature extraction 62111. By means of the feature extraction 62111 and by means of the distance calculation 62112 or the classifier 62112 and, where applicable, the Viterbi estimator 62113, the control device then determines that signal object of the signal object sequence database 62116 or that signal basic object of the prototype database 62115 which has the next lowest probability. Because the first detected signal object or signal basic object has been removed from the second sampling value vector of the second sampling value memory 74625 according to its weighting and is thereby essentially no longer present in the vector residual signal 73660, the first detected signal object or signal basic object can no longer influence this detection. This form of detection thus provides a better result in the form of a list of detected signal objects or signal basic objects.

A reconstructor 74600 reconstructs the parameter signal with the aid of the detected signal basic objects 62121 and the detected signal objects 62122 and by means of the determined signal basic object parameters and the co-determined signal object parameters and the data from the prototype database 62155 and the data from the signal object sequence database 62116 and by means of the associated time stamps, as if it would only be composed of the detected signal objects 62122 with the co-determined signal object parameters and the determined signal basic object parameters with the co-determined signal basic object parameters taking into account the associated time stamps by adding the corresponding vector values. In this way, a reconstructor 74600 reconstructs the reconstructed parameter signal model vector with q values of vector components corresponding to the q values of the vector components of the second sampling value vector in the second sampling value memory 74625 as a reconstructed parameter signal model vector 74610. The reconstruction memory 74603 temporarily stores the reconstructed parameter signal model vector 74610. The reconstructor 74600 optionally comprises the reconstruction memory 74603. The reconstruction memory 74603 outputs the reconstructed parameter signal model vector 74610 stored in its memory cells as a stored parameter signal model vector 74635 to the vector subtractor 74602; this closes the circle.

However, this detection method is generally slower. It is therefore expedient to first carry out a direct first signal object detection without subtraction during the still ongoing measurement, and then after detection of all sampling values of a sampling window to carry out a repeated pattern recognition with subtraction of the parameter signal model 74610, which does takes longer, but is more precise.

Optionally, this reducing classification of the parameter signal 62103 and the breakdown into prototypical signal objects or signal basic objects are then terminated with the aid of the parameter signal model vector 74610 if the amounts of the sampling values of the vector residual signal 73660 are below the amounts of a predetermined threshold value curve and/or of a threshold value.

In particular, the control device 4 of the fuse executes the data transmission in the vehicle via a serial bidirectional one-wire data bus or a bidirectional, optionally differential, two-wire data bus as a data bus 9. In the case of a one-wire data bus, the body of the vehicle optionally guarantees the electrical return line. Optionally, the control device 4 of the fuse 1 transmits the fuse data to the higher-level computer system 4 in a current-modulated manner. By contrast, the higher-level computer system 12 transmits the data for controlling the fuses to the control devices 4 of the fuses 1 optionally in a voltage-modulated manner. The development of the technical teaching of this document showed that the use of data buses, such as the PSI5 data bus and/or the DSSI3 data bus or a Lin data bus 9 or a CAN data bus 9 or a CAN FD data bus 9 or an Ethernet data bus or a Flexray data bus 9 or an LVDS data bus 9 or an otherwise wired data bus, is suitable. Wireless data transmission paths, for example via a Bluetooth or WLAN data connection or an optical data connection (540) for the data communication of the control device 4 of the fuse 1 with the higher-level computer system 12, are also possible. In this case, the data communication of the computer core 2 of the control device 4 of the fuse 1 optionally runs via a wired or wireless interface (610, 10, 551, 550) of the control device 4.

Furthermore, it has been recognized that it is particularly advantageous to transmit the data to the higher-level computer system at a transmission rate of >200 kbit/s and from the higher-level computer system to the at least one electronic fuse at a transmission rate>10 kbit/s, optionally 20 kbit/s. Furthermore, it was recognized that the transmission of data from the fuse 1 to the higher-level computer system 12 should be modulated to the data bus with a transmission current, the current intensity of which should be less than 50 mA, optionally less than 5 mA, optionally less than 2.5 mA. These buses must be adapted accordingly for these operating values. However, the basic principle remains.

For carrying out the methods described above, a higher-level computer system 12 is required which has a data interface to said data bus 9 and supports the decompression of such compressed data. In general, however, the higher-level computer system 12 will not perform a complete decompression, but instead, for example, will only evaluate the time stamp and the signal object or signal basic object detected by the fuse 1 in question. The fuse 1, which is required for carrying out one of the methods described above, optionally has means for detection of the parameter characteristic by the fuse of physical parameters to be detected, and/or the characteristic of values of parameters which are derived therefrom. These means for detection of the parameter characteristic by the fuse of physical parameters to be detected and/or of the characteristic of parameters derived from values generate corresponding signals 62102 of the temporal parameter value characteristics and/or the corresponding time characteristics of the parameters derived from these parameter value characteristics of the physical parameters. These signals 62602 of the temporal parameter value characteristics and/or the corresponding time characteristics of the parameters derived from these parameter value characteristics of the physical parameters are also referred to as measured value signals by the disclosure. Furthermore, the proposed fuse 1 has devices for processing and compressing these measured value signals and a data interface 10, 610 for transmitting the data of the processed and compressed measured value signals via the data bus 9 to the higher-level computer system 12. The fuse 1 optionally has at least one of the following sub-devices for compression:
matched filters,
comparators,
threshold signal generating devices for generating one or more threshold signals,
differentiators for forming derivatives,
integrators for forming integrated signals,
other filters,
correlation filters for comparing measured value signals or signals derived therefrom to reference signals.

In a particularly simple form, the proposed method for transmitting fuse data from a fuse to a higher-level computer system, in particular in a vehicle, is carried out as follows:

It begins with the switch-on or, if necessary, switching off of a circuit breaker 17 of the fuse 1 by the control device 4 of the fuse. The parameter characteristics of the values of the physical parameters of the fuse to be detected are then detected by the control device 4 of the fuse 1 and a time-discrete measurement signal consisting of a temporal sequence of sampling values, the parameter signal 62103, is formed. A temporal datum (time stamp) is optionally assigned to each sampling value. This temporal datum (time stamp) typically reflects the instant of the sampling. On the basis of this data stream of the parameter signal 62103, for example, a first intermediate parameter signal of a first property is determined by the control device 4 of the fuse 1 with the aid of a first filter of a feature vector extraction 62111 from the sequence of sampling values of the parameter signal 62103. The intermediate parameter signal is in turn optionally formed by the control device 4 of the fuse 1 as a time-discrete sequence of intermediate parameter signal values. Each intermediate parameter signal value is in turn assigned precisely one temporal datum (time stamp) by the control device 4 of the fuse 1. Optionally, this datum corresponds to the most recent temporal datum of a sampling value that was used to form this corresponding intermediate parameter signal value. At the same time, the determination of at least one further intermediate parameter signal of a property associated with this further intermediate parameter signal is optionally made by the control device 4 of the fuse 1 with the aid of a further filter associated with this further intermediate parameter signal from the sequence of sampling values of the parameter signal 62103. The further intermediate parameter signals are optionally each formed in turn as time-discrete sequences of further intermediate parameter signal values. Here too, the same temporal datum (time stamp) as the corresponding intermediate parameter signal value is optionally assigned to each further intermediate parameter signal value by the control device 4 of the fuse 1.

This document hereinafter refers to the first intermediate parameter signal 62123.1 and the further m−1 intermediate parameter signals 62123.2 to 62123.m together as intermediate parameter signal bundle 62123. This intermediate parameter signal bundle 62123 (or else intermediate parameter vector signal) thus represents a time-discrete sequence of vectorial intermediate parameter signal values, which comprise the intermediate parameter signal values and further intermediate parameter signal values each having the same temporal datum (time stamp). This corresponding temporal datum (time stamp) can thus be assigned to each vector value of the intermediate parameter signal bundle 62123 (=parameter signal value) formed in this way.

The control device 4 of the fuse 1 then optionally carries out quasi-continuously the comparison of the values of the vector components of the intermediate parameter signal bundle 62123 of a temporal datum (time stamp) with a threshold vector, the vector components of which are threshold values and which has the same dimension as the intermediate parameter signal bundle 62123, with the formation of a Boolean result that can have a first and a second value. It is also conceivable that the control device 4 maps the intermediate parameter signal bundle 62123 by means of an affine transformation to a feature vector of a signal of the feature vectors 62138. It is expressly also conceivable that the signal of the feature vectors 62138 can be identical to the intermediate parameter signal bundle 62123 if the control device 4 does not carry out a significance increase by means of the LDA matrix 63126.

For example, it is conceivable to compare the magnitude of a first vector component of the current feature vector of the signal of the feature vectors 62138 to a threshold value representing a first vector component of the threshold vector, and to add the Boolean result to a first value if the magnitude of the first vector component of the current feature vector of the signal of the feature vectors 62138 is less than this threshold, and to a second value if this is not the case. If the Boolean result has a first value, then it is then further conceivable to compare the magnitude of a further vector component of the current feature vector of the signal of the feature vectors 62138 to a further threshold value which represents a further component of the threshold vector, and to leave the Boolean result at the first value, if the magnitude of the further vector component of the current feature vector of the signal of the feature vectors 62138 is less than this further threshold value, and to set the Boolean result to the second value if this is not the case. In this way, all further vector components of the current feature vector of the signal of the feature vectors 62138 can be checked by the control device 4. Of course, other classifiers are also conceivable. The comparison to a plurality of different threshold vectors is also possible. These threshold vectors thus represent the prototypes of specified signal forms. They optionally originate from said library. A symbol is in turn optionally assigned to each threshold vector.

Following then, as a last step, is in this case the transmission of the symbol and possibly also of the feature vector signal values and the temporal datum (time stamp) associated with this symbol or feature vector signal value from the fuse 1 to the higher-level computer system 12 if the Boolean result for this temporal datum (time stamp) has the first value.

All other data are thus no longer transmitted. Furthermore, faults are avoided by the multidimensional evaluation.

On this basis, a supply network 200 is thus proposed, having at least one higher-level computer system 12 which is capable of carrying out one of the methods previously presented and having at least two fuses which are also capable of carrying out one of the methods presented above, so that these at least two fuses can communicate with the higher-level computer system 12 by signal object detection and/or signal basic object detection, and are also capable of transmitting, in compacted form, suspected interference signals to the higher-level computer system and to provide this information additionally to the higher-level computer system. Accordingly, the supply network 200 is typically provided such that the data transmission between the at least two fuses and the higher-level computer system 12 runs or can run in accordance with the methods described above. Within the at least two fuses of the supply network 100, a parameter signal 62103 is therefore typically compressed in each case by means of one of the previously proposed methods and transmitted to the higher-level computer system 12. The higher-level computer system here will reconstruct the at least two compressed parameter signals received from the two fuses to form reconstructed parameter signals. The higher-level computer system 12 then treats these reconstructed parameter signals like a single parameter signal for the supply network 200.

The higher-level computer system 12 then carries out a detection of states and/or events in the supply network 200 with the aid of reconstructed parameter signals. As a result, the higher-level computer system can thus detect events, for example, which appear at the same time in a plurality of fuses. Such events can be safety-relevant and appear insignificant and not safety-relevant for the individual fuse. By the correlation of two or more reconstructed parameter signals with one another, the higher-level computer system is capable of detecting, for example, weak short circuits as precursors of serious short circuits between lines, which should actually be isolated from one another.

The higher-level computer system 12 optionally additionally carries out a state analysis for the vehicle with the aid of the reconstructed parameter signals and additional signals of further sensors and/or fuses, in particular the signals of acceleration sensors, temperature sensors 586, gas sensors, smoke sensors, etc.

As the last step, the higher-level computer system 12 optionally creates a status map for the supply network and the loads, power sources, line sections, and fuses located therein from the basis of the detected objects.

A further, easily modified, proposed fuse 1, as shown by way of example in FIGS. 62 and 73, thus optionally comprises a means for detecting the parameter value characteristic of the physical parameters to be detected by the fuse 1 and/or the characteristics of the values of parameters 62100 derived therefrom, a physical interface 62101, a feature extraction 62111, and with an estimator 62122, 67151, 62113 or classifier. The fuse 1 is optionally provided and/or configured to monitor a line between a first line terminal 18 of the fuse 1 and a second terminal 19 of the fuse 1 and to detect parameter characteristics of physical parameters of the fuse 1. The fuse then forms, depending on the detected values, signals 62102 of the temporal parameter value characteristics and/or the corresponding time characteristics of the parameters derived from these parameter value characteristics of the physical parameters. The feature extraction 62111 is optionally provided and/or configured to form—from the signal 62102 of the temporal parameter value characteristics and/or from the corresponding time characteristics of the parameters derived from these parameter value characteristics of the physical parameters—a signal of the feature vectors 62138 in cooperation with a physical interface 62101. The physical interface 62101 converts the detected signal 62102 of the temporal parameter value characteristics and/or the corresponding time characteristics of the parameters derived from these parameter value characteristics of the physical parameters into a parameter signal 62103. This fuse 1 is optionally configured and provided to detect and classify signal objects and/or signal basic objects in the parameter signal 62103 by means of the estimator 67151. At least one associated signal object parameter or an associated signal basic object parameter and a symbol corresponding to the index associated with this signal object corresponding to the index associated with this signal object are optionally assigned by the control device 4 to each signal object 62122 and/or signal basic object that is thus detected and classified. Optionally, at least one associated signal object parameter and a symbol for this signal object are determined by the control device 4 for each thus detected and classified signal object (122). At least the symbol of a detected signal object 62122 and at least of the one associated signal object parameter of this detected signal object 62122 is transmitted to a higher-level computer system 12 via the data bus 9 by the control device 4 of the fuse 1.

The estimator 62150 optionally has a distance determination device 62112 and a prototype database 62115 which defines the signal basic objects either as sequences of prototypical sampling values or as prototypical feature vectors. Likewise, the estimator 62150 optionally has a Viterbi estimator 62113 and a signal object sequence database 62116 which defines the composition of the prototypical signal objects with respect to the prototypical signal basic objects of the prototype database 62155. The estimator 62150 can also use a neural network model 67151. The computer core 2 of the control device 4 of the fuse 1 optionally emulates the neural network model 67151. The feature vectors of the signal of the feature vectors 62138 typically serve as an input value of the neural network model 67151. The detected signal basic objects 62121 and/or the detected signal objects 62122 are optionally the output signals of the neural network model 67151. Of course, the control device 4 of the fuse 1 can also interpret output signals of the neural network model directly as signals which the control device 4 of the electronic fuse causes to execute a predetermined method and/or method step such as the closing or opening of a circuit breaker 17 of the fuse. Furthermore, a Viterbi estimator 62113 can evaluate, for example, signal basic objects determined by the neural network model 67151 and detect signal objects 62122 in the stream of the signal basic objects 62121. In this case, at least one part of the output signals of the neural network model 67151 optionally represents the input signal of the Viterbi estimator 62113.

A proposed method for operation of a fuse 1, in particular by the control device 4 of the fuse 1, therefore comprises the steps according to FIG. 66:
waiting for a characteristic in a parameter signal 62103 of a temporal parameter value characteristic of a physical parameter or a parameter derived therefrom, which parameter is different from the background noise;
switching into a “no signal object ground prototype” state if the characteristic of the parameter signal 62103 is different from background noise, and carrying out a method for detecting signal ground prototypes 62121, in particular a prototype database 62115, in the parameter signal 62103 and for classifying these signal ground prototypes by means of the control device 4 of the fuse 1;
switching into a sequence of states that are associated with the signal ground prototypes of a predefined sequence of signal ground prototypes, in particular a signal object sequence database 62116, if the first signal ground prototype of such a sequence of signal object ground prototypes is detected by the control device 4 of the fuse 1;
following the sequence of the signal ground prototypes until the end of the sequence of signal ground prototypes is reached;
deducing the presence of a signal object associated with this sequence of signal ground prototypes and a signal object associated with this sequence if the end of this sequence of signal ground prototypes is reached and signaling of this signal object;
cancellation (not shown in FIG. 66) of this sequence when time expires and/or in the case of a single or multiple detection of a signal ground prototype at a position of this sequence at which this detected signal ground prototype is not expected or at which in the following position this detected signal ground prototype is not expected; and
return to the state “no signal object ground prototype.”

The above-described compression method corresponds to an associated decompression method 70000, which optionally uses the higher-level computer system 12 for decompression of fuse data of the control device 4 of the fuse 1 in the higher-level computer system 12, which fuse data is compressed and transmitted in this signal-object-oriented and/or signal-ground-object-oriented manner, after it is received by the control device 4 of the fuse 1 via the data bus 9 and said data interfaces 10, 610, 555.

In a first step 70010, new data 70160 to be decompressed which originate from the control computer 4 of the fuse 1 are received in the higher-level computer system 12. This reception is virtually the start signal for the decompression method. The data to be decompressed comprise the data 70160 to be compressed of at least one sampling window. The decompression is optionally carried out by sampling window.

After receiving new data 70160 to be decompressed of at least one sampling window in the higher-level computer system 12, which data originate from the control computer 4 of the fuse 1, a reconstructed parameter signal model 69610 for a sampling window is provided in a further step 70020. This reconstructed parameter signal model of the sampling window should later comprise the reconstructed parameter value characteristic and/or the reconstructed parameter value characteristics of parameters derived from these parameters for this reconstructed sampling window. The parameter signal model 69610 is optionally located in a memory of the higher-level computer system 12. This initial reconstructed parameter signal model 69610 initially comprises only an initial dummy signal 70010—which typically at first essentially has no signal—as optionally only zeros or only a constant value (FIG. 70).

The higher-level computer system 12 now fills this parameter signal model 69610 in a signal-object-specific manner by successive addition of the corresponding prototypical, parameterized signal characteristic of the next signal object. These are those signal objects or signal basic objects which the control device 4 of the fuse 1 has already signaled to the higher-level computer system 12 via the data bus for this sampling window.

In a next step 70030, the higher-level computer system 12 determines the next object to be reconstructed in the received data of the control device 4 of the fuse 1. This next object can be a signal object or a signal basic object. In general, the datum of an index of the prototype database 62115 or an index of the signal object sequence database 62116 of the control device 4 of the fuse 1 represents the object to be reconstructed.

In a subsequent step 70040, the higher-level computer system 12 as appropriate checks whether the next object to be reconstructed is a signal object. If it is a signal basic object, the higher-level computer system optionally treats this signal basic object like a signal object which is a sequence 70060 of signal basic objects having only one signal basic object, namely exactly the one signal basic object to be detected.

If it is a signal object, the higher-level computer system 12 must determine which signal basic objects, among other things, the signal object to be reconstructed comprises. For this purpose, in a further step 70050, the higher-level computer system 12 determines the sequence of signal basic objects which corresponds to the index of the signal object sequence database 62116 of the control device 4 of the fuse 1. For this purpose, the higher-level computer system 12 optionally comprises a signal object sequence database 70116 of the higher-level computer system 12. Typically, the content of the signal object sequence database 70116 of the higher-level computer system 12 corresponds to the content of the signal object sequence database 62116 of the control device 4 of the fuse 1. Typically, the relations between the indices of the signal object sequence database 62116 of the control device 4 of the fuse 1 and the signal object sequence database 70116 of the higher-level computer system 12 are one-to-one. The relations between the indices of the signal object sequence database 62116 of the control device 4 of the fuse 1 and of the signal object sequence database 70116 of the higher-level computer system 12, on the one hand, and the associated sequences of signal basic objects in the data sets of the signal object sequence database 62116 of the control device 4 of the fuse 1 and the signal object sequence database 70116 of the higher-level computer system 12 are optionally bijective.

As a result, the higher-level computer system 12 can now replace the signal object to be reconstructed with a sequence 70060 of signal basic objects which are to be reconstructed.

In a next step 70070, the higher-level computer system 12 determines the next signal basic object of the sequence 70060 of signal basic objects that the higher-level computer system 12 is to reconstruct. Typically, an index of the prototype database 62115 of the control device 4 of the fuse 1 or an index of a prototype database 70115 of the higher-level computer system 12 represents in each case a corresponding signal object to be reconstructed of this sequence 70060 of signal basic objects. The prototype database 62115 of the control device 4 of the fuse 1 and the prototype database 70115 of the higher-level computer system 12 optionally comprise substantially corresponding database entries at least in the portion of their data that is important for the reconstruction, because only then is a reconstruction possible in the higher-level computer system 12.

In a next step 70070, the higher-level computer system 12 reconstructs this next signal basic object to be reconstructed of the sequence 70060 of signal basic objects. For this purpose, the higher-level computer system 12 determines the signal characteristic of the signal basic object to be reconstructed according to the entries of the prototype database 70115 of the higher-level computer system 12. In this case, the signal basic object to be reconstructed generally represents an index of a data set 70090, 70100 of the prototype database 70115 of the higher-level computer system 12. Optionally, this data set 70090, 70100 of the prototype database 70115 of the higher-level computer system 12, which is marked by the signal basic object to be reconstructed, comprises a prototypical feature vector 70090 or prototypical parameter value characteristics 70100 for the parameter value characteristics of the physical parameters and/or of the parameters derived therefrom. Optionally, the prototype database 70115 of the higher-level computer system 12 comprises in its data sets either only prototypical feature vectors or alternatively prototypical parameter value characteristics for the parameter value characteristics of the physical parameters and/or of the parameters derived therefrom. Nevertheless, it is conceivable that the prototype database 70115 of the higher-level computer system 12 comprises both data forms. Where applicable, the higher-level computer system checks in a test step 70080 whether the relevant data set 70090, 70100 of the prototype database 70115 of the higher-level computer system 12 comprises a prototypical feature vector 70090 and no parameter value characteristics 70100, or prototypical ones, for the parameter value characteristics of the physical parameters and/or of the parameters derived therefrom. If the higher-level computer system 12 has only one prototypical feature vector 70090 in its prototype database 70115, the higher-level computer system 12 converts the prototypical feature vector 70100—for example by means of a signal construction device or a signal reconstruction method 70110—into prototypical parameter value characteristics 70100 for the parameter value characteristics of the physical parameters and/or of the parameters derived therefrom.

In the next step 70120, the higher-level computer system 12 parameterizes the prototypical parameter value characteristics 70100 for the parameter value characteristics of the physical parameters and/or of the parameters derived therefrom:
a) corresponding to the parameters of the data set for this signal basic object from the prototype database 70115 of the higher-level computer system 12, and
b) corresponding to the parameters of the data set for this signal object from the signal object sequence database 70116 of the higher-level computer system 12, and
c) corresponding to the data transmitted by the control device 4 of the fuse 1 for this signal object.

These parameters typically relate essentially to instants relative to a corresponding time reference point and/or amplitudes relative to other components of the respective signals. The reference instants of the data that the control device 4 of the fuse 1 transmits is typically a predefined reference instant within the time sampling window, for example the beginning or the middle or the end of the sampling window. A reference instant of a signal object is typically a predefined reference instant within the signal object, for example the beginning or the middle or the end of the signal object.

In this step 70120, the higher-level computer system 12 parameterizes the prototypical parameter value characteristics 70100 for the parameter value characteristics of the physical parameters and/or the parameters derived therefrom, thus, to form parameterized parameter value characteristics 70130 for the parameter value characteristics of the physical parameters and/or of the parameters derived therefrom.

In the next step 70125, the higher-level computer system 12 adds these parameterized parameter value characteristics 70130 for the parameter value characteristics of the physical parameters and/or of the parameters derived therefrom to the parameter signal model 69610. As a result, the parameter signal model 69610 is filled by a further signal basic object.

In the next step 70140, the higher-level computer system 12 checks whether it has already processed all signal basic objects of the sequence 70060 of signal basic objects. If this is not the case, in step 70070, the higher-level computer system 12 determines the next signal basic object not yet taken into account of the sequence 70060 of signal basic objects that the higher-level computer system 12 intends to reconstruct and then continues the method, as described above, with the test step 70080, which checks whether the relevant data set 70090, 70100 of the prototype database 70115 of the higher-level computer system 12 comprises a prototypical feature vector 70090 and possibly does not comprise any parameter value characteristics 70100, or prototypical ones, for the parameter value characteristics of the physical parameters and/or of the parameters derived therefrom.

If the higher-level computer system 12 has already processed all signal basic objects of the sequence 70060 of signal basic objects, the higher-level computer system 12 checks in a test step 70150 whether it has already taken into account all signal objects of the data 70160 to be decompressed for the reconstructed parameter signal model 69610 for this sampling window.

If the higher-level computer system 12 has already taken into account all signal objects of the data 70160 to be decompressed for the reconstructed parameter signal model 69610 for this sampling window, the reconstructed parameter signal model 69610 is completed for this sampling window (end 70170). The reconstructed parameter signal model 69610 then comprises the reconstructed parameter value characteristics of the physical parameters and the characteristics of the parameter values of the parameters derived therefrom, wherein it is optionally only the decompressed parameter value characteristics of the physical parameters and the characteristics of the parameter values of the parameters derived therefrom that the control device 4 of the fuse 1 has detected.

If the higher-level computer system 12 has not already taken all signal objects of the data 70160 to be decompressed into account for the reconstructed parameter signal model 69610 for this sampling window, the higher-level computer system 12 determines in a next step 70030 the next object to be reconstructed in the received data of the control device 4 of the fuse 1, which object the higher-level computer system 12 has not yet taken into account for the reconstruction for the reconstructed parameter signal model 69610 for this sampling window and continues the method from there.

In this way, the higher-level computer system 12 slowly fills the parameter signal model 69610, and the parameter signal model 69610 slowly approaches the measured signal characteristic of the parameter signal 62105. As described above, the higher-level computer system 12 optionally adds up only the signal characteristics of prototypical signal objects of the signal object sequence database 70116 of the higher-level computer system 12 and/or the signal characteristics of the prototypical signal basic objects of the prototype database 70115 of the higher-level computer system 12 for the parameter signal model 69610 for optionally each sampling window.

From the signal characteristics summed up in this way of the prototypical parameter value signal characteristics of the prototypical signal objects or of the prototypical signal basic objects that are detected by the control device 4 of the fuse 1, the higher-level computer system 12 optionally forms the reconstructed parameter signal on the basis of the parameter signal model 69610 of the control device 4 of the fuse 1; this can occur in the form of forming reconstructed sampling values of the signals 62102 of the temporal parameter value characteristics and/or the corresponding time characteristics of the parameters derived from these parameter value characteristics of the physical parameters. The result is a parameter signal model vector 74610 from the detected signal objects 62122 and the signal basic objects 62121, the content of which essentially corresponds to reconstructed sampling values of the signals 62102 of the temporal parameter value characteristics and/or the corresponding time characteristics of the parameters derived from these parameter value characteristics of the physical parameters as a reconstructed parameter signal 70610 (FIG. 73b). This reconstructed parameter signal 70610 (FIG. 73b) can then be used substantially better in the higher-level computer system 12 for more complicated subsequent signal processing methods, such as sensor fusion, than the data of the signal objects and/or signal basic objects that the control device 4 of the fuse 1 transmits to the higher-level computer system.

### BRIEF DESCRIPTION OF THE DRAWINGS

FIG. 1 shows a simplified and schematic system 50 of electronic fuse 1, data bus 9, and higher-level computer system 12. According to the proposal, the electronic fuse 1 optionally comprises a circuit breaker 17 and a control device 4 which controls this circuit breaker 17.

FIG. 2 shows in simplified form and, by way of example, a supply network 200 comprising electronic fuses.

FIG. 3 shows a data bus system comprising a data bus 9 drawn in with dashed lines for the exemplary supply network 200 of FIG. 2.

FIG. 4 shows in schematically simplified form an exemplary fuse box 400 comprising slots 410 and 420 for receiving electronic fuses 405 and melting fuses 415.

FIG. 5 is based on FIG. 1 and represents a modification of FIG. 1, wherein the fuse 1 of FIG. 5 comprises additionally a first test current source 505 which feeds an electrical test current 515 into the first terminal 26 of the circuit breaker 17 of the fuse 1.

FIG. 6 substantially corresponds to FIG. 1, wherein the control device 4 of the fuse 1 of FIG. 4 comprises an additional second data interface 610.

FIG. 7 corresponds in substantial parts to FIG. 3, wherein the data bus 9 is designed as an annular data bus ring 9′.

FIG. 8 corresponds in the most important parts to FIG. 4, wherein the supply sub-network of FIG. 8 comprises a further fuse 805, a second further fuse 810, a first connected distribution tree 815, a second connected distribution tree 820, an electronic fuse 825, loads 830, and further loads 835.

FIG. 9 shows a fuse 1 which, compared to the fuse 1 of FIG. 5, has a second test current source 905 in addition to the first test current source 505, the test current 915 of which second test current source is modulated by means of the control signal 910 with a modulation signal {505} of a second signal generator 920.

FIG. 10 shows a proposed power-source-side cross-over fuse 1000.

FIG. 11 shows a proposed supply network 1100 comprising a higher-level computer system 12 and comprising a plurality of supply lines and comprising a plurality of cross-over fuses 1110 to 1118, which enable flexible load-dependent and supply-dependent reconfiguration of the supply network 1100.

FIG. 12 shows the basic sequence of a method 1200 for operating a supply network.

FIG. 13 diagrams a method 1300 for operating a vehicle (load-side feature version).

FIG. 14 also shows a further method 1400 described in a simplified manner for operating a vehicle with activation of power sources in the vehicle.

FIG. 15 corresponds largely to FIG. 8, wherein the supply network is nevertheless now divided into a first supply sub-network and a second supply sub-network.

FIG. 16 shows in schematically simplified form a method 1600 for detecting non-extinguishing arcs 1510 in the cable harness 1515 of a vehicle.

FIG. 17 substantially corresponds to FIG. 7, wherein here the third supply line section 245 is separated into the third supply line section 245 and the fourth supply line section 246.

FIG. 18 shows in schematically simplified form an exemplary method 1800 for operating a supply network 1700 of FIG. 17.

FIG. 19 corresponds in substantial parts to FIG. 15 and FIG. 10, wherein, while FIG. 10 shows a fuse box 1000, FIG. 19 shows two lines 1915 and 1505 to be protected, which are parts of a cable harness 1515.

FIG. 20 describes in schematic and simplified form a distributed measurement method 2000 for detecting the state of a cable harness 1515 of a vehicle in accordance with the representation of FIG. 19.

FIG. 21 shows in schematically simplified form a proposed battery 2100 with a diagnostic function for a vehicle using supply networks 200 as described by the disclosure in the preceding figures.

FIG. 22 corresponds to FIG. 21 with the difference that the first electronic fuse 825 has an additional contact 2210 in order, in the event of an incorrect sign of the current 2121 through the first fuse 825, to direct this current past the electrochemical battery cell 2145.

FIG. 23 shows a battery cell module 2300 which comprises at least one battery cell 2145 and/or an interconnection of battery cells, a first circuit breaker 17, a second circuit breaker 17′, a first electrical node 2120, a second electrical node 2135, a third electrical node 2140, a first battery cell terminal 2305, and a second battery cell terminal 2310.

FIG. 24 corresponds to FIG. 6, wherein the fuse 1 of FIG. 24 has a second circuit breaker 17′.

FIG. 25 corresponds to the battery of FIG. 22, wherein FIG. 25 shows a battery cell module 2500 having a plurality of battery cells 2145, 2185.

FIG. 26 shows a housed battery cell module 2600 having a common housing 2605 of the battery cell module 2600 for an electronic fuse 825 and an inner battery cell module 2105.

FIG. 27 shows a battery 2700 in which an electronic fuse 825 of the battery 2200 has a second circuit breaker 17′ which is suitable for shunting the battery cell module 2105 associated with the fuse when the second circuit breaker 17′ is closed and in which the control device is supplied from the battery cell 2145, but only if the circuit breaker 17 is closed.

FIG. 28 shows a battery 2800 in which an electronic fuse 825 of the battery 2200 has a second circuit breaker 17′ which is suitable for shunting the battery cell module 2105 associated with the fuse when the second circuit breaker 17′ is closed and in which the control device 4 is further supplied from the battery cell 2145, even if the circuit breaker 17 is open.

FIG. 29 shows a supply network 2900, wherein one or more supply branches of the supply network 2900 are designed to supply electrical power to electrical loads 2930 to 2933 as a ring of a supply line 2910 to 2915, in particular if a body serves as a return ground line, and/or are implemented as two rings of two supply lines.

FIG. 30 corresponds to FIG. 29 with the difference that power sources and loads are pluggable.

FIG. 31 schematically shows and represents in simplified form a supply network 3100 which substantially corresponds to the supply network 3000 of FIG. 30, wherein the plug connections are now protected with their own fuses.

FIG. 32 corresponds in large parts to FIG. 11, wherein the supply network 3200 of FIG. 32 has a first sub-supply network 3201 and a second sub-supply network 3202.

FIG. 33 shows a supply network 3300 similar to FIG. 31 for explaining the prioritization of loads and power sources and a favorable topology of the supply network 3300 to support this prioritization capability.

FIG. 34 illustrates by way of example and in simplified form a method 3400 for active power management in a supply network 1100 (see FIG. 11) with electrical fuses 1110 to 1118 for supplying electrical loads 1121 to 1125 in this supply network 1100 with electrical power from one or more electrical power sources 1150 to 1155.

FIG. 35 illustrates in a simplified and schematic manner a method 3500 for operating a vehicle with equipment variants, wherein the activation and deactivation of the equipment variants of the vehicle is accomplished at least in part optionally by means of the supply network and by means of the electronic fuses and their circuit breakers 17.

FIG. 36 is intended to represent possible levels of a data protocol on the data bus 9 of the supply network 200.

FIG. 37 shows the present-day protection of the cable of a supply line section.

FIG. 38 shows the advantages of protecting a supply line section with an electronic fuse;

FIG. 39 shows the combination of two SPAD diodes according to the proposal in cross section.

FIG. 40 shows the combination of two proposed SPAD diodes in cross section, wherein now a plurality of isolation layers forms the optical waveguide 44.

FIG. 41 shows the integration of the SPAD diodes and the optical waveguide into an evaluation and operating circuit.

FIG. 42 corresponds to FIG. 41, which is now supplemented by monitoring circuits.

FIG. 43 shows a typical output signal of the second SPAD diode.

FIG. 44 shows an exemplary oscillogram of the voltage signal 4104 of the entropy source 4101.

FIG. 45 shows the schematic sequence of a server client communication using a proposed quantum random number generator.

FIG. 46 shows the schematic sequence of the functions KeyExchangeServer( ) and KeyExchan-geClient( ).

FIG. 47 shows schematically the sequence of the setPrimes( ) function.

FIG. 48 shows the schematic sequence of the setEO function.

FIG. 49 shows the schematic sequence of the findD( ) function.

FIG. 50 shows the schematic sequence of a secure transmission of quantum-based random numbers between a computer core 2 of the control device 4 of the fuse 1 (server) and a computer core 2 of the control device 4 of the other fuse 1 (client).

FIG. 51 schematically shows the proposed method 5200 for generating a quantum random number.

FIG. 52 shows a general four-way fuse with only one control device 4.

FIG. 53 shows the general four-way fuse of FIG. 52 as a general triple fuse, wherein the three circuit breakers 17, 17′ and 17″ are wye-connected, so that they can be used, for example, as the triple fuse 3010′ of FIG. 31.

FIG. 54 shows the general four-way fuse of FIG. 52 wherein the four circuit breakers 17, 17′, 17″ and 17″′ are interconnected to form the cross-over fuse 1000.

FIG. 55a shows an exemplary system for integrating SW programs.

FIG. 55b shows an exemplary structure of a SW program.

FIG. 56 shows a flowchart of an exemplary method for executing a SW program in a vehicle.

FIG. 57 corresponds to FIG. 24, wherein, for a better overview, the test current sources and the controllers thereof are not shown, and wherein in FIG. 57 a temperature switch 5710 is inserted into the current path between the first terminal 18 of the fuse 1 and the second terminal of the fuse 1.

FIG. 58 corresponds to FIG. 24, wherein, for a better overview, the test current sources and the controllers thereof are not shown, and wherein, unlike in that of 57, the fuse 1 uses a thermal fuse 5740 instead of a thermal switch 5710.

FIG. 59 corresponds to an application of the multiple fuse 1 of FIG. 52 to protect the three motor phases of an exemplary three-phase motor.

FIG. 60 shows in schematically simplified form the sequence of a method for transmitting compressed data, from the fuse 1 to the higher-level computer system 12, wherein, within the meaning of the technical teaching presented here in connection with this data transmission, a compressed transmission from the control device 4 of the fuse to a different control device 4 of a different fuse is included in the disclosure of the disclosure.

FIG. 61 is a refinement of FIG. 60, in which the steps 6020 of detecting the physical parameter to be detected of the control device 4 of the fuse 1 and 6030 the analysis and the compression of the detected temporal parameter value characteristic of the detected physical parameter are refined into further exemplary sub-steps.

FIG. 62 illustrates an example HBMM detector.

FIG. 63 serves to explain the selection of the signal basic object prototypes of the prototype database 62115 by the distance determination device 62112.

FIG. 64 serves to explain the HBMM method that is applied by the Viterbi estimator 62113 in order to identify the signal object as the most likely sequence of signal basic object prototypes due to a sequence of detected signal basic object prototypes 62121 as a detected signal object 62122.

FIG. 65 shows an exemplary state sequence in the Viterbi estimator 62113 for the detection of a single signal object.

FIG. 66 shows an exemplary, preferred state sequence in the Viterbi estimator 62113 for the continuous detection of signal objects, as is typically necessary for the detection during tasks of autonomous driving.

FIG. 67 corresponds largely to FIG. 62 with the difference that a neural network model 67151 classifies and analyzes the feature vectors of the signal of the feature vectors 62138.

FIG. 68 shows the exemplary decompression of a transmitted exemplary sub-signal of the parameter signal 62103, wherein only signal components having a first property are incorporated in the reconstruction.

FIG. 69 shows the exemplary decompression of a transmitted exemplary sub-signal of the parameter signal 62103, wherein only signal components without the first property are incorporated in the reconstruction.

FIG. 70 discloses an example decompression method.

FIGS. 71a to 71g and 72 show the decompression of the parameter signal 62103.

FIG. 73 shows an exemplary, arbitrary sub-signal of the parameter signal 62103 as an original signal (FIG. 73a), the reconstructed parameter signal 70610 (FIG. 73b) and the superposition of these two signals (FIG. 73c).

FIG. 74 shows an improved device for improved recursive compression.

FIG. 75 shows a device for evaluating the decompressed fuse data of a plurality of fuses, e.g., two of two fuses (805, 825).

FIG. 76 shows a method 7600 for operating a supply network 200 with compression and encryption of the fuse data in the electronic fuse 1 and decryption and decompression of the fuse data in the higher-level computer system 12.

FIG. 77 corresponds to FIG. 75 with the difference that the combiner 75101 now merges the reconstructed parameter signals 70610 and 70610′ not only with one another, but also with a parameter signal 77610 of a further sensor 77010 to form the merged parameter signal 75103.

FIG. 78 shows a device corresponding to FIG. 75, wherein the higher-level computer system 12 now executes an exemplary neural network model 778151.

FIG. 79 shows an example of a supply system for a vehicle having at least one power source and a plurality of electrical loads as well as a higher-level control or computer system for electronic fuses arranged distributed over the supply network.

FIG. 80 shows an example of a supply system for a vehicle having at least one power source and a plurality of electrical loads as well as a higher-level control or computer system for electronic fuses arranged distributed over the supply network.

FIG. 81 shows a further example of a supply system for a vehicle having at least one power source and a plurality of electrical loads as well as a higher-level control or computer system for electronic fuses arranged distributed over the supply network.

### DESCRIPTION

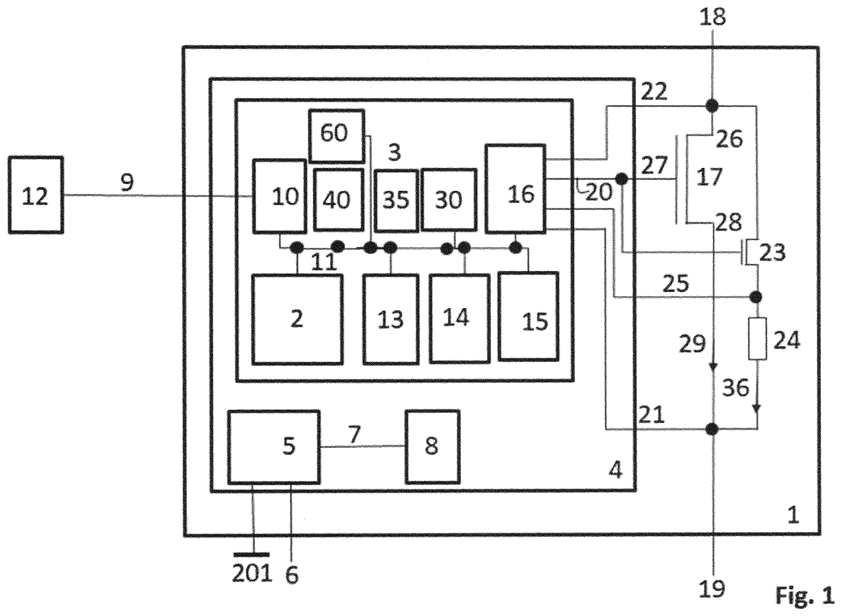

### FIG. 1

FIG. 1 shows a simplified and schematic system 50 made up of electronic fuse 1, data bus 9, and higher-level computer system 12. According to the proposal, the electronic fuse 1 optionally comprises a circuit breaker 17 and a control device 4 which controls this circuit breaker 17. The circuit breaker 17 is optionally a MOS transistor or the like. Other semiconductor components such as thyristors, bipolar transistors etc. are conceivable, but are currently less common.

The power transistor 17 can be integrated with device parts of the control device 4 in a semiconductor substrate. However, different technologies are optionally used for the circuit breaker 17 and the control device 4. The control device 4 is optionally manufactured in a CMOS technology. The circuit breaker 17 is optionally manufactured in a MOS technology for power transistors or another semiconductor technology for power transistors. The shunt resistor 24 can be integrated both with the control device 4 on a common semiconductor substrate and also integrated together with the circuit breaker 17 on a common substrate.

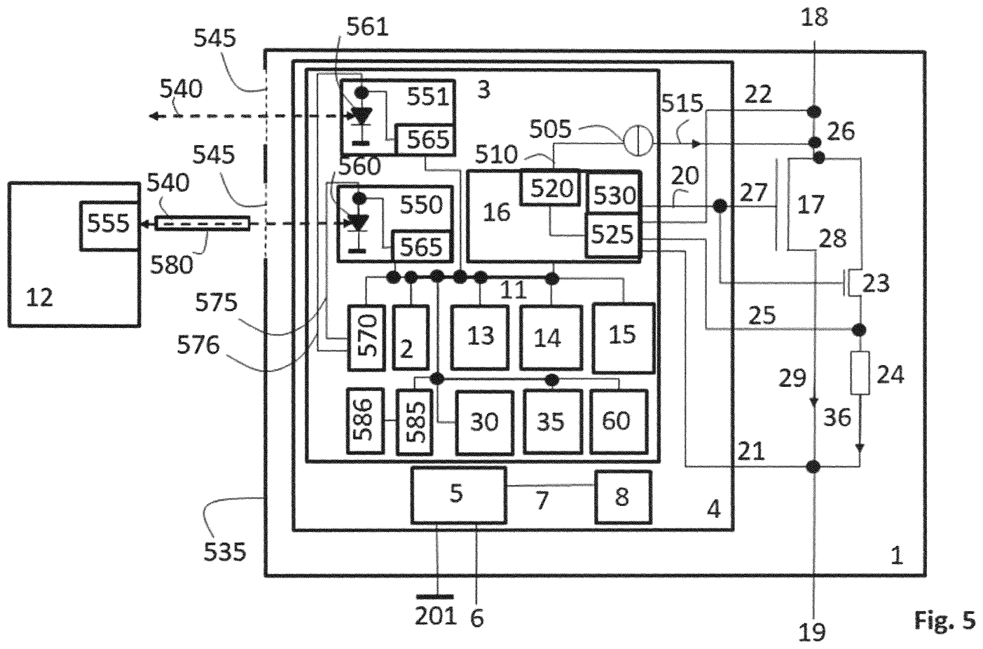

In FIG. 1, for better clarity, not all appropriate and in some cases customary device components are shown. Further device components that the reader can assume as possibly present in FIG. 1 can be found, for example, in FIGS. 5, 6, 9, 24, 41, 42, 52, 53, 54, 55, 57, 58 and 62. The combination of the device parts of the Figure described here with those of these figures is expressly part of the disclosure of the disclosure.

The higher-level computer system 12 exchanges data with the control device 4 via the data bus 9. Typically, the higher-level computer system 4 queries state data of the electronic fuse 1 via the data bus 9 and a data bus interface 10 from a computer core 2 of the control device 4 of the electronic fuse 1. In this case, the computer core 2 optionally accesses the peripheral components of the control device 4 via an internal data bus 11. However, these peripheral components can be, for example, but are not limited to the data bus interface 10, a watchdog, 13, non-volatile memory 14, volatile read-write memory 15, and a gate drive circuit 16 for controlling and monitoring the circuit breaker 17.

Optionally, the one gate drive circuit 16 monitors and controls the circuit breaker 17. A control line 20 for controlling the circuit breaker 17 optionally connects the gate drive circuit 16 to the first terminal of the circuit breaker 17. The gate drive circuit 16 optionally controls the switching state of the circuit breaker 17 by means of the control line 20. The gate drive circuit 16 optionally detects one or more voltages between the first terminal 26 of the circuit breaker 17 and/or the second terminal 28 of the circuit breaker 17 and/or the control terminal 27 of the circuit breaker 17 on the one hand and a reference potential 201 on the other hand. The gate drive circuit 16 optionally detects one or more voltages between the first terminal 26 of the circuit breaker 17 and/or the second terminal 28 of the circuit breaker 17 and/or the control terminal 27 of the circuit breaker 17. The electronic fuse 1 optionally comprises an auxiliary circuit breaker 23. The auxiliary circuit breaker 23 optionally serves to detect a current which is proportional to the current through the circuit breaker 17 or corresponds thereto in another way. The electronic fuse 1 optionally comprises a shunt resistor 24. The value of the electrical current 36 through the shunt resistor 24 and the auxiliary circuit breaker 23 is typically proportional to the electrical current 29 through the circuit breaker 17. A measuring line 25 serves to detect the voltage drop across the shunt resistor 24. A monitoring line 21 serves to detect the voltage between the second terminal 19 of the circuit breaker 17 and the control line 20 of the circuit breaker 17. The gate drive circuit 16 optionally detects the voltage drop across the shunt resistor 24 by means of the measuring line 25 and a monitoring line 21. Typically, the computer 2 of the control device 4 of the electronic fuse 1 controls the circuit breaker 17 depending on the values of these voltages detected in this way and depending on commands which the computer 2 of the control device 4 receives, for example, from a higher-level computer system 12, for example via said data bus 9.

Within the meaning of the disclosure, the first terminal 18 of the electronic fuse 1 is optionally the power-source-side terminal of the electronic fuse. Within the meaning of the disclosure, the second terminal 19 of the electronic fuse 1 is optionally the load-side terminal of the electronic fuse. Because loads, such as motors, often do not consume power in certain operating situations, for example braking, but instead recover it, this assignment may possibly reverse during operation. In this respect, it is only a concept for the predominant use of the first terminal 18 of the fuse 1 and the second terminal 19 of the fuse 1.

A watchdog 13 optionally serves to monitor the microcontroller, i.e., the computer 2. In the simplest case, the watchdog is a timer which counts, for example, with the system clock of the control device 4. Typically, the computer 2 signals to the watchdog 13 at more or less regular time intervals that it is still functional. Optionally, with each signaling of the computer 2, the watchdog 13 returns its counter reading to a predefined starting value. However, if the watchdog 13 reaches a predefined watchdog threshold value, the watchdog 13 typically assumes a fault of the processing of the operating program by the computer 2. The watchdog 13 then typically adopts countermeasures. A countermeasure can be, for example, resetting the program execution of the computer 2 to a specified program start address. Another countermeasure can be the stopping of the computer 2. Another countermeasure can be the opening of the circuit breaker 17. Another countermeasure can be, for example, a signaling of the watchdog 13 to a higher-level computer system 12 via the internal data bus 11, the data interface 10, and the external data bus 9 to a higher-level computer system 12. Typically, the computer 2 of the control device 4 of the electronic fuse 1 can configure the watchdog 13 via the internal data bus 11 by means of a register of the watchdog 13 and read out the status of the watchdog 13 via watchdog register.

The non-volatile memory 14 can comprise, for example, a flash memory or an EEPROM or a ROM or the like. The non-volatile memory 14 optionally comprises data and/or program code. The computer 2 of the electronic fuse 1 optionally accesses this data and the program code via the internal data bus 11. In particular, the data in the non-volatile memory 14 optionally also comprise configuration data of the electronic fuse 2.

Furthermore, the proposed electronic fuse 1 optionally comprises a volatile read-write memory 15. The volatile read-write memory 15 can be, for example, a RAM or an SRAM or a DRAM or an FRAM or an MRAM or the like. The computer 2 of the electronic fuse 1 uses this volatile read-write memory 15 optionally for caching intermediate results.

An oscillator 30 together with a clock-pulse supply optionally generate the system clock of the control device 4 of the electronic fuse 1. Optionally, the higher-level computer system 12 can access the configuration registers of the oscillator 30 and the clock-pulse supply via the internal data bus 11 and the data bus interface 10 and the data bus 9 and configure them and read their status. Likewise, the computer 2 can optionally give the internal data bus 11 access to these configuration registers of the oscillator 30 and the clock-pulse supply and configure them and read out their status from status registers.

The control device 4 optionally comprises a timer and/or a clock of the control device 4. The computer 2 can then combine measured values of the gate drive circuit 16 for controlling and monitoring the circuit breaker 17 with a time stamp from a time value of the timer 16 and measured values of voltages and/or other physical parameters, etc.

For example, a temperature measuring device 40 can determine the temperature of the control device 4 and/or the temperature of device parts of the control device 4. The control device 4 of the fuse 1 can also comprise an analog-to-digital converter 570, which is shown by way of example in a following figure. For example, such an analog-to-digital converter can provide a measuring line to a temperature sensor 586, not shown here for better clarity, via which the analog-to-digital converter 570 can determine the temperature of the circuit breaker 17 or other device parts of the fuse 1 and provide it to the computer 2 via the data bus 11. For this purpose, this temperature sensor 586 is optionally thermally tightly coupled to the circuit breaker 17. Optionally, the temperature sensor 586 is a sub-device of the circuit breaker 17. The electronic fuse can have a plurality of temperature sensors 586, the measured value signals of which can be detected by the analog-to-digital converter 570 and made available to the computer 2. For example, the temperature sensor 586 can also detect the temperature of the line at the first terminal 18 or at the second terminal 19 of the electronic fuse 1.

The electronic fuse 1 optionally has a voltage supply 5 for the control device 4 and the operation of the possibly present other device parts of the electronic fuse 1. A line for the operating voltage 6 and a line for the reference potential 201 optionally supply the electronic fuse 1 with electrical power. It is also conceivable that the electronic fuse draws its power from the first terminal 18 and/or the second terminal 19 on the one hand and the reference potential line 201. In normal operation, the voltage supply 5 optionally charges a power reserve 8. This is typically a capacitor and/or an accumulator and the like.

In the event of a failure of the supply of power via the operating voltage 6, the power reserve 8 supplies the control device 4 and thus the circuit breaker 17 with the necessary power via an emergency power supply 7. Optionally, the voltage supply 5 isolates the operating voltage 6 and possibly also the reference potential 201 in the event of such a failure by means of isolating switches in order not to discharge the power reserve 8.

The voltage supply 5 optionally comprises the necessary voltage regulators and/or voltage converters in order to provide the voltages required by the control device 4 from the power reserve 8 or from the operating voltage 6 for the operation of the control device 4.

The control device 4 presented here for the operation of an electronic fuse 1 of a vehicle optionally has a system basis chip functionality. This system basis chip functionality provides all functions in order to be able to operate a microcontroller as computer core 2 in the control device 4 of the electronic fuse 1 and at least one data interface 1, so that the computer core 2 can safely transmit at least errors and/or faults of the control device 4 and/or other device parts of the fuse to a higher-level computer system 12 via the data bus 9. This system basis chip functionality comprises a boost converter 5 for the voltage supply 5 of the safety-relevant device parts of the control device 4 of the fuse 1 and for charging and in some cases discharging an internal or external power reserve 8. The power reserve 8 can comprise an accumulator and/or a capacitor. In normal operation, the boost converter 5 optionally processes an externally provided operating voltage 6 of one or more external power sources and makes the necessary internal operating voltages available to the device parts of the control device 4 and/or other device parts of the fuse 1. The computer core 2 of the control device 4 of the fuse 1 monitors the operating voltage 6 of the boost converter 5 by means of an analog-to-digital converter 570, for example. In the event of a failure of the externally provided operating voltage 6, the computer core 2 of the control device 4 of the fuse 1 switches into an emergency operating mode. In such an emergency operating mode, the boost converter 5 optionally supplies the control device 4 and/or further device parts of the fuse, insofar as this is absolutely necessary, with electrical power from the power reserve 8. In normal operation, the boost converter 5 charges the power reserve 8 with electrical power. In the emergency operating mode, the power reserve 8 assumes the task of supplying power to the control device 4 of the fuse 1. Thus, in the emergency operating mode the boost converter 5 and/or a functionally equivalent second voltage regulating device provide an emergency power supply 7 of the safety-relevant device parts of the control device 4 of the fuse 1 and/or of the fuse 1.

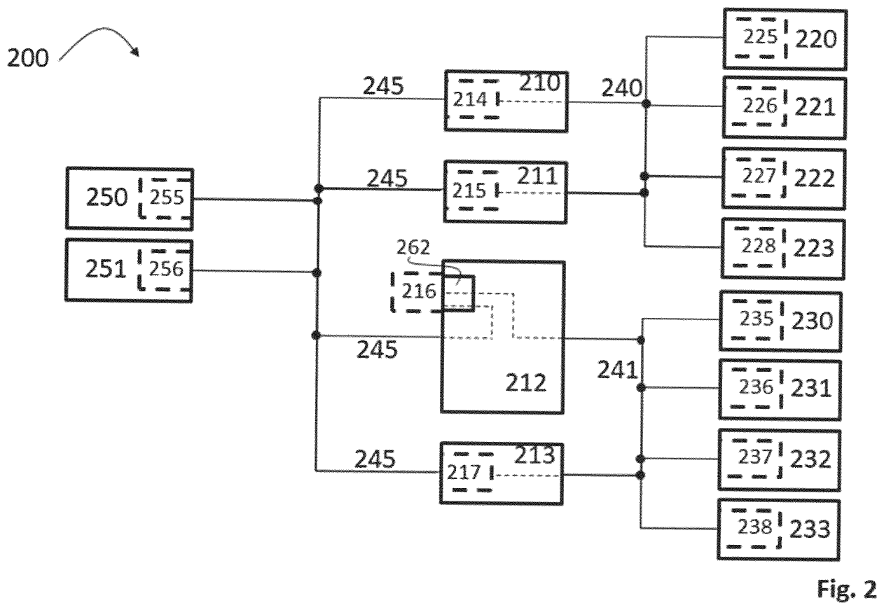

### FIG. 2

FIG. 2 shows a supply network 200 with electronic fuses in simplified and exemplary form. The supply network shows the reference potential nodes 201 only by symbols. The reference potential node can be, for example, the body ground of a vehicle body made of metal or the like. The proposed supply network thus uses, for example, an electrically conductive vehicle body as an electrical return line. In the example of FIG. 2, this electrical return line is the reference potential node 201. The reference potential node 201 is typically the ground of the vehicle. In the figures of the disclosure, the reference potential node 201 is, for better clarity, not always shown and is also not always denoted by the reference character. If shown in a figure, the circuit symbol for the ground denotes the reference potential node 2021 in the figures of this document. In the example of FIG. 2, the supply network 200 has different device parts (210 to 213). These typically consume electrical power.

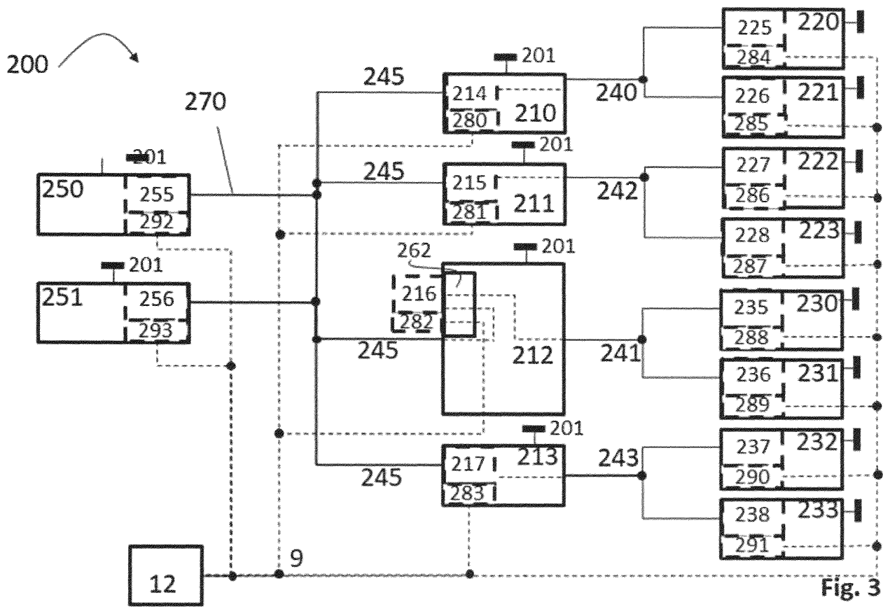

A first fuse 214 of the first device part 210 of the supply network 200 protects the first line section 240 and the loads connected thereto in the form of further, dependent device parts (220 to 223) of the supply network 200. The first fuse 214 optionally corresponds in its internal structure to an electrical fuse of FIG. 1. In the example of FIG. 2, the first fuse 214 can electrically connect the third line section 245 to the first line section 240 by means of its circuit breaker 17, or locally disconnect the third line section (245) from the first line section 240 by means of its circuit breaker 17. Typically, the first fuse 214 is connected to a data bus 9, which, for the sake of simplicity, is not shown in FIG. 1. FIG. 3 shows an exemplary wiring of the data bus 9, which would also be applicable in the form in FIG. 1.

A second fuse 215 of the second device part 211 of the supply network 200 protects the first line section 240 and the loads connected thereto in the form of further, dependent device parts (220 to 223) of the supply network 200. The second fuse 215 optionally corresponds in its internal structure to an electrical fuse of FIG. 1. In the example of FIG. 2, the second fuse 215 can electrically connect the third line section 245 to the first line section 240 by means of its circuit breaker 17, or locally disconnect the third line section 245 from the first line section 240 by means of its circuit breaker 17. Typically, the second fuse 215 is connected to a data bus 9, which, for the sake of simplicity, is not shown in FIG. 1. FIG. 3 shows an exemplary wiring of the data bus 9, which would also be applicable in the form in FIG. 1.

A third fuse 216 of the third device part 212 of the supply network 200 protects the second line section 241 and the loads connected thereto in the form of further, dependent device parts (230 to 233) of the supply network 200. The third fuse 216 optionally corresponds in its internal structure to an electrical fuse of FIG. 1. In the example of FIG. 2, the third fuse 216 can electrically connect the third line section 245 to the second line section 241 by means of its circuit breaker 17, or locally disconnect the third line section 245 from the second line section 241 by means of its circuit breaker 17. Typically, the third fuse 216 is connected to a data bus 9, which, for the sake of simplicity, is not shown in FIG. 1. FIG. 3 shows an exemplary wiring of the data bus 9, which would also be applicable in the form in FIG. 1.

A fourth fuse 217 of the fourth device part 213 of the supply network 200 protects the second line section 241 and the loads connected thereto in the form of further, dependent device parts (230 to 233) of the supply network 200. The fourth fuse 217 optionally corresponds in its internal structure to an electrical fuse of FIG. 1. In the example of FIG. 2, the fourth fuse 217 can electrically connect the third line section 245 to the second line section 241 by means of its circuit breaker 17, or locally disconnect the third line section 245 from the second line section 241 by means of its circuit breaker 17. Typically, the fourth fuse 217 is connected to a data bus 9, which, for the sake of simplicity, is not shown in FIG. 1. FIG. 3 shows an exemplary wiring of the data bus 9, which would also be applicable in the form in FIG. 1.

When the first fuse 214 is connected in parallel to the second fuse 215, as in the example of FIG. 1, the circuit breakers 17 of both fuses (214, 215) must be open in order to disconnect the first line section 240 from the third line section 245. If the first line section 240 is disconnected from the third line section 245 by open circuit breakers 17, the first power source 250 and the second power source 251 no longer supply the further device parts (220 to 223) with electrical power. If the first line section 240 is electrically connected to the third line section 245 via closed circuit breakers 17, the first power source 250 and the second power source 251 supply the further device parts (220 to 223) with electrical power if these power sources (250, 251) feed power into the third line section 245.

When the third fuse 216 is connected in parallel to the fourth fuse 217, as in the example of FIG. 1, the circuit breakers 17 of both fuses (216, 217) must be open in order to disconnect the first line section 240 from the third line section 245. If the second line section 241 is disconnected from the third line section 245 by open circuit breakers 17, the first power source 250 and the second power source 251 no longer supply the further device parts (230 to 233) with electrical power. If the second line section 241 is electrically connected to the third line section 245 via closed circuit breakers 17, the first power source 250 and the second power source 251 supply the further device parts (230 to 233) with electrical power if these power sources (250, 251) feed power into the third line section 245.

A fifth fuse 225 can disconnect the fifth device part 220 of the supply network 200 from the first line section 240 by means of its circuit breaker 17, and thus prevent the supply of power to the fifth device part 220, or connect the fifth device part 220 of the supply network 200 to the first line section 240 by means of its circuit breaker 17, and thus enable power to be supplied to the fifth device part 220.

A sixth fuse 226 can disconnect the sixth device part 221 of the supply network 200 from the first line section 240 by means of its circuit breaker 17, and thus prevent the supply of power to the sixth device part 221, or connect the sixth device part 221 of the supply network 200 to the first line section 240 by means of its circuit breaker 17, and thus enable power to be supplied to the sixth device part 221.

A seventh fuse 227 can disconnect the seventh device part 222 of the supply network 200 from the first line section 240 by means of its circuit breaker 17, and thus prevent the supply of power to the seventh device part 222, or connect the seventh device part 222 of the supply network 200 to the first line section 240 by means of its circuit breaker 17, and thus enable power to be supplied to the seventh device part 222.

An eighth fuse 228 can disconnect the eighth device part 223 of the supply network 200 from the first line section 240 by means of its circuit breaker 17, and thus prevent the supply of power to the eighth device part 223, or connect the eighth device part 223 of the supply network 200 to the first line section 240 by means of its circuit breaker 17, and thus enable power to be supplied to the eighth device part 223.

A ninth fuse 235 can disconnect the ninth device part 230 of the supply network 200 from the second line section 241 by means of its circuit breaker 17, and thus prevent the supply of power to the ninth device part 230, or connect the ninth device part 230 of the supply network 200 to the second line section 241 by means of its circuit breaker 17, and thus enable power to be supplied to the ninth device part 230.

A tenth fuse 236 can disconnect the tenth device part 231 of the supply network 200 from the second line section 241 by means of its circuit breaker 17, and thus prevent the supply of power to the tenth device part 231, or connect the tenth device part 231 of the supply network 200 to the second line section 241 by means of its circuit breaker 17, and thus enable power to be supplied to the tenth device part 231.

A eleventh fuse 237 can disconnect the eleventh device part 232 of the supply network 200 from the second line section 241 by means of its circuit breaker 17, and thus prevent the supply of power to the eleventh device part 232, or connect the eleventh device part 232 of the supply network 200 to the second line section 241 by means of its circuit breaker 17, and thus enable power to be supplied to the eleventh device part 232.

A twelfth fuse 238 can disconnect the twelfth device part 233 of the supply network 200 from the second line section 241 by means of its circuit breaker 17, and thus prevent the supply of power to the twelfth device part 232, or connect the twelfth device part 233 of the supply network 200 to the second line section 241 by means of its circuit breaker 17, and thus enable power to be supplied to the twelfth device part 233.

A thirteenth fuse 255 can disconnect the twelfth device part 233 of the supply network 200 from the second line section 241 by means of its circuit breaker 17, and thus prevent the supply of power to the twelfth device part 232, or connect the twelfth device part 233 of the supply network 200 to the second line section 241 by means of its circuit breaker 17, and thus enable power to be supplied to the twelfth device part 233.

A thirteenth fuse 255 can disconnect the first power source 250 of the supply network 200 from the third line section 245 by means of its circuit breaker 17 or connect the first power source 250 of the supply network 200 to the third line section 245 by means of its circuit breaker 17. As a result, the thirteenth fuse 255 can prevent the supply of power to the sub-networks connected to the first power source 250, in this case the device parts 210 to 213 and 220 to 223 and 230 to 233, by the first power source 250 by means of opening the first circuit breaker 17 of the thirteenth fuse 255, or enable the supply of power to the sub-networks connected to the first power source 250, in this case the device parts 210 to 213 and 220 to 223 and 230 to 233, by the first power source 250 by means of closing the first circuit breaker 17 of the thirteenth fuse 255.

A fourteenth fuse 256 can disconnect the second power source 251 of the supply network 200 from the third line section 245 by means of its circuit breaker 17 or connect the first power source 251 of the supply network 200 to the third line section 245 by means of its circuit breaker 17. As a result, the fourteenth fuse 256 can prevent the supply of power to the sub-networks connected to the second power source 251, in this case the device parts 210 to 213 and 220 to 223 and 230 to 233, by the second power source 251 by means of opening the first circuit breaker 17 of the fourteenth fuse 256, or enable the supply of power to the sub-networks connected to the second power source 251, in this case the device parts 210 to 213 and 220 to 223 and 230 to 233, by the second power source 251 by means of closing the first circuit breaker 17 of the fourteenth fuse 256.

In FIG. 2, by way of example, the third device part 212 is provided with a plug-in option 262 for the third electronic fuse 216 of the third device part 212. As a result, for example, a repair shop can manually replace the third electronic fuse 216, for example in the event of an error of the fuse. If the plug-in option has a design compatible with melting fuses, a repair shop, for example, can replace the third electronic fuse 216 with a melting fuse. Conversely, for example, the repair shop can replace a melting fuse which is located in the plug-in option 262 with a third electronic fuse 216.

All devices 210 to 213 and 220 to 223 and 230 to 233 would optionally be provided with a plug-in option for an electronic fuse such as the plug-in option 262 for the electronic fuse 216 of the third device part 212. The disadvantage is that such plug connections typically lead to reduced reliability. FIG. 3

FIG. 3 shows a data bus system with a data bus 9 drawn in with dashed lines for the exemplary supply network 200 of FIG. 2. Each of the electronic fuses 214 to 217 and 225 to 228 and 235 to 238 optionally corresponds to an electronic fuse corresponding to FIG. 1. Therefore, each of the electronic fuses 214 to 217 and 225 to 228 and 235 to 238 typically has a control device 4 with a data interface 10. In FIG. 3, these control devices 4 are provided with separate reference characters 280 to 293 for each electronic fuse 214 to 217 and 225 to 228 and 235 to 238. The higher-level computer system 12 optionally communicates via the corresponding data interface 10 of the corresponding control device 4 of the corresponding electronic fuse of the electronic fuses 214 to 217 and 225 to 228 and 235 to 238 with the corresponding computer core 2 of the corresponding fuse. This corresponding computer core 2 of the corresponding fuse can open or close the circuit breaker 17 of the corresponding fuse of the electronic fuses 214 to 217 and 225 to 228 and 235 to 238 by means of the gate drive circuit 16. By means of a data message to a computer core 2 of a control device 4 of a fuse of the electronic fuses 214 to 217 and 225 to 228 and 235 to 238, the higher-level computer system 12 can optionally cause this computer core 2 to open or close the circuit breaker 17 of this electronic fuse by means of control signals to the gate drive circuit 16 of the relevant electronic fuse. The computer cores 2 of the electronic fuses 214 to 217 and 225 to 228 and 235 to 238 of the supply network 200 optionally detect operating parameters of the associated electronic fuse by means of aids (16, 520, 530, 525, 23, 24, 21, 25, 505, 905, 920, etc.). A first particularly important parameter is typically the electrical current 29 through the circuit breaker 17 of the relevant electronic fuse. Some sub-devices of the electronic fuse optionally detect a measured current value of this electrical current or model an electrical current which is proportional to this electrical current 29 through the circuit breaker 17. A further important parameter, which the computer cores 2 of the electronic fuses 214 to 217 and 225 to 228 and 235 to 238, optionally determine in each case in a fuse-specific manner with further auxiliary devices of these fuses, is optionally the voltage between the first terminal 18 of the relevant electronic fuse and the reference potential 201 and/or the voltage between the second terminal 19 of the relevant electronic fuse and the reference potential and/or further voltages between internal electrical nodes and/or external electrical nodes of the corresponding electronic fuse of the electronic fuses 214 to 217 and 225 to 228 and 235 to 238. Optionally, the computer cores 2 of the control devices 4 of some or, better, all electronic fuses of the electronic fuses 214 to 217 and 225 to 228 and 235 to 238 transmit a portion of or all of these measured values to the higher-level computer system 2 via the data bus 9. The higher-level computer system 12 can then evaluate this data. For example, the higher-level computer system is then able to determine the voltage drop across a line section of the line sections 240 to 245 by applying Kirchhoffs mesh and node rules. In order to avoid a ground offset if the body is used as a return line of the electrical current, it is advantageous if the reference potential line is substantially current-free. However, such an additional reference potential line can generally not be realized for cost reasons. It is therefore expedient if one or more or, better, each of the fuses is configured in each case to detect a ground offset of the reference potential line 201, for example by detecting a quiescent potential of the data bus 9 at times in which the data bus is not being used. It is obvious that a control device 4 of a fuse of the electronic fuses 214 to 217 and 225 to 228 and 235 to 238 can, with its computer core 2, assume the role of the higher-level computer system 12. In this case, a separate higher-level computer system 12 would no longer be necessary, unlike what is shown in FIG. 3.

In the exemplary difference from FIG. 2, the first device part 210 now feeds the first line section 240, which only supplies the fifth device part 220 and the sixth device part 221 with electrical power from the power sources 250 and 251 via the first fuse 214 of the first device part 210.

In the exemplary difference from FIG. 2, the second device part 211 now feeds a fourth line section 242, which, instead of the first line section 240, now supplies the seventh device part 222 and the eighth device part 223 with electrical power from the power sources 250 and 251 via the second fuse 215 of the second device part 211.

In the exemplary difference from FIG. 2, the third device part 212 now feeds the second line section 241, which continues to supply only the ninth device part 230 and the tenth device part 231 with electrical power from the power sources 250 and 251 via the third fuse 216 of the third device part 212.

In the exemplary difference from FIG. 2, the fourth device part 213 now feeds a fifth line section 243, which, instead of the second line section 241, now supplies the eleventh device part 232 and the twelfth device part 233 with electrical power from the power sources 250 and 251 via the fourth fuse 217 of the fourth device part 213.

If a single circuit breaker of the circuit breakers 17 of a single fuse of the fuses 214 to 217 is now opened by its computer core 2 of its control device 4, the power sources 250 and 251 no longer supply the sub-network downstream of this fuse with electrical power. The fuses optionally have a standby capacity which further allows a limited delivery of electrical power for the purpose of a standby operation.

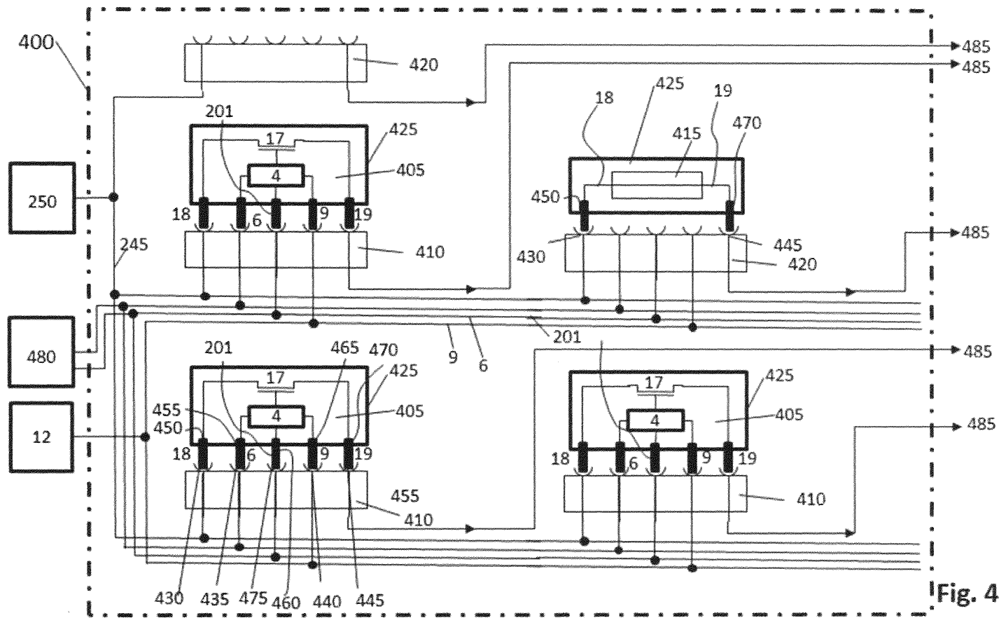

### FIG. 4

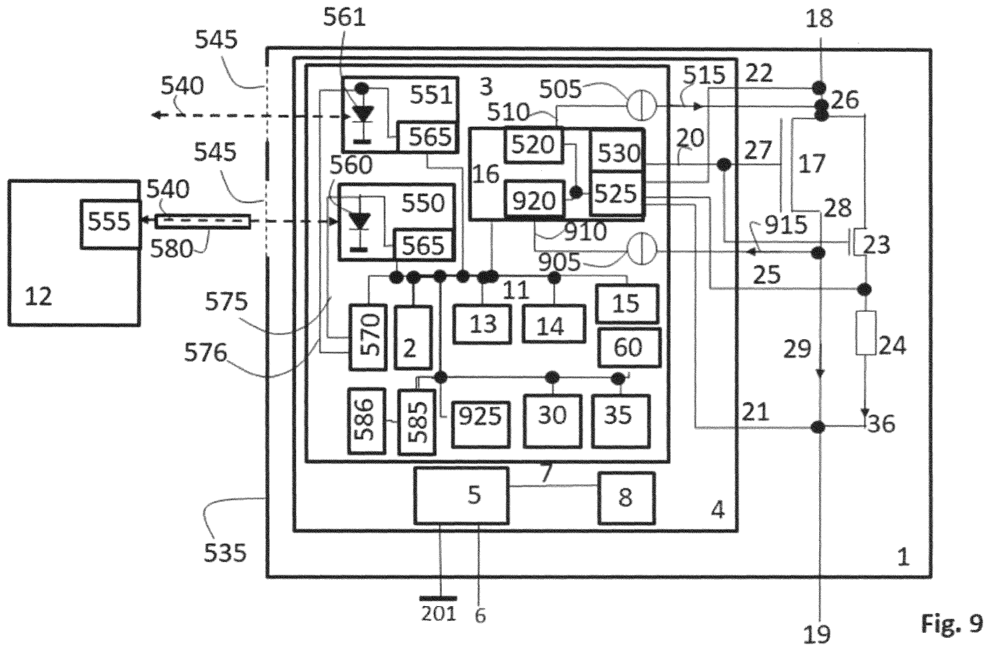

FIG. 4 shows in schematically simplified form an exemplary fuse box 400 with slots 410 and 420 for receiving electronic fuses 405 and melting fuses 415. A slot 410 for an electronic fuse 405 optionally has a first contact 430 for the first terminal 18 of the circuit breaker 17 of the electronic fuse 405 that can be inserted there. The slot 410 for an electronic fuse 405 furthermore optionally has a second contact 435 for the operating voltage terminal 6 of the electronic fuse 405. Here, the prerequisite is that the electronic fuse 405 does not derive the operating voltage for its operation from the potential at its first terminal 18 of its circuit breaker 17. In this case, the need for the second contact 435 is omitted, because this function can then take over for the first contact 430. The slot 410 for an electronic fuse 405 furthermore optionally has a third contact 475 for the reference potential terminal 201 of the electronic fuse 405. The slot 410 for an electronic fuse 405 furthermore optionally has a fourth contact 440 for the connection of the external data bus 9 of the electronic fuse 405. In the example of FIG. 9, the data bus 9 is a so-called one-wire data bus in which the return line of the data bus is typically identical to the reference potential line 201. The data bus 9 presented here is thus typically a fuse data bus 9 or an e-fuse data bus 9. In the automotive field, the data bus 9 is, for example, a Lin data bus 9 or a DSSI3 data bus 9 or a PSI5 data bus 9 or a CAN data bus 9 or a CAN FD data bus 9 or an Ethernet data bus or a Flexray data bus 9 or an LVDS data bus 9 or an otherwise wired or wireless data transmission path, for example via a Bluetooth or WLAN data connection or an optical data connection (540). The data communication of the computer core 2 of the control device 4 of the fuse 1 in this context runs via a wired or wireless interface (610, 10, 551, 550).

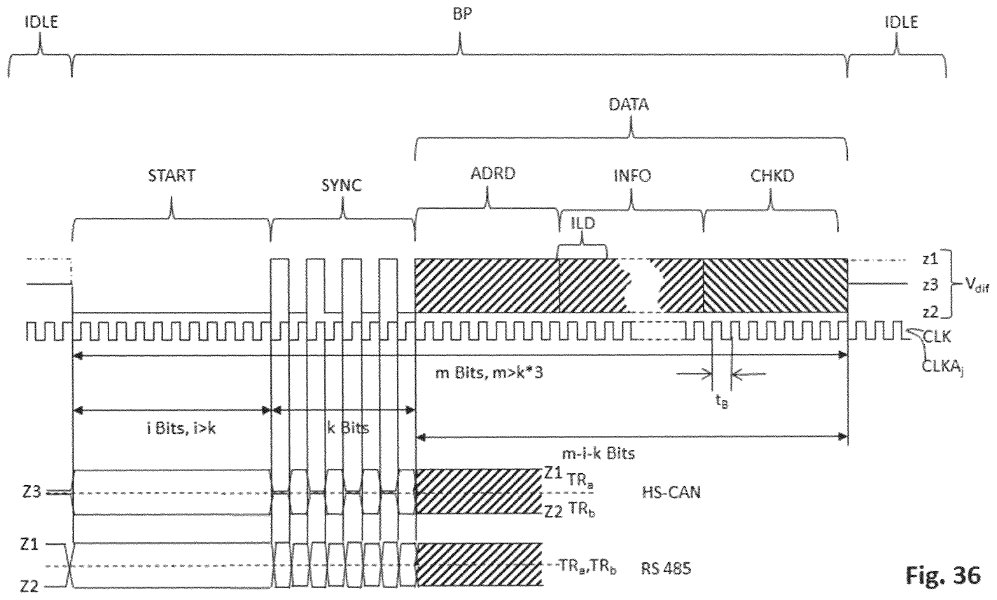

It is in particular conceivable that the data bus 9 is a differential data bus 9. In this case, the contact 440 of the data bus 9 in reality comprises a first electrical contact for the first line of the differential two-wire data bus and a second electrical contact for the second line of the differential two-wire data bus. Such a differential two-wire data bus can be, for example, a CAN data bus and/or a CAN FD data bus, which is used as a data bus 9. Because the CAN data bus protocol or the CAN FD data bus protocol requires a very good local oscillator, the use of a CAN data bus or a CAN FD data bus would lead to increased effort for clock-pulse generation in each individual fuse, which would cause the costs of such a data bus system to explode. For such a case of a differential fuse data bus 9, the disclosure therefore proposes the use of a CAN physical layer with a special fuse data protocol. For this purpose, the higher-level computer system 12 signals a synchronization signal to the oscillators 30 of the control devices 4 of the electronic fuses 405 via the data bus 9. Optionally, the synchronization signal is a so-called clock-run-in, in which, for example, a higher-level computer system transmits a predefined alternating 1-0-bit sequence from the higher-level computer system 12, for example, to one or more or all of the control devices 4 of electronic fuses 405 of the supply network 200 for a short time, for example. (In FIGS. 2 and 3, these would be the electronic fuses 214 to 217 and 225 to 225 and 235 to 238 and 255 and 256). The control devices 4 synchronize their oscillators 30 optionally in frequency magnitude and phase position to this synchronization signal. A data packet optionally has a start signal. Typically, the start signal is designed such that it is also detected by the data interface 10 of the control device 4 of an electronic fuse 405 even when the local oscillator 30 of the control device 4 of the relevant electronic fuse is not synchronous with the oscillator of the higher-level computer system 12. The oscillators 30 of the control devices 4 of the fuses 405 each provide the control devices 4, of which these oscillators 30 are each a part, at least one corresponding clock pulse for operating this corresponding control device 4. Typically, the data interface 10 or another sub-device of the control device 4 of an electronic fuse 405 generates from this clock pulse a sampling clock pulse with which the data interface 10 samples the logic values on the data bus 9 if it receives data via the data bus from the higher-level computer system or from the control device 4 of a different fuse or another device connected to the data bus 9. The transmitting bus participant optionally transmits the data via the data bus as a data packet with m data bits. Such a data packet optionally begins with a start signal. The synchronization phase for the oscillator 30 of this fuse 405 begins with the detection of the start signal by a data interface 10 of a fuse 405. After the synchronization of the oscillator 30, the control device 4 optionally freezes the frequency and phase control of its oscillator 30. The data interface 10 then samples the following bits up to the end of the data packet at a constant frequency and phase of the clock pulse of the oscillator 30 of the control device 4. The data interface 10 of the control device 4 of a fuse 405 recognizes the end of the data packet optionally with the aid of a stop symbol at the end of the data packet. The data interface optionally detects the end of the synchronization phase at a start symbol. This is optionally a predefined bit sequence. Optionally, the data interface allows the detection of such a start symbol only a predetermined time after the start of the synchronization phase. The regulation of frequency and phase of the oscillator 30 of a control device 4 of an electronic fuse 405 optionally ends when this time expires and therefore when the sampling clock of the data interface 10 is generated from this clock pulse of the oscillator 30. The disclosure accordingly discloses a device for controlling electrical and/or electronic data interfaces 10 of control devices 4 of fuses of a supply network 200 with a serial, bidirectional, differential data bus 9 and with n data interfaces 10 of n control devices 4 of n fuses with n as a positive integer greater than 1 and with a higher-level computer system 12. The serial, bidirectional, differential data bus 9 has a first one-wire data bus and a second one-wire data bus. The voltage value between the first one-wire data bus and the second one-wire data bus typically represents the possibly transmitted logic information-any datum that may be present. Each of the n fuses optionally has at least one differential, serial data bus interface 10 as part of its corresponding control device 4. Each control device 4 of each of these fuses optionally comprises an oscillator 30 which generates a fuse-specific clock pulse CLKj for operating the control device 4 of this fuse—in this case referred to as the jth fuse. The corresponding data interface 10 of a control device 4 of a fuse optionally comprises a sampling device which samples the data bus 9 with a sampling clock pulse, which is optionally derived from the clock pulse of the oscillator 30 of the control device 4 of this fuse. The control device 4 of a fuse optionally comprises an address detection unit and a fuse address register. The data bus interface 10 or the computer core 2, for example, can comprise here the fuse address register. The serial, bidirectional, differential data bus 9 can optionally be located at least in a first differential logic state (high, z1) and in a second differential logic state (low, z2). The serial data bus interface 10 of the control device 4 of the at least one fuse of the n fuses is in each case connected to the serial, bidirectional differential data bus 9 in order to transmit data via this serial, bidirectional differential data bus 9 and/or to receive data from other computer cores 2 of other control devices 4 of other fuses or a higher-level computer system 12 via this serial, bidirectional, differential data bus 9. Typically, the higher-level control device 12 also receives control commands from the outside for controlling the n fuses. Typically, the higher-level control device 12 converts these control commands initiated from the outside into bit streams and bus stream packets BP to be transmitted via the serial, bidirectional, differential data bus 9 to the computer cores 2 of the control devices 4 of the fuses via their data bus interfaces 10. The higher-level computer system 12 then typically transmits the bits of the bit streams and bit stream packets to be transmitted by the higher-level computer system 12 via the serial, bidirectional, differential data bus 9, depending on a clock pulse CLK within the higher-level computer system 12. The higher-level computer system 12 receives bit streams and/or bit stream packets BP generated by the computer cores 2 of the control devices 4 of the electronic fuses via the serial, bidirectional, differential data bus 9. The corresponding oscillator 30 of the corresponding control device 4 of the corresponding fuse typically generates a corresponding sampling signal CLKAj for the corresponding data bus interface 10 of the control device 4 of the corresponding fuse from the corresponding clock pulse of the corresponding oscillator 30 of the corresponding control device 4 of the corresponding fuse. The sampling device ATj of the corresponding data bus interface 10 of the corresponding control device 4 of the corresponding fuse then optionally samples, depending on its corresponding sampling signal CLKAj of the oscillator 30 of the control device 4 of this fuse, the bit streams and/or bit stream packets BP transmitted via the serial, bidirectional, differential data bus 9 in order to obtain a local bit stream from the received bit stream and/or bit stream packet BP in the corresponding control device 4 of the corresponding electronic fuse. The higher-level computer system 12 optionally transmits the bit streams to be transmitted as sequences of bits in bit stream packets (or frames, BP). According to the technical teaching of the disclosure, the bit stream packets BP comprise a temporal sequence of m individual bits of the bit stream packet BP with the same time length tB. Here, m is a positive integer. The time length tB of the individual bits varies in this case by no more than a factor of +/−(0.4/m)*tB within a bit stream packet BP. After the end of the synchronization phase for a bit stream packet, the sampling device of the data bus interface 10 of a control device 4 of a fuse samples the individual bits on the data bus 9 optionally in their temporal center. The regulation of the frequency and phase position of the clock pulse signal that the oscillator 10 generates and/or the sampling signal CLKj is then frozen for the remainder of the reception of the bit stream packet BP. The time length of m periods of the sampling signal CLKj optionally deviates by no more than +/−(0.4/m)*t_{B} from the length m*t_{B} from m individual bits of a received bit stream packet, so that the sampling device of the data bus interface 10 of the control device 4 of the electronic fuse also samples the last individual bit in a manner conforming to assignment and a double sampling of an individual bit or a non-sampling of an individual bit does not take place. In order for this to be possible, at least a portion of the bit stream packets BP transmitted by the higher-level computer system 12 optionally has the following contents (see also FIG. 36):
a START signal in the form of i bits with i as the positive integer with i−1>m of the m bits of the corresponding bit stream packet BP with a second differential logic state z2 on the serial, bidirectional, differential data bus 9;
synchronization information SYNC from k synchronization bits, with k as a positive integer, and k<m/3, for synchronization of the corresponding sampling signal CLKAj of the corresponding sampling device of the corresponding data bus interface 10 of the corresponding control device 4 of the corresponding electronic fuse and/or of the corresponding oscillator 30 of the corresponding control device 4 of the corresponding fuse with the clock pulse CLK of the higher-level computer system 12;
data information DATA from the remaining bits of the m-i-k bits of the m bits of the corresponding bit stream packet BP, wherein the data information optionally comprises DATA address information ADRD and useful information INFO and check information CHKD.

The check information CHKD can be, for example, CRC checksums and/or parity bits. At least one part of the useful information INFO optionally comprises configuration information ILD. This configuration information ILD can comprise, for example, threshold values and values of switch-off thresholds which, if necessary, can determine when the computer core 2 of a control device 4 of an electronic fuse opens or closes the circuit breaker 17 of this electronic fuse. Optionally, the higher-level computer system 12 transmits configuration commands via the fuse data bus 9 to the computer cores 2 of the control devices 4 of the fuses by means of this configuration information ILD. For example, such configuration commands may depend on a determined power requirement of loads in sub-networks of the supply network 200 and on an ascertained power supply capacity of power sources in sub-networks of the supply network 200. Such configuration commands in this configuration information LD can, for example, possibly cause the opening and closing of circuit breakers 17 of electronic fuses of the supply network 200 by the computer cores 2 of these electronic fuses. The higher-level computer system 12 optionally dynamically adjusts the electrically effective topology of the supply network 200 of the supply lines to the fuses of the supply network 200 by means of such configuration commands via the fuse data bus 9, according to the determined power requirement and/or according to the determined power supply capacity and/or according to the current safety requirement. The computer cores 2 of the control devices 4 of electronic fuses each receive and transmit data via their corresponding data interface 10 of the corresponding control device 4 of the corresponding electronic fuse via the data bus, wherein this data can comprise configuration information ILD, such as configuration data (read-write) and/or switch commands (read-write), but also diagnostic data (read-write), measured values (read) and comparison value settings (read-write). Optionally, the data bus 9 is connected directly or indirectly, for example via gateways or the like, to a terminal (740) for an input for reconfiguration of the supply network 200 by means of the electronic fuses. In the event of a system emergency scenario, the higher-level computer system 12 adapts the current consumption of a load of the loads of the supply network 300 to the weakest supply line in the path between one or more power sources of the power sources of the supply network 200, on the one hand, and this load of the loads, on the other hand, by reconfiguration or operating parameter change of this load. In addition, in the event of a system emergency scenario, the higher-level computer system 12 adapts the current supply capacity of a power source of the power sources of the supply network 200 to the weakest supply line in the path between this power source of the power sources of the supply network 200, on the one hand, and loads of the loads of the supply network 200 by reconfiguration or operating parameter change of this power source of the power sources of the supply network 200. The higher-level computer system 12 initiates a configuration change of the supply network 200 by corresponding commands via one or more data buses 9 to electronic fuses of the supply network 200. Firstly, the higher-level computer system 12 optionally determines how much power a load of the loads of the supply network 200, which load is affected by the configuration change of the supply network 200, may consume in order not to overload the supply network 200 at any point. The higher-level computer system 12 then optionally communicates to this relevant load of the loads of the supply network 200 how much power this load of the loads of the supply network 200 may consume from the supply network 200. Secondly, the higher-level computer system 12 optionally determines how much power a power source of the power source of the power sources of the supply network 200, which power source is affected by the configuration change of the supply network 200, may supply in order not to overload the supply network 200 at any point. The higher-level computer system 12 optionally communicates to this relevant power source of the power sources of the supply network 200 how much power this power source of the power sources of the supply network 200 is permitted to supply.

The configuration information ILD thus optionally serves to control the power supply of the device parts and to control the power extraction from the power sources and to control the loading of the supply lines of the supply network 200. According to the technical teaching of the disclosure, this control is performed by the computer core 2 of a control device 4 of an electronic fuse of the supply network 200 optionally depending on this configuration information ILD of a bit stream packet BP if the logic content of the address information ADRD of this bit stream packet BP matches the content of the fuse address register of the computer core 2 or of the data bus interface 10 of the control device 4 of the fuse. The corresponding address recognition units of the corresponding data bus interfaces 10 or of the computer cores 2 of the control devices 4 of the electronic fuses evaluate the address information ADRD of the bit stream packets BP and only allow use of the useful information INFO contained in the relevant bit stream packet BP by the corresponding computer core 2 of the corresponding control device 4 of the corresponding fuse if the content of the address information ADRD of the bit stream packet BP corresponds to the current content of the fuse address register of the relevant fuse. The control devices 4 of the electronic fuses and the data interfaces 10 thereof optionally have means in order to carry out an auto addressing method in order to fill the fuse address register with a logic fuse address which corresponds to the physical position of this fuse within the serial, bidirectional, differential data bus 9. Optionally, the higher-level computer system 12 and/or computer cores 2 of control devices 4 of fuses deduce an incorrectly running oscillator 30 of one or more fuses based on the evaluation of the received check information CHKD. If necessary, these fuses then regulate their oscillators 30. Optionally, the oscillators 30 of the control devices 4 of the fuses 405 of a supply network 200 each have a frequency stability after synchronization of these oscillators 30 with the synchronization signal SYNC in the synchronization phase, which stability is substantial enough that such an error should not occur in the CRC check.

Optionally, the slot 410 of an electronic fuse 405 of the fuse box 400 has a first contact 430 for the first terminal 18 of the circuit breaker 17 of the electronic fuse 405. This first contact 430 is optionally connected to the power source 250 via the third supply line section 245 for supplying power to the corresponding supply line 485 protected by this fuse 405. The first contact 430 of the slot 410 for the electronic fuse 405 optionally serves to connect the first terminal 18 of the electronic fuse 405. The first contact 450 of the fuse body 425 corresponds to the first contact 430 of the slot 410 of the electronic fuse 405 of the fuse box 400. The first contact 450 of the fuse body 425 serves to connect the first terminal 18 of the electronic fuse 405.

Optionally, the slot 410 of an electronic fuse 405 of the fuse box 400 has a second contact 445 for the second terminal 19 of the circuit breaker 17 of the electronic fuse 405. This second contact 445 is optionally electrically connected to the corresponding output 485 of the fuse box 400 for supplying a load of the supply network 200 via a downstream supply line section of the supply line sections (240 to 243) of the supply network 200. The second contact 445 of the slot 410 for the electronic fuse 405 optionally serves to connect the second terminal 19 of the electronic fuse 405. The second contact 470 of the fuse body 425 corresponds to the second contact 445 of the slot 410 of the electronic fuse 405 of the fuse box 400. The second contact 470 of the fuse body 425 serves to connect the second terminal 19 of the electronic fuse 405.

Optionally, the slot 410 of an electronic fuse 405 of the fuse box 400 has a third contact 440 for the connection of the data bus 9 of the data bus interface 10 of the control device 4 of the electronic fuse 405. This third contact 440 is optionally connected with data technology to the data bus 9 of the fuse box 400 and the supply network 200. The third contact 440 of the slot 410 for the electronic fuse 405 optionally serves to connect the data bus 9 to the data bus interface 10 of the control device 4 of the electronic fuse 405. The third contact 465 of the fuse body 425 corresponds to the third contact 440 of the slot 410 of the electronic fuse 405 of the fuse box 400. The third contact 465 of the fuse body 425 serves to connect the data bus 9 of the supply network 200 to the data interface 10 of the control device 4 of the electronic fuse 405.

Optionally, the slot 410 of an electronic fuse 405 of the fuse box 400 has a fourth contact 435 for the connection of a supply voltage line for supplying power to the control device 4 of the electronic fuse 405. This fourth contact 435 is optionally electrically connected to the supply voltage line for supplying power to the control device 4 of the electronic fuse 405. The supply voltage line is connected to a power source 250 via a third supply line section 245, for example. The fourth contact 435 of the slot 410 for the electronic fuse 405 optionally serves to connect the supply voltage line to supply power to the control device 4 of the electronic fuse 405. The fourth contact 455 of the fuse body 425 corresponds to the fourth contact 435 of the slot 410 of the electronic fuse 405 of the fuse box 400. The fourth contact 455 of the fuse body 425 serves to connect the power source 250 by means of the exemplary, third supply line section 245 to the supply voltage line for supplying power to the control device 4 of the electronic fuse 405.

Optionally, the slot 410 of an electronic fuse 405 of the fuse box 400 has a fifth contact 475 for connecting a supply voltage line 201—in this case the reference potential line 201—for supplying power to the control device 4 of the electronic fuse 405. This fifth contact 475 is optionally electrically connected to the supply voltage line 201 for supplying power to the control device 4 of the electronic fuse 405. The supply voltage line-in this case the reference potential line 201—is connected to the power source 250 via the body of the vehicle, for example. The fifth contact 475 of the slot 410 for the electronic fuse 405 optionally serves to connect the second supply voltage line-in this case the reference potential line 201—to supply power to the control device 4 of the electronic fuse 405. The fifth contact 460 of the fuse body 425 corresponds to the fifth contact 475 of the slot 410 of the electronic fuse 405 of the fuse box 400. The fifth contact 460 of the fuse body 425 serves to connect the reference potential line 201 of the power source 250 to the supply voltage line-in this case the reference potential line 201—for supplying power to the control device 4 of the electronic fuse 405. The fifth contact 460 of the fuse body 425 is optionally used to control the control device 4 of the electronic fuse 405 as a reference potential point.

An operating voltage source 480 for operating the control devices 4 of the electronic fuses 405 feeds the electrical power for operating the control devices 4 of the fuses 405 into the supply voltage line for the operating voltage 6. Here, the body ground of the reference potential line 201 is optionally in turn used as a return line.

Optionally, the slots 420 for the melting fuses 415 are designed such that they are at least mechanically compatible with the slots 410. The slots 410 for the electronic fuses 405 are optionally designed such that production and/or maintenance and/or repair work can alternatively also equip said slots with conventional melting fuses 415. Optionally, the melting fuses 415 are mechanically designed such that they mechanically and optionally also electrically fit into a slot 410 for an electronic fuse 405.

The electronic fuses 405 are optionally designed such that they also mechanically fit into a slot 420 for a conventional fuse. In the event that such a slot 420 for a conventional fuse 415 does not have any contacts 435, 475 for supplying electrical power to the electronic fuse 405, the electronic fuse 405 has to comprise a power reserve 8 which must be provided with power before the electronic fuse 405 is installed into the plug connection 420. For example, in the case of the power reserve 8, it can be a battery or an accumulator. Such an electronic fuse 405 then optionally comprises a signaling means, for example an LED, in order to be able to query the charge state at least on request via a-optionally optical-data interface 550.

The technical teaching of the disclosure proposes a fuse box 400 for a supply network 200 of a vehicle. The proposed fuse box 400 comprises electronic fuses 405 and/or slots 410 for electronic fuses 405. The proposed fuse box has melting fuses 415 and/or slots 420 for melting fuses 415. Optionally, at least one electronic fuse 405 of the electronic fuses of the proposed fuse box 400 has a first terminal 18 and a second terminal 19, wherein this at least one electronic fuse 405 is configured to emulate the behavior of a melting fuse 415. For this purpose, this electronic fuse optionally detects the value of the electrical current 29 through its circuit breaker 17 and determines the temporal integral of a polynomial of at least the second degree of this current value. The electronic fuse 405 is optionally configured to detect the value of the electrical current 29 flowing through this electronic fuse 405 from the first terminal 18 to the second terminal 19 or vice versa. This electronic fuse 405 is optionally configured to determine, by means of a polynomial of at least the second degree, an intermediate value from this detected current value and to temporally integrate it into an integrated intermediate value. The electronic fuse is optionally configured to prevent the current flow of the current 29 between the first terminal 18 and the second terminal 19 by opening its circuit breaker 17 if the integrated intermediate value exceeds a maximum value. This corresponds to the melting of a conventional thermal fuse. The electronic fuse 405 is optionally accommodated in a fuse body 425 with plug-in connectors, which body mechanically and optionally also electrically fits in one of the slots 410 for electronic fuses 405. The fuse box 400 optionally additionally comprises at least sections of the fuse data bus 9.

Optionally, a slot 410 for an electronic fuse 405 has a first contact 430 of the slot 410 and a second contact 445 of the slot 410. The first contact 430 of the slot 410 is optionally configured to establish an electrical connection between this first contact 410 of the slot 410 and a first contact 450 of a plug-in connector of a fuse body 425 in order to electrically connect the first terminal 18, 450 of the fuse 405 of the fuse body 425 to the first contact 430 of the slot 410.

The second contact 445 of the slot 410 is optionally configured to establish an electrical connection between this second contact 445 of the slot 410 and a second contact 470 of the plug-in connector 410 of the fuse body 425 in order to electrically connect the second terminal 19, 470 of the fuse 405 of the fuse body 425 to the second contact (445) of the slot 405.

In the proposed fuse box 400, a slot 410 for an electronic fuse 405 optionally has a third contact 440 of the slot 410, wherein the third contact 440 of the slot 405 is configured to establish an electrical connection between this third contact 440 of the slot 405 and a third contact 465 of the plug-in connector 410 of the fuse body 425 in order to electrically connect the data line 9 of the data interface 10 of a control circuit 4 of the electronic fuse 405 of the fuse body 425 to the third contact 440 of the slot 405.

The proposed fuse box 400 optionally has a slot 410 for an electronic fuse 405 with a fourth contact 435 of the slot 410. The fourth contact 435 of the slot 410 is optionally intended to establish an electrical connection between this fourth contact 435 of the slot 410 and a fourth contact 455 of the plug-in connector of the fuse body 425 in order to electrically connect a power supply of the control device 4 of the electronic fuse 405 to the fourth contact 455 of the slot 410.

The disclosure proposes a fuse body 425 of an electronic fuse 405 for a proposed fuse box 400, in which the plug-in connector of the fuse body 425 has a first contact 450 for the first terminal 18 of the electronic fuse 405 and a second contact 470 for the second terminal 19 of the electronic fuse 405. Optionally, the plug-in connector mechanically fits into at least one of the slots 410 for electronic fuses 405.

The plug-in connector of the fuse body 425 optionally has a third contact 465 for a fuse data bus 9, wherein the third contact 465 is electrically connected to the data line 9 of a data interface 10 for the control circuit 4 of the electronic fuse 405 of the fuse body 425.

The plug-in connector of the fuse body 425 optionally has at least one fourth contact 455 for a voltage supply 6 of the control device 4 of the electronic fuse 405.

The disclosure proposes a melting fuse 415 for a fuse box 400, in which the plug-in connector 410 of the fuse body 425 has a first contact 455 for the first terminal 18 of the melting fuse 415 and has a second contact 470 for the second terminal 19 of the melting fuse 415. The plug-in connector of the melting fuse 415 is optionally configured to mechanically fit into at least one of the slots 410 for electronic fuses 405 and to mechanically fit into at least one of the slots 420 for melting fuses 415.

### FIG. 5

FIG. 5 is based on FIG. 1 and represents a modification of FIG. 1. The fuse 1 of FIG. 5 additionally comprises a first test current source 505, which feeds an electrical test current 515 into the first terminal 26 of the circuit breaker 17 of the fuse 1. The additional first electrical test current 515 is optionally provided with a first modulation signal {505} of a first signal generator 520 by means of the first control signal 510. In this case, the curly brackets are supposed to indicate that {505} is the first modulation signal with which the first current 515 of the first test current source 505 is modulated.

In FIG. 5, for better clarity, not all appropriate and in some cases customary device components are shown. Further device components that the reader can assume as possibly present in FIG. 1 can be found, for example, in FIGS. 1, 6, 9, 24, 41, 42, 52, 53, 54, 55, 57, 58 and 62. The combination of the device parts of the Figure described here with those of these figures is expressly part of the disclosure of the disclosure.

The control device 4 optionally comprises a first gate drive 530 of the control contact 27 of the first circuit breaker 17 and a first control signal generation for the control signal of the control line 20 of the first circuit breaker 17 for controlling the first circuit breaker 17. Optionally, the computer core 2 controls the first gate drive 530 via the internal data bus 11.

The proposed fuse 1 optionally comprises a first correlator 525. Optionally, the computer core 2 of the control device 4 of the fuse 1 controls the first correlator 525 via the internal data bus 11. The first correlator 525 optionally comprises one or more input amplifiers which detect, filter, and process the voltages between the first measuring contacts (21, 25, 27, 28, 22). Optionally, the first correlator 525 comprises, for example, a first synchronous demodulator which checks one of the measurable voltages for first components of the first modulation signal {505} of the first current 515 of the first test current source 505. Optionally, the first synchronous demodulator of the first correlator uses a correlation in the form of a scalar product, for example according to the formula:

$$A = 〈 \{ 505 \} \vert {V}_{x y} ( t ) 〉 = {\int }_{0}^{T} \{ 505 \} \times {V}_{x y} ( t ) d t .$$

A here represents the value of the first component, and V_{xy} represents a voltage between the first measuring contacts (21, 25, 27, 28, 22). Optionally, the first correlator 525 uses a voltage V_{xy} between the second terminal 28 of the first circuit breaker 17 and the first control terminal 27 of the first circuit breaker 17. Optionally, the proposed fuse 1 has a housing 535 of the fuse 1. Optionally, the housing 535 of the fuse 1 has one or more optical windows 545 via which the control device 4 of the fuse 1 can carry out signaling to other devices and/or humans.

The disclosure proposes an electronic fuse 1 which has a first terminal 18 and a second terminal 19. The proposed electronic fuse 1 furthermore has a circuit breaker 17 and a control device 4. According to the proposal, the circuit breaker 17 has a first terminal 26, a control terminal 27 and a second terminal 28. Optionally, it is a MOS transistor. The first terminal 26 of the circuit breaker 17 is optionally electrically connected to the first terminal 18 of the fuse 1, and the second terminal 28 of the circuit breaker 17 is optionally electrically connected to the second terminal 19 of the fuse 1. The control terminal 27 of the circuit breaker 17 is typically electrically connected to the control device 4. According to the proposal, the control device 4 of the electronic fuse 1 detects electrical voltages between the terminals (26, 27, 28) of the circuit breaker 17 and/or functionally equivalent values of physical parameters within the fuse 1 and determines therefrom a value for an electrical current 29 through the circuit breaker 17 between the first terminal 26 of the circuit breaker 17 and the second terminal 28 of the circuit breaker 17.

The electronic fuse 1 has an electronic test current source 505 which is connected to the circuit breaker 17 in such a way that it can feed an additional current 515 into the circuit breaker 17 between the first terminal 26 of the circuit breaker 17 and the second terminal 28 of the circuit breaker 17 depending on a first control signal 510 of the control device 4. The control device 4 modulates the control signal 510 optionally with a first modulation signal {505}. This modulation signal {505} in turn, modulates the temporal value characteristic of the value of the additional current 515. The control device 4 optionally detects or determines the temporal value characteristic of the value of the electrical current 29 through the circuit breaker 17. Optionally, the control device 4 checks whether the temporal value characteristic of the value of the electrical current 29 comprises signal components of which the modulation correlates with the modulation of the modulation signal. In order now to be able to detect the proportion of the test current 515 modulated in this way in the current 29 through the circuit breaker 17, the control device 4 of a proposed fuse 1 optionally comprises a synchronous demodulator 525 or a functionally equivalent device, such as a matched filter. The synchronous demodulator 525 typically determines the correlation between the signal of the temporal value characteristic of the electrical current 29 through the circuit breaker 17, on the one hand, and the temporal value characteristic of the modulation signal {505}, on the other hand. For example, a synchronous demodulator 525 can determine the value of the function C₂₉ₘ=∫I₂₉(t)×M(t)dt, wherein I₂₉(t) represents the value characteristic of the electrical current 29 through the circuit breaker 17 and M(t) represents the temporal value characteristic of the modulation signal {505} and C₂₉ₘ represents the correlation value which the synchronous demodulator 525 determines. Other correlation methods are conceivable. In the method proposed here, the synchronous demodulator 525 multiplies the modulation signal {505} or a signal derived therefrom or a signal which is in a fixed temporal relationship with the modulation signal {505}, on the one hand, optionally with the temporal value characteristic I₂₉(t) of the electrical current 29 or a signal derived therefrom, on the other hand. The synchronous demodulator 525 then filters the signal resulting from the multiplication to form a correlation signal. Optionally, this filtering is a low-pass filtering, so that the synchronous demodulator 525 then implements the function C₂₉ₘ=∫I₂₉(t)×M(t)dt in this way. At minimum, the synchronous demodulator should show the integrating effect of a low-pass filter at least in terms of frequency range. To determine the correlation signal C₂₉ₘ(t), the synchronous demodulator 525 or the control device 4 can comprise a matched filter optimized for the modulation signal (505) and/or a matched filter and/or a Kalman filter or another estimation filter, which converts the temporal value characteristic I₂₉(t) of the electrical current 29 to the correlation signal C₂₉ₘ(t).

Typically, the control device 4 switches the circuit breaker 17 to non-conductive if the sign of the electrical voltage between the first terminal 18 of the fuse 1 and the second terminal 19 of the fuse 1 does not correspond to a default value. For this purpose, the control device 4 detects the electrical voltage between the first terminal 18 of the fuse 1 and the second terminal 19 of the fuse 1. For example, the computer core 2 of the control device 4 can use an analog-to-digital converter 570 in order to detect the potentials on the circuit breaker 17 or on an auxiliary circuit breaker 23 via corresponding measuring lines 22, 21, 25. The auxiliary circuit breaker 23 optionally serves to detect an auxiliary current which is proportional to the current through the circuit breaker (17) or corresponds thereto in another way. A shunt resistor 24 then enables the computer core 2 of the control device 4 of the fuse 1 to measure this auxiliary current by means of the corresponding measuring lines 25, 21 and by means of the analog-to-digital converter 570. In FIG. 5, for better clarity, the connections between the analog-to-digital converter 570 and the measuring lines 20, 21, 22, 25 are not shown. The reader should assume it as present and disclosed. Optionally, the computer core 2 of the control device 4 of the fuse 1 switches the circuit breaker 17 to non-conductive if the electrical voltage between the first terminal 18 of the fuse 1 and the second terminal 19 of the fuse 1 falls below a first default value. Optionally, the computer core 2 of the control device 4 of the fuse 1 switches the circuit breaker 17 to non-conductive if the electrical voltage between the first terminal 18 of the fuse 1 and the second terminal 19 of the fuse 1 exceeds a second default value. Typically, the electronic fuse 1 comprises a reference potential terminal 201. Optionally, the computer core 2 of the control device 4 of the fuse 1 switches the circuit breaker 17 to non-conductive if the electrical voltage between the first terminal 19 of the fuse 1 and the reference potential terminal 201 of the fuse 1 falls below a third default value. Optionally, the computer core 2 of the control device 4 of the fuse 1 switches the circuit breaker 17 to non-conductive if the electrical voltage between the second terminal 19 of the fuse 1 and the reference potential terminal 201 of the fuse 1 falls below a fourth default value. Optionally, the computer core 2 of the control device 4 of the fuse 1 switches the circuit breaker 17 to non-conductive if the electrical voltage between the first terminal 18 of the fuse 1 and the reference potential terminal 201 of the fuse exceeds a fifth default value. Optionally, the computer core 2 of the control device 4 of the fuse 1 switches the circuit breaker 17 to non-conductive if the electrical voltage between the second terminal 19 of the fuse 1 and the reference potential terminal 201 of the fuse 1 exceeds a sixth default value. As a result, the control device 4 of the electronic fuse 1 ensures that the downstream supply sub-network is only operated in a predetermined voltage range.

Optionally, the circuit breaker 17 and the control device 4 are accommodated in a common housing 535. This has the advantage that the EMC compatibility is increased.

The control device 4 of the electronic fuse can, for example, have an optical data interface 550 in order to achieve good galvanic isolation between the protected supply line at the first terminal 18 of the fuse 1 and/or at the second terminal 19 of the fuse 1. In order to be able to control this optical data interface 550, the housing 535 optionally has an optical window 545, which allows electromagnetic radiation to enter the housing 535 and thus allows an interaction of the optical data interface 550 with this electromagnetic radiation that has entered, so that the optical data interface 550 can in this way receive an optically transmitted signal 540. Conversely, the optical data interface 550 can emit electromagnetic radiation 540 which can then leave the housing 535 via this optical window 545 in the housing 535 of the fuse 1. Thus, such optical windows 545 are optionally sub-devices of one or more optical data interfaces 550 of the control device 4 of the relevant electronic fuse 1. Such an optical window 545 thus allows the entry and/or exit of electromagnetic radiation for the transport of data from and to the control device 4 of the fuse and thus makes it possible for an optical interface 550 of the control device 4 of the fuse 1 within the housing 535 to be able to communicate via this optical window 545 with an optical interface 555 of a different device 12, for example a higher-level computer system 12, outside the housing 535 via an optical data connection 540. Optical functional elements 580 can guide and/or configure the optical data connection 540. Such optical functional elements can be deflecting functional elements such as mirrors and/or prisms and the like, and/or cross-section-modifying functional elements such as apertures and/or focusing functional elements such as lenses and/or concave mirrors and/or light-guiding optical functional elements such as optical waveguides and the like. Such a fuse with an optical data interface 550 optionally has an optical plug connection which allows the mechanical establishment of the optical connection between the optical data bus interface 550 and the optical data connection 540. Such an optical window 545 also enables the computer core 4 of the control device 4 or the control device 4 of the fuse 1 to signal to a human by means of an optical visible signal. For example, the fuse can emit a red light through the optical window 545 if the circuit breaker 17 is open. Likewise, the fuse 1 can emit an optical signal that can be recognized by a human via such an optical window 545 and indicates the charge state of the power reserve 8. The electromagnetic radiation for the transport of data which the optical interface 550 emits and/or receives is optionally laser radiation of a laser 560 or radiation of an LED 560. The disclosure therefore proposes that the proposed fuse 1 optionally comprises a laser 560 or an LED 560. Optionally, the computer core 2 of the control device 4 of the fuse 1 uses this laser or this LED as a transmitter of data of the optical data interface 550 of the control device 4 of the fuse 1. In certain implementation scenarios, there may be a need to install no separate laser or no separate LED into the housing 545 of the fuse 1, but rather to produce the LED monolithically with the remainder of the control circuit 4 of the fuse in a semiconductor crystal. In this case, it is particularly favorable if the control circuit 4 of the electronic fuse 1 has a silicon-based LED 560 as an LED. Typically, the control circuit then comprises a driving device 565 for operating the silicon-based LED, which driving device provides the operating voltage for the silicon-based LED. The silicon-based LED 560 is optionally a silicon avalanche LED 560, in particular a SPAD diode 560 operated as an LED. The driving device 656 optionally operates this above the breakdown voltage in the reverse direction. The driving device 565 generates the necessary operating voltage for the silicon-based LED 560 from the operating voltage of the electronic fuse 1 between the terminals 6, 201 by means of a voltage converter of a voltage supply 5.

The optical data bus interface 550 optionally also comprises an optical receiver. Optionally, this optical receiver of the data bus interface 550 is a photodiode. To achieve a maximum synergy, it may be expedient if the control device of the electronic fuse 1 operates the silicon-based LED 560, at least at times, as a receiver of the optical data bus interface 550. Optionally, the computer core 2 of the control device 4 of the electronic fuse 4 can disconnect the silicon LED 560 from the electrical supply of the voltage converter of the voltage supply 5 by means of an isolating switch of the control device 4 of the electronic fuse 1, and thus modulate the emitted light signal of the silicon LED 560 for the purpose of data transmission, or switch the silicon LED from the transmission mode into the receiving mode. In receiving operation, the computer core 2 optionally detects the voltage signal 575 of the silicon LED 560 by means of the analog-to-digital converter 570 of the control device 4 of the electronic fuse 1 and thus generates a digitized input data signal. The computer core 2 of the control device 4 of the fuse 1 uses the value detected in this way as an input data signal of the optical data interface 550 and extracts the data transmitted thereto from this input data signal data stream. Of course, the control device 4 of the electronic fuse 1 can also comprise a separate photodetector, for example a photodiode 560, and evaluation electronics of the photodetector 560. The electronic fuse 1 is optionally configured such that the optical waveguide 580 and/or other optical functional means connect the electronic fuse 1 to one or more other electronic fuses (214 to 217,225 to 223, 230 to 235, 225 to 256) via the corresponding optical data interface 550 of these electronic fuses. Optionally, a supply network 200 comprises an optical data network as a data bus 9, with which the optical data interface 555 of a higher-level computer system 12 and/or the data interfaces 550 of the control devices 4 of the fuses of the supply network 200 can communicate with one another. In particular, if an increased requirement for galvanic isolation exists, the proposed electronic fuse 1 is optionally connected via its optical interface 550 and an optical waveguide 580 to an optical interface 555 of a higher-level computer system 12, for example, a higher level computer system (12), and, as appropriate, to one or more further electronic fuses (214 to 217, 225 to 223, 230 to 235, 225 to 256). In addition to data communication via this optical data interface 550 or the wired data interface 10, the control device 4 of the fuse 1 can be connected via a further, different optical data interface 551 or other data interface 610 to a higher-level controller and/or a higher-level computer system 12 and, as appropriate, to the control devices 4 of one or more further electronic fuses (1, 214 to 217, 225 to 223, 230 to 235, 225 to 256). A typically occurring error is an overheating of the fuse 1. In this case, both the circuit breaker 17 and the control device 4 can overheat. The control device 4 of the electronic fuse optionally comprises one or more temperature sensor evaluation devices 585. The control device 4 of the fuse 1 optionally comprises a temperature sensor 586, for example a p-n junction or a PTC resistor or an NTC resistor, which detect the temperature of the control device 4 of the fuse 1 and convert it into an electrical signal, which the temperature sensor evaluation device 585 and/or the analog-to-digital converter 570 convert into a measured variable for the computer core 2 of the control device 4 of the electronic fuse 1. Optionally, the circuit breaker 17 of the fuse 1 comprises a temperature sensor 586, for example a p-n junction or a PTC resistor or an NTC resistor, which detect the temperature of the circuit breaker 17 of the fuse 1 and convert it into an electrical signal, which the temperature sensor evaluation device 585 and/or the analog-to-digital converter 570 convert into a measured variable for the computer core 2 of the control device 4 of the electronic fuse 1. In this way, the computer core 2 of the control device 4 of the fuse 1 can detect a thermal overload of the circuit breaker 17 and/or of the control device 4 and can open the circuit breaker 17 before the occurrence of damage and/or transmit an impending overload of the circuit breaker 17 and/or of the control device 4 of the fuse 1 via the data bus 9 to the higher-level computer system 12. The electronic fuse 1 thus optionally comprises one or more temperature sensors 586 for monitoring the safe operation of the fuse 1. The control device 4 of the fuse 1 evaluates temperature measured values of the one or more temperature sensor evaluation devices 585, which the temperature sensors 586 measure. The temperature sensor evaluation devices 585 detect these temperature measured values with the aid of temperature sensors external to the electronic control device 4 and/or with the aid of temperature sensors 586 of the electronic fuse 1.

In many applications, it is expedient if the fuse 1 has a power-source-side first terminal 18 and a load-side second terminal 18. In many applications, a feedback of electrical power in the direction of the power source is not desired. The electrical current 29 through the circuit breaker 17 should thus optionally flow only from the first terminal 18 of the fuse 1 to the second terminal 19 of the fuse 1 in such applications. In this case, the electronic fuse 1 comprises means (20, 21, 22, 23, 24, 25, 525, 570) for capturing and detecting a reverse-flowing current 29. For example, the analog-to-digital converter 570 can detect the voltages of the measuring lines (20, 21, 22, 25) among one another and/or with respect to the reference potential 201 and transmit the detected values to the computer core 2 of the control device 4 of the fuse 1 via the internal data bus 11. The computer core 2 of the control device 4 of the fuse 1 can then, for example, deduce the value of the auxiliary current 36 through the shunt resistor 24, which the auxiliary circuit breaker 23 generates proportional to the current 29 and thus deduce the sign of the current 29. For example, the computer core 2 of the control device 4 of the fuse 1 can open the circuit breaker 1 if the estimated and/or determined sign of the electrical current 29 does not correspond to an expected sign. This can be the case, for example, if power is transported without permission from the second terminal 19 of the fuse 1 to the first terminal 18 of the fuse, even though the reverse power transport direction is the expected power transport direction.

The computer core 2 of the control device 4 of the electronic fuse 1 then evaluates the measured values of the voltages of the measuring lines (20, 21, 22, 25) detected in this way and optionally forwards the measured values and/or measured values derived therefrom to other computer cores 2 of other electronic fuses (1, 214 to 217, 225 to 223, 230 to 235, 225 to 256) via a fuse data bus (9, 540) or the like or to a higher-level computer system 12, for example to a higher-level computer system 12.

In many cases, it is expedient if the electronic fuse 1 comprises two data interfaces 10 and 610. The data interfaces can also be a plurality of optical data interfaces 550 and 551. It is also conceivable that the electronic fuse 1 comprises one or more wired data interfaces 10, 610 and/or at the same time one or more optical data interfaces 550, 551. An optical waveguide 580 can, for example, connect the one electronic fuse 1 or the plurality of electronic fuses (1, 214 to 217, 225 to 223, 230 to 235, 225 to 256) via the optical data interfaces 551, 550 of the one electronic fuse 1 or the plurality of electronic fuses to a different device 12, for example to a higher-level computer system 12, or to the computer cores 2 of the control devices 4 of other electronic fuses and/or to one another.

The electronic fuse 1 disclosed in the disclosure optionally has a control device 4 and a circuit breaker 17 as a circuit breaker of the electronic fuse 1. The computer core 2 of the control device 4 controls by means of a gate drive circuit 16 for driving and monitoring the circuit breaker 17 whether the circuit breaker 17 is conductive and thus operates as a closed-circuit breaker, or whether the circuit breaker 17 does not conduct and thus operates as an open circuit breaker. The control device 4 of the electronic fuse optionally has a data interface 10 for a fuse data bus 9. The computer core 2 of the control device 4 of the fuse 1 receives and/or transmits data messages via the fuse data bus 9 and the data interface 10. Whether the computer core 2 of the control device 4 of the fuse 1 closes or opens the circuit breaker 17 by means of the gate drive circuit 16 depends at least partially and at least at times on the content of these data messages. In order now to prevent undesired opening and/or closing of the circuit breaker 17, the computer core 2 of the control device 4 of the electronic fuse 1 changes the switching state of the circuit breaker 17 based on a data message only if the control device 4 receives a data message with a password. For this purpose, the bit stream packet BP comprising the data message comprises, in the data portion INFO, optionally, first of all, the configuration data ILD and, secondly, a password for authenticating this command. In a predefined method, the computer core 2 compares the received password to an expected password or verifies the validity of the received password in another way. If the result of this verification is such that the password is valid, the computer core 2 of the control device 4 of the fuse 2 executes the received command and opens or closes the circuit breaker 17 of the electronic fuse 1 depending on the content of the command.

The disclosure thus describes an electronic fuse 1 with a circuit breaker 17, wherein the electronic fuse 1 detects and checks the voltage between this terminal 26 and a reference node 201 at the terminal 26 of its circuit breaker 17, which is located on the power-source side, and wherein the electronic fuse 1 detects and/or determines the current 29 through the circuit breaker 17 and checks it. The electronic fuse 1 optionally switches off the electrical supply of the downstream subtree of the supply network 200 by switching off its circuit breaker 17 if the detected value of the voltage falls below a minimum value and if at the same time the detected value of the electrical current 23 through the circuit breaker 17 of the electronic fuse 1 exceeds a predetermined threshold value. This is namely a clear sign of a short circuit, the interception of which is the task of the fuse 1.

Because it can be a temporary fault, for example as a result of commutation of an inductive load, it may be expedient to make a switching-back-on attempt. After a short-circuit event as described above, the computer core 2 of the control device 4 of the electronic fuse 1 then optionally carries out one or more switch-on attempts of the circuit breaker 17. It can then be a true short-circuit. It is therefore useful if the computer core 2 of the control device 4 of the fuse 1 precisely checks the number of switching-back-on attempts and the execution of the switching-back-on attempts and, as appropriate, logs the execution and the result thereof. The computer core 2 of the control device 4 of the electronic fuse 1 therefore optionally increases a switch-on attempt counter of the control device 4, in particular a register value of the computer core 2, when a short-circuit event occurs during a switch-on attempt of the circuit breaker 17, by a switch-on attempt increment value, which can also be negative and differs from 0. The computer core 2 of the control device 4 of the electronic fuse 1 optionally transmits an error message to the computer core 2 of the control device 4 of a different electronic fuse or to a higher-level computer system 12 via the data bus 9 if the number of unsuccessful switch-on attempts in the form of the counter reading of the switch-on attempt counter crosses or reaches a specified maximum number of switch-on attempts. The computer core 2 of the control device 4 of the proposed electronic fuse 1 transmits and receives data such as configuration data (read-write), switch commands (read-write), diagnostic data (read-write), measured values (read), comparison value settings (read-write) via a data interface (10, 550) or via the fuse data bus (9, 540). The corresponding data bus 9 can be, for example, parts or all of a two-wire data bus, in particular in a bidirectional and/or differential two-wire data bus 9. It is particularly advantageous if the data bus 9 is a conventional automobile data bus such as a CAN data bus or a data bus with a physical interface of a CAN data bus, of a CAN FD data bus or of a Flexray data bus or of an LVDS data bus or the like. The fuses can be linked to one another as a daisy chain. For this purpose, control devices 4 of fuses 1 of the supply network 200 can comprise two data interfaces 610, 10 for the fuse data bus (9), for example. The plug-in connectors 410 and the fuse bodies 425 of the fuses 405, 1 should then have corresponding additional plugs and contacts. The computer cores 2 of the control devices 4 of the electronic fuses (1, 214 to 217, 225 to 223, 230 to 235, 225 to 256) of a supply network 200 and the higher-level computer system 12, which are connected to the data bus 9, optionally carry out an auto addressing method in order to assign a unique fuse address to each data interface 10 of each control device 4 of each fuse at the data bus 9. EP 1 490 772 B1 describes a possible exemplary auto addressing method. The disclosure describes for the first time the use of an auto addressing method for assigning unique fuse addresses to the electronic fuses of a supply network 200, which are connected to a fuse data bus 9.

Optionally, the data interfaces 10, 610 of the control device 4 of the electronic fuses 1 are configured to carry an auto addressing method for determining a fuse address or to participate in such an auto addressing method.

FIG. 5 shows, inter alia, the optical data connection 540 between the first optical data interface 550 of the control device 4 of the fuse 1 and the optical interface 555 of the higher-level computer system 12. An optical waveguide 580 guides the electromagnetic radiation of the optical data connection 540. Optionally, the housing 535 of the electronic fuse 1 has an optical plug-in connector which allows the mechanical and optical connection of the electronic fuse 1 to the optical waveguide 580. As a result, an LED 560 can feed electromagnetic radiation into the optical waveguide 580 as an optical data connection 540. A photodetector of the optical data interface 550 can thereby receive electromagnetic radiation as a data connection 540 from the optical waveguide 580. The optical plug-in connector optionally comprises an optical window 545, whereby the housing 535 of the fuse 1 comprises such an optical window 545. The optical data interface 550 optionally comprises a driving device 565 for driving the LED 560. If the LED 560 is not supplied with electrical power by the driving device 565, the control device 4 can also use it as a photodetector for receiving the optical data connection 540 of the optical data interface 555 of the higher-level computer system 12. In this case, for example, an analog-to-digital converter 570 of the control device 4 of the fuse can detect the voltage signal 575 of the silicon LED 560 and supply it to the computer core 2 via the internal data bus 11 for evaluation. Of course, this evaluation and an analog-to-digital converter can also be part of the optical data interface 550.

FIG. 5 shows, inter alia, a second optical data connection 540 between the second optical data interface 552 of the control device 4 of the fuse 1 and an optical interface (not shown) of a different higher-level computer system or a different control device 4 of a different fuse 1. Optionally, the housing 535 of the electronic fuse 1 has a further optical plug-in connector which allows the mechanical and optical connection of the electronic fuse 1 to a second optical waveguide (not shown). As a result, an LED 561 can feed electromagnetic radiation into the further optical waveguide as an optical data connection 540 of the second optical data interface 551. A photodetector of the second optical data interface 551 can thereby receive electromagnetic radiation as a data connection 540 from the further optical waveguide (not shown). The second optical plug-in connector optionally also comprises a second optical window 545, whereby the housing 535 of the fuse 1 comprises such a second optical window 545. The second optical data interface 552 optionally comprises a driving device 565 for driving the second LED 561. If the second LED 561 is not supplied with electrical power by the driving device 565 of the second optical data interface 551, the control device 4 can also use it as a photodetector for receiving the second optical data connection 540 of the optical data interface of the further higher-level computer system or of the optical data interface of the other electronic fuse 1. In this case, for example, an analog-to-digital converter 570 of the control device 4 of the fuse can detect the voltage signal 576 of the second silicon LED 561 and supply it to the computer core 2 via the internal data bus 11 for evaluation. Of course, this evaluation and an analog-to-digital converter can also be part of the second optical data interface 551. The second laser or the second LED 561 can, for example, in turn be a silicon-based LED, in particular a silicon avalanche LED, in particular a SPAD diode operated as an LED.

The control device 4 of the fuse 1 optionally has temperature sensor evaluation devices 585, which, for example, determine temperature measured values by means of temperature sensors 586 and provide said values to the computer core 2 of the control device 4 of the fuse 1 via the internal data bus 11.

Optionally, the control device 4 of the fuse 1 comprises a random number generator 60 random number generator (RNG). The computer core 2 of the control device 4 of the fuse 1 can read the random value of the random number generator 60 via the internal data bus 11 of the control device 4 of the fuse 1. A list of random number generators can be found, for example, at https://en.wikipe-dia.org/wiki/List_of_random_number_generators. Implementation in hardware is outlined, for example, in https://en.wikipedia.org/wiki/Hardware_random_number_generator. In particular, the disclosure refers to entropy extraction, which is touched on, for example, in https://en.wikipedia.org/wiki/Random-ness_extractor. Optionally, the computer core 2 of the control device then uses this random number for encrypting the data communication via the data interface 10 or the optical data interface 550 with other computer cores 2 of other control devices 4 of other fuses 1 in the supply network 200 and/or for encrypting the data communication with a higher-level computer system 12. The random generator 60 is optionally a so-called true random number generator (TRNG). Very particularly optionally, the random generator 60 is a quantum random number generator (QRNG). Such a quantum random number generator 60 uses quantum-random properties for generating the quantum random number as a random number. In the prior art, there are two basic sources of practical quantum-mechanical physical randomness: quantum mechanics at atomic or subatomic level and thermal noise (which is in part of quantum-mechanical origin). Quantum mechanics predicts that specific physical phenomena, such as the nuclear disintegration of atoms and/or, as proposed here, the spontaneous emission of a photon by an energetically excited electron, are basically random and cannot in principle be predicted. With regard to the empirical testing of the unpredictability of quantum mechanics, the disclosure refers to the known Bell test experiments. Because the usual environmental conditions require a temperature above the absolute zero point, each real system has a certain random variation in its state.

Because the result of quantum-mechanical events cannot be predicted in principle, they are the “gold standard” for generating random numbers. Some quantum phenomena used for generating random numbers are:

A quantum-mechanical noise source in electronic circuits causes typical shot noise. A simple example is a lamp—in this case a first SPAD diode which appears on a photodiode, in this case a second SPAD diode. Due to the uncertainty principle, the relevant photons generate noise in the circuit. The detection of the noise for generating random bits causes some problems. The quantum random number generator proposed here is a particularly simple and compact random noise source. However, the power of the shot noise is not always well distributed over the bandwidth of interest. Up to the entropy extraction, all stages, including the light source and the detector, generate thermal noise that the evaluation circuit of the quantum random number generator 60 has to suppress. The evaluation circuit of the quantum random number generator 60 requires, for conditioning the signal of the detector—in this case the second SPAD diode—a filter stage for careful filtering in order to achieve a uniform distribution of the random events over a wide spectrum.

The quantum random number generator presented here in the disclosure is based on the spontaneous emission of a photon by a first SPAD diode biased in the reverse direction and the stimulated emission of a second SPAD diode. Both SPAD diodes are optionally each biased via, for example, a series resistor with optionally the same voltage source in the reverse direction with a voltage above the breakdown voltage. A spontaneous or stimulated emission of a photon is associated with the formation of a current spike. The series resistor prevents such a current spike from leading to a permanent discharge, and thus to an excessively high-power input into the corresponding SPAD diode, by supplying power from the voltage source. Such paired quasi-simultaneous events in the first SPAD diode and the second SPAD diode are characterized by a current spike twice as high as single events of spontaneous emission of one of the two SPAD diodes.

According to the proposal, the quantum random generator 60 has a first SPAD diode which is biased in the reverse direction with a voltage above the reverse voltage. The reverse voltage optionally supplies the voltage supply 5 or a device part thereof. As a result, the first SPAD diode begins to emit individual, typically very short, light pulses. Optionally, an optical waveguide of the control device forwards these light pulses of the first SPAD diode to a second SPAD diode. The optical waveguide is of particular importance because it maximizes the number of photons reaching the second SPAD diode. The two SPAD diodes are optionally manufactured monolithically in a silicon semiconductor crystal in CMOS technology. Optionally, the optical waveguide is manufactured in the metallization stack of the CMOS circuit comprising the first SPAD diode and the second SPAD diode. The metallization stack optionally comprises a plurality of structured metal wiring levels and a plurality of isolating isolation levels. The metal wiring levels can be manufactured, for example, from an aluminum alloy which can be structured by means of photolithography in conductor tracks, etc. The optically transparent isolation levels between these line levels of the metallization stack can, for example, be made of silicon dioxide or another optically transparent and suitable insulator. The isolation levels are typically also structured photolithographically and provided with vias for connecting lines of different line levels. Optionally, the metallization stack is structured and designed in the region of the two SPAD diodes such that, of the photons that the first SPAD diode emits in the direction of the metallization stack, the second SPAD diode can reach a greater amount of them, and conductor tracks of the metallization stack do not hinder the photons. Optionally, conductor tracks of the metallization stack shield the optical waveguide at the top and toward the sides in such a way that these conductor tracks reflect at least a portion of the photons attempting to escape in this direction back in the direction of the second SPAD diode. The interior of the optical waveguide therefore optionally comprises only material of the insulation layers and optionally no material of the conductor tracks. The optical waveguide of the quantum random number generator 60 optionally optically connects the first SPAD diode to the second SPAD diode. Optionally, the optical waveguide of the quantum random number generator 60 covers both the first SPAD diode and the second SPAD diode in order to capture a maximum number of photons of the first SPAD diode and feed them to the second SPAD diode. This design enables a maximum bit rate per second for the generated random bits. The second SPAD diode is optionally likewise biased in the reverse direction with a detection voltage. The detection voltage is optionally provided again by the voltage supply 5 and/or a sub-device thereof. The second SPAD diode also generates current pulses of a first maximum height by spontaneous emission of individual photons. If a photon of the first SPAD diode reaches the second SPAD diode, stimulated emission occurs. The resulting current pulse of the SPAD diode current of the second SPAD diode then has a second height. Typically, the first height is approximately twice as high as the second height. A transimpedance amplifier optionally amplifies the SPAD diode current of the second SPAD diode and thus the current pulses of the second SPAD diode. A comparator compares the amplified SPAD output signal to a threshold value. The threshold value is optionally set such that the comparator supplies a logic 1 at its output for current pulses of the second height and supplies a logic 0 at its output for current pulses of the first height and for the case of no current pulses. Optionally, a counter, which optionally runs with the clock pulse of the oscillator 30 or a clock pulse of the clock-pulse system of the control device, counts the time between the occurrence of two ones at the output of the comparator. The counter represents a time-to-digital converter. This is referred to below as a time-to-digital converter. Because the second SPAD diode has a dead time for the detection of photons, the time-to-digital converter of the quantum random number generator optionally discards all pulse pairs of one-pulses at the output of the comparator which follow one another too closely, i.e., more briefly than this dead time. In this way, the time-to-digital converter of the quantum random number generator 60 generates a first number, which already depends substantially on a quantum process, namely the spontaneous emission of the first SPAD diode, and a second quantum process, namely the stimulated emission of the second SPAD diode. The following entropy extraction device now uses a first number of the time-to-digital converter and a second number of the time-to-digital converter if the first number of the time-to-digital converter and the second number of the time-to-digital converter are different. If the first number of the time-to-digital converter is greater than the second number of the time-to-digital converter, the entropy extraction generates a random bit having a first logic value, and in the other case a random bit having a second logic value which is different from the first value. From a plurality of these random bits, the entropy extraction device of the quantum random number generator then generates a random number, which the entropy extraction device then provides to the computer core 2 of the control device 4 of the fuse 1 in a register of the quantum random number generator 60.

Optionally, the computer core 2 of the control device 4 of the fuse 1 generates a private key and a public key by means of such a generated random number.

The computer core 2 of the control device 4 of the electronic fuse 1 then transmits this public key via the data bus 9 to one or more computer cores 2 of other control devices 4 of other fuses and/or to a higher-level computer system 12. These can then use this public key for the encryption of data messages in bit stream packets BP to the computer core 2 of the control device 4 of the fuse 1 via the data bus interface (10, 610, 550, 551) and transmit data encrypted in this way to the computer core 2 of the control device 4 of the fuse 1.

Optionally, the computer core 2 of the control device 4 of the fuse generates a new key pair with the aid of the random number generator 30 from time to time, optionally regularly, and distributes the public key via the data bus 9 back to one or more computer cores 2 of other control devices 4 of other fuses and/or to a higher-level computer system 12. The computer core 2 of the control device 4 of the fuse 1 can then decrypt the received encrypted data messages with its private key.

The higher-level computer system 12 of the supply network 200 also optionally comprises one or more such random number generators 60. Also in this case, these can be RNGs or QRNGs (quantum random number generators), which provide random numbers for the key pair generation to the higher-level computer system 12.

Optionally, the higher-level computer system 12 generates a private and a public key by means of such a generated random number of such a random number generator.

The higher-level computer system 12 then transmits this public key via the data bus 9 to one or more computer cores 2 of other control devices 4 of other fuses and/or to a different higher-level computer system 12 that may be present. They can then use this public key for encrypting data messages in bit stream packets BP to the higher-level computer system 12 and to transmit data encrypted in this way to the higher-level computer system 12.

Optionally, the higher-level computer system 12 generates a new key pair with the aid of its own random number generator from time to time, optionally regularly, and distributes the public key via the data bus 9 back to one or more computer cores 2 of other control devices 4 of other fuses and/or to the other higher-level computer system 12. The higher-level computer system 12 can then decrypt the received encrypted data messages with its private key.

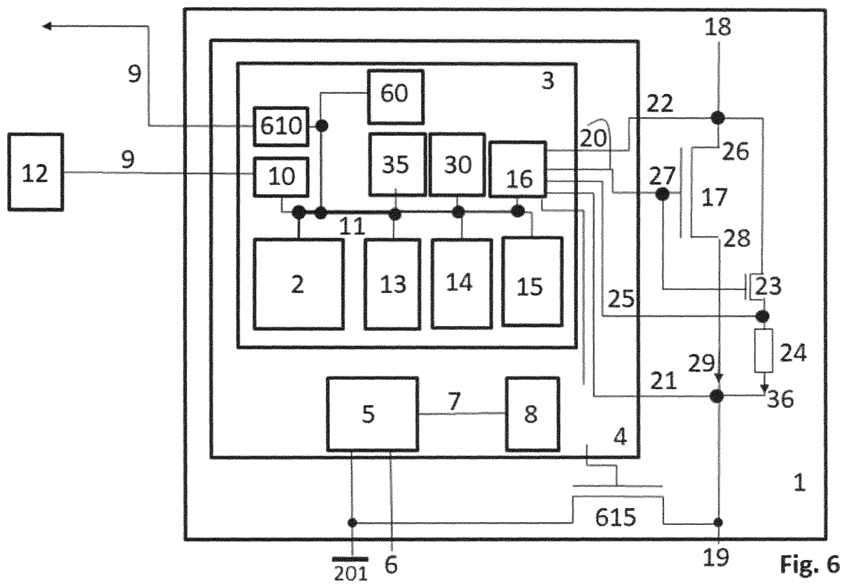

### FIG. 6

FIG. 6 substantially corresponds to FIG. 1, wherein the control device 4 of the fuse 1 of FIG. 4 has an additional second data interface 610. That which was already written about the first data interface 10 is also meant to apply to the second data interface 610. In particular, it can be a data interface for a one-wire data bus and/or a differential bidirectional data bus. In the automotive field, the data bus 9 of the second data bus interface 610 can, for example, be a Lin data bus 9 or a DSSI3 data bus 9 or a PSI5 data bus 9 or a CAN data bus 9 or a CAN FD data bus 9 or an Ethernet data bus or a Flexray data bus 9 or an LVDS data bus 9 or an otherwise wired or wireless data transmission path, for example via a Bluetooth or WLAN data connection or an optical data connection 540. In this case, the data communication of the computer core 2 of the control device 4 of the fuse 1 additionally runs for data communication via the first data bus interface 10, 550 via a wired or wireless second interface 610, 551.

In FIG. 6, for better clarity, not all appropriate and in some cases customary device components are shown. Further device components that the reader can assume as possibly present in FIG. 1 can be found, for example, in FIGS. 1, 5, 9, 24, 41, 42, 52, 53, 54, 55, 57, 58 and 62. The combination of the device parts of the Figure described here with those of these figures is expressly part of the disclosure of the disclosure.

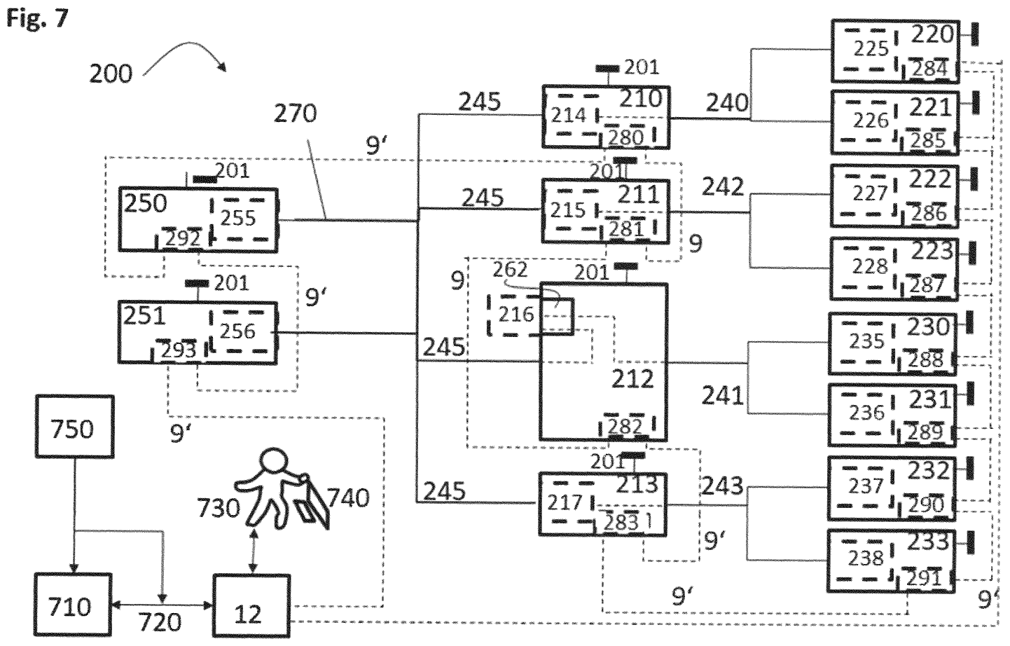

In many cases, it is desirable for the control device 4 of a fuse 1 to have more than one single data interface 10. This can be the case, for example, if increased communication safety is required by redundancy or, for example, secure addressing is to be carried out by a daisy chain. The computer core 2 of the control device 4 can access this second data interface 610 via the internal data bus 11 and communicate with other computer systems 12 and/or other computer cores 2 of other control devices 4 of other fuses 1 in the supply network 200. The disclosure therefore proposes electronic fuses 1 having control devices 4 which comprise two data bus interfaces (610, 10) for the fuse data bus 9. Some of these second data bus interfaces 10, 610 can be optical data interfaces 550, 551. Optionally, some of such fuses 1 are connected to this fuse data bus 9 with two data interfaces 10, 610 or inserted into the fuse data bus 9 by means of two such data interfaces (10, 551, 550, 610). A supply network 200 then results in which one or more electronic fuses (1, 214 to 217, 225 to 228, 235 to 238, 250, 251) each have two data interfaces (214 to 217, 225 to 228, 235 to 238, 250, 251, 610, 10) per electronic fuse (1, 214 to 217, 225 to 228, 235 to 238, 250, 251) and which are optionally inserted into the data bus 9. (See also FIG. 7). The computer cores 2 of the control devices (4) of the electronic fuses of the fuses (1, 214 to 217, 225 to 228, 235 to 238, 250, 251) of such a supply network 200 then receive and transmit, via a data interface (10, 610, 550, 551) via this data bus 9, data such as configuration data (read-write), switch commands (read-write), diagnostic data (read-write), measured values (read) and comparison value settings (read-write). For example, it is conceivable that the computer core 2 of the control device 4 of a fuse 1 receives via the first data interface 10 data from a computer core 2 of the control device 4 of a different fuse 1 or from a higher-level computer system 12, and then forwards this data directly or, after modification of the data, via the second data interface 610 to a computer core 2 of a different control device 4 of a different fuse 1 and/or a or the higher-level computer system 12. In this way, the higher-level computer system 12 can check, for example, the functionality of the computer core 2 of the control device 4 of the fuse 1. For example, electronic fuses (1, 214 to 217, 225 to 228, 235 to 238, 250, 251) of such a supply network 200 can comprise two such data interfaces 10 and 610 for the data bus 9 and can be inserted into the data bus 9. In this way, the fuses then form a linear chain of fuses (1, 214 to 217, 225 to 228, 235 to 238, 250, 251) of such a supply network 200 along at least a portion of the data bus 9. As a result, the fuses (1, 214 to 217, 225 to 228, 235 to 238, 250, 251) of such a supply network 200 then have a unique physical position, which the computer core 2 of a control device 4 of a fuse 1 can then determine for its fuse 1 within the scope of an auto addressing method and can convert it into a logic fuse address of its fuse 1 for addressing data messages in bit stream packets BP to this fuse. Optionally, the computer core 2 transmits the fuse address determined by it to the higher-level computer system 12 after completion of the auto addressing method at the start of operation of the supply network 200. The higher-level computer system 12 then optionally checks whether the transmitted fuse addresses correspond to the expected values. If this is not the case, the higher-level computer system 12 optionally repeats the auto addressing method, which typically results in the computer cores 2 of the control devices 4 of the fuses of the supply network 200 discarding the already determined fuse addresses in favor of the fuse addresses newly to be determined. A higher-level computer system 12, which is optionally connected at the beginning of this portion of the data bus 9, optionally determines a fuse address for driving the computer cores 2 of the control devices 4 of the fuses of the supply network 200 by means of auto addressing in cooperation with the computer cores 2 of the control devices 4 of the electronic fuses for each of the computer cores 2 of the control devices 4 of the fuses and transmits it, as appropriate, to the computer cores 2 of the control devices 4 of the electronic fuses of the supply network 200. The data communication of the computer core 2 of the control device 4 of the fuse 1 runs via a wired or wireless interface 610, 10.

### FIG. 7

FIG. 7 corresponds in substantial parts to FIG. 3, wherein the data bus 9 is designed as an annular data bus ring 9′. The data interfaces 280 to 293 of the fuses (214 to 217 and 225 to 228 and 235 to 238 and 255 and 256) here comprise the two data interfaces 10, 610 of FIG. 6. The higher-level computer system 12 in turn controls the supply network 200.

The higher-level computer system 12 is connected to the first data bus interface of the data bus interfaces 284 of the fuse 225 of the load 220 by a second data bus interface via the data bus ring 9′.

The second data bus interface of the data bus interfaces 284 of the fuse 225 of the load 220 is connected via the data bus ring 9′ to the first data bus interface 285 of the fuse 226 of the load 221.

The second data bus interface of the data bus interfaces 285 of the fuse 226 of the load 221 is connected via the data bus ring 9′ to the first data bus interface 286 of the fuse 227 of the load 222.

The second data bus interface of the data bus interfaces 286 of the fuse 227 of the load 222 is connected via the data bus ring 9′ to the first data bus interface 287 of the fuse 228 of the load 223.

The second data bus interface of the data bus interfaces 287 of the fuse 228 of the load 223 is connected via the data bus ring 9′ to the first data bus interface 288 of the fuse 235 of the load 230.

The second data bus interface of the data bus interfaces 288 of the fuse 235 of the load 230 is connected via the data bus ring 9′ to the first data bus interface 289 of the fuse 236 of the load 231.

The second data bus interface of the data bus interfaces 289 of the fuse 236 of the load 231 is connected via the data bus ring 9′ to the first data bus interface 290 of the fuse 237 of the load 232.

The second data bus interface of the data bus interfaces 290 of the fuse 237 of the load 232 is connected via the data bus ring 9′ to the first data bus interface 291 of the fuse 238 of the load 233.

The second data bus interface of the data bus interfaces 291 of the fuse 238 of the load 233 is connected via the data bus ring 9′ to the first data bus interface 283 of the fuse 217 of the load 213.

The second data bus interface of the data bus interfaces 283 of the fuse 217 of the load 213 is connected via the data bus ring 9′ to the first data bus interface 282 of the fuse 216 of the load 212.

The second data bus interface of the data bus interfaces 282 of the fuse 216 of the load 212 is connected via the data bus ring 9′ to the first data bus interface 281 of the fuse 215 of the load 211.

The second data bus interface of the data bus interfaces 281 of the fuse 215 of the load 211 is connected via the data bus ring 9′ to the first data bus interface 280 of the fuse 214 of the load 210.

The second data bus interface of the data bus interfaces 280 of the fuse 214 of the load 210 is connected via the data bus ring 9′ to the first data bus interface 292 of the fuse 255 of the power source 250.

The second data bus interface of the data bus interfaces 292 of the fuse 255 of the power source 250 is connected via the data bus ring 9′ to the first data bus interface 293 of the fuse 256 of the power source 251.

The second data bus interface of the data bus interfaces 293 of the fuse 256 of the power source 251 is connected via the data bus ring 9′ to the first data bus interface of the higher-level computer system 12.

The data bus ring 9′ is thereby closed. A supply network 200 with a data bus ring 9′ as a data bus 9 has the advantage that, when the data bus ring 9′ is interrupted by an error or an accident, the communication of all bus participants with all other bus participants at one point is still possible. This is of particular importance because supply networks 200 are typically safety-relevant.

The disclosure also refers here to the description of FIG. 6, which substantially represents the fuses in FIG. 7.

The disclosure explains the targeted shedding of supply sub-networks in the example of FIG. 7. The supply network 200 of the vehicle comprises, among other things, device parts 210, a cable harness with line sections 240, 241, 245, at least one power source 250, 251, at least one control computer 12—for example, a higher-level computer system 12—and at least two electronic fuses 214, 225. The device parts 220 are typically electrical loads. At least one or more power sources 250, 251 of the supply network 200 supplies at least two of the device parts 210, 220 with electrical power via the cable harness with the line sections 240, 241, 245. The electronic fuses 214, 225 are inserted into the cable harness with line sections 240, 241, 245. Optionally, each of the electrical fuses 214, 225 is associated with at least one electrical load (210, 225), which is referred to below as the electrical load associated with the corresponding electronic fuse. A fuse of the fuses 214, 215 can thereby enable or prevent the supply of power to the electrical load associated with this fuse depending on a control signal of the control computer, i.e., of the higher-level computer system 12. The computer core of the control device of the relevant fuse typically receives such a control signal via the data bus 9, in this case via the data ring bus 9′. A fuse associated with this load can then prevent the supply of power to the electrical load associated with this fuse by means of the corresponding fuse associated with this load. Optionally, the control computer 12, i.e., the higher-level computer system 12, for example, establishes an encrypted data connection 720 between the control computer 12 of the vehicle, i.e., for example the higher-level computer system 12, and a computer 710 of a service provider, in particular a computer system of the automobile manufacturer of the vehicle. The control computer 12 of the vehicle, i.e., for example, the higher-level computer system 12, optionally authenticates the vehicle to the computer 710 of the service provider. The authentication data of the vehicle can comprise, for example, the data of the vehicle and/or of the car key and/or of a SIM card in the vehicle and/or of a vehicle-specific password input or password generation and/or biometric user data of a vehicle owner, etc. Typically, the computer 710 of the service provider authenticates itself in turn to the control computer 12 of the vehicle, for example to a higher-level computer system 12 of the vehicle. If necessary, the requesting person 730 authenticates themselves to the computer 710 of the service provider by inputs and/or biometric sensor data, such as fingerprint recognition, via the control computer 12 of the vehicle, for example via the higher-level computer system 12. The authentication data can comprise, for example, the data of the vehicle and/or of the personalized car key, of a personalized SIM card, of a personalized password input, biometric user data, etc. The computer 710 of the service provider then optionally generates or provides an activation code. The computer 710 of the service provider transmits the activation code via the secure data connection 720 to the control computer 12 of the vehicle, for example to the higher-level computer system 12. The control computer 12 of the vehicle, i.e., the higher-level computer system 12, optionally verifies the admissibility and/or the syntactical correctness and/or the situational admissibility of the activation codes. If this verification was successful, the control computer 12 of the vehicle, i.e., the higher-level computer system 12 of the vehicle, enables the supply of power to an electrical load 220 associated with the fuse by means of the corresponding fuse 225 if the activation code is admissible and/or syntactically correct and/or is situationally admissible. For this purpose, the higher-level control computer 12 of the vehicle, as the higher-level computer system 12, issues a command to the computer core 2 of the control device 4 of the corresponding fuse via the data bus 9. This command is optionally encrypted so that the computer core 2 of the control device 4 of the fuse can verify whether the command has been issued by a reliable higher-level computer system 12. If the computer core 2 of the control device 4 of the corresponding fuse receives such a protected command, the computer core 12 of the control device 4 of the corresponding fuse closes the circuit breaker 17 of this fuse and thus allows the supply of power to the downstream supply sub-network via this circuit breaker 17. Optionally, the higher-level computer system 12 transmits billing data to a or the computer 710 of a or the service provider via the data connection 720, in particular to a or the computer system of the automobile manufacturer, wherein memory information in the computer 710 of the service provider optionally marks that the invoice is not yet paid. Optionally, the computer 710 of the service provider or the automobile manufacturer creates an invoice depending on the transmitted billing data. The computer 710 of the service provider then optionally transmits the invoice to a or the computer system 740 of the ordering person 730, or to the ordering person 730. The ordering person 730 or a computer (710) of a or the service provider then optionally settles this invoice. The computer of the service provider 740 then marks the memory information in the computer of the service provider (740) that the invoice is paid.

A vehicle according to the proposal comprises device parts 210, at least one cable harness 1515 with line sections 240, 241, 245, at least one power source 250, 251, at least one control computer 12—for example, a higher-level computer system 12—and at least two electronic fuses 214, 225. The device parts (220) are typically electrical loads. The at least two power sources 250, 251 of the supply network 200 of the vehicle supply one or more of the device parts 210, 220 with electrical power via the cable harness with line sections 240, 241, 245. The electronic fuses 255, 256 are inserted into the cable harness of the supply network, which comprises line sections 240, 241, 245. Optionally, substantially each of the electrical fuses 255, 256 is assigned at least one electrical power source 250, 251, which is referred to below as the associated electrical power source 250, 251. The word “inserted” can here mean that the electronic fuse 255, 256 can connect a line section 240, 241, 241 to the electrical power source 250, 251 associated with this fuse 255, 256, or can disconnect the electrical power source 250, 251 associated with this fuse 255, 256 from this line section 240, 241, 241. A corresponding fuse of the fuses 255, 256 can enable or prevent the supply of power of the respectively associated electrical power source 250, 251 depending on a control signal of the control computer 12, for example of the higher-level computer system 12. The corresponding associated fuse 255, 260 can prevent the power supply of an associated electrical power source 250, 251. The control computer 12 establishes an encrypted connection 720 between the control computer 12 of the vehicle, for example the higher-level computer system 12, and a computer 710 of a service provider, in particular a computer system 710 of the automobile manufacturer. The control computer 12 of the vehicle, for example the higher-level computer system 12, authenticates the vehicle to the computer 710 of the service provider, wherein the authentication data of the vehicle can comprise, for example, the data of the vehicle and/or the car key and/or a SIM card in the vehicle and/or a vehicle-specific password input or password generation and/or biometric user data of a vehicle owner, etc. The computer 710 of the service provider also authenticates itself to the control computer 12 of the vehicle, for example to the higher-level computer system 12. If necessary, the requesting person 730 authenticates itself using the control computer 12 of the vehicle, for example using the higher-level computer system 12, to the computer 710 of the service provider, wherein the authentication data can comprise, for example, the data of the vehicle and/or of the personalized car key, of a personalized SIM card, of a personalized password input, biometric user data, etc. The computer 710 of the service provider generates an activation code or provides this activation code. The computer 710 of the service provider then transmits the activation code to the control computer 12 of the vehicle, for example to the higher-level computer system 12. The control computer 12 of the vehicle, i.e., for example, the higher-level computer system 12 then verifies the admissibility and/or syntactical correctness and/or the situational admissibility of the activation code. Upon successful verification of the activation code, the control computer 12 of the vehicle enables the power supply of an associated electrical power source (250, 251) by means of the corresponding associated fuse 255, 260. For this purpose, the control computer 12 of the vehicle transmits a corresponding command via the data bus 9 to the relevant fuse 255, 260. The communication between the control computer 12 and the fuse 255, 260 is optionally encrypted. The communication is optionally PQC encrypted. Optionally, the control computer 12 of the vehicle has previously authenticated itself at least once to the computer core 2 of the control device 4 of the relevant fuse 250, 260. The computer core 2 of the control device 4 of the relevant fuse 250, 260 has optionally previously authenticated itself to the control computer 12 of the vehicle, i.e., the higher-level computer system 12. Optionally, the control computer 12 of the vehicle transmits billing data to a or the computer 710 of a or the service provider, in particular to a or the computer system of the automobile manufacturer, wherein memory information in the computer 710 of the service provider marks that the invoice has not been paid. A computer 710 or the computer 710 of a service provider or of the service provider then optionally creates an invoice depending on these transmitted billing data, in particular to a computer system of the automobile manufacturer or the computer system of the automobile manufacturer. The billing data can relate, for example, to the duration of the use of specific loads or power sources or specific line sections or the determination of specific operating parameters or the provision of specific methods for operating the vehicle or the device parts thereof. A computer 710 or the computer 710 of a service provider or of the service provider then optionally transmits the invoice created in this way to a computer 750 or the computer 750 of a service provider or the service provider, in particular to a computer system or the computer system of the ordering person, or to the ordering person 730. A computer 750 or the computer 750 of a service provider or of the service provider and/or the requesting person 730 then optionally settles the invoice. An input of the requesting person 730 is optionally required for this purpose. Optionally, the computer 710 of the service provider marks the memory information in the computer 710 of the service provider that the invoice is paid.

For example, a computer 710 of a service provider or of the automobile manufacturer can create a prediction of the failure probability of a device part of the vehicle by means of the vehicle data and/or of the operating data and/or of the measured values and/or of the damage data with the aid of the transmitted billing data. This computer 710 can then transmit these prediction results to a server 1985 and/or a terminal of the repair shop and/or a terminal 740 and/or a computer of a vehicle owner 730 and/or a terminal 740 and/or a computer of a vehicle driver 730 or a terminal and/or a server 710 of an automobile manufacturer and/or a terminal and/or server of a logistics company and/or a terminal and/or a server of another user of this data, and can in some cases be displayed there.

The vehicle can also use such a system for detecting incorrect operations. For example, the computer core 2 of a control device 4 of an electronic fuse can transmit a message to a computer 710, 750 of a service provider and/or of the automobile manufacturer in the event of a hot plug event in the supply network 3100, i.e., the in particular non-permitted release or closing of an electrical plug connection under current and/or voltage. In the event of a hot plug event in the supply network 200 of a vehicle, the computer core 2 of the control device 4 of an electronic fuse can transmit a message to a computer 710 of a vehicle manufacturer or a service provider immediately or in a time-delayed manner or can provide such information, for example, in a memory of a higher-level computer 12.

The computers in the supply network 200 optionally exchange security codes in encrypted form by means of data messages in the bit stream packets BP exchanged via the data bus 9. These security codes are special activation codes that enable individual circuit breakers 17 of individual fuses in the supply network 200 to be switched on or off. Optionally, the computer core 2 of the control device 4 of a fuse checks a received switch-on or switch-off command for the circuit breaker 17 of its fuse as to admissibility with the aid of a security code likewise transmitted to this computer core 2 of the control device 4 of the fuse. In this case, the computer core 2 of the control device 4 of the fuse can take into account factors such as time of the transmission, current intensity flowing through the circuit breaker 17, voltage of terminals 18, 19 of the circuit breaker 17 against a reference potential, state of other fuses in the supply network 200, priority of the downstream supply sub-network and/or loads contained therein, and/or power sources contained therein, and/or original computers of the security code and/or transmitting computers of the security code, user inputs, notifications of other computers 710, 750, etc.

For example, a service provider or the automobile manufacturer or a subcontractor of the automobile manufacturer can transmit by means of a server 710 the security code or data for generating the security code by means of the higher-level computer system 12 or by means of the computer cores 2 of the control devices 4 of the electronic fuses to the higher-level computer system 12 or to a computer core 2 of a control device 4 of the electronic fuse.

For example, the fuse data bus 9 can be provided directly or indirectly, for example via gateways or the like, with a terminal 740 for a manual user input for reconfiguration of the supply network 200 by means of the electronic fuses of the supply network.

The terminal 740 can be configured to also serve to transmit authentication data to a server 710 of the automobile manufacturer, or of a subcontractor of the automobile manufacturer, wherein the authentication data can comprise, in particular, authentication data of the operating person 730 and/or authentication data of the organization for which the person 730 is working, and/or authentication data of the vehicle or and/or authentication data of the car key of the vehicle and/or the similar authentication data. In particular, the authentication data can be data of a signature card or the like and/or biometric data such as data of a fingerprint scanner and/or of a retina scanner or the like or data derived from such data. The terminal 740 is then optionally configured to obtain the security code from the server 710 of the automobile manufacturer or of a subcontractor of the automobile manufacturer depending on the authentication data thus determined.

One or more computer cores 2 of control devices 4 of electronic fuses of the electronic fuses in the supply network 200 are optionally configured to determine measured values by means of measuring means of these electronic fuses and to transmit these measured values via the fuse data bus 9 to a higher-level computer system 12.

The higher-level computer system 12 is optionally configured to carry out a neural network model and to use the determined measured values and/or values dependent thereon as input values of the neural network model. At least the switching state of a circuit breaker 17 of an electronic fuse in the supply network 200 and/or the switching states of a plurality of circuit breakers 17 of a plurality of electronic fuses in the supply network 200 and/or at least one data message of the higher-level computer system 12 then optionally depend on a different computer system 710, 750, 740 or a signaling of the higher-level computer system 12 to a user 730 from an output signal and/or output value of the neural network model.

The higher-level computer system 12 can also be configured to carry out spectral analyses of the data of the characteristics of measured values of the measuring devices of the fuses in the supply network, for example by Fourier or Laplace transform or wavelet transform, and to determine values of the spectra. The higher-level computer system 12 can then be configured, in the event of substantial deviations of the values of the spectra from expected value intervals for the values of the spectra, to deduce the need for preventive maintenance or to perform signaling to a different computer system 750, 710 or an indicator 740. The higher-level computer system 12 can also be configured to carry out spectral analyses of the data of the characteristics, for example by Fourier or Laplace transform or wavelet transform, and to determine values of the spectra and to evaluate the system availability of device parts of the supply network and/or of the supply network 200 itself by means of determined spectra, and to signal the evaluation result to other computer systems 710, 750, 740, 4, and/or to change parameters of the vehicle depending on this evaluation. The other computer systems can be terminals 740 of a user 730 and/or computers 710 of a vehicle manufacturer or computers 710, 750 of one or more service providers and/or a repair shop or a higher-level computer system 12 of the vehicle or a computer core 2 of a control device 4 of a fuse of the supply network 200.

The presented supply network optionally comprises, at least temporarily, a computer (server) 710 of a service provider, in particular a computer system of an automobile manufacturer and thus in some cases also a repair shop. A optionally encrypted data connection 720 between the control computer of the vehicle—e.g., a higher-level computer system 12—and a computer 710 of a service provider, in particular a computer system of the automobile manufacturer of the vehicle, ensures communication. A requesting/operating person or user 730 can get access to the computers 4, 12 of the supply network 200 and thus to the switching state of the circuit breakers 17 of the fuses via a data input means and/or data output means—for example, a terminal 740. In addition to the computer 710 of the vehicle manufacturer or of a service provider, further computers 750 of further service providers or further computers of the service provider who checks the computer 710 can be connected to the computers of the supply network 200 via the data bus 9 and the higher-level computer system 12 via wired and/or wireless data connections.

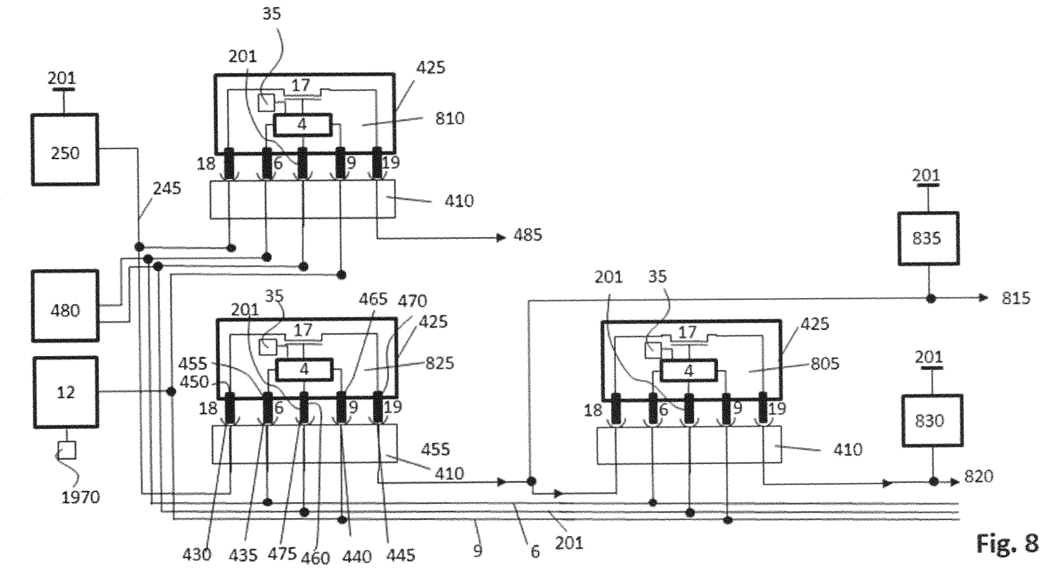

### FIG. 8

FIG. 8 corresponds in the most important parts to FIG. 4.

The supply sub-network of FIG. 8 comprises a further fuse 805, a second further fuse 810, a first connected distribution tree 815, a second connected distribution tree 820, an electronic fuse 825, a load 830, and further loads 835. The other parts of FIG. 8 have already been explained in connection with FIG. 4.

Optionally, a computer core 2 of a control device 4 of an electronic fuse 825 transmits parameters of the supply sub-trees 815 connected to the electronic fuse 825 and/or individual nodes of the connected supply line sections 815 and/or individual connected supply line sections of the supply tree of the supply lines of the vehicle to a computer core 2 of a control device 4 of another electronic fuse 805 and/or one or more controllers of the vehicle and/or a higher-level computer system 12. Such parameters can in particular be measured values that the computer core 2 of the control device 4 of a fuse detects by means of measuring devices of the control device 4 of the fuse. Such parameters can be, for example, a directly accessible parameter, such as temperature of a temperature sensor 40, 586, the voltage of a node 26, 27, 28 within the fuse against a reference potential 201 and/or the voltage of a node of the supply tree against a reference potential 201, and/or the value of an electrical current in a supply line section of the connected supply tree 820.

By means of this exchange of detected measured values and/or parameters, the computer core 2 of the control device 4 of an electronic fuse 825, 805 can—in particular by applying Kirchhoff equations to data that the computer core 2 of the control device 4 of the electronic fuse 825, 805 has determined by means of measuring devices of the control device 4 of this electronic fuse 825, 805 or that the computer core 2 of the control device 4 of this electronic fuse 825 has received from the computer cores 2 of the control devices 4 of different electronic fuses 805 or from higher-level computer systems 12, for example a higher-level computer system 12—detect or determine derived parameters, such as leakage currents against other electrical nodes in the vehicle or electrical resistances of supply voltage line sections.

Optionally, the computer core 2 of the control device 4 of the electronic fuse 825 estimates the temperature of a downstream supply line section, which temperature is increased as a result of the electric current 29 into this supply line section and the voltage drop across this supply line section. Such an estimation is also possible if its ohmic resistance and its heat capacity and its thermal leakage resistances and the ambient temperature in the region of the supply line section are known approximately, e.g., by estimation by the computer core 2 of the control device 4 of the electronic fuse 825 and/or by data transmission from the higher-level computer system 12 and/or by data transmission from the higher-level computer system 12, to the computer core 2 of the control device 4 of the fuse 825.

Optionally, the computer core 2 of the control device 4 of the electronic fuse 825 determines the voltage value of the voltage of a node 22, 25, 21 on the circuit breaker 17 of the electronic fuse 825 or a node associated therewith with respect to a reference potential 201 by means of a voltage measuring device 16 in order to be able to detect such estimations, such as the above and/or to be able to detect overvoltages or undervoltages, and to signal them to a higher-level computer system 12 via the data bus 9. The computer core of the control device 4 of the electronic fuse 825 optionally determines the value of the current 29 through the circuit breaker 17 of the electronic fuse 825. The computer core 2 of the control device 4 of the electronic fuse 825 and/or a higher-level computer system 12 optionally determines the output value of the electrical output fed into the load or a downstream supply tree 815, 820 or into a downstream supply line section from the current value and/or the voltage value. If this power feed exceeds a power feed threshold value, the computer core 2 of the control device 4 of the fuse 825 optionally opens the circuit breaker 17 of the fuse 825 and optionally signals this opening of the circuit breaker 17 via the data bus 9 to the higher-level computer system 12.

Typically, the computer core 2 of the control device 4 of the electronic fuse 825 determines the voltage value of the voltage of a node 22, 25, 21 on the circuit breaker 17 of the electronic fuse 805 or of a node associated therewith with respect to a reference potential 201 and the value of the current 29 through the circuit breaker 17 of the electronic fuse by means of a voltage measuring device. The computer core 2 of the control device 4 of the electronic fuse 825 and/or a higher-level computer system 12 determines from the current value and the voltage value the output value of the electrical output flowing from the power source or from an upstream supply tree or from an upstream supply line section. If this power extraction exceeds a power extraction threshold value, the computer core 2 of the control device 4 of the fuse 825 optionally opens the circuit breaker 17 of the fuse 825 and optionally signals this opening of the circuit breaker 17 via the data bus 9 to the higher-level computer system 12.

Optionally, the computer core 2 of the control device 4 of the electronic fuse 805 transmits this output value via the fuse data bus 9 to the control device 4 of another electronic fuse 825 or the higher-level computer system 12 of the supply network 200. The higher-level computer system 12 can also be a server 710, 750 of a power provider or one of the subcontractors of a power provider or of the vehicle manufacturer or of another service provider.

Optionally, a proposed electronic fuse 825, 1 comprises a control device 4 with a clock or a timer 35. The computer core 2 of the control device 4 of the fuse 1, 85 optionally uses this timer 35 for generating time stamps of a log table, which the computer core 2 of the control device 4 of the fuse 825 optionally creates in a memory of the control device 4 of the fuse 825, or which the higher-level computer system 12 optionally creates in a memory of the higher-level computer system 12, or which the computer core 2 of a control device 4 of a different fuse 805 creates in the memory of this control device 4 of the other fuse 805.

The clock or the timer 35 of the control device 4 of the electronic fuse 1, 825 optionally has a synchronization option with the clocks and timers 35 of the control devices 4 of other electronic fuses 805, 810 and/or with the clocks and/or timers 1970 of a higher-level computer system 12.

In a proposed electronic fuse 825, the computer core 2 of the control device 4 of this electronic fuse 825 optionally carries out a switch-off of the circuit breaker 17 after receiving a switch-off signal and/or a switch-off command via the fuse data bus 9 only after a switch-off delay time has elapsed. Optionally, the computer core 2 of the control device 4 of the electronic fuse 825 determines the time since receipt of the switch-off signal or switch-off command with the aid of the timer 35 of the control device 4 of the electronic fuse 825. Optionally, the computer core 2 of the control device 4 of the electronic fuse 825 immediately executes the switch-off of the circuit breaker 9 if the value of the electrical current 29 through the circuit breaker 17 of the electronic fuse 825 exceeds a threshold value and/or if the magnitude of the power feed into the downstream supply sub-network and/or into the downstream supply line section or into a downstream load exceeds a power feed threshold value and/or if the magnitude of power extraction from the upstream supply sub-network and/or in the upstream supply line section or from an upstream power source exceeds a power extraction threshold value. Immediately means that the computer core 2 executes the switch-off in less than 100 μs, better in less than 50 μs, better in less than 20 μs, better in less than 10 μs, better in less than 5 μs, better in less than 2 μs, better in less than 1 μs, better in less than 500 ns, better in less than 200 ns, better in less than 100 ns.

Optionally, the switch-off delay time depends on the value of the electrical current 29 through the circuit breaker 17 and/or on the magnitude of the power feed into the downstream supply sub-network and/or into the downstream supply line section or into a downstream load, which magnitude exceeds a power feed threshold value, and/or on the power extraction from the upstream supply sub-network and/or in the upstream supply line section or from an upstream power source.

The switch-off delay time furthermore optionally depends on the value of the electrical current 29 through the circuit breaker 17 such that it drops in a parabolic manner when the value of the electrical current 29 through the circuit breaker 17 increases.

Optionally, the computer core 2 of the control device 4 of the electronic fuse 825 integrates the square of the absolute value of the electrical current 29 through the circuit breaker 17 of the electronic fuse 825 over time and in this way emulates the behavior of a melting fuse. Optionally, the computer core 2 of the control device 4 of the electronic fuse 825 opens the circuit breaker 17 of the electronic fuse 825 if the magnitude of the temporal integral of the square of the absolute value of the current 29 through the power transistor 17 exceeds a current squared threshold value. Instead of the square of the absolute value of the electrical current 29 through the circuit breaker 17 of the electronic fuse 825, the computer core 2 of the control device 4 of the electronic fuse can also calculate the integral of a polynomial of at least the second degree of the value of the current 29 through the circuit breaker 17 of the electronic fuse 825, and then use this value for the comparison to the current squared threshold value for switching off the circuit breaker 17 when the current squared threshold value is exceeded.

By means of corresponding measuring means 16, the computer core 2 of the control device 4 of the electronic fuse 825 optionally detects the value of the electrical current 29 through the circuit breaker 17, squares it or applies a polynomial of at least the second degree thereto and integrates the result over time. This integration can also be a filtering, especially a low-pass filtering. The computer core 2 of the control device 4 of the electronic fuse then compares the detected, squared, and filtered value of the electrical current 29 to a threshold value, in particular to said current squared threshold value. The switching state of the circuit breaker 17 of the electronic fuse 825 then depends at least at times on the result of this comparison. However, it is possible, for example, for the circuit breaker 17 of the electronic fuse 825 to be opened by the higher-level computer system 12 independently thereof by command via the data bus 9.

As already indicated, the computer core 2 of the control device 4 of the electronic fuse 825 can detect the value of the electrical current 29 through the circuit breaker 17 by corresponding means 16, convert the detected value of the electrical current 29 through the circuit breaker 17 into a mapped value by means of a polynomial having an order of the polynomial greater than one, and integrate this mapped value of the electrical current 29 through the circuit breaker 17 over time, in particular filter, in particular low-pass filter, this value integrated over time of the electrical current 29. Optionally, the computer core 2 of the control device 4 of the electronic fuse 825 compares the mapped and filtered value of the electrical current 29 with a threshold value, in particular the current squared threshold value, wherein the switching state of the circuit breaker 17 of the electronic fuse 825 optionally depends, as before, at least at times on the result of this comparison.

Optionally, the computer core 2 of the control device 4 of the electronic fuse 825 allows the transport of electrical power from one or more power sources 250 to the load 835, 830 at least at times, in which the computer core 2 of the control device 4 of the fuse 825 closes its circuit breaker 17. Typically, the computer core 2 of the control device 4 of the electronic fuse 825 prevents the transport of electrical power from the load 835, 830 to one or more or all of the power sources 250.

The electronic fuse 825 and/or the control device 4 of the electronic fuse 825 optionally comprise means 24, 23 for detecting the direction of the electrical current 29 through the circuit breaker 17. Optionally, the computer core 2 of the control device 4 of the electronic fuse 825 detects the direction of the flowing electric current 29 with the aid of these means 24, 23. If a power return flow in the direction of the power source 250 is not desired, the computer core 2 of the control device 4 of the electronic fuse 825 opens the circuit breaker 17 of the electronic fuse 825 if the electrical current 29 from the load 830 to one or more power sources 250 is flowing through the circuit breaker 17 of the electronic fuse 825.

The control device 4 of the electronic fuse or the fuse 825 optionally comprises a third circuit breaker 615, which is different from the circuit breaker 17 of the electronic fuse 825. The computer core 2 of the control device 4 of the fuse 825 typically closes this third circuit breaker 615 if the electrical current 29 from the load 835 to one or more power sources 250 is flowing through the circuit breaker 17 of the electronic fuse 825. In this case, if the third circuit breaker 615 is closed, this third circuit breaker 615 diverts the electrical current 29 from the load 835 into a current sink, in particular a reference potential line 201.

### FIG. 9

Optionally, the electronic fuse 1, and specifically in particular the control device 4 of the electronic fuse 1, comprises means 505, 905 for detecting the switchability of the circuit breaker 17 of the electronic fuse 1.

In FIG. 9, for better clarity, not all appropriate and in some cases customary device components are shown. Further device components that the reader can assume as possibly present in FIG. 1 can be found, for example, in FIGS. 1, 5, 6, 24, 41, 42, 52, 53, 54, 55, 57, 58 and 62. The combination of the device parts of the Figure described here with those of these figures is expressly part of the disclosure of the disclosure.

In contrast to the fuse 1 of FIG. 5, the fuse 1 of FIG. 9 has, in addition to the first test current source 505, a second test current source 905, the test current 915 of which is modulated by means of the control signal 910 with a modulation signal {505} of a second signal generator 920. The second test current 915 optionally corresponds to the first test current 515. As a result, the control device 4 can feed the test current 515 into the circuit breaker 17 and extract it back out of the current path as a second test current 915 after it passes through the circuit breaker 17. If the circuit breaker 17 is not in the expected state, for example open or closed, the second test current 915 and/or the first test current 515 and/or the voltage drops between the terminals 26, 27, 28 of the circuit breaker 17 do not correspond to the expected values. From this, the computer core 2 of the control device 4 of the electronic fuse 1 can then detect an error of the circuit breaker 1. In such an error case, the computer core 2 of the control device 4 of the electronic fuse 1 can signal such an error to, for example, a higher-level computer system 12 or the computer cores 2 of the control devices 4 of other electronic fuses. For controlling the second test current source 905, a second signal generator 920 optionally generates a second control signal 910 of the second electronic test current source 905, which ensures that the second test current 915, which the second test current source (910) extracts from the circuit breaker (17), is modulated with the modulation signal {505}.

The disclosure proposes that the control device 4 of the electronic fuse 1 comprises a first test current source 505 and a second test current source 905. The control device 4 of the electronic fuse 1 controls the first test current source 505 and the second test current source 905. At the instigation of the control device 4, the first test current source 505 feeds the test current 515 into the first terminal 26 of the circuit breaker 17. The second test current source 905 then extracts this test current 915 from the second terminal 28 of the circuit breaker 17. The second test current source 905 optionally comprises means in order to detect the extraction of the test current. The computer core 2 of the control device 4 deduces an error of the circuit breaker 17 of the electronic fuse 1 if the second current source 905, against expectations, does not detect or detects an extraction of a test current 915. For example, the control device 4 can also evaluate a deviation of the magnitude of the second test current 915 outside an expected value interval as an error. The computer core 2 of the control device 4 of the electronic fuse 1 optionally changes one or more times the switching state of the circuit breaker 17 and checks the switching state of the circuit breaker 17.

For this purpose, the computer core 2 of the control device 4 of the electronic fuse 1 optionally determines measured values by means of measuring means of the electronic fuse 1 and/or of the control device 4 of the electronic fuse 1. Optionally, the computer core 2 of the control device 4 and/or the higher-level computer system 2 executes a neural network model. The computer core 2 of the control device 4 and/or the higher-level computer system 2 use the determined measured values as input values of the neural network model executed thereby. In order to enable this, the computer cores 2 of the control devices 4 of one or more fuses and/or the higher-level computer system 12 optionally transmit the necessary data for the input signals of the neural network to the computer core 2 of the control device 4 of the fuse 1 and/or to the higher-level computer system 12, depending on which computer is currently executing the neural network model.

The switching state of the circuit breaker 17 of the electronic fuse 1 and/or at least one data message of the computer core 2 of the control device 4 of the electronic fuse 1 to a higher-level computer system 12 or a computer core 2 of another control device 4 of another electronic fuse 805 then optionally depends on an output signal of the neural network model.

The neural network model is optionally trained with suitable training data from the development time.

For example, the computer core 2 of the control device 4 of the electronic fuse 825 can detect a failure of one or more loads 835 or a failure of one or more power sources 250 or another defect of the system of the overall device by means of an output signal of the neural network model.

The computer core 2 of the control device 4 of the electronic fuse 825 can also exchange data by means of power-line communication with a different computer system 12 and/or with the control device 4 of a different electronic fuse 805, for example via a supply voltage line (6, 241, 242, 245).

For realizing power line communication, the computer core 2 of the control device 4 of the electronic fuse 1 can use the circuit breaker 17 of the electronic fuse 825 as a transmitting transistor for data communication via the supply voltage line (6, 241, 242, 245).

The computer core 2 of the control device 4 of the electronic fuse 1 can open the circuit breaker 17 of the electronic fuse 1, for example, for transmitting a bit of a first logic value. The computer core 2 of the control device 4 of the electronic fuse 1 can close the circuit breaker 17 of the electronic fuse 1, for example, for transmitting a bit of a second logic value which is different from the first logic value.

Instead of this modeling, communication about different internal resistances of the circuit breaker 17 is possible via complete opening and closing.

The computer core 2 of the control device 4 of the electronic fuse 1 can, for example, bring the circuit breaker 17 of the electronic fuse 1 into a first state having a first electrical resistance value between the first terminal 26 of the circuit breaker 17 and the second terminal 28 of the circuit breaker 17, for transmitting a bit of a first logic value. The computer core 2 of the control device 4 of the electronic fuse 1 can, for example, bring the circuit breaker 17 of the electronic fuse 1 into a second state having a second electrical resistance value between the first terminal 26 of the circuit breaker 17 and the second terminal 28 of the circuit breaker 17, which is different from the first resistance value, in order to transmit a bit of a second logic value which is different from the first logic value.

In order to be able to receive data via the supply voltage line, the control device 4 of the electronic fuse 1 optionally has means for detecting the time characteristic of the electrical current 29 through the circuit breaker 17 of the electronic fuse 1. These means optionally detect the time characteristic of the electrical current 29 through the circuit breaker 17 of the electronic fuse 1 at least at times. These means can in particular comprise an analog-to-digital converter 570 and/or a memory of the computer core 2 of the control device 4 of the electronic fuse 1 or of the control device 4 of the electronic fuse 1.

The control device 4 of the electronic fuse 1 optionally comprises means for detecting the time characteristic of the voltage between a terminal (26, 27, 28) of the circuit breaker 17 of the electronic fuse 1 and a reference potential 201. These means typically detect, at least at times, the time characteristic of the voltage between a terminal (26, 27, 28) of the circuit breaker 17 of the electronic fuse 1 and a reference potential 201.

The computer core 2 of the control device 4 of the electronic fuse 1 optionally carries out a spectral analysis of the data of the time characteristics, for example by Fourier or Laplace transform or wavelet transform and determines values of the spectrum. The computer core 2 of the control device 4 of the electronic fuse 1 optionally deduces, in the event of substantial deviations of the values of these spectra from associated expected value intervals for these values of these spectra, the need for preventive maintenance and/or signals this deviation to a higher-level computer system 12.

The electronic fuse 1 optionally comprises means for detecting the value of the electrical current 29 through the circuit breaker 17 of the electronic fuse 1 and for detecting a voltage at a terminal (26, 27, 28) of the circuit breaker 17 of the electronic fuse 1 against a reference potential 201. According to the proposal, the computer core 2 of the control device 4 of the electronic fuse 1 switches off the circuit breaker 17 of the electronic fuse 1 in the event of a voltage drop in the measured voltage values below a minimum voltage value AND a simultaneous current increase of the value of the current 29 through the circuit breaker 17 above a maximum current value, i.e., the circuit breaker 17 in this case opens. This is therefore the case if:
a) the measured voltage value falls below a voltage threshold value AND at the same time the measured current value exceeds a current threshold value; and/or
b) the speed of a measured change over time in the voltage value drop exceeds a voltage drop rate threshold AND at the same time the speed of a measured change over time in the magnitude of the electrical current 29 through the circuit breaker 17, i.e., the current increase, exceeds a current increase rate threshold.

Under such switch-off conditions, the computer core 2 of the control device 4 of the electronic fuse 1 optionally switches off the circuit breaker 17 of the electronic fuse 1 more quickly than within 1 μs. This has the advantage that in many cases this very short time is sufficient to prevent damage.

The proposed electronic fuse 1 optionally has an emergency control 925. The emergency control 925 can optionally transmit data via a data bus 540, 9 and receive it via this data bus 9, 540. The control device 4 of the electronic fuse 1, 825 in emergency operation can be, for example, the control device 4 of a different electronic fuse 805 which controls the other electronic fuse 805 in the event of a failure of the control device 4 of the other electronic fuse 805 by means of a data communication via the data bus 9, 540 and by means of the emergency control 925 of the other electronic fuse 805. (See also FIG. 8) The emergency control 925 optionally monitors the data communication between the control device 4 and the emergency control 925 of the other fuse 805. In the event of a failure of the data communication of the fuse 1, the emergency control 925 optionally emulates simple functions of the control device 4 and thus optionally ensures at least basic protection of the connected supply line 19, 815, 820 and/or supply sub-networks and/or loads and/or power sources.

The computer core 2 of the control device 4 of the electronic fuse 1 transmits a signal to a higher-level computer system 12 via the fuse data bus 9, 540, which signal signals that a) the corresponding electronic fuse 1 is still present and/or that b) the corresponding electronic fuse 1 is ready for operation and/or what fuse identification information the fuse 1 has and/or what operating parameters the electronic fuse 1 has.

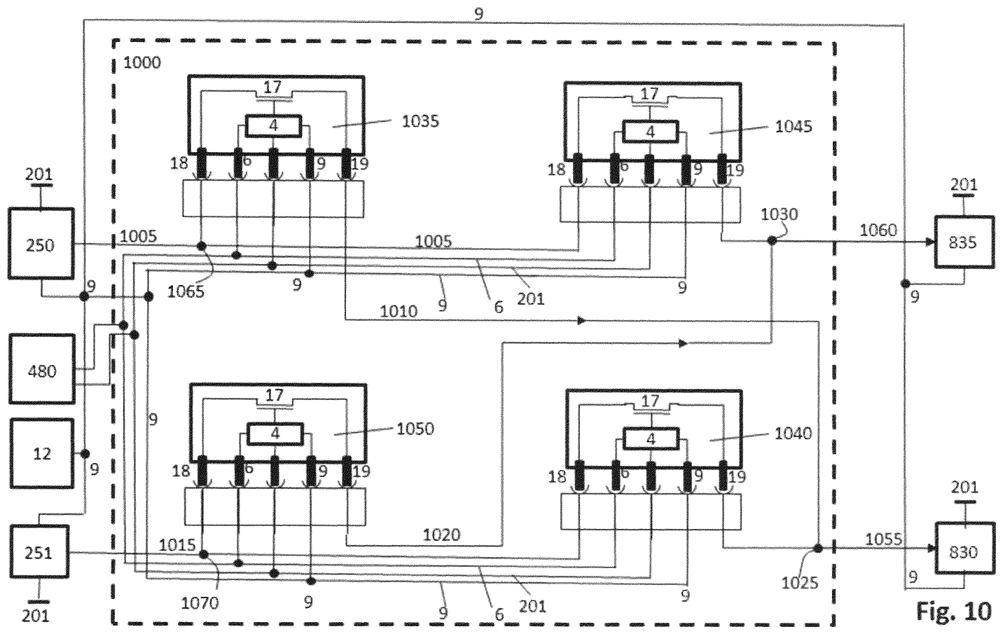

### FIG. 10

FIG. 10 shows a proposed power-source-side cross-over fuse 1000. The exemplary cross-over fuse 1000 comprises a power-source-side first supply line section 1005 of a first supply line, a load-side second supply line section 1010 of a first supply line, a power-source-side first supply line section 1015 of a second supply line, a load-side second supply line section 1020 of a second supply line, a first electrical node 1025, a second electrical node 1030, a first electronic fuse 1035 as described above, a second electronic fuse 1040 as described above, a third electronic fuse 1045 as described above, and a fourth electronic fuse 1050 as described above. Depending on the switching state of the circuit breaker 17 of the first electronic fuse 1035, the first electronic fuse 1035 connects the power-source-side first supply line section 1005 of the first supply line to the first node 1025, or disconnects the power-source-side first supply line section 1005 of the first supply line from the first node 1025. Depending on the switching state of the circuit breaker 17 of the second electronic fuse 1040, the second electronic fuse 1040 connects the power-source-side first supply line section 1015 of the second supply line to the first node 1025, or disconnects the power-source-side first supply line section 1015 of the second supply line from the first node 1025. The second electronic fuse 1040 does not connect the power-source-side first supply line section 1015 of the second supply line to the first node 1025 if the first electronic fuse 1035 connects the power-source-side first supply line section 1005 of the first supply line to the first node 1025. The first electronic fuse 1040 does not connect the power-source-side first supply line section 1005 of the first supply line to the first node 1025 if the second electronic fuse 1040 connects the power-source-side first supply line section 1015 of the second supply line to the first node 1025. Depending on the switching state of the circuit breaker 17 of the third electronic fuse 1045, the third electronic fuse 1045 connects the power-source-side first supply line section 1005 of the first supply line to the second node 1030, or disconnects the power-source-side first supply line section 1005 of the first supply line from the second node 1030. Depending on the switching state of the circuit breaker 17 of the fourth electronic fuse 1050, the fourth electronic fuse 1050 connects the power-source-side first supply line section 1015 of the second supply line to the second node 1030, or disconnects the power-source-side first supply line section 1030 of the second supply line from the second node 1030. The fourth electronic fuse 1050 does not connect the power-source-side first supply line section 1015 of the second supply line to the second node 1030 if the third electronic fuse 1045 connects the power-source-side first supply line section 1005 of the first supply line to the second node. The third electronic fuse 1045 does not connect the power-source-side first supply line section of the first supply line to the second node 1030 if the fourth electronic fuse 1050 connects the power-source-side first supply line section 1015 of the second supply line to the second node 1030. The load-side second supply line section 1055 of the first supply line is connected to the first node 1025. The load-side second supply line section 1060 of the second supply line is connected to the second node 1030.

A proposed load-side cross-over fuse 1000 comprises a power-source-side first supply line section 1005 of a first supply line, a load-side second supply line section 1015 of a first supply line, a power-source-side first supply line section 1055 of a second supply line, a load-side second supply line section 1060 of a second supply line, a third electrical node 1065, a fourth electrical node 1070, a first electronic fuse 1035 as described above, a second electronic fuse 1040 as described above, a third electronic fuse 1045 as described above, and a fourth electronic fuse 1050 as described above. Depending on the switching state of the circuit breaker 17 of the first electronic fuse 1035, the first electronic fuse 1035 connects the load-side second supply line section 1055 of the first supply line to the third node 1065 or disconnects the load-side second supply line section 1055 of the first supply line from the third node 1065. Depending on the switching state of the circuit breaker 17 of the second electronic fuse 1040, the second electronic fuse 1040 connects the load-side second supply line section 1055 of the first supply line to the fourth node 1070 or disconnects the load-side second supply line section 1055 of the first supply line 1055 from the fourth node 1070. The second electronic fuse 1040 does not connect the load-side second supply line section 1055 of the first supply line to the fourth node 1070 if the first electronic fuse 1035 connects the load-side second supply line section 1055 of the first supply line to the third node 1065. The first electronic fuse 1035 does not connect the load-side second supply line section 1055 of the first supply line to the third node 1055 if the second electronic fuse 1040 connects the load-side second supply line section of the first supply line 1055 to the fourth node 1070. Depending on the switching state of the circuit breaker 17 of the third electronic fuse 1045, the third electronic fuse 1045 connects the load-side second supply line section 1060 of the second supply line to the third node 1065 or disconnects the load-side second supply line section 1060 of the second supply line from the third node 1065. Depending on the switching state of the circuit breaker 17 of the fourth electronic fuse 1050, the fourth electronic fuse 1050 connects the load-side second supply line section of the second supply line 1060 to the fourth node 1070 or disconnects the load-side second supply line section 1060 of the second supply line from the fourth node 1070. The fourth electronic fuse 1050 does not connect the load-side second supply line section 1060 of the second supply line to the fourth node 1070 if the third electronic fuse 1045 connects the load-side second supply line section 1060 of the second supply line to the third node 1065. The third electronic fuse 1045 does not connect the load-side second supply line section 1060 of the second supply line to the third node 1065 if the fourth electronic fuse 1050 connects the load-side second supply line section 1060 of the second supply line to the fourth node 1070. The power-source-side first supply line section 1005 of the first supply line is connected to the third node 1065. The power-source-side first supply line section 1015 of the second supply line is connected to the fourth node 1070.

With the above-described cross-over fuses, the switching state of the circuit breakers 17 of the electronic fuses (1035, 1040, 1045, 1050) of the cross-over fuse 1000 depends on a determined power requirement of one or more loads (830, 835) and/or on a determined power supply capacity of one or more power sources (250, 251).

The computer cores 2 of the control devices 4 of the electronic fuses (1035, 1040, 1045, 1050) of the cross-over fuse 1000 are optionally connected to one another via a fuse data bus 9 and to a higher-level computer system 12. The higher-level computer system 12 optionally determines the power requirement of one or more loads 835, 830, which the supply lines (1005, 1010: 1015, 1020, 1055, 1060) of the cross-over fuse 1000 can supply with electrical power. The higher-level computer system 12 determines the power supply capacity of one or more power sources 250, 251, which, via the supply lines (1005, 1010: 1015, 1020, 1055, 1060) can supply the cross-over fuse 1000 with electrical power. The computer system 12 transmits configuration commands via the fuse data bus 9 to the computer cores 2 of the control devices 4 of the fuses (1035, 1040, 1045, 1050) of the cross-over fuse 1000, which commands depend on the determined power requirement of these loads 830, 831 and/or depend on the determined power supply capacity of these power sources 250, 251. These configuration commands of the higher-level computer system 12 optionally cause the opening and closing of circuit breakers 17 of the electronic fuses (1035, 1040, 1045, 1050) of the cross-over fuse 1000.

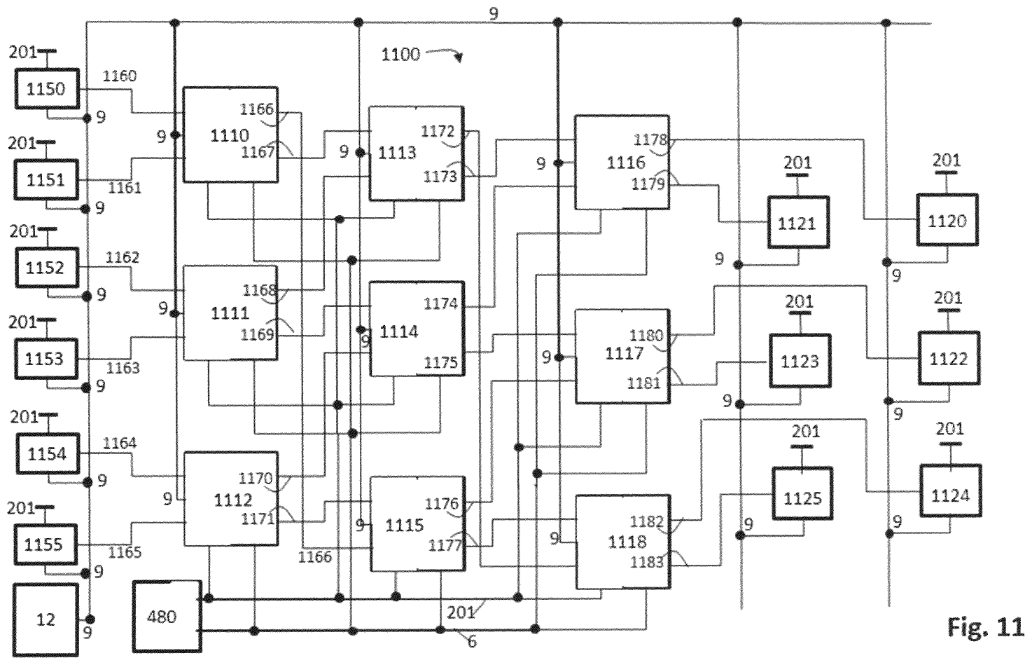

### FIG. 11

FIG. 11 shows a proposed supply network 1100 having a higher-level computer system 12 and having a plurality of supply lines and having a plurality of cross-over fuses 1110 to 1118, which enable flexible load-dependent and supply-dependent reconfiguration of the supply network 1100.

The cross-over fuses 1110 to 1118 are each inserted in supply line pairs of the supply lines of the supply network 1100. The higher-level computer system 12 is connected to the computer cores 2 of the control devices 4 of the electronic fuses of the cross-over fuses 1110 to 1118 by means of a fuse data bus 9.

The electronic fuses of the cross-over fuses 1110 to 1118 each have control devices 4 with a corresponding computer core. These fuses are optionally electronic fuses of the type described above.

To simplify the construction, the by way of example four electronic fuses of a corresponding cross-over fuse of the cross-over fuses 1110 to 1118 can jointly also have a common control device (4), so that this individual control device 4 simultaneously controls four circuit breakers 17 of the four fuses.

The higher-level computer system 12 optionally determines the power requirement of electrical power loads 1121 to 1124 in the supply network 1100. The higher-level computer system 12 also optionally determines the power supply capacity of electrical power sources 1150 to 1155 in the supply network 1100.

The higher-level computer system 12 optionally determines the current safety requirement on the basis of the current driving situation of the vehicle, which means that the higher-level computer system-based on measurement data, which in particular can comprise measurement data of electronic fuses in the supply network value 1100-deduces, for example, the future power supply capacity and the future power consumption.

By means of configuration commands via the fuse data bus 9 to the computer cores 2 of the control devices 4 of the fuses of the cross-over fuses (1110 to 1118), the higher-level computer system 12 optionally dynamically adjusts the electrically effective topology of the supply network of the supply lines according to the determined power requirement and/or according to the determined power supply capacity and/or according to the current safety requirement.

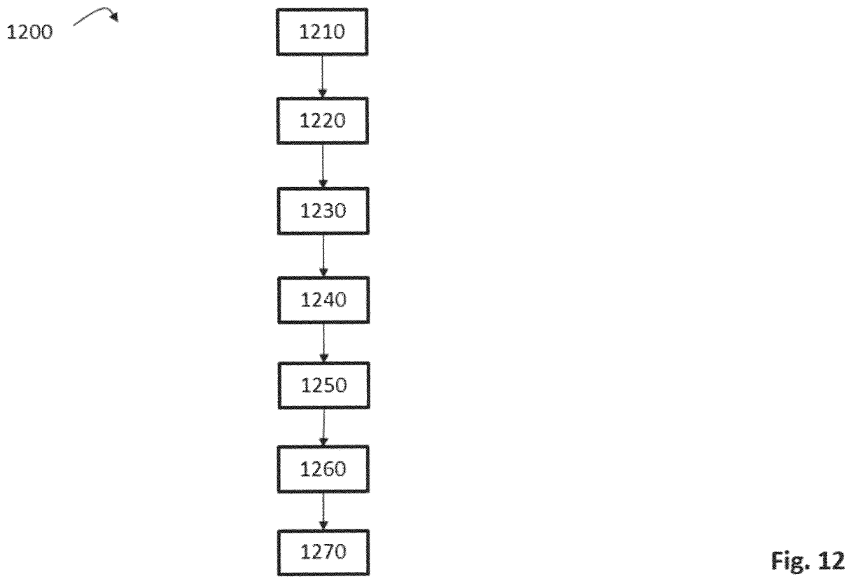

### FIG. 12

FIG. 12 shows the basic sequence of a method 1200 for operating a supply network. The method comprises the steps of:
Step 1: providing 1210 a supply network (250, 251, 210 to 213, 245) having a device part of the vehicle, hereinafter referred to as a power-supplying device part 210, wherein the power-supplying supply part 210 comprises a control device 280, 4 and a memory in a first logic state;
Step 2: supplying 1220 the power-supplying device part 210 with electrical power from a power source 251, 250 of the vehicle;
Step 3: connecting 1230 a first terminal of a further line section 240 to the power-supplying device part 210 of the vehicle;
Step 4: connecting 1240 a second terminal of the further line section 240 to a further device part 220, 221 of the vehicle;
Step 5: signaling 1250 a switch-on signal to the control device 280, 4 of the power-supplying device part 210;
Step 6: changing 1260 the logic state of the memory to a second logic state depending on the logic state of the memory;
Step 7: supplying 1270 the further device part 220 to 221 of the vehicle with electrical power via the further line section 240 depending on the logic state of the memory.

Optionally, the signaling 1250 of the switch-on signal takes place via a fuse data bus 9.

The power-supplying device part 210 optionally has an electronic fuse 215 of the power-supplying device part 250, 251. The supply 1270 of the further device part 220, 221 of the vehicle with electrical power optionally takes place via the further line section 240 by means of the electronic fuse 215 of the power-supplying device part 210 being switched on depending on the logic state of the memory.

A variant of the method 1200 for operating a supply network 200 comprises the steps of:
Step 1: providing 1210 a supply network 200 having a device part 210 of the vehicle, hereinafter referred to as a power-supplying device part 210.
Step 2: supplying 1220 the power-supplying device part 210 with electrical power from a power source 250, 251 of the vehicle;
Step 3: connecting 1230 a first terminal of a further line section 240 to the power-supplying device part 210 of the vehicle;
Step 4: connecting 1240 a second terminal of a further line section 240 to a further device part of the device parts 220 to 221 of the vehicle, wherein the further supply part of the device parts 220 to 221 of the vehicle comprises a control device 280, 4, and wherein the further supply part of the device parts 220 to 221 of the vehicle comprises a memory in a first logic state;
Step 5: signaling 1250 a switch-on signal to the control device 280, 4 of the further device part of the device parts (220 to 221) of the vehicle;
Step 6: changing 1260 the logic state of the memory to a second logic state depending on the logic state of the memory;
Step 7: supplying 1270 the further device part of the device parts 220 to 221 of the vehicle with electrical power via the further line section 240 depending on the logic state of the memory. Optionally, the switch-on signal is also signaled here via a fuse data bus 9. Optionally, the further device part has an electronic fuse 225 for protecting the further device part 220. The further device part 220 of the vehicle is optionally supplied with electrical power via the further line section 240 by means of the circuit breaker 17 of the electronic fuse 225 of the further device part 220 being switched on depending on the logic state of the memory.

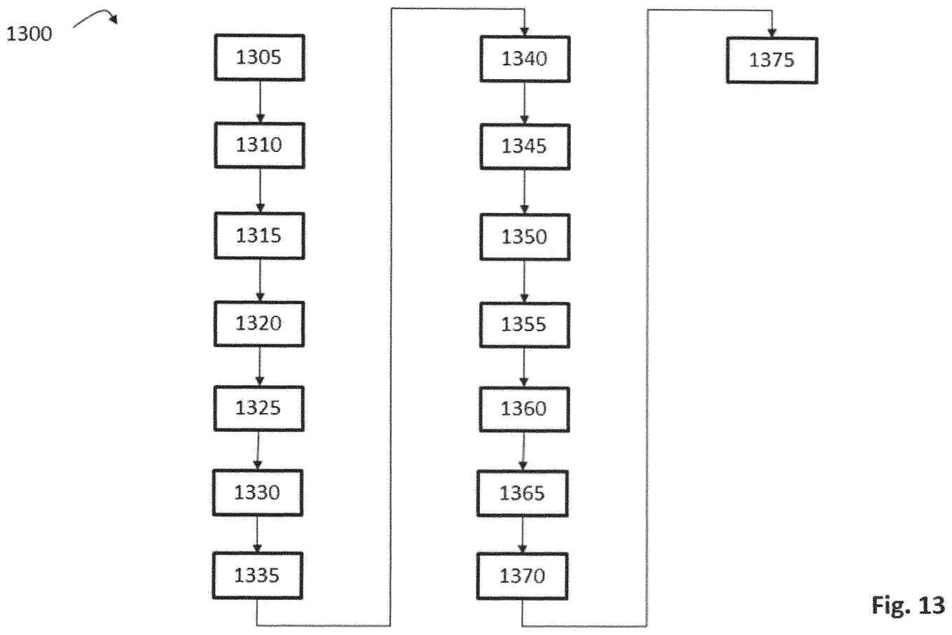

### FIG. 13

FIG. 13 outlines a method 1300 for operating a vehicle (load-side feature version). It comprises the steps of:
Step 1: providing 1305 the vehicle, (see also FIG. 7), wherein the vehicle comprises, among other things, device parts 210 and at least one cable harness with line sections 240, 241, 245 and at least one power source 250, 251, and comprises at least one control computer 12, for example a higher-level computer system 12, and at least two electronic fuses 214, 225. The device parts 220 in this case are electrical loads. At least one or more power sources 250, 251 supply at least two of the device parts 210, 220 with electrical power via the cable harness with line sections 240, 241, 245. The electronic fuses 214, 225 are optionally inserted into the cable harness with line sections 240, 241, 245. Optionally, each of the electrical fuses 214, 225 is assigned at least one electrical load 210, 225, which is referred to below as the electrical load associated with the corresponding electronic fuse. A fuse of the fuses 214, 215 can enable or prevent the supply of power to the electrical load associated with this fuse depending on a control signal of the control computer, for example of a higher-level computer system 12.
Step 2: preventing 1310 the supply of power to an associated electrical load by means of the corresponding fuse with which this load is associated;
Step 3: establishing 1315 an encrypted data connection 720 between the control computer 12 of the vehicle, for example the higher-level computer system 12, and a computer 710 of a service provider, in particular a computer system of the automobile manufacturer of the vehicle;
Step 4: authentication 1320 of the vehicle by the control computer 12 of the vehicle, for example by a higher-level computer system 12, to the computer 710 of the service provider, wherein the authentication data of the vehicle may comprise, for example, the data of the vehicle and/or the car key and/or a SIM card in the vehicle and/or a vehicle-specific password input or password generation and/or biometric user data of a vehicle owner, etc.;
Step 4: authentication 1325 of the computer 710 of the service provider to the control computer 12 of the vehicle, for example to a higher-level computer system 12;
Step 5: if necessary, authentication 1330 of the requesting person 730 by the control computer 12 of the vehicle, for example by the higher-level computer system 12, to the computer 710 of the service provider, wherein the authentication data can comprise, for example, the data of the vehicle and/or of the personalized car key, a personalized SIM card, a personalized password input, biometric user data, etc.;
Step 6: generation 1335 or provision of an activation code by the computer 710 of the service provider;
Step 7: transmission 1340 of the activation code by the computer of the service provider 710 to the control computer 12 of the vehicle, for example to the higher-level computer system 12;
Step 8: verification 1345 of the admissibility and/or syntactical correctness and/or the situational admissibility of the activation code by the control computer 12 of the vehicle, for example by the higher-level computer system 12;
Step 9: enabling 1350 the supply of power to an associated electrical load 220 by means of the corresponding fuse 225 if the activation code is admissible and/or syntactically correct and/or is situationally admissible;
Step 10: transmission 1355 of billing data to a or the computer 710 of a or the service provider, in particular to a or the computer system of the automobile manufacturer, wherein memory information in the computer 710 of the service provider marks that the invoice is not paid;
Step 11: creation 1360 of an invoice depending on the transmitted billing data by a or the computer 710 of a or the service provider, in particular to a or the computer system of the automobile manufacturer;
Step 12: transmission 1365 of the invoice to a or the computer 710 of a or the service provider, in particular to a or the computer system 740 of the ordering person 730, or to the ordering person 730;
Step 13: settlement 1370 of the invoice via a or the computer 710 of a or the service provider and/or the requesting person 730;
Step 14: marking 1375 of the memory information in the computer of the service provider 740 that the invoice is paid.

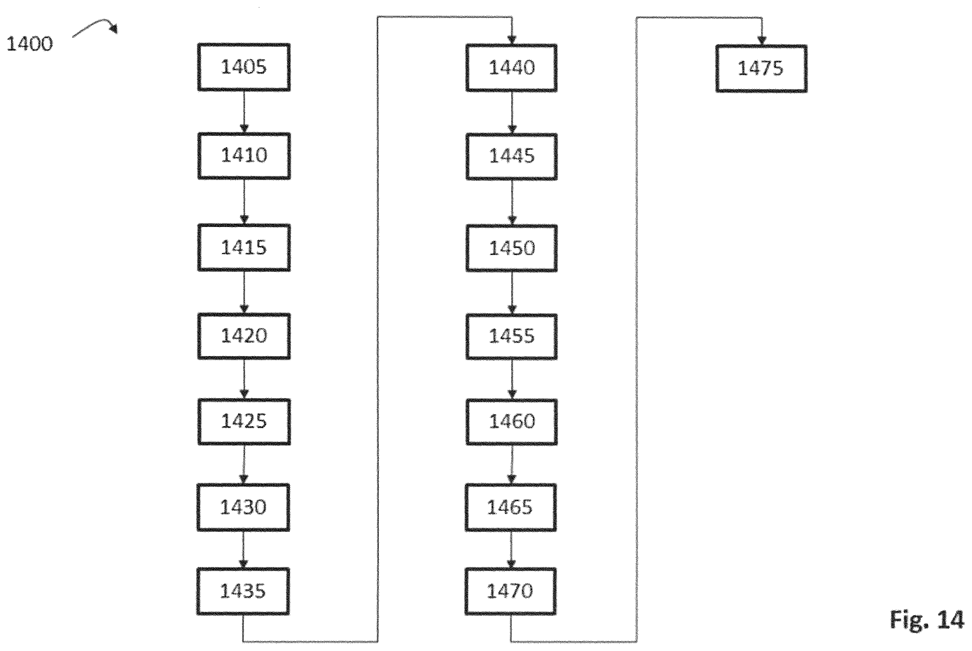

### FIG. 14

FIG. 14 also shows a further method described in a simplified manner 1400 for operating a vehicle with activation of power sources in the vehicle. The method comprises the steps of:
Step 1: providing 1405 the vehicle;
Step 2: preventing 1410 the supply of power of an associated electrical power source 250, 251 in which, for example, the higher-level computer system 12 signals to the computer core 2 of the control device 4 of the corresponding fuse 255, 260 to open the circuit breaker 17 of this electronic fuse 255, 260, whereupon this computer core 2 of this control device 4 of this associated electronic fuse 255, 260 opens the circuit breaker 17 of this fuse 255, 260;
Step 3: producing 1415 an encrypted connection 720 between the control computer of the vehicle, i.e., the higher-level computer system 12, and a computer 710 of a service provider, in particular a computer system 710 of the automobile manufacturer. Here, the higher-level computer system 12 and the computer system 710 of the service provider or of the automobile manufacturer optionally use PQC encryption;
Step 4: authentication 1420 of the vehicle by the control computer of the vehicle, i.e., by the higher-level computer system 12, to the computer 710 of the service provider, wherein the authentication data of the vehicle can comprise, for example, the data of the vehicle and/or of the car key and/or of a SIM card in the vehicle and/or of a vehicle-specific password input or password generation and/or biometric user data of a vehicle owner, etc.;
Step 5: authentication 1430 of the computer 710 of the service provider to the control computer of the vehicle, i.e., to the higher-level computer system 12;
Step 6: authentication 1430 of the requesting person 730 by the control computer of the vehicle, i.e., by the higher-level computer system 12, to the computer 710 of the service provider, wherein the authentication data can comprise, for example, the data of the vehicle and/or of the personalized car key, a personalized SIM card, a personalized password input, biometric user data (e.g., fingerprint sensor data and/or retina scanner data and/or facial recognition data and/or speech input data, etc.), etc.;
Step 7: generation 1435 or provision of an activation code in particular by the computer 710 of the service provider. The activation code optionally depends on the transmitted configuration data of the vehicle and/or the transmitted authentication data and/or the location at which the vehicle is located and/or on the requesting person 730 and/or on the owner of the vehicle and/or on operating data of the vehicle, etc.;
Step 8: optionally encrypted transmission 1440 of the activation code by the computer 710 of the service provider to the control computer of the vehicle, i.e., to the higher-level computer system 12;
Step 9: verification 1445 of the admissibility and/or syntactical correctness and/or the situational admissibility of the activation code by the control computer 12 of the vehicle, i.e., by the higher-level computer system 12. This should prevent a computer system other than the computer system 710 of an approved service provider from successfully entering an activation code into the system of the vehicle;
Step 10: enabling 1450 the supply of power of an associated electrical power source 250, 251 by means of the corresponding associated fuse 255, 260. Upon successful verification of the activation code in step 10, the computer core 2 of the control device 4 of the associated fuse 255, 260 optionally closes the circuit breaker 17 of this fuse 255, 260, so that an upstream power source 250, 251 can supply a downstream supply sub-network and/or a downstream supply line section and/or a downstream electrical load with electrical power;
Step 11: optionally, measuring means and/or fuses in the supply network 200 detect measured values and parameters that the invoice creator requires for the power billing. In this step 11, a transmission 1455 of billing data is optionally carried out by the higher-level computer system 12 to a or the computer 710 of a or the service provider, in particular to a or the computer system of the automobile manufacturer, wherein memory information in the computer 710 of the service provider marks that the invoice has not yet been paid;
Step 12: creation 1460 of an invoice depending on the transmitted billing data by a or the computer 710 of a or the service provider, in particular to a or the computer system of the automobile manufacturer;
Step 13: transmission 1465 of the invoice, in particular by a or the computer 710 of a or the service provider to a or the computer 750 of a or the service provider, in particular to a or the computer system of the ordering person, or to the ordering person 730;
Step 14: settlement 1470 of the invoice by a or the computer 750 of a or the service provider and/or the requesting person 730;
Step 15: marking 1475 of the memory information in the computer 710 of the service provider that the invoice is paid;

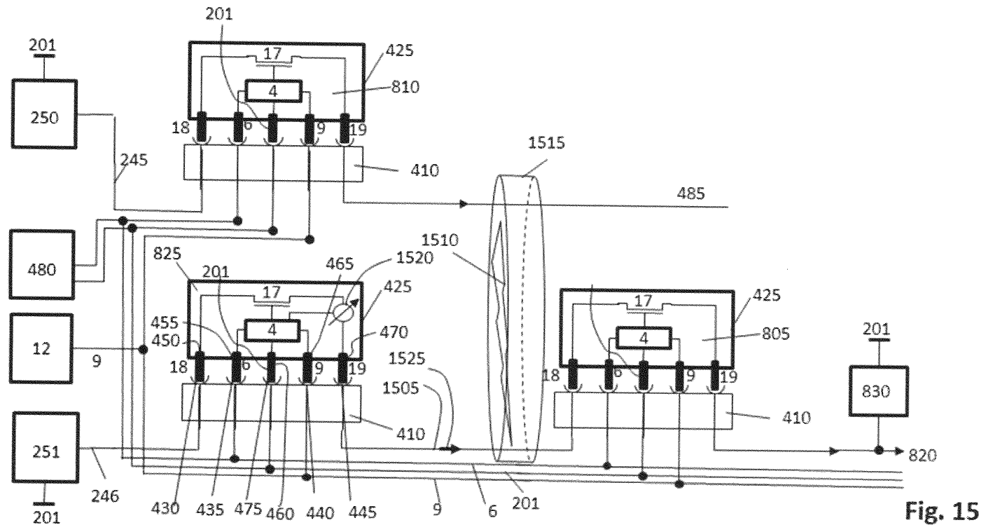

### FIG. 15

FIG. 15 largely corresponds to FIG. 8. However, the supply network is to now be subdivided into a first supply sub-network and a second supply sub-network.

In the first supply sub-network, a first power source 250 supplies power to an output 485 of the fuse box 400 for supplying a load with electrical power via the third supply line section 245 and a second further fuse 810. By way of example, we assume here that the first power source 250 delivers an output voltage in a range from 45 V to 80 V.

In the second supply sub-network, a second power source 251 supplies a load 830 with electrical power via the fourth supply line section 246 and an electronic fuse 825 and via a line section 1505 to be protected and a further fuse 805. By way of example, we assume here that the second power source 251 delivers an output voltage in a range from 700 V to 900 V.

The output 485 of the fuse box 400 for supplying a load and the line section 1505 to be protected together form a cable harness 1515. In the line section 1505 to be protected, the electrical current 1525 flows through the line section 1505 to be protected. The fuse 825 optionally has a current measuring device 1520 which is inserted into the line section 1505 to be protected. Typically, the fuse 825 uses its circuit breaker 17 as a current measuring device 1520. The computer core 2 of the control device 4 of the fuse 825 optionally uses the analog-to-digital converter 570 of the control device 4 of the fuse 825 in order to detect the potentials at the terminals 26, 27, 28 of the circuit breaker 17 and/or the voltage drop across the shunt resistor 24 and to deduce therefrom the current 29 through the circuit breaker 17. Thus, if it is stated here that the current measuring device 1520 is inserted into the line section 1505 to be protected, such designs made up of circuit breakers 17, auxiliary circuit breakers 23, and shunt resistor in combination with an analog-to-digital converter 570 thereof are expressly included and are considered to be inserted into the line section 1505 to be protected. Such devices are therefore suitable for determining and thus detecting the value of the electrical current 1525 through the line section 1505 to be protected.

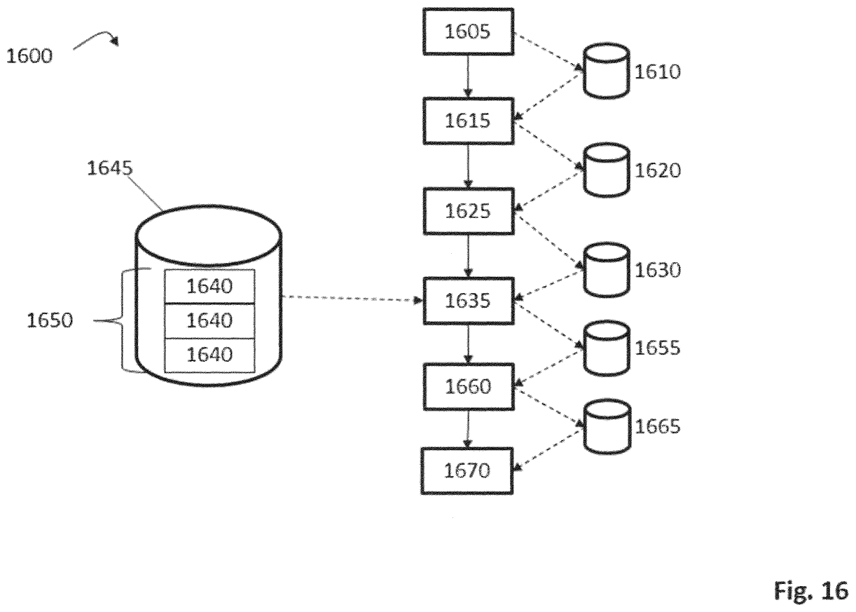

In the example of FIG. 15, it is assumed that an arc 1510 has formed in a faulty manner between the output 485 of the fuse box 400 for supplying a load and the line section 1505 to be protected. The proposed supply network 200 should detect this arc. For this purpose, the disclosure refers to the following FIG. 16.

### FIG. 16

FIG. 16 shows in schematically simplified form and by way of example a method 1600 for detecting non-extinguishing arcs 1510 in the cable harness 1515 of a vehicle. The cable harness 1515 comprises different line sections 485,1505, which are to be, for example, at different electrical potentials. The disclosure also refers here to the preceding FIG. 15.

In the cable harness 1510, voltages of more than 40 V, for example 48 V and/or 800 V, are to occur by way of example at least at times between the line sections 485, 1505. A non-extinguishing arc 1510 therefore represents a fire hazard that is not to be underestimated. Electronic fuses 810, 825, 805 are inserted by way of example into line sections 245, 246, 485, 1505 of the cable harness 1515, which electronic fuses can interrupt the current flow in individual line sections 245, 246, 485, 1505 of the cable harness 1515 or a plurality thereof by means of their circuit breakers 17. The exemplary cable harness 1515 of FIG. 16 is divided into line sections 485, 1505 to be protected. At least one electronic fuse 825 of the electronic fuses is associated with a line section 1515 of these line sections 485, 1515-hereinafter referred to as the line section 1505 to be protected-which electronic fuse can interrupt the current flow in this line section 1505 of the line sections 485, 1505 that is associated therewith. A control device 12 of the vehicle, for example the higher-level computer system 12, controls this fuse 825 of the electronic fuses 810, 825, 805 by means of data commands in bit stream packets BP via the fuse data bus 9. The higher-level computer system 12 transmits commands to the computer core 2 of the control device 4 of this fuse 825.

The method proposed in the disclosure comprises, for example, the following steps:

In a first step 1606, the computer core 2 of the control device optionally detects the time characteristic of the electrical current 1525 through the line section 1505 to be protected for a time segment by means of the analog-to-digital converter 570 of the control device 4 of the fuse 825 and the shunt resistor 24 or by means of other measuring means 1520. The computer core 2 of the control device 4 of the fuse 825 and/or the higher-level computer system 12 optionally generate an associated value characteristic 1610 of the detected value of the electrical current 1525 through the line section 1505 that is to be protected of this time segment. For this purpose, the computer core 2 of the control device 4 of the fuse 825 uses, in particular, said current measuring device 1520 which is inserted into the line section 1505. In particular, the current measuring device 1520 can be the fuse 825 associated with the line section 1505 to be protected, or a sub-device of the fuse 825 associated with the line section 1505 to be protected. For example, it can be said shunt resistor 24. In particular, this detection 1605 and/or the generation of the associated value characteristic 1610 of this time segment are optionally carried out by means of a computer core 2 of a control device 4 of an electronic fuse, which can be different from the electronic fuse 825, and/or by means of a higher-level control device 12 and/or by means of a higher-level computer system 12 which communicate with the computer core 2 of the control device 4 of the fuse 825 via a data bus 9.

The higher-level computer system 12 and/or the higher-level control device 12 of the vehicle and/or the computer core of the control device 4 of the electronic fuse, which can be identical to the electronic fuse 825, then optionally carry out a spectral analysis 1615 of the detected value characteristic 1610 of this time segment depending on the generated temporal value characteristic 1610 of the time characteristic of the electrical current 1525 through the line section 1505 to be protected. The higher-level computer system 12 and/or the higher-level control device 12 of the vehicle and/or the computer core of the control device 4 of the electronic fuse, which can be identical to the electronic fuse 825, thereby generate a spectral analysis result 1620. The higher-level computer system 12 and/or the higher-level control device 12 of the vehicle and/or the computer core 2 of the control device 4 of the electronic fuse, which can be identical to the electronic fuse 825, can communicate here with one another via the data bus (9) and/or with the computer core 2 of the control device 4 of the electronic fuse 828;

The higher-level computer system 12 and/or the higher-level control device 12 of the vehicle and/or the computer core of the control device 4 of the electronic fuse, which can be identical to the electronic fuse 825, then use 1625 these values of the spectral analysis result 1620 of the detected value characteristic 1610 of this time segment and/or values derived therefrom as the current feature vector 1630 for a pattern recognition method, which the higher-level computer system 12 and/or the higher-level control device 12 of the vehicle and/or the computer core of the control device 4 of the electronic fuse, which can be identical to the electronic fuse 825, then optionally executes.

For execution of the pattern recognition method, the higher-level computer system 12 and/or the higher-level control device 12 of the vehicle and/or the computer core of the control device 4 of the electronic fuse, which can be identical to the electronic fuse 825, map 1635 the current feature vector 1630 of the values of the spectral analysis results 1620 of the detected value characteristic 1610 of this time segment onto predefined feature vectors 1640 of spectral base structures from a stored set of predefined feature vectors of spectral base structures 1650 in a base structure database 1645. The higher-level computer system 12 and/or the higher-level control device 12 of the vehicle and/or the computer core of the control device 4 of the electronic fuse, which can be identical to the electronic fuse 825, execute this mapping 1635 in particular optionally by means of scalar product formation, as follows: The higher-level computer system 12 and/or the higher-level control device 12 of the vehicle and/or the computer core of the control device 4 of the electronic fuse, which can be identical to the electronic fuse 825, generate a spectral parameter set 1655 from the feature vector 1640. The spectral parameter set 1655 is composed of similarity values. Each similarity value of the parameter set 1655 reflects the similarity between the feature vector 1640 and both a predefined feature vector 1640 of a base structure database 1635 and the current feature vector 1640. Each of the predefined feature vectors 1640 of the base structure database 1635 is a feature vector 1640 which a temporal base structure of a temporal base characteristic of the measured values of the electrical current 1525 would generate during the processing described above. Such a base structure can be, for example, the temporal value characteristic of a current spike in the value characteristic of the current 1525, as would occur in the case of an arc. However, it can also be normal events as occur in error-free normal operation. Each predefined feature vector 1640 thus optionally corresponds to exactly one spectral base structure of a set of predefined feature vectors 1640 of spectral base structures 1625 of the base structure database 1635, which set is stored in the base structure database 1635. The higher-level computer system 12 and/or the higher-level control device 12 of the vehicle and/or the computer core of the control device 4 of the electronic fuse, which can be identical to the electronic fuse 825, now optionally calculate a similarity value for each pair made up of a feature vector 1640 of the base structure database 1635 and the current feature vector 1640. Each of these similarity values is then a value of the spectral parameter set 1655. Optionally, the higher-level computer system 12 and/or the higher-level control device 12 of the vehicle and/or the computer core of the control device 4 of the electronic fuse, which can be identical to the electronic fuse 825, calculate such a similarity value by scalar product formation between a feature vector 1650 of the base structure database 1635, on the one hand, and the current feature vector on the other hand. The higher-level computer system 12 and/or the higher-level control device 12 of the vehicle and/or the computer core of the control device 4 of the electronic fuse, which can be identical to the electronic fuse 825, optionally calculate this scalar product for predefined, in particular all predefined, feature vectors of spectral base structures from the stored set of predefined feature vectors of spectral base structures 1625 in the base structure database 1635.

The higher-level computer system 12 and/or the higher-level control device 12 of the vehicle and/or the computer core of the control device 4 of the electronic fuse, which can be identical to the electronic fuse 825, then optionally evaluate 1660 the spectral parameter set 1655 thus obtained and generate therefrom an evaluation result 1665.

For this purpose, the higher-level computer system 12 and/or the higher-level control device 12 of the vehicle and/or the computer core of the control device 4 of the electronic fuse, which can be identical to the electronic fuse 825, optionally execute a neural network model. The similarity values of the spectral parameter set 1655 and/or further values, such as the current feature vector, optionally form the input values of the neural network model. The output values of the neural network model optionally represent the evaluation result. The higher-level computer system 12 and/or the higher-level control device 12 of the vehicle and/or the computer core of the control device 4 of the electronic fuse, which can be identical to the electronic fuse 825, can also derive the evaluation result from the output values of the neural network model. The higher-level computer system 12 and/or the higher-level control device 12 of the vehicle and/or the computer core of the control device 4 of the electronic fuse, which can be identical to the electronic fuse 825, thus carry out this evaluation 1660, for example by applying a neural network model. The evaluation result 1665 of the evaluation 1660 thus typically depends on output values of the neural network model.

Depending on the evaluation result 1665, the higher-level computer system 12 and/or the higher-level control device 12 of the vehicle and/or the computer core of the control device 4 of the electronic fuse, which can be identical to the electronic fuse 825, interrupt 1670 the current flow 1525 through the line section 1505 to be protected. For this purpose, the higher-level computer system 12 and/or the higher-level control device 12 of the vehicle and/or the computer core of the control device 4 of the electronic fuse, which can be identical to the electronic fuse 825, signal via the data bus 9 to the computer core 2 of the control device 4 of the electronic fuse 825 that the computer core 2 of the control device 4 of the electronic fuse 825 is to open the circuit breaker 17 of the electronic fuse 825 if the evaluation result 1665 of the spectral parameter set 1640 corresponds to or suggests the presence of a short circuit or a plasma discharge 1510, in particular an arc.

The computer core 2 of the control device 4 of the electronic fuse 825 then typically opens the circuit breaker 17 of the electronic fuse 825, which stops the power supply and extinguishes the arc.

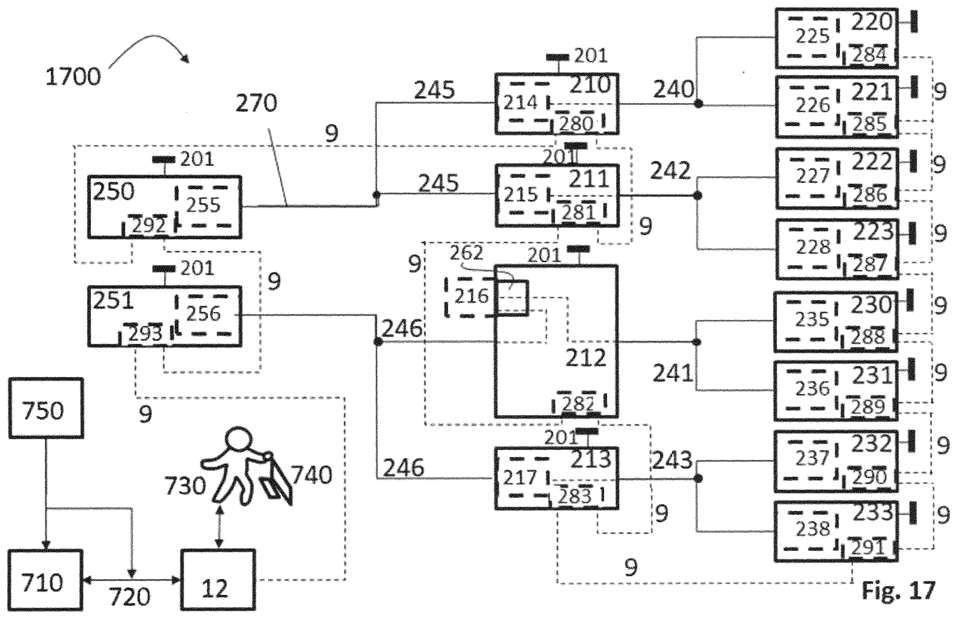

### FIG. 17

FIG. 17 substantially corresponds to FIG. 7, wherein the third supply line section 245 is separated here into the third supply line section 245 and the fourth supply line section 246.

The first power source 250 accordingly supplies the first device part 210 of the supply network 200 and the fifth device part 220 of the supply network 200 and the sixth device part 221 of the supply network 200 with electrical power via the third supply line section 245 and the first device part 210 of the supply network 200 and the downstream first supply line section 240. For example, the first power source 250 can supply a first operating voltage.

The first power source 250 accordingly supplies the second device part 211 of the supply network 200 and the seventh device part 222 of the supply network 200 and the eighth device part 223 of the supply network 200 with electrical power via the third supply line section 245 and the second device part 211 of the supply network 200 and the downstream fifth supply line section 242.

The second power source 251 accordingly supplies the third device part 212 of the supply network 200 and the ninth device part 224 of the supply network 200 and the tenth device part 225 of the supply network 200 with electrical power via the fourth supply line section 246 and the third device part 212 of the supply network 200 and the downstream second supply line section 241. For example, the second power source 251 can supply a second operating voltage. The second operating voltage can deviate from the first operating voltage. In this context, the disclosure refers to the exemplary descriptions relating to the exemplary FIGS. 15 and 16 for detecting an arc between a high-voltage supply network and a low-voltage supply network.

The second power source 251 accordingly supplies the fourth device part 213 of the supply network 200 and the eleventh device part 226 of the supply network 200 and the twelfth device part 226 of the supply network 200 with electrical power via the fourth supply line section 246 and the fourth device part 213 of the supply network 200 and the downstream sixth supply line section 243.

The control devices 4 of the fuses (214 to 217 and 225 to 228 and 235 to 238 and 292 and 293) of the sub-devices (210 to 213 and 220 to 223 and 230 to 233 and 250 and 255) are optionally inserted into the data bus 9 with two data interfaces 10, 610 in each case. In contrast to FIG. 7, however, the data bus 0 is now by way of example not closed in an annular manner. The computer cores 2 of the control devices 4 of the fuses (214 to 217 and 225 to 228 and 235 to 238 and 292 and 293) of the sub-devices (210 to 213 and 220 to 223 and 230 to 233 and 250 and 255) are arranged one behind the other in the data bus 9 corresponding to a daisy chain. This has the advantage that the computer cores 2 of the control devices 4 of the fuses (214 to 217 and 225 to 228 and 235 to 238 and 292 and 293) of the sub-devices (210 to 213 and 220 to 223 and 230 to 233 and 250 and 255) can carry out an auto addressing method after the system start of the supply network 200 or on command of the higher-level computer system 12, which typically functions as a bus master, in order to generate a logic fuse address from its physical position within this data bus chain of the data bus 9.

To assign a fuse address, the higher-level computer system 12 optionally transmits to all computer cores 2 of the control devices 4 of the fuses (214 to 217 and 225 to 228 and 235 to 238 and 292 and 293) of the sub-devices (210 to 213 and 220 to 223 and 230 to 233 and 250 and 255) a data message in the form of a predefined bit stream packet BP, which optionally causes each of the computer cores 2 of the control devices 4 of the fuses (214 to 217 and 225 to 228 and 235 to 238 and 292 and 293) of the sub-devices (210 to 213 and 220 to 223 and 230 to 233 and 250 and 255) to classify its own state as without a valid fuse address.

Optionally, all computer cores 2 of the control devices 4 of all fuses (214 to 217 and 225 to 228 and 235 to 238 and 292 and 293) forward to the sub-devices (210 to 213 and 220 to 223 and 230 to 233 and 250 and 255) such a command as they receive via the data bus interface 10 of the control device 4 of its fuse on the bus master side placed downstream of the data bus, via the second data bus interface 610 placed upstream of the data bus to the computer core 2 of the control device, following upstream of the data bus, of the control device of the fuse, following immediately after in succession upstream of the data bus, of the fuses (214 to 217 and 225 to 228 and 235 to 238 and 292 and 293) to the sub-devices (210 to 213 and 220 to 223 and 230 to 233 and 250 and 255), so that all computer cores 2 of all control devices 4 of all fuses (214 to 217 and 225 to 228 and 235 to 238 and 292 and 293) of the sub-devices (210 to 213 and 220 to 223 and 230 to 233 and 250 and 255) ultimately go into this initial state without a valid fuse address. All circuit breakers 17 of all fuses (214 to 217 and 225 to 228 and 235 to 238 and 292 and 293) of the sub-devices (210 to 213 and 220 to 223 and 230 to 233 and 250 and 255) are optionally open after this initialization, so that no uncontrolled power extraction and/or no uncontrolled power consumption can take place. Particularly optionally, the fuses (214 to 217 and 225 to 228 and 235 to 238 and 292 and 293) of the sub-devices (210 to 213 and 220 to 223 and 230 to 233 and 250 and 255) have an independent power supply via a separate supply voltage line 6 and a reference potential line 201 which can be identical to the body ground, or via a temporary power supply via one power reserve 8 per fuse of the fuses (214 to 217 and 225 to 228 and 235 to 238 and 292 and 293) of the sub-devices (210 to 213 and 220 to 223 and 230 to 233 and 250 and 255), so that the supply network 200 can also carry out the addressing of the logic fuse addresses to the individual fuses (214 to 217 and 225 to 228 and 235 to 238 and 292 and 293) of the sub-devices (210 to 213 and 220 to 223 and 230 to 233 and 250 and 255) without problems, even when the circuit breakers 17 of the fuses (214 to 217 and 225 to 228 and 235 to 238 and 292 and 293) of the sub-devices (210 to 213 and 220 to 223 and 230 to 233 and 250 and 255) are open.

At least, however, the fuse of the fuses (214 to 217 and 225 to 228 and 235 to 238 and 292 and 293) of the sub-devices (210 to 213 and 220 to 223 and 230 to 233 and 250 and 255) which is closest to the higher-level computer system 12 in the data bus 9, has to be supplied with electrical power so that the first step of address assignment of the fuse address to this fuse of the fuses (214 to 217 and 225 to 228 and 235 to 238 and 292 and 293) of the sub-devices (210 to 213 and 220 to 223 and 230 to 233 and 250 and 255) can take place.

In the next step, by means of a special data message in the form of a special bit stream packet BP, the higher-level computer system 12 then assigns, via the data bus 9, a first fuse address to the computer core 2 of the control device 4 of this fuse 256 which is closest to the higher-level computer system 12 in the data bus 9. The computer core 2 of the control device 4 of this fuse 256 then marks its fuse address as a valid fuse address. Optionally, the computer core 2 of the control device 4 of the fuse 256 should then close the circuit breaker 17 of this fuse 256. Thus, the second power source 251 then supplies the third device part 212 and the fourth device part 213 of the supply network with electrical power via the fourth supply line section 246.

Optionally, the computer core 2 of the control device 4 of the fuse 256 then logs into the higher-level computer system 12 with its new valid fuse address. As a result, the higher-level computer system 12 then knows that the computer core 2 of the control device 4 of the nearest fuse 256 has received a valid fuse address.

In the next step, the higher-level computer system 12 assigns a fuse address to the computer core 2 of the control device 4 of the fuses of the fuses (214 to 217 and 225 to 228 and 235 to 238 and 292 and 293) of the sub-devices (210 to 213 and 220 to 223 and 230 to 233 and 250 and 255) which is closest to the higher-level computer system 12 in the data bus 9 and of which the computer core 2 of its control device 4 of this fuse does not yet have a valid fuse address. In the next step, the higher-level computer system 12 transmits a new special data message for this purpose in the form of a special bit stream packet BP via the data bus 9. The computer cores 2 of the control devices 4 of those fuses of the fuses (214 to 217 and 225 to 228 and 235 to 238 and 292 and 293) of the sub-devices (210 to 213 and 220 to 223 and 230 to 233 and 250 and 255) which already have received a valid fuse address from the higher-level computer system 12 receive this data message of the higher-level computer system 10 via its first data interface 10 and ignore the content of this data message of the higher-level computer system 12 and optionally forward this data message via its second data bus interface 610 upstream of the data bus to the next computer core 2 in succession of the control device 4 of the fuse next in succession in the data bus 9 of the fuses (214 to 217 and 225 to 228 and 235 to 238 and 292 and 293) of the sub-devices (210 to 213 and 220 to 223 and 230 to 233 and 250 and 255).

If now the computer core 2 of a control device 4 of a fuse of the fuses (214 to 217 and 225 to 228 and 235 to 238 and 292 and 293) of the sub-devices (210 to 213 and 220 to 223 and 230 to 233 and 250 and 255) receives such a data message and still does not have a valid fuse address, the computer core 2 of the control device 4 of this fuse of the fuses (214 to 217 and 225 to 228 and 235 to 238 and 292 and 293) of the sub-devices (210 to 213 and 220 to 223 and 230 to 233 and 250 and 255) generates a fuse address using information contents of the received data message, which fuse address then is the valid fuse address of the computer core 2 of the control device 4 of this fuse of the fuses (214 to 217 and 225 to 228 and 235 to 238 and 292 and 293) of the sub-devices (210 to 213 and 220 to 223 and 230 to 233 and 250 and 255). The computer core 2 of the control device of this fuse then stores information that its fuse address is a valid fuse address, whereby the computer core 4 of the control device 4 of this fuse then has a valid fuse address. The computer core 2 of the control device 4 of this fuse 256 thus marks its fuse address as a valid fuse address. Optionally, the computer core 2 of the control device 4 of this fuse 256 should then close the circuit breaker 17 of this fuse 256. Thus, the power source upstream in the supply network of this fuse then supplies the downstream device parts of the downstream supply sub-network of the supply network 200 with electrical power via the downstream supply sub-network. Optionally, the computer core 2 of the control device 4 of this fuse just being addressed then signals to the higher-level computer system 12 with its new valid fuse address. As a result, the higher-level computer system 12 then knows that the computer core 2 of the control device 4 of this fuse just being addressed has likewise received a valid fuse address. This newly addressed fuse then behaves in the following like the other fuses of which the computer cores 2 of these control devices of these fuses have already received a valid fuse address.

The higher-level computer system 12 continues this process until all computer cores 2 of all control devices 4 of all fuses of the fuses (214 to 217 and 225 to 228 and 235 to 238 and 292 and 293) of the sub-devices (210 to 213 and 220 to 223 and 230 to 233 and 250 and 255) have received a valid fuse address.

The computer cores 2 of the control devices 4 of the fuses can optionally provide information about the device parts 210 to 213 and 220 to 223 and 230 to 233 and 255 and 260). Such information is optionally found in the non-volatile memories of the control devices 4 of these fuses (214 to 217 and 225 to 228 and 235 to 238 and 292 and 293) of the sub-devices (210 to 213 and 220 to 223 and 230 to 233 and 250 and 255). The computer cores 2 of the control devices 4 of these fuses (214 to 217 and 225 to 228 and 235 to 238 and 292 and 293) of the sub-devices (210 to 213 and 220 to 223 and 230 to 233 and 250 and 255) can provide this information together with their fuse addresses to the higher-level computer system 12 in the data bus 9. The higher-level computer system 12 can then check whether the arrangement and configuration of the fuses (214 to 217 and 225 to 228 and 235 to 238 and 292 and 293) of the sub-devices (210 to 213 and 220 to 223 and 230 to 233 and 250 and 255) and the device parts (210 to 213 and 220 to 223 and 230 to 233 and 250 and 251) correspond to an expected arrangement and/or an arrangement by a server 710 of a service provider and/or automobile manufacturer. If this is not the case, the higher-level computer system 12 can, for example, first transmit a corresponding message via an encrypted data line 720, for example to the server 710 of the service provider, and/or initiate a display on a user input device 740 and/or make an entry in a non-volatile memory of the higher-level computer system 12 for later retrieval in a repair shop and/or reopen individual circuit breakers 17 of individual fuses of the fuses (214 to 217 and 225 to 228 and 235 to 238 and 292 and 293) of the sub-devices (210 to 213 and 220 to 223 and 230 to 233 and 250 and 255) in the supply network 200 and/or change operating parameters before device parts in the supply network 200.

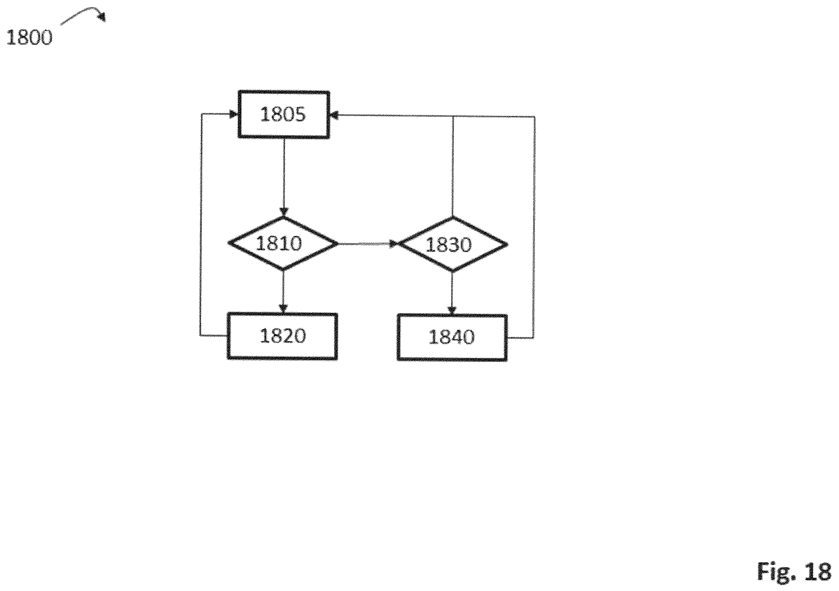

### FIG. 18

FIG. 18 shows in schematically simplified form an exemplary method 1800 for operating a supply network 1700 of FIG. 17.

In the two following sections, the disclosure describes a first method in which the fuse 255 of a power source 250 carries out the balancing of the supply network 1700. In a second section, the disclosure describes a second possible method 1800 corresponding to the aforementioned method, in which the fuses 214, 215 of downstream device parts 210, 211 carry out the balancing of the supply network 1700 in the vehicle.

The supply network 1700 has line sections 245 and power-consuming device parts 210, 211 of the supply network 1700 which supply electrical power to the supply network 1700 via a line section 245. The supply network 1700 furthermore comprises power-supplying device parts 250 of the vehicle which feed power into the supply network 1700. The supply network 1700 supplies power-consuming device parts 210, 211 of the supply network 1700 of the vehicle via at least one line section 245 with electrical power from the supply network 1700. Power-consuming device parts 210 can in turn supply a further device part 220 of the vehicle with electrical power via a further line section 240. The power-consuming device parts 210 each optionally have an electronic fuse 214. The electronic fuse 255 of a device part 250 can prevent the supply of power to this power-consuming device part 210 and to the further device parts 220, 221 supplied with electrical power by this power-consuming device part 210. This can be done in such a way that the computer core 2 of the control device 4 of this fuse 255 of this device parts 250 opens the circuit breaker 17 of this fuse 255 in order to prevent the supply of power to this power-consuming device part 210 and the further device parts 220, 221 supplied with electrical power by this power-consuming device part 210. The method described here in the disclosure then comprises the steps of:

Step 1: The higher-level computer system 12 and/or a computer core 2 of a control device 4 of a fuse of the fuses (214 to 217 and 225 to 228 and 235 to 238 and 255 and 260) monitors the total power requirement of device parts (210, 211, 220, 221, 222, 223) of the device parts of the vehicle.

For this purpose, the higher-level computer system 12 and/or the computer core 2 of the control device 4 of that fuse of the fuses (214 to 217 and 225 to 228 and 235 to 238 and 255 and 260) detects 1805 the corresponding expected current and/or future power requirements of these device parts (210, 211, 220, 221, 222, 223) by querying in computer cores 2 of the control devices 4 of the fuses of these device parts (210, 211, 220, 221, 222, 223) and/or in other computer cores of these device parts (210, 211, 220, 221, 222, 223) which are connected to the data bus 9. Optionally, from the responses of the computer cores 2 of the control devices 4 of the fuses of these device parts (210, 211, 220, 221, 222, 223) and/or from the responses of the other computer cores of these device parts (210, 211, 220, 221, 222, 223), which are connected to the data bus 9, the higher-level computer system 12 and/or the computer core 2 of the control device 4 of that fuse of the fuses (214 to 217 and 225 to 228 and 235 to 238 and 255 and 260) determines the corresponding expected, current and/or future total power requirement of these device parts (210, 211, 220, 221, 222, 223).

Optionally, the higher-level computer system 12 and/or the computer core 2 of the control device 4 of each fuse of the fuses (214 to 217 and 225 to 228 and 235 to 238 and 255 and 260) compares the overall power requirement thus determined of these device parts (210, 211, 220, 221, 222, 223) of the vehicle to an upper power consumption threshold value.

The supply network 1700 can react to an exceeding of the upper power consumption threshold value in two different ways. First, the supply network 1700 can increase the supplied and/or generated power and/or, secondly, reduce the power requirement of the loads in the supply network 1700.

If the determined total power requirement is above the upper power consumption threshold value, the higher-level computer system 12 and/or the computer core 2 of the control device 4 of that fuse of the fuses (214 to 217 and 225 to 228 and 235 to 238 and 255 and 260) can prevent 1820 the supply of electrical power to a first power-consuming device part 210 and/or the further device parts 220, 221 supplied with electrical power by this first device part 210. If the determined total power requirement is above the upper power consumption threshold value, the higher-level computer system 12 and/or the computer core 2 of the control device 4 of that fuse of the fuses (214 to 217 and 225 to 228 and 235 to 238 and 255 and 260) can increase 1820 the power supply capacity of a power source 250, if possible, for example by reparametrizing the power source 250.

The higher-level computer system 12 and/or the computer core 2 of the control device 4 of that fuse of the fuses (214 to 217 and 225 to 228 and 235 to 238 and 255 and 260) can adopt these measures if the determined total power requirement of all device parts (210, 211, 220, 221, 222, 223) is or could be above the upper power consumption threshold value or the operating state and/or the driving situation allows this to be expected, particularly in the future.

The higher-level computer system 12 and/or the computer core 2 of the control device 4 of that fuse of the fuses (214 to 217 and 225 to 228 and 235 to 238 and 255 and 260) can prevent 1820 the supply of electrical power to a first power-consuming device part 210 and/or the further device parts 220, 221 supplied with electrical power by this first device part 210 by causing the computer core 2 of the control device 4 of this fuse 255 to open the circuit breaker 17 of this fuse 255 of the relevant device part 250 by means of a data message via the data bus to a computer core 2 of a control device 4 of a fuse 255.

The higher-level computer system 12 and/or the computer core 2 of the control device 4 of that fuse of the fuses (214 to 217 and 225 to 228 and 235 to 238 and 255 and 260) can also compare 1830 the determined total power requirement of these device parts (210, 211, 220, 221, 222, 223) of the vehicle to a lower power consumption threshold value.

As before, the supply network can react to falling below the lower power consumption threshold value in two different ways. First, the supply network 1700 can reduce the supplied and/or generated power and/or, secondly, increase the power requirement of the loads in the supply network 1700.

If the determined total power requirement is below the lower power consumption threshold value, the higher-level computer system 12 and/or the computer core 2 of the control device 4 of that fuse of the fuses (214 to 217 and 225 to 228 and 235 to 238 and 255 and 260) can enable 1840 the supply of electrical power to a first power-consuming device part 210 and/or to the further device parts 220, 221 supplied with electrical power by this first device part 210. If the determined total power requirement is below the lower power consumption threshold value, the higher-level computer system 12 and/or the computer core 2 of the control device 4 of that fuse of the fuses (214 to 217 and 225 to 228 and 235 to 238 and 255 and 260) can reduce 1840 the power supply capacity of a power source 250, if possible, for example by reparametrizing the power source 250.

The higher-level computer system 12 and/or the computer core 2 of the control device 4 of that fuse of the fuses (214 to 217 and 225 to 228 and 235 to 238 and 255 and 260) can adopt these measures if the determined total power requirement of all device parts (210, 211, 220, 221, 222, 223) is or could be below the lower power consumption threshold value or the operating state and/or the driving situation allows this to be expected, particularly in the future.

The higher-level computer system 12 and/or the computer core 2 of the control device 4 of that fuse of the fuses (214 to 217 and 225 to 228 and 235 to 238 and 255 and 260) can enable 1840 the supply of electrical power to a first power-consuming device part 210 and/or the further device parts 220, 221 supplied with electrical power by this first device part 210 by causing a computer core 2 of a control device 4 of a fuse 255 to close the circuit breaker 17 of this fuse 255 of the relevant device part 250 by means of a data message via the data bus to the computer core 2 of the control device 4 of this fuse 255.

Optionally, the supply of power to the device parts 220, 221 of the supply network 1700 of the vehicle, the power supply of which is prevented as applicable, has a lower priority than the supply of power to the device parts 222, 223 of the supply network 1700 of the vehicle, the power supply of which is not prevented as applicable.

Optionally, the supply of power to the device parts 222, 223 of the supply network 1700 of the vehicle, the power supply of which is enhanced as applicable, has a higher priority than the supply of power to the device parts 220, 221 of the supply network 1700 of the vehicle, the power supply of which is not enhanced as applicable.

In the preceding section, the disclosure describes a method in which the fuse 255 of a power source 250 carries out the balancing of the supply network 1700. The above method corresponds to a possible method 1800 in which the fuses 214, 215 of downstream device parts 210, 211 carry out the balancing of the supply network 1700 in the vehicle.

As before, this second method 1800 for balancing a supply network 1700 of a vehicle is in turn, as before, a method 1800 for operating a supply network 1700. For this second method 1800, the supply network 1700 in turn has line sections 245, 240, 241. The supply network 1700 in turn comprises power-consuming device parts 210, 211 of the supply network 1700, which supply electrical power to the supply network 1700 via a line section 245. The supply network 1700 in turn furthermore comprises power-supplying device parts 250 of the vehicle that feed power into the supply network 1700. The supply network 1700 supplies power-consuming device parts 210, 211 of the vehicle via at least one line section 245 with electrical power from the supply network 1700. As before, power-consuming device parts 210, 211 can in turn supply electrical power to a further device part 220, 221, 222, 223 of the vehicle via a further line section 240, 241. These power-consuming device parts 210, 211 each have an electronic fuse 214, 215, which is optionally connected to the data bus 9. The electronic fuse 255 of a device part 250 can now optionally prevent the supply of power to this power-consuming device part 210, 211 and the further device parts 220, 221, 222, 223 supplied with electrical power by this device part 210, 211. The proposed second method then comprises the following steps:

The higher-level computer system 12 and/or the computer core 2 of the control device 4 of that fuse of the fuses (214 to 217 and 225 to 228 and 235 to 238 and 255 and 260) monitor the total power requirement of device parts (210, 211, 220, 221, 222, 223) of the device parts of the vehicle. For this purpose, the higher-level computer system 12 and/or the computer core 2 of the control device 4 of that fuse of the fuses (214 to 217 and 225 to 228 and 235 to 238 and 255 and 260) detect 1805 via the data bus 9 the power requirement of these device parts (210, 211, 220, 221, 222, 223) by querying in the computer cores 2 of the control devices 4 of the fuses (214 to 217 and 225 to 228 and 235 to 238 and 255 and 260) of these device parts and/or by querying in other computer cores connected to the data bus 9. The higher-level computer system 12 and/or the computer core 2 of the control device 4 of that fuse of the fuses (214 to 217 and 225 to 228 and 235 to 238 and 255 and 260) determine, on the basis of the responses of the computer cores 2 of the control devices 4 of the fuses (214 to 217 and 225 to 228 and 235 to 238 and 255 and 260) of these device parts and/or the responses of the other computer cores connected to the data bus 9, which are received by the higher-level computer system 12 and/or the computer core 2 of the control device 4 of that fuse of the fuses (214 to 217 and 225 to 228 and 235 to 238 and 255 and 260) via the data bus 9, the total power requirement of these device parts (210, 211, 220, 221, 222, 223).

The higher-level computer system 12 and/or the computer core 2 of the control device 4 of that fuse of the fuses (214 to 217 and 225 to 228 and 235 to 238 and 255 and 260) can compare 1810 this determined total power requirement of these device parts (210, 211, 220, 221, 222, 223) of the vehicle to an upper power consumption threshold value.

If the determined total power requirement is above the upper power consumption threshold value, the higher-level computer system 12 and/or the computer core 2 of the control device 4 of that fuse of the fuses (214 to 217 and 225 to 228 and 235 to 238 and 255 and 260) can prevent 1820 the supply of electrical power to a power-consuming device part of these device parts and the further device parts supplied with electrical power by this device part. The higher-level computer system 12 and/or the computer core 2 of the control device 4 of that fuse of the fuses (214 to 217 and 225 to 228 and 235 to 238 and 255 and 260) prevent 1820 this power supply if the total power requirement of all device parts is or could be above the upper power transport threshold for this line section, or the operating state and/or the driving situation causes this to be expected.

The higher-level computer system 12 and/or the computer core 2 of the control device 4 of that fuse of the fuses (214 to 217 and 225 to 228 and 235 to 238 and 255 and 260) can, for example, signal by means of a suitable data message to the computer core 2 of the control device 4 of the fuse 214 of such a device part 210 that the computer core 2 of the control device 4 of this fuse 214 is to set the power supply of the downstream supply sub-network 240, 220, 221 by opening the circuit breaker 17, so that the total power requirement of the supply network 1700 drops by the power requirement of the shed device parts 220, 221.

If the determined total power requirement is above the upper power consumption threshold value, the higher-level computer system 12 and/or the computer core 2 of the control device 4 of that fuse of the fuses (214 to 217 and 225 to 228 and 235 to 238 and 255 and 260) can increase 1820 the supply of power of a power source into the affected supply sub-network of the supply network 1700 and into the further supply sub-networks supplied with electrical power by this device part. The higher-level computer system 12 and/or the computer core 2 of the control device 4 of that fuse of the fuses (214 to 217 and 225 to 228 and 235 to 238 and 255 and 260) increase 1820 this power supply if the total power requirement of all supplied device parts is or could be above the upper power transport threshold for this line section, or the operating state and/or the driving situation causes this to be expected.

The higher-level computer system 12 and/or the computer core 2 of the control device 4 of that fuse of the fuses (214 to 217 and 225 to 228 and 235 to 238 and 255 and 260) can signal, for example by means of a suitable data message to the computer core 2 of the control device 4 of the fuse 214 of such a device part 210, that the computer core 2 of the control device 4 of this fuse 214 is to enable the supply of power to the downstream supply sub-network 240, 220, 221 by closing the circuit breaker 17, so that the power source 250 can cover the total power requirement of the downstream supply sub-network 240, 220, 221.

The higher-level computer system 12 and/or the computer core 2 of the control device 4 of that fuse of the fuses (214 to 217 and 225 to 228 and 235 to 238 and 255 and 260) can then compare 1810 this determined total power requirement of these device parts (210, 211, 220, 221, 222, 223) of the vehicle to a lower power consumption threshold value.

If the determined total power requirement is below the lower power consumption threshold value, the higher-level computer system 12 and/or the computer core 2 of the control device 4 of that fuse of the fuses (214 to 217 and 225 to 228 and 235 to 238 and 255 and 260) can enable 1820 the supply of electrical power to a power-consuming device part of these device parts and the further device parts supplied with electrical power by this device part. The higher-level computer system 12 and/or the computer core 2 of the control device 4 of that fuse of the fuses (214 to 217 and 225 to 228 and 235 to 238 and 255 and 260) enable 1820 this power supply if the total power requirement of all device parts is or could be below the lower power transport threshold for this line section, or the operating state and/or the driving situation causes this to be expected.

The higher-level computer system 12 and/or the computer core 2 of the control device 4 of that fuse of the fuses (214 to 217 and 225 to 228 and 235 to 238 and 255 and 260) can, for example, signal by means of a suitable data message to the computer core 2 of the control device 4 of the fuse 214 of such a device part 210 that the computer core 2 of the control device 4 of this fuse 214 is to enable the power supply of the downstream supply sub-network 240, 220, 221 by closing the circuit breaker 17, so that the total power requirement of the supply network 1700 increases by the power requirement of the shed device parts 220, 221.

If the determined total power requirement is below the lower power consumption threshold value, the higher-level computer system 12 and/or the computer core 2 of the control device 4 of that fuse of the fuses (214 to 217 and 225 to 228 and 235 to 238 and 255 and 260) can reduce 1820 the supply of power of a power source into the affected supply sub-network of the supply network 1700 and into the further supply sub-networks supplied with electrical power by this device part. The higher-level computer system 12 and/or the computer core 2 of the control device 4 of that fuse of the fuses (214 to 217 and 225 to 228 and 235 to 238 and 255 and 260) reduce 1820 this power supply if the total power requirement of all supplied device parts is or could be below the lower power transport threshold for this line section, or the operating state and/or the driving situation causes this to be expected.

The higher-level computer system 12 and/or the computer core 2 of the control device 4 of that fuse of the fuses (214 to 217 and 225 to 228 and 235 to 238 and 255 and 260) can, for example, signal by means of a suitable data message to the computer core 2 of the control device 4 of the fuse 214 of such a device part 210 that the computer core 2 of the control device 4 of this fuse 214 is intended to prevent the additional supply of power to the downstream supply sub-network 240, 220, 221 by opening the circuit breaker 17, so that the power source 250 can no longer cover the total power requirement of the downstream supply sub-network 240, 220, 221.

Optionally, the power supply of the device parts of the vehicle of which the power supply is prevented has a lower priority than the power supply of the device parts of the vehicle of which the power supply is not prevented.

Optionally, the power supply of the device parts of the vehicle of which the power supply is enabled has a higher priority than the power supply of the device parts of the vehicle of which the power supply is not enabled.

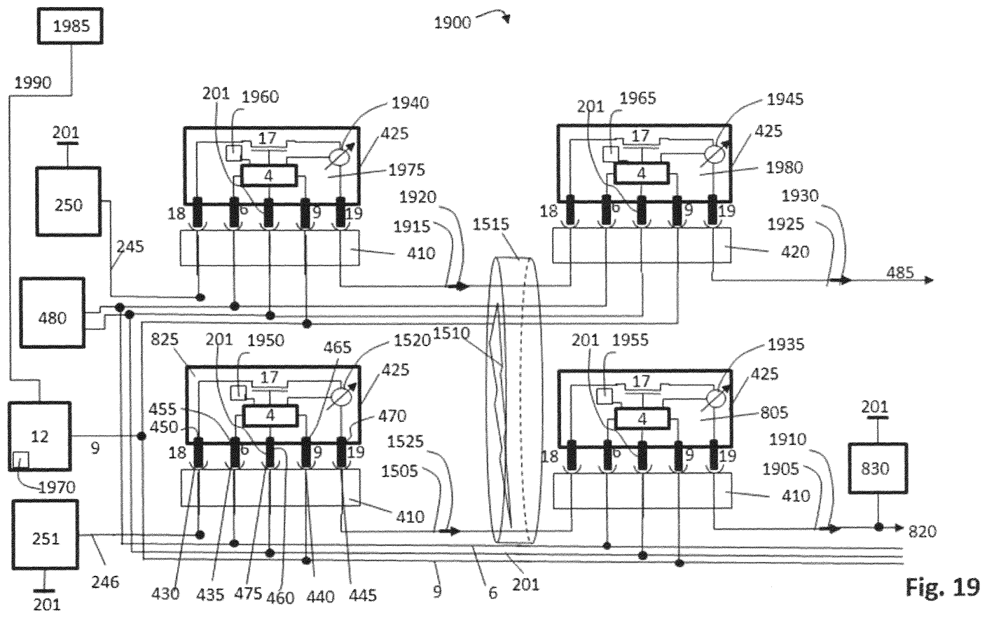

### FIG. 19

FIG. 19 corresponds in substantial parts to FIG. 15 and FIG. 10.

While FIG. 10 shows a fuse box 1000, FIG. 19 shows two lines 1915 and 1505 to be protected, which are parts of a cable harness 1515.

A first power source 250 feeds power into the third supply line section 245.

A third electronic fuse 1975 optionally connects, via its circuit breaker 17, the third supply line section 245 to the third line section 1915 to be protected. By means of the third current measuring device 1940, the computer core 2 of the control device 4 of the third electronic fuse 1975 can detect the value of the third current flow 1920 into a third, upstream line section 1915 to be protected of the cable harness 1515. By means of the third timer 1960 of the third electronic fuse 1975, the computer core 2 of the control device 4 of the third electronic fuse 1975 can assign a time stamp value to each measured value of the third current flow 1910 in the third, upstream line section 1915 to be protected of the cable harness 1515. Optionally, the computer core 2 of the control device 4 of this third electronic fuse 1975 transmits the detected value pairs of time stamp value and measured value of the third current flow 1920 into a third, upstream line section 1915 to be protected of the cable harness 1515 via the data bus 9 to a computer core 2 of a control device 4 of a different fuse in the supply network and/or to a higher-level computer system 12 for consolidation. At the other end of the third line section 1915 to be protected, the circuit breaker 17 of a fourth electronic fuse 1980 connects the third line section 1915 to be protected to a fourth line section 1925 to be protected. By means of the fourth current measuring device 1945, the computer core 2 of the control device 4 of the fourth electronic fuse 1980 can detect the value of the fourth current flow 1925 into a fourth, downstream line section 1925 to be protected. The computer core 2 of the control device 4 of the electronic fuse 1980 can associate a time stamp value with each measured value of the fourth current flow 1930 in the fourth, downstream line section 1925 to be protected by means of the fourth timer 1965 of the fourth electronic fuse 1980. Optionally, the computer core 2 of the control device 4 of this fourth electronic fuse 1980 transmits the detected value pairs of time stamp value and measured value of the fourth current flow 1930 into a fourth, downstream line section 1925 to be protected via the data bus 9 to a computer core 2 of a control device 4 of a different fuse in the supply network and/or to a higher-level computer system 12 for consolidation.

A second power source 251 feeds power into the fourth supply line section 246.

An electronic fuse 825 connects, via its circuit breaker 17, the fourth supply line section 246, as appropriate, to the first line section 1505 to be protected. By means of the first current measuring device 1520, the computer core 2 of the control device 4 of the first electronic fuse 825 can detect the value of the first electrical current flow 1525 into a first, upstream line section 1505 to be protected of the cable harness 1515. By means of the first timer 1950 of the first electronic fuse 825, the computer core 2 of the control device 4 of the first electronic fuse 825 can assign a time stamp value to each measured value of the first current flow 1525 in the first, upstream line section 1505 to be protected of the cable harness 1515. Optionally, the computer core 2 of the control device 4 of this first electronic fuse 825 transmits the detected value pairs of time stamp value and measured value of the first current flow 1525 into a first, upstream line section 1505 to be protected of the cable harness 1515 via the data bus 9 to a computer core 2 of a control device 4 of a different fuse in the supply network and/or to a higher-level computer system 12 for consolidation. At the other end of the first line section 1505 to be protected, the circuit breaker 17 of a second electronic fuse 805 connects the first line section 1505 to be protected to a second, downstream line section 1905 to be protected. By means of the second current measuring device 1935, the computer core 2 of the control device 4 of the second electronic fuse 805 can detect the value of the second current flow 1910 in a second, downstream line section 1905 to be protected. The computer core 2 of the control device 4 of the second electronic fuse 805 can associate a time stamp value with each measured value of the second current flow 1910 in the second, downstream line section 1905 to be protected by means of the second timer 1955 of the second electronic fuse 805. Optionally, the computer core 2 of the control device 4 of this second electronic fuse 805 transmits the detected value pairs of time stamp value and measured value of the second current flow 1910 into a second, downstream line section 1905 to be protected via the data bus 9 to a computer core 2 of a control device 4 of a different fuse in the supply network and/or to a higher-level computer system 12 for consolidation.

The higher-level computer system 12 optionally has a timer 1970 of the higher-level computer system 12. The higher-level computer system 12 optionally synchronizes the timers 1950, 1955, 1960, 1965 of these fuses 805, 825, 1975, 1080 with the timer 1970 of the higher-level computer system 12 by means of a special data message via the data bus 9 to all relevant computer cores 2 of the control devices 4 of the relevant fuses 805, 825, 1975, 1980. The data message optionally in turn has the form of a bit stream packet BP.

The higher-level computer system 12 can optionally be connected to a server 1985, 710 and/or a terminal 740 of a repair shop and/or to the server 710 of an automobile manufacturer and/or a service provider and/or another user 730 of the data determined by the supply network or a higher-level computer system (12). This data connection is optionally established by one or more wired and/or wireless data connections 1990, 740 to a server 1985, 710 of a repair shop and/or of an automobile manufacturer and/or of a service provider. These data connections are optionally encrypted. These data connections are optionally PQC encrypted.

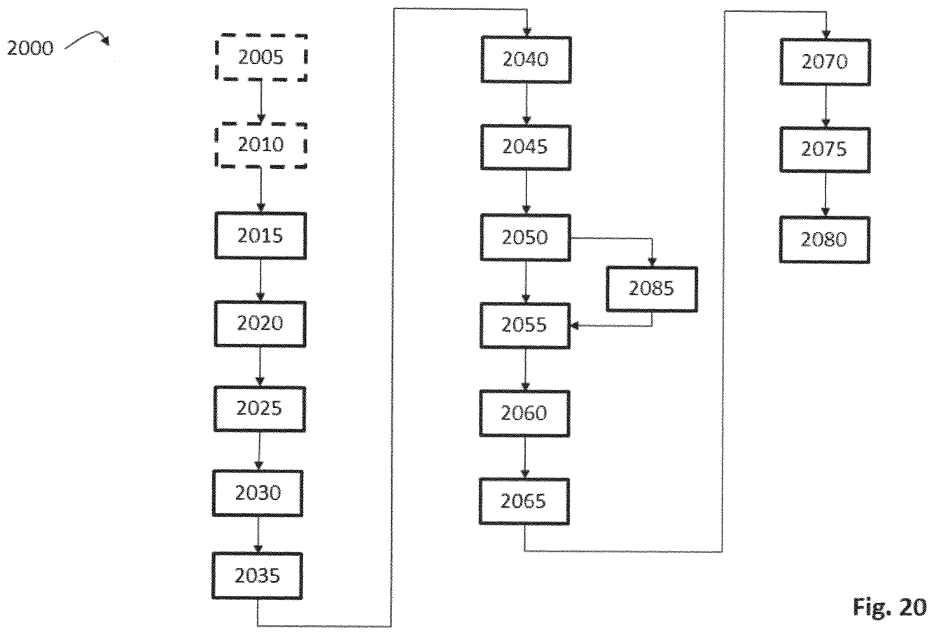

### FIG. 20

Here, the disclosure refers to the description of FIG. 19.

In a schematic and simplified manner, FIG. 20 describes a distributed measurement method 2000 for detecting the state of a cable harness 1515 of a vehicle in accordance with the representation of FIG. 19. The proposed method is carried out, for example, with the following steps:

Optionally, the higher-level computer system 12 or another computer system and/or a computer core 2 of a fuse synchronizes 2005 a first timer 1950 of a first electronic fuse 825 with a time standard, in particular a timer 1970 of a higher-level computer system 12. The timer 35 of a control device 4 of a fuse 1 of the supply network can also serve as a time standard. In the same way, a second timer 1955 of a second electronic fuse 805 is optionally synchronized 2010 with the time standard, in particular the timer 1970 of a higher-level computer system 12.

Optionally, the higher-level computer system 12 and/or a computer core 2 of a control device 4 of one of the fuses 825, 805, 1975, 1980 initiate 2015 the following two detection processes optionally synchronized at equal time values of the first timer 1950 of the first electronic fuse 825 and the second timer 1955 of the second electronic fuse 805. For this purpose, the higher-level computer system 12 and/or a computer core 2 of a control device 4 of one of the fuses 825, 805, 1975, 1980 optionally signal this initiation 2015 via the data bus via the data bus to the computer core 2 of the control device 4 of the first fuse 825 and to the computer core 2 of the control device 4 of the second fuse 825.

The next step is the detection 2020 of a first value of the current flow 1525 into a first line section 1505 to be protected of the cable harness 1515. The computer core 2 of the control device 4 of the first fuse 825 optionally carries out this detection 2020 by means of the first current measuring device 1520 of the first fuse 825. The first current measuring device 1520 of the first fuse 825 optionally comprises the analog-to-digital converter 570 and the auxiliary circuit breaker 23 of the first electronic fuse 825 and the shunt resistor 24 of the first fuse 825. The computer core 2 of the control device 4 of the first fuse 825 optionally detects the first value of the current flow 1525 into a first line section 1505 to be protected of the cable harness 1515 by means of these means (570, 20, 21, 22, 23, 24, 25). The computer core 2 of the control device 4 of the first fuse 825 optionally simultaneously detects the first time stamp value as the instantaneous time value of the first timer 1950 of the first fuse 825 at the instant of detection of the first value of the current flow 1525 into a first line section 1505 to be protected of the cable harness 1515.

The next step is detection 2025 of a second value of the current flow 1920 into a second line section 1905 to be protected. The computer core 2 of the control device 4 of the second fuse 805 optionally carries out this detection 2025 by means of the second current measuring device 1935 of the first fuse 805. The second current measuring device 1935 of the second fuse 805 optionally comprises the analog-to-digital converter 570 and the auxiliary circuit breaker 23 of the second electronic fuse 805 and the shunt resistor 24 of the second fuse 805. The computer core 2 of the control device 4 of the second fuse 805 optionally uses these means (570, 20, 21, 22, 23, 24, 25) to detect the second value of the current flow 1935 into a second line section 1905 to be protected. The computer core 2 of the control device 4 of the second fuse 805 optionally simultaneously detects the second time stamp value as the instantaneous time value of the second timer 1955 of the second fuse 805 at the instant of detection of the second value of the current flow 1910 into a second line section 1905 to be protected.

The computer core 2 of the control device 4 of the first fuse 825 optionally determines 2030 the first time stamp value with the aid of the first timer 1950 of the first electronic fuse 825, for each measured value or for a group of measured values of the first values of the current flow 1525.

The computer core 2 of the control device 4 of the second fuse 805 optionally determines 2035 the second time stamp value with the aid of the second timer 1955 of the second electronic fuse 805, for each measured value or for a group of measured values of the second values of the current flow 1910.

The computer core 2 of the control device 4 of the second fuse 805 optionally transmits 2040 at least the detected second measured value for the second value of the current flow 1910 in the second line section 1905 together with the detected second time stamp value from the second fuse 805 via the data bus 9 to a higher-level computer system 12 and/or to the computer core 2 of the control device 4 of the first electronic fuse 825 and/or to a computer core 2 of a control device 4 of a different fuse of the supply network.

The computer core 2 of the control device 4 of the first fuse 825 optionally transmits 2040 at least the detected first measured value for the first value of the current flow 1505 in the first line section 1505 together with the detected first time stamp value from the first fuse 825 via the data bus 9 to a higher-level computer system 12 and/or to a computer core 2 of a control device 4 of a different fuse of the supply network if the computer core 2 of the control device 4 of the second fuse 805 transmits 2040 at least the detected second measured value for the second value of the current flow 1910 in the second line section 1905 together with the detected second time stamp value from the second fuse 805 to a higher-level computer system 12 and/or to a computer core 2 of a control device 4 of a different fuse of the supply network.

The higher-level computer system 12 and/or the computer core 2 of the control device 4 of the first electronic fuse 825 and/or the computer core 2 of a control device 4 of a different fuse of the supply network compares 2045 the first measured value obtained via the data bus 9 to the second measured value.

The higher-level computer system 12 and/or the computer core 2 of the control device 4 of the first electronic fuse 825 and/or the computer core 2 of a control device 4 of a different fuse of the supply network deduce 2050 a power loss in line sections 1525 between the two electronic fuses 825, 805 if the difference between the first measured value and the second measured value lies outside of a permitted difference value interval and/or if a quotient of the first measured value and the second measured value lies outside of a permitted quotient interval.

In the event of a fault, the higher-level computer system 12 and/or the computer core 2 of the control device 4 of the first electronic fuse 825 and/or the computer core 2 of a control device 4 of a different fuse of the supply network optionally signal such an incident via the data bus 9 to a terminal 740 of a user 730.

As appropriate, the higher-level computer system 12 and/or the computer core 2 of the control device 4 of the first electronic fuse 825 and/or the computer core 2 of a control device 4 of a different fuse of the supply network adopt countermeasures. Such a countermeasure can, for example, be a command via the data bus to the computer core 2 of the control device 4 of the first fuse 825 that the computer core 2 of the control device 4 of the first fuse 825 is to open the circuit breaker 17 of the first fuse 825. The higher-level computer system 12 and/or the computer core 2 of the control device 4 of the first electronic fuse 825 and/or the computer core 2 of a control device 4 of a different fuse of the supply network optionally transmit this command in encrypted form via the data bus 9. The computer core 2 of the control device 4 of the first fuse 825 can then open the first circuit breaker 17 as appropriate. This de-energizes any short circuits of the first supply line section 1505 with other lines and/or device parts of the supply network 200 and thus brings them into a safe state.

A special step, which is possible, is therefore the adoption 2055 of countermeasures, in particular by the higher-level computer system 12 or by the computer core 2 of the evaluating control device 4 of the evaluating electronic fuse 825, if the measured values or the ratio of the measured values to one another or a difference of such measured values or variables derived therefrom do not correspond to one or more expected values and/or are not within an expected value interval.

The data communication between the computer cores 2 of the control devices 4 of the fuses of the supply network and/or with the higher-level computer system 12 is optionally carried out via a fuse data bus 9 and/or an e-fuse data bus 9 and/or a Lin data bus 9 and/or a DSI3 data bus 9 and/or a PSI5 data bus 9 and/or a CAN data bus 9 and/or a CAN-FD data bus 9 and/or an Ethernet data bus 9 and/or a Flexray data bus 9 and/or an LVDS data bus 9 and/or an Ethernet data bus 9 and/or an in some other way wired or wireless data transmission path, for example via a Bluetooth or a WLAN data connection or an optical data connection 540, and/or another wired or wireless interface (610, 10, 551, 550).

Optionally, the higher-level computer system 12 and/or the computer core 2 of the control device 4 of the first electronic fuse 825 and/or the computer core 2 of a control device 4 of a different fuse of the supply network detect changes in the values of the currents (1525, 1910, 1920, 1930) and/or changes in the spectra of the temporal voltage characteristic of the voltages between line sections 1505, 1905, 1915, 1920 to be protected of the cable harness 1515, on the one hand, and a reference potential, on the other hand, and/or changes in the spectra of the current characteristic of the values of the currents 1525, 1910, 1920, 1930, or the power transport via the line sections 1505, 1905, 1915, 1920 to be protected of the cable harness 1515. Optionally, the higher-level computer system 12 and/or the computer core 2 of the control device 4 of the first electronic fuse 825 and/or the computer core 2 of a control device 4 of a different fuse of the supply network evaluate these changes by comparing the changes to expected characteristics and/or expected values.

The higher-level computer system 12 and/or the computer core 2 of the control device 4 of the first electronic fuse 825 and/or the computer core 2 of a control device 4 of a different fuse of the supply network optionally establish 2060 a data connection 1990 to a server 1985 of a repair shop and/or of an automobile manufacturer and/or of a service provider in order to provide the detected values and/or time stamps or data derived therefrom.

The higher-level computer system 12 and/or the computer core 2 of the control device 4 of the first electronic fuse 825 and/or the computer core 2 of a control device 4 of a different fuse of the supply network transmit 2065 optionally vehicle data and/or operating data and/or measured values and/or damage data if the comparison of the detected changes to the expected characteristics and/or expected values resulted in a deviation beyond a predetermined extent.

The higher-level computer system 12 and/or the computer core 2 of the control device 4 of the first electronic fuse 825 and/or the computer core 2 of a control device 4 of a different fuse of the supply network optionally transmit 2065 the vehicle data and/or operating data and/or measured values and/or damage data to a server 1985 or a terminal of the repair shop or of another user of this data.

The higher-level computer system 12 and/or the computer core 2 of the control device 4 of the first electronic fuse 825 and/or the computer core 2 of a control device 4 of a different fuse of the supply network and/or a different computer 1985 optionally create, on the basis of these data, a prediction 2070 of the failure probability of a device part of the vehicle by means of the vehicle data and/or operating data and/or measured values and/or damage data.

The higher-level computer system 12 and/or the computer core 2 of the control device 4 of the first electronic fuse 825 and/or the computer core 2 of a control device 4 of a different fuse of the supply network and/or the other computer 1985 transmit 2075 optionally the prediction result to a server and/or a terminal of the repair shop and/or a terminal 740 and/or a computer of a vehicle owner 730 and/or a terminal 740 and/or a computer of a vehicle driver 730 or a terminal and/or a server 710 of an automobile manufacturer and/or a terminal and/or server of a logistics company and/or a terminal and/or a server of another user of these data.

Optionally, one of the users of these data, in particular a fully automatic or semi-automatic logistics center, provides 2080 a replacement part for the device part of the vehicle when there is a prediction result that a failure of the device part can be expected. In this context, a computer that uses the transmitted data identifies the device part of the vehicle to be replaced. A computer of a semi-automatic or fully automatic warehouse locates the necessary replacement part. A robot and/or a fully automatic or semi-automatic delivery device provides the required replacement part and creates the necessary shipping documents and, as appropriate, packages the replacement part for shipping. Optionally, the robot and/or the fully automatic or semi-automatic delivery device ship the replacement part to an address specified by the vehicle owner 730 or the vehicle driver or an employee of the repair shop. This address should typically be the address of the repair shop in which the precautionary repair is to take place, typically within the scope of regular maintenance.

The higher-level computer system 12 and/or the computer core 2 of the control device 4 of the first electronic fuse 825 and/or the computer core 2 of a control device 4 of a different fuse of the supply network deduce 2085 optionally the temperature of a line section 1915, 1925, 1505, 1905 and/or an overtemperature of a line section 1915, 1925, 1505, 1905 by means of the detected values of the current flow 1920, 1925, 1525, 1910 in a plurality of line sections 1915, 1925, 1505, 1905 to be protected of the cable harness 1515.

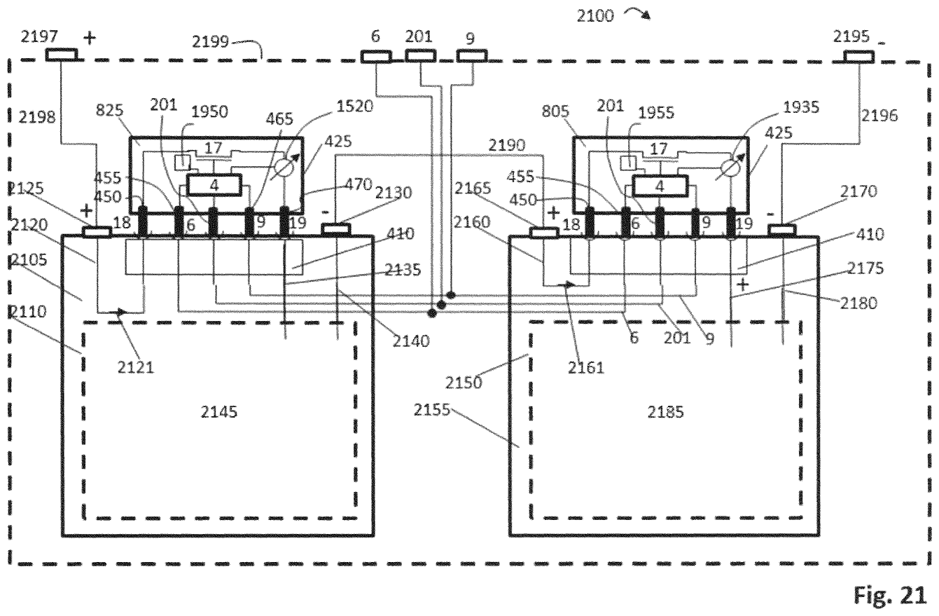

### FIG. 21

FIG. 21 shows in schematically simplified form a proposed battery 2100 with a diagnostic function for a vehicle using supply networks 200 such as the disclosure has already described above. The proposed battery 2100 optionally comprises one or more battery cell modules 2105, 2155 and one or more electronic fuses 825, 805. At least one terminal 2197 of the battery 2100 is optionally connected to the first terminal 26 of the circuit breaker 17 of a first electronic fuse 825. The battery 2100 optionally comprises a supply tree and/or a supply network having one or more supply branches (2198, 2196, 2120, 2135, 2140, 2190, 2160, 2175, 2180, 2196). A plurality of electronic fuses 825, 805 are optionally connected in series into a supply branch (2198, 2196, 2120, 2135, 2140, 2190, 2160, 2175, 2180, 2196) of the supply tree or of the supply network. Such a supply tree or such a supply network can also comprise only one supply branch with a plurality of electronic fuses which are inserted into the supply branch. One or more battery cell modules 2105, 2155 of the battery 2100 are electrically connected in series, for example. One or more electronic fuses 805 are connected between battery cell modules 2105, 2155 of the battery 2100.

Optionally, exactly one electronic fuse 805 is connected between two battery cell modules 2105, 2155, which are interconnected in series.

For each battery cell module 2105, 2155, a corresponding electronic fuse 825, 805 associated with this battery cell module is optionally provided. Each battery cell module 2105, 2155 or, each of one or more groups, in particular battery cell modules 2105, 2155 connected in series, is optionally assigned one electronic fuse 825, 805.

One or more or all of these electronic fuses 825, 805 optionally have a first circuit breaker 17, which is suitable for preventing the current flow 2121, 2161 through one or more battery cell modules 2105, 2155 and/or the relevant group of battery cell modules, i.e., to disconnect the electrical connection 2140, 2190, 2160, 2175 between a first battery cell module 2105 and a second battery cell module 2155 or a first group of battery cell modules and a second group of battery cell modules that are connected in series with one another, if the first circuit breaker 17 is open. One or more or all of these electronic fuses 825, 805 has a first circuit breaker 17 which is suitable for enabling the current flow 2121, 2161 through one or more battery cell modules 2105, 2155 and/or the relevant group of battery cell modules, i.e., the electrical connection (2140, 2190, 2160, 2175) between a first battery cell module 2105 and a second battery cell module 2155 or a first group of battery cell modules and a second group of battery cell modules connected in series with one another, if the first circuit breaker 17 is closed.

FIG. 21 shows a battery 2100 with a diagnostic function for a vehicle. The battery comprises a first battery cell module 2105 and a second battery cell module 2155. The first battery cell module 2105 comprises a first electrochemical cell 2145, the first battery cell of the first battery cell module (2105). The second battery cell module 2155 comprises a second electrochemical cell 2185, the second battery cell of the second battery cell module (2155). The connection 2198 of the first terminal 2197 of the battery 2100 connects the first terminal 2125 of the first battery cell module 2105 to the first terminal 2197 of the battery 2100. The connection 2120 connects the first terminal 2125 to the first terminal 18 of the circuit breaker 17 of the first fuse 825 of the battery 2100. The plug-in connector 410 connects the first fuse 825 to the first battery cell module 2105. The first fuse 825 comprises a computer core 2 and a control device 4 and a timer 1950 and a measuring device 1520 for detecting the electrical current into the first electrochemical cell 2145 of the first battery cell module 2105 or out of it. This current essentially corresponds to the electrical current 2121 in the connection 2120 between the first terminal 2125 and the first terminal 18 of the circuit breaker 17 of the first fuse 825 of the battery 2100. The first terminal 2135 of the first electrochemical cell of the first battery cell 2145 of the first battery cell module 2105 is optionally connected to the second terminal 19 of the first fuse 825. The second terminal 2130 of the first battery cell module 2105 is optionally connected to the second terminal 2140 of the first electrochemical cell of the first battery cell 2145 of the first battery cell module 2105.

The connection 2190 connects the second terminal 2130 of the first battery cell module 2105 to the first terminal 2165 of the second battery cell module 2155. The connection 2160 connects the first terminal 2165 to the first terminal 18 of the circuit breaker 17 of the second fuse 805 of the battery 2100. In the connection 2160, the electrical current 2161 flows in the connection 2160 between the first terminal 2165 and the first terminal 18 of the circuit breaker 17 of the second fuse 805 of the battery 2100.

The connection 2196 connects the second terminal 2195 of the battery 2100 to the second terminal 2170 of the second battery cell module 2155. The second terminal 19 of the second fuse 805 is optionally connected to the first terminal 2175 of the second electrochemical cell of the second battery cell 2184 of the second battery cell module 2155. The second terminal 2180 of the second electrochemical cell of the second battery cell 2185, of the second battery cell module 2155 is optionally connected to the second terminal 2170 of the second battery cell module 2155.

The entire battery 2100 comprises a battery housing 2199.

The data bus 9 is connected to the first electronic fuse 825 via a first plug-in connector 410. The data bus 9 is connected to the second electronic fuse 805 via a second plug-in connector 410. The battery housing 2199 optionally has a terminal for the data bus 9. This terminal for the data bus 9 is optionally connected to the data bus 9 within the battery 210.

The supply voltage line 6 for supplying the first electronic fuse 825 and supplying the second electronic fuse 805 within the battery 2100 is optionally connected to the first electronic fuse 825 via a first plug-in connector 410 and connected to the second electronic fuse 805 via a second plug-in connector 410 in order to supply the corresponding control devices 4 with electrical power there.

The reference potential line 201 for supplying the first electronic fuse 825 and supplying the second electronic fuse 805 within the battery 2100 is optionally connected to the first electronic fuse 825 via a first plug-in connector 410 and connected to the second electronic fuse 805 via a second plug-in connector 410 in order to supply the corresponding control devices 4 with electrical power and a reference potential there.

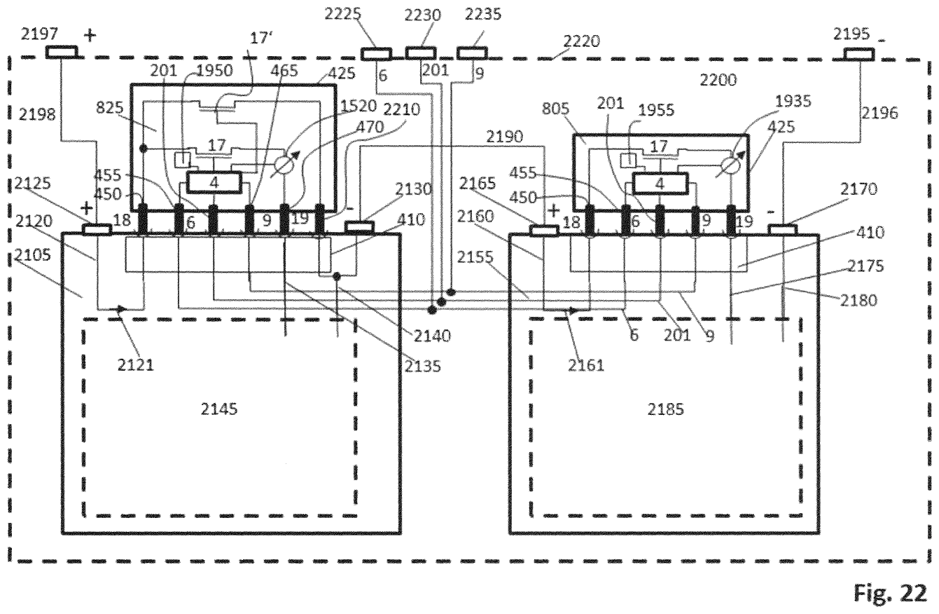

### FIG. 22

FIG. 22 corresponds to FIG. 21 with the difference that the first electronic fuse 825 has an additional contact 2210 in order to have this current bypass the electrochemical battery cell 2145 in the event of an incorrect sign of the current 2121 through the first fuse 825.

For this purpose, the first fuse 825 in the example of FIG. 22 has a second circuit breaker 17′, which is also controlled by the computer core 2 of the control device 4 of the first fuse 825.

Optionally, one or more or all of these electronic fuses 825 of the battery 2200 has such a second circuit breaker 17′, which is suitable for shunting the battery cell module 2105 and/or the group of battery cell modules when the second circuit breaker 17′ is closed.

Optionally, the computer core 2 of the corresponding control device 4 of the corresponding electronic fuse 825 optionally detects the switching state of the first circuit breaker 17 before the second circuit breaker 17′ is closed and whether the first circuit breaker 17 is open. The computer core 2 of the control device 4 of the electronic fuse 825 only closes the second circuit breaker 17′ when the first circuit breaker 17 is open.

The computer core 2 of the control devices 4 of the corresponding electronic fuse causes the feeding of a test current 515 into the first circuit breaker 17 at a connection point 26 upstream of the first circuit breaker 17 and causes the extraction of this test current 915 at a second connection point 28 downstream of the first circuit breaker 17. The computer core 2 of the control device 4 of the corresponding electronic fuse evaluates whether this feeding and extraction were successful.

FIG. 22 thus shows a battery 2200 in which an electronic fuse 825 of the battery 2200 has a second circuit breaker 17′, which is suitable for shunting the battery cell module 2105 associated with the fuse when the second circuit breaker 17′ is closed. The battery 2200 is optionally accommodated in a housing 2220 of the battery 2200 or of the battery cell module. The housing 2220 of the battery 2200 optionally has a terminal 2225 of the battery 2220 of the battery cell module for the operating voltage 6 of the electronic fuses 825, 805 within the battery 2200. The housing 2220 of the battery 2200 optionally has a terminal 2230 of the battery 2200 of the battery cell module for the reference potential node 201 of the electronic fuses 825, 805. The housing 2220 of the battery 2200 optionally has a terminal 2235 of the battery 2200 of the battery cell module for the external data bus 9 of the electronic fuses 825, 805.

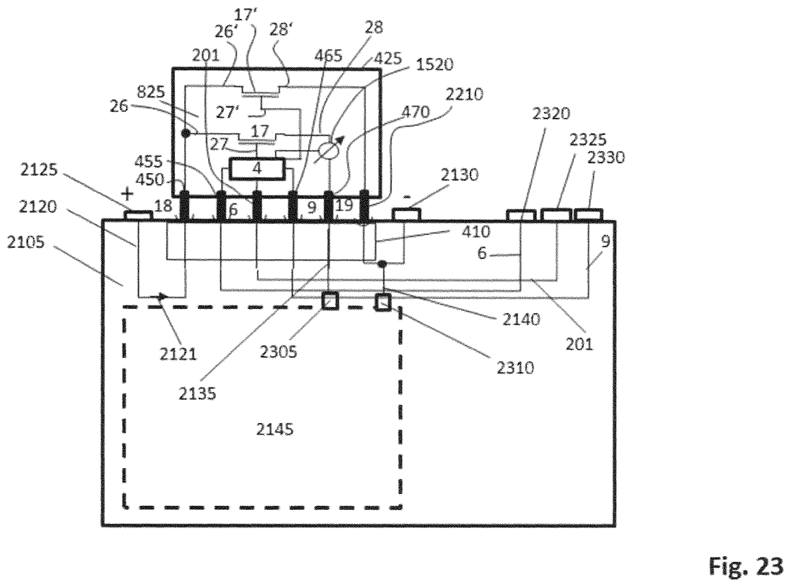

### FIG. 23

FIG. 23 shows a battery cell module 2300, which comprises at least one battery cell 2145 and/or an interconnection of battery cells, a first circuit breaker 17, a second circuit breaker 17′, a first electrical node 2120, a second electrical node 2135, a third electrical node 2140, a first battery cell terminal 2305, and a second battery cell terminal 2310. The first battery cell terminal 2305 is connected, for example, to the second node 2135. The second battery cell terminal 2310 is connected, for example, to the third node 2140. The first circuit breaker 17 has a first terminal 26 and a second terminal 28 and a control terminal 27. The second circuit breaker 17′ has a first terminal 26′ and a second terminal 28′ and a control terminal 27′. The battery cell 2105 and/or the interconnection of battery cells comprise a first terminal 2125 and a second terminal 2130. The first circuit breaker 17 is optionally connected to the first node 2120 at its first terminal 26 of the first circuit breaker 17. The first circuit breaker 17 is optionally connected to the second node 2135 at its second terminal 28 of the first circuit breaker 17. The second circuit breaker 17′ is optionally connected to the first node 2120 at its first terminal 26′ of the second circuit breaker 17′. The second circuit breaker 17′ is optionally connected to the third node 2140 at its second terminal 28′ of the second circuit breaker 17′. A first terminal 2305 of the battery cell 2145 or the group of battery cells is optionally connected to the second node 2135. A second terminal 2310 of the battery cell 2145 or the group of battery cells is optionally connected to the third node 2140. When reference is made here to “connected,” this means that an electrical direct or indirect connection exists via further electrical components which is essentially functionally equivalent to a direct connection.

The battery cell module 2105 optionally comprises a control device 4 of a fuse or is connected to such a control device 4. This control device 4 optionally controls the control terminal 27 of the first circuit breaker 17. A computer core 2 of the control device 4 optionally controls the control terminal 27 of the first circuit breaker 17. Furthermore, the control device 4 optionally controls the control terminal 27′ of the second circuit breaker 17′. The computer core 2 of the control device 4 optionally controls the control terminal 27′ of the second circuit breaker 17′. The control device 4 or the computer core 2 of the control device 4 interlock the control terminal 27 of the first circuit breaker 17 optionally relative to the control terminal 27′ of the second circuit breaker 17′ in terms of shape in such a way that it is ruled out that the first circuit breaker 17 is conductive, i.e., closed, if the second circuit breaker 17′ is conductive, i.e., closed.

The control device 4 optionally comprises means (16, 525, 520, 920, 530, 21, 22, 28, 26, 27, 915, 515, 510, 910, 905 and 16′, 525′, 520′, 920′, 530′, 21′, 22′, 28′, 26′, 27′, 915′, 515′, 510′, 910′, 905′) for detecting the switching state of the circuit breakers 17, 17′. The control device 4 and/or the computer core 2 of the control device optionally detect the switching state of at least one of the circuit breakers 17, 17′, in particular as “on” or “off” or as “closed” or “open” by means of these means (16, 525, 520, 920, 530, 21, 22, 28, 26, 27, 915, 515, 510, 910, 905 and 16′, 525′, 520′, 920′, 530′, 21′, 22′, 28′, 26′, 27′, 915′, 515′, 510′, 910′, 905′).

The control device 4 and/or the computer core 2 of the control device 4 are optionally configured for shunting the battery cell module 2105. For this purpose, the control device 4 and/or the computer core 2 of the control device 4 are optionally configured first to open the first circuit breaker 17 and thus prevent a current flow 2121 through the battery cell 2145 and then, in particular by means of the means (16, 525, 520, 920, 530, 21, 22, 28, 26, 27, 915, 515, 510, 910, 905) for the detection of the switching state of the first circuit breaker 17, to check and to determine whether the first circuit breaker 17 is open, and then, if the second circuit breaker 17′ is open, to close the second circuit breaker 17′ and then, by means of the means (16′, 525′, 520′, 920′, 530′, 21′, 22′, 28′, 26′, 27′, 915′, 515′, 510′, 910′, 905′) for the detection of the switching state of the second circuit breaker 17′, to check whether the second circuit breaker 17′ is closed.

The battery cell module 2200 can itself in some cases comprise, in turn, at least one first battery cell module 2105 as described above and can itself comprise, in turn, at least one second battery cell module 2155, as described above. The second terminal 2130 of the first battery cell module 2105 is optionally connected to the first terminal 2165 of the second battery cell module 2155.

The circuit breaker 17 and the control device 4 of the fuse 825 and the fuse 825 are optionally accommodated within a housing 2605 together with the actual battery cell module 2105.

The control device 4 of the fuse 825 can have an optical data interface 550, 551.

In this case, the housing 2605 optionally has an optical window 545 which allows the entry of electromagnetic radiation 540 for the optical transport of data away from the optical data interface 550, 551 of the control device 4 and toward the optical data interface 550, 551 of the control device 4.

Via the optical interface 550, 551 of the control device 4 within the housing 2605, the computer core 2 of the control device 4 can communicate, for example, with an optical interface 555 of a different device, for example a higher-level computer system 12 outside the housing 2665.

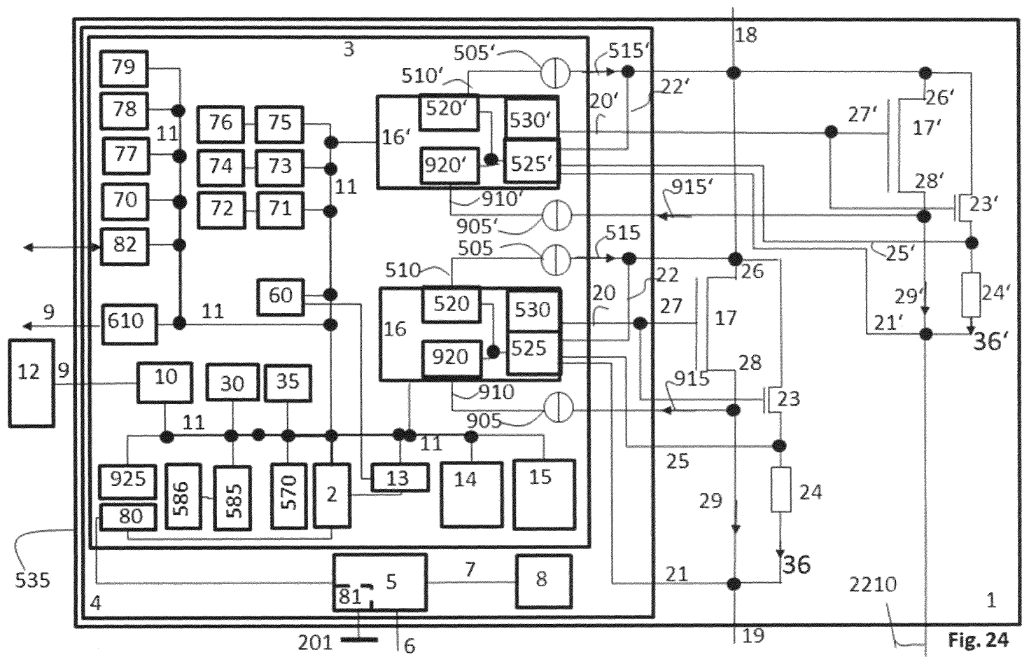

The disclosure thus also describes, among other things, a battery cell module 2300 with a battery cell 2145, a first battery cell terminal 2305, a second battery cell terminal 2310, a terminal 2320 of the battery cell module 2105 for the operating voltage 6 of the electronic fuse 825, a terminal 2325 of the battery cell module 2105 for the reference potential node 201 of the electronic fuse 825, and a terminal 2330 of the battery cell module 2105 for the external data bus 9 of the electronic fuse 825. FIG. 24

FIG. 24 corresponds to FIG. 6, wherein the fuse 1 of FIG. 24 has a second circuit breaker 17′.

In FIG. 24, for better clarity, not all appropriate and in some cases customary device components are shown. Further device components that the reader can assume as possibly present in FIG. 1 can be found, for example, in FIGS. 1, 5, 6, 9, 41, 42, 52, 53, 54, 55, 57, 58 and 62. The combination of the device parts of the Figure described here with those of these figures is expressly part of the disclosure of the disclosure.

Optionally, the control circuit 4 of the fuse 1 additionally has a second gate drive circuit 16′ for controlling and monitoring the second circuit breaker 17′. The first terminal 26′ of the second circuit breaker 17′ is optionally connected to the first terminal 18 of the fuse 1. The second gate drive circuit 16′ for controlling and monitoring the second circuit breaker 17′ controls the second circuit breaker 17′ via the control line 20′ for controlling the second circuit breaker 17′. By means of the monitoring line 21′ for detecting the voltage between the second terminal 19′ of the second circuit breaker 17′ and the control line 20′ of the second circuit breaker 17′ and by means of the monitoring line 22′ for detecting the voltage between the first terminal 18′ of the second circuit breaker 17′ and the control line 20′ of the second circuit breaker 17′ and by means of the measuring line 25′ for detecting the voltage drop across the second shunt resistor 24′, the second gate drive circuit 16′ for controlling and monitoring the second circuit breaker 17′ monitors the second circuit breaker 17′. The fuse 1 of FIG. 24 furthermore comprises a second auxiliary circuit breaker 23′ for detecting a current which is proportional to the current 29′ through the second circuit breaker 17′ or corresponds thereto in another way. The fuse 1 of FIG. 24 furthermore optionally comprises a shunt resistor 24′ for detecting the current through the second auxiliary circuit breaker 23′ of the second circuit breaker 17′. A third test current source 505′ is modulated by means of the second control signal 510′ with a second modulation signal {505′} of a second signal generator 520′. In this case, the curly brackets are supposed to indicate that {505′} is the second modulation signal with which the second current 515′ of the third test current source 505′ is modulated. Optionally, the second modulation signal {505′} is orthogonal to the first modulation signal {505} with respect to the scalar product ({505}1{505′})=∫₀^{T}{505}×{505′}dt. T here is to represent the period of the first modulation signal {505} or of the second modulation signal {505′}, which are optionally the same or an integer multiple of one another. The period T of the first modulation signal {505} is optionally equal to the period T of the second modulation signal {505′}. This enables the two modulation signals to be separated ({505}, {505′}). Optionally, therefore,

$$〈 \{ 505 \} \vert \{ 50 {5}^{′} \} 〉 = {\int }_{0}^{T} \{ 505 \} \times \{ 50 {5}^{′} \} d t = 0 ,$$

which means orthogonality.

The second current 515′ of the third test current source 505′ is optionally modulated with the second modulation signal {505′} by means of the third control signal 510′ of the third electronic test current source 505′. The third test current source 505′ feeds the second additional current 515′ into the second circuit breaker 17. A second signal generator 520′ generates the second modulation signal (505′). A second correlator 525′ optionally comprises one or more input amplifiers which detect, filter, and process the voltages between the second measuring contacts (21′, 25′, 27′, 28′, 22′). The second correlator 525′ optionally comprises, for example, a second synchronous demodulator, which checks one of the measurable voltages for second components of the second modulation signal {505′} of the second current 515′ of the third test current source 505′. Optionally, the second synchronous demodulator of the second correlator 525′ uses a correlation in the form of a scalar product, for example according to the formula:

$${A}^{′} = 〈 \{ {505}^{′} \} \vert {V}_{x y}^{′} ( t ) 〉 = {\int }_{0}^{T} \{ 50 {5}^{′} \} \times {V}_{x y} ( {t}^{′} ) d t$$

A′ here represents the value of the second component, and V′_{xy} represents a voltage between the second measuring contacts (21′, 25′, 27′, 28′, 22). Optionally, the second correlator 525′ uses a voltage V_{xy} between the second terminal 28′ of the second circuit breaker 17′ and the second control terminal 27′ of the second circuit breaker 17′.

A second gate drive 530′ of the control contact 27′ of the second circuit breaker 17′ and second control signal generation for the control signal of the control line 20′ of the second circuit breaker 17′ controls the second circuit breaker 17′.

A first test current source 505′ feeds a test current 515′ into the first terminal 26′ of the second circuit breaker 17′, which is provided with a modulation signal {505′} of a first signal generator 520′ by means of the control signal 510′.

A second test current source 905′ extracts a test current 915′ from the second terminal 28′ of the second circuit breaker 17′, which is provided with a modulation signal {505′} of a second signal generator 920′ by means of the control signal 910′.

A third control signal 510′ controls the third electronic test current source 505′.

A fourth control signal 910′ controls the fourth electronic test current source 905′.

Optionally, the first test current 515′ corresponds to the second test current 915′.

The fourth signal generator 920′ optionally generates the modulation signal {505′}.

In the example of FIG. 24, some modules possible modules of the control device 4 are shown, which, for better clarity, are not shown in the figures. The reader may assume these modules in the figures as possibly present and hereby disclosed.

FIG. 24 shows a diagram of an example of an electronic fuse with a secure control device 4 and a secure computer core 2. The secure control device 4 contains, for example, memory elements which are connected to the internal data bus 11. The memory elements can comprise, for example, one or more read-write memories RAM 14 and/or one or more writable non-volatile memories, such as EEPROM memories 15 and/or flash memories 15 and/or OTP memories 15. Furthermore, the secure control device 4 optionally comprises one or more non-volatile, pure read memories 14, such as a ROM. In addition, the secure control device 4 optionally comprises one or more non-volatile, writable and/or non-writable manufacturer memories. This can be, for example, a manufacturer memory 72 for data of the vehicle manufacturer and/or a supplier-manufacturer memory 74 for data from the automobile supplier and/or a semiconductor-manufacturer manufacturer memory 76 for data of the semiconductor manufacturer. Each of these data memories is optionally protected by a corresponding password. The manufacturer memory 72 is optionally protected by a manufacturer password. The supplier-manufacturer memory 74 is optionally protected by a supplier password. The semiconductor-manufacturer manufacturer memory 76 is optionally protected by a semiconductor-manufacturer password.

The supplier can obtain access to the manufacturer memory 72 by means of a supplier analysis password. With such access of the supplier to the manufacturer memory 72, the content of the manufacturer memory 72 is optionally deleted, so that the supplier cannot obtain any knowledge of the content of the manufacturer memory 72. The passwords of the manufacturer are optionally also deleted.

The semiconductor manufacturer can obtain access to the manufacturer memory 72 and/or the supplier memory 74 by means of a semiconductor-manufacturer analysis password. With such access of the semiconductor manufacturer to the manufacturer memory 72, the content of the manufacturer memory 72 is optionally deleted, so that the semiconductor manufacturer cannot obtain any knowledge of the content of the manufacturer memory 72. With such access of the semiconductor manufacturer to the supplier memory 74, the content of the supplier memory 74 is optionally deleted, so that the semiconductor manufacturer cannot obtain any knowledge of the content of the supplier memory 72. The passwords of the manufacturer or the supplier are optionally also deleted.

In the case of a non-writable manufacturer memory 72 or a non-writable supplier memory or a non-writable semiconductor manufacturer memory 76, these memories can each be a corresponding manufacturer ROM. The access to the manufacturer memory 72 is via one or more manufacturer memory firewalls 71, optionally implemented in hardware.

For access, the computer core 2 stores the manufacturer password via the internal data bus 11 in a register of the manufacturer memory firewall 71. The manufacturer memory firewall 71 checks the content of the register and enables access to the registers of the manufacturer memory firewall 71 and access to the manufacturer memory 72 for the computer core 2, if the manufacturer password corresponds to the content in a manufacturer password specification register of the manufacturer memory firewall 71 in a predetermined manner. The computer core 2 can then access the manufacturer memory 72 and the manufacturer password specification register of the manufacturer memory firewall 71.

The access to the supplier memory 74 optionally takes place via one or more supplier memory firewalls 73, optionally implemented in hardware. For access, the computer core 2 stores the supplier password via the internal data bus 11 in a register of the supplier memory firewall 73. The supplier memory firewall 73 checks the content of the register and enables access to the registers of the supplier memory firewall 73 and access to the supplier memory 74 for the computer core 2 if the supplier password corresponds to the content in a supplier password specification register of the supplier memory firewall 73 in a predetermined manner. The computer core 2 can then access the supplier memory 74 and the supplier password specification register of the supplier memory firewall 73.

The access to the semiconductor manufacturer memory 76 optionally takes place via one or more semiconductor manufacturer memory firewalls 75, optionally implemented in hardware. For access, the computer core 2 stores the semiconductor manufacturer password via the internal data bus 11 in a register of the semiconductor manufacturer memory firewall 75. The semiconductor manufacturer memory firewall 75 checks the content of the register and enables access to the registers of the semiconductor manufacturer memory firewall 75 and access to the semiconductor manufacturer memory 76 for the computer core 2, if the semiconductor manufacturer password corresponds to the content in a semiconductor manufacturer password specification register of the semiconductor manufacturer memory firewall 75 in a predetermined manner. The computer core 2 can then access the semiconductor manufacturer memory 76 and the semiconductor manufacturer password specification register of the semiconductor manufacturer memory firewall 75.

The manufacturer memory firewall 71 optionally encrypts the data of the computer core 2 before storage in the manufacturer memory 72 by means of a PQC-enabled encryption method and/or using a quantum random number of the quantum random number generator 60.

Optionally, the supplier memory firewall 73 encrypts the data of the computer core 2 before storage in the supplier memory 74 by means of a PQC-enabled encryption method and/or using a quantum random number of the quantum random number generator 60.

Optionally, the semiconductor manufacturer memory firewall 75 encrypts the data of the computer core 2 before storage in the semiconductor manufacturer memory 76 by means of a PQC-enabled encryption method and/or using a quantum random number of the quantum random number generator 60.

A manufacturer ROM 72, 74, 76 optionally comprises the corresponding boot software. The secure control device 4 comprises, for example, one or more cryptography accelerators 70, for example a DES accelerator and/or an AES accelerator 70, which is connected to the internal data bus 11. For example, one or more manufacturer memory firewalls 71, 73, 75 is optionally provided between the corresponding manufacturer memory 72, 74, 76 and the internal data bus 11. The computer core 2 accesses these memories 72, 74, 76 via the data bus 11. The secure control device 4 comprises, for example, processing modules which communicate with the computer core 2 via the internal data bus 11. The processing modules of the control device 4 of the fuse 1 optionally comprise one or more of the following modules: a CRC module (cyclic redundancy check) 77, an oscillator and clock-pulse generator module 30, one or more timer modules 78, a safety monitoring circuit and safety control circuit 79, one or more quantum-process-based generators for true random numbers (quantum random number generator: QRNG) 60, a 8/16/32/15-bit microcontroller core as computer core 2, and one or more data interfaces 82, in particular one or more universal asynchronous receiver-transmitters (UART) for supporting serial high-speed data and/or one or more so-called general purpose IOs (GPIO). The further circuit parts of the secure control device 4 include, for example, one or more base clock-pulse generators 30 (CLK) and/or one or more clock-pulse generator modules 30, a reset circuit 80, a power supply or VCC circuit 5 with voltage controllers, which provide the operating voltage, a ground circuit 81, which compensates for faults in the ground line, and an input/output circuit 82.

The secure control device 4 is optionally configured to enable secure authentication. This relates first of all to the authentication of the control device 4 to other computers. These other computers can be, for example, the higher-level control device 12 and also servers 710 of service providers and/or servers 710 of automobile manufacturers and/or terminals 740, for example smartphones. This first relates to the authentication of such other computers to the control device 4 of the fuse 1. These other computers can be, for example, the higher-level control device 12 and also servers 710 of service providers and/or servers 710 of automobile manufacturers and/or terminals 740, for example smartphones. However, this also relates to the authentication of a user 730 to the control device 4 of the fuse 1, for example by means of data inputs on an authenticated terminal and/or by means of detection of biometric data of the user 730 by means of biometric sensors of the terminal 740. The secure control device 4 therefore stores, in addition to the authentication code, further data, for example one or more service life and usage data and/or, for example, logistical data and/or, for example, commercial data and/or websites and email addresses and/or image data, a set of instructions for controllers of the vehicle and/or of the higher-level computer system 12 with which the computer core 2 of the control device 4 communicates via a data interface 10. In addition, the secure control device 4 can store further application data.

By way of example, the control device 4 of FIG. 24 comprises one or more cryptography accelerators 70, for example a DES accelerator and/or an AES accelerator 70.

Optionally, a monolithically integrated circuit comprises, for example, the secure control device 4, which is optionally configured such that it facilitates the secure authentication and verification of a product, of a user, and/or of other computers and use situations. The integrated circuit optionally also comprises the shunt resistors 24 and 24′. Optionally, the integrated circuit is manufactured on or in a first semiconductor substrate optionally in CMOS technology.

The first auxiliary circuit breaker 23 is optionally manufactured monolithically on or in a common second substrate with the first circuit breaker 17.

The second auxiliary circuit breaker 23′ is optionally manufactured monolithically on or in a common third substrate with the second circuit breaker 17′.

The second substrate and the third substrate optionally form a common second substrate.

Optionally, the first substrate and the second substrate and—if not part of the second substrate—the third substrate are accommodated in a common housing 535.

Optionally, the housing 535 has a second metallic mounting surface, a so-called land, for mounting the second substrate by means of adhesive or solder on the surface of this second mounting surface and, in some cases, a third metallic mounting surface, a so-called land, for mounting the third substrate by means of adhesive or solder on the surface of this third mounting surface. Optionally, the underside of the second mounting surface is not covered by the material of the housing 535. The underside of the second mounting surface is thus optionally part of the surface of the underside of the housing 535. If the solder or the adhesive with which the underside of the second substrate is fastened to the first circuit breaker 17 and, where applicable, to the second circuit breaker 17′ on the surface of the top side of the second mounting surface is electrically conductive, the second substrate can be contacted electrically and thermally via the underside of this second mounting surface as a so-called exposed die pad, so that the first circuit breaker 17 and, where applicable, the second circuit breaker 17′ can be cooled particularly well and can be designed smaller and switch more quickly. This is thus an important prerequisite in order to be able to switch off particularly quickly in the event of a short circuit, as mentioned elsewhere in this document.

Optionally, the housing 535 has a third metal mounting surface, a so-called land for mounting the possibly present third substrate by means of adhesive or solder on the surface of this third mounting surface. Optionally, the underside of the third mounting surface is not covered by the material of the housing 535. The underside of the third mounting surface is thus optionally part of the surface of the underside of the housing 535. If the solder or the adhesive with which the underside of the present third substrate, if present, is fastened to the second circuit breaker 17′ on the surface of the top side of the third mounting surface is electrically conductive, the third substrate can be electrically and thermally contacted via the underside of this third mounting surface as a so-called exposed die pad, so that the second circuit breaker 17′ is cooled particularly well and can be designed smaller and switches more quickly. This is thus an important prerequisite in order to be able to switch off particularly quickly in the event of a short circuit, as mentioned elsewhere in this document.

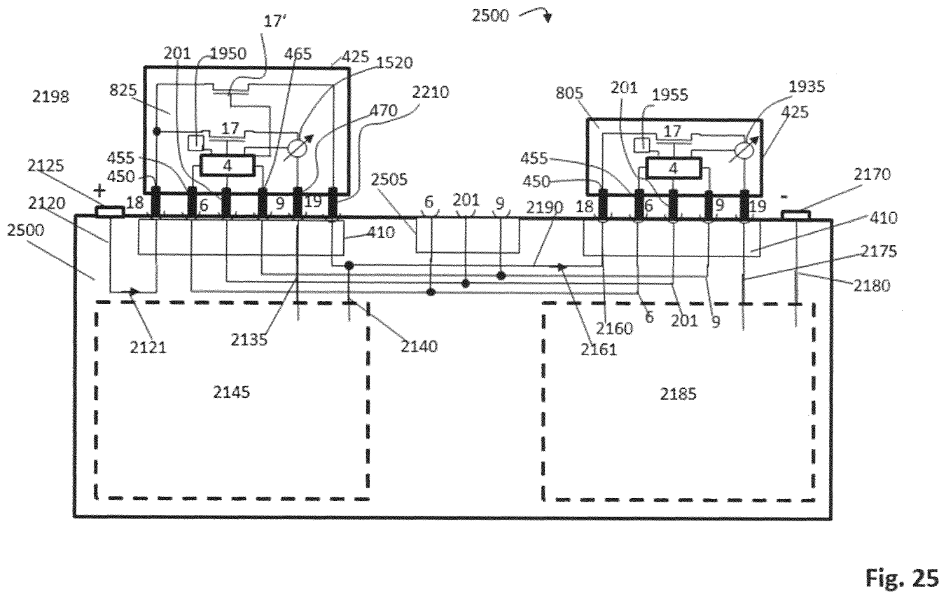

### FIG. 25

FIG. 25 corresponds to the battery of FIG. 22, wherein FIG. 25 shows a battery cell module 2500 comprising a plurality of battery cells 2145, 2185. Within the meaning of the disclosure, the battery cell module 2500 corresponds to the battery cell module 2105 of FIG. 21.

An exemplary plug-in connector 2505 has a first contact 6 for the operating voltage terminal 6 of the electronic fuses 825, 805. The plug-in connector 2505 furthermore has a second contact 201 for the reference potential terminal 201 of the electronic fuses 805, 815. The plug-in connector has a third contact 9 for the external data bus 9 of the electronic fuses 805, 815.

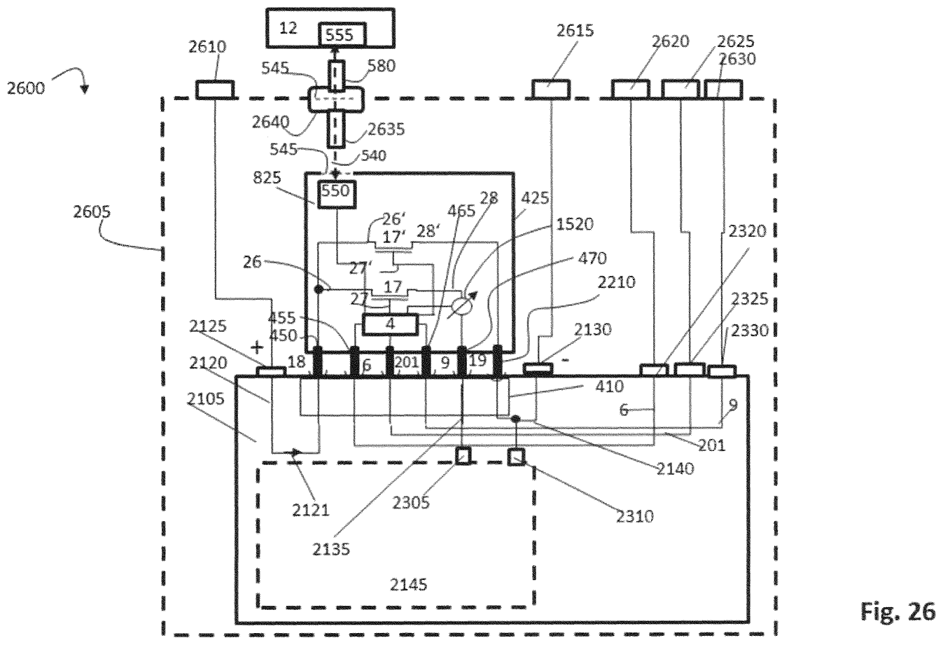

### FIG. 26

FIG. 26 shows a housed battery cell module 2600 having a common housing 2605 of the battery cell module 2600 for an electronic fuse 825 and an inner battery cell module 2105. By means of an optical plug system 2640 for the pluggable optical connection between the external optical waveguide 580 outside the housing 2605 and the optical waveguide 2635 within the housing 2605, the optical data interface 550 of the electronic fuse 825 can exchange data and commands with an optical interface 555 of a higher-level computer system 12 via an optical window 545. Optionally, the fuse housing 425 also has an optical window 545.

The proposed battery cell module 2600 comprises an exemplary optical waveguide 2635 within the housing 2605 of the battery cell module 2600.

The first terminal 2610 of the battery cell module 2600 is optionally connected to the first terminal 2125 of the inner battery cell module 2105 within the housing 2605 of the battery cell module 2600.

The second terminal 2615 of the battery cell module 2600 is optionally connected to the second terminal 2130 of the inner battery cell module 2105 within the housing 2605 of the battery cell module 2600.

The battery cell module 2600 optionally comprises a terminal 2620 of the battery cell module 2600 for the operating voltage 6 of the electronic fuse 825 of the inner battery cell module 2105.

The battery cell module 2600 optionally comprises a terminal 2625 of the battery cell module 2600 for the reference potential node 201 of the electronic fuse 825 of the internal battery cell module 2105.

The battery cell module 2600 optionally comprises a terminal 2630 of the battery cell module 2600 for the external data bus 9 of the electronic fuse 825 of the inner battery cell module 2105.

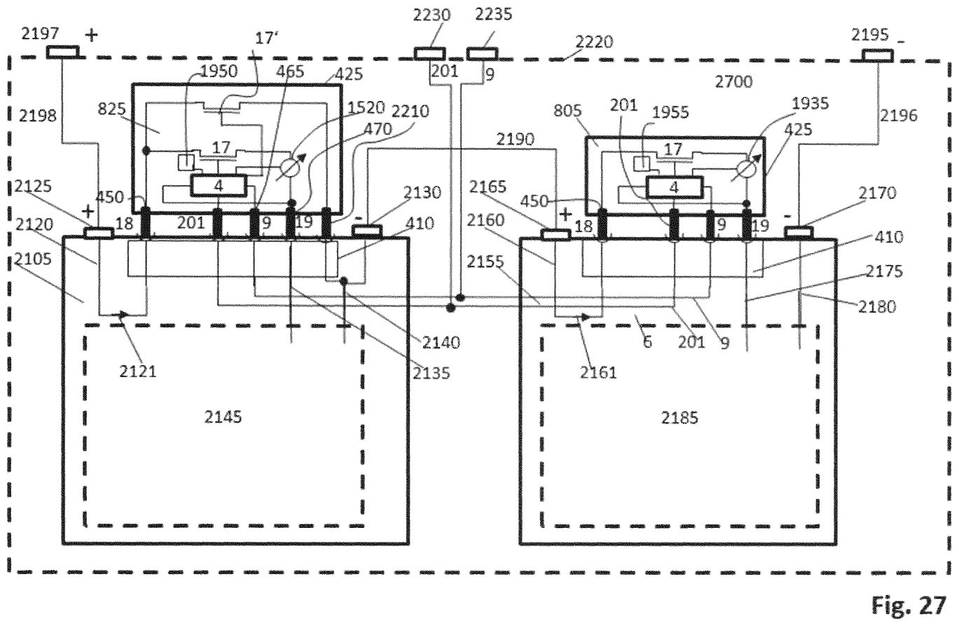

### FIG. 27

FIG. 27 shows a battery 2700 in which an electronic fuse 825 of the battery 2200 has a second circuit breaker 17′ which is suitable for shunting the battery cell module 2105 associated with the fuse when the second circuit breaker 17′ is closed and in which the control device is supplied from the battery cell 2145, but only if the circuit breaker 17 is closed. Otherwise, the battery 2700 essentially corresponds to the battery 2022 of FIG. 22.

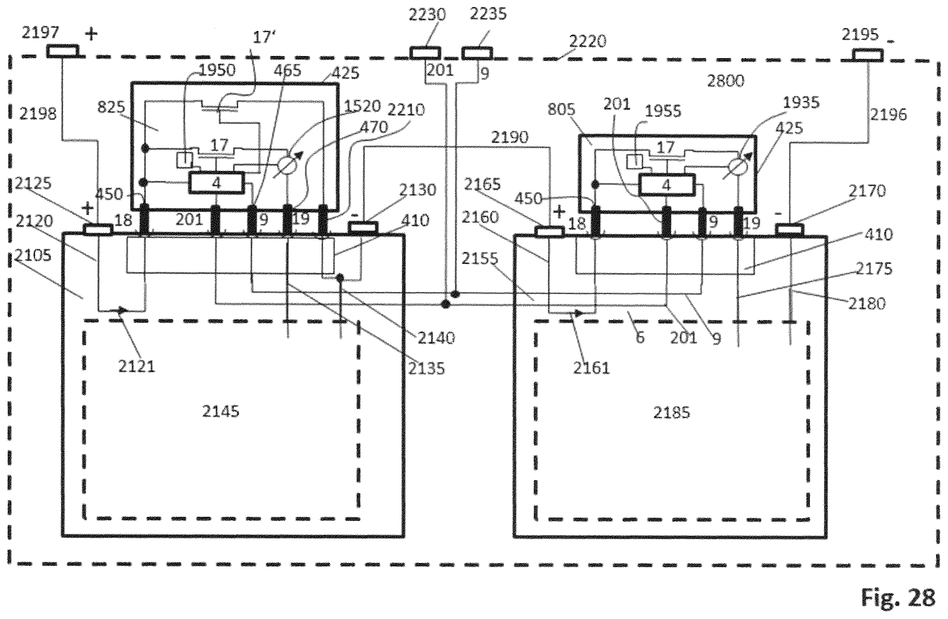

### FIG. 28

FIG. 28 shows a battery 2800 in which an electronic fuse 825 of the battery 2200 has a second circuit breaker 17′ which is suitable for shunting the battery cell module 2105 associated with the fuse when the second circuit breaker 17′ is closed and in which the control device 4 is further supplied from the battery cell 2145, even if the circuit breaker 17 is open.

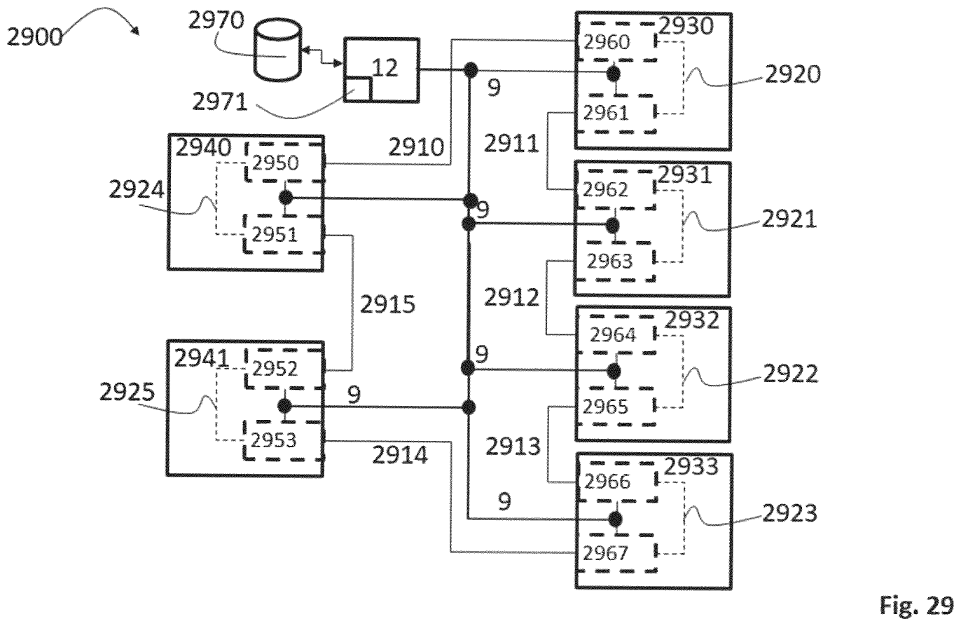

### FIG. 29

FIG. 29 shows a supply network 2900, wherein one or more supply branches of the supply network 2900 are designed to supply electrical power to electrical loads 2930 to 2933 as a ring of a supply line 2910 to 2915, in particular if a body serves as a return ground line, and/or are implemented as two rings of two supply lines. One or more supply branches of the supply network 2900 for power output of electrical power from electrical power sources 2940, 2941 can be designed as a ring of a supply line 2910 to 2915, in particular if a body serves as a return ground line, and/or as two rings of two supply lines.

Optionally, in the supply network 2900, for some loads of the loads 2930 to 2933, two fuses 2960 to 2967 are inserted in each case into the supply line 2910 to 2915 at the corresponding power extraction point 2920 to 2923 for this load of the loads 2930 to 2933 into the supply line 2910 to 2915 and/or, for power sources 2940, 2941, two fuses 2950 to 2953 are inserted in each case into the supply line 2910 to 2915 at the power feed point 2924 to 2925 of the electrical power for these power sources 2940, 2941 into the supply line 2910 to 2915.

Optionally, precisely those two electronic fuses of the fuses 2950 to 2953 and 2960 to 2967 which are associated with a defective line section of the line sections 2910 to 2915 are configured to open their circuit breakers 17 in the event of an error on the line section, so that precisely these two electronic fuses of the fuses 2950 to 2953 and 2960 to 2967 open this defective line section of the line sections 2910 to 2915. Optionally, in the event of an error on a load of the loads 2930 to 2933, the electronic fuses of the fuses 2960 to 2967 that are associated with this defective load open their circuit breakers 17, so that these two electronic fuses thereby isolate the faulty load and/or, in the event of an error on a power source of the power sources 2940, 2941, the electronic fuses of the fuses 2950 to 2953 associated with this defective power source open their circuit breakers, so that these two electronic fuses thereby isolate the faulty power source. This is optionally the case in particular when the above errors impair the power supply of other loads of the loads 2930 to 2933 and/or highly prioritized loads of the loads 2930 to 2933.

The disclosure also describes, among other things, a supply network 2900 in which the computer core 2 of the control device 4 of an electronic fuse of the fuses 2950 to 2953 and 2960 to 2967 receives or transmits data, such as configuration data (read-write), switch commands (read-write), diagnostic data (read-write), measured values (read), comparison value settings (read-write), via a data interface 10, 610, 550, 551 via a data bus 9.

Optionally, the data bus 9 is in some parts or completely a two-wire data bus and/or a differential data bus 9 and/or a differential bidirectional data bus 9.

For example, the data bus 9 can be a CAN data bus or a data bus 9 having a physical interface of a CAN data bus, a CAN FD data bus, or a Flexray data bus or an LVDS data bus or the like.

Electronic fuses 2950 to 2953 and 2960 to 2967 of the supply network 2900 can each comprise two data interfaces 10, 610, 550, 551 for the data bus 9, wherein they are inserted into the data bus 9 and form a linear chain of fuses 2950 to 2953 and 2960 to 2967 along at least a portion of the data bus 9.

A higher-level computer system 12, which is connected at the beginning of this part of the data bus 9 can determine, by means of auto addressing in cooperation with the control devices 4 of the electronic fuses for each of the control devices 4 of the electronic fuses (2950 to 2953 and 2960 to 2967), a fuse address for driving the computer cores 2 of the control devices 4 of the fuses and, where applicable, to transmit them to the computer cores 2 of the control devices 4 of the electronic fuses (2950 to 2953 and 2960 to 2967).

The supply network 2900 optionally comprises a supply line 2910 to 2915. For example, the supply network 2900 can be annular in parts. The loads 2920 to 2923 can extract electrical power from the supply line 2910 to 2915 of the supply network 2900 at different power extraction points 2920 to 2923 of the annular supply network 2900. The power sources 2940 to 2941 can feed electrical power into the supply line 2910 to 2915 of the supply network 2900 at different feed points 2924 to 2925 of the annular supply network 2900. The supply line 2910 to 2915 of the annular supply network 2900 to the left or right of the corresponding extraction points of electrical power or to the left or right of the corresponding feed points of electrical power are each interrupted at least on one side by a corresponding electronic fuse of the fuses 2950 to 2953 and 2960 to 2967. The corresponding electronic fuse of the fuses 2950 to 2953 and 2960 to 2967 is inserted with its corresponding circuit breaker 17 into the supply line 2910 to 2915 of the supply line section between two corresponding extraction points of the extraction points 2920 to 2923 for electrical load power of the associated loads of the loads 2930 to 2933, or is inserted between two corresponding feed points of the feed points 2924 to 2924 for electrical power of the associated power sources of the power sources 2940 to 2941 or between a corresponding feed point of the feed points 2924 to 2924 for electrical power of the associated power source of the power sources 2940 to 2941 and a corresponding extraction point of the extraction points 2920 to 2923 for electrical load power of the associated load of the loads 2930 to 2933.

The supply line of the annular supply network 2900 is in each case interrupted to the left and right of the corresponding extraction points 2920 to 2923 of electrical power on each side of each extraction point of the extraction points 2920 to 2923 by a corresponding electronic fuse of the fuses 2960 to 2967, and/or interrupted to the left and right of the corresponding feed points 2924 to 2925 of electrical power on each side of each feed point of the feed points 2924 to 2925 by a corresponding electronic fuse of the fuses 2950 to 2953.

Optionally, the two electronic fuses which are closest to a feed point of the feed points 2924 to 2925 or an extraction point of the extraction points 2920 to 2923 or a supply line section of the supply sections 2910 to 2915 isolate this feed point or this extraction point or this supply line section by opening their circuit breakers 17 if an error of a load of the loads 2930 to 2933 occurs at this extraction point in this supply line section of the supply sections 2910 to 2915 and/or if an error of a power source of the power sources 2940 to 2941 occurs at this feed point in this supply line section of the supply sections 2910 to 2915.

For example, a higher-level computer system 12 can determine the status of the electronic fuses 2960 to 2967 and 2950 to 2953 by response of the computer cores 2 of the control devices 4 of the electronic fuses 2960 to 2967 and 2950 to 2953 via the data bus 9. When a fault or an error is present, the higher-level computer system 12 can determine the position of the fault or of the error in the supply network 2900. The higher-level computer system 9 can then contain the fault or the error at the determined position by means of an intervention into the supply network 2900, in which the higher-level computer system 12 causes the computer cores 2 of the control devices 4 of the two electronic fuses of the fuses 2960 to 2967 and 2950 to 2953 of the supply network 2900 which are closest to the position of the fault to open their circuit breakers 17.

The intervention by the higher-level computer system 12 is optionally faster than twice the longest time constant of the power extractions of the loads 2920 to 2923 drawing power from the supply network 2900 at the instant of intervention. Likewise, the intervention by the higher-level computer system 12 is optionally faster than twice the longest time constant of the power feeds of the power sources 2940 to 2941 which feed power into the supply network 2900.

Optionally, the computer core 2 of the control device 4 of an electronic fuse of the fuses 2950 to 2953 and 2960 to 2967 records the faults and/or errors in the form of a log table 2970, which may also comprise only a few bits, or a log file 2970 or in different form of memory in a optionally non-volatile memory of the control device 4 of the fuse. Similarly, a higher-level computer system 12 can record the faults and/or the errors in the supply network 2900 and/or the faults and/or the errors of the fuses 2950 to 2953 and 2960 to 2967 in the form of a log table 2970, which may also comprise only a few bits, or a log file 2970 or a different form of memory, optionally in a non-volatile memory of the higher-level computer system 12.

The computer core 2 of the control device 4 of the electronic fuse optionally provides the entries of the log table 2970 or of the log file 2970 with a time stamp of a timer unit 35 of the control device 4 of the electronic fuse. The higher-level computer system 12 can also provide the entries of the log table 2970 or of the log file 2970 with a time stamp of a timer unit 1970 of the higher-level computer system 12 in an analogous manner.

The computer core 2 of the control device 4 of the electronic fuse optionally also records with a time stamp in the log table 2970 or the log file 2970 the time from which the fault was no longer present. In an analogous manner, the higher-level computer system 12 can also record with a time stamp in the log table 2970 or the log file 2970 the time from which the fault was no longer present.

The higher-level computer system 12 reads the log table 2970 or the log file 2970 of the computer core 2 of the control device 4 of a fuse of the fuses 2950 to 2953 and 2960 to 2963 via the data bus (9) from the memory of the control device 4 of this electronic fuse and/or from the memory of the computer core 2 of the control device 4 of this fuse, optionally regularly or in the event of a fault or in the event of an error.

The higher-level computer system 12 identifies—with the aid of one or more of its log tables 2970 or one or more of its log files 2970 and/or with the aid of one or more log tables 2970 or one or more log files 2970 of one or more computer cores 2 of one or more control devices 4 of one or more electronic fuses of the fuses (2950 to 2953 and 2960 to 2967)—potentially affected sensors and measuring systems which the supply network 2900 supplies with electrical power. The higher-level computer system 12 then optionally marks the measured values acquired in the relevant time period by these sensors and measuring systems as potentially incorrect or discards outright the measured values acquired in the relevant time period by these sensors and measuring systems.

FIG. 29 thus shows in schematically simplified form a supply network 2900. One or more supply branches of the supply network 2900 are designed to supply electrical power to electrical loads 2930 to 2933 as a ring of a supply line 2910 to 2915. In particular, for example, a body can serve as a return ground line in a ring. If the body ground is not available as a return line in all parts of the supply network 2900, the supply network 2900 can be designed in these regions in the form of two rings of two supply lines. One or more supply branches of the supply network 2900 then serve to supply electrical power from electrical power sources 2940 to 2941 as a ring of a supply line 2910 to 2915 if, for example, a body serves as a return ground line, and/or as two rings of two supply lines if, for example, no body serves as a return ground line.

In the example of FIG. 29, the supply network 2900 comprises a first line section 2910 of the supply line ring, wherein the first line section 2910 electrically connects the power feed point 2924 of the first power source 2940 to the first power extraction point 2920 of the first load 2930 in the example of FIG. 29, and wherein the return line can be, for example, the vehicle body.

In the example of FIG. 29, the supply network 2900 comprises a second line section 2911 of the supply line ring, wherein the second line section 2911 electrically connects the first power extraction point 2920 of the first load 2930 to the second power extraction point 2921 of the second load 2931 in the example of FIG. 29, and wherein the return line can be, for example, the vehicle body.

In the example of FIG. 29, the supply network 2900 comprises a third line section 2912 of the supply line ring, wherein the third line section 2912 electrically connects the second power extraction point 2921 of the second load 2931 to the third power extraction point 2922 of the third load 2932 in the example of FIG. 29, and wherein the return line can be, for example, the vehicle body.

In the example of FIG. 29, the supply network 2900 comprises a fourth line section 2913 of the supply line ring, wherein the fourth line section 2913 electrically connects the third power extraction point 2922 of the third load 2932 to the third power extraction point 2922 of the third load 2933 in the example of FIG. 29, and wherein the return line can be, for example, the vehicle body.

In the example of FIG. 29, the supply network 2900 comprises a fifth line section 2914 of the supply line ring, wherein the fifth line section 2914 electrically connects the fourth power extraction point 2923 of the fourth load 2933 to the second power feed point 2925 of the second power source 2941 in the example of FIG. 29, and wherein the return line can be, for example, the vehicle body.

In the example of FIG. 29, the supply network 2900 comprises a sixth line section 2915 of the supply line ring, wherein the sixth line section 2915 electrically connects the second power feed point 2925 of the second power source 2941 to the first power feed point 2924 of the first power source 2940 in the example of FIG. 29, and wherein the return line can be, for example, the vehicle body.

In the example of FIG. 29, the supply network 2900 comprises a first power extraction point 2920 for supplying the first load 2930 with electrical power from the supply line ring 2910 to 2915, wherein the return line can be, for example, the vehicle body.

In the example of FIG. 29, the supply network 2900 comprises a second power extraction point 2921 for supplying the second load 2931 with electrical power from the supply line ring 2910 to 2915, wherein the return line can be, for example, the vehicle body.

In the example of FIG. 29, the supply network 2900 comprises a third power extraction point 2922 for supplying the third load 2932 with electrical power from the supply line ring 2910 to 2915, wherein the return line can be, for example, the vehicle body.

In the example of FIG. 29, the supply network 2900 comprises a fourth power extraction point 2923 for supplying the fourth load 2933 with electrical power from the supply line ring 2910 to 2915, wherein the return line can be, for example, the vehicle body.

In the example of FIG. 29, the supply network 2900 comprises a first power feed point 2924 for feeding the power of the first power source 2940 into the supply line ring 2910 to 2915, wherein the return line can be, for example, the vehicle body.

In the example of FIG. 29, the supply network 2900 comprises a second power feed point 2925 for feeding the power of the second power source 2941 into the supply line ring 2910 to 2915, wherein the return line can be, for example, the vehicle body.

In the example of FIG. 29, the supply network 2900 comprises a first fuse 2950 of the first power source 2940. By means of its circuit breaker 17, the first fuse 2950 can disconnect the first power feed point 2924 from the first line section 2910 of the supply line ring 2910 to 2915 or connect the first power feed point 2924 to the first line section 2910 of the supply line ring 2910 to 2915. This disconnection or connection typically depends on the electrical current through the first fuse 2950 and/or the electrical voltage of the supply line ring 2910 to 2915 in the region of the first fuse 2950 relative to a reference potential and/or on a data command via the fuse data bus 9.

In the example of FIG. 29, the supply network 2900 comprises a second fuse 2951 of the first power source 2940. By means of its circuit breaker 17, the second fuse 2951 can disconnect the first power feed point 2924 from the sixth line section 2915 of the supply line ring 2910 to 2915 or connect the first power feed point 2924 to the sixth line section 2915 of the supply line ring 2910 to 2915. This disconnection or connection typically depends on the electrical current through the second fuse 2951 and/or the electrical voltage of the supply line ring 2910 to 2915 in the region of the second fuse 2951 relative to a reference potential and/or on a data command via the fuse data bus 9.

In the example of FIG. 29, the supply network 2900 comprises a third fuse 2952 of the second power source 2941. By means of its circuit breaker 17, the third fuse 2952 can disconnect the second power feed point 2925 from the sixth line section 2915 of the supply line ring 2910 to 2915 or connect the second power feed point 2925 to the sixth line section 2915 of the supply line ring 2910 to 2915. This disconnection or connection typically depends on the electrical current through the third fuse 2952 and/or the electrical voltage of the supply line ring 2910 to 2915 in the region of the third fuse 2952 relative to a reference potential and/or on a data command via the fuse data bus 9.

In the example of FIG. 29, the supply network 2900 comprises a fourth fuse 2953 of the second power source 2941. By means of its circuit breaker 17, the fourth fuse 2953 can disconnect the second power feed point 2925 from the fifth line section 2914 of the supply line ring 2910 to 2915 or connect the second power feed point 2925 to the fifth line section 2914 of the supply line ring 2910 to 2915. This disconnection or connection typically depends on the electrical current through the fourth fuse 2953 and/or the electrical voltage of the supply line ring 2910 to 2915 in the region of the fourth fuse 2953 relative to a reference potential and/or on a data command via the fuse data bus 9.

In the example of FIG. 29, the supply network 2900 comprises a thirteenth fuse 2950 of the first power source 2940. By means of its circuit breaker 17, the thirteenth fuse 2950 can disconnect the first power feed point 2924 from the first line section 2910 of the supply line ring 2910 to 2915 or connect the first power feed point 2924 to the first line section 2910 of the supply line ring 2910 to 2915. This disconnection or connection typically depends on the electrical current through the thirteenth fuse 2950 and/or the electrical voltage of the supply line ring 2910 to 2915 in the region of the thirteenth fuse 2950 relative to a reference potential and/or on a data command via the fuse data bus 9. The thirteenth fuse 2950 and the fourteenth fuse 2951 can have a common control device 4.

In the example of FIG. 29, the supply network 2900 comprises a fourteenth fuse 2951 of the first power source 2940. By means of its circuit breaker 17, the fourteenth fuse 2951 can disconnect the first power feed point 2924 from the sixth line section 2915 of the supply line ring 2910 to 2915 or connect the first power feed point 2924 to the sixth line section 2915 of the supply line ring 2910 to 2915. This disconnection or connection typically depends on the electrical current through the fourteenth fuse 2951 and/or the electrical voltage of the supply line ring 2910 to 2915 in the region of the fourteenth fuse 2951 relative to a reference potential and/or on a data command via the fuse data bus 9. The thirteenth fuse 2950 and the fourteenth fuse 2951 can have a common control device 4.

In the example of FIG. 29, the supply network 2900 comprises a fifteenth fuse 2952 of the second power source 2941. By means of its circuit breaker 17, the fifteenth fuse 2952 can disconnect the second power feed point 2925 from the sixth line section 2915 of the supply line ring 2910 to 2915 or connect the second power feed point 2925 to the sixth line section 2915 of the supply line ring 2910 to 2915. This disconnection or connection typically depends on the electrical current through the fifteenth fuse and/or the electrical voltage of the supply line ring 2910 to 2915 in the region of the fifteenth fuse 2952 relative to a reference potential and/or on a data command via the fuse data bus 9. The fifteenth fuse 2952 and the sixteenth fuse 2953 can have a common control device 4.

In the example of FIG. 29, the supply network 2900 comprises a sixteenth fuse 2953 of the second power source 2941. By means of its circuit breaker 17, the sixteenth fuse 2953 can disconnect the second power feed point 2925 from the fifth line section 2914 of the supply line ring 2910 to 2915 or connect the second power feed point 2925 to the fifth line section 2914 of the supply line ring 2910 to 2915. This disconnection or connection typically depends on the electrical current through the sixteenth fuse 2953 and/or the electrical voltage of the supply line ring 2910 to 2915 in the region of the sixteenth fuse 2953 relative to a reference potential and/or on a data command via the fuse data bus 9. The fifteenth fuse 2952 and the sixteenth fuse 2953 can have a common control device 4.

In the example of FIG. 29, the supply network 2900 comprises a fifth fuse 2960 of the first load 2930. By means of its circuit breaker 17, the fifth fuse 2960 can disconnect the first power extraction point 2920 from the first line section 2910 of the supply line ring 2910 to 2915 or connect the first power extraction point 2930 to the first line section 2910 of the supply line ring 2910 to 2915. This disconnection or connection typically depends on the electrical current through the fifth fuse 2960 and/or the electrical voltage of the supply line ring (2910 to 2915) in the region of the fifth fuse 2960 relative to a reference potential and/or on a data command via the fuse data bus 9. The fifth fuse 2960 and the sixth fuse 2961 can have a common control device 4.

In the example of FIG. 29, the supply network 2900 comprises a sixth fuse 2961 of the first load 2930. By means of its circuit breaker 17, the sixth fuse 2961 can disconnect the first power extraction point 2920 from the second line section 2911 of the supply line ring 2910 to 2915 or connect the first power extraction point 2930 to the second line section 2911 of the supply line ring 2910 to 2915. This disconnection or connection typically depends on the electrical current through the sixth fuse 2961 and/or the electrical voltage of the supply line ring 2910 to 2915 in the region of the sixth fuse 2961 relative to a reference potential and/or on a data command via the fuse data bus 9. The fifth fuse 2960 and the sixth fuse 2961 can have a common control device 4.

In the example of FIG. 29, the supply network 2900 comprises a seventh fuse 2962 of the second load 2931. By means of its circuit breaker 17, the seventh fuse 2962 can disconnect the second power extraction point 2921 from the second line section 2911 of the supply line ring 2910 to 2915 or connect the second power extraction point 2921 to the second line section 2911 of the supply line ring 2910 to 2915. This disconnection or connection typically depends on the electrical current through the seventh fuse 2962 and/or the electrical voltage of the supply line ring 2910 to 2915 in the region of the seventh fuse 2962 relative to a reference potential and/or on a data command via the fuse data bus 9. The seventh fuse 2962 and the eighth fuse 2963 can have a common control device 4.

In the example of FIG. 29, the supply network 2900 comprises an eighth fuse 2963 of the second load 2931. By means of its circuit breaker 17, the eighth fuse 2963 can disconnect the second power extraction point 2921 from the third line section 2912 of the supply line ring 2910 to 2915 or connect the second power extraction point 2921 to the third line section 2912 of the supply line ring 2910 to 2915. This disconnection or connection typically depends on the electrical current through the eighth fuse 2963 and/or the electrical voltage of the supply line ring 2910 to 2915 in the region of the eighth fuse 2963 relative to a reference potential and/or on a data command via the fuse data bus 9. The seventh fuse 2962 and the eighth fuse 2963 can have a common control device 4.

In the example of FIG. 29, the supply network 2900 comprises a ninth fuse 2964 of the third load 2932. By means of its circuit breaker 17, the ninth fuse 2964 can disconnect the third power extraction point 2922 from the third line section 2912 of the supply line ring 2910 to 2915 or connect the third power extraction point 2922 to the third line section 2912 of the supply line ring 2910 to 2915. This disconnection or connection typically depends on the electrical current through the ninth fuse 2964 and/or the electrical voltage of the supply line ring 2910 to 2915 in the region of the ninth fuse 2964 relative to a reference potential and/or on a data command via the fuse data bus 9. The ninth fuse 2964 and the tenth fuse 2965 can have a common control device 4.

In the example of FIG. 29, the supply network 2900 comprises a tenth fuse 2965 of the third load 2932. By means of its circuit breaker 17, the tenth fuse 2965 can disconnect the third power extraction point 2922 from the fourth line section 2913 of the supply line ring 2910 to 2915 or connect the third power extraction point 2922 to the fourth line section 2913 of the supply line ring 2910 to 2915. This disconnection or connection typically depends on the electrical current through the tenth fuse 2965 and/or the electrical voltage of the supply line ring 2910 to 2915 in the region of the tenth fuse 2965 relative to a reference potential and/or on a data command via the fuse data bus 9. The ninth fuse 2964 and the tenth fuse 2965 can have a common control device 4.

In the example of FIG. 29, the supply network 2900 comprises an eleventh fuse 2966 of the fourth load 2933. By means of its circuit breaker 17, the eleventh fuse 2966 can disconnect the fourth power extraction point 2923 from the fourth line section 2913 of the supply line ring 2910 to 2915 or connect the fourth power extraction point 2923 to the fourth line section 2913 of the supply line ring 2910 to 2915. This disconnection or connection typically depends on the electrical current through the eleventh fuse 2966 and/or the electrical voltage of the supply line ring 2910 to 2915 in the region of the eleventh fuse 2966 relative to a reference potential and/or on a data command via the fuse data bus 9. The eleventh fuse 2966 and the twelfth fuse 2967 can have a common control device 4.

In the example of FIG. 29, the supply network 2900 comprises a twelfth fuse 2967 of the fourth load 2933. By means of its circuit breaker 17, the twelfth fuse 2967 can disconnect the fourth power extraction point 2923 from the fifth line section 2914 of the supply line ring 2910 to 2915 or connect the fourth power extraction point 2923 to the fifth line section 2914 of the supply line ring 2910 to 2915. This disconnection or connection typically depends on the electrical current through the twelfth fuse 2967 and/or the electrical voltage of the supply line ring 2910 to 2915 in the region of the twelfth fuse 2967 relative to a reference potential and/or on a data command via the fuse data bus 9. The eleventh fuse 2966 and the twelfth fuse 2967 can have a common control device 4.

In the example of FIG. 29, the supply network 2900 comprises a log table 2970 or log file for the errors and faults, and in some cases further operating parameters. The log table 2970 or log file for the errors and faults and possibly further operating parameters is optionally a log table 2970 or a log file for the errors and faults, and in some cases further operating parameters of the higher-level computer system 12.

The higher-level computer system 12 optionally comprises a timer 2971 of the higher-level computer system 12 for synchronizing the other timers of the supply network 2900 and in particular for synchronizing the timers 35 of the control devices 4 of the electronic fuses in the supply network 2900.

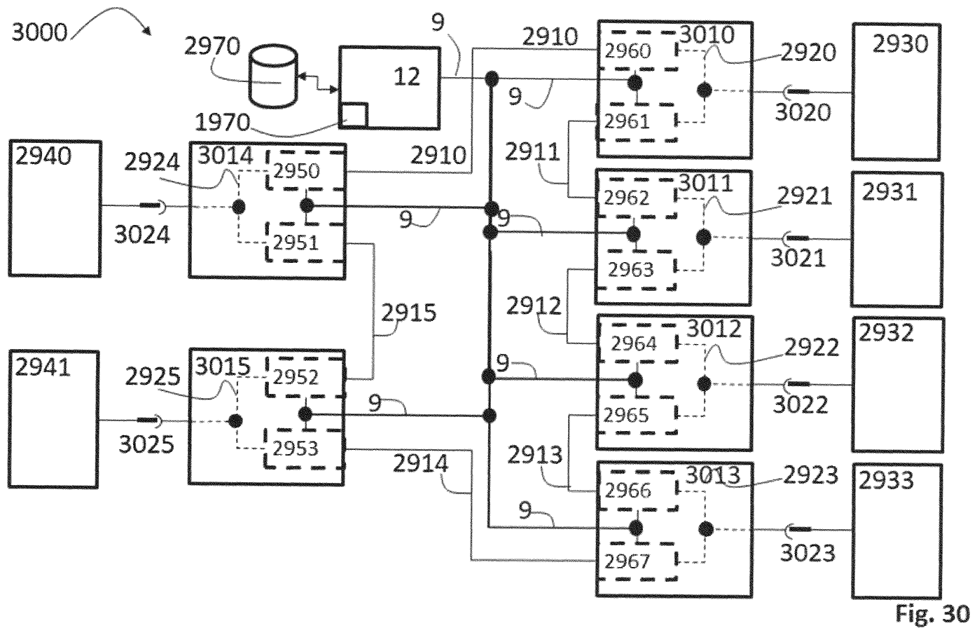

### FIG. 30

FIG. 30 corresponds to FIG. 29 with the difference that the power sources and loads are pluggable.

The supply network 3000 of FIG. 30 additionally has a first fuse slot 3010 for the first load 2930 with two fuses 2960, 2961 and a first plug connection 3020.

The supply network 3000 of FIG. 30 additionally has a second fuse slot 3011 for the second load 2931 with two fuses 2962, 2963 and a second plug connection 3021.

The supply network 3000 of FIG. 30 additionally has a third fuse slot 3012 for the third load 2932 with two fuses 2964, 2965 and a third plug connection 3022.

The supply network 3000 of FIG. 30 additionally has a fourth fuse slot 3013 for the fourth load 2933 with two fuses 2966, 2967 and a fourth plug connection 3023.

The supply network 3000 of FIG. 30 additionally has a fifth fuse slot 3014 for the first power source 2940 with two fuses 2950, 2951 and a fifth plug connection 3024.

The supply network 3000 of FIG. 30 additionally has a sixth fuse slot 3015 for the second power source 2941 with two fuses 2952, 2953 and a sixth plug connection 3025.

The supply network 3000 of FIG. 30 additionally has a first plug connection 3020 with a first plug and a first socket for the connection and the supply of the first load 2930.

The supply network 3000 of FIG. 30 additionally has a second plug connection 3021 with a second plug and a second socket for the connection and the supply of the second load 2931.

The supply network 3000 of FIG. 30 additionally has a third plug connection 3022 with a third plug and a third socket for the connection and the supply of the third load 2932.

The supply network 3000 of FIG. 30 additionally has a fourth plug connection 3023 with a fourth plug and a fourth socket for the connection and the supply of the fourth load 2933.

The supply network 3000 of FIG. 30 additionally has a fifth plug connection 3024 with a fifth plug and a fifth socket for the connection and feed-in of the first power source 2940.

The supply network 3000 of FIG. 30 additionally has a sixth plug connection 3025 with a sixth plug and a sixth socket for the connection and feed-in of the second power source 2941.

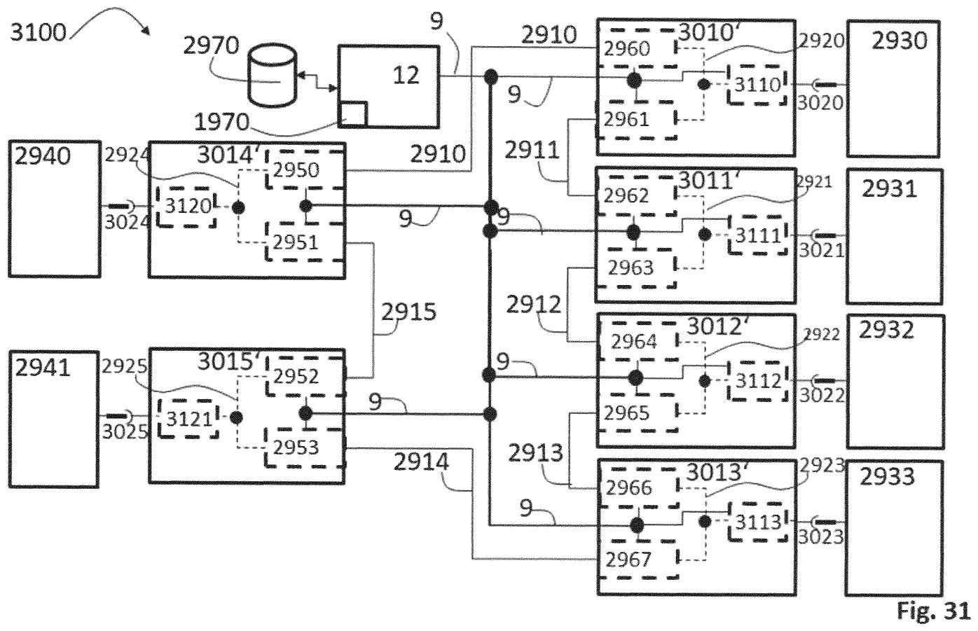

### FIG. 31

The supply network 3100 shown schematically and in simplified form in FIG. 31 substantially corresponds to the supply network 3000 of FIG. 30, wherein the plug connections are now protected with their own fuses.

According to the proposal, a supply line (2910 to 2015 and 2920 to 2923) of the supply network 3100 can have a plug connection of the plug connections 3020 to 2023 to a plug or a socket for the connection and the supply of a load of the loads 2930 to 2033. A supply line (2910 to 2015 and 2924 to 2925) of the supply network 3100 can have a plug connection of the plug connections 3024 to 2025, a plug or a socket for the connection and the power feed of a power source of the power sources 2940 to 2041. According to the proposal, an electronic fuse of the fuses 3110 to 3113 is now inserted in the vicinity of the plug connection of the plug connections 3020 to 3023 for the extraction of power by the electrical load of the electrical loads 2930 to 2933 from the relevant supply line (2910 to 2915 and 2920 to 2925), or an electronic fuse of the fuses 3110 to 3113 is inserted in the vicinity of the plug connection of the plug connections 3020 to 3023 for the feeding of power by the power source of the power sources 2940 to 2941 into the relevant supply line (2910 to 2915 and 2920 to 2925).

This electronic fuse detects a hot plug event relating to this plug connection of the plug connections (3020 to 3023) in that the computer core 2 of the control device 4 of the electronic fuse monitors the transient time characteristic of the voltage of the potential of a node of the circuit breaker 17 of this fuse against the potential of a reference node 201, in particular against a ground potential, for example by means of the analog-to-digital converter 570 of the control device 4 of the fuse. The computer core 2 of the control device 4 of the fuse can also monitor the transient characteristic of the current 29 through the circuit breaker 17 of this electronic fuse, for example by means of the analog-to-digital converter 570. Optionally, the computer core 2 of the control device 4 of this electronic fuse monitors these transient characteristics.

The disclosure understands a hot plug event as removing or inserting a power source and/or a load in the live state of one side of the plug connection and/or in the current-carrying state of the plug connection. Hot plug describes the possibility of inserting device parts that are loaded and/or in operation into the supply network and/or removing them from the supply network without a previously executed shutdown method for the device part and/or without a previously executed conditioning method for the device part in preparation for the plug-in process.

The computer core 2 of the control device 4 of this electronic fuse, which detects a hot plug event at one of its terminals 18, 19, optionally switches off the circuit breaker (17) in the event of a hot plug event. This possibly prevents further damage to the device part.

The computer core 2 of the control device 4 of this electronic fuse optionally signals such a hot plug event to the higher-level computer system 12 via the data bus 9. The higher-level computer system 12 indicates the signaled hot-plug event on a display or a similar or functionally equivalent instrument, for example a terminal 740.

Optionally, one or more electronic fuses are configured in normal operation to signal—at least at times and/or on request, in particular on request of the higher-level computer system 12 or of an operator 730 by means of the data input and data output means 740—this normal operation in a manner that is visually recognizable for a human, in particular by means of an illuminant and/or an LED and/or an indicator and/or a display of a data output means 740 of the fuse or of the higher-level computer system 12 and/or as data information via the data bus 9. It is conceivable, for example, that each fuse has an LED which, in the case of proper operation, lights up green and, in the event of a defect, lights up red. Such LEDs optionally light up only on request by an operator 730 in order to save energy.

Optionally, one or more electronic fuses are configured, in the event of an error and/or a fault and/or a hot plug event, to signal this error or this fault or this hot plug event in a manner visually recognizable for a human, in particular by means of an illuminant and/or an LED and/or an indicator and/or a display of a data output means 740 of the fuse or of the higher-level computer system 12 and/or as data information via the data bus 9, at least at times and/or on request, in particular on request of the higher-level computer system 12 or of an operator 730 by means of the data input and data output means 740.

In the event of a hot plug event in the supply network 3100, the computer core 2 of the control device 4 of the electronic fuse optionally transmits a message to a computer 710, 750 of a service provider and/or to a higher-level computer system 12. In the event of a hot plug event in the supply network 3100 of a vehicle, the computer core 2 of the control device 5 of the electronic fuse can transmit a message to a computer 710 of a vehicle manufacturer or of a service provider immediately or in a time-delayed manner.

Optionally, control devices 4 of electronic fuses of the supply network 3100 comprise clocks or timers 35, in particular for creating time stamps for log tables and/or log files. The higher-level computer system 12 of the supply network can also have one or more clocks or one or more timers 1970, in particular for creating time stamps for log tables and/or log files. Optionally, the higher-level computer system 12 then optionally synchronizes clocks and/or timers 35, 1970 in the supply network 3100, optionally regularly by means of a synchronization signal, in particular via the data bus 9.

Optionally, this synchronization of clocks and/or timers 35, 1970 in the supply network 3100 comprises a reset to a common starting value of these clocks and/or timers 35, 1970.

The synchronization of clocks and/or timers 35, 1970 in the supply network 3100 optionally comprises a correction of the frequency and/or of the phase of the oscillators 30 of the control devices 4 of the electronic fuses (2950 to 2953 and 2960 to 2967 and 3110 to 3113 and 3120 to 3121). The oscillators 30 of the control devices 4 of the electronic fuses (2950 to 2953 and 2960 to 2967 and 3110 to 3113 and 3120 to 3121) are optionally synchronized by means of a corresponding PLL of the corresponding control device 4 of the corresponding fuse.

By means of a command via the data bus 9 in broadcasting mode to a plurality of and/or all of these fuses (2950 to 2953 and 2960 to 2967 and 3110 to 3113 and 3120 to 3121), a higher-level computer system 12 optionally causes computer cores 2 of control devices 4 of electronic fuses (2950 to 2953 and 2960 to 2967 and 3110 to 3113 and 3120 to 3121) in the supply network to carry out at the same instants optionally identical measurements at optionally the same times by means of the measuring means of the control devices 4 of the fuses and/or by means of the analog-to-digital converters 570 of the control devices 4 of the fuses. The term “same times” refers here to the equality of the clock states of the respective clocks and/or timers 35 of the different control devices 4 of the different electronic fuses (2950 to 2953 and 2960 to 2967 and 3110 to 3113 and 3120 to 3121).

The disclosure proposes that at least two electronic fuses (2950 to 2953 and 2960 to 2967 and 3110 to 3113 and 3120 to 3121) of the supply network 3100 carry out a distributed measurement method with synchronous measurement by means of two synchronized local clocks 35, which are each located within the corresponding control device 4 of the at least two electronic fuses. This means that the first computer core 2 of a first control device 4 of a first electronic fuse and the second computer core 2 of a second control device 4 of a second electronic fuse of these fuses (2950 to 2953 and 2960 to 2967 and 3110 to 3113 and 3120 to 3121) perform a distributed measurement method with synchronous measurement of specified parameters by means of a first timer 35 of the control device 4 of the first fuse and by means of a second timer 35 of the control device 4 of the second fuse. The supply network uses the two timers as two synchronized local clocks 35. The parameters detected in this case can, for example, be the corresponding current 29 through the corresponding circuit breaker 17 and the corresponding voltage of the second terminal 19 of the corresponding fuse against a reference potential 201 and the corresponding voltage of the first terminal 18 of the corresponding fuse against a reference potential 201.

Optionally, the computer cores 2 of the control devices 4 of the fuses, if necessary, transmit the measured values thus detected to a higher-level computer system 12 and/or to an evaluating computer core 2 of the control device 4 of a fuse via the data bus 9.

The computer core 2 of a control device 4 of a first of the electronic fuses can operate as the higher-level computer system 12. Optionally, the first fuse and the second fuse are connected to one another via one or more supply line sections. The higher-level computer system 12 deduces from the transmitted data a parameter of the supply line section between the first electronic fuse and the second electronic fuse. This parameter can be, for example, the electrical resistance and/or the temperature of the supply line section between the first electronic fuse and the second electronic fuse.

Accordingly, the higher-level computer system 12 can deduce from the data transmitted via the data bus 9 the temperature and/or the electrical resistance of one or more supply line sections between the first electronic fuse and the second electronic fuse.

FIG. 31 thus shows a supply network 3100 having an isolation capacity of line sections 2910 to 2915 and an isolation capacity of loads 2930 to 2933 and having an isolation capacity of power sources 2940 to 2941, wherein proposed fuses establish this isolation capacity by means of their circuit breakers 17.

The supply network 3100 of FIG. 1 comprises a seventeenth fuse 3110 of the first load 2930. By means of its circuit breaker 17, the seventeenth fuse 3110 can disconnect the first power extraction point 2920, on the one hand, from the first load 2930 or, on the other hand, from the first plug connection 3020 with the first plug and the first socket for the connection and the supply of the first load 2930, or can connect the first power extraction point 2920, on the one hand, to the first load 2930 or, on the other hand, to the first plug connection 3020 with the first plug and the first socket for the connection and the supply of the first load 2930. This disconnection or connection typically depends on the electrical current 29 through the seventeenth fuse 3110 and/or the electrical voltage of the supply line ring 2910 to 2915 in the region of the seventeenth fuse 3110 or in the region of the first plug connection 3020 relative to a reference potential 201 and/or on a data command via the fuse data bus 9. The seventeenth fuse 3110 and the fifth fuse 2960 and the sixth fuse 2961 can have a common control device 4;

The supply network 3100 of FIG. 1 comprises an eighteenth fuse 3111 of the second load 2931. By means of its circuit breaker 17, the eighteenth fuse can disconnect the second power extraction point 2921, on the one hand, from the second load 2931 or from the second plug connection 3021 with the second plug and the second socket for the connection and the supply of the second load 2931, on the other hand, or connect the second power extraction point 2921, on the one hand, to the second load 2931 or to the second plug connection 3021 with the second plug and the second socket for the connection and the supply of the second load 2931, on the other hand. This disconnection or connection typically depends on the electrical current 29 through the eighteenth fuse 3111 and/or the electrical voltage of the supply line ring 2910 to 2915 in the region of the eighteenth fuse 3111 or in the region of the second plug connection 3021 relative to a reference potential 201 and/or on a data command via the fuse data bus 9. The eighteenth fuse 3111 and the seventh fuse 2962 and the eighth fuse 2963 can have a common control device 4.

The supply network 3100 of FIG. 1 comprises a nineteenth fuse 3112 of the third load 2932. By means of its circuit breaker 17, the nineteenth fuse 3112 can disconnect the third power extraction point 2922, on the one hand, from the third load 2932 or from the third plug connection 3022 with the third plug and the third socket for the connection and the supply of the third load 2932, on the other hand, or connect the third power extraction point 2922, on the one hand, to the third load 2932 or to the third plug connection 3022 with the third plug and the third socket for the connection and supply of the third load 2932, on the other hand. This disconnection or connection typically depends on the electrical current 29 through the nineteenth fuse 3112 and/or the electrical voltage of the supply line ring 2910 to 2915 in the region of the nineteenth fuse 3112 or in the region of the third plug connection 3022 relative to a reference potential 201 and/or on a data command via the fuse data bus 9. The nineteenth fuse 3112 and the ninth fuse 2964 and the tenth fuse 2965 can have a common control device 4.

The supply network 3100 of FIG. 1 comprises a twentieth fuse 3113 of the fourth load 2933. By means of its circuit breaker 17, the twentieth fuse 3113 can disconnect the fourth power extraction point 2923, on the one hand, from the fourth load 2933 or from the fourth plug connection 3023 with the fourth plug and the fourth socket for the connection and the supply of the fourth load 2933, on the other hand, or connect the fourth power extraction point 2923, on the one hand, to the fourth load 2933 or to the fourth plug connection 3023 with the fourth plug and the fourth socket for the connection and the supply of the fourth load 2933, on the other hand. This disconnection or connection typically depends on the electrical current 29 through the twentieth fuse 3113 and/or the electrical voltage of the supply line ring 2910 to 2915 in the region of the twentieth fuse 3113 or in the region of the fourth plug connection 3023 relative to a reference potential 201 and/or on a data command via the fuse data bus 9. The twentieth fuse 3113 and the eleventh fuse 2966 and the twelfth fuse 2966 can have a common control device 4;

The supply network 3100 of FIG. 1 comprises a twenty-first fuse 3120 of the first power source 2940. By means of its circuit breaker 17, the twenty-first fuse 3120 can disconnect the first power feed point 2924, on the one hand, from the first power source 2940 or from the fifth plug connection 3024 with the fifth plug and the fifth socket for the connection and the supply of the first power source 2940, on the other hand, or connect the fifth power extraction point 2924, on the one hand, to the first power source 2940 or to the fifth plug connection 3024 with the fifth plug and the fifth socket for the connection and supply of the first power source 2940, on the other hand. This disconnection or connection typically depends on the electrical current 29 through the twenty-first fuse 3120 and/or the electrical voltage of the supply line ring 2910 to 2915 in the region of the twenty-first fuse 3120 or in the region of the fifth plug connection 3024 relative to a reference potential 201 and/or on a data command via the fuse data bus 9. The twenty-first fuse 3120 and the thirteenth fuse 2950 and the fourteenth fuse 2951 can have a common control device 4;

The supply network 3100 of FIG. 1 comprises a twenty-second fuse 3121 of the second power source 2941. By means of its circuit breaker 17, the twenty-second fuse 3121 can disconnect the second power feed point 2925, on the one hand, from the second power source 2941 or from the sixth plug connection 3025 with the sixth plug and the sixth socket for the connection and the supply of the second power source 2941, on the other hand, or connect the sixth power extraction point 2925, on the one hand, to the second power source 2941 or to the sixth plug connection 3025 with the sixth plug and the sixth socket for the connection and the supply of the second power source 2941, on the other hand. This disconnection or connection typically depends on the electrical current 29 through the twenty-second fuse 3121 and/or the electrical voltage of the supply line ring 2910 to 2915 in the region of the twenty-second fuse 3121 or in the region of the sixth plug connection 3025 relative to a reference potential 201 and/or on a data command via the fuse data bus 9. The twenty-second fuse 3121 and the fifteenth fuse 2952 and the sixteenth fuse 2953 can have a common control device 4;

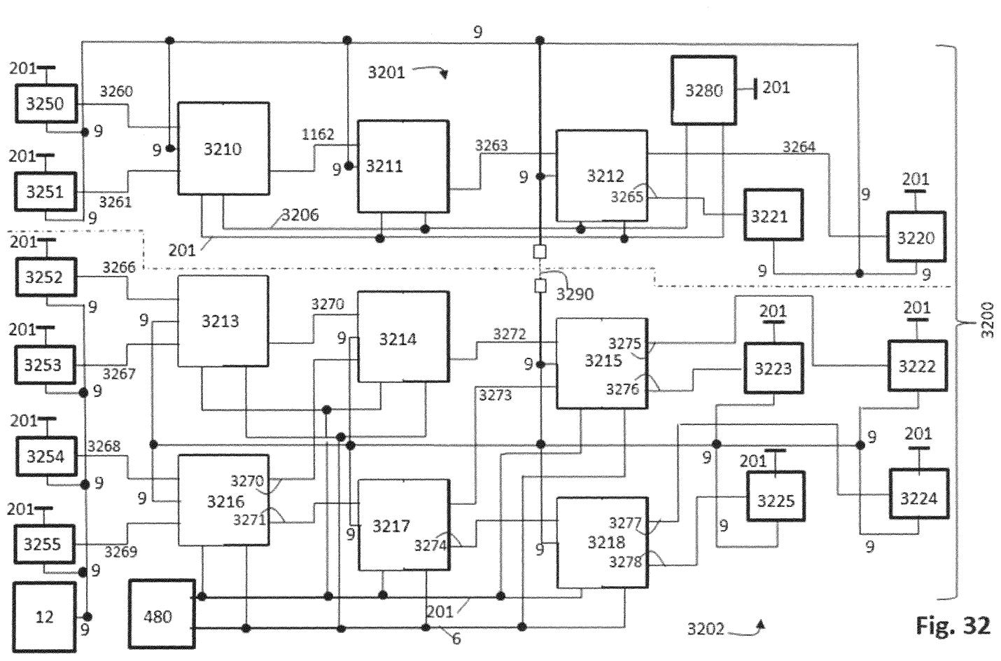

### FIG. 32

FIG. 32 corresponds in large parts to FIG. 11, wherein the supply network 3200 of FIG. 32 has a first sub-supply network 3201 and a second sub-supply network 3202. In the example of FIG. 32, the first sub-supply network 3201 is to have, for example, high voltage values of greater than 50 V of the voltage between supply line sections 3260 to 3265 of the first sub-supply network 3201, on the one hand, and a reference potential 20 and/or the supply line portions 3260 to 3265 of the second sub-supply network 3202 on the other hand. In the example of FIG. 32, in contrast to this, the second sub-supply network 3202 is to have, for example, low voltage values of less than 50 V of the voltage between supply line sections 3266 to 3278 of the second sub-supply network 3202, on the one hand, and the reference potential 201.

The supply network 3200 of FIG. 31 comprises a first sub-supply network 3201 of the supply network 3200. In the example of FIG. 32, the first sub-supply network 3201 has, for example, high voltage values of greater than 50 V of the voltage between supply line sections 3260 to 3265 of the first sub-supply network 3201, on the one hand, and a reference potential 201 or the supply line sections 3260 to 3265 of the second sub-supply network 3202, on the other hand;

The supply network 3200 of FIG. 31 comprises a second sub-supply network 3202 of the supply network 3200. In the example of FIG. 32, the second sub-supply network 3202 has, for example, low voltage values of less than 50 V of the voltage between supply line sections 3266 to 3278 of the second sub-supply network 3202, on the one hand, and a reference potential 201;

The supply network 3200 of FIG. 31 comprises an operating voltage 3206 for the fuses in the HV supply sub-network 3201.

The supply network 3200 of FIG. 31 comprises a first cross-over fuse 3210 in the first supply sub-network 3201 for voltages greater than 50 V.

The supply network 3200 of FIG. 31 comprises a second cross-over fuse 3211 in the first supply sub-network 3201 for voltages greater than 50 V.

The supply network 3200 of FIG. 31 comprises a third cross-over fuse 3212 in the first supply sub-network 3201 for voltages greater than 50 V.

The supply network 3200 of FIG. 31 comprises a fourth cross-over fuse 3213 in the second supply sub-network 3202 for voltages less than 50 V.

The supply network 3200 of FIG. 31 comprises a fifth cross-over fuse 3214 in the second supply sub-network 3202 for voltages less than 50 V.

The supply network 3200 of FIG. 31 comprises a sixth cross-over fuse 3215 in the second supply sub-network 3202 for voltages less than 50 V.

The supply network 3200 of FIG. 31 comprises a seventh cross-over fuse 3216 in the second supply sub-network 3202 for voltages less than 50 V.

The supply network 3200 of FIG. 31 comprises an eighth cross-over fuse 3217 in the second supply sub-network 3202 for voltages less than 50 V.

The supply network 3200 of FIG. 31 comprises a ninth cross-over fuse 3218 in the second supply sub-network 3202 for voltages less than 50 V.

The supply network 3200 of FIG. 31 comprises a first power source 3250 in the first supply sub-network 3201 for voltages greater than 50 V.

The supply network 3200 of FIG. 31 comprises a second power source 3251 in the first supply sub-network 3201 for voltages greater than 50 V.

The supply network 3200 of FIG. 31 comprises a third power source 3252 in the second supply sub-network 3202 for voltages less than 50 V.

The supply network 3200 of FIG. 31 comprises a fourth power source 3253 in the second supply sub-network 3202 for voltages less than 50 V.

The supply network 3200 of FIG. 31 comprises a fifth power source 3254 in the second supply sub-network 3202 for voltages less than 50 V.

The supply network 3200 of FIG. 31 comprises a sixth power source 3255 in the second supply sub-network 3202 for voltages less than 50 V.

The supply network 3200 of FIG. 31 comprises supply line sections 3260 to 3265 in the first supply sub-network 3201 for voltages greater than 50 V.

The supply network 3200 of FIG. 31 comprises supply line sections 3266 to 3278 in the second supply sub-network 3202 for voltages less than 50 V.

The supply network 3200 of FIG. 31 comprises an operating voltage source 3280 for the operation of the control devices 4 of the electronic fuses 405 in the first HV supply sub-network 3201.

The supply network 3200 of FIG. 31 comprises an optical data bus 3290 for galvanic isolation.

FIG. 32 thus by way of example schematically shows a supply network 3200, wherein the supply network 3200 has supply sub-networks 3202 with voltages less than 50 V (LV networks) and supply sub-networks 3201 with voltages greater than 50 V (HV networks). The supply network 3200 comprises a data bus 9 which is implemented, in the range of the voltage domain limits between supply sub-networks 3202, having voltages less than 50 V on the one hand and supply sub-networks 3201 having voltages greater than 50 V, optionally as an optical data bus 3290.

The supply network 3200 should at least comprise a data bus 9 which is implemented in the range of the voltage domain limits between supply sub-networks 3202 having voltages less than 50 V on the one hand and supply sub-networks 3201 having voltages greater than 50 V as a data bus with potential isolation 3290.

Optionally, within one or more supply lines of the supply lines (3260, 3262, 3263, 3264), at least two electronic fuses (3210, 3211, 3212) are cascaded, which divide the supply line (3260, 3262, 3263, 3264) into different supply line sections (3260, 3262, 3263, 3264).

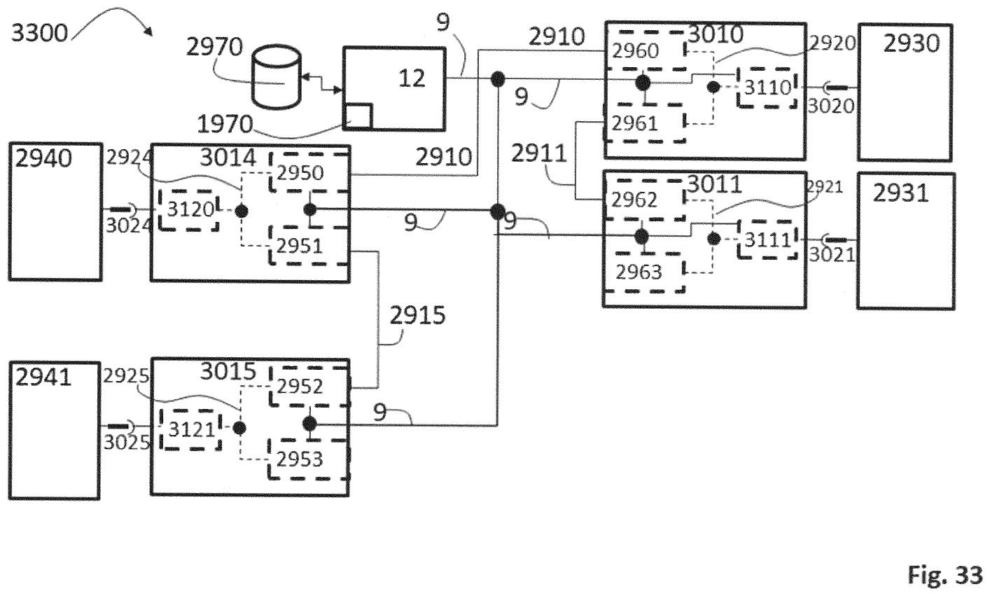

### FIG. 33

FIG. 33 shows a supply network 3300 similar to FIG. 31 for explaining the prioritization of loads and power sources and a favorable topology of the supply network 3300 to support this prioritization. Firstly, the electrical connection point 2920 of a more important load 2930 to a supply line 2910 of the supply network 3300 is arranged in the part of the supply line 2910, 2911 located closer to the power source 2940, while the electrical connection point 2921 of a less important load 2931 to the supply line 2911 is arranged in the part of the supply line 2910, 2911 located further away from the power source 2940. As a result, a prioritization of the power supply by means of interruption of the supply line between an important load 2930 and a less important load 2931 can take place without endangering the power supply of the important load 2930. For this purpose, an electronic fuse 2961, 2962 is optionally located between the electrical connection point 2920 of the more important load 2930 to the supply line 2910, 2911 and the electrical connection point 2921 of the less important load 2931 to the supply line 2915, 2910, 2911. This corresponding electronic fuse 2961, 2962 can then, with its corresponding circuit breaker 17, prevent the supply of power to the less important loads 2931 by an interruption of the supply line 2915, 2910, 2911. In the example of FIG. 33, the cross-over fuse 3011 also comprises a further fuse 3111 which can also prevent the power supply of the less important load 2931 with its circuit breaker 17.

The computer core 2 of the control device 4 of an electronic fuse (2961, 2962) in the supply network 2915, 2910, 2911 and/or the computer core 2 of the control device 4 of the fuse 3111 in the branch line 3021 to the less important load 2931 optionally disconnect from the supply network 2915, 2910, 2911 the less important load 2931 and/or the supply line section 2911 of the less important load 2931 and/or the branch line 3021 for supplying the less important load 2931 in the event of an error or a fault in the less important load 2931 or in the event of an error or a fault in the supply line section 2911 of the less important load 2931 and/or in the event of an error or a fault in the branch line 3021 of the less important load 2931.

The advantage is that the supply network then continues to supply the more important load 2930 with electrical power in the event of such an error or such a fault.

In an analogous manner, the supply network 3300 can also configure the power sources on a prioritized basis. Secondly, the electrical connection point 2924 of a more important power source 2940 to a supply line 2915, 2910, 2911 of the supply network 3300 is therefore optionally arranged in the part of the supply line 2915, 2910, 2911 closer to one or more loads 2930, 2931, while the electrical connection point 2925 of a less important power source 2925 to the supply line 2915, 2910, 2911 is optionally arranged in the part of the supply line 2915, 2910, 2911 further from the one or more loads 2930, 2931. This ensures the prioritization of the power sources. An electronic fuse 2951, 2952 is optionally located between the electrical connection point 2924 of the more important power source 2940 to the supply line 2915, 2910, 2911 and the electrical connection point 2925 of the less important power source 2941 to the supply line 2915, 2910, 2911. In the example of FIG. 33, a further fuse 3121 is located in the branch line between the connection point 2925 of the less important power source 2941 and the less important power source 2941.

This electronic fuse 2951, 2952 can disconnect the less important power source 2941 in the event of an error and/or a fault of the less important power source 2941 or of the supply line section 2915 of the less important power source 2941 or the branch line 3025 of the less important power source 2941 from the supply line 2915, 2910, 2911 of the supply network 3300. In such a case of such a fault, the supply network 3300 can further remove electrical power from the more important power source 2940.

The disclosure also describes, by way of example, a supply network 3300, wherein the supply network 3300 comprises at least one supply line 2915, 2910, 2911, a first electrical load 2930, a second electrical load 2931, and a power source 2940. The first electrical load 2930 is connected at a first connection point 2920 via a seventeenth electronic fuse 3110 to the supply line 2915, 2910, 2911 by means of a first branch line 3020. The second electrical load 2931 is connected at a second connection point 2921 via an eighteenth electronic fuse 3111 to the supply line 2915, 2910, 2911 by means of a second branch line 3021. The first connection point 2920 is spaced apart from the second connection point 2921. The first connection point 2920 is closer to the power source 2940 than the second connection point 2921.

If both loads 2930 and 2931 are sensitive to damage in the same way, the supply network 3300 should switch off the first load last, because it is more important. In relation to the time of the switch-off event, the computer core 2 of the control device 4 of the seventeenth electronic fuse 3110 therefore switches off the circuit breaker 17 of the seventeenth electronic fuse 3110 with a longer first delay time than the delay time with which the computer core 2 of the control device 4 of the eighteenth electronic fuse 3111 switches off the circuit breaker 17 of the eighteenth electronic fuse 3111.

If both loads 2930 and 2931 are not sensitive to damage in the same way, and the first load 2930 is more sensitive, the supply network 3300 should switch off the first load first, because it is more important, for improved protection. In relation to the time of the switch-off event, the computer core 2 of the control device 4 of the seventeenth electronic fuse 3110 thus switches off the circuit breaker 17 of the seventeenth electronic fuse 3110 with a shorter first delay time than the delay time relative to the switch-off event with which the computer core 2 of the control device 4 of the eighteenth electronic fuse 3111 switches off the circuit breaker 17 of the eighteenth electronic fuse 3111.

The disclosure also describes a supply network 3300, wherein the supply network 3300 comprises at least one supply line 2915, 2910, 2911, a first electrical power source 2940, a second electrical power source 2941, and one or more electrical loads 2930, 2931. The first electrical power source 2940 is connected at a first connection point 2924 via a twenty-first fuse 3120 to the supply line 2915, 2910, 2911. The second electrical power source 2941 is connected at a second connection point 2925 via a twenty-second fuse 3121 to the supply line 2915, 2910, 2911. The first connection point 2924 is spaced apart from the second connection point 2925. The first connection point 2924 is located closer to the one or more electrical loads 2930, 2931 than the second connection point 2925. The computer core 2 of the control device 4 of the twenty-first electronic fuse 3120 switches off the circuit breaker 17 of the twenty-first electronic fuse 3120 with a time delay relative to a switch-off event that is longer than the delay time, with which the computer core 2 of the control device 4 of the twenty-second electronic fuse 3121 switches off the circuit breaker 17 of the twenty-second electronic fuse 3121 relative to a switch-off event.

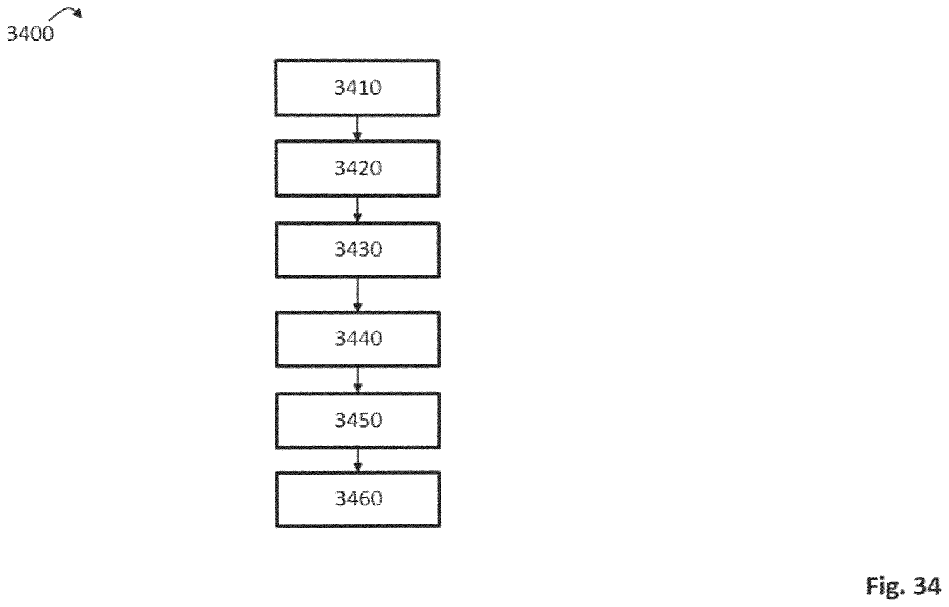

### FIG. 34

FIG. 34 illustrates by way of example and in simplified form a method 3400 for active power management in a supply network 1100 (see FIG. 11) with electrical fuses 1110 to 1118 for supplying electrical loads 1121 to 1125 in this supply network 1100 with electrical power from one or more electrical power sources 1150 to 1155. The cross-over fuses 1110 to 1118 shown in FIG. 11 generally comprise four electronic fuses. The disclosure nevertheless references these fuses here with reference characters 1110 to 1118 to simplify the representation. The proposed method 3400 comprises, among other things, the following steps:

In a first step, the computer cores 2 of the control devices 4 of the electronic fuses detect 3410 the corresponding value of the corresponding electrical currents 29 through one or more of their corresponding circuit breakers 17 of one or more corresponding electronic fuses of the fuses 1110 to 1118 of the supply network 1100. The detection 3410 can also mean the determination of a corresponding value of a corresponding auxiliary current 36 by a corresponding shunt resistor 24 of the corresponding fuse if the corresponding auxiliary current can be essentially proportional to the corresponding current 29 through the corresponding circuit breaker 17 of the corresponding fuse and/or if the computer core 2 of the control device 4 of the corresponding electronic fuse and/or a higher-level computer system 12 can deduce the corresponding value of the corresponding current 29 through the corresponding circuit breaker 17 of the corresponding fuse from the value of the corresponding auxiliary current by means of an already known mathematical relationship.

In a second step, the corresponding computer cores 2 of the control devices 4 of the corresponding fuses detect 3420 the corresponding values of the voltage difference between one or more terminals (26, 27, 28) of the corresponding circuit breaker 17 of the corresponding fuse against a reference potential (201) of a reference potential contact, for example by means of the corresponding analog-to-digital converters 570 of the corresponding control devices 4 of the corresponding fuses.

In a third step, the corresponding computer cores 2 of the control devices 4 of the corresponding fuses optionally calculate 3430 the corresponding theoretical ground offset of the corresponding local reference potential 201 on the control device 4 of the corresponding fuse as a result of the corresponding local energization of the corresponding circuit breakers 17 of the corresponding fuse. For this purpose, the corresponding computer cores 2 of the corresponding control device 4 of the corresponding fuses optionally use a model with a optionally corresponding fuse-specific parameterization.

In a fifth step, the computer cores 2 of the control devices 4 of the corresponding fuses optionally correct 3440 the respective voltage measured values of the corresponding detected voltage values by the calculated value of the corresponding theoretical ground offset to form corresponding corrected voltage value.

The computer cores 2 of the control devices 4 of the fuses optionally transmit their corresponding corrected voltage values to a higher-level computer system 12.

The computer cores 2 of the control devices 4 of the fuses optionally transmit their corresponding measured current values for the corresponding current 29 through the corresponding circuit breaker 17 to a higher-level computer system 12.

The computer cores 2 of the control devices 4 of the fuses optionally transmit these calculated values of the corresponding theoretical ground offsets to a higher-level computer system 12.

The computer cores 2 of the control devices 4 of the fuses optionally also transmit the non-corrected corresponding voltage measured values of the corresponding detected voltage values to a higher-level computer system 12.

As a result, the higher-level computer system 12 can detect any errors that occur in the overall system.

Optionally, a computer core 2 of a control device 4 of a fuse and/or the higher-level computer system 12 deduce 3450 state parameters of supply line sections of the supply line sections (3260 to 3278) of the supply network with the aid of the parameters thus detected, such as current values and voltage values.

For example, such state parameters of a supply line section of the supply line sections 3260 to 3278, which a computer core 2 of a control device 4 of an electronic fuse and/or the higher-level computer system 12 determine, can be a resistance load per unit length of a supply line section of the supply line sections 3260 to 3278 and/or the temperature of a supply line section of the supply line sections (3260 to 3278).

For example, a computer core 2 of a control device 4 of a fuse and/or the higher-level computer system 12 can determine 3460 an estimated temperature of a supply line section with the aid of a known temperature coefficient of the line material of the relevant supply line section of the supply line sections 3260 to 3278 and the known design data, for example the length and the cross section of the supply line section.

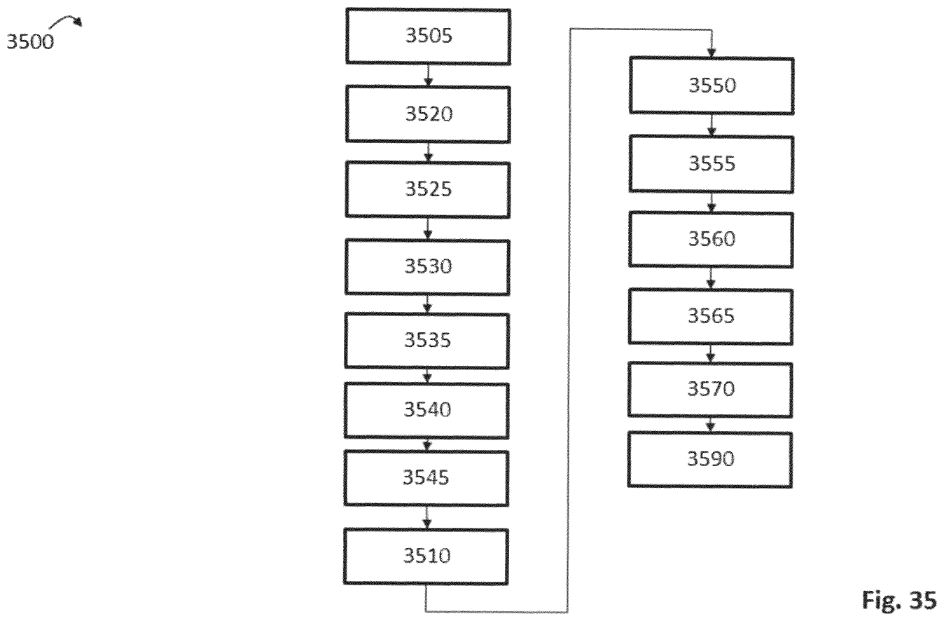

### FIG. 35

FIG. 35 illustrates in a simplified and schematic manner a method 3500 for operating a vehicle with equipment variants, wherein the activation and deactivation of the equipment variants of the vehicle is accomplished at least in part optionally by means of the supply network and by means of the electronic fuses and their circuit breakers 17.

The first step of the proposed method comprises providing 3505 a vehicle having a supply network 3300 (see, for example, FIG. 33) for supplying electrical loads 2930, 2931 of the vehicle with electrical power. The vehicle optionally comprises one or more power sources 2940, 2941, one or more loads 2930, 2931 and a plurality of electronic fuses 2960 to 2963 and 2959 to 2953. The supply lines 2915, 2910, 2911 connect the loads 2930, 2931 to the one power source or the plurality of power sources 2940, 2941. Optionally, the loads 2930, 2931 and the power sources 2940, 2941 are interconnected together with the supply lines 2915, 2910, 2911 in a tree structure 3300 or a supply network. The tree structure comprises sub-trees, or the supply network comprises sub-networks ([2915, 3015, 3025, 2941]; [2940, 3024, 3014, 2910, 3010, 3020, 2930]; [2911, 3011, 2931]). Firstly, electronic fuses (2960 to 2963 and 2959 to 2953) are optionally inserted into supply lines of the supply network, so that the computer cores 2 of the control devices 4 of these electronic fuses (2960 to 2963 and 2959 to 2953) can, by means of their corresponding circuit breakers 17, disconnect corresponding sub-trees of the tree structure from the rest of the tree structure or can connect them to this remaining tree structure.

Secondly, electronic fuses (2916, 2962, 2951, 2952) are optionally inserted into the supply network in supply lines, so that the computer cores 2 of the control devices 4 of these electronic fuses (2960 to 2963 and 2959 to 2953) can, by means of their corresponding circuit breakers 17, disconnect these corresponding sub-networks ([2915, 3015, 3025, 2941]; [2911, 3011, 3021, 2931]) of the supply network 3300 from the rest of the supply network 3300 or connect them to this remaining supply network 3300. As a result, these corresponding sub-networks ([2915, 3015, 3025, 2941]; [2911, 3011, 3021, 2931]) and/or corresponding sub-trees have substantially no more power supply and/or no more power consumption after a corresponding disconnection.

By means of commands of a user 730 via a terminal 740 and/or by commands of a server 710 of a service provider and/or of a vehicle manufacturer or by other access to the higher-level computer system 12 and/or the computer cores 2 of the control devices 4 of fuses of the supply network, programming 3510 of certain specific equipment variants can now take place.

For example, a first equipment variant of these equipment variants of the vehicle should be distinguished from a second equipment variant of these equipment variants of the vehicle.

For example, at least the computer core 2 of the control device 4 of an electronic fuse of these electronic fuses (2916, 2962, 2951, 2952) can disconnect a sub-tree of the tree structure or a sub-network ([2915, 3015, 3025, 2941]; [2911, 3011, 3021, 2931]) of the supply network 3300 in the first equipment variant by means of the circuit breaker 17 of this electronic fuse from the rest of the tree structure or the rest of the supply network 3300 and connect it to the rest of the tree structure or to the rest of the supply network 3300 in the second equipment variant. As a result, the supply network 3300 supplies this sub-tree or this sub-network ([2915, 3015, 3025, 2941]; [2911, 3011, 3021, 2931]) of the supply network 3300 with electrical power of the power sources of the supply network 3300 only in the second equipment variant. In this way, only in the second equipment variant can one or more electrical loads 2931 of the relevant sub-network ([2915, 3015, 3025, 2941]; [2911, 3011, 3021, 2931]) have an electrical power consumption that the supply network 3300 supplies with electrical power via a closed circuit breaker 17 of the relevant electronic fuse only in this second equipment variant.

Optionally, the programming 3510 of certain equipment variants is performed by transmitting programming data to the computer cores 2 of the control devices 4 of electronic fuses of the supply network 3300 via a data bus 9 of the supply network 3300.

Optionally, this communication and/or programming 3510 is accomplished by means of encrypted communication via the control data bus 9 of the supply network 3300 for programming the equipment variants and/or for communicating via the control data bus 9. Optionally, this communication and/or programming 3510 is accomplished by means of the encrypted communication via the control data bus 9 of the supply network 3300 for programming the equipment variants and/or for communicating via the control data bus 9 for programming the equipment variants only after a password has been transmitted to the computer core 2 of the control device 4 of the corresponding electronic fuse.

Optionally, the higher-level computer system 12 communicates and/or the higher-level computer system 12 programs 3510 by means of encrypted communication via the control data bus 9 of the supply network 3300 for programming the equipment variants and/or for communicating via the control data bus 9. Optionally, the higher-level computer system 12 communicates and/or the higher-level computer system 12 programs 3510 by means of the encrypted communication via the control data bus 9 of the supply network 3300 for programming the equipment variants and/or for communicating via the control data bus 9 for programming the equipment variants only after a password is transmitted from the higher-level computer system 12 to the computer core 2 of the control device 4 of the corresponding electronic fuse.

The communication between a computer core 2 of a control device 4 of an electronic fuse and its surroundings thus optionally is performed with encryption via such data connections via the data bus 9 with a PQC method. (PQC=post quantum cryptography);

A server 710 of a service provider and/or of a vehicle manufacturer optionally communicates with the higher-level computer system 12 via an encrypted data line 720. The server 710 and the higher-level computer system optionally use a PQC encrypted communication protocol. The higher-level computer system 12 optionally uses a PQC encrypted communication protocol for data communication via the data bus 9 of the supply network with computer cores 2 of control devices 4 of fuses of the supply network. The computer cores 2 of the control devices 4 of the electronic fuses of the supply network optionally use a PQC encrypted communication protocol for data communication via the data bus 9 of the supply network with computer cores 2 of control devices 4 of fuses of the supply network.

Particularly optionally, these computer cores 2 and/or the higher-level computer system 12 and/or the servers 710, 750 and/or the terminal 740 use one or more of the following methods for PQC encryption:

‘BIKE1-L1-CPA’, ‘BIKE1-L3-CPA’, ‘BIKE1-L1-FO’, ‘BIKE1-L3-FO’, ‘Kyber512’, ‘Ky-ber768’, ‘Kyber1024’, ‘Kyber512-90s’, ‘Kyber768-90s’, ‘Kyber1024-90s’, ‘LEDAcryptKEM-LT12’, ‘LEDAcrypt-KEM-LT32’, ‘LEDAcryptKEM-LT52’, ‘NewHope-512-CCA’, ‘NewHope-1024-CCA’, ‘NTRU-HPS-2048-509’, ‘NTRU-HPS-2048-677’, ‘NTRU-HPS-4096-821’, ‘NTRU-HRSS-701’, ‘LightSaber-KEM’, ‘Saber-KEM’, ‘FireSaber-KEM’, ‘BabyBear’, ‘BabyBearEphem’, ‘Mama-Bear’, ‘MamaBearEphem’, ‘PapaBear’, ‘PapaBearEphem’, ‘FrodoKEM-640-AES’, ‘FrodoKEM-640-SHAKE’, ‘FrodoKEM-976-AES’, ‘FrodoKEM-976-SHAKE’, ‘FrodoKEM-1344-AES’, ‘FrodoKEM-1344-SHAKE’, ‘SIDH-p434’, ‘SIDH-p503’, ‘SIDH-p610’, ‘SIDH-p751’, ‘SIDH-p434-compressed’, ‘SIDH-p503-compressed’, ‘SIDH-p610-compressed’, ‘SIDH-p751-compressed’, ‘SIKE-p434’, ‘SIKE-p503’, ‘SIKE-p610’, ‘SIKE-p751’, ‘SIKE-p434-compressed’, ‘SIKE-p503-compressed’, ‘SIKE-p610-compressed’, ‘SIKE-p751-compressed’.

Particularly optionally, these computer cores 2 and/or the higher-level computer system 12 and/or the servers 710, 750 and/or the terminal 740 use one or more of the following PQC signature methods for signing data messages:

‘DILITHIUM_2’, ‘DILITHIUM_3’, ‘DILITHIUM_4’, ‘MQDSS-31-48’, ‘MQDSS-31-64’, SPHINCS+-Haraka-128f-robust’, SPHINCS+-Haraka-128f-simple’, ‘SPHINCS+-Haraka-128s-robust’, ‘SPHINCS+-Haraka-128s-simple’, ‘SPHINCS+-Haraka-192f-robust’, ‘SPHINCS+-Haraka-192f-simple’, ‘SPHINCS+-Haraka-192s-robust’, ‘SPHINCS+-Haraka-192s-simple’, ‘SPHINCS+-Haraka-256f-robust’, ‘SPHINCS+-Haraka-256f-simple’, ‘SPHINCS+-Haraka-256s-robust’, ‘SPHINCS+-Haraka-256s-simple’, ‘SPHINCS+-SHA256-128f-robust’, SPHINCS+-SHA256-128f-simple’, ‘SPHINCS+-SHA256-128s-robust’, ‘SPHINCS+-SHA256-128s-simple’, ‘SPHINCS+-SHA256-192f-robust’, ‘SPHINCS+-SHA256-192f-simple’, ‘SPHINCS+-SHA256-192s-robust’, ‘SPHINCS+-SHA256-192s-simple’, ‘SPHINCS+-SHA256-256f-robust’, ‘SPHINCS+-SHA256-256f-simple’, ‘SPHINCS+-SHA256-256s-robust’, ‘SPHINCS+-SHA256-256ssimple’, ‘SPHINCS+-SHAKE256-128f-robust’, ‘SPHINCS+-SHAKE256-128f-simple’, ‘SPHINCS+-SHAKE256-128s-robust’, ‘SPHINCS+-SHAKE256-128s-simple’, ‘SPHINCS+-SHAKE256-192f-robust’, ‘SPHINCS+-SHAKE256-192fsimple’, ‘SPHINCS+-SHAKE256-192s-robust’, ‘SPHINCS+-SHAKE256-192s-simple’, ‘SPHINCS+-SHAKE256-256f-robust’, ‘SPHINCS+-SHAKE256-256fsimple’, ‘SPHINCS+-SHAKE256-256s-robust’, ‘SPHINCS+-SHAKE256-256s-simple’,m'picnic_L1_FS’, ‘pic-nic_L1_UR’, ‘picnic_L3_FS’, ‘picnic_L3_UR’, ‘picnic_L5_FS’, ‘picnic_L5_UR’, ‘pic-nic2_L1_FS’, ‘picnic2_L3_FS’, ‘picnic2_L5_FS’, ‘qTesla-p-I’, ‘qTesla-p-III’.

The activation and/or deactivation of an electronic fuse, i.e., the switching on or off of the circuit breaker 17 of the electronic fuse, optionally requires the transmission of a digital password from the computer core 2 of the control device 4 of a different electronic fuse and/or from the computer 12 of a controller, i.e., for example from the higher-level computer system 12, and/or from a server 710 of a service provider and/or of an automobile manufacturer via a data bus 9 to the computer core 2 of the control device 4 of the electronic fuse. Optionally, the computer core 2 of the control device 4 of the electronic fuse verifies the received passwords and commands before their execution. In this case, it optionally checks for the correctness of the content, for example whether the password matches the commands and/or for admissibility of the commands, for example whether the correct participants of the supply network are also permitted for the input of these commands and/or whether the participants of the supply network are also the participants that they specify to be, and/or whether the commands are allowed and/or useful in the current usage situation and/or the current state of the vehicle and/or of the supply network. If this check by the computer core 2 of the control device 4 of the fuse is successful, the computer core 2 of the control device 4 of the fuse executes the command.

It is part of the proposal presented in this document to use the supply lines of the supply network itself as lines of the data bus 9 of the supply network. In particular, the vehicle and/or the supply network and/or device parts thereof can use data communication via the supply lines of the supply network as emergency communication if the normal data bus 9 is faulty. The document proposed here furthermore proposes to use a supply voltage line 6 for supplying the electronic fuses with electrical power also for such power-line communication as emergency operation of the fuse data bus. In this case, such a supply voltage line 6 is a part of a fuse data bus 9. In this case, the communication takes place via this data bus 9 by power-line communication. This emergency communication via the supply voltage line 6 can be communication of at least two computer cores 2 of at least two control devices 4 of two electronic fuses among one another and/or between a computer core 2 of a control device 4 of an electronic fuse, on the one hand, and a higher-level computer system 12, on the other hand, via this data bus 9.

In order to minimize switchover and switch-on currents, it is expedient if, after the change of an equipment variant due to programming of a new equipment variant, the fuses that have to change their switching state for this equipment variant change, i.e., at least two electronic fuses, better all affected electronic fuses, change their switching state in a time-delayed manner relative to one another, and essentially do not simultaneously change their switching state. For example, the higher-level computer system 12 can signal to the computer cores 2 of the control devices 4 of these affected fuses of the supply network what time value of the corresponding timer 35 of the corresponding control device 4 of the corresponding fuse of which computer core 2 of which control device 4 of which fuse is intended to change the switching state of which of its circuit breakers 17.

Because the higher-level computer system 12 can communicate to the computer cores 2 of the control devices 4 of the fuses at what instant, i.e., the time value of its corresponding timers 35, they are intended to bring their corresponding circuit breaker 17 into which switching state (closed vs. open), it is conceivable that the higher-level computer system 12 of the vehicle programs a predefined sequence of equipment variants at certain time intervals in predetermined operating states. This then means for the individual computer core 2 of a control device 4 of a fuse that the higher-level computer system specifies to this computer core 2 of the control device 4 of a fuse a sequence of switching states of the circuit breaker 17 of this fuse, wherein the higher-level computer system optionally specifies, for each equipment variant to be adopted, a switching state to be adopted of the circuit breaker 17 of the fuse to the computer core 2 of the control device 4 of the fuse together with the instant, i.e., the timer value of the timer 35, at which the computer core 2 of the control device 4 of the fuse is to bring the circuit breaker 17 of the fuse into this state. Optionally, the higher-level computer system 12 transmits only the changes in the switching state of the circuit breaker 17 of the relevant fuse and the planned instant of the switching state change to the computer core 2 of the control device 4 of the fuse 1.

After the vehicle is switched on, the higher-level computer system 12 optionally transfers the vehicle from the parking state into the driving state by programming at least two equipment variants at two different programming instants within a time interval different from 0 s between the programming instants. Within the meaning of the disclosure, the parking state of the supply network of the vehicle and the driving state of the supply network of the vehicle are equipment variants.

Because the programming of a sequence of equipment variants under certain circumstances requires a certain time, the higher-level computer system optionally determines a time reference point to which the programmed switching instants relate for the equipment variant change. For this purpose, the higher-level computer system 12 optionally transmits to the computer cores 2 of the control devices 4 of the relevant electronic fuses a start signal optionally at the same time via the data bus 9, whereupon these electronic fuses generate the sequence of the equipment variants for the corresponding electronic fuse and optionally set it in a timely manner.

The higher-level computer system 12 optionally programs beforehand, before the start signal is transmitted, the values of waiting times which the computer cores 2 of control devices 4 of the electronic fuses are intended to wait between the arrival of the start signal from the higher-level computer system 12 and the closing or opening of its corresponding circuit breaker 17 in the memories of the computer cores 2 of the control devices 4 of the fuses and/or the memories of the control devices of the fuses.

Optionally, the higher-level computer system 12 or a different computer 710, 2 programs these values of the waiting times into a non-volatile memory 14 of the control devices 4 of the relevant electronic fuses.

Optionally, at least parts of this programming are carried out at the factory and/or by the higher-level computer system 12 and/or a different computer of the vehicle, thus also by the control device (4) of a different electronic fuse.

The disclosure also describes, inter alia, a method 3500, which additionally provides that the higher-level computer system 12 and/or a computer core 2 of a control device 4 of a fuse and/or a terminal 740 of a user 730 (with user input) and/or a different computer of the vehicle transmit 3520 authentication data to a server 710 of an activation code provider.

Optionally, the server 710 of an activation code provider or a different computer verifies 3525 the authentication data transmitted to the server 710 of an activation code provider.

The server 710 of an activation code provider and/or a computer of a subcontractor of the activation code provider generate 3530 an activation code with the aid of these or other authentication data according to an established method and/or provide the generated or a ready-at-hand activation code.

If the activation code provider requires a payment of the activation, a purchase (3535) of an activation code is then carried out via a data connection from the terminal 740 of the user 730 and/or from the higher-level computer system 12 and/or from a computer core 2 of a control device 4 of a fuse to the server 710 of the activation code provider.

Optionally, the terminal 740 of the user 730 and/or the higher-level computer system 12 and/or the computer core 2 of the control device 4 of the fuse transmit, to the server 710 of the activation code provider, the necessary data to carry out the billing and the data for verifying the consent of the paying person or institution for the conclusion of the contract and the execution of the contract.

If the data for the execution of the contract are correctly and completely verified and, where applicable, also successfully verified, the server 710 of the activation code provider transmits 3540 the activation code or codes to the higher-level computer system 12 of the vehicle and/or to one or more computer cores 2 of one or more control devices 4 of one or more fuses of the vehicle and thus to the vehicle. If necessary, a program of the terminal 740 of the user 730 logs this successful transmission of one or more activation codes.

Such a transmission can result in the transmission (3545) of one or more activation codes for one or more equipment variants on the basis of the obtained activation codes to the computer cores 2 of the control devices 4 of the affected electronic fuses by the higher-level computer system 12.

Optionally, the higher-level computer system 12 and/or the computer cores 2 of the control devices 4 of the fuses program 3510 the activated equipment variants if the verification of these activation codes is successful.

The disclosure also describes, inter alia, a method 3500, which additionally provides that the computer cores 2 of the control devices 4 of fuses detect 3550 and determine the power that flows through an electronic fuse in a supply sub-branch ([2915, 3015, 3025, 2941]; [2911, 3011, 3021, 2931]) of the supply tree 3300 as a measured value of the amount of power and/or of the underlying measured values in the electronic fuse.

Optionally, the higher-level computer system 12 or another computer of the supply network or of the vehicle reads 3555 the measured value of the determined amount of power and/or of the underlying measured values from the computer core 2 of the control device of the relevant electronic fuse via the data bus 9.

Optionally, the higher-level computer system 12 transmits 3560 the measured value of the determined amount of power and/or the underlying measured values over a data transmission path 720, which is optionally encrypted, from the higher-level computer system 12 to a computer 750 of a service provider, for example a utility company or its subcontractors.

The service provider and/or a subcontractor thereof, optionally create 3565 an invoice on the basis of the transmitted measured value or the transmitted measured values of the determined amount of power and/or the underlying measured values.

The disclosure proposes to check the structural and functional integrity of the supply network during and/or at the beginning of and/or at the end of a driving operation of the vehicle.

For this purpose, the higher-level computer system 12 determines 3570 the topology of the supply network using the electronic fuses of the supply network. For example, the higher-level computer system 12 can here cause power sources in the supply network to feed test currents in a targeted manner and cause loads in the supply network to receive these test currents in a targeted manner. The computer cores 2 of the control devices 4 of the fuses through which these test currents flow can detect them and signal the detected measured current values to the higher-level computer system 12.

The higher-level computer system 12 determines a topology of the supply network on the basis of the measured values obtained by the computer cores 2 of the control devices 4 of the fuses.

Optionally, the higher-level computer system 12 compares 3575 the topology thus determined of the supply network with the equipment variant that is valid or to be set for checking plausibility of the present equipment variant or the admissibility of the determined topology of the supply network.

If the determined topology does not correspond to an admissible topology, the higher-level computer system 12 can transmit this to the server 710 of an automobile manufacturer and/or service provider. Another possible measure in such a case is that the higher-level computer system 12 switches off supply sub-networks of the supply network by means of corresponding commands to the computer cores 2 of the control devices 4 of corresponding fuses or otherwise limits them in their function.

A further variant of the method presented can comprise the detection of values for currents 29 through circuit breakers 17 of electronic fuses by the control devices 4 of these fuses in the supply network, and calculating or providing expected value intervals for these currents 29 through these circuit breakers 17 of electronic fuses in the supply network.

The higher-level computer system 12 optionally checks the plausibility of the supply network with the supply lines and the loads and the power sources and the electronic fuses by comparing the current values detected by the control devices 4 of the fuses in the supply network to calculated or provided expected value intervals.

Typically, the higher-level computer system 12 deduces a manipulation of the supply network and/or a manipulation of an electrical load in the supply network and/or a manipulation of an electrical power source in the supply network and/or a manipulation of a supply line in the supply network and/or the manipulation of an equipment variant if the above-described plausibility check has failed.

The disclosure also proposes a method for lowering the starting current (in-rush current). The computer cores 2 of the control devices 4 of the fuses optionally detect the values of the starting currents in the supply network by means of the measuring means of these fuses. The higher-level computer system 12 optionally collects these current values via the data bus 8 from the computer cores 2 of the control devices 4 of the fuses in the supply network. The higher-level computer system 12 optionally causes a change of the equipment variant to one having an equipment variant with increased current consumption of other loads if the magnitude of the starting current is below a threshold value after a waiting time has elapsed.

Optionally, the higher-level computer system 12 thus begins with an equipment variant in which the supply network is optionally substantially supplied with electrical power to that load which causes the in-rush current. The supply network then optionally does not supply loads having low priority with electrical power, or supplies them with electrical power to a limited extent, at the beginning.

### FIG. 36

FIG. 36 is intended to represent possible levels of a data protocol on the data bus 9 of the supply network 200. In the example of FIG. 36, the data bus 9 is a bidirectional and differential data bus 9 that comprises a first one-wire data bus and a second one-wire data bus. The information is optionally transmitted by means of the voltage difference between the electrical potential of the first one-wire data bus minus the second electrical one-wire data bus. This has the advantage that a ground offset possibly acting as common mode interference does not affect the transmitted data. In its preferred role as a bus master, the higher-level computer system 12 has a first driver with which it can bring the first one-wire data bus of the differential data bus 9 into a first state Z1 or a second state Z2 or a third state Z3. A first driver can optionally assume two of three permitted states as a CAN driver: In a first state, it sets a first logic level Z1 on the first one-wire data bus of the differential, bidirectional data bus 9. In a second state, it sets a third logic level Z3 on the first one-wire data bus of the differential, bidirectional data bus 9. In addition, in the addressing state of the data bus system and of the computer cores 2 of the control devices 4 of the electronic fuses of the supply network 200, the first driver of the higher-level computer system 12 operates optionally as a first current sink for the first addressing currents of the first addressing current sources of the data interfaces 10 of the control devices 4 of the electronic fuses. (In FIGS. 2 and 3, these would be the electronic fuses 214 to 217 and 225 to 225 and 235 to 238 and 255 and 256). The first driver of the data interface 10 of the control device 4 of an electronic fuse or of the higher-level computer system 12 optionally assumes the first state Z1 if the second driver of the relevant data interface 10 of the relevant control device 4 of the relevant fuse assumes the second state Z2. As a result, the signal is impressed differentially with a first differential level z1 on the differential and bidirectional data bus 9. The first driver of a data interface 10 of a control device 4 of a fuse of the supply network 200 or of the higher-level computer unit 12 optionally assumes the third state Z3 if the second driver of the relevant data interface 10 of the relevant control device 4 of the relevant electronic fuse of the supply network 200 assumes the third state Z3. As a result, the signal is impressed differentially with a third differential level z3.

The first driver can also optionally assume two of two permitted states as an RS485 driver: In a first state, it applies a first logic level Z1 to the first one-wire data bus. In a second state, it applies a second logic level Z2 to the first one-wire data bus. The first driver of the higher-level computer system 12 also operates in the addressing state of the data bus system and the fuses as the first current sink for the first addressing currents of the addressing current sources of the data interfaces 10 of the control devices 4 of the fuses of the supply network 200 and the quiescent currents thereof. The first driver of a data interface 10 of a control device 4, of a fuse of the supply network 200, or of the higher-level computer system 12 assumes the first state Z1, if the second driver of the relevant data interface 10 assumes the second state Z2. As a result, the signal is impressed differentially with a first differential level z1 on the differential, bidirectional data bus 9. The first driver of a data interface 10 or of the higher-level computer system 12 optionally assumes the second state Z2 if the second driver of the relevant data interface 10 or of the higher-level computer system 12 assumes the first state Z1. As a result, the signal is impressed differentially with a second differential level z2. In addition, the first driver typically has a sub-device for detecting and avoiding a bus collision in the event of simultaneous access to the first one-wire data bus by a first driver of another data bus interface 10 of a different fuse or of the higher-level computer system 12.

A second driver as a CAN driver can optionally assume two of three permitted states as a driver of a data interface 10 or of the higher-level computer system 12: In a first state, it applies a second logic level Z2 to the second one-wire data bus. In a second state, it applies a third logic level Z3 to the second one-wire data bus. In addition, in the addressing state of the data bus system and of the data interfaces 10 of the fuses, the second driver of the higher-level computer system 12 operates as a second current sink for the second addressing currents of the second addressing current sources of the data interfaces of the fuses and the second quiescent currents thereof. The second driver of a data interface 10 of a control device 4 of a fuse or of the higher-level computer system 12 optionally assumes the second state Z2 if the first driver of the relevant data interface 10 of the relevant control device 4 of the relevant fuse assumes the first state Z1. As a result, the signal is impressed differentially with a first differential level z1. The second driver of a data interface 10 of a fuse or of the higher-level computer system 12 optionally assumes the third state Z3 if the first driver of the relevant data interface 10 of the relevant control device 4 of the relevant fuse assumes the third state Z3. As a result, the signal is impressed differentially with a third differential level z3.

The second driver can also optionally assume two of two permitted states as an RS485 driver: In a first state, it applies a second logic level Z2 to the first one-wire data bus. In a second state, it applies a first logic level Z1 to the second one-wire data bus. In addition, in the addressing state of the data bus system and of the data interfaces 10 of the control devices 4 of the fuses of the supply network 200, the second driver of the higher-level computer system 12 operates as a second current sink for the second addressing currents of the second addressing current sources of the data bus interfaces 10 of the control devices 4 of the fuses and the second quiescent currents thereof. The second driver of a data bus interface 10 of a control device 4 of a fuse or of the higher-level computer system 12 optionally assumes the second state Z2 if the first driver of the relevant data bus interface 10 of the relevant control device 4 of the relevant fuse assumes the first state Z1. As a result, the signal is impressed differentially on the data bus 9 with a first differential level z1. The second driver of a data interface 10 of a control device 4 of a fuse or of the higher-level computer system 12 optionally assumes the first state Z1 if the first driver of the relevant data interface 10 of the relevant control device 4 of the relevant fuse assumes the second state Z2. As a result, the signal is impressed differentially on the data bus 9 with a second differential level z2.

In addition, the second driver typically has a sub-device for detecting and avoiding a bus collision in the event of simultaneous access to the first one-wire data bus by a second driver of a different data bus interface 10 of a different control device 4 of a different fuse or of the higher-level computer system 12.

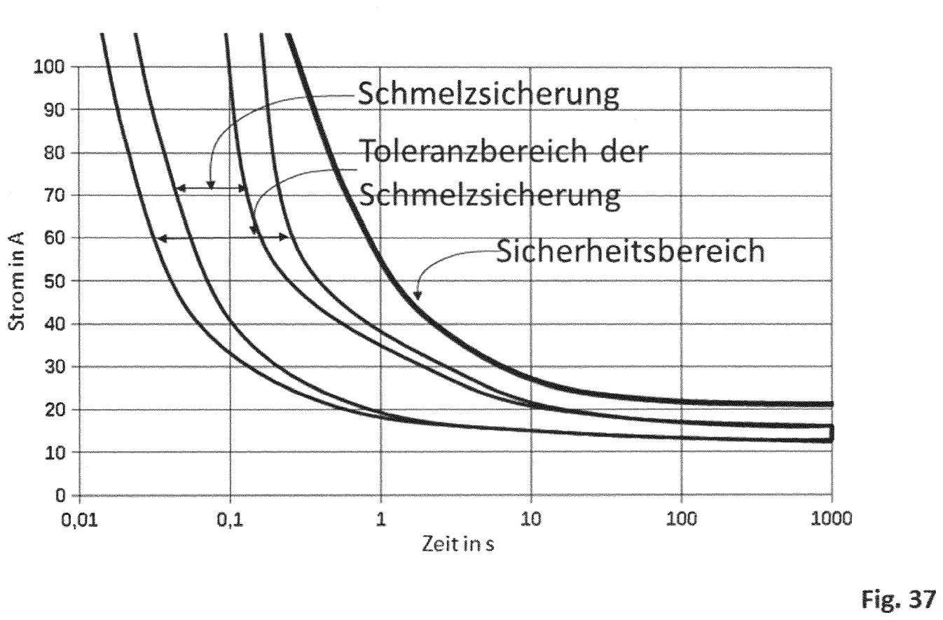

### FIG. 37

FIG. 37 shows the present-day protection of the cable of a supply line section.

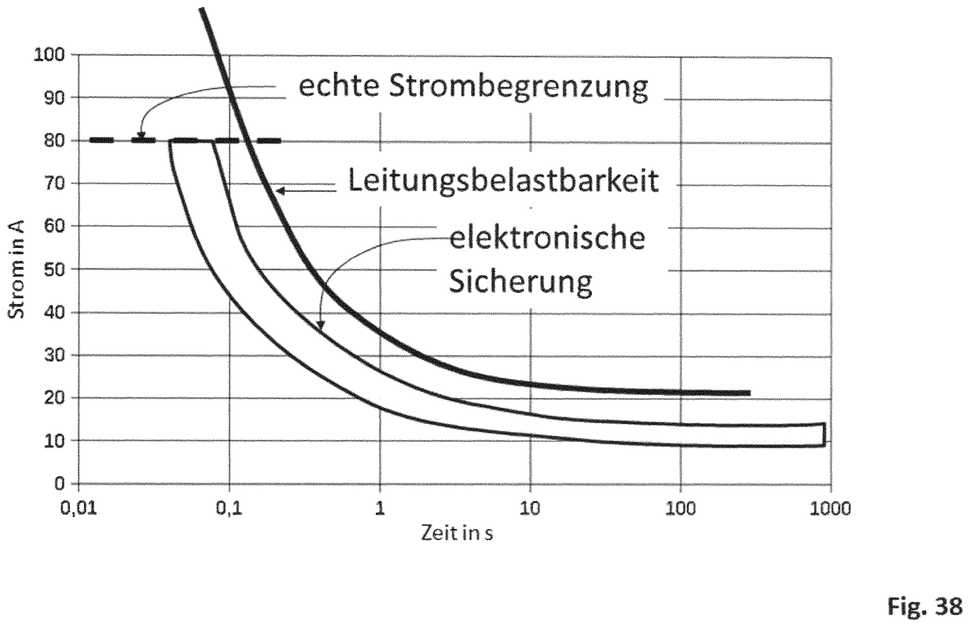

### FIG. 38

FIG. 38 shows the advantages of protecting a supply line section with an electronic fuse.

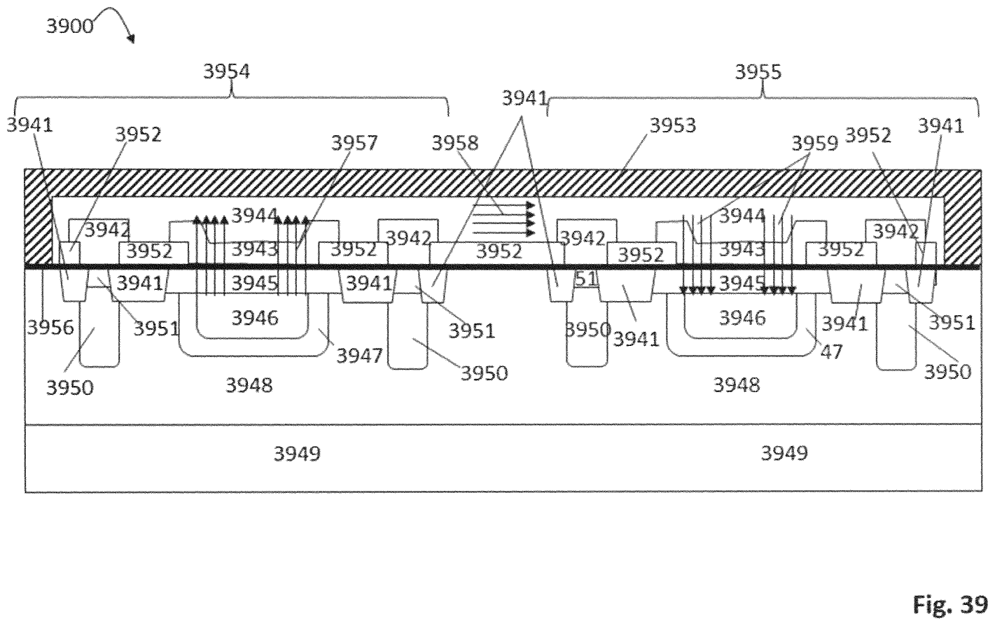

### FIG. 39

FIG. 39 shows the combination of two SPAD diodes according to the proposal in cross section.

The semiconductor crystal of the control device 4 of the fuse 1 optionally has at least one first SPAD diode 5394 and at least one second SPAD diode 3955 and at least one optical waveguide 3944. The quantum random number generator 4100, 60 is optionally a quantum-process-based generator for true random numbers (QRNG) 60. The quantum-process-based generator for true random numbers (QRNG)60 optionally comprises a first SPAD diode 3954 as a light source for an optical quantum signal and a second SPAD diode 3955 as a photodetector for the optical quantum signal. Furthermore, the quantum-process-based generator for true random numbers (QRNG) 60 optionally comprises at least the processing circuit and the optical waveguide 3944. The at least one optical waveguide 3944 optionally optically couples the at least one first SPAD diode 3954 to the at least one second SPAD diode 3955. An operating circuit supplies the first SPAD diode 3954 with electrical power in such a manner that the first SPAD diode 3954 emits light. The emission of light requires that the operating voltage provides sufficient electrical bias of the first SPAD diode 354 (4104.1). A processing circuit (4102, 4103, 4104) detects the signal of the second SPAD diode 3955 (4104.3) and forms the random number therefrom. The processing circuit then optionally provides the random number thus formed to one or more of the one or more processors, in particular the computer core 2 of the control device 4 of the fuse 1, via a data bus 11.

The semiconductor crystal of the control device 4 of the fuse 1 optionally has a surface 3956. Typically, the semiconductor crystal has a semi-conducting material below its surface 3956. Particularly when conventional semiconductor circuit manufacturing processes, such as CMOS processes, bipolar processes, and BiCMOS processes are used, the surface 3956 of the semiconductor crystal typically has a metallization stack as structured metal layers and electrical insulation layers. The structured metal layers typically form the conductor tracks which are electrically disconnected from one another by the insulation layers. Thus, the metallization stack has a typically structured and optically transparent and electrically insulating layer 3944. At least a section of this typically structured, transparent and electrically insulating layer 3944 of the surface 3956 optionally forms the optical waveguide 3944. The first SPAD diode 3954 typically radiates light 3957 from the semi-conducting material of the semiconductor substrate into this optical waveguide 3944. That is, in contrast to the prior art, the first SPAD diode 3954 usually radiates substantially upward, perpendicular to the surface 3956 and not to the side into the semiconductor substrate of the semiconductor crystal, which has a high attenuation. Nevertheless, the emission of the photons 3957 of the first SPAD diode 5394 in the optical waveguide 3944 is not directed. In particular, the emission via the substrate 3948, 3949 is very attenuated, because visible light has a very high absorption. As a result, the device can couple more photons of the first SPAD diode 3954 directly to the second SPAD diode 5395. Compared to the prior art, the optical waveguide 3944 transports these photons 3957, 3958, 3959 of the first SPAD diode 3954 in the optical waveguide 3944 in a practically loss-free manner to the second SPAD diode 3955. The optical waveguide 4394 irradiates the second SPAD diode 3955 with these photons 3957, 5398, 3959 of the first SPAD diode 5394 in such a way that the light 5399 from inside the optical waveguide 3944 penetrates from the surface 3956 back into the semi-conducting material of the semiconductor substrate and there impinges device parts of the second SPAD diode 3955. The second SPAD diode 3955 then generates a received signal depending on the irradiation with these photons 59.

Typically, at least one operating circuit supplies the at least one first SPAD diode 3954 with electrical power at least at times. When supplying sufficient electrical power, the at least one first SPAD diode 3954 then feeds photons 3957 into the at least one optical waveguide 3944. The optical waveguide 3944 then further transports these photons 3957, 3958, 3959. The at least one optical waveguide 3944 then radiates the transported photons 3958 as photons 3959 that move substantially perpendicularly to the second SPAD diode 3955. Because this transport of the photons from the first SPAD diode 3954 to the second SPAD diode 3955 due to the low attenuation in the optical waveguide 3944 loses significantly fewer photons than in the design from the prior art, which uses the strongly absorbing semiconductor substrate 3949, 3948, the quantum efficiency is massively higher. This increases the bit rate at which the device can generate random numbers. Therefore, in the design presented here, a pair made up of a single first SPAD diode 3954 and a single second SPAD diode 3955 is already sufficient. The prior art always uses a plurality of SPAD diodes.

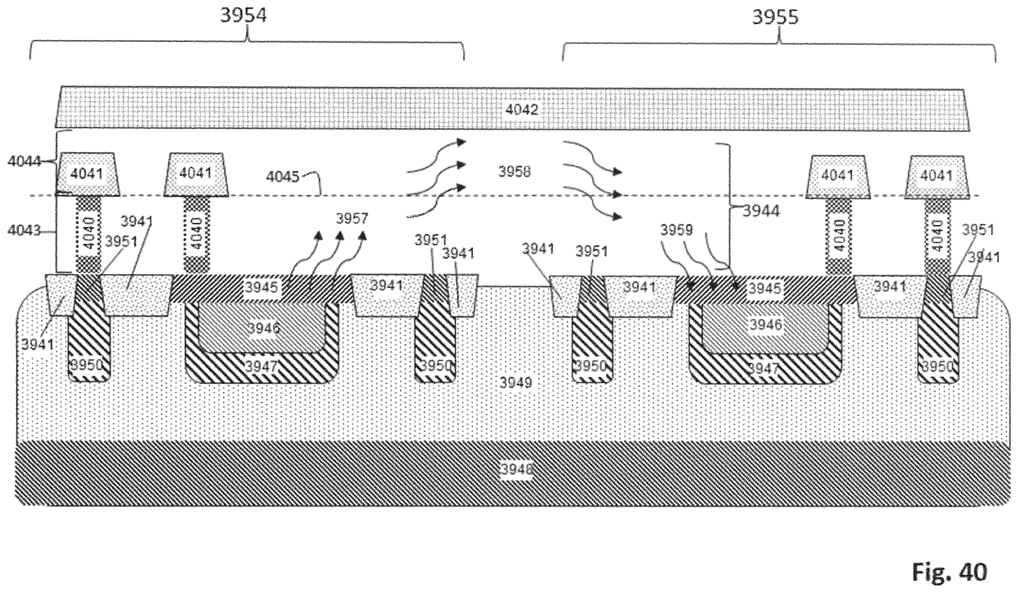

### FIG. 40

FIG. 40 shows the combination of two proposed SPAD diodes in cross section, wherein a plurality of isolation layers now forms the optical waveguide 3944.

FIG. 40 substantially corresponds to FIG. 39. In contrast to FIG. 39, the semiconductor crystal 3948 and the epitaxial layer 3949 are now covered with a first optically transparent insulation layer, for example an oxide layer 4043. The vias 4040 are electrically conductively filled with metal. These vias 4040 contact the metallization level 1 with the electrical lines of the first wiring level 4041. A second optically transparent insulation layer 4044, optionally also in the form of an oxide layer, is applied to this first insulation layer 4042 and the first metallization layer with the first wiring level 4041. This can also be contacted by vias which are not shown in FIG. 7, so that lines of the first metallization level can be connected to lines of the second metallization level. The boundary surface 4045 shown in dashed lines between the first optically transparent insulation layer 4043 and the second optically transparent insulation layer 4044 is substantially also optically transparent and optionally substantially does not reflect and/or absorb the light of the first SPAD diode 3955. The first optically transparent insulation layer 4043 and the second optically transparent insulation layer 4044 substantially form the optical waveguide in the region of the first SPAD diode 3954 and the second SPAD diode 3955. Optionally, no vias 4040 and no metal lines 4041 are located in the optical path between the first SPAD diode 3954 and the second SPAD diode 3955, so that the light of the first SPAD diode 3954 can reach the second SPAD diode 3955 unhindered. A metal cover 4042 prevents photons from escaping upward and optionally reflects them back into the optical waveguide 3944. The vias 4040 and the metal lines of the first metallization level 4041 in a similar way prevent light from the optical waveguide from being lost in the horizontal.

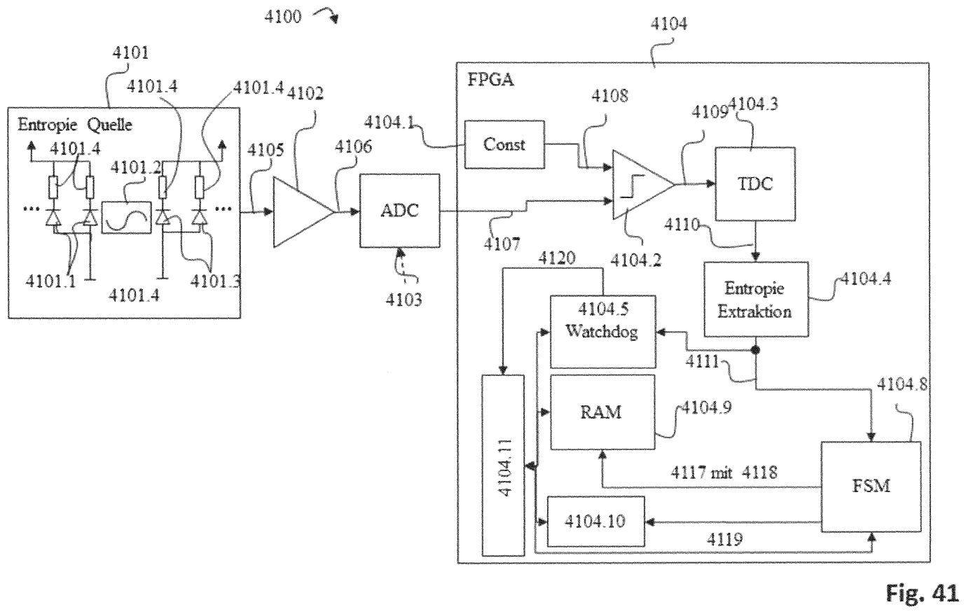

### FIG. 41

FIG. 41 schematically shows the simplified block diagram of a quantum-based random generator 4100 as it corresponds to the proposal of this document.

In FIG. 41, for better clarity, not all appropriate and in some cases customary device components of the control device 4 are shown. Further device components that the reader can assume to be possibly present in FIG. 1 can be found, for example, in FIGS. 1, 5, 6, 9, 24, 42, 52, 53, 54, 55, 57, 58 and 62. The combination of the device parts of the Figure described here with those of these figures is expressly part of the disclosure of the disclosure.

A optionally common clock pulse optionally clocks the digital circuits of the device shown by way of example in FIG. 41. The quantum random number generator 60,4100 of FIG. 41 is optionally part of the control device 4 of the fuse 1. The structure includes an entropy source 4101, optionally a broadband 40 dB high-frequency amplifier 4102 or the like, an analog-to-digital converter 4103, which may optionally also be identical to the analog-to-digital converter 570 or only an inverter or the like. In experiments, an analog-to-digital converter 4103 with a resolution of 14 bits and a sampling rate of 125 MS/s and with an evaluation device 4104, which essentially comprises sub-devices of the control device 4 of the fuse 1, has proven effective.

The entropy source 4101 of the quantum random number generator 4100, 60 typically comprises an array of single-photon avalanche diodes (SPAD). The quantum random number generator 4100 operates the SPADs optionally in so-called Geiger mode with a supply voltage above the breakdown voltage. In addition, a quenching resistor 4101.4 is optionally connected in series for each SPAD diode 4101.1, 4101.3. The quenching resistor 4101.4 prevents thermal destruction of the corresponding SPAD diode 4101.1, 4101.3 in the event of a triggered charge carrier avalanche. The current signal of the second single-photon avalanche diodes 4101.3 is measured via a shunt resistor 4101.4 for this second SPAD diode 4101.3. In the example of FIG. 41, the series resistor for limiting the current intensity (quenching resistor 4101.4) through the respective SPAD diodes 4101.1 and 4101.3 forms the shunt resistor 4101.4. However, the shunt resistor 4101.4 can be inserted independently of the quenching resistor 4101.4 into the supply line of the corresponding SPAD diode 4101.1, 4101.3. An exemplary array of SPAD diodes, in the example of FIG. 41, comprises by way of example four active first SPAD diodes 4101.1 and twelve passive second SPAD diodes 4101.3. The four active, first SPAD diodes 4101.1 and twelve passive, second SPAD diodes 4101.3, for example, are optionally coupled via an optical waveguide 4101.2. The active first SPAD diodes 4101.1 emit individual light pulses spontaneously and randomly. They correspond to the first SPAD diode 3954 of FIGS. 39 and 40. The active first SPAD diodes 4101.1, 3954 are optionally located in the interior of the array of first and second SPAD diodes 4101.1 and 4101.3. The proposed device supplies the active first SPAD diodes 4101.1 with an increased supply voltage and therefore optionally operates the active, first SPAD diodes 4101.1 far above the breakdown voltage of the first SPAD diodes 4101.1, 3954. This increases the dark count rate, which results in a higher number of spontaneously emitted photons 3957. The optical waveguide 4101.2, 3944 passes on some photons 3958 of the emitted photons 3957 to the passive, second SPAD diodes 4101.3, 3955. The optical waveguide 4101.2, 3944 corresponds to the optical waveguide 3944 of FIGS. 39 and 40. The passive, second SPAD diodes 4101.3 correspond to the second SPAD diode 3955 of FIGS. 39 and 40. The proposed device supplies the passive, second SPAD diodes 4101.3, 3955 with an increased supply voltage. The proposed device therefore operates the passive, second SPAD diodes 4101.3, 3955 only just above the breakdown voltage. The passive, second SPAD diodes 4101.3, 3955 are optionally arranged as a ring around the active, first SPAD diodes 4101.2, 3954. The passive, second SPAD diodes 4101.3, 3955 detect at least a portion of the photons 3959 arriving via the optical waveguide 4101.2, 3944. The passive, second SPAD diodes 4101.3, 3955 generate a current flow via a shunt resistor, which is associated with the second SPAD diodes 4101.3, 3955, depending on the incoming photons 3959. The entropy source 4101 optionally comprises the shunt resistors, operating device of the SPAD diodes, the SPAD diodes 4101.1 and 4101.3, and the optical waveguide 4101.2. A voltage signal 4105 of the entropy source 4101 optionally connects the entropy source 4101 to a preferred, exemplary, broadband 40 dB high-frequency amplifier 4102. Optionally, the voltage signal corresponds to the voltage drop across the quenching resistor 4101.4, which in the example of the figure functions as a shunt resistor 4101.4. The proposed, exemplary high-frequency amplifier 4102 has, optionally and by way of example, a bandwidth of 30 to 4000 MHz and optionally a 1-dB compression point of 20 dBm. The voltage range of the voltage signal 4105 of the entropy source 4101 typically moves in the sub-millivolt range. The high-frequency amplifier 4102 proposed by way of example amplifies, for example, the voltage range of this voltage signal 4105 of the entropy source 4101 to, for example, 50 to 150 mV.

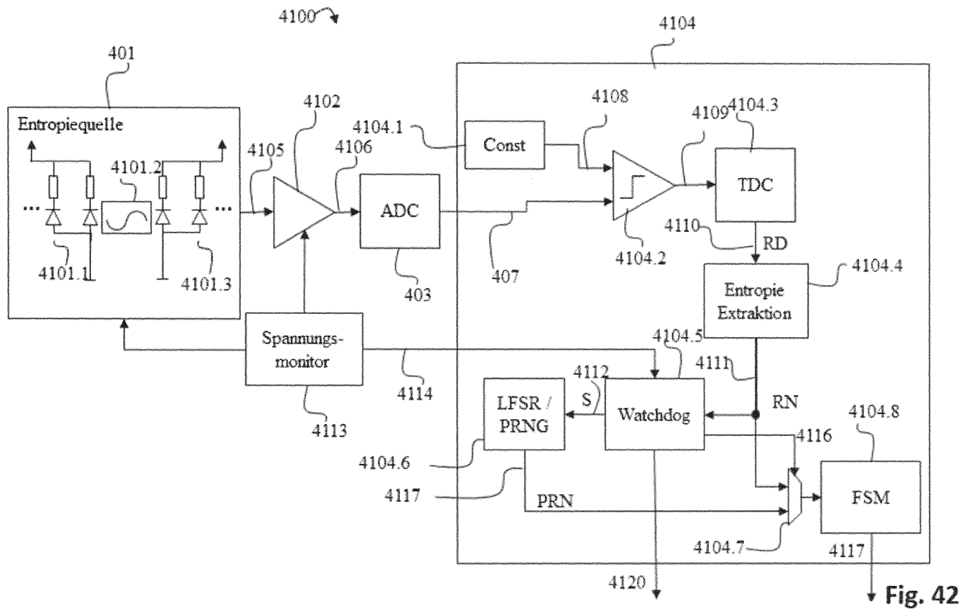

An amplifier output signal 4106 of the high-frequency amplifier 4102 connects, for example, the exemplary high-frequency amplifier 4102 to an exemplary evaluation device 4104 which essentially comprises sub-devices of the control device 4 of the fuse 1. The evaluation device 4104 of FIG. 41 is only one of many different implementations of the technical teaching presented in this document. The evaluation device 404 is a microcontroller. The microcontroller is optionally the computer core 2 of the fuse 1. In the examples of FIGS. 41 and 42, the evaluation circuit 4101 has an exemplary 14-bit analog-to-digital converter (ADC) 4103, 570 with an exemplary sampling rate of 125 mega samples/s and an exemplary bandwidth of 50 MHz. It has been shown in development that lower bit widths and lower sampling rates are possible. In some cases, analog preprocessing before digitization by the analog-to-digital converter 4103, 570 by means of circuits for pulse broadening is expedient. The amplified voltage signal of the exemplary high-frequency amplifier 4102 is the amplifier output signal 4106 of the high-frequency amplifier 4102. The analog-to-digital converter 4103, 570 samples the amplifier output signal 4106 of the high-frequency amplifier 4102 with a sampling rate of the analog-to-digital converter 4103, 570. The analog-to-digital converter 4103, 570 forwards, for example, the determined sampling values of the amplifier output signal 4106 of the high-frequency amplifier 4102 to the evaluatio device 4104 digitally with a bus width of, for example, 14 bits.

The device shown as a block diagram of the device shown in simplified form in FIG. 41 contains, by way of example, a comparator 4104.2, a time-to-digital converter (TDC) 4104.3, an entropy extraction device 4104.4 and a finite state machine 4104.8.

In the example of FIG. 41, the comparator 4104.2 compares the exemplary digital 14-bit value 4107 of the analog-to-digital converter 4103, 570 to a constant 4104.1, which represents a threshold value, and generates a two-clock-pulse-long 1-bit output pulse on its output signal 4109 of the comparator 4104.2 if the value of the analog-to-digital converter 4103 is greater than the constant 4104.1. The output signal 4109 of the comparator 4104.2 connects the comparator 4104.2 to the time-to-digital converter 4104.3. The time-to-digital converter 4104.3 optionally consists of, for example, a 32-bit counter which increments in the clock pulse of the evaluation device 4104. The oscillator 30 and the clock-pulse system of the control device 4 typically provide this clock pulse. The bit width of this counter can deviate depending on the application. For example, this clock pulse can have a frequency of 125 MHz. The 1-bit output signal of the comparator 4104.2 optionally resets the counter reading of this counter. The time-to-digital converter 4104.3 applies the counter reading present at this instant immediately before the reset to the output 4110 of the time-to-digital converter (TDC) 4104.3. The counting result has a resolution of 1/(125 MHz)=8 ns at an exemplary 125 MHz clock pulse. The output 4110 of the time-to-digital converter (TDC) 4104.3 forwards the exemplary 32-bit counting result, also called raw data, of the time-to-digital converter 4104.3 to the entropy extraction 4104.4 following in the signal path. The entropy extraction 4104.4 converts the random raw data RD of the time-to-digital converter (TDC) 4104.3 on the signal of the output 4110 of the time-to-digital converter (TDC) 4104.3 into a 1-bit random number 4111 RN. The output 4111 of the entropy extraction 4104.4 is connected to the input of the finite state machine FSM 4104.8.

The finite state machine 4104.8 typically has the task of receiving data in the form of a serial stream of random bits 4111 from the entropy extraction 4104.4, converting the serial stream of random data bits into random data words and saving these into the block RAM 4104.9 of the evaluation device 4104, which block is typically the volatile memory 15 of the control device 4 of the fuse 1. Optionally, the finite state machine 4104.8 communicates with the microcontroller 4104.11, which can be identical to the computer core 2 of the control device 4 of a fuse, via an internal data bus 4119, which can be identical to the internal data bus 11 of the control device 4 of the fuse 1. After a successful write operation, the finite state machine 4104.8 sets a finish flag 4104.10. The microcontroller 4104.11 can optionally write and/or read the finish flag 4104.10 via the internal data bus 4119. The finish flag 4104.10 may in some cases be part of the RAM 4104.9 or a register of the microcontroller 4104.11. The microcontroller 4104.11 optionally controls and monitors the finite state machine 4104.8 via the internal data bus 4119. The finish flag 4104.10 is optionally not set when the system is started. The computer core 2, 4104.11 of the control device 4 can then access the block RAM 4104.9, 15, for example by means of a C program, and read out the random number from the RAM 4104.9, 15. The microcontroller 404.11 is optionally identical to the first processor 10-1 of FIG. 1. The computer core 2 of the control device 4 of the fuse, which operates here as a microcontroller 4104.11, can be, for example, a dual core ARM Cortex-A9 MPCore. The computer core can also execute some of the functions of the sub-devices of the evaluation device 4104 by means of a suitable program and thus replace these device parts if necessary.

Optionally, the microcontroller 4105.11 controls a watchdog 4104.5. In the context of the disclosure, the watchdog 4104.5 is not only a watchdog timer, which comprises a timer which is clocked with the system clock pulse of the quantum random number generator 4100, 60 or of the clock pulse of the control device 4 of the fuse 1, and which, at regular time intervals, has to be reset by the microcontroller 4104.11 back to a starting value in order to avoid an interruption of the program execution of the microcontroller 4104.11 when a watchdog counter threshold value is reached and/or crossed by the counter reading of the timer of the watchdog 4105.5. The watchdog 4105.5 also executes further monitoring tasks within the quantum random number generator 4100. For example, the watchdog 4104.5 optionally monitors the entropy of the random bits 4111. In particular, the watchdog 4104.5 ensures that the random bits 4111 optionally have no more than k consecutive random bits of the same logic value. If this is the case, the watchdog 4104.5 optionally inserts other bits in place of the random bits 4111 into this serial bit data stream from the entropy extraction 4104.5 to the finite state machine 4107.8. More on this in the following FIG. 42. In this case, the watchdog 4104.5 optionally inserts random bits of a different true random number generator and/or of a different quantum random number generator and/or pseudo-random bits of a pseudo-random number generator, the starting value of which is determined by valid random bits of a quantum random number generator (QRNG) or of a true random number generator (TRNG). The watchdog 4104.5 is at the same time optionally also a watchdog 13 of the control device 4 of the fuse 1. Furthermore, within the meaning of the disclosure, the watchdog 4104.5 optionally monitors further variables, such as the matching of voltage values within the quantum random number generator 4100, 60 and/or within the control device 4 of the fuse 1 by means of one or more analog-to-digital converters 570, 4113, etc.

### FIG. 42

FIG. 42 shows the extended exemplary evaluation device 4104, which now comprises a monitoring of the random number 4111 RN, and an additional backup system in the event of a fault in order to protect the safety of the supply network 200 by means of an emergency method even in the event of failure of the quantum random number generator. For better clarity, the components microcontroller 4104.11 (computer core 2), RAM 4104.9, 15 and finish flag 4104.10 are omitted. The reader should still consider these device parts or functions in FIG. 42 as present. However, the person skilled in the art can easily copy the connection to finite state machine 4104.8 from FIG. 41 into FIG. 42 and then arrive at the disclosed technical teaching. The watchdog 4104.5, a linear-feedback shift register 4104.6 as a pseudo-random number generator PRNG and a signal multiplexer 4104.7 expand the device of FIG. 41 to form the device of FIG. 42.

In FIG. 42, for better clarity, not all appropriate and in some cases customary device components of the control device 4 are shown. Further device components that the reader can assume as possibly present in FIG. 1 can be found, for example, in FIGS. 1, 5, 6, 9, 24, 41, 52, 53, 54, 55, 57, 58 and 62. The combination of the device parts of the Figure described here with those of these figures is expressly part of the disclosure of the disclosure.

The output 4111 of the entropy extraction 4104.4 is now connected by way of example to the watchdog 4104.5 and the signal multiplexer 4104.7. The watchdog 4104.5 monitors the random number RN at the output 4111 of the entropy extraction 4104.4. According to the proposal, the watchdog 4104.5 detects at least three defined fault cases. For this purpose, the watchdog 4104.5 indicates, for example, the last valid random numbers as seed S 4112 to the linear-feedback shift register 4104.6. If an error occurs, the watchdog 4104.5 sets error bits in an error register ER (not shown) of the microcontroller 4104.11, 2 (computer core 2). Which error bit the watchdog 4104.5 sets in the error register of the microcontroller 4104.11, 2 (computer core 2) optionally depends on the particular error situation that the watchdog 4104.5 detects. In addition, the watchdog 4104.5 is connected to a voltage monitor 4113 via one or more, optionally digital, input/output signal lines 4114. The watchdog circuit optionally monitors the voltage values that the voltage monitor 4113 determines. It has proven useful if the voltage monitor 4113 determines and monitors not only the voltages in the quantum random number generator 4100, 60, but also other voltages within the control device 4 of the fuse 1. The voltage monitor 4113 can be the analog-to-digital converter 570.

The voltage monitor 4113 monitors, for example, the operating voltages of the entropy source 4101 and/or the voltages within the control device 4 and/or the voltages of the power reserve 8 and/or the internal supply voltages which the voltage supply 5 of the fuse 1 generates. If one of the operating voltages of one of the SPAD diodes connections 4101.1 or 4101.3 is too low, i.e., voltage value is below a lower SPAD operating voltage threshold value, or too high, i.e., voltage value is above an upper SPAD operating voltage threshold value, the operating voltage monitor 4113 detects this voltage deviation. The computer core 2 can optionally read out the values of the voltage monitor 4113 via the internal data bus 11 of the control device 4 of the fuse. In the event of such a voltage deviation, the voltage monitor 4133 signals such a deviation to the watchdog 4104.5 or directly to the microcontroller 4104.11 (computer core 2). In the event of signaling to the watchdog 4104.5, the watchdog 4104.5 can generate an interrupt signal 4120 for the microcontroller 4104.11 (the computer core 2), for example. The watchdog 4104.5 can, for example, trigger such an interrupt 4120 of the microcontroller 4104.11 (computer core 2) or another sub-device of an application system/of the fuse 1 if the supply voltage of the entropy source 4101 or of the high-frequency amplifier 4102 or of a different device part of the quantum random number generator QRNG 4100 and/or of the control device 4 and/or of the fuse 1 is incorrect. If the watchdog 4104.5 detects an error of the quantum random generator 4100, the quantum random number generator 4100 switches into an emergency state. For this purpose, the watchdog 4104.5 sets the selection signal 4116 of the signal multiplexer 4104.7, so that the signal multiplexer 4104.7, instead of the output 4111 of the entropy extraction 4104.4, applies the pseudo-random number PRN of the linear-feedback shift register 4104.6 in the form of a stream of pseudo-random bits via a pseudo-random signal line 4117 as a replacement for the at least potentially faulty random number RN of the output 4111 of the entropy extraction 4104.4 to the input of the finite state machine 4104.8.

The linear-feedback shift register 4104.6 is connected to the output seed S 4112 of the watchdog 4104.5. In the event of an error, the watchdog 4104.5 activates the linear-feedback shift register 4104.6. The linear-feedback shift register 4104.6 then generates pseudo-random numbers PRN as a pseudo-random number generator PRNG. The seed S 4112 optionally has the last, for example 16, still valid random numbers (e.g., 1 bit each). The watchdog 4104.5 optionally applies these last valid random numbers to the input of the linear-feedback shift register 4104.6. The seed S thus serves as a random PQC-secure starting value for the generator polynomial of the feedback of the linear-feedback shift register 4104.6 for the generation of the pseudo-random number PRN and its signaling via the pseudo-random signal line 4117. The generator polynomial and the degree of the generator polynomial are optionally freely selectable.

The signal of the output 4111 of the entropy extraction 4104.4 with the 1-bit random number RN of the entropy extraction 4104.4 or the signal of the pseudo-random signal line 4117 with the pseudo-random number PRN of the linear-feedback shift register 4104.6 are connected to the inputs of the signal multiplexer 4104.7. Depending on the value of the selection signal 4116 SEL, the signal multiplexer 4104.7 forwards one of the two inputs to the finite state machine 4104.8. Of course, it is conceivable to use a multiplexer having more than two inputs and a more complex control signal if the application requires this. The number of inputs of the signal multiplexers 4104.7 is therefore typically greater than or equal to two.

Here, too, the finite state machine 4104.8 has the task of receiving the random data RN or the pseudo-random number PRN at the output of the signal multiplexer 4104.7 and writing them to the block RAM 4104.9, 15 of the evaluation device 4104 within the control device 4 of the fuse 1. If the write operation is successful, the finite state machine 4104.8 in turn sets the finish flag 4104.10. Thereupon, the microcontroller 4104.11 (computer core 2) can then be accessed on the block RAM 4104.9, 15, for example by means of a C program, which optionally runs on the embedded microcontroller 4104.11, and can read out the random number and use it, for example, for encryption.

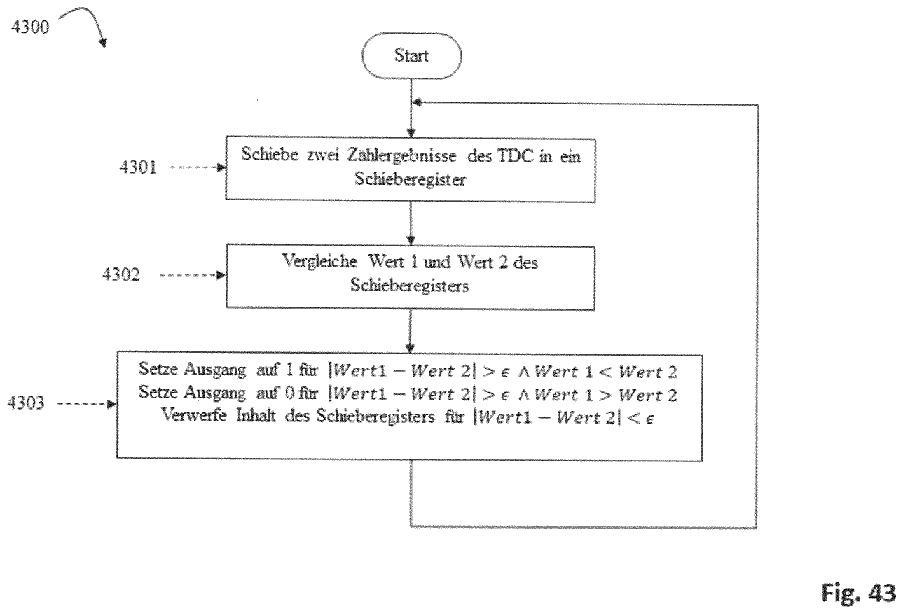

### FIG. 43

FIG. 43 shows the flowchart 4300 of the entropy extraction method that executes, for example, the entropy extraction 4104.4. The method first provides in a first step 4301 determining two values of the output 4110 of the time-to-digital converter 4104.3 and storing them in a shift register of the entropy extraction 4104.4. If two values are stored in the shift register of the entropy extraction 4104.4, the entropy extraction 4104.4 compares these two values in a second step 4302. The two values in the shift register of the entropy extraction 4104.4 thus comprise a first value and a second value which both of the time-to-digital converters 4104 have determined by means of two different measurements of the corresponding time period in each case between two signal pulses above the value of the constant 4104.1. In a third step 4303, the entropy extraction 4104.4 evaluates the two values. If the first value is smaller than the second value and the difference between value 1 and value 2 is greater than a minimum difference c, the entropy extraction 4014.4 sets the value of its output 4111 to a first logic value. If the first value is greater than the second value and the difference between the first value and the second value 2 is greater than the minimum difference c, the entropy extraction 4104.4 sets its output to a second logic value, which is different from the first logic value. If the difference between the first value and the second value is less than the minimum difference c, the entropy extraction discards the first value and the second value. The entropy extraction optionally causes the watchdog 4104.5 to increase an error counter in such a case by a first error counter increment. The first error counter increment can be negative. Conversely, the entropy extraction 4104.4 can reduce the error counter of the watchdog 4104.5 by a second error counter increment if the difference between the first value and the second value is greater than the minimum difference c. The second error counter increment may be equal to the first error counter increment. Typically, the signs of the first error counter increment and the second error counter increment are the same. The microcontroller 4104.11 (computer core 2) can optionally set the error counter increments and the starting value of the error counter and an error counter threshold value. If the counter reading of the error counter crosses the error counter threshold value, the watchdog 4104.5 optionally signals the presence of a critical error state by means of an interrupt 4120 or another signaling to the microcontroller 404.11 (computer core 2). The microcontroller 4104.11 (computer core 2) then typically starts a self-test program in order to test the different parts of the quantum random number generator 4100. For this purpose, for example, the microcontroller 4104.11 (computer core 2) can optionally put the analog-to-digital converter 4103, 570 into a state in which the microcontroller 4104.11 (computer core 2) can describe an output register of the analog-to-digital converter 4103 with test values, which the downstream signal chain then further processes like true sampling values. Because the test values are previously known, the microcontroller 4104.11 (computer core 2) can observe and evaluate the correct reaction of the residual system, for example the incrementing of the error counter in the watchdog 4104.5. The microcontroller 4104.11 (computer core 2) can therefore optionally monitor all memory nodes of the evaluation circuit 4104 or of the control circuit 4 and read their logic state.

If a time value at the output 4110 of the time-to-digital converter 4104.3 is less than a minimum value, it is a value which is within the dead time of the SPAD diodes 4101.1, 4101.3. The evaluation device 4104 optionally discards such a value and optionally increases the error counter by the first error increment, which can also be negative. In this case, the entropy extraction 4104.4 waits for determining the next time value by the time-to-digital converter 4104.3. If the random bit is extracted in this way, the quantum random number generator 4100 begins the method from the start.

If the error counter crosses or reaches the error counter threshold value, an error can be present, for example, in which the time-to-digital converter 41\hat{ }03 provides constant numerical values due to an error, for example.

This device is thus able to detect a failure of the voltage supply 5 of the entropy source 4101 or other parts of the device 4, 4100. The microcontroller 4104.11 (computer core 2) can detect voltages and currents in the quantum random number generator 4100 and/or within the control device 4 of the fuse and/or within the fuse 1—including for test purposes—by means of the analog-to-digital converter 4103 and compare the values thus determined to expected value ranges within which these values must be. The microcontroller 4104.11 (the computer core 2) can also detect digital values within the quantum random number generator 4100 and/or the control device 4. For example, the microcontroller 4104.11 (the computer core 2) can set the constant Const 4104.1 for test purposes low enough that the noise background essentially controls the time-to-digital converter 4104.3. The values of the time-to-digital converter 4104.3 should then satisfy expected statistics within a tolerance band. If this is not the case, an error is present. The microcontroller 4104.11 (computer core 2) can create these statistics and, where applicable, deduce this error if the determined statistical values are not within an expected value interval.

The watchdog 4104.5 can monitor the entropy of the supplied random numbers 4111. If the average entropy of the bits 4111 over an entropy measurement period deviates significantly more than a permitted entropy deviation value from the expected random mean value of 50%, the watchdog 4104.5 optionally deduces an error of the quantum random number generator 4100, 60, and optionally increments the error counter by said error counter increment. Optionally, the watchdog 4104.5 then stops the use of these random bits of the output 4111 of the entropy extraction in order to prevent the transmission of plain text via the data bus through the fuse 1. Within the meaning of the disclosure, plain text means that the data transmitted and/or stored are in a form which makes it possible for a third party to obtain unauthorized access to the content of a data message and/or of stored data and/or program code directly and/or by applying statistical or other methods. Namely, it is conceivable that a virtual permanent logic one or a virtual permanent logic zero is generated randomly even in functioning sub-devices. The randomness specifically also comprises the permanent logic zero and the permanent logic one. It is thus useful if the maximum length of a bit sequence is limited by the watchdog 4195.5 to a value that is programmable by the microcontroller 4104.11 (computer core 2) without the logic state at the output 411 of the entropy extraction 4104.4 changing.

The above-described quantum random number generator 4100 can thus essentially detect the following errors and, by an emergency operation, capture them by means of a pseudo-random number generator 4104.6, i.e., for example, by means of a linear-feedback shift register 4104.6, with a lower safety level:
fault of supply voltages
faulty signal generation of SPAD diodes 4101.1 and 4101.3,
fault of the optical waveguide 4101.2 and/or the coupling of the SPAD diodes 4101.1 and 4101.3 to the optical waveguides 4101.2,
circuit failures in digital part 4104 of the quantum random number generator 4100
faulty entropy of the supplied random numbers 4111.

Instead of the linear-feedback shift register 4104.6 or the pseudo-random number generator 4104.6, it is conceivable to use a second complete quantum random number generator 4100, the output 4111 of the entropy extraction of which is then used by the multiplexer 4104.7 instead of the signal of the pseudo-random signal line 4117 for the emergency operation of the quantum random number generator 4100, 60. In the event that the output of the pseudo-random number generator 4104.6 depends on one or more true random bits 4112 as seed, it is in turn a quantum random number as long as the number of inserted bits is limited. The watchdog 4105.5 optionally determines the number k of the permitted, maximum successive quantum bits 4111 from a quantum random number. If this quantum random number 4111 used by the watchdog 4104.5 for the determination of k comprises only bits having a single logic value, there is the possibility that there is an error. The number k should then not be maximal in order to avoid a transmission or storage of plain text. Rather, the watchdog 4104.5 should then select the number k to be very small, optionally a minimum.

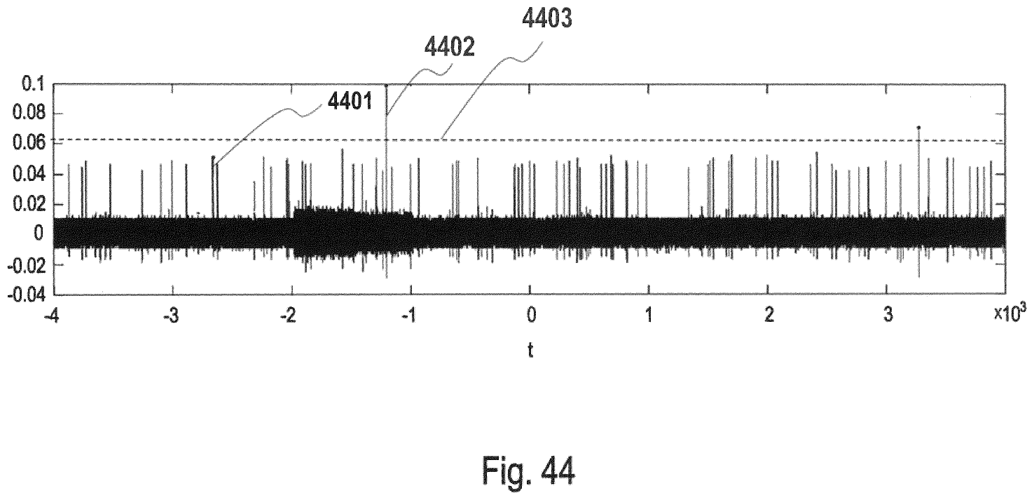

### FIG. 44

FIG. 44 shows an exemplary oscillogram of the voltage signal 4104 of the entropy source 4101. As can easily be seen, first spikes 4401 having a first height and second spikes 4402 having a second height are occurring. The spread of the first height of the first spikes 4401 and the spread of the second height of the second spikes 4402 is in each case low enough that a clear separation of these events 4401, 4402 is possible by means of an exemplary cutoff level 4403 via the choice of the constants 4104.1. The cutoff level 4403 corresponds to the value that the microcontroller 4104.11 (computer core 2) sets by means of the constant 4104.1, which is optionally designed as a register of the microcontroller 4104.11 (computer core 2).

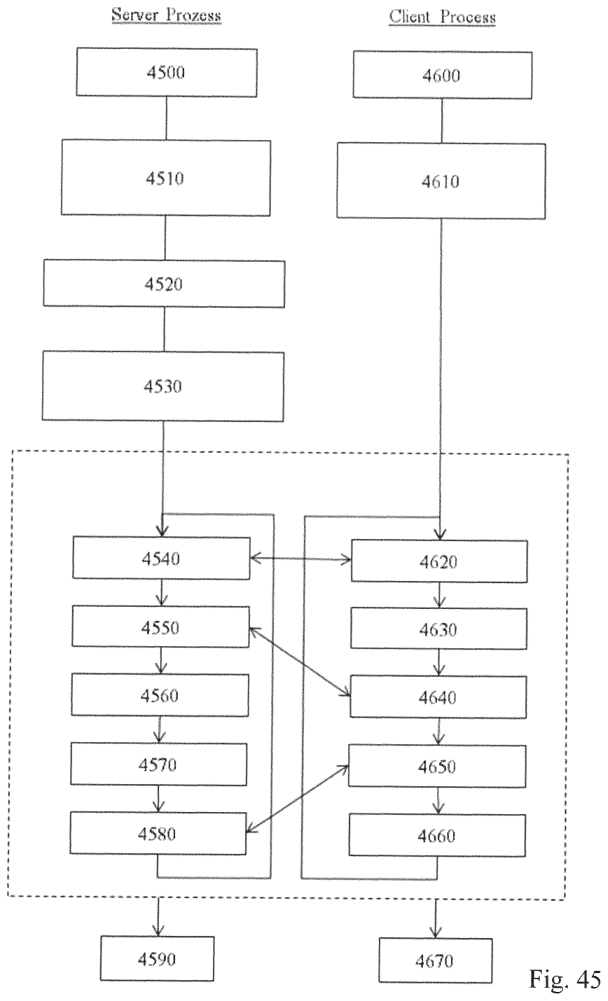

### FIG. 45

FIG. 45 shows the schematic sequence of a server-client communication using a proposed quantum random number generator. In this case, a first device, such as the electronic fuse 1 of FIG. 1, is to communicate in encrypted form as a server via a data bus 9 with a second device, such as another, second fuse of FIG. 1 and/or a higher-level computer system 12, as a client. In a first example, both the first device and the second device should optionally each comprise a quantum random number generator 60 which the corresponding computer uses for the encryption. The quantum random number generator 60, 4100 optionally corresponds completely or partially to a design corresponding to one of FIGS. 41 to 42. Very particularly optionally, the quantum random number generators of the first device and of the second device each comprise a quantum random number generator 4100, 60 which each have at least one first SPAD diode 4101.1 and each have at least one optical waveguide 4101.2, optionally in the form of the oxide stack 3944 on the semiconductor surface and optionally at least one second SPAD diode 4101.3 as a receiver. This increases the data rate of the random bits generated and enables the computer of the particular device to generate and exchange the keys very quickly. The respective computers of the respective devices encrypt their mutual communication optionally by means of an RSA encryption method. The exemplary RSA encryption method is known, for example, from R. L. Rivest, A. Shamir, and L. Adleman, “A Method for Obtaining Digital Signatures and Public Key Cryptosystems” Communications of the ACM, February 1978, vol. 21, no. 2, pages 120 to 126. The prime numbers which the corresponding computer of the corresponding device optionally uses to generate the public and the private key are optionally generated randomly by the quantum random number generator 4100, 60 QRNG. The communication of the computer core 2 of the control device 4 of the fuse (server) with the corresponding computer core 2 of the control device 4 of the other fuse 1 (client) or the higher-level computer system (client) optionally comprises firstly the “server process”, which is started on the computer core 2 of the control device 4 of the fuse (server), i.e., the first device, and secondly the “client process”, which is started on the corresponding computer core 2 of the control device 4 of the other fuse (client) or the higher-level computer system 12, i.e., the second device. The corresponding computer core 2 of the control device 4 of the other fuse (client) or the higher-level computer system 12 typically communicates with the computer core 2 of the control device 4 of the fuse (server) via so-called sockets. These are communication points provided by the corresponding operating system of the corresponding computer. The functions required to establish communication are optionally derived from the C standard library socket.h, for example. The following explains by way of example the communication according to FIG. 45:

At the beginning, the computer core 2 of the control device 4 of the fuse 1 (server) generates a socket descriptor in step 4500. A socket descriptor within the meaning of the disclosure is an integer similar to a file handle which, for example, is generated by the C standard library socket( ) function of the socket.h library. The computer core 2 of the control device 4 of the fuse 1 (server) can use this socket descriptor in later function calls, which use sockets.

In step 4510, the computer core 2 of the control device 4 of the fuse 1 (server) optionally binds the socket descriptor to a port and an IP address. Binding within the meaning of this document means that the computer core 2 of the control device 4 of the fuse 1 (server) uses the C standard bind( ) function from the C standard library socket.h in order to logically link the port and the IP address to the socket descriptor generated in step 4500. In the context of the present document, a port is a part of the network address which enables the assignment of data packets between server and client programs. In the context of the present document, an IP address is a network address which makes a participant unambiguously identifiable in a network.

In the next step 4520, the computer core 2 of the control device 4 of the fuse 1 (server) enters a passive waiting state 4520 and waits for connection requests of a computer core 2 of the control device 4 of the other fuse 1 (client). In the context of the disclosure, the computer core 2 of the control device 4 of the fuse 1 (server) optionally calls the C standard listen( ) function of the socket.h library. The function indicates that the computer core 2 of the control device 4 of the fuse 1 (server) is ready for the computer core 2 of the control device 4 of the fuse 1 (server) to be able to accept connection requests by clients. The computer core 2 of the control device 4 of the fuse 1 (server) generates a queue for incoming connection requests of the computer core 2 of the control device 4 of the other fuse 1 (client) in one of the memories 15 of the computer core 2 of the control device 4 of the fuse 1 (server) or another device part of the control device 4 of the fuse 1 (server). If the computer core 2 of the control device 4 of the fuse 1 (server) determines a connection request of a computer core 2 of the control device 4 of the other fuse 1 (client), the computer core 2 of the control device 4 of the fuse 1 (server) accepts this connection request of the computer core 2 of the control device 4 of the other fuse 1 (clients).

In a subsequent step 4530, the computer core 2 of the control device 4 of the fuse 1 (server) then establishes 4530 a connection to the computer core 2 of the control device 4 of the other fuse 1 (client). The computer core 2 of the control device 4 of the fuse 1 (server) establishes a connection request of the computer core 2 of the control device 4 of the other fuse 1 (client) in that the computer core 2 of the control device 4 of the fuse 1 (server) leaves the listen(function. The computer core 2 of the control device 4 of the fuse 1 (server) optionally accepts the connection request by calling up the C standard accept(function of the socket.h C standard library. For this purpose, the computer core 2 of the control device 4 of the fuse 1 (server) optionally extracts the first connection request from the queue of open connection requests for the server and thus then establishes the connection to the computer core 2 of the control device 4 of the other fuse 1 (client). If this is successful, the accept( ) function returns a socket descriptor of the client to the computer core 2 of the control device 4 of the fuse 1 (server). A socket descriptor within the meaning of this document is an integer similar to a file handle of the C standard library socket.h. The connection then exists between the computer core 2 of the control device 4 of the fuse 1 (server) and the computer core 2 of the control device 4 of the other fuse 1 (client).

If a said connection exists, the computer core 2 of the control device 4 of the fuse 1 (server) optionally starts a keyExchangeServer( ) function in a subsequent step 4540. The computer core 2 of the control device 4 of the fuse 1 (server) then executes this keyExchange( ) function in this step 4540 in order for the computer core 2 of the control device 4 of the other fuse 1 (client) to be sent its public key. However, this keyExchangeServer( ) function is then not a C standard function. In this function, in this step 4540, the computer core 2 of the control device 4 of the fuse 1 (server) generates random numbers from random bits 4111 by means of a quantum random number generator 4100, 60 QRNG. The random number optionally has a bit width n. Here n is a positive integer including zero. In the example presented in this document, these random numbers of the quantum random number generator 4100, 60 of the control device 1 of the fuse 1 (server) serve as indices for a look-up table of the first 2n prime numbers. This look-up table is optionally located in one of the memories 15, 14 of the control device 4 of the fuse 1 (server). The computer core 2 of the control device 4 of the fuse 1 (server) then reads the prime number according to this index of the quantum random number of the quantum random number generator 4100, 60 of the control device 4 of the fuse 1 (server) from the memory 14, 15 of the computer core 2 of the control device 4 of the fuse 1 (server). By means of these prime numbers, the computer core 2 of the control device 4 of the fuse 1 (server) generates both a public key and the private key according to the aforementioned RSA encryption method.

The computer core 2 of the control device 4 of the fuse 1 (server) then transmits a public key to the computer core 2 of the control device 4 of the other fuse 1 (client) via the data interface 64 of the computer core 2 of the control device 4 of the fuse 1 (server) and the data bus 9 and the data interfaces 10, 610, 550, 551 of the computer core 2 of the control device 4 of the other fuse 1 (client).

Thereafter, the computer core 2 of the control device 4 of the fuse 1 (server) waits for a message of the computer core 2 of the control device 4 of the other fuse 1 (client) via the data interface 10, 610, 550, 551 of the computer core 2 of the control device 4 of the other fuse 1 (client) and the data bus 9 and the data interfaces 10, 610, 550, 551 of the computer core 2 of the control device 4 of the fuse 1 (server). This message of the computer core 2 of the control device 4 of the other fuse 1 (client) optionally comprises a public key of the computer core 2 of the control device 4 of the other fuse 1 (client). The computer core 2 of the control device 4 of the other fuse 1 (client) thus typically transmits the private key of the computer core 2 of the control device 4 of the other fuse 1 (client) via the data interface 64 of the computer core 2 of the control device 4 of the other fuse 1 (client) and via the data bus 9 and the data interface 10, 610, 550, 551 of the computer core 2 of the control device 4 of the fuse 1 (server) to the computer core 2 of the control device 4 of the fuse 1 (server). If the computer core 2 of the control device 4 of the fuse 1 (server) has received the public key of the computer core 2 of the control device 4 of the other fuse 1 (client), the computer core 2 of the control device 4 of the fuse 1 (server) stores this public key in a memory 14, 15 of the computer core 2 of the control device 4 of the fuse 1 (server).

The computer core 2 of the control device 4 of the fuse 1 (server) then transmits, for example, its public key via its data bus interface 10, 610, 550, 551 and the data bus 9 and the data bus interface 10, 610, 550, 551 of the computer core 2 of the control device 4 of the other fuse 1 (client) to the computer core 2 of the control device 4 of the other fuse 1 (client).

The computer core 2 of the control device 4 of the fuse 1 (server) is thus typically prepared for the exchange of encrypted data between the computer core 2 of the control device 4 of the other fuse 1 (client) and the computer core 2 of the control device 4 of the fuse 1 (server).

After the keys are then exchanged, the computer core 2 of the control device 4 of the fuse 1 (server) then optionally executes the recv( ) function 4550 and waits for an encrypted message of the computer core 2 of the control device 4 of the other fuse 1 (client). If the computer core 2 of the control device 4 of the fuse 1 (server) receives a message, the computer core 2 of the control device 4 of the fuse 1 (server) optionally stores this encrypted message first in a temporary cache memory 15 of the computer core 2 of the control device 4 of the fuse 1 (server). Within the meaning of the document present here, the recv( ) function is optionally a C standard function of the C standard library socket.h. The recv( ) function typically reads incoming data from a socket descriptor, in this case the socket descriptor of the computer core 2 of the control device 4 of the other fuse 1 (client) from step 4530 of the method. The recv( ) function, which the computer core 2 of the control device 4 of the fuse 1 (server) typically executes, typically stores the received data in the temporary cache memory 15 of the computer core 2 of the control device 4 of the fuse 1 (server).

If the computer core 2 of the control device 4 of the fuse 1 (server) has received an encrypted message in this way, the computer core 2 of the control device 4 of the fuse 1 (server) optionally executes the Decrypt( ) function 4560 in a further step 4560. This Decrypt( ) function is not a C standard function. Within the meaning of the disclosure, the Decrypt( ) function in this step 4560 decrypts the message by means of the private key of the computer core 2 of the control device 4 of the fuse 1 (server) from step 4540 according to the RSA method, which private key is temporarily stored in the memory 15 of the computer core 2 of the control device 4 of the fuse 1 (server). As a result, the computer core 2 of the control device 4 of the fuse 1 (server) decrypts the received encrypted message of the client by means of the private key temporarily stored in the memory 15 of the computer core 2 of the control device 4 of the fuse 1 (server) from step 4540 according to the RSA method. The computer core 2 of the control device 4 of the fuse 1 (server) optionally stores the then decrypted message in a temporary cache memory 15 of the computer core 2 of the control device 4 of the fuse 1 (server).

If the computer core 2 of the control device 4 of the fuse 1 (server) does not receive a message of the computer core 2 of the control device 4 of the other fuse 1 (client) within a predetermined period of time, the computer core 2 of the control device 4 of the fuse 1 (server) skips to the step now described. The computer core 2 of the control device 4 of the fuse 1 (server) checks whether it is to transmit a message to the computer core 2 of the control device 4 of the other fuse 1 (client). Typically, such a message is stored for transmission in such a case in a memory 15 of the computer core 2 of the control device 4 of the fuse 1 (server). In some cases, the computer core 2 of the control device 4 of the fuse 1 (server) can also retrieve or receive as transmitted such a message from a different memory or system before the message is sent. Optionally, the computer core 2 of the control device 4 of the fuse 1 (server) then stores such a message temporarily in a cache memory 15 of the computer core 2 of the control device 4 of the fuse 1 (server). If such a message to be sent is queued for sending in a memory 15 or cache memory of the computer core 2 of the control device 4 of the fuse 1 (server), the computer core 2 of the control device 4 of the fuse 1 (server) optionally executes the Encrypt( ) function in a further step 4570. In this case, the computer core 2 of the control device 4 of the fuse 1 (server) in this step 4570 encrypts its own message by means of the public key of the client from 4540 according to the RSA method. This Encrypt( ) function is not a C standard function. The server stores its now encrypted message in a temporary cache memory 15 of the computer core 2 of the control device 4 of the fuse 1 (server).

The computer core 2 of the control device 4 of the fuse 1 (server) now executes the send( ) function in a step 4580. In step 4580, the computer core 2 of the control device 4 of the fuse 1 (server) transmits its encrypted message stored in the cache memory 15 of the computer core 2 of the control device 4 of the fuse 1 (server) to the computer core 2 of the control device 4 of the other fuse 1 (client) via the data bus interface 10, 610, 550, 551 of the computer core 2 of the control device 4 of the fuse 1 (server) and via the data bus 9 and via the data interface 10, 610, 550, 551 of the computer core 2 of the control device 4 of the other fuse 1 (client). Within the meaning of the document present here, the send( ) function is a C standard function of the C standard library socket.h. The send( ) function transmits data via a socket descriptor, in this case the socket descriptor of the client from step 4530. The typical cycle is terminated with the end of the transmission.

The encrypted communication for the computer core 2 of the control device 4 of the fuse 1 (server) then restarts at step 4540.

If the communication by the computer core 2 of the control device 4 of the fuse 1 (server) or the computer core 2 of the control device 4 of the other fuse 1 (client) is terminated, the computer core 2 of the control device 4 of the fuse 1 (server) executes the close( ) function 4590. The close( ) function is a C standard function of the C standard library socket.h. By executing the close( ) function, the computer core 2 of the control device 4 of the fuse 1 (server) closes the open connection to a socket, in this case the socket of the client, and thus terminates the communication.

Similarly, the computer core 2 of the control device 4 of the other fuse 1 (client) excludes a client process.

At the beginning of the “client process,” the computer core 2 of the control device 4 of the other fuse 1 (client) generates a socket descriptor in a step 4600. A socket descriptor within the meaning of this document is in turn an integer similar to a file handle, which can be used by the C standard library socket( ) function of the socket.h library, for example, the computer core 2 of the control device 4 of the other fuse 1 (client) in later function calls that use sockets. The computer core 2 of the control device 4 of the other fuse 1 (client) submits a connection request to the computer core 2 of the control device 4 of the fuse 1 (server) using the port and the IP address, which were defined in step 4510.

For this purpose, the computer core 2 of the control device 4 of the other fuse 1 (client) optionally executes the C standard connect( ) function of the C standard library socket.h. This function establishes a connection between the server socket from step 4510 and the client socket from step 4600.

If the connection was accepted by the computer core 2 of the control device 4 of the fuse 1 (server) according to step 4530, the computer core 2 of the control device 4 of the other fuse 1 (client) executes the KeyExchangeClient( ) function in a step 4620. This function is not a C standard function. By executing this function, the computer core 2 of the control device 4 of the other fuse 1 (client) generates one or more QRNG random numbers from random bits 4111 by means of the quantum random number generator 4100, 60. This random number has a bit width n. Here n is a positive integer including zero. These random numbers of the quantum random number generator 4100, 60 of the computer core 2 of the control device 4 of the other fuse 1 (client) optionally serve as indices for a look-up table of the first 2″ prime numbers. By means of these prime numbers or other prime numbers, the computer core 2 of the control device 4 of the other fuse 1 (client) generates both a public and private key according to RSA encryption. The computer core 2 of the control device 4 of the other fuse 1 (client) stores its public key generated in this way and its private key generated in this way optionally in a memory 15 of the computer core 2 of the control device 4 of the other fuse 1 (client). The computer core 2 of the control device 4 of the other fuse 1 (client) then transmits its public key to the computer core 2 of the control device 4 of the fuse 1 (server) via the data interface 10, 610, 550 551 of the computer core 2 of the control device 4 of the other fuse 1 (client) and via the data bus 9 and via the data interface 10, 610, 550, 551 of the computer core 2 of the control device 4 of the fuse 1 (server). The computer core 2 of the control device 4 of the other fuse 1 (client) then waits for a message of the computer core 2 of the control device 4 of the fuse 1 (server). Typically found in this message of the first processor 10-1 of the computer core 2 of the control device 4 of the fuse 1 (server) is the public key of the computer core 2 of the control device 4 of the fuse 1 (server).

The computer core 2 of the control device 4 of the other fuse 1 (client) then executes the Encrypt( ) function 4630. As a result of this execution of the Encrypt( ) function in step 4630, the computer core 2 of the control device 4 of the other fuse 1 (client) encrypts its own message by means of the public key of the computer core 2 of the control device 4 of the fuse 1 (server) from step 4540 by means of the RSA method. This function is not a C standard function. The client stores the encrypted message in a temporary cache memory 15.

The computer core 2 of the control device 4 of the other fuse 1 (client) then executes the send( ) function in step 4640 and transmits its encrypted message to the computer core 2 of the control device 4 of the fuse 1 (server). Within the meaning of the document present here, the send( ) function is a C standard function of the C standard library socket.h. By executing the send( ) function, the computer core 2 of the control device 4 of the other fuse 1 (client) transmits data via a socket descriptor, in this case the socket descriptor of the client from 4600.

The computer core 2 of the control device 4 of the other fuse 1 (client) then executes the recv( ) function 4650. In step 4650, the computer core 2 of the control device 4 of the other fuse 1 (client) waits for an encrypted message of the computer core 2 of the control device 4 of the fuse 1 (server). If the computer core 2 of the control device 4 of the other fuse 1 (client) receives a message, the computer core 2 of the control device 4 of the other fuse 1 (client) stores this received and typically encrypted message in a temporary cache memory 15. Within the meaning of the document present here, the recv( ) function is optionally a C standard function of the C standard library socket.h. The computer core 2 of the control device 4 of the other fuse 1 (client) reads incoming data from a socket descriptor, in this case from the socket descriptor of the computer core 2 of the control device 4 of the other fuse 1 (client) from step 4600, by executing the recv( ) function. The computer core 2 of the control device 4 of the other fuse 1 (client) optionally stores the read data in a temporary cache memory 15 of the computer core 2 of the control device 4 of the other fuse 1 (client).

If the computer core 2 of the control device 4 of the other fuse 1 (client) has received an encrypted message in this way, the computer core 2 of the control device 4 of the other fuse 1 (client) optionally executes the Decrypt( ) function in a step 4660. This Decrypt( ) function is not a C standard function. By executing the Decrypt( ) function, the computer core 2 of the control device 4 of the other fuse 1 (client) decrypts an encrypted message of the computer core 2 of the control device 4 of the fuse 1 (server) received by the computer core 2 of the control device 4 of the other fuse 1 (client) by means of the private key of the computer core 2 of the control device 4 of the other fuse 1 (client) from step 4620 by means of the RSA method. Thereafter, the computer core 2 of the control device 4 of the other fuse 1 (client) stores the message decrypted in this way in a temporary cache memory 15 of the computer core 2 of the control device 4 of the other fuse 1 (client).

The communication between the computer core 2 of the control device 4 of the fuse 1 (server) and the computer core 2 of the control device 4 of the other fuse 1 (client) then starts again at step 4620.

If the communication by the computer core 2 of the control device 4 of the other fuse 1 (client) or the computer core 2 of the control device 4 of the fuse 1 (server) is terminated, the computer core 2 of the control device 4 of the other fuse 1 (client) executes the close( ) function in step 4670. The close( ) function is a C standard function of the C standard library socket.h. Because the computer core 2 of the control device 4 of the other fuse 1 (client) executes the close( ) function, the computer core 2 of the control device 4 of the other fuse 1 (client) closes the open connection to a socket and thus terminates the communication with the computer core 2 of the control device 4 of the fuse 1 (server).

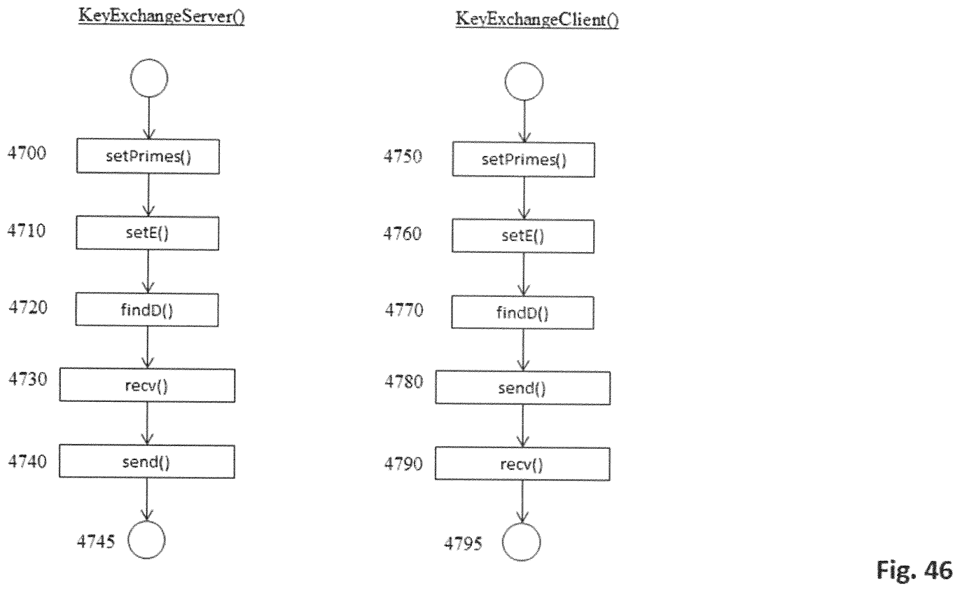

### FIG. 46

FIG. 46 shows the schematic sequence of the KeyExchangeServer( ) and KeyExchangeClient( ) functions.

When the KeyExchangeServer( ) function is started, the computer core 2 of the control device 4 of the fuse 1 (server) first calls up the setPrimes( ) function in step 4700. This KeyExchangeServer( ) function is not a C standard function. The computer core 2 of the control device 4 of the fuse 1 (server) generates by means of the KeyExchangeServer( ) function two different prime numbers p and q, the product n=p*q and Euler's phi function phi=(p−1×q−1) in step 3200.

The computer core 2 of the control device 4 of the fuse 1 (server) then calls up the setEO function in step 4710. This setE( ) function in step 4710 is not a C standard function. When the setE( ) function is called up in step 4710, the computer core 2 of the control device 4 of the fuse 1 (server) generates a number e that is relatively prime to phi, wherein the number phi is that from step 4700. Relatively prime within the meaning of the present document means that there is no natural number, except for the number one, which simultaneously divides the number e and phi.

The computer core 2 of the control device 4 of the fuse 1 (server) then executes the findD( ) function in step 4720. This findD( ) function is not a C standard function. The computer core 2 of the control device 4 of the fuse 1 (server) calculates the multiplicative inverse to e by means of the findD( ) function, so that (e*d)mod phi=1 applies.

The computer core 2 of the control device 4 of the fuse 1 (server)now calls up the recv( ) function in step 4730. The computer core 2 of the control device 4 of the fuse 1 (server)now waits for an incoming message from the computer core 2 of the control device 4 of the other fuse 1 (client), which message should typically comprise the public key of the client. Within the meaning of the document present here, the recv( ) function is a C standard function of the C standard library socket.h. By calling up the recv( ) function, the computer core 2 of the control device 4 of the fuse 1 (server) reads the incoming data from a socket descriptor, in this case the socket descriptor of the client. The computer core 2 of the control device 4 of the fuse 1 (server) optionally stores the read data in a temporary cache memory 15 of the computer core 2 of the control device 4 of the fuse 1 (server).

The computer core 2 of the control device 4 of the fuse 1 (server) now calls up the send( ) function in step 4740. In this step 4740, the computer core 2 of the control device 4 of the fuse 1 (server) transmits its public key (d, n) from steps 4700 and 4720 to the computer core 2 of the control device 4 of the other fuse 1 (client). Within the meaning of the document present here, the send( ) function is a C standard function of the C standard library socket.h. The computer core 2 of the control device 4 of the fuse 1 (server) transmits data via a socket descriptor, in this case the socket descriptor of the client from step 4530, by means of the send( ) function.

The computer core 2 of the control device 4 of the fuse 1 (server) then leaves the KeyExchang-eServer( ) function in step 4745.

When the KeyExchangeClient( ) function is started, the computer core 2 of the control device 4 of the other fuse 1 (client) first calls up the setPrimes( ) function in step 4750. This function is not a C standard function. The computer core 2 of the control device 4 of the other fuse 1 (client) generates, by means of the KeyExchangeClient( ) function, the prime number p and the prime number q which is different from q. The computer core 2 of the control device 4 of the other fuse 1 (client) generates the product n=p*q by means of the KeyExchangeClient( ) function. The computer core 2 of the control device 4 of the other fuse 1 (client) generates, by means of the KeyExchangeClient( ) function, Euler's phi function phi=(p−1)×q−1).

The computer core 2 of the control device 4 of the other fuse 1 (client) then calls up the setE( ) function in step 4760. This function is not a C standard function. The computer core 2 of the control device 4 of the other fuse 1 (client) generates, by means of the setE( ) function, an integer e that is relatively prime to the number phi from step 4750. Relatively prime, within the meaning of the present document, means that there is no natural number apart from the number one which simultaneously divides the number e and the phi without a remainder.

The computer core 2 of the control device 4 of the other fuse 1 (client) then calls up the findD( ) function 4770. This function is not a C standard function. The computer core 2 of the control device 4 of the other fuse 1 (client) calculates the multiplicative inverse for the number e by means of the findD( ) function, so that (e*d)mod phi=1 applies.

The computer core 2 of the control device 4 of the other fuse 1 (client) now calls up the send( ) function 4780 and transmits its public key (d, n) from steps 4750 and 4770 to the computer core 2 of the control device 4 of the fuse 1 (server). Within the meaning of the document present here, the send( ) function is a C standard function of the C standard library socket.h. The computer core 2 of the control device 4 of the other fuse 1 (client) transmits data via a socket descriptor, in this case the socket descriptor of the client from step 4600, by means of the send( ) function.

The computer core 2 of the control device 4 of the other fuse 1 (client) now calls up the recv( ) function in step 4790. The computer core 2 of the control device 4 of the other fuse 1 (client) now waits for an incoming message of the computer core 2 of the control device 4 of the fuse 1 (server) with the public key of the computer core 2 of the control device 4 of the fuse 1 (server). Within the meaning of the document present here, the recv( ) function is a C standard function of the C standard library socket.h. The computer core 2 of the control device 4 of the other fuse 1 (client) reads, by means of the recv( ) function, incoming data of the computer core 2 of the control device 4 of the fuse 1 (server) from a socket descriptor, in this case from the socket descriptor of the client from step 4600, and stores the data in a temporary cache memory 15 of the computer core 2 of the control device 4 of the other fuse 1 (client).

The computer core 2 of the control device 4 of the other fuse 1 (client) then leaves the KeyExchangeClient( ) function in step 4795.

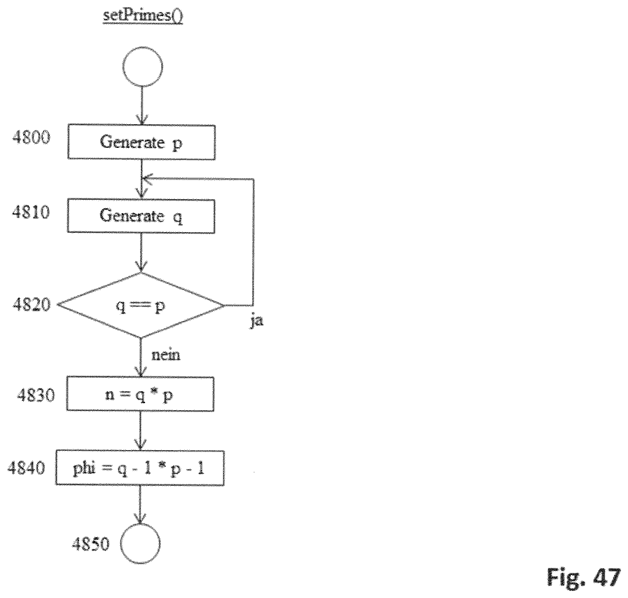

### FIG. 47

FIG. 47 shows schematically the sequence of the setPrimes( ) function.

The computer core 2 of the control device 4 of the other fuse 1 (client) and the computer core 2 of the control device 4 of the fuse 1 (server) call up this function at the given time in each case. If one of these computers calls up the setPrimes( ) function, the calling computer generates—in the case of the present document the computer core 2 of the control device 4 of the fuse 1 (server) or the computer core 2 of the control device 4 of the other fuse 1 (client)—a random number by means of a quantum random number generator QRNG in step 4800. This random number has a bit width n. Here n is a positive integer including zero. These random numbers are used in the technical teaching of the document submitted here as indices for a look-up table of the first 2″ prime numbers. The calling computer stores the prime number, which is indexed by the random number, as a variable p.

The calling computer then generates a further random number in step 4810 with the preferred bit width n by means of the quantum random number generator 4100, 60 QRNG. These random numbers optionally serve the calling computer in turn as indices for a look-up table of the first 2″ prime numbers. The calling computer stores the prime number indexed by the random number as a variable q in a cache memory 15 of the calling computer, of which the computer is optionally a part.

The calling computer now checks in step 4820 whether the logic statement q=p applies. If this statement applies, step 4810 is repeated.

The calling computer then calculates the product n=p*q in step 4830.

The calling computer then calculates Euler's phi function phi=(q−1)*(p−1) in step 4840.

Thereafter, the calling computer leaves the setPrimes( ) function in step 4850.

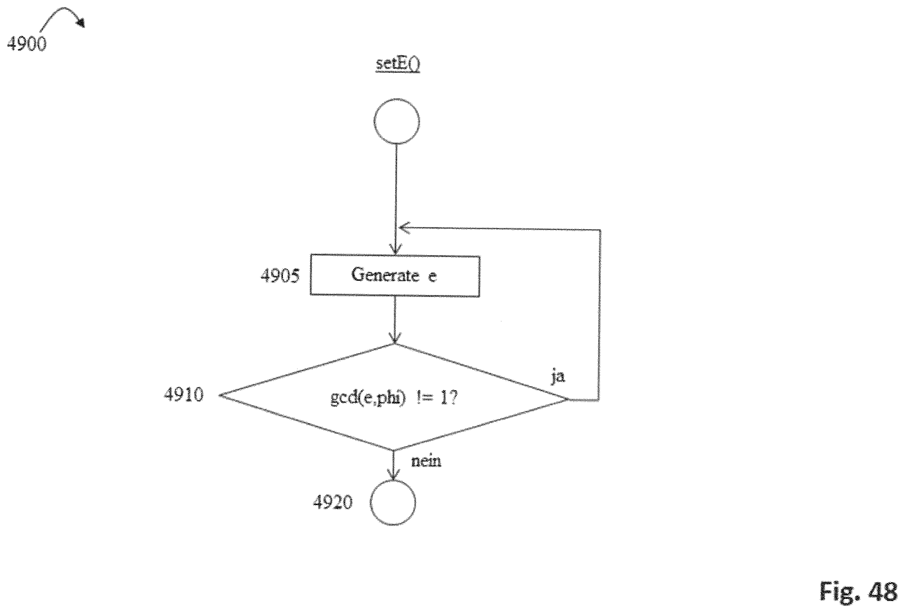

### FIG. 48

FIG. 48 shows the schematic sequence of the setEO function 4900. When the setE( ) function is called up in step 4900, the calling computer, in the case of the present document, the computer core 2 of the control device 4 of the other fuse 1 (client) or the computer core 2 of the control device 4 of the fuse 1 (server), generates a random number e for which it applies that e is relatively prime to the number phi. Relatively prime within the meaning of the present document means that there is no natural number, except for the number one, which simultaneously divides the number e and phi. The calling computer can generate the number e both by a random number of the quantum random number generator 4100, 60 QRNG and by a pseudo-random number generator PRNG and by more and more integrating of an integer number beginning with 2. However, the generation by means of the quantum random number generator 4100, 60 QNG is preferred.

The calling computer then checks in step 4910 whether the logic statement gcd(e,phi) !=1 is satisfied.

If the logic statement is satisfied, the calling computer repeats step 4900.

If the logic statement is not satisfied, the calling computer leaves the setE( ) function and returns the current value of e as a return value to the calling computer. The gcd(a,b) function is not a C standard function. By means of this gcd(a,b) function, the calling computer calculates the greatest common divisor of the transfer parameters a, b and returns the result to the calling computer.

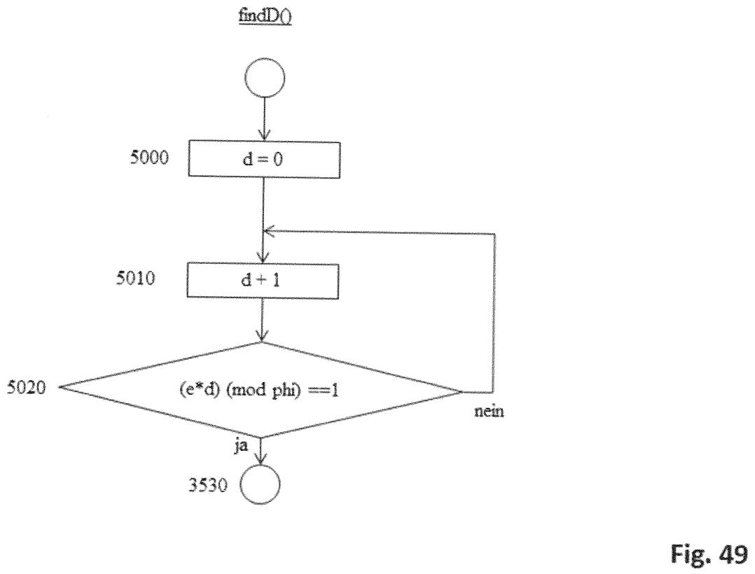

### FIG. 49

FIG. 49 shows the schematic sequence of the findD( ) function. If the calling computer calls up the findD( ) function in step S000, then the calling computer initializes a variable d with 0 in step S000.

In the next step S010, the calling computer adds the number 1 to the number d.

Then, in step S020, the calling computer checks whether the logic statement (e*d) (mod phi)=1 is satisfied. If the logic statement (e*d) (mod phi)=1 is not satisfied, the calling computer repeats the steps starting from step S010.

If the logic statement (e*d) (mod phi)=1 is satisfied, then in step S030 the calling computer leaves the findD( ) function and the calling computer gives the current value of d as a return value to the calling computer, in the case of the present document the computer core 2 of the control device 4 of the other fuse 1 (client) or the computer core 2 of the control device 4 of the fuse 1 (server).

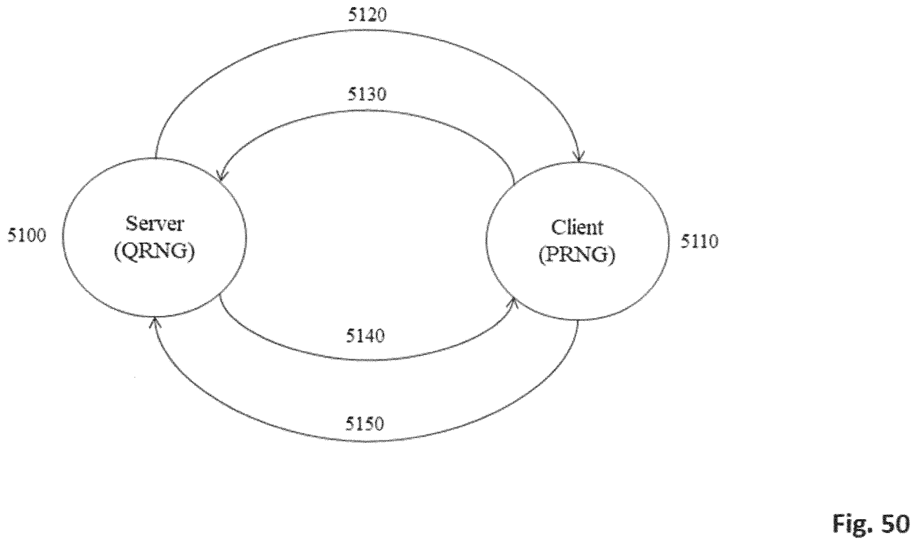

### FIG. 50

FIG. 50 shows the schematic sequence of a secure transmission of quantum-based random numbers between a computer core 2 of the control device 4 of the fuse 1 (server) 5100 and a computer core 2 of the control device 4 of the other fuse 1 (client) 5110.

In the case of the present document, the server 5100 is a computer core 2 of the control device 4 of the fuse 1 (server), wherein the computer core 2 of the control device 4 of the fuse 1 (server) 5100 has a quantum random number generator 4100, 60 QRNG. In the case of the present document, the client 5110 is a further computer core 2 of the control device 4 of the other fuse 1 (client), wherein now this computer core 2 of the control device 4 of the other fuse 1 (client) 5110 expressly has NO quantum random number generator 4100, 60 QRNG.

At the beginning, the computer core 2 of the control device 4 of the fuse 1 (server) 5100 generates quantum random numbers QZ1. The quantum random numbers QZ1 serve the computer core 2 of the control device 4 of the fuse 1 (server) 5100 as a basis for generating a private and a public key of the server 5100 according to an asymmetric encryption method.

The asymmetric encryption method can be, for example, the RSA method.

In a step S120, the computer core 2 of the control device 4 of the fuse 1 (server) 5100 transmits the public key of the server 5100 via a non-bug-proof channel to the computer core 2 of the control device 4 of the other fuse 1 (client) 5110.

The computer core 2 of the control device 4 of the other fuse 1 (client) 5110 then generates a pseudo-random number PZ or a random number generated differently. The computer core 2 of the control device 4 of the other fuse 1 (client) 5110 stores the pseudo-random number PZ or the random number generated differently in a memory 15 of the computer core 2 of the control device 4 of the other fuse 1 (client) 5110. The computer core 2 of the control device 4 of the other fuse 1 (client) 5110 generates a first private key of the client 5110 and a first public key of the client 5110 using this pseudo-random number PZ or this random number generated differently.

The computer core 2 of the control device 4 of the other fuse 1 (client) 5110 encrypts the first public key of the client 5110 by means of the public key of the server 5100.

The computer core 2 of the control device 4 of the other fuse 1 (client) 5110 then transmits the encrypted first public key of the client 5110 to the computer core 2 of the control device 4 of the fuse 1 (server) 5100.

The computer core 2 of the control device 4 of the fuse 1 (server) 5100 now decrypts this message with its first private key. As a result, the computer core 2 of the control device 4 of the fuse 1 (client) 3600 now has the first public key of the client 5110 without said key being known to third parties.

The computer core 2 of the control device 4 of the fuse 1 (server) 5100 then generates a further, second quantum random number QZ2 by means of the quantum random number generator 4100, 60. The bit width of this second quantum random number is optionally equal to the bit width of the random number PZ of the client 5110.

The computer core 2 of the control device 4 of the fuse 1 (server) 5100 now encrypts the second quantum random number QZ2 with the first public key of the client 5110. For example, the first public key of the client 5110 can have the same length in number of bits as this new quantum random number QZ2. In this case, the computer core 2 of the control device 4 of the fuse 1 (server) 5100 can encrypt the second quantum random number QZ2, for example by bit-wise XOR linking of the second quantum random number QZ2 to PZ, to form an encrypted second quantum random number QZ2′. The computer core 2 of the control device 4 of the fuse 1 (server) 5100 then optionally transmits the encrypted second quantum random number QZ2′ to the computer core 2 of the control device 4 of the other fuse 1 (client) 5110 in a step S140.

The computer core 2 of the control device 4 of the other fuse 1 (client) 5110 decrypts the encrypted second quantum random number QZ2′ using its first private key to form the second quantum random number QZ2. If the computer core 2 of the control device 4 of the other fuse 1 (client) 5110 has determined the second encrypted quantum random number QZ2′ by bit-wise XOR linking of the random number PZ to the second quantum random number QZ2, the computer core 2 of the control device 4 of the other fuse 1 (client) 5110 can decrypt, for example, by means of bit-wise XOR linking of the encrypted second quantum random number QZ2′ to the random number PZ known to it to form the second quantum random number QZ2.

The computer core 2 of the control device 4 of the other fuse 1 (client) 5110 optionally uses the second quantum random number QZ2 now present as a basis for generating a second private and a second public key according to an asymmetric encryption method. The asymmetric encryption method can be, for example, the RSA method. The computer core 2 of the control device 4 of the other fuse 1 (client) 5110 now transmits its second public key via the non-bug-proof channel to the server 5100. In this case, it optionally encrypts this second public key of the client 5110 with the public key of the server 5100. The server 5100 decrypts the encrypted second public key of the client 5110 and then uses this second public key of the client for encrypting further messages to the computer core 2 of the control device 4 of the other fuse 1 (client) 5110. Optionally, the computer core 2 of the control device 4 of the fuse 1 (server) 5100 generates and transmits a new public key on the basis of a new quantum random number of its quantum random number generator 4100, 60 QRNG encrypted with the second public key of the client 5110 after a predetermined time or after the transmission of a predetermined volume of data to the computer core 2 of the control device 4 of the other fuse 1 (client) 5110. Optionally, the computer core 2 of the control device 4 of the fuse 1 (server) 5100 and the computer core 2 of the control device 4 of the other fuse 1 (client) 5110 then carry out the previously described method again, so that the keys are continuously changing. This makes it impossible even for a quantum computer to break the keys.

As a result, the computers involved can perform the communication based on the selected asymmetric encryption method after the exchange of these keys.

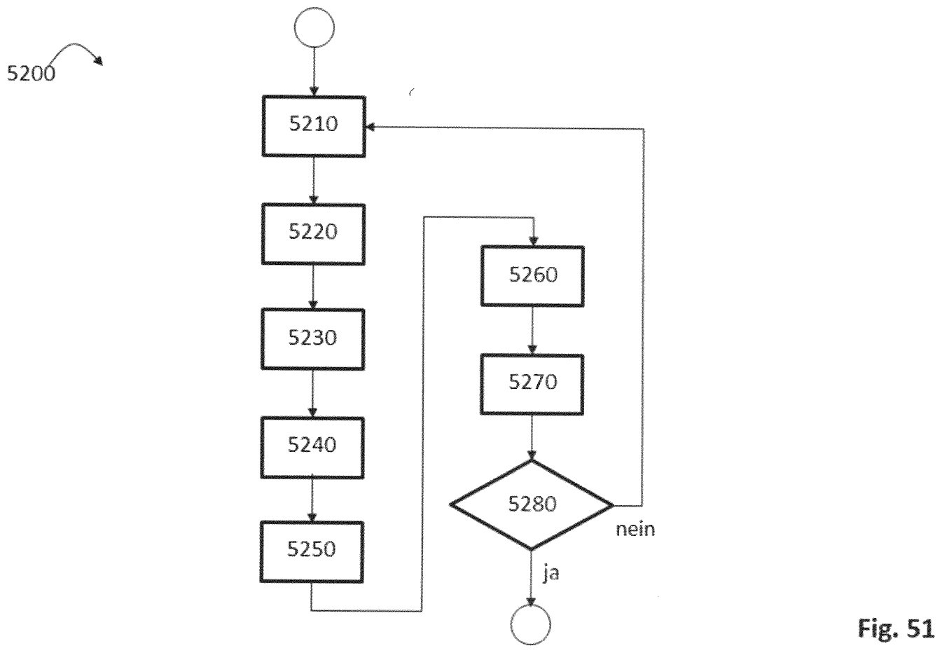

### FIG. 51

FIG. 51 schematically shows the proposed method 5200 for generating a quantum random number. The method 5200 begins with the generation 5210 of a random single-photon current (3957, 3958, 3959, 4101.2) by means of one or more first SPAD diodes (4101.1, 3954). The method 5200 continues with the transmission 5220 of the random single-photon current (3957, 3958, 3959, 4101.2) by means of an optical waveguide (3944, 4101.2) different from the semiconductor substrate (3949, 3948) to one or more second SPAD diodes (4101.3, 3955). This is followed by the conversion 5230 of the random single-photon current (3957, 3958, 3959, 4101.2) into a detection signal in the form of a voltage signal 4105 of the entropy source 4101, which optionally comprises the first SPAD diodes 4101.1 and the optical waveguide 4101.2 and the second SPAD diodes 4101.3. This is then followed by the conditioning 5240, in particular an amplification and/or filtering and/or an analog-to-digital conversion, of the detection signal into a conditioned detection signal, in particular a digital 14-bit value 4107 of the analog-to-digital converter 4103. Then the pulses of the conditioned detection signal that are generated by coupling the emissions of a first SPAD diode 4101.1 and of a second SPAD diode 4101.3 are separated 5250 from the pulses of the conditioned detection signal generated by spontaneous emission by comparing the conditioned detection signal to a threshold value 4104.1, in particular in a comparator 4104.2, and a corresponding output signal 4109, in particular of the comparator 4104.2, is generated. This is then followed by the determination 5260 of a first time interval between the first pulse and the second pulse of a first pulse pair from two successive pulses of the conditioned detection signal that are generated by coupling the emissions of a first SPAD diode 4101.1 and of a second SPAD diode 4101.3, and the determination of a second time interval between a third pulse and a fourth pulse of a second pulse pair from two successive pulses of the conditioned detection signal that are generated by coupling the emissions of a first SPAD diode 4101.1 and a second SPAD diode 4101.3, and, in particular for determining the first value of the output 4110 of the time-to-digital converter 4104.3 and the second value of the output 4110 of the time-to-digital converter 4104.3. On this basis, the determination 5270 of the bit value of a random bit is then made by comparing the value of the first time interval and the value of the second time interval. In a last check 5280, the computer core 2 of the control device 4 of the fuse 1 checks whether the number n of the determined random bits is even smaller than the desired number m of the random bits of the desired quantum random number. If this is not the case, the computer core 2 of the control device 4 of the fuse 1 repeats the above steps. Otherwise, the computer core 2 of the control device 4 of the fuse 1 terminates the process for generating a quantum random number.

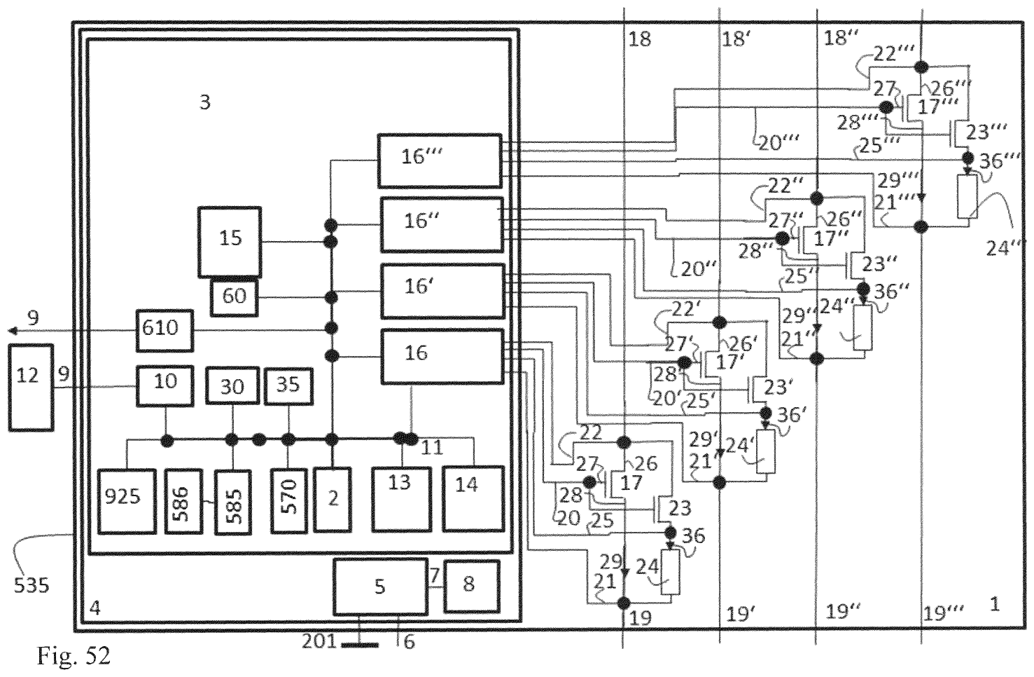

### FIG. 52

FIG. 52 shows a general four-way fuse with only one control device 4. For each protected line, the common control device 4 of the multiple fuse 1 has a corresponding gate drive circuit (16, 16′, 16″, 16″′) for controlling and monitoring the corresponding circuit breaker (17, 17′, 17″, 17″′). Each of the corresponding circuit breakers (17, 17′, 17″, 17″′) has a corresponding first terminal (18, 18′, 18″, 18″′) and a corresponding second terminal (19, 19′, 19″, 19″′) of the corresponding circuit breaker (17, 17′, 17″, 17″′). Analogously to FIG. 1, a corresponding auxiliary circuit breaker (23, 23′, 23″, 23″′), optionally with a corresponding shunt resistor (24, 24′, 24″, 24″′), is in turn associated with each circuit breaker (17, 17′, 17″, 17″′) and is associated with the corresponding circuit breaker (17, 17′, 17″, 17″′) analogously to FIG. 1. The electronic multiple fuse of FIG. 52 thus comprises a first fuse channel (16, 18, 17, 19, 26, 27, 28, 20, 21, 22, 23, 24, 25) and a second fuse channel (16′, 18′, 17′, 19′, 26′, 27′, 28′, 20′, 21′, 22′, 23′, 24′, 25′) and a third fuse channel (16″, 18″, 17″, 19″, 26″, 27″, 28″, 20″, 21″, 22″, 23″, 24″, 25″) and a fourth fuse channel (16″′, 18″′, 17″′, 19″′, 26″′, 27″′, 28″′, 20″′, 21″′, 22″′, 23″′, 24″′, 25″′). The computer core (2) of the control device (4) controls and monitors the corresponding circuit breaker (17, 17′, 17″, 17″′) of the corresponding fuse channel via the corresponding gate drive circuit (16, 16′, 16″, 16″′) of the corresponding fuse channel. This control and monitoring by means of a single gate drive circuit (16, 16′, 16″, 16″′) is already described in the description of FIG. 1.

In FIG. 52, for better clarity, not all appropriate and in some cases customary device components of the control device 4 are shown. Further device components that the reader can assume as possibly present in FIG. 1 can be found, for example, in FIGS. 1, 5, 6, 9, 24, 41, 42, 53, 54, 55, 57, 58 and 62. The combination of the device parts of the Figure described here with those of these figures is expressly part of the disclosure of the disclosure.

The functions of the corresponding control lines (20, 20′, 20″, 20″′) for controlling the corresponding circuit breaker (17, 17′, 17″, 17″′) can be read there.

The functions of the corresponding monitoring line (20,20′, 20″, 20″′) for detecting the voltage between the corresponding second terminal (19, 19′, 19″, 19″′) of the corresponding circuit breaker (17, 17′, 17″, 17″′) and the corresponding control line (20, 20′, 20″, 20″′) of the corresponding circuit breaker (17, 17′, 17″, 17″′) can be read there.

The functions of the corresponding monitoring line (22,22′, 22″, 22″′) for detecting the voltage between the corresponding first terminal (18, 18′, 18″, 18″′) of the corresponding circuit breaker (17, 17′, 17″, 17″′) and the corresponding control line (20, 20′, 20″, 20″′) of the corresponding circuit breaker (17, 17′, 17″, 17″′) can be read there.

The functions of the corresponding measuring line (25, 25, 25″, 25″′) for detecting the voltage drop across the corresponding shunt resistor (24, 24′, 24″, 24″′) can be read there.

Optionally, the multiple fuse of FIG. 52 is manufactured monolithically or as a module with a microelectronic circuit, which optionally comprises the control device 4 and optionally also the shunt resistors (24, 24′, 24″, 24″′) and is optionally manufactured in CMOS technology. Such a multiple fuse can be used as a cross-over fuse 1000 or as a triple fuse 3010 or as a three-phase fuse with a star point fuse via the fourth fuse channel without having to change the hardware.

For example, it is expedient to electrically connect the second terminals (19, 19′, 19″, 19″′) and to use the first fuse channel (16, 18, 17, 19, 26, 27, 28, 20, 21, 22, 23, 24, 25) for protecting the ground lead of a first half-bridge for the first three-phase current phase R (L 1) and to use the second fuse channel (16′, 18′, 17′, 19′, 26′, 27′, 28′, 20′, 21′, 22′, 23′, 24′, 25′) for protecting the ground lead of a first half-bridge for the second three-phase current phase S (L2), and to use the third fuse channel (16″, 18″, 17″, 19″, 26″, 27″, 28″, 20″, 21″, 22″, 23″, 24″, 25″) for protecting the ground lead of a first half-bridge for the third three-phase current phase T (L3). The second terminals (19, 19′, 19″, 19″′) then form the star point. The fourth fuse channel (16″′, 18″′, 17′, 19″′, 26″′, 27″′, 28″′, 20″′, 21″′, 22″′, 23″′, 24″′, 25″′) can then secure the star point against the reference ground, typically the ground, via its first terminal (18″′).

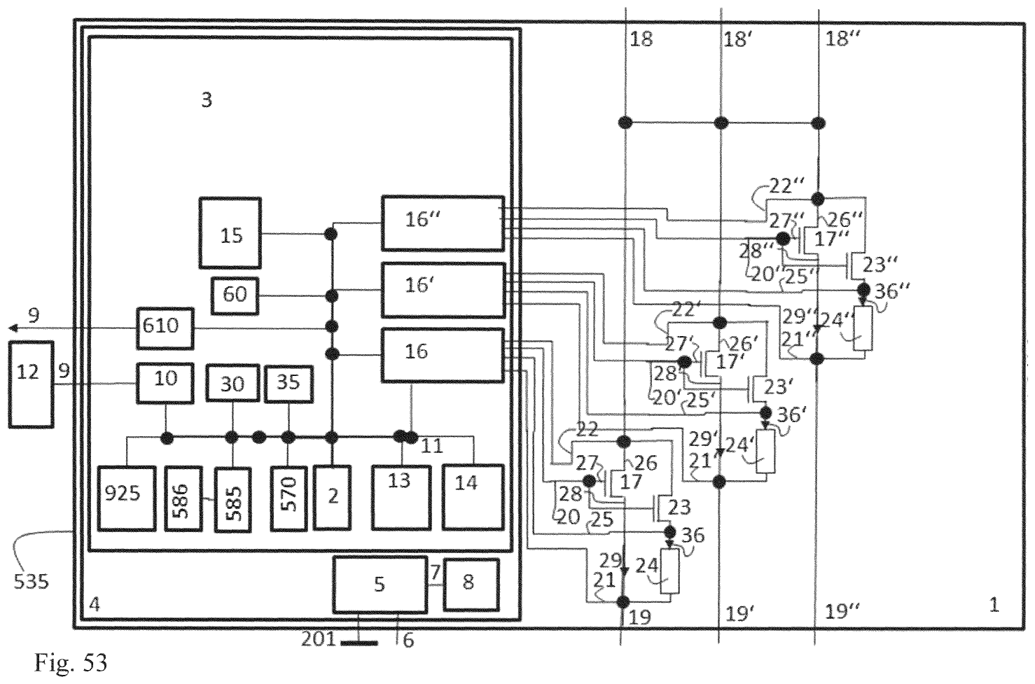

### FIG. 53

FIG. 53 shows the general four-way fuse of FIG. 52 as a general triple fuse, wherein the three circuit breakers 17, 17′ and 17″ are wye-connected, so that they can be used, for example, as the triple fuse 3010′ of FIG. 31.

In FIG. 53, for better clarity, not all appropriate and in some cases customary device components of the control device 4 are shown. Further device components that the reader can assume as possibly present in FIG. 1 can be found, for example, in FIGS. 1, 5, 6, 9, 24, 41, 42, 52, 54, 55, 57, 58 and 62. The combination of the device parts of the Figure described here with those of these figures is expressly part of the disclosure of the disclosure.

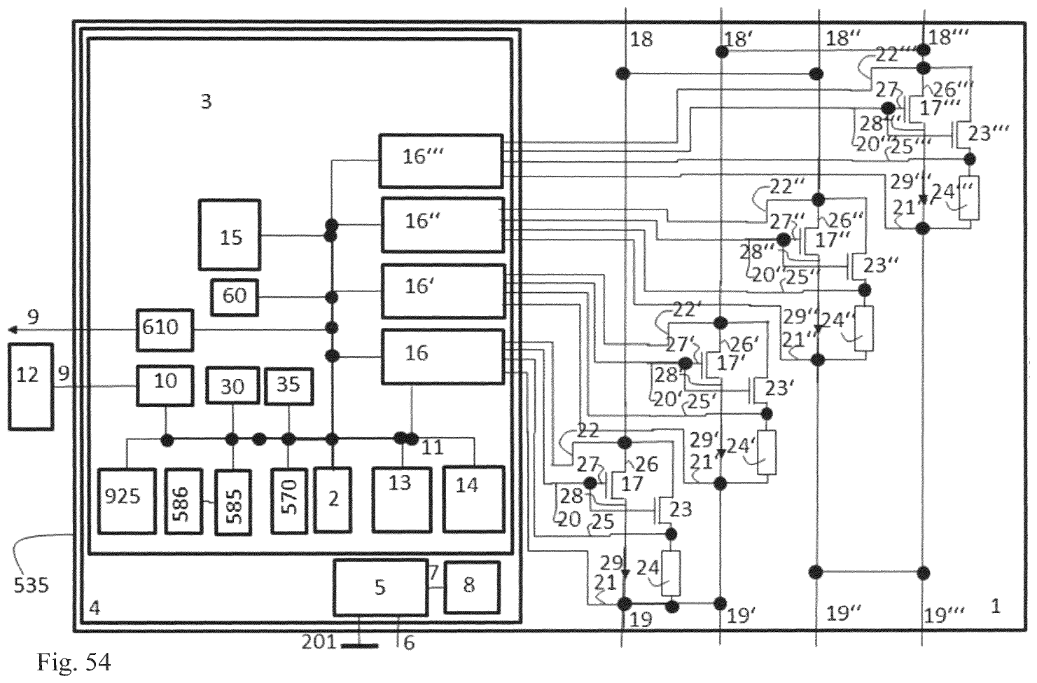

### FIG. 54

FIG. 54 shows the general four-way fuse of FIG. 52 wherein the four circuit breakers 17, 17′, 17″ and 17″′ are interconnected to form the cross-over fuse 1000.

In FIG. 54, for better clarity, not all appropriate and in some cases customary device components of the control device 4 are shown. Further device components that the reader can assume as possibly present in FIG. 1 can be found, for example, in FIGS. 1, 5, 6, 9, 24, 41, 42, 52, 53, 55, 57, 58 and 62. The combination of the device parts of the Figure described here with those of these figures is expressly part of the disclosure of the disclosure.

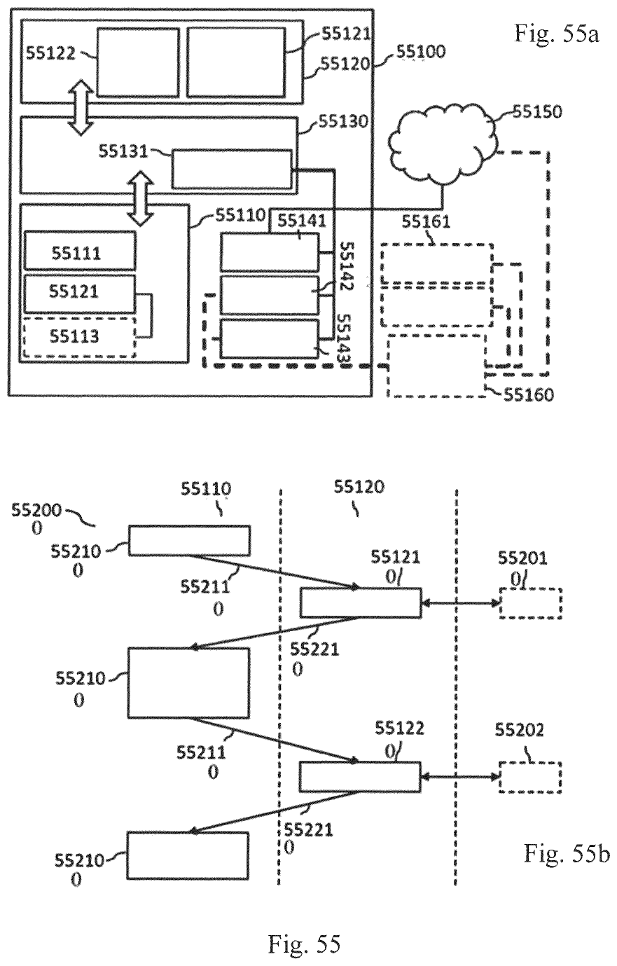

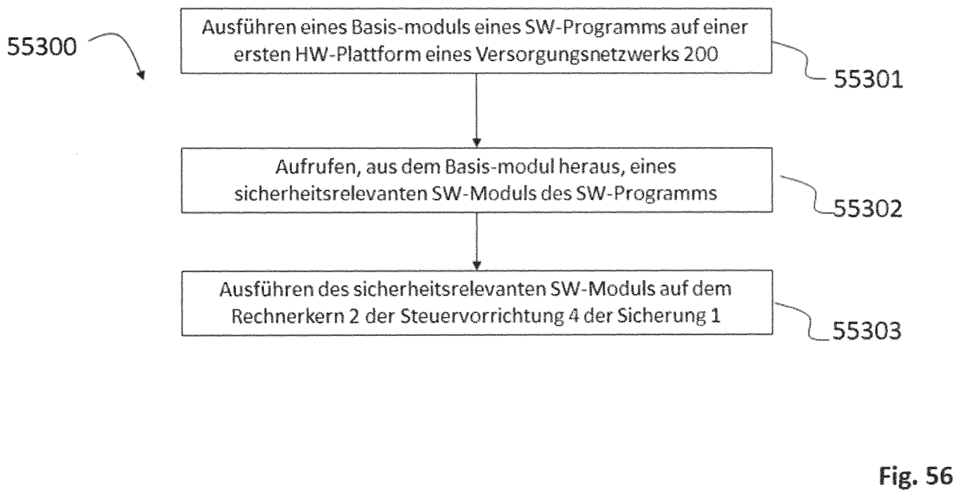

### FIG. 55a

FIG. 55a shows a block diagram of a system 55100 for providing SW programs in a supply network 200. The system 55100 comprises a first HW platform 55110 (for example a higher-level computer system 12 or a server 710 of a service provider, etc.) on which different SW programs 55111, 55112, 55113, in particular a SW program 55113 of an external provider, can be executed. The SW programs 55111, 55112, 55113 can be executed using an operating system 55130. Furthermore, the SW programs 55111, 55112, 55113 can access one or more HW drivers 55131, for example in order to enable data communication via a communication unit 55141, 55142, 55143, 555 (for example via a communication unit 55141 for a cellular network (GSM, UMTS, LTE), via a communication unit 55142 for WLAN and/or via a communication unit 55143 for Bluetooth).

In FIG. 55a, for better clarity, not all appropriate and in some cases customary device components of the control device 4 are shown. Further device components that the reader can assume as possibly present in FIG. 1 can be found, for example, in FIGS. 1, 5, 6, 9, 24, 41, 42, 52, 53, 54, 57, 58 and 62. The combination of the device parts of the Figure described here with those of these figures is expressly part of the disclosure of the disclosure.

The system 55100 further comprises a control device 55120, 4 of a fuse 1 having a computer core 2 for executing one or more safety-relevant SW modules 55121, 55122 of the SW programs 55111, 55112, 55113 implemented on the first HW platform 55110. A safety-relevant SW module 55121, 55122 can comprise, for example, safety-relevant data and/or safety-relevant program code and/or SW modules 55121, 55122, which change the switching state of the circuit breaker 17 of the fuse 1 and/or SW modules 55121, 55122, which enable access to memories 14, 15 of the control device 55120, 4 of the electronic fuse 1, and/or SW modules 55121, 55122, which enable the downloading and/or the execution of SW in the memory 14, 15 of the control device 55120,4 of the fuse 1, and/or SW modules 55121, 55122, which enable the reading of measured values and/or data of the memories of the control device 55120, 4 of the fuse 1, and/or SW modules 55121, 55122, which enable the configuration of parameters and/or threshold values and the like in the control device 55120, 4 of the fuse 1. Alternatively or additionally, a safety-relevant SW module 55121, 55122 can enable access to a safety-relevant internal function of the supply network 200 and/or to a safety-relevant internal function of the electronic fuses 1 of the supply network 200 and/or to a function external to safety-relevant, internal functions of the supply network 200 and/or to a function external to safety-relevant, internal functions of the electronic fuses 1 of the supply network 200.

The control device 55120, 4 of the fuse 1 can be subject to one or more special safety measures. In particular, a detailed analysis and checking of the one or more SW modules 55121, 55122 installed on the control device 55120, 4 of the fuse 1 can be performed by the manufacturer of a vehicle. Furthermore, measures can be provided which prevent unauthorized access to SW modules 55121, 55122 and/or data on the control device 55120, 4 of the fuse 1. The control device 55120, 4 of the fuse 1 can have a safety measure which provides special protection from side-channel attacks for the control device 55120, 4 of the fuse 1. Furthermore, a physical reading of a memory of the control device 55120, 4 of the fuse 1 can be prevented by a safety measure. In other words, the control device 55120, 4 of the fuse 1 can be protected by one or more safety measures in such a way that the one or more memories 14, 15 of the control device 55120, 4 of the fuse 1 cannot be read out (from the outside). The control device 55120, 4 of the fuse 1 can in particular be designed to be tamper-resistant or tamper-proof.

A trusted application environment of a control device 55120, 4 of the fuse 1 for an automobile manufacturer and a provider of third-party software for use in a supply network according to the proposal is thus provided. The safety hardware platform control device 55120, 4 of the fuse 1 represents an abstraction layer between the controller operating system 55130-typically in the higher-level computer system 12—one or more high-safety modules 55121, 55122 and all other SW programs 55111, 55112, 113. A high-safety module 55121, 55122 is typically very small so that the program source code of such a module 55121, 55122 can be checked. Furthermore, the safety hardware platform 55120 provides strong isolation for a high-safety module 55121, 55122. This prevents access to computing operations and/or data of a high-safety module 55121, 55122 by a different high-safety module 55121, 55122 or by another SW program 55111, 55112, 55113. The one or more interfaces for high-safety modules 55121, 55122 can be uniform and/or standardized.

FIG. 55a further shows a communication network 15150 (e.g., the Internet 720) with which it is possible to communicate directly (e.g., via a communication unit 55141 for a cellular network) or indirectly via a smartphone 55160, 740 with one or more SW applications 55161.

### FIG. 55b

FIG. 55b illustrates an exemplary sequence 55200 of a SW program 55111, 55112, 55113. An SW program 55111, 55112, 55113 can comprise one or more base modules 55210 which can be installed on the first HW platform 55110, i.e., for example, the higher-level computer unit 12. Furthermore, a SW program 55111, 55112, 55113 can comprise one or more safety-relevant modules 55121, 55122, which are optionally installed on the control device 55120, 4 of the fuse 1. In the execution of a SW program 55111, 55112 55113, a base module 55210 can first be executed which, if necessary, calls up a safety-relevant module 55121, 555122. During the call, input data 55211 can be transferred to a safety-relevant module 55121, 55122. Furthermore, output data 55221 can be transferred back to a base module 55210 after or during the execution of the safety-relevant modules 55121, 55122. By dividing a SW program 55111, 55112, 55113 into one or more base modules 55210 and one or more safety-relevant modules 55121, 55122, complex applications can be provided which, however, only comprise relatively small safety-relevant modules 55121, 55122, which can be checked in an efficient and reliable manner.

Access to a safety-relevant supply-network-internal function 55201 and/or to a safety-relevant supply-network-external function 55202 can optionally be made possible exclusively by a safety-relevant module 55121, 55122. The safety of functions 55201 of the supply network 200 and/or of supply-network-external functions 55202 can thus be ensured in an efficient manner.

In one example of an automatic equipment variant billing, an external provider provides a payment application 55113 by means of its server 710. This application 55113 is divided, for example, into two parts 55121, 55210: a safety-critical part 55121 and a safety-uncritical part 55210. The safety-critical part 55121 is executed on a safety hardware platform 55120, for example of the control device 4 of a fuse 1, and the safety-uncritical part 55210 is executed within the usual controller operating system 55130 or on the first HW platform 55110, for example the higher-level computer system 12 itself. For example, the cryptographic operations required for the payment process and/or the access to the switching states of the circuit breakers 17 of the electronic fuses 1 of the supply network can be regarded as a safety-critical part 55121. The user interface and the communication with the Internet 55150, for example, can be viewed as a safety-uncritical part 55210. All critical operations (in particular encryption and in particular post-quantum encryption) can be executed on the safety hardware platform 55120, so that, for example, all data from and to the Internet 55150, which are processed, for example, on the first HW platform 55110 (e.g., server 710), are encrypted and integrity-protected. The safety hardware platform optionally comprises a true random number generator 60 and/or a quantum random number generator 60. The safety hardware platform 55120, i.e., for example, a control device 55120, 4 of the fuse 1, optionally uses a quantum random number generator 60 for encryption.

A user 730 changes the capabilities of his vehicle by changing the equipment variant. For this purpose, the user 730 makes contact with the higher-level computer system 12 of the supply network 200 of the vehicle via a terminal 740 of the vehicle, for example via WLAN, Bluetooth, or Internet. Using a safety-critical part 55121 of the payment application 55113, the user or the vehicle is registered as using this equipment variant, and a confirmation can be output via the user interface (by means of a safety-uncritical part 55210). Upon termination of the use of the equipment variant, a safety-critical part 55121 of the payment application 55113 in turn makes the calculation of the costs and, in this case, identifies the vehicle with the supply network 200 unambiguously by means of cryptographic operations, which optionally use PQC-fixed signatures and encryptions and access random numbers of the true random number generator 60 and/or of the quantum random number generator 60.

Using the system 55100 described in this document, an equipment variant application 55113 can be divided into two parts 55210, 55121, a safety-critical part 55121 and a safety-uncritical part 55210. The safety-critical part 55121 is executed on the safety HW platform 55120 (control device 55120, 4 of the fuse 1) and the safety-uncritical part 55210 can be executed within the higher-level computer system 12 and/or together with a non-critical user application on, for example, a smartphone 55160.

For example, the cryptographic operations required for changing the switching states of the circuit breakers 17 of the fuses 1 and/or for changing the switching thresholds for the switching of the circuit breakers 17 and/or for all other changes in the behavior of the circuit breakers 17 of the fuses 1 and the cryptographic operations required for the billing process and the parameters for the operation of the quantum random number generators and the other cryptographic devices and safety-relevant devices can be regarded as a safety-critical part 55121. The user interface and the communication, for example, with the Internet can be viewed as a safety-uncritical part 55210. Because all critical operations are already executed on the safety HW platform 55120 (control device 55120, 4 of the fuse 1), for example all data from and to the Internet are already encrypted (optionally PQC encrypted) and integrity-protected.

A user 730 installs an application for changing the equipment variants (which supports supply-network-specific interfaces) on a smartphone 55160, which is to serve here as a terminal 740. The user 730 registers with a server 730 of a provider for the equipment variants, which in turn carries out registration of the user 730 in a backend. Using the equipment variant application, the user 730 registers an available equipment variant of the supply network, which corresponds to an equipment variant of the vehicle, and receives on his smartphone 55160 (740) a “token” with which he can use a specific equipment variant, i.e., a specific configuration and topology of the supply network 200 with specific properties of the fuses 1 of the supply network 200 with specific supply sub-networks of the supply network, and specific power sources and loads of the supply network with specific parameter ranges of these power sources and loads, and with specific functions of these power sources and loads, for example, within a specific period of time and, for example, within a specific geographical region. The user with his smartphone 55160 (740) and/or via a different terminal 740 of the vehicle can use the now supplied and approved device parts of the vehicle and of the supply network 200 and parameterize them within the scope of what is licensed.

The safety-critical part 55121 of the equipment variant configuration application 55113 verifies the “token,” and the use of the relevant equipment variant is granted when the “token” is confirmed. In this case, it is impossible for a user 730 to generate a token himself or to reinstall an old token. Furthermore, due to the structure described in this document, it is irrelevant whether the smartphone 55160 or the equipment variant configuration application are unsecure, because only the safety-critical part 55121 of the equipment variant configuration application 55113 influences critical components 55201 of the supply network 200 and/or critical supply-network-external components 55202 (e.g., on/off of the circuit breakers 17 of the fuses 1).

Further adaptation of the underlying hardware (in particular of the processor environment of the head unit, for example) can enable a further isolation of SW programs 55113 of an external provider. Applications can be completely isolated from the remaining software environment of the higher-level computer system 12. The safety can thus be further increased.

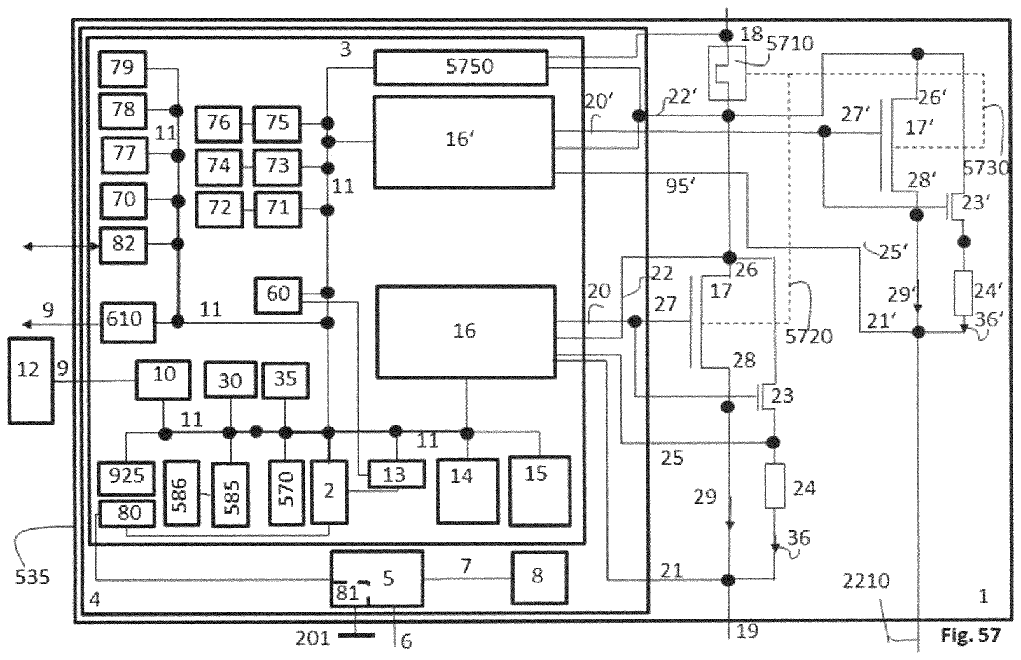

### FIG. 56

FIG. 56 shows a flowchart of an exemplary method 55300 for executing a SW program 55113 in a supply network 200. The SW program 55113 can be provided by an external provider for an application. The external provider can also be neither the manufacturer of the vehicle nor a supplier for a component of the vehicle, of which the supply network is a part. The external provider can be, for example, a service provider which, by means of the SW program 55113, would like to provide a service, such as a billing service, an equipment variant service, etc., in connection with the supply network 200.

The method 55300 comprises the execution 55301 of a base module 55210 of the SW program 55113 on a first HW platform 55110 of the vehicle (e.g., on the higher-level computer system 12 of the supply network 200). The base module 55210 can enable, for example, relatively non-critical functions, such as a user interface and/or a communication with a network 55150 and/or with a supply-network-external device 55160 (e.g., a smartphone or a car key or the like).

A safety-relevant module (55121) of the SW program (55113) can then be called up (step S5302) from the base module 55210 when the SW program 55113 is executed. The safety-relevant module 55121 accesses safety-relevant data (e.g., cryptographic keys and/or billing data) and/or a safety-relevant function (e.g., one or more gate drives 16 of one or more circuit breakers 17 of one or more fuses 1 in the supply network 200 of the vehicle).

In addition, the method 55300 comprises the execution 55303 of the safety-relevant module 55121 on a control device 55120, 4 of the supply network 200. In this case, the control device 55120, 4 of the fuse 1 is subject to one or more safety measures to which the first HW platform 55110, i.e., for example, the higher-level computer system 12 and/or the terminal 740 is not subject. For example, for SW modules 55121 which are to be executed on the control device 55120, 4 of the fuse 1, a check of the SW code by the manufacturer of the vehicle and/or the manufacturer of the supply network 200 and/or the manufacturer of the fuse 1 takes place in order to prevent undesired effects on a vehicle function 55201 and/or a function of the supply network 200 and/or a function of the fuse 1. Alternatively, or additionally, it is possible to limit data 55201, 55202 that can be transferred to a SW module 55121 or from a SW module 55121 which is executed on the control device 55120, 4 of the fuse 1. Within the meaning of the disclosure, the higher-level computer system 12 can also be considered in some applications as a fuse without circuit breakers 17. The first HW platform would then, for example, be the server 710 of the service provider and/or the terminal 740 for inputs of the user 730.

This document thus describes a standardized software and hardware environment for SW programs 55113 from external providers. The described system 55100 is optionally designed such that no special knowledge regarding embedded hardware/software is required and that all software interfaces are clearly defined. By abstraction of the hardware, an external provider of SW programs 55113 does not have to be concerned about hardware interfaces. Furthermore, a vehicle manufacturer or a manufacturer of a supply network does not have to make any software or hardware changes for the connection of a new SW program 55113.

A secure and reliable execution environment for SW programs 55113 is thus provided by external providers within a supply network 200. SW programs 55113 can be supplied during the operating time of a supply network 200 (after checking and signature by the automobile manufacturer or the manufacturer of the supply network), so that functional extension and/or changes in the equipment variant of the vehicle are enabled by a change in the equipment variant of the supply network 200. In addition, an automobile manufacturer, or the manufacturer of the supply network 200, can transfer safety-critical parts 55121 of a SW program 55111 onto the safety HW platform 55120 (control device 5120, 4 of the fuse 1) in order to increase the safety level of a higher-level computer system 12 of the supply network 200.

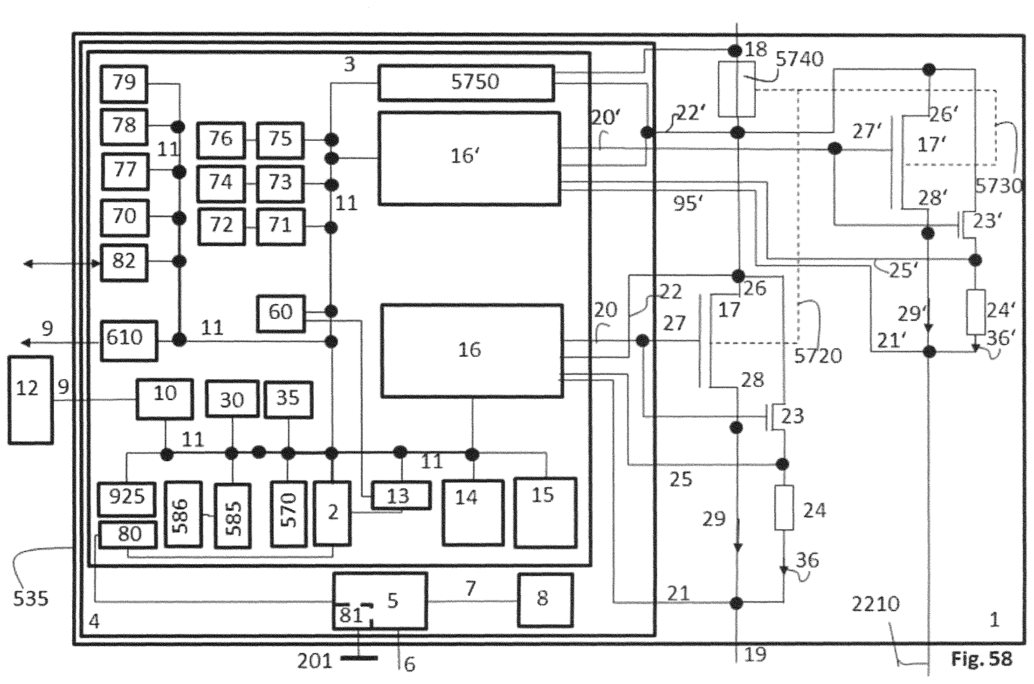

### FIG. 57

FIG. 57 corresponds to FIG. 24, wherein, for a better overview, the test current sources and the controllers thereof are not shown.

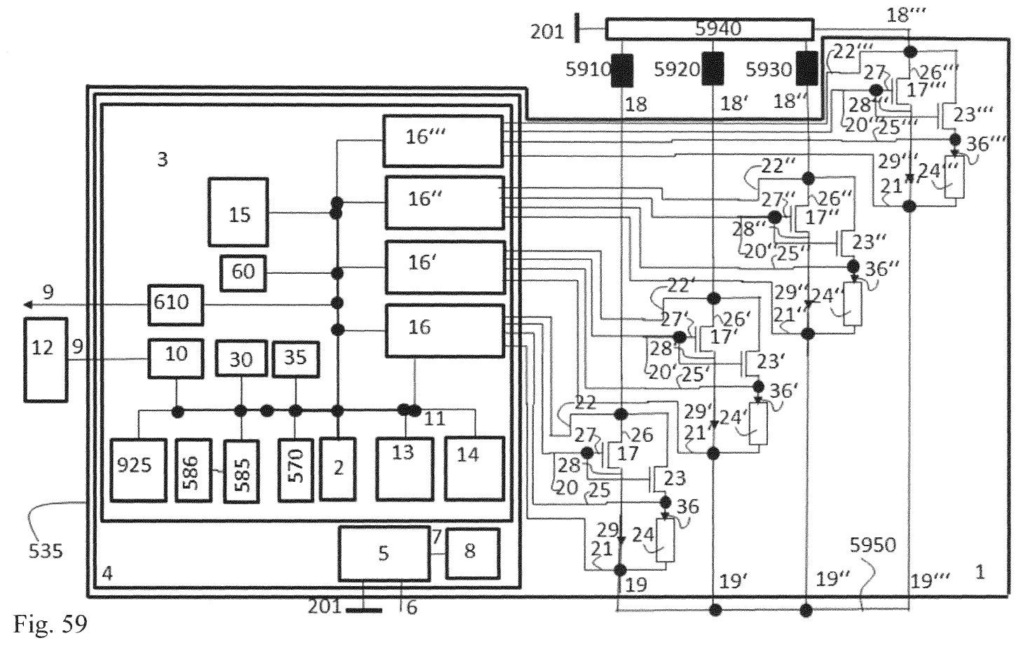

In FIG. 57, a temperature switch 5710 is inserted into the current path between the first terminal 18 of the fuse 1 and the second terminal of the fuse 1. The temperature switch 5710 switches within the permissible operating range of the fuse 1 independently of the currents 29 and 29′ through the circuit breaker 17 and the second circuit breaker 17′. The temperature switch 5710 typically switches back on if the temperature is undershot again. A temperature switch from safety aspects is therefore not always the optimum solution (see also FIG. 58). The temperature switch 5710 is optionally thermally coupled to the first circuit breaker 17. The temperature switch 5710 opens at an overtemperature of the circuit breaker 17 and optionally at an overtemperature of the fuse 1 and optionally at an overtemperature within the housing 535 of the fuse 1. The temperature switch 5710 is required in many applications to achieve functional safety. In the event of a failure of the power transistor 17, the power transistor 17 is no longer switchable and can continue to be conductive with a non-negligible residual resistance. If the load is, for example, a resistive load, which, even in the event of a reduction in voltage, does not ever or does not yet switch off for whatever reason, a high power can be implemented in the circuit breaker 17. This can lead to plasma development and/or to a fire. This is possible in particular if, for whatever reasons, combustible impurities are also in contact with the circuit breaker and/or the then typically heated safety housing 535.

The temperature switch 5710 then switches the current path through the circuit breaker 17 and here also the second circuit breaker 17′. In the event of an error of the second circuit breaker 17′, the temperature switch 5710 typically behaves in an analogous manner as a result of the thermal coupling between the second circuit breaker 17′ and the temperature switch 5710. If the power source is connected to the first terminal 19 of the fuse 1 and if the fuse 1 is itself supplied with electrical power from the current path downstream of the circuit breaker 17, for example from the electrical node of the second terminal 19 of the fuse 1, the control device 4 of the electronic fuse 1 can still be supplied from the power reserve 8 for a certain time before it becomes inoperative.

Optionally, a control device 4 of such a fuse 1 has a temperature switch/thermal fuse monitoring device 5750, which optionally monitors the voltage via the temperature switch 5710. The temperature switch/thermal fuse monitoring device 5750 is optionally designed such that it withstands the maximum voltage between the first terminal 18 and the second terminal 19 of the fuse, including necessary safety voltage margins, without interference. For this reason, such a control device 4 is optionally manufactured as an integrated circuit on an SOI substrate.

In the example of FIG. 57, the first circuit breaker 17 is thermally coupled to the temperature switch 5710 via a first temperature path of action 5720. In the example of FIG. 57, the second circuit breaker 17′ is thermally coupled to the temperature switch 5710 via a second temperature path of action 5730.

Of course, it is conceivable to equip the first circuit breaker 17 with a first temperature switch 5710 and the second circuit breaker 17′ with a separate temperature switch and, where applicable, with a second temperature switch/thermal fuse monitoring device.

Of course, it is conceivable for each further circuit breaker 17″, 17″′ to be equipped with a further separate temperature switch and optionally with a corresponding further temperature switch/thermal fuse monitoring device.

The computer core 2 of the control device 4 monitors and controls the temperature switches/thermal fuse monitoring devices 5750 via the internal data bus 11 of the control device 11.

In FIG. 57, for better clarity, not all appropriate and in some cases customary device components are shown. Further device components that the reader can assume as possibly present in FIG. 1 can be found, for example, in FIGS. 1, 5, 6, 9, 24, 41, 42, 52, 53, 54, 55, 58 and 62. The combination of the device parts of the Figure described here with those of these figures is expressly part of the disclosure of the disclosure.

### FIG. 58

FIG. 58 corresponds to FIG. 24, wherein, for a better overview, the test current sources and the controllers thereof are not shown.

Unlike in 57, the fuse 1 uses a thermal fuse 5740 instead of a thermal switch 5710. The thermal fuse switches off when the temperature is exceeded and then no longer switches on even after a decrease in the temperature. Optionally, the control device 4 of the electronic fuse has no influence on this disconnection process, so that no influence which could impair functional safety occurs.

In FIG. 58, the temperature fuse 5740 is inserted into the current path between the first terminal 18 of the fuse 1 and the second terminal of the fuse 1. The temperature fuse 5740 switches within the permissible current operating range of the fuse 1 independently of the currents 29 and 29′ through the circuit breaker 17 and the second circuit breaker 17′. The temperature fuse 5740 is thermally coupled to the first circuit breaker 17. At an overtemperature of the circuit breaker 17 and optionally at an over-temperature of the fuse 1 and optionally at an overtemperature within the housing 535 of the fuse 1, the temperature fuse 5740 opens. The temperature fuse 4 is required in many applications to achieve the functional safety. In the event of a failure of the power transistor 17, the power transistor 17 is no longer switchable and can continue to be conductive with a non-negligible residual resistance. If the load is, for example, a resistive load which, even in the event of a reduction in voltage, does not ever or does not yet switch off for whatever reason, a high power can be implemented in such a case in the circuit breaker 17. This can lead to plasma development and/or to a fire. This is possible in particular if, for whatever reasons, combustible impurities are also in contact with the circuit breaker and/or the then typically heated safety housing 535.

The temperature fuse 5740 then switches off the current path through the circuit breaker 17. If the power source is connected to the first terminal 19 of the fuse 1 and if the fuse 1 is itself supplied with electrical power from the current path downstream of the circuit breaker 17, for example from the electrical node of the second terminal 19 of the fuse 1, the control device 4 of the electronic fuse 1 can still be supplied from the power reserve 8 for a certain time before it becomes inoperative.

Optionally, a control device 4 of such a fuse 1 has a temperature switch/thermal fuse monitoring device 5750, which optionally monitors the voltage via the temperature fuse 5740. The temperature switch/thermal fuse monitoring device 5750 is optionally designed such that it withstands the maximum voltage between the first terminal 18 and the second terminal 19 of the fuse, including necessary safety voltage margins, without interference. For this reason, such a control device 4 is optionally manufactured as an integrated circuit on an SOI substrate.

In the example of FIG. 58, the first circuit breaker 17 is thermally coupled to the temperature fuse 5740 via a first temperature path of action 5720. In the example of FIG. 58, the second circuit breaker 17′ is thermally coupled to the temperature fuse 5740 via a second temperature path of action 5730.

Of course, it is conceivable to equip the first circuit breaker 17 with a first temperature fuse 5740 and the second circuit breaker 17′ with a separate temperature fuse and, where applicable, with a second temperature switch/thermal fuse monitoring device.

Of course, it is conceivable for each further circuit breaker 17″, 17″′ to be equipped with a further separate temperature fuse and, where applicable, with a corresponding further temperature switch/thermal fuse monitoring device.

The computer core 2 of the control device 4 monitors and controls the temperature switches/thermal fuse monitoring devices 5750 via the internal data bus 11 of the control device 11.

In FIG. 58, for better clarity, not all appropriate and in some cases customary device components are shown. Further device components that the reader can assume as possibly present in FIG. 1 can be found, for example, in FIGS. 1, 5, 6, 9, 24, 41, 42, 52, 53, 54, 55, 57 and 62. The combination of the device parts of the Figure described here with those of these figures is expressly part of the disclosure of the disclosure.

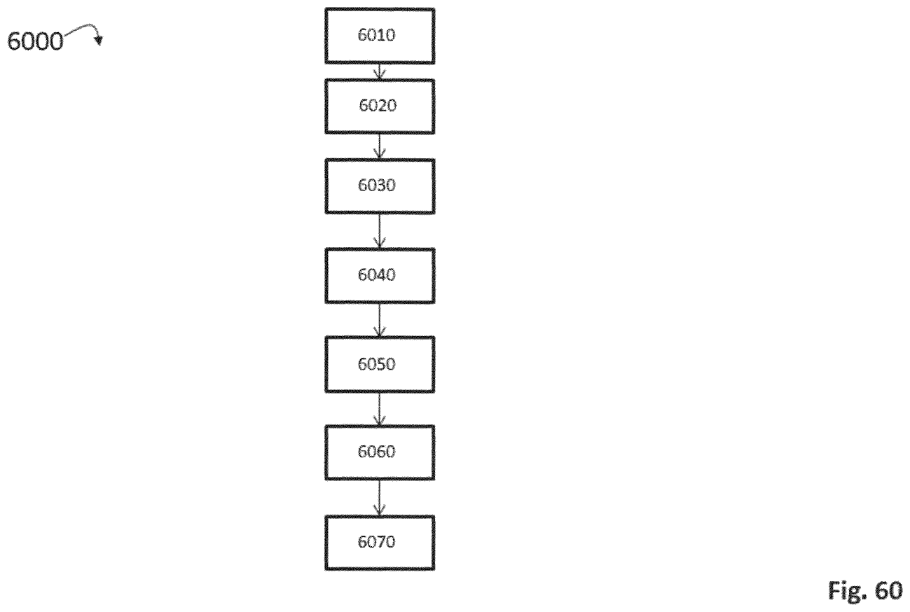

### FIG. 59

FIG. 59 corresponds to an application of the multiple fuse 1 of FIG. 52 to protect the three motor phases of an exemplary three-phase motor. The three motor coils 5910, 5920, 5930 are each protected by a circuit breaker of the corresponding circuit breakers 17, 17′, 17″. The star point is protected against ground 201 or a star point from the motor controller 5940 via the fourth circuit breaker 17″′. The second outputs 19, 19′, 19″ and 19″′ are connected to one another to form a virtual star point. The motor controller 5940 comprises the half-bridges for controlling the motor inductances 5910, 5920, 5930.

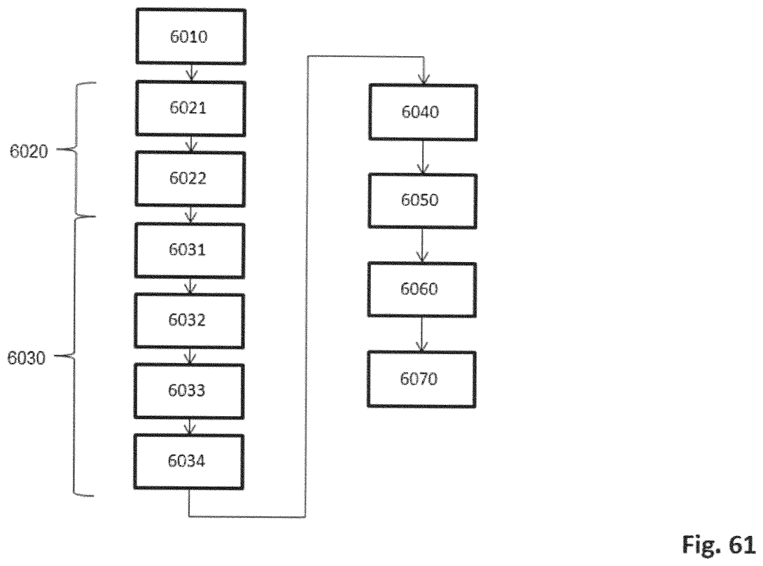

### FIG. 60

FIG. 60 shows in schematically simplified form the sequence of a method for transmitting compressed data from the fuse 1 to the higher-level computer system 12, wherein, within the meaning of the technical teaching presented here in connection with this data transmission, a compressed transmission from the control device 4 of the fuse to another control device 4 of a different fuse is included in the disclosure of the disclosure. The corresponding technical teaching is arrived at by replacing the higher-level computer system 12 with the control device 4 of a fuse in the corresponding texts regarding compressed data communication of this document. The compressed data, which the control device 4 of the fuse 1 transmits to the higher-level computer system 12, can be measured values, signal basic objects, signal objects (such as predetermined signal forms, etc.), state data of device parts of the fuse 1 and/or of monitored device parts of the supply network 200, etc., program data and other data.

A first preferred step of the method 6000 presented here comprises, as one of the first steps, the closing 6010 of the circuit breaker 17 of the fuse 1 by a control device 4 of a fuse 1.

A second preferred step 6020 of the method presented here comprises the detection of the physical parameter to be detected which the control device 4 of the fuse 1 detects in this second step 6020 using first means, which can comprise, for example, the analog-to-digital converter 570 of the control device 4 and/or the shunt resistor 24 and/or the auxiliary circuit breaker 23. The physical parameters to be detected can comprise, for example, voltages between circuit nodes within and outside the fuse 1 and/or electrical currents through lines within the fuse 1 and/or temperatures in and/or in the surroundings of the fuse 1. However, the parameters to be detected can also be derived parameters, such as the power that the control device 4 determines as a product of a voltage value (parameter 1) with a current value (parameter 2);

A third step 6030 can, for example, comprise an analysis and compression of the detected temporal parameter value characteristic of the detected physical parameter by the control device 4 of the electronic fuse 4 in order to minimize the data bus capacity of the data bus 9 necessary for the data transmission and to provide free space for status messages and further control commands of the higher-level computer system 12 to the control device 4 of the fuse 1 or for status messages and further data transmissions of the control device 4 of the fuse 1 to the higher-level computer system 12;

A fourth step 6040 of the method presented here for transmitting data-compressed data from the fuse 1 to the higher-level computer system can comprise the transmission of the compressed, detected temporal parameter value characteristic of the physical parameter to be signaled by the control device 4 of the electronic fuse 1 to the higher-level computer system 12.

A fifth step 6050 of the method presented here for transferring in particular the measurement data can comprise the decompression of the compressed, detected temporal parameter value characteristic received via the data bus 9 from the control device 4 of the fuse 1 by the higher-level computer system 12 to form a decompressed, detected temporal parameter value characteristic, which is ultimately a reconstructed, detected temporal parameter value characteristic that is associated with the control device 4 of the fuse 1 within the higher-level computer system 12;

A sixth step 6060 of the method presented here can comprise the comparison and/or correlation of the reconstructed, detected temporal parameter value characteristic associated with the control device 4 of the fuse 1 within the higher-level computer system 12 with one or more other reconstructed, detected temporal parameter value characteristics associated with the control devices 4 of other fuses 1 within the higher-level computer system 12 by the higher-level computer system 12. In this case, the higher-level computer system 12 optionally detects events which can optionally be attributed to the same causes in temporal correlation;

A sixth step 6070 can comprise as far as possible the adoption of measures depending on the detected events by the higher-level computer system 12. The measures adopted by the higher-level computer system 12 can depend here on detected signal objects and/or signal basic objects;

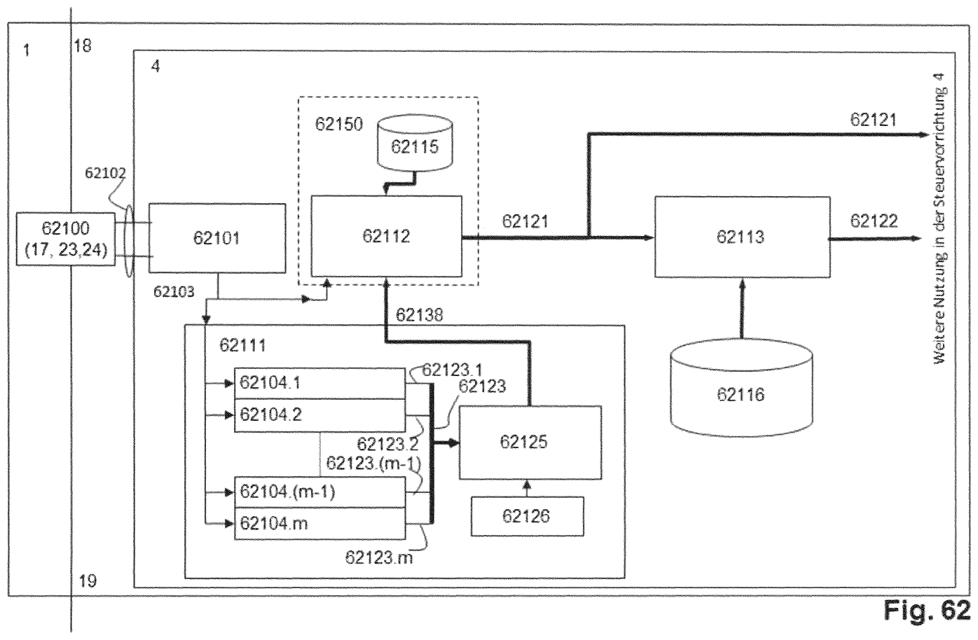

### FIG. 61

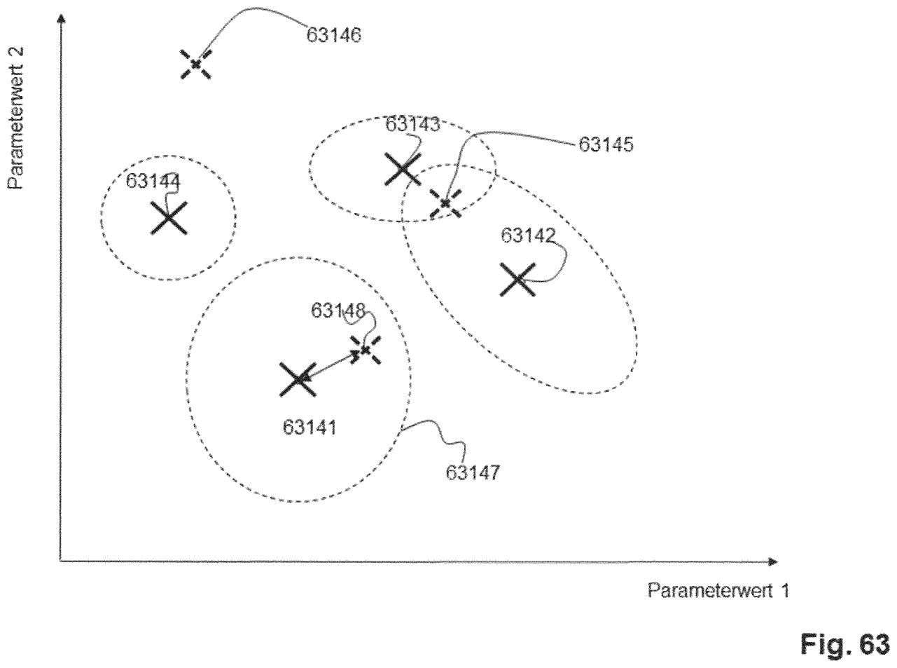

FIG. 62 is a refinement of FIG. 60, in which the steps 6020 of detecting the physical parameter to be detected by the control device 4 of the fuse 1 and 6030, the analysis and the compression of the detected temporal parameter value characteristic of the detected physical parameter, are refined into further exemplary sub-steps.

A first sub-step 6021 of step 6020 of detection of the physical parameter to be detected comprises the conversion of the electrical analog signals, which are generated by the means for detecting the physical parameters (e.g., temperature sensors 586 for detecting the temperature, shunt resistors 24 for detecting electrical currents 36, potential lines for detecting electrical potentials, analog-to-digital converters 570, etc.), by sampling in a first sub-step 6021 of the second step 6020 (see FIG. 61) by the control device 4 of the electronic fuse 1 in sampled time parameter value characteristics, which comprise a time-discrete flow of sampling values of the parameter values of the relevant physical parameter and any associated time stamps of these sampling values. Typically, the control device 4 of the fuse 1 optionally assigns to each sampling value and/or each of the sampling values a sampling instant as a time stamp of this sampling value at optionally equal time intervals.

A first sub-step 6022 of the step 6020 of the detection of the physical parameter to be detected comprises the performance of an exemplary wavelet transform or a different compression method and conversion of the sampled temporal parameter value characteristics into compressed temporal parameter value characteristics by the control device 4 of the fuse in a second sub-step 6022 of the second step 6020.

A first sub-step 6031 of step 6030 of the analysis and compression of the detected temporal value characteristic optionally comprises the analysis of the temporal parameter value characteristic of the parameters detected by the control device 4 of the electronic fuse 1 and/or of the time characteristic of parameters derived therefrom, for example by the matched filter of the control device 4 of the electronic fuse 1 in a first sub-step 6031 of the third step, and the preferred formation optionally in each case of a value of a vector component of a feature vector by optionally in each case one matched filter.

A second sub-step 6032 of the step 6030 of the analysis and compression of the detected temporal parameter value characteristic optionally comprises the extraction of a current feature vector from the detected temporal parameter value characteristics and/or from parameters derived from the prototypical time characteristics derived therefrom, by the control device 4 of the fuse and, where applicable, association of a corresponding time stamp, optionally with each of these feature vectors in a third sub-step 6023 of the second step 6020, by the control device 4 of the fuse.

A third sub-step 6033 of the step 6030 of the analysis and compression of the detected temporal parameter value characteristic optionally comprises the determination of a distance of the extracted current feature vector from a prototypical feature vector of the prototypical feature vectors of the prototype database 62115 in a third sub-step 6033 of the third step 6030.

A fourth sub-step 6034 of the step 6030 of the analysis and compression of the detected temporal parameter value characteristic optionally comprises the detection of a prototypical feature vector of the prototype database 62115 as a detected prototypical feature vector of the prototype database if the determined distance for this pair made up of this current feature vector and this prototypical feature vector of the prototype database 62115 is smaller than a distance threshold value and if at the same time this determined distance is less than or equal to any other distance between the current feature vector on the one hand and any other prototypical feature vector of the prototype database 62115.

### FIG. 62

FIG. 62 shows an exemplary device in the form of an exemplary electronic fuse 1. For better clarity, the details of FIGS. 1, 5, 6, 9, 24, 41, 42, 52, 53, 54, 55 and 57 are not shown. Further device components that the reader can assume as possibly present in FIG. 1 can be found in FIGS. 1, 5, 6, 9, 24, 41, 42, 52, 53, 54, 55, 57 and 58, for example. The control device 4 of the fuse optionally carries out a detection of signal objects and signal basic objects. The data interface 10, the data bus 9 and the higher-level computer system 12 are, for the sake of simplicity, also not shown. The means 62100 for detecting physical parameters of the fuse 1 generate signals 62102 of the temporal parameter value characteristics and/or the corresponding time characteristics of the parameters derived from these parameter value characteristics of the physical parameters. The physical interface 62101 of the control device 4 detects them and converts them into a parameter signal 62103, which can be a bundle of a plurality of signals. The parameter signal 62103 is the input signal of the subsequent signal object classification. The parameter signal 62103 is optionally a digitized signal with temporally spaced sampling values. The computer core 2 of the control device 4 of the electronic fuse can, for example, emulate device parts of the control device, if possible, by software program. The feature vector extraction 62111 has various devices, in this case for example n matched filters (matched filter 62123.1 to matched filter 62123.m), with m as a positive integer. The outputs of the matched filters 62123.1 to 62123.m, which are exemplary here, form the intermediate parameter signal 61123. Instead of the matched filters 62123.1 to 62123.m or in addition to these,
integrators and/or
differentiators and/or
filters and/or
logarithmizers and/or
FF and DFFT devices and/or
correlators and/or
demodulators which multiply their input signal with a predefined signal and then filter it, and/or
other signal-processing sub-devices and/or
combinations thereof can also be used depending on the application, which then generate the m-dimensional intermediate parameter signal 62123. The blocks in the drawings referred to as “matched filters” are to be understood only as placeholders for such signal processing blocks. Such a signal processing block designated with “matched filter” can also have more than one output, which contributes to the m-dimensional intermediate parameter signal 62123, i.e., multiple times with more than one signal. A downstream, exemplary significance increase unit 62125 serves to map the m-dimensional space of the intermediate parameter signal 62123 to an n-dimensional space of the signal of the feature vectors 62138. N here is a positive integer. In general, n is smaller than m. This is used, on the one hand, to maximize the selectivity of the parameter values from which each feature vector of the signal of the feature vectors 62138 results. This is optionally done by a linear mapping with the aid of an offset value determined in the laboratory with statistical methods, which value is added to the values of the intermediate parameter signal, and a so-called LDA matrix 62126, with which the corresponding vector of the corresponding sampling values of the intermediate parameter signals 62123 is in each case multiplied by the control device 4 to form a feature vector of the signal of the feature vectors 62138. The distance determination device/classifier 62112 optionally compares each feature vector resulting in this way of the signal of the feature vectors 62138 to each signal basic object prototype of the prototype database 62115. For this purpose, the prototype database 62115 contains an entry with a centroid vector (e.g., 63141, 63142, 63143, 63144) of the corresponding signal basic object prototypes of the prototype database 62115 for optionally each of the signal basic object prototypes of the prototype database 62115. Optionally, a distance of the currently examined feature vector of the signal of the feature vectors 62138 to the just examined centroid vector of the prototype database 63115 is calculated by the distance determination device 62112. However, the distance determination device 62112 can also in another way calculate an evaluation of the similarity between the centroid vector (e.g., 63141, 63142, 63143, 63144) of the corresponding signal basic object prototypes of the prototype database 62115 and the currently examined feature vector of the signal of the feature vectors 62138 in the form of an evaluation value, which we always call distance here for the sake of simplicity. In this way, the distance determination device 62112 determines whether a centroid vector (e.g., 63141, 63142, 63143, 63144) of the signal basic object prototypes of the prototype database 62115 is sufficiently similar to the current feature vector of the signal of the feature vectors 62138, i.e., has a sufficiently small distance, and, if this is the case, which centroid vector (e.g., 63141, 63142, 63143, 63144) of the signal basic object prototypes of the prototype database 62115 is most similar to the current feature vector of the signal of the feature vectors 62138, i.e., has the smallest distance. If necessary, the distance determination device 62112 determines a list of centroid vectors (e.g., 63141, 63142, 63143, 63144) of the signal basic object prototypes of the prototype database 62115, which are sufficiently similar to the current feature vector of the signal of the feature vectors 62138, i.e., have a sufficiently small distance. These are optionally ordered according to distance and passed on to the Viterbi estimator with their associated distance as a hypothesis list. An exemplary hypothesis list was indicated above. In the case of a single detected signal basic object 62121, the detection result of the distance determination device (which is also referred to here as a classifier) is forwarded as a symbol (for example as a prototype database address/index which points to the detected signal basic object prototypes of the prototype database 62115) and in the case of a hypothesis list optionally as a list of pairs of a symbol (index) of the detected signal basic object (for example the prototype database addressindex, which points to the detected signal basic object prototypes of the prototype database 62115) and the distance from the centroid of this detected signal basic object. The Viterbi estimator then searches for the sequence of signal basic object prototypes which best corresponds to a predefined sequence of signal basic object prototypes in its signal object sequence database 62116. In this case, matches are, for example, counted positively and non-matches are counted negatively, so that an evaluation value for each entry of the signal object sequence database 62116 results for a temporal sequence of detected signal basic object prototypes. In the case of hypothesis lists, the Viterbi estimator 62113 optionally checks all possible paths through the time sequence of hypothesis lists. Optionally, the Viterbi estimator 62113 determines its evaluation result taking into account the previously determined distances. This can be done, for example, by dividing the added values by the distance before the addition during the calculation of the evaluation value. In this way, the Viterbi estimator 62113 determines the detected signal objects 62122 which are then transmitted, if necessary, with suitable parameters via the data bus 9. The control device 4 can also transmit the detected signal basic objects 62121 directly to the higher-level computer system 12. The important thing is: This procedure, for example, involves the detection of events and states physically occurring, for example, in current signals and/or voltage signals within the fuse 1 and the transmission of this information and the detection of structures within the parameter signal 62103 and the transmission thereof to the higher-level computer system 12. As a side effect, the control device can deduce, from the occurring signal basic objects and from the sequence of these signal basic objects and their parameterization, the state of the fuse and/or the protected supply sub-network. If necessary, the control device 4 of the fuse 1 also takes into account the data of other sensors and/or fuses in the supply network 200 and/or in the vehicle and optionally further data from servers 710, which are connected in the broadest sense at least temporarily to the control device 4 of the fuse in a data connection via the data bus 9.

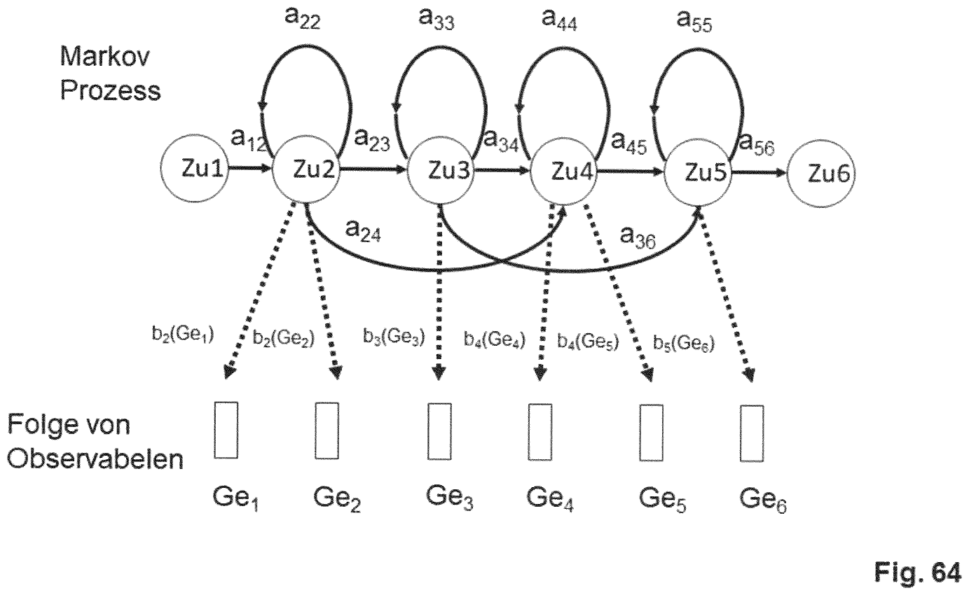

### FIG. 63

FIG. 63 serves to explain the selection of the signal basic object prototypes of the prototype database 62115 by the distance determination device 62112.

The position of the current feature vector of the signal of the feature vectors 62138 determined by the distance determination device/classifier 62112 in the, by way of example, two-dimensional parameter space of FIG. 63 can be very different. It is thus conceivable that such a first exemplary feature vector 63146 is too far away from the centroid coordinates (63141, 63142, 63143, 63144) of the centroid of any signal basic object prototypes of the prototype database 62115. This distance threshold value can be, for example, the aforementioned minimum half prototype distance below the signal basic object prototypes of the prototype database 62115. It may also be the case that the variation ranges of signal basic object prototypes of the prototype database 62115 overlap around their respective centroids (63143, 63142) and a second exemplary determined current feature vector 63145 of the signal of the feature vectors 63138 lies in such an overlapping region. In this case, a hypothesis list can contain both signal basic object prototypes having different probabilities as an added parameter because the distances are different. These probabilities are optionally represented by the distances. Therefore, it is not a signal basic object that is transferred as the most probable to the Viterbi estimator 62113, but a vector of possibly present signal basic objects (hypothesis list) is transferred to the Viterbi estimator 62113. From the temporal sequence of these hypothesis lists, the Viterbi estimator 62133 then searches for the possible sequence which the greatest probability to one of the specified signal basic object sequences in its signal object database compared to all possible paths through the signal basic objects 62121 detected as possible of the hypothesis lists received by the Viterbi estimator 62113 from the distance determination device/classifier 62112. In this case, precisely one detected signal basic object prototype of this hypothesis list per hypothesis list must be traversed by this path in such a path.

In the best case, the current feature vector 63148 is in the variation range (threshold ellipsoid) 63147 around the centroid 63141 of a single signal basic object prototype 63141, which is thereby reliably detected by the distance determination device 62112 and passed on to the Viterbi estimator 62113 as a detected signal basic object 62121.

It is conceivable, for improved modeling of the variation range of a single signal basic object prototype, to model said range by a plurality of signal basic object prototypes, which in this case are circular, with associated variation ranges. A plurality of signal basic object prototypes of the prototype database 62115 can thus represent the same signal basic object prototypes within the understanding of a signal basic object class.

The distance determination device 62112 optionally compares each thus resulting feature vector of the signal of the feature vectors 63138 to each signal basic object prototype of the prototype database 62115. For this purpose, the prototype database 62115 contains an entry with a centroid vector (e.g., 63141, 63142, 63143, 16344) of the corresponding signal basic object prototype of the prototype database 62115 for each of the signal basic object prototypes of the prototype database 62115. Optionally, a distance of the currently examined feature vector of the signal of the feature vectors 62138 to the just examined centroid vector of the prototype database 62115 is calculated by the distance determination device 62112. However, the distance determination device 62112 can also in another way calculate an evaluation of the similarity between the centroid vector (e.g., 63141, 63142, 63143, 63144) of the corresponding signal basic object prototypes of the prototype database 62115 and the currently examined feature vector of the signal of the feature vectors 62138 in the form of an evaluation value, which we always call distance here for the sake of simplicity. In this way, the distance determination device 62112 determines whether a centroid vector (e.g., 63141, 63142, 63143, 63144) of the signal basic object prototypes of the prototype database 62115 is sufficiently similar to the current feature vector of the signal of the feature vectors 62138, i.e., has a sufficiently small distance, and, if this is the case, which centroid vector (e.g., 63141, 63142, 63143, 63144) of the signal basic object prototypes of the prototype database 62115 is most similar to the current feature vector of the signal of the feature vectors 62138, i.e., has the smallest distance. If necessary, the distance determination device 62112 determines a list of centroid vectors (e.g., 63141, 63142, 63143, 144) of the signal basic object prototypes of the prototype database 62115, which are sufficiently similar to the current feature vector of the signal of the feature vectors 62138, i.e., have a sufficiently small distance.

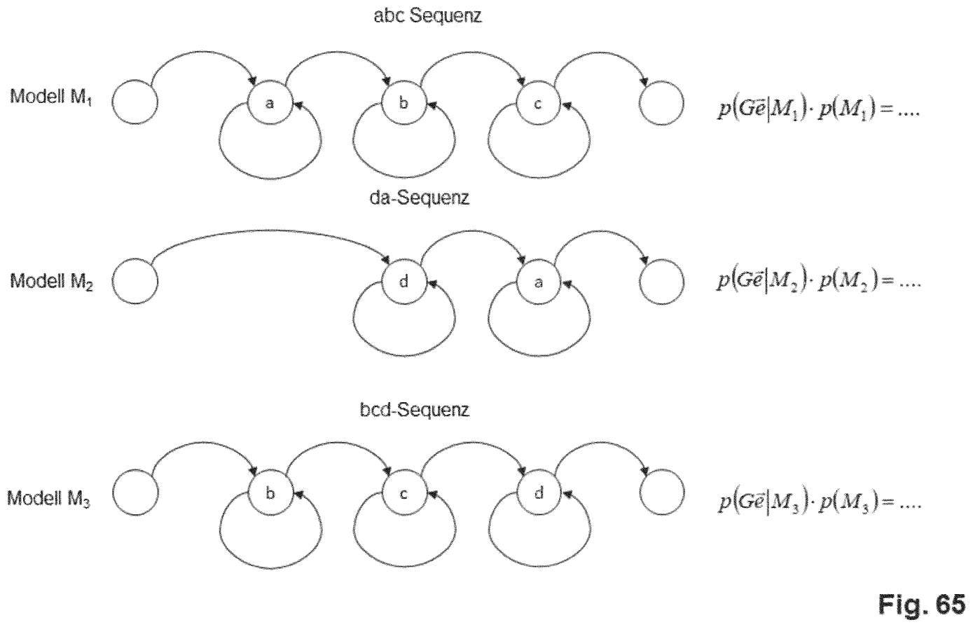

### FIG. 64

FIG. 64 serves to explain the HMM method that is applied by the Viterbi estimator 62113 in order to identify the signal object as the most likely sequence of signal basic object prototypes due to a sequence of detected signal basic object prototypes 62121 as a detected signal object 62122. FIG. 64 is explained above in the text.

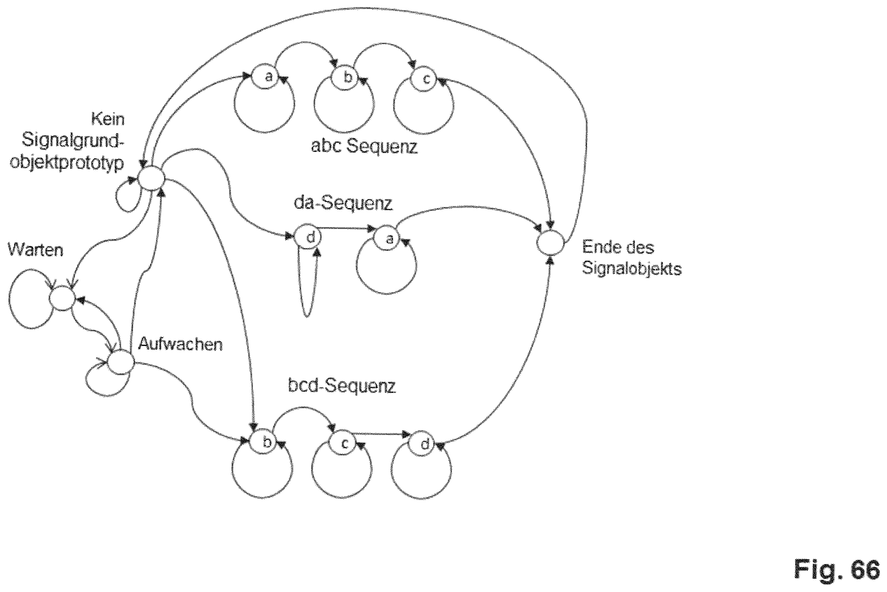

### FIG. 65

FIG. 65 shows an exemplary state sequence in the Viterbi estimator 62113 for the detection of a single signal object. FIG. 65 is explained above in the text.

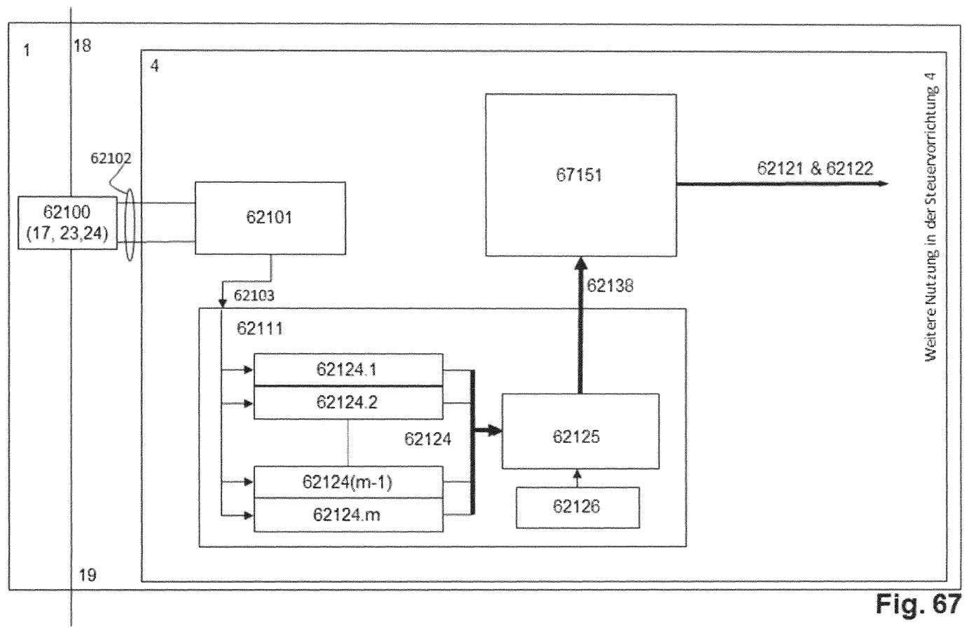

### FIG. 66

FIG. 66 shows an exemplary, preferred state sequence in the Viterbi estimator 62113 for the continuous detection of signal objects, as is typically necessary for detection during tasks of autonomous driving. FIG. 66 is explained above in the text.

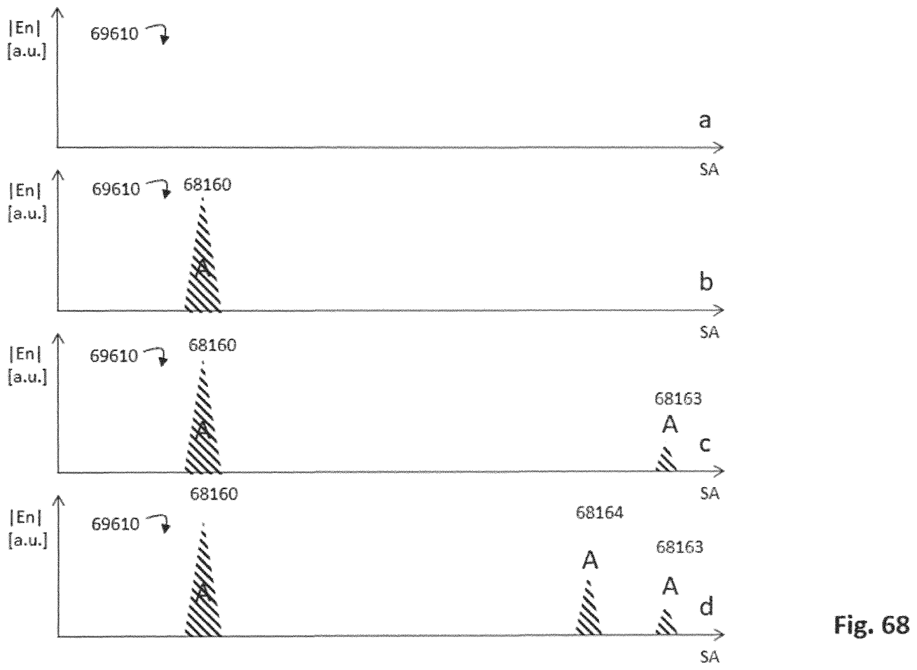

### FIG. 67

FIG. 67 largely corresponds to FIG. 62 with the difference that a neural network model 67151 classifies and analyzes the feature vectors of the signal of the feature vectors 62138. The computer core 2 of the control device 4 of the fuse 1 optionally executes the neural network model. This detection optionally is also performed by sampling window.

The neural network model 62151 is optionally trained in the laboratory with training data from feature vectors of real events with regard to the parameter value characteristic of the physical parameters that the control device 4 of the fuse detects.

FIG. 67 thus shows an alternative example with an estimator 62151 which executes a neural network model 62151. The data interface 10, 610 and the data bus 9 are, for the sake of simplicity, not entered. The means 62100 for detecting the physically relevant parameters are controlled and measured by a physical interface 62101. The physical interface 62101 serves for the conditioning of the measurement signals 62102 generated by these means 62100 to form the parameter signal 62103 for the subsequent signal object classification. Optionally, the parameter signal 62103 is a digitized signal with temporally spaced sampling values. The feature vector extraction 62111 in turn has different devices, in this case for example m matched filters (matched filter 1 to matched filter m) with m as a positive integer. The outputs of the matched filters 62124.1 to 62124.m, which are given here as examples, form the intermediate parameter signal 62123. Instead of the matched filters 62124.1 to 62124.m or in addition thereto, integrators, filters, differentiators, logarithmizers and/or other signal-processing sub-devices and the combinations thereof can also be used, depending on the application, which then generate the m-dimensional intermediate parameter signal 62123. A downstream, exemplary significance increase unit 62126 serves to map the m-dimensional space of the intermediate parameter signal 62123 to an n-dimensional space of the signal of the feature vectors 62138. N here is a positive integer. In general, n is smaller than m. This is used, on the one hand, to maximize the selectivity of the parameter values from which each feature vector of the signal of the feature vectors 62138 results. This is optionally done by a linear mapping with the aid of an offset value determined in the laboratory with statistical methods, which value is added to the values of the intermediate parameter signal 62123, and a so-called LDA matrix 62126, with which the corresponding vector of the corresponding sampling values of the intermediate parameter signals 62123 is in each case multiplied to form a feature vector of the signal of the feature vectors 62138. The estimator 67151 then attempts, for example, to detect the signal objects in the data stream of the feature vectors of the signal of the feature vectors 62138 with the aid of a neural network model 62151, which the computer core 2 of the control device 4 of the fuse 1 optionally implements. The signal basic object prototypes and the signal objects are encoded via the interconnection of the nodes within the neural network model and the parameterization of the neural network model within the neural network model. The estimator 67151 then outputs the detected signal objects 62122 and/or the detected signal basic objects 62121. Optionally, the control device 4 of the fuse then uses these detected signal objects 62122 and/or these detected signal basic objects 62121 first for communication with the higher-level computer system 12 of the supply network 200 and/or for deriving measures if the indices of the detected signal objects 62122 and/or if the detected signal basic objects 62121 and typically also the parameters thereof correspond to specifications and threshold values in specified combinations.

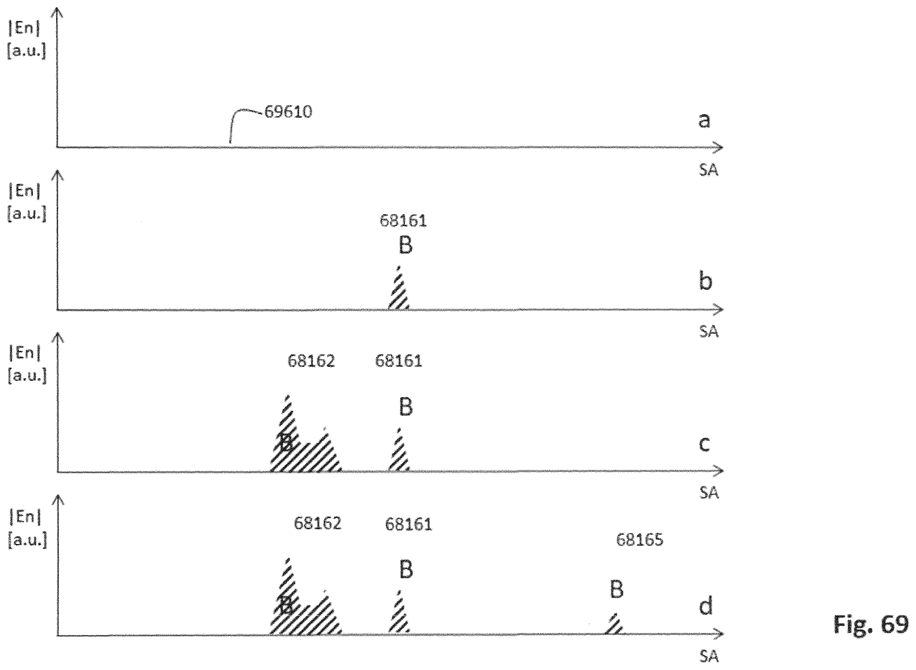

### FIG. 68

FIG. 68 shows the exemplary decompression of a transmitted exemplary sub-signal of the parameter signal 62103, wherein only signal components having a first property are incorporated in the reconstruction.

First, a parameter signal model 69610 is generated that does not have a signal. (FIG. 68a). The parameter signal model 69610 is parameterized using a model parameter (SA) which is optionally correlated with the time (t) since the start of the sampling window.

This parameter signal model 69610 is then optionally supplemented in a suitably parameterized manner by addition of the first exemplary signal object 68160, which describes a triangular shape and is transmitted with data transmission priority 1 from the control device 4 of the fuse 1 to the higher-level computer system 12. (FIG. 68b)

The second exemplary signal object 68161 transmitted with data priority 2 in triangular form is not taken into account for the reconstruction here, because it is intended to have first properties that exclude it.

The third exemplary signal object 68162 in dual peak form transmitted with data priority 3 is not taken into account for the reconstruction here, because it is intended to have first properties that exclude it.

The already supplemented parameter signal model 69610 is then optionally supplemented in a suitably parameterized manner by addition of the fourth exemplary signal object 68163, which describes a triangular shape and is transmitted with data transmission priority 4 from the control device 4 of the fuse 1 to the higher-level computer system 12. (FIG. 68c)

The already supplemented parameter signal model 69610 is then optionally supplemented in a suitably parameterized manner by addition of the fifth exemplary signal object 68164, which describes a triangular shape and is transmitted with data transmission priority 5 from the control device 4 of the fuse 1 to the higher-level computer system 12. (FIG. 68d)

The sixth exemplary signal object 68165 transmitted with data priority 6 in dual peak form with chirp-up characteristic (B) is also not taken into account here for the reconstruction because of its first property.

The resulting reconstructed parameter signal is the reconstructed parameter signal 73635. However, all signal components having a first property were not incorporated in the reconstruction. The signal was thus selectively reconstructed by the higher-level computer system 12.

The parameter signal 73635 decompressed and reconstructed in this way is then typically used for object detection in the higher-level computer system 12 or at a different location in the vehicle.

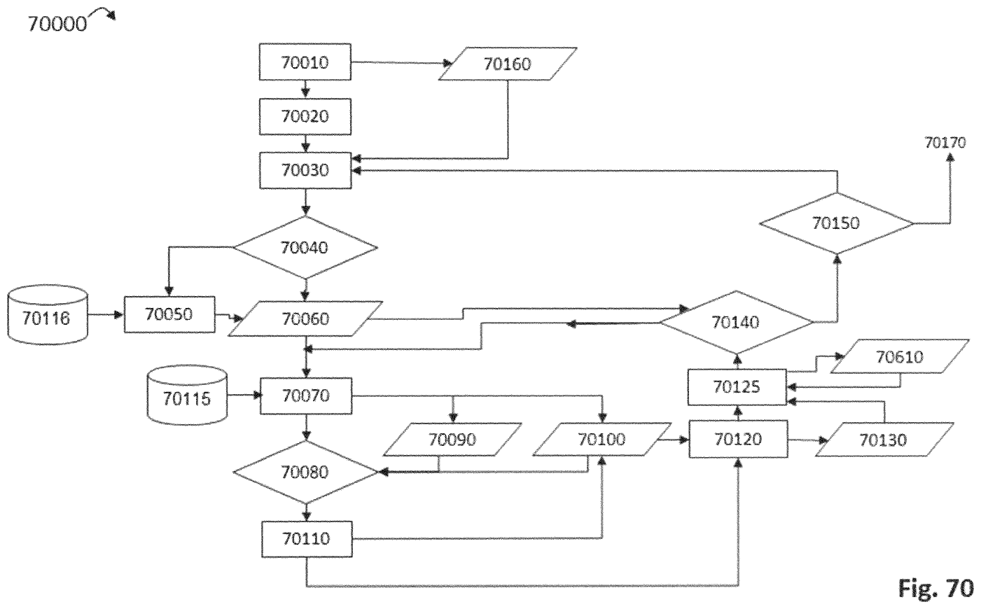

### FIG. 69

FIG. 69 shows the exemplary decompression of a transmitted exemplary sub-signal of the parameter signal 62103, wherein only signal components without the first property are incorporated in the reconstruction.

First, a parameter signal model 69610 is generated that does not have a signal. (FIG. 69a). The parameter signal model 69610 is parameterized using a model parameter (SA) which is optionally correlated with the time (t) since the start of the sampling window.

The first exemplary signal object 68160 transmitted with data priority 1 in triangular form without the first property is not taken into account here for the reconstruction.

This parameter signal model 69610 is then optionally supplemented in a suitably parameterized manner by addition of the second exemplary signal object 62161, which describes a triangular shape with a first property and is transmitted with data transmission priority 2 from the control device 4 of the fuse 1 to the higher-level computer system 12. (FIG. 68b)

This parameter signal model 69610 is then optionally supplemented in a suitably parameterized manner by addition of the third exemplary signal object 68161, which describes a dual peak form with a first property and is transmitted with data transmission priority 3 from the control device 4 of the fuse 1 to the higher-level computer system 12. (FIG. 68c)

The fourth exemplary signal object 68162 transmitted with data priority 4 in triangular form without the first property is not taken into account here for the reconstruction.

The fifth exemplary signal object 68163 transmitted with data priority 5 in triangular form without the first property is not taken into account here for the reconstruction.

This parameter signal model 69610 is then optionally supplemented in a suitably parameterized manner by addition of the sixth exemplary signal object 68165, which describes a triangular shape with a first property and is transmitted with data transmission priority 6 from the control device 4 of the fuse 1 to the higher-level computer system 12. (FIG. 68d)

The resulting reconstructed parameter signal is the reconstructed parameter signal 73635. However, all signal components without a first property were not incorporated in the reconstruction. The signal was thus selectively reconstructed by the higher-level computer system 12.

The parameter signal 73635 decompressed and reconstructed in this way is then typically used for object detection in the higher-level computer system 12 or at a different location in the vehicle.

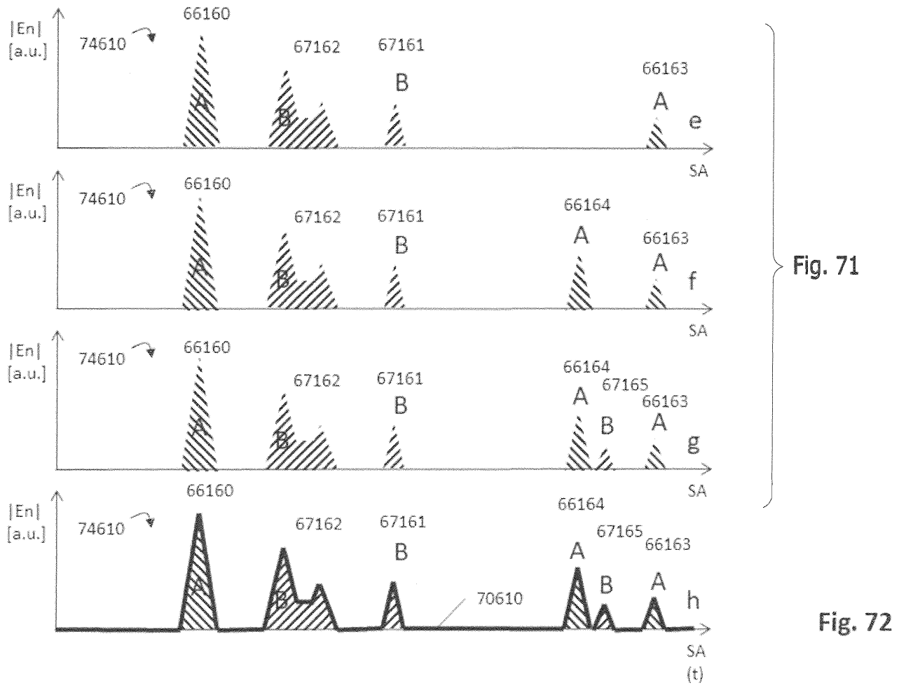

### FIGS. 71a to 71g and 72

FIGS. 71a to 71g and 72 show the decompression of the parameter signal 62103.

First, a parameter signal model vector 74610 is generated that does not have a signal. (FIG. 71a). The parameter signal model vector 74610 is parameterized using a model parameter (SA) which is optionally correlated with the time (t) since the start of the sampling window.

This parameter signal model vector 74610 is then optionally supplemented in a suitably parameterized manner by addition of the first exemplary signal object 68160, which describes a triangular shape and is transmitted with data transmission priority 1 from the control device 4 of the fuse 1 to the higher-level computer system 12. (FIG. 71b)

This parameter signal model vector 74610 is then optionally supplemented in a suitably parameterized manner by addition of the second exemplary signal object 68161, which describes a triangular shape and is transmitted with data transmission priority 2 from the control device 4 of the fuse 1 to the higher-level computer system 12. (FIG. 71c)

This parameter signal model vector 74610 is then optionally supplemented in a suitably parameterized manner by addition of the third exemplary signal object 68162, which describes a dual peak form and is transmitted with data transmission priority 3 from the control device 4 of the fuse 1 to the higher-level computer system 12. (FIG. 71d)

This parameter signal model vector 74610 is then optionally supplemented in a suitably parameterized manner by addition of the fourth exemplary signal object 68163, which describes a triangular shape and is transmitted with data transmission priority 4 from the control device 4 of the fuse 1 to the higher-level computer system 12. (FIG. 71e)

This parameter signal model vector 74610 is then optionally supplemented in a suitably parameterized manner by addition of the fifth exemplary signal object 68164, which describes a triangular shape and is transmitted with data transmission priority 5 from the control device 4 of the fuse 1 to the higher-level computer system 12. (FIG. 71f)

This parameter signal model vector 74610 is then optionally supplemented in a suitably parameterized manner by addition of the sixth exemplary signal object 68165, which describes a triangular shape and is transmitted with data transmission priority 6 from the control device 4 of the fuse 1 to the higher-level computer system 12. (FIG. 71g)

For the sake of clarity, the reconstructed parameter signal 70610 is shown in bold in FIG. 72. Otherwise, FIG. 72 corresponds to FIG. 71g.

The parameter signal 70610 decompressed and reconstructed in this way is then typically used for object detection in the higher-level computer system 12 or at a different location in the vehicle or in a different server 710, 750.

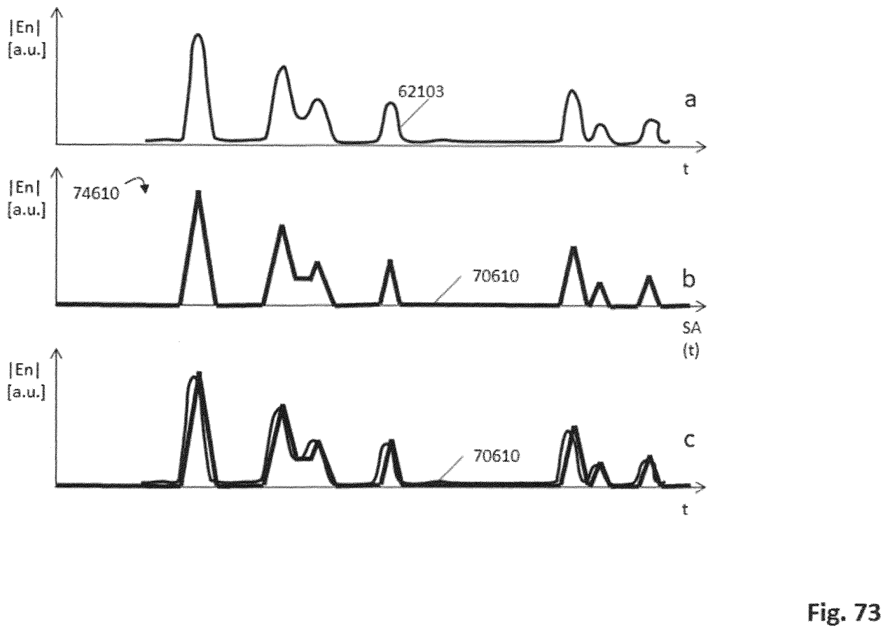

### FIG. 73

FIG. 73 shows an exemplary, arbitrary sub-signal of the parameter signal 62103 as an original signal (FIG. 73a), the reconstructed parameter signal 70610 (FIG. 73b) and the superposition thereof (FIG. 73c). The deviations between the reconstructed parameter signal 70610 and the sub-signal of the parameter signal 62103 with the correct approach and skillful selection of the signal basic objects and signal objects are only very low.

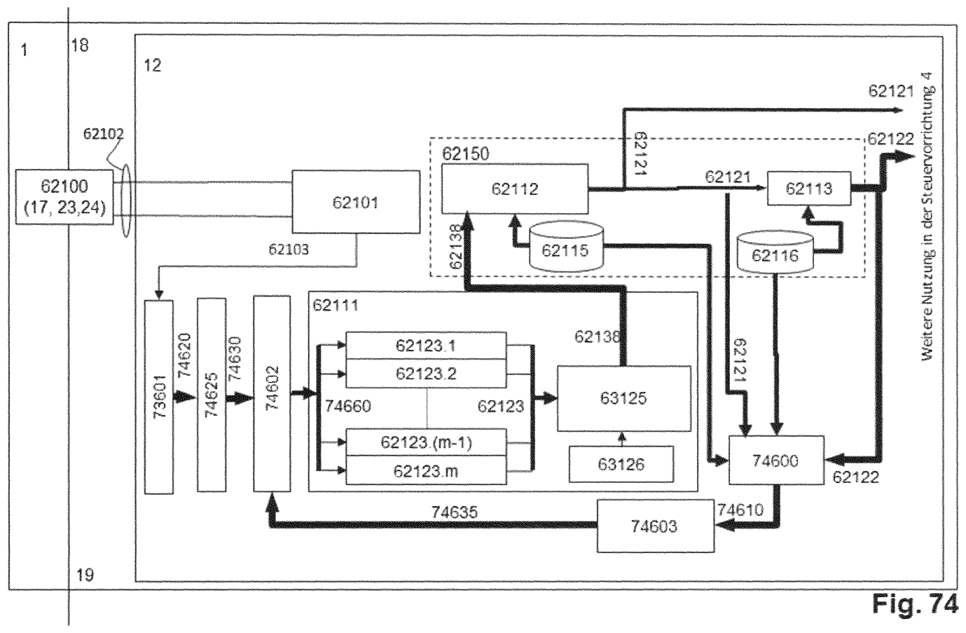

### FIG. 74

FIG. 74 shows an improved device for improved recursive compression. The reconstructor 74600, the function of which is explained in FIGS. 71a to 73 can be used not only in the higher-level computer system 12, but also in the control device 4 of the fuse 1 itself before the data transmission. For this purpose, the reconstructor 74600 generates a reconstructed parameter signal model vector 74610 as shown in FIGS. 71a to 73 depending on the purpose. This is subsequently subtracted from the previously received parameter signal 62103 in a vector subtractor 74602. For this purpose, the parameter signal 62103 is optionally stored in chronological order in the form of digital sampling values in a two-stage memory 74601, 74625. A stored sampling value of the parameter signal 62103 optionally corresponds to exactly one value of the reconstructed parameter signal model vector 74610, which is optionally also stored in a reconstruction memory 74603. The reconstruction memory 74603 can be part of the reconstructor 74600. This additional feedback branch (74600, 74610, 74603, 74602, 74601) can also be used for other classifiers, such as the device of FIG. 67.

The reconstruction of a reconstructed parameter signal model vector 74610 from the detected signal objects 62122 and the signal basic objects 62121 during the compression is particularly advantageous.

For this purpose, the control device of the fuse 1 optionally stores the q sampling values of the parameter signal 62103 of a temporal sampling window, which values the control device 4 has detected in the temporal sampling window, in a first sampling value memory 74601. The number q here is a positive integer which indicates the number of sampling values in the first sampling value memory 74601 of the control device 4 of the fuse 1. As soon as the sampling window is temporally at an end, the sampling value memory 74601 r deletes the oldest sampling values in its memory cells. The number r is a positive integer. Then, the first sampling value memory 74601 optionally shifts all the sampling values by the same number r of memory cells in the first sampling memory 74601 in such a way that the oldest non-deleted sampling value is in the memory cell of the first sampling memory 74601 in which the oldest, previously deleted sampling value was previously stored. As a result, after the end of a sampling window in a new temporal sampling window, the first sampling value memory 74601 is successively refilled with the new sampling values of the new sampling window, while it always discards the oldest sampling values in order to create space for these new sampling values that are moved up in the sequence.

The q sampling values in the first sampling value memory 74601 form a q-dimensional first sampling value vector 74620, which the first sampling value memory 74601 optionally outputs. Because the content of the first sampling value vector 74620 is unstable during the writing of the sampling values of the parameter signal 62103 into the first sampling value memory 73607, a second sampling memory 74625 adopts the sampling value vector 74620 from the first sampling value memory 74601 at the temporal end of each sampling time window.

The control device 4 of the fuse 1 generates the parameter signal model vector 74610 from the cumulative linearly superposed signal characteristic models of the individual detected signal objects and/or signal basic objects.

The control device 4 subtracts the values of the vector components of the stored parameter signal model vector 74635 from the second sampling value vector 74630 by means of a vector subtractor 74602 and thereby forms a vector residual signal 73660. This better suppresses signal objects similar to the selected signal object detected with a higher probability. As a result, the weaker signal objects and signal basic objects also emerge better in the vector residual signal 73660. The control device 4 can then better recognize the weaker signal objects and signal basic objects in the residual signal 73660. (See also FIG. 73). The method proposed in the technical teaching of the disclosure thus optionally also comprises a subtraction of the stored parameter signal model 74635 made up of the already detected signal objects and signal basic objects from the second sampling value vector 74630 in the second sampling value memory 74625 for forming the vector residual signal 73660. The control device 4 then in turn uses the vector residual signal 73660 thus formed for the formation of the signal of the feature vectors 62138 by means of the feature extraction 62111. By means of the feature extraction 62111 and by means of the distance calculation 62112 or the classifier 62112 and, where applicable, the Viterbi estimator 62113, the control device then determines that signal object of the signal object sequence database 62116 or that signal basic object of the prototype database 62115 which has the next lowest probability. Because the first detected signal object or signal basic object has been removed from the second sampling value vector of the second sampling value memory 74625 according to its weighting and is thereby essentially no longer present in the vector residual signal 73660, the first detected signal object or signal basic object can no longer influence this detection. This form of detection thus provides a better result in the form of a list of detected signal objects or signal basic objects.

A reconstructor 74600 reconstructs the parameter signal with the aid of the detected signal basic objects 62121 and the detected signal objects 62122 and by means of the determined signal basic object parameters and the co-determined signal object parameters and the data from the prototype database 62155 and the data from the signal object sequence database 62116 and by means of the associated time stamps, as if it would only be composed of the detected signal objects 62122 with the co-determined signal object parameters and the determined signal basic object parameters with the co-determined signal basic object parameters taking into account the associated time stamps by adding the corresponding vector values. In this way, a reconstructor 74600 reconstructs the reconstructed parameter signal model vector with q values of vector components corresponding to the q values of the vector components of the second sampling value vector in the second sampling value memory 74625 as a reconstructed parameter signal model vector 74610. The reconstruction memory 74603 temporarily stores the reconstructed parameter signal model vector 74610. The reconstructor 74600 optionally comprises the reconstruction memory 74603. The reconstruction memory 74603 outputs the reconstructed parameter signal model vector 74610 stored in its memory cells as a stored parameter signal model vector 74635 to the vector subtractor 74602; this closes the circle.

However, this detection method is generally slower. It is therefore expedient to first carry out a direct first signal object detection without subtraction during the still ongoing measurement, and then after detection of all sampling values of a sampling window to carry out a repeated pattern recognition with subtraction of the parameter signal model vector 74610, which does takes longer, but is more precise.

Optionally, this reducing classification of the parameter signal 62103 and the breakdown into prototypical signal objects or signal basic objects are then terminated with the aid of the parameter signal model vector 74610 if the amounts of the sampling values of the vector residual signal 73660 are below the amounts of a predetermined threshold value curve and/or of a threshold value.

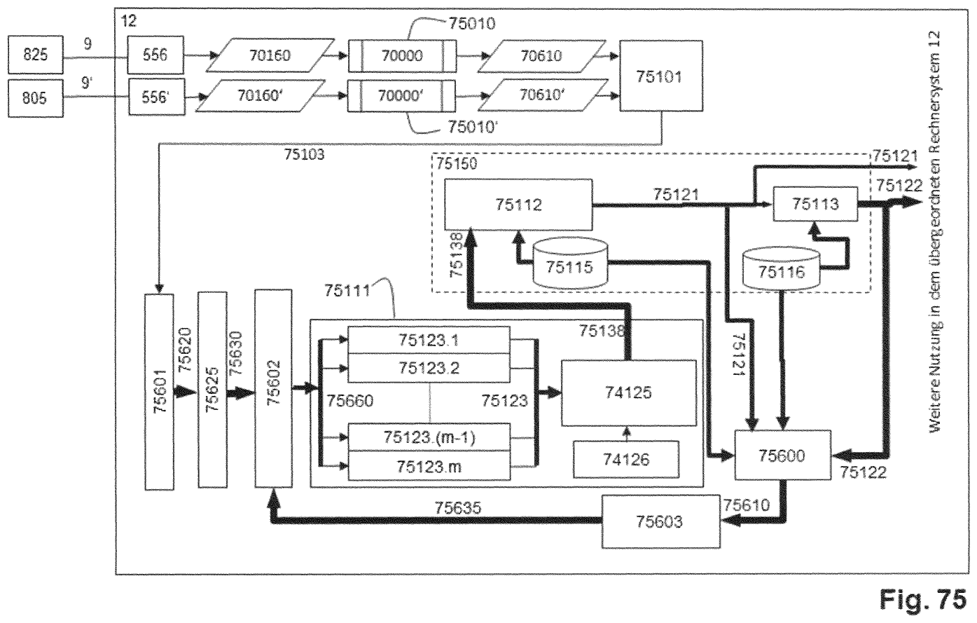

### FIG. 75

FIG. 75 shows a device for evaluating the decompressed fuse data of a plurality of fuses, e.g., two of two fuses (805, 825). By way of example, the two electronic fuses (805, 825) are to generate the compressed fuse data according to FIG. 74. The first exemplary fuse (825) transmits its first compressed fuse data (70160) via a first exemplary data bus (9) to the first data interface (556) of the higher-level computer system (12). The second exemplary fuse (825′) transmits its second compressed fuse data (70160′) via a second exemplary data bus (9′) to the exemplary second data interface (556′) of the higher-level computer system (12). Instead of two data buses (9, 9′), the supply network (200) can also have only one data bus (9′). In this case, the second exemplary fuse (825′) transmits its second compressed fuse data (70160′) via the first exemplary data bus (9′) to the exemplary first data interface (556) of the higher-level computer system (12), and the higher-level computer system (12) then separates the two data streams in time-division multiplexing instead of space-division multiplexing.

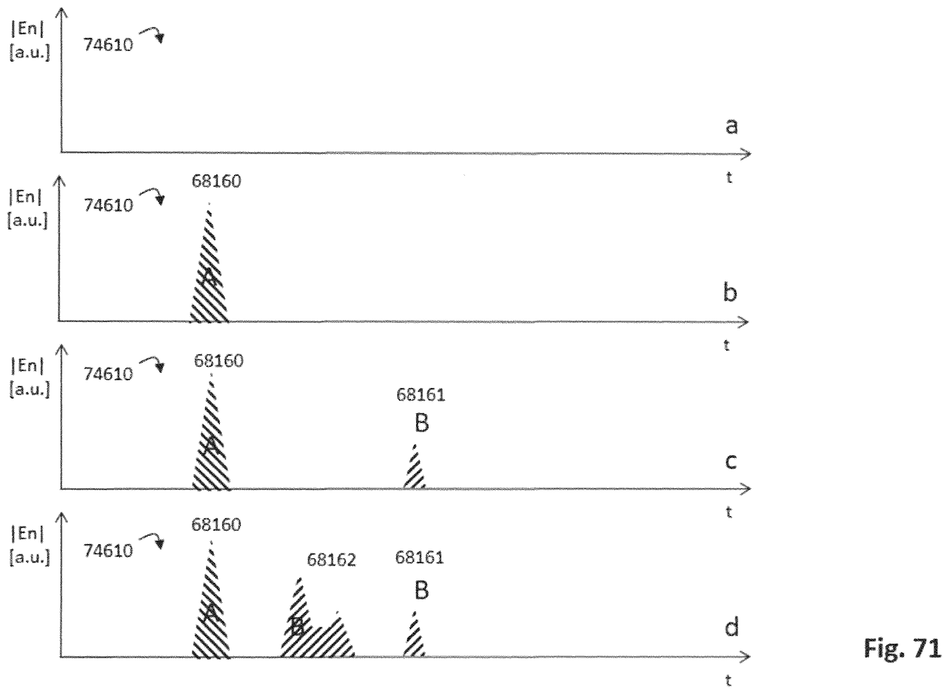

A first decompression device 75010 decompresses the first, compressed fuse data 70160 received from the first fuse 825 and which are to be decompressed, for example by means of the decompression method of FIG. 70, to form a first reconstructed parameter signal 70610 of the first fuse 825.

A second decompression device 75010′ decompresses the second, compressed fuse data 70160′ received from the second fuse 805 and which are to be decompressed, for example by means of the decompression method of FIG. 70, to form a second reconstructed parameter signal 70610′ of the second fuse 805′.

If the higher-level computer system 12 receives further compressed fuse data which are to be decompressed, a corresponding further decompression device optionally decompresses the further compressed fuse data received from the further fuse and which are to be decompressed, for example by means of the decompression method of FIG. 70, to form a corresponding further reconstructed parameter signal of the corresponding further fuse. For better clarity, FIG. 75 shows only two fuses 825 and 805.

A combination device 75101 optionally merges the first reconstructed parameter signal 70610 of the first fuse 825 and the second reconstructed parameter signal 70610′ of the second fuse 825 and optionally further reconstructed parameter signals of the further fuses to form a merged parameter signal 75103. In this case, the combination device 75101 interpolates the value characteristics of the reconstructed parameter signals of different sampling instants of the reconstructed parameter signals and thereby generates a merged parameter signal 75103 in which all sampling values of the different sub-signals of the reconstructed parameter signals 75103 are related to synchronous sampling instants.

FIG. 75 shows an exemplary device in the form of an exemplary higher-level computer system 12. The representation is simplified and schematic. The device parts of the higher-level computer system 12 can in part be emulated by means of software by a computer core of the higher-level computer system 12. The higher-level computer system 12 optionally performs a detection of merged signal objects and merged signal basic objects in the merged parameter signal 75103. The object is thus similar to that in FIG. 62 for an electronic fuse 1. The difference is that the merged parameter signal 75103 is ultimately based on a plurality of parameter signals 62103 of a plurality of fuses. Therefore, the signal objects are also different. For differentiation, the corresponding functional components in this document are marked with the adjective “merged” for the classification of the events in the supply network, so that similar designations as in FIG. 62 can be used.

Here too, the merged parameter signal 75103 can typically be a bundle of a plurality of signals. The merged parameter signal 75103 is the input signal of the subsequent signal object classification into merged signal object and/or merged signal basic objects. Optionally, the merged parameter signal 75103 is a digitized signal with temporally spaced sampling values. The higher-level computer system 12 can, for example, emulate device parts of the higher-level computer system 12, if possible, by software program. The merged feature vector extraction 75111 of the higher-level computer system 12 has various devices, in this case for example n matched filters (matched filter 75123.1 to matched filter 75123.m) of the higher-level computer system 12 with m as a positive integer. The outputs of the matched filters 75123.1 to 75123.m of the higher-level computer system 12, provided here as examples, form the merged intermediate parameter signal 75123. Instead of the matched filters 75123.1 to 75123.m of the higher-level computer system 12 or in addition thereto,
integrators and/or
differentiators and/or
filters and/or
logarithmizers and/or
FF and DFFT devices and/or
correlators and/or
demodulators which multiply their input signal with a predefined signal and then filter it, and/or
other signal-processing sub-devices and/or
combinations thereof can also be used, depending on the application, which then generates the m-dimensional merged intermediate parameter signal 75123 of the higher-level computer system 12. The blocks in the drawings referred to as “matched filters” are to be understood only as placeholders for such signal processing blocks of the higher-level computer system 12. Such a signal processing block of the higher-level computer system 12, referred to as a “matched filter,” can also have more than one output which thus contributes to the m-dimensional merged intermediate parameter signal 75123 of the higher-level computer system 12 multiple times with more than one signal. A downstream, exemplary merged significance increase unit 75125 of the higher-level computer system 12 serves to map the m-dimensional space of the merged intermediate parameter signal 75123 of the higher-level computer system 12 to an n-dimensional space of the signal of the merged feature vectors 75138 of the higher-level computer system 12. N here is a positive integer. In general, n is smaller than m. This is used, on the one hand, to maximize the selectivity of the parameter values from which each merged feature vector of the merged signal of the merged feature vectors 75138 of the higher-level computer system 12 results. This is optionally done by a linear mapping with the aid of an offset value determined in the laboratory with statistical methods, which is added to the values of the merged intermediate parameter signals, and a so-called merged LDA matrix 75126, with which the corresponding vector of the corresponding sampling values of the merged intermediate parameter signals 75123 of the higher-level computer system 12 is multiplied by the higher-level computer system 12 in each case to form a merged feature vector of the merged signal of the merged feature vectors 75138. The merged distance determination device/classifier 75112 optionally compares each of the thus resulting merged feature vectors of the merged signal of the merged feature vectors 75138 of the higher-level computer system 12 to each merged signal basic object prototype of the merged prototype database 75115 of the higher-level computer system 12. For this purpose, the merged prototype database 75115 of the higher-level computer system 12 contains an entry with a centroid vector (e.g., similar to 63141, 63142, 63143, 63144) of the corresponding merged signal basic object prototype of the merged prototype database 75115 of the higher-level computer system 12 for optionally each of the merged signal basic object prototypes of the merged prototype database 75115. Optionally, a distance of the currently examined merged feature vector of the merged signal of the merged feature vectors 75138 of the higher-level computer system 12 from the just examined centroid vector of the merged prototype database 75115 of the higher-level computer system 12 is calculated by the merged distance determination device 75112 of the higher-level computer system 12. However, the merged distance determination device 75112 of the higher-level computer system 12 can also calculate in another way an evaluation of the similarity between the centroid vector (e.g., similar to 63141, 63142, 63143, 63144) of the corresponding merged signal basic object prototypes of the merged prototype database 75115 of the higher-level computer system 12 and the currently examined merged feature vector of the merged signal of the merged feature vectors 75138 of the higher-level computer system 12 in the form of an evaluation value, which we always refer to here as merged distance for the sake of simplicity. In this way, the merged distance determination device 75112 determines whether a centroid vector (e.g., similar to 63141, 63142, 63143, 63144) of the merged signal basic object prototypes of the merged prototype database 75115 is sufficiently similar to the current merged feature vector of the merged signal of the merged feature vectors 75138 of the higher-level computer system 12, i.e., has a sufficiently low merged distance, and, if this is the case, which centroid vector (e.g., similar to 63141, 63142, 63143, 63144) of the merged signal basic object prototypes of the merged prototype database 75115 of the higher-level computer system 12 is most similar to the current merged feature vector of the merged signal of the merged feature vectors 75138, i.e., has the smallest merged distance. If necessary, the merged distance determination device 75112 of the higher-level computer system 12 determines a list of centroid vectors (e.g., similar to 63141, 63142, 63143, 63144) of the merged signal basic object prototypes of the merged prototype database 75115 of the higher-level computer system 12, which are sufficiently similar to the current merged feature vector of the merged signal of the merged feature vectors 75138 of the higher-level computer system 12, i.e., have a sufficiently small merged distance. Optionally, these are ordered according to merged distance and passed on with their associated merged distance as a merged hypothesis list to the merged Viterbi estimator 75113. An exemplary hypothesis list was indicated above. The merged hypothesis list is optionally structured similarly to the hypothesis list. In the case of a single detected merged signal basic object 75121, the detection result of the merged distance determination device (which is also referred to here as a merged classifier) 75112 is forwarded as a merged symbol (for example, as a prototype database address/index of the merged prototype database 75115, which highlights the detected merged signal basic object prototypes of the merged prototype database 75115) and in the case of a merged hypothesis list optionally as a list of pairs of a symbol (index) of the detected merged signal basic object (for example, the prototype database address/index, which highlights the detected merged signal basic object prototypes of the merged prototype database 75115.) and of the merged distance to the centroid of this detected merged signal basic object. The merged Viterbi estimator 75113 of the higher-level computer system 12 then searches for the sequence of merged signal basic object prototypes which best corresponds to a predefined sequence of merged signal basic object prototypes in its merged signal object sequence database 75116. In this case, matches are, for example, counted positively and non-matches are counted negatively, so that an evaluation value for each entry of the merged signal object sequence database 75116 of the higher-level computer system 12 results for a temporal sequence of detected merged signal basic object prototypes. In the case of merged hypothesis lists, the merged Viterbi estimator 75113 optionally checks all possible paths through the time sequence of merged hypothesis lists. The merged Viterbi estimator 75113 optionally determines its evaluation result taking into account the previously determined merged distances. This can be done, for example, by dividing the added values by the merged distance before the addition during the calculation of the merged evaluation value. In this way, the merged Viterbi estimator 75113 determines the detected merged signal objects 75122 which the higher-level computer system 12 can use for deriving measures and/or for transmission to a server 710. The higher-level computer system 12 can also transmit the detected merged signal basic objects 75121 directly to such a server 710. The important thing is: This procedure, for example, involves the detection of events and states physically occurring, for example, in current signals and/or voltage signals within the supply network 200 and the transmission of this information and the detection of structures within the merged parameter signal 75103 and the transmission thereof to a server 710 and/or the derivation of measures of the higher-level computer system 12. As a main purpose, the higher-level computer system 12 can deduce the state of one or more fuses and/or of the protected supply network and/or of the vehicle, etc. from the merged signal basic objects that occur and from the sequence of these merged signal basic objects and the parameterization thereof. Where applicable, the higher-level computer system 12 also takes into account the data of other sensors and/or fuses in the supply network 200 and/or in the vehicle, and in some cases further data from servers 710, which are connected in the broadest sense at least temporarily to the higher-level computer system 12 in a data connection, for example via the data bus 9.

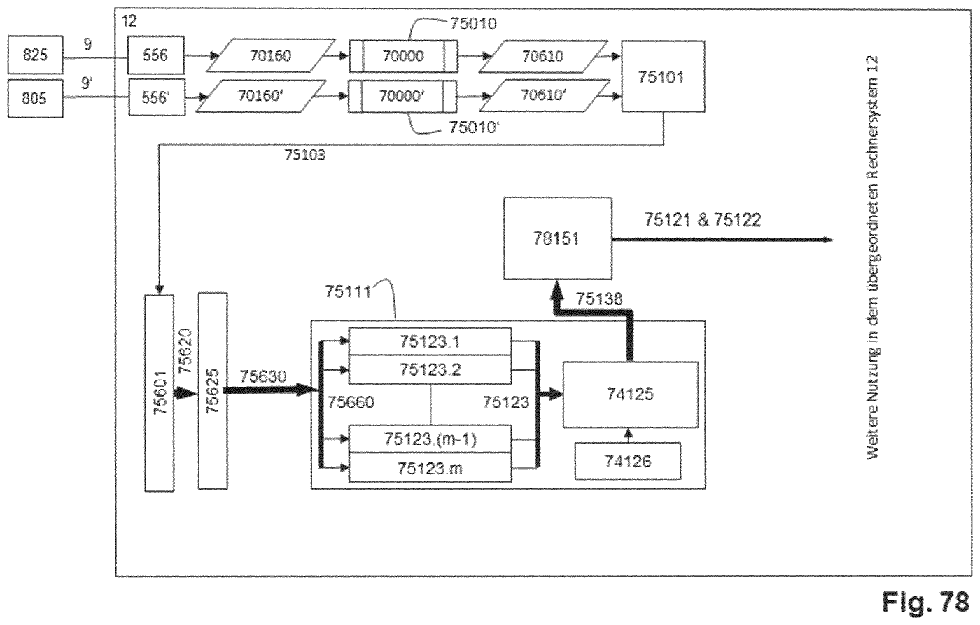

The reconstructor 74600, the function of which is explained in FIGS. 71a to 73, is now used in the higher-level computer system 12 as a reconstructor 75600 after the data transmission. For this purpose, the reconstructor 75600 of the higher-level computer system 12 generates a reconstructed merged parameter signal model vector 75610 of the higher-level computer system 12 as shown in FIGS. 71a to 73 as a reconstructed parameter signal model vector 74610 depending on the purpose. This is subsequently subtracted from the previously received merged parameter signal 75103 in a vector subtractor 75602 of the higher-level computer system 12. For this purpose, the merged parameter signal 75103 of the higher-level computer system 12 is optionally stored in the form of digital sampling values in a two-stage memory 75601, 75625 of the higher-level computer system 12, optionally in chronological order. A stored sampling value of the merged parameter signal 75103 of the higher-level computer system 12 optionally corresponds to exactly one value of the reconstructed merged parameter signal model vector 75610 of the higher-level computer system 12, which is optionally also stored in a reconstruction memory 75603 of the higher-level computer system 12. The reconstruction memory 74603 of the higher-level computer system 12 can be part of the reconstructor 74600 of the higher-level computer system 12. This additional feedback branch (74600, 74610, 74603, 74602, 74601) of the higher-level computer system 12 can also be used for other classifiers, such as the device of FIG. 78. For example, the higher-level computer system 12 can execute a neural network model 78151 that classifies the merged parameter signal 75103 into merged signal basic objects 75121 and/or merged signal objects 75122.

The reconstruction of a reconstructed merged parameter signal model vector 75610 of the higher-level computer system 12 from the detected signal objects 75122 and the signal basic objects 75121 during the compression/classification of the merged parameter signal 75103 of the higher-level computer system 12 is particularly advantageous.

For this purpose, the higher-level computer system 12 optionally stores the q sampling values of the merged parameter signal 75103 of a time sampling window, which the combination device 75101 has generated in the temporal sampling window from the reconstructed parameter signals 70610, 70610′ by data merging, in a first sampling value memory 75601 of the higher-level computer system 12. The number q here is a positive integer which indicates the number of sampling values in the first sampling value memory 75601 of the higher-level computer system 12. As soon as the sampling window is temporally at an end, the sampling value memory 77601 r deletes oldest sampling values in its memory cells. The number r is a positive integer. Then, the first sampling value memory 75601 of the higher-level computer system 12 optionally shifts all sampling values by the same number r of memory cells in the first sampling memory 75601 of the higher-level computer system 12 in such a way that the oldest non-deleted sampling value is in the memory cell of the first sampling memory 75601 of the higher-level computer system 12 in which the oldest, previously deleted sampling value was previously stored. As a result, after the end of a sampling window in a new temporal sampling window, the first sampling value memory 75601 of the higher-level computer system 12 is successively filled again with the new sampling values of the new sampling window, while it always discards the oldest sampling values in order to create space for these new sampling values that are moved up in the sequence.

The q sampling values in the first sampling value memory 75601 of the higher-level computer system 12 form a q-dimensional first sampling value vector 75620 of the higher-level computer system 12, which the first sampling value memory 74601 of the higher-level computer system 12 optionally outputs. Because the content of the first sampling value vector 75620 is unstable during the writing of the sampling values of the merged parameter signal 75103 into the first sampling value memory 75607 of the higher-level computer system 12, a second sampling memory 75625 of the higher-level computer system 12 adopts the sampling value vector 75620 from the first sampling value memory 75601 of the higher-level computer system 12 at the temporal end of each sampling time window.

The higher-level computer system 12 generates the merged parameter signal model vector 75610 of the higher-level computer system 12 from the cumulative linearly superposed signal characteristic models of the individual detected signal objects and/or signal basic objects.

The higher-level computer system 12 subtracts the values of the vector components of the stored merged parameter signal model vector 75635 from the second sampling value vector 75630 of the higher-level computer system 12 by means of a vector subtractor 75602 of the higher-level computer system 12 and thereby forms a vector residual signal 75660 of the higher-level computer system 12. This better suppresses signal objects similar to the selected signal object detected with a higher probability. As a result, the weaker signal objects and signal basic objects also emerge better in the vector residual signal 75660. The higher-level computer system 12 can then better recognize the weaker signal objects and signal basic objects in the vector residual signal 75660 of the higher-level computer system 12. (See also FIG. 73). The method proposed in the technical teaching of the disclosure thus optionally also comprises a subtraction of the stored merged parameter signal model 75635 of the higher-level computer system 12 made up of the already detected signal objects and signal basic objects from the second sampling value vector 75630 of the higher-level computer system 12 in the second sampling value memory 75625 of the higher-level computer system 12 for forming the vector residual signal 75660 of the higher-level computer system 12. The higher-level computer system 12 then uses the vector residual signal 75660 of the higher-level computer system 12 thus formed in turn for the formation of the merged signal of the feature vectors 75138 of the higher-level computer system 12 by means of the feature extraction 75111 of the higher-level computer system 12. By means of the feature extraction 75111 of the higher-level computer system 12 and by means of the distance calculation 75112 of the higher-level computer system 12 or of the classifier 75112 of the higher-level computer system 12 and, where appropriate, of the Viterbi estimator 75113 of the higher-level computer system 12, the higher-level computer system 12 then determines that signal object of the signal object sequence database 75116 of the higher-level computer system 12 of sequences of merged signal basic object prototypes or that signal basic object of the prototype database 75115 of merged signal basic object prototypes of the higher-level computer system 12 having the next lower probability. Because the first detected merged signal object or merged signal basic object has been removed from the second sampling value vector of the second sampling value memory 75625 of the higher-level computer system 12 according to its weighting and is thereby essentially no longer present in the merged vector residual signal 75660 of the higher-level computer system 12, the first detected merged signal object or merged signal basic object can no longer affect this detection. This form of detection thus provides a better result in the form of a list of detected merged signal objects or merged signal basic objects.

With the aid of the detected merged signal basic objects 75121 and the detected merged signal objects 75122 and by means of the co-determined signal basic object parameters and the co-determined signal object parameters and the data from the prototype database 75155 of the merged signal objects and the data from the signal object sequence database 75116 of the sequences of merged signal objects and by means of the associated time stamps, a reconstructor 75600 of the higher-level computer system 12 reconstructs the merged parameter signal 75103 as if it were composed only of the detected merged signal objects 75122 with the co-determined signal object parameters and the determined signal basic object parameters with the co-determined signal basic object parameters, taking into account the associated time stamps by addition of the corresponding vector values. In this way, a reconstructor 75600 reconstructs the reconstructed merged parameter signal model vector 75610 with q values of vector components corresponding to the q values of the vector components of the second sampling value vector of the higher-level computer system 12 in the second sampling value memory 75625 of the higher-level computer system 12 as a reconstructed merged parameter signal model vector 75610. The reconstruction memory 75603 of the higher-level computer system 12 intermediately stores the reconstructed merged parameter signal model vector 75610 of the higher-level computer system 12. The reconstructor 75600 of the higher-level computer system 12 optionally comprises the reconstruction memory 75603 of the higher-level computer system 12. The reconstruction memory 75603 of the higher-level computer system 12 outputs the reconstructed merged parameter signal model vector 75610 stored in its memory cells as a stored merged parameter signal model vector 75635 to the vector subtractor 75602 of the higher-level computer system 12; this closes the circle.

Optionally, this reducing classification of the merged parameter signal 75103 and the breakdown into prototypical merged signal objects or merged signal basic objects are then terminated with the aid of the merged parameter signal model vector 75610 of the higher-level computer system 12 if the amounts of the sampling values of the merged vector residual signal 75660 of the higher-level computer system 12 are below the amounts of a predetermined threshold value curve and/or of a threshold value.

The higher-level computer system 12 optionally adopts measures depending on the detected merged signal objects 75122 and/or the detected merged signal basic objects 75121. Such measures can relate, for example, to the opening and/or closing of circuit breakers 17 of fuses in the supply network 200 by means of commands from the higher-level computer system 12 to one or more fuses in the supply network 200. Such measures can relate, for example, to reconfiguration of the supply network by means of electronic fuses in the supply network 200 by means of commands from the higher-level computer system 12 to one or more fuses of these fuses in the supply network 200. Such measures can relate, for example, to shedding supply sub-networks and/or the connection of supply sub-networks of the supply network by means of electronic fuses in the supply network 200 by means of commands from the higher-level computer system 12 to one or more fuses of these fuses in the supply network 200. Such measures can relate, for example, to signaling to another computer system and/or servers 710, 750 and/or terminals 740. Such measures can relate, for example, to signaling via a human-machine interface of a terminal 740 or the like.

For example, the higher-level computer system 12 can thereby detect temporally correlated error states in the supply network 200 which cannot be detected in the individual fuse.

The higher-level computer system can transmit such detected signal objects of individual or multiple fuses and/or such detected signal basic objects of individual or multiple fuses and/or such detected merged signal objects of individual or multiple fuses and/or such detected merged signal basic objects of individual or multiple and/or further sensor data to a server 710, for example of an automobile manufacturer or of a service provider. The higher-level computer system 12 optionally compresses these data prior to the transmission. For this purpose, the higher-level computer system optionally uses methods, sub-devices and concepts as the disclosure describes for the communication between an electronic fuse of a supply network and the higher-level computer system 12 here with respect to compression and encryption. In this case, the higher-level computer system 12 then assumes the function of the control device 4 of the electronic fuse and the server 710 assumes the function of the higher-level computer system 12. The higher-level computer system 12 therefore optionally has a quantum random number generator which corresponds in its design and in the method carried out in this quantum random number generator to the quantum random number generator described in this document for the control device 4 of a fuse 1.

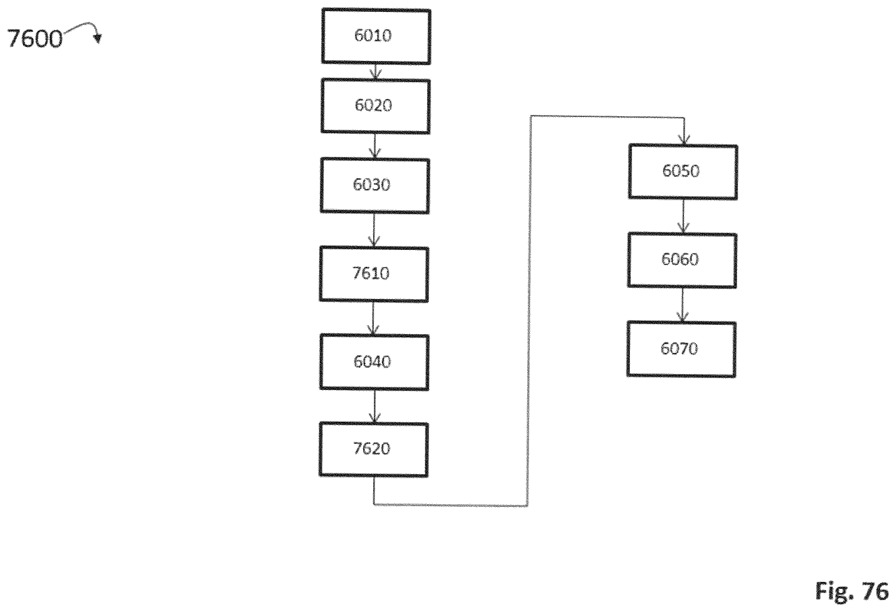

### FIG. 76

FIG. 76 shows a method 7600 for operating a supply network 200 with compression and encryption of the fuse data in the electronic fuse 1 and decryption and decompression of the fuse data in the higher-level computer system 12. The method corresponds to the method of FIG. 60. In addition to the method of FIG. 60, the method comprises the encryption 7610 of the one or more compressed, detected temporal parameter value characteristics of the one or more physical parameters to be signaled, in particular by the control device 4 of the electronic fuse 1, to form one or more, encrypted, compressed, detected temporal parameter value characteristics of the one or more physical parameters to be signaled. In addition to the method of FIG. 60, the method further comprises the decryption 7620 of the one or more encrypted, compressed, detected temporal parameter value characteristics of the one or more physical parameters to be signaled, in particular by the control device 4 of the electronic fuse 1, to form one or more, decrypted, compressed, detected temporal parameter value characteristics of the one or more physical parameters to be signaled;

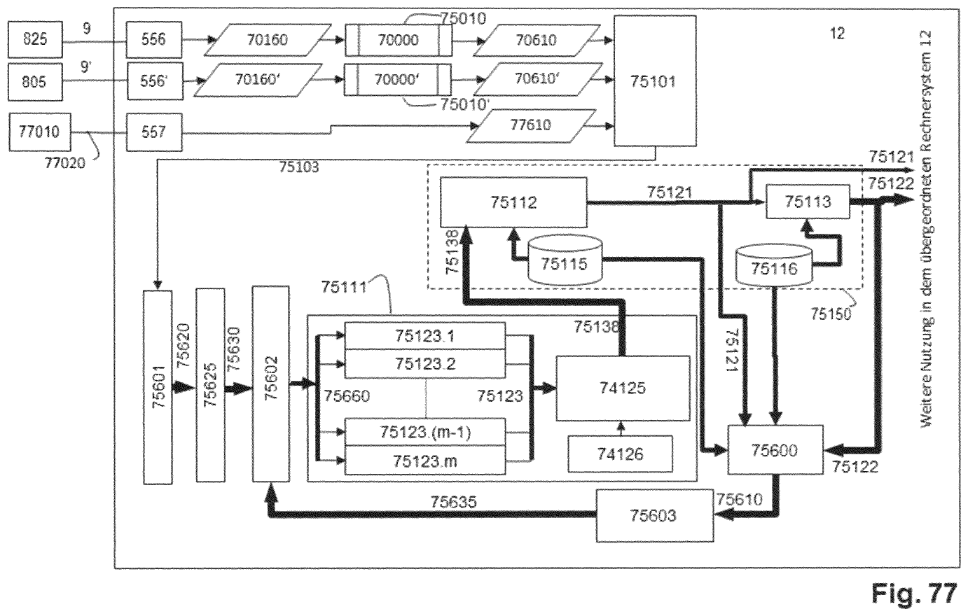

### FIG. 77

FIG. 77 corresponds to FIG. 75 with the difference that the combiner 75101 now merges the reconstructed parameter signals 70610 and 70610′ not only with one another, but also with a parameter signal 77610 of a further sensor 77010 to form the merged parameter signal 75103.

The further sensor 77010 transmits sensor data in the form of a parameter signal 77610 of a further sensor 77010 via a sensor data interface 557 to the higher-level computer system 12 via the sensor data bus 77020. The sensor data bus 77020 for the exemplary sensor 77010 in the vehicle and/or in the supply network 200 can be identical to the data bus 9.

Here, too, the merged parameter signal 75103 can comprise a plurality of signals. As a result, the higher-level computer system 12 can detect and classify temporal correlations between the value characteristics of other physical parameters of the vehicle and/or other value characteristics of other parameters of the vehicle and the reconstructed parameter signals of the fuses. Depending on the detected correlations, the higher-level computer system 12 can detect corresponding measures, such as the opening and/or closing of circuit breakers of fuses in the supply network and/or the reconfiguration of the topology of the supply network 200 and/or the disconnection and/or connection of supply sub-networks by means of electronic fuses of the supply network 200 by command via the data bus 9 to fuses of the supply network 200. Such classified correlations are optionally merged signal objects and/or merged signal basic objects.

The combiner 75101 now merges the reconstructed parameter signals 70610 and 70610′ not only with one another, but also with a parameter signal 77610 of a further sensor 77010 to form the merged parameter signal 75103. This merger of the reconstructed parameter signals 70610 and 70610′ and the parameter signal 77610 of a further sensor 77010 to form the merged parameter signal 75103 represents the merger of the fuse data thus obtained (reconstructed parameter value characteristics) with the parameter value characteristics of further sensors and sensor systems, which transmit data directly or indirectly via data buses, data transmission paths, and/or the data bus 9 to the higher-level computer system 12. For example, a sensor merger can appear such that the higher-level computer system 12 correlates the time characteristics of values characteristics of parameters that detect further sensors and sensor systems (e.g., 77010) with reconstructed parameter value characteristics (e.g., 70610, 70601′) of control devices 4 of fuses (e.g., 825, 805). For this purpose, the higher-level computer system 12 interpolates missing sampling values on the basis of valid sampling values of the reconstructed parameter value characteristics (70610, 70610′, 77610) to form interpolated, reconstructed parameter value characteristics. Furthermore, on the basis of valid sampling values of the value characteristics of those parameters that the further sensors and sensor systems detect, the higher-level computer system 12 interpolates interpolated value characteristics of those parameters that the further sensors and sensor systems detect. At least one sampling value of the interpolated value characteristics of those parameters that the further sensors and sensor systems detect optionally corresponds in time to each sampling value of the interpolated, reconstructed parameter value characteristics. As a result, the higher-level computer system 12 can search correlations in the form of conspicuous, typically more or less synchronous events both in the reconstructed parameter value characteristics and in the value characteristics of those parameters that the further sensors and sensor systems detect. For example, mechanical defects of mechanical devices—e.g., electric motors—can become noticeable in acceleration values—e.g., vibrations, torque vibrations, etc.—and at the same time in corresponding fluctuations of currents 29, 36 through the electronic fuses associated with these mechanical devices. (See also FIG. 59). In this context, the disclosure points to the document by Wolfgang Koch, “Tracking and Sensor Data Fusion: Methodological Framework and Selected Applications (Mathematical Engineering),” Springer 1st ed. 2014 Edition (Au-gust 23, 2016) ISBN-10: 3662520168, ISBN-13: 978-3662520161 as an arbitrary example from the vast amount of publications on sensor fusion.

### FIG. 78

FIG. 78 shows a device corresponding to FIG. 75, wherein the higher-level computer system 12 now executes an exemplary neural network model 778151. The input signals of the neural network model 78151 optionally comprise the current merged feature vector 75138. The neural network model optionally provides a sequence of merged signal basic objects 75121 and merged signal objects 75122 as output signals of the neural network model 78151.

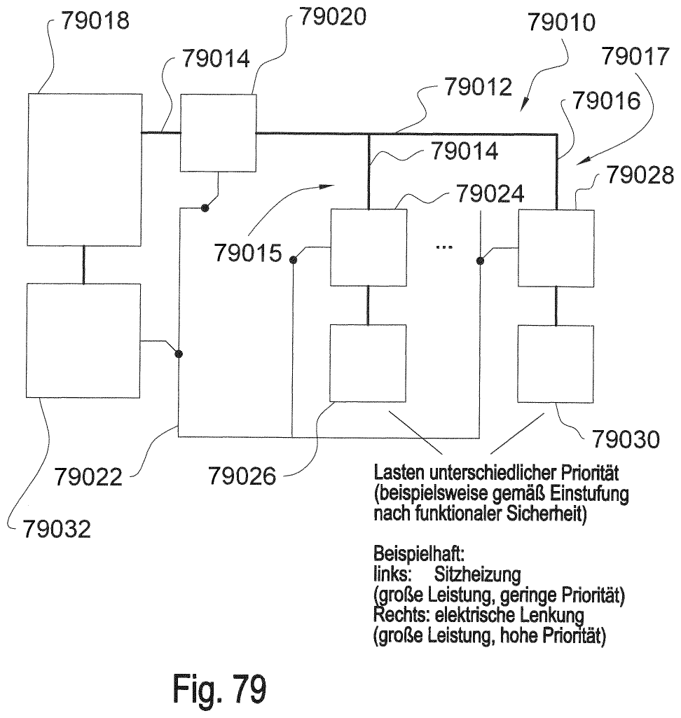

### FIG. 79

According to the concept according to the disclosure in accordance with this example, the disclosure relates to a supply system for a vehicle having a demand-dependent, reconfigurable supply network. Criteria for a reconfiguration of the supply network can be thermal loads in individual supply sub-networks or the supply lines and supply line sections thereof, but also the non-compliance with electrical requirements. For this purpose, electronic fuses are used which monitor the electrical parameters at a plurality of different locations of the supply network and report them to a control center. The decisive criteria for possible reconfiguration of the supply network are especially the coordination of the current power requirements of the electric loads in relation to the power supply capacity of the power sources. In the event of a possible reconfiguration of the supply network, individual loads can be “shed.” Priorities with regard to the relevance of the functionality of the loads for driving operation in general or for the current driving situation of the vehicle are taken into account by the higher-level control or computer system.

According to the example according to FIG. 79, the supply network 79010 has different supply lines (one of these supply lines 79012 is shown in FIG. 79) from which a plurality of supply line sections branches off. FIG. 79 shows two such supply line sections 79014 and 79016 which can also be interpreted as supply sub-networks 79015 and 79017. The supply line 79012 coming from the power source or from one of the power sources 79018 in this example can be optimally provided with a distributor sub-control unit 79020, from which a data communication bus 79022 extends.

In the supply line section 79014, there is an electronic fuse 79024 (or a distributor sub-control unit for electronic fuse) for protecting a load 79026 (or a plurality of loads), which is, for example, a seat heater. In the supply line section 79016, there is likewise an electronic fuse 79028 (or a distributor sub-control unit for electronic fuse) for protecting a further load 79030 (or a plurality of further loads), which is, for example, the electric steering of the vehicle.

In addition to their electronic circuit breakers, all electronic fuses also have measuring means in order to determine the current operating parameters of a supply line or of a supply line section. Furthermore, all electronic fuses are connected via the data communication bus 79022 to an onboard electrical system management as a higher-level control or computer system 79032 in this example.

In the example described here, the two loads are those which require considerable electrical outputs but have clearly different priorities. Thus, the supply of the electric steering of the vehicle, which is to say of the load 79030, is substantially more important and thus is to be established in its priority as substantially higher than the supply of the electrical seat heater (load 79026) with electrical power. Therefore, if it is detected that, due to a high power requirement of the electric steering, the thermal loading in the supply line 79012 is too high within its section leading to the power source 79018 (the two electrical fuses 79024 and 79028 in this respect signal the currently flowing currents and voltages in particular), the higher-level control or computer system 79032 can be used to switch off the electronic fuse 79024 for the electrical load 79026 (seat heater) in order to protect the supply line 79012 from thermal destruction.

Other potential scenarios can provide that electronic fuses make it possible for supply line sections of a supply network running at least partially electrically in parallel, by switching, to lead to one and the same electrical load, while they normally lead to different loads. In an emergency, therefore in the case of high electrical outputs which have to be transported, supply line sections of a cable harness typically not designed for this purpose can be electrically connected in parallel in order to be able to supply the electrical load which requires the high electrical output with sufficient power and in a manner protected from thermal destruction of the supply line sections.

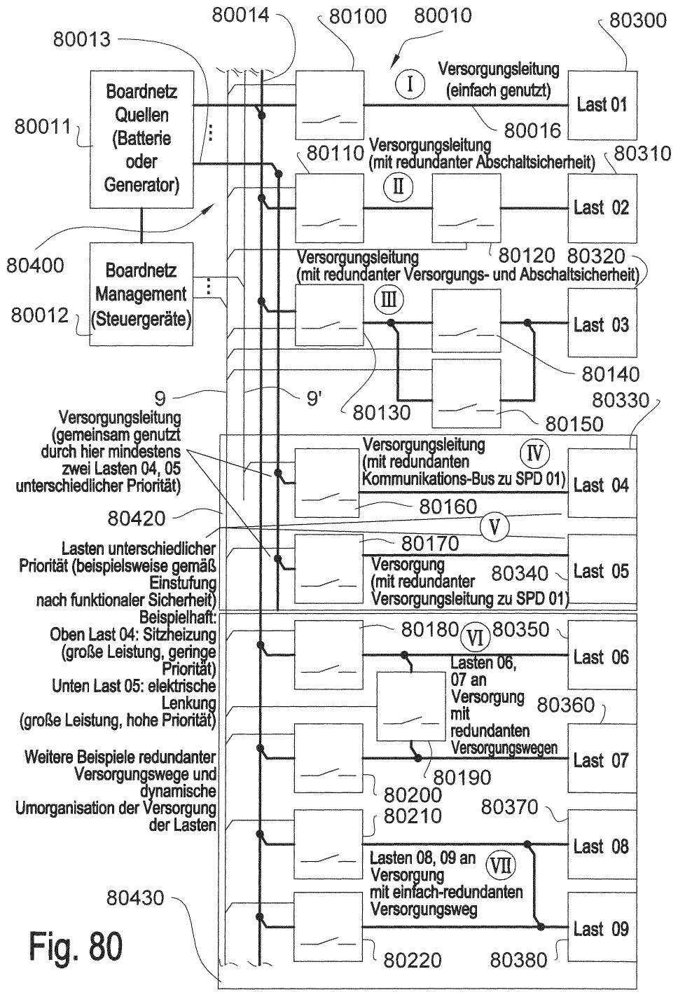

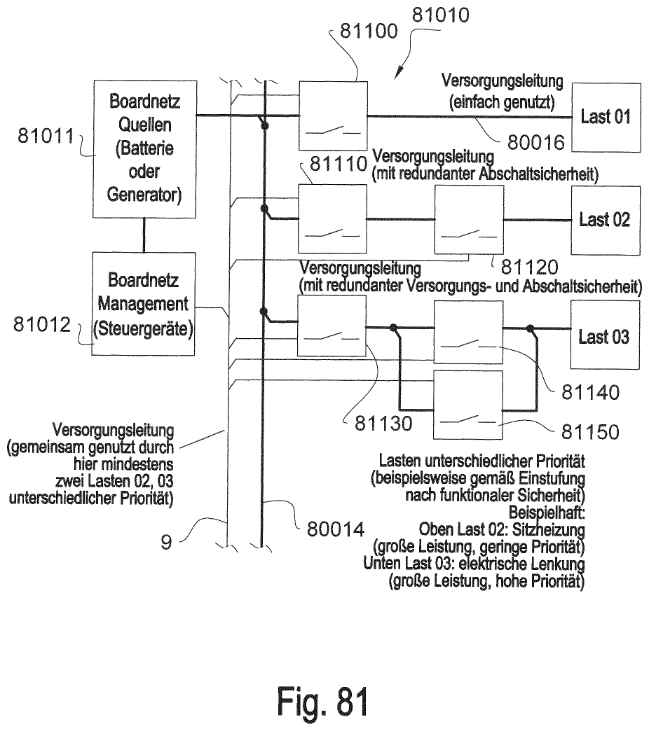

### FIGS. 80 and 81

According to the concept according to the disclosure in accordance with two further examples, the disclosure relates to a supply system for a vehicle having a demand-dependent, reconfigurable supply network. Criteria for a reconfiguration of the supply network can be thermal loads in individual supply sub-networks or the supply lines and supply line sections thereof, but also the non-compliance with electrical requirements. For this purpose, electronic fuses are used which monitor the electrical parameters at a plurality of different locations of the supply network and report them to a control center. The decisive criteria for possible reconfiguration of the supply network are especially the coordination of the current power requirements of the electric loads in relation to the power supply capacity of the power sources. In the event of a possible reconfiguration of the supply network, individual loads can be “shed.” Priorities with regard to the relevance of the functionality of the loads for driving operation in general or for the current driving situation of the vehicle are taken into account by the higher-level control or computer system.

FIGS. 80 and 81 show two examples of supply systems or 81010. Based on FIG. 80, the supply system has one or more power sources 80011 and a higher-level control or computer system 80012 in this example in the form of an onboard electrical system management. In this example, the power source 80011 is the starting point of three supply sub-networks 80400, 80410, and 80420. In FIG. 80 in the upper and lower region of the supply network 80010, a plurality of supply line sections 80016 branch from the two supply lines 80013 and 80014. Each of these supply line sections 80016 is provided with at least one electronic fuse 80100 to 80220 and leads to an electrical load 80300 to 80380. The electronic fuses 80100 to 80220 are connected via their data interfaces to one of a plurality of data communication buses 9, 9′, which originate from the higher-level control or computer system 80012. It is also possible for the electronic fuses or some of the electronic fuses to be connected to two or more different data communication buses. A plurality of supply subnetworks 80400, 80410 and 80420 are thus created, which have one or two supply lines with their supply line sections and/or the electrical fuses of which are connected to one or two of the data communication buses.

FIG. 80 shows, at I, a supply line section 80016 used simply. At II, a supply line section with redundant switch-off protection is shown, in which the two electronic fuses 80110 and 80120 are connected in series into the supply line section.

At III, a supply line section with redundant supply and switch-off protection is shown, in which two electronic fuses 80130 and 80140 are in turn connected in series into the supply line section and the electronic fuse 80150 is connected in parallel with the electronic fuse 80140.

At IV in FIG. 80, a supply line section with redundancy of the connection of its electronic fuse 80160 is on the data communication bus 9′.

V in FIG. 80 shows a supply line section with a redundant supply line 80013 originating from the power source 80011.

VI shows the situation in which the electronic fuse 80190 is arranged between two supply line sections in order to connect them to one another when required (the loads 80350 and 80360 are connected to the supply with the redundant supply lines 80013 and 80014).

VII shows the situation in which the loads 80370 and 80380 are connected to the supply with a single redundant supply line 80014.

FIG. 80 thus shows the variability of the use of electronic fuses in supply networks for reconfiguration of the topology, i.e., of the connection of individual supply line sections among one another and to different loads, wherein, starting from the power source, a plurality of supply lines leads to the different electronic fuses and via them to the loads. The supply lines can be used jointly in order to supply different loads with power. However, different loads can also be supplied with power by different supply lines. Finally, it is also possible for different loads to be protected via different electronic fuses.

FIG. 81 shows a further example of a supply system 81010 in a vehicle, in which a power source 81011 in turn supplies loads with power via, in this example, a supply line 81014, which loads are connected via supply line sections 81016 branching off from the supply line 81014. In the individual supply line sections, one or more electronic fuses 81100 to 81150 are provided, which are connected to a higher-level control or computer system 81012 in the form of an onboard electrical system management via a common data communication bus 9. The topology substantially corresponds to that of the upper supply sub-network 80400 of FIG. 80.

Of the electronic fuses of the supply networks of FIGS. 79 to 81, one or more can be designed such that they use their control device to control a plurality of circuit breakers which are distributed in an electronic fuse or on a plurality of electronic fuses. Furthermore, the control device can also be arranged externally of all the electronic fuses. The aforementioned variants apply accordingly to the operating parameter measuring devices of the electronic fuses.

### Features of the Proposal

The features of the proposal reflect different features of possible manifestations. The features have sub-features. The features are organized into feature groups. A new feature group begins with a new feature number 1. Those making revisions can combine features and/or sub-features with one another as desired, if appropriate. These combinations are an explicit part of the disclosure presented here. The scope of protection results in each case from the claims. However, the right to amend the scope of protection in the further patenting proceedings is expressly reserved. The scope of protection is directed to functional combinations as well as meaningful combinations. If no values and/or value ranges for parameters are specified, the disclosure recommends the performance of a DoE (design of experiment), i.e., the performance of a series of experiments with suitable statistical experimental planning.

Electronic fuse for a vehicle with emergency power supply

1. A control device (4) of an electronic fuse (1) of a vehicle,
wherein the control device (4) is monolithic, and
wherein the control device (4) comprises a circuit breaker (17), and
wherein the control device (4) comprises an oscillator (30) and/or a clock-pulse system, and
wherein the control device (4) comprises a voltage supply (5), and
wherein the control device (4) comprises an externally provided operating voltage (6), and
wherein the control device (4) is configured to receive at least a first state of the normal operation of the control device (4) when the externally provided operating voltage (6) is available and a second state of the emergency operation of the control device (4) when the externally provided operating voltage (6) fails, and
wherein the voltage supply (5) is configured to provide, during normal operation of the control device (4), internal supply voltages of the control device (4) required by device parts of the control device (4) and/or internal supply voltages of the electronic fuse (1) required by other device parts of the electronic fuse (1), by processing an externally-provided operating voltage (6) of the control device (4), and
wherein the voltage supply (5) is configured to charge, during normal operation of the control device (4), an external and/or internal power reserve (8) with the power of an externally provided operating voltage (6) of the control device (4) and/or the externally provided operating voltage (6) of the control device (4), and
wherein the voltage supply (5) is configured to extract, during emergency operation of the control device (4), the power for providing these internal supply voltages and/or the power for providing some of these internal supply voltages from the power reserve (8) instead of from the externally provided operating voltage (6) of the control device (4), and
wherein the voltage supply (5) is configured to supply the oscillator (30) and/or the clock-pulse system with electrical power from the power reserve (8) during emergency operation of the control device (4) when the operating voltage (6) fails, and
wherein the control device (4) sets the state of the circuit breaker (17) in normal operation and in emergency operation of the control device (4) when the operating voltage (6) fails.

2. The control device according to feature 1,
wherein the control device (4) comprises a computer core (2), and
wherein the control device (4) comprises a non-volatile memory (14), and
wherein the voltage supply (5) is configured to supply electrical power to the computer core (2) from the power reserve (8) during emergency operation of the control device (4) when the operating voltage (6) fails, and
wherein the voltage supply (5) is configured to supply the non-volatile memory (14) with electrical power from the power reserve (8) during emergency operation of the control device (4) when the operating voltage (6) fails.

3. The control device according to feature 2,
wherein the control device (4) comprises a data bus interface (10), and
wherein the voltage supply (5) is configured to supply the data bus interface (10) with electrical power from the power reserve (8) during emergency operation of the control device (4) when the operating voltage (6) fails, and
wherein the computer core (2) of the control device (4) is connected to a higher-level computer system (12) of the vehicle via the data bus interface (10) and via a data bus (9), and
wherein the computer core (2) is configured to signal to the higher-level computer system (12) this emergency operation and/or the failure of the operating voltage (6) of the control device (4) in an emergency operation of the control device (4) when the operating voltage (6) fails.

4. The control device according to feature 2 or 3,
wherein the control device (4) comprises a watchdog timer (13), and
wherein the control device (4) is configured to supply the watchdog timer (13) with electrical power from the power reserve (8) during emergency operation of the control device (4) when the operating voltage (6) fails.

### Supply Network for a Vehicle Comprising Electronic Fuses and Central Power Feed and Extraction Points

1. A supply network (200) for a vehicle for supplying device parts (210 to 215 and 220 to 224 and 230 to 234) of the vehicle with electrical power from power sources (250, 251), in particular according to one or more of the preceding features,
wherein the supply network (200) comprises one or more first supply line sections (245) which are configured to supply in each case one or more first device parts (210 to 213) of the device parts (210 to 215 and 220 to 224 and 230 to 234) of the vehicle with electrical power, and
wherein these first device parts (210 to 213) are configured to supply other, second device parts (220 to 224 and 230 to 234) of the device parts (210 to 215 and 220 to 224 and 230 to 234) of the vehicle with electrical power via one or more other, second line sections (240, 241), and
wherein some or all device parts of these device parts (210 to 213 and 220 to 224 and 230 to 234) have at least one corresponding electronic fuse (214 to 217 and 225 to 228 and 235 to 238), hereinafter referred to as an electronic fuse (214 to 217 and 225 to 228 and 235 to 238) of the device part, and
wherein the corresponding electronic fuse (214 to 217 and 225 to 228 and 235 to 238) of the corresponding device part is in each configured to prevent or allow the power extraction of this corresponding device part from the supply line section (245) which is configured to supply this corresponding device part with electrical power.

2. The supply network according to feature 1,
wherein the topology of the supply network (200) has a tree structure with a tree starting point (270), and
wherein the line sections (241 to 245) represent the branches of the supply network (200), and
wherein a power source (250) and/or a central power feed point is located at the tree starting point (270), and
wherein device parts (210 to 213, or 220 to 224, or 230 to 234) which have the electronic fuse (214 to 217 and 225 to 228 and 235 to 238) are located at ends of line sections (240 to 245).

3. The supply network according to feature 1 or feature 2,
wherein a plurality of electronically controllable fuses (e.g., 255, 216, 235, etc.) are serially connected in at least one resulting power supply path (250, 255, 245, 216, 212, 241, 235, 230).

4. The supply network (200) according to feature 3,
wherein at least two line sections (241, 243) are configured to supply in each case at least one device part (230, 232) of the vehicle with electrical power, at least at times, with different prioritization, and wherein a higher-level computer system (12) of the vehicle is configured, in particular via a data bus (9), to disconnect individual device parts or a plurality of device parts of the device parts (210 to 213 and 220 to 224 and 230 to 234) of the supply network (200) from the power supply (250) by means of electronic fuses (255, 214 to 217 and 225 to 228 and 235 to 238) in the supply network (200) depending on the operating state of the vehicle and/or due to environmental influences and/or due to the state of the surroundings of the vehicle and/or due to the vehicle occupants and/or due to vehicle parameters, such as speed or acceleration or location.

5. The supply network (200) according to feature 4,
wherein the supply network (200) is configured to supply at least one first device part (212) with electrical power having higher priority via a first supply line section (245), and
wherein the supply network (200) is configured to supply at least one second device part (231) with electrical power having lower priority via a second supply line section (241).

6. The supply network (200) according to feature 5,
wherein the vehicle comprises a higher-level computer system (12), and
wherein the higher-level computer system (12) of the vehicle is configured to disconnect the device part (231) having the lower priority within the supply network (200) from the power supply (250) via the data bus (9) by means of the electronic fuse (236) of the device part (231) having the lower priority or by means of a different fuse in the supply network (200), if the supply safety of other device parts of the supply network (200) having higher priority regarding the supply of electrical power would otherwise be endangered.

7. The supply network (200) according to any of features 1 to 6,
wherein one or more, optionally all device parts (250, 210 to 213, and 220 to 224 and 230 to 234) of the vehicle which are supplied with power from a supply line section (245, 240, 241) and/or feed electrical power into a supply line section (245, 240, 241) are configured
to detect electrical parameters of the current flow in the relevant supply line section of the supply line sections (245, 240, 241) and/or
electrical parameters of the potential of the supply line section of the supply line sections (245, 240, 241) on the supply side of the device part against a reference potential (280).

8. The supply network (200) according to feature 7,
wherein the device parts (250, 210 to 213, and 220 to 224 and 230 to 234) of the vehicle which are supplied with power from the relevant supply line section (245, 240, 241) and/or feed electrical power to the relevant supply line section (245, 240, 241) are configured to transmit the detected parameters and/or the values derived from these detected parameters to control devices (281 to 292) of other device parts of the vehicle and/or to control devices (281 to 292) of other electronic fuses of the supply network (200) and/or to a higher-level computer system (12) via a data bus (9).

9. The supply network (200) according to feature 8,
wherein the data bus (9) comprises a fuse data bus (9) or a different data bus, for example a Lin data bus or a DSI3 data bus or a PSI5 data bus or a CAN data bus or a CAN FD data bus or an Ethernet data bus or a Flexray data bus or an LVDS data bus or an otherwise wired or wireless data communication device, for example a Bluetooth or WLAN data communication device, or the like, or is the like.

10. The supply network (200) according to any of features 1 to 9,
wherein a power source (250) is configured to supply electrical power to a device part (213) of the device parts (250, 210 to 213, and 220 to 224 and 230 to 234) of the vehicle, hereinafter referred to as a power-supplying device part (213), via a supply line section (245), and
wherein the power-supplying device part (213) is configured to supply a further device part (232) of the vehicle with electrical power via a further supply line section (243).

11. The supply network (200) according to one or more of features 1 to 10,
wherein a first supply line section (241) of the supply network (200) and a second supply line section (243) of the supply network (200) have a voltage of more than 40 V among one another or at least temporarily with respect to a reference potential (201).

12. The supply network (200) according to one or more of features 1 to 11,
wherein the supply network (200) has a first supply sub-network which is a supply network according to one or more of features 1 to 11, and
wherein the supply network (200) has a second supply sub-network which is a supply network according to one or more of features 1 to 11, and
wherein the first supply sub-network is different from the second supply sub-network, and
wherein the potential difference between the potential of the supply line sections of the first supply sub-network and a reference potential is at least at times at a voltage of 0 V to 1500 V, typically 800 V, and wherein the potential difference between the potential of the supply line sections of the second supply sub-network and a reference potential is at least at times at a voltage of 0 V to 50 V, typically 48 V, i.e., less than 50 V.

13. A device part for a vehicle having a supply network according to any of features 1 to 12,
wherein the corresponding device part (212) has a plug-in option (262) for the corresponding electronic fuse (216).
   Supply Network with Electronic Fuses with Sub-Network Shedding Option

1. A supply network (200) for a vehicle, in particular according to one or more of the preceding features,
wherein the supply network (200) has supply line sections, and
wherein the supply network (200) comprises power-consuming device parts (250, 210 to 213 and 220 to 224 and 230 to 234) of the supply network (200), and
wherein the supply network (200) comprises power-supplying device parts (250, 251) of the vehicle which are configured to feed power into the supply network (200), and
wherein power-consuming device parts (250, 210 to 213 and 220 to 224 and 230 to 234) of the vehicle are configured to be supplied with electrical power from the supply network via at least one supply line section (240 to 245), and
wherein power-consuming device parts (210 to 213) are configured to be able to supply a further device part (220 to 223 and 230 to 233) of the vehicle with electrical power via a further line section (240, 241), and
wherein the power-consuming device parts (210 to 213 and 220 to 223 and 230 to 233) have an electronic fuse (280 to 291), and
wherein the corresponding electronic fuse (280 to 291) of a corresponding power-consuming device part (210 to 213 and 220 to 223 and 230 to 233) is configured in each case to be able to prevent the supply of this corresponding power-consuming device part (210 to 213 and 220 to 223 and 230 to 233) and the possibly existing further power-consuming device parts (220 to 223 and 230 to 233) supplied with electrical power from this corresponding power-consuming device part (210 to 213 and 220 to 223 and 230 to 233).

2. The supply network (200) of a vehicle according to feature 1,
wherein power-supplying device parts (250 to 251) have a corresponding electronic fuse (292 to 293), and
wherein the corresponding electronic fuse (280 to 291) of a corresponding power-supplying device part (250 to 251) is configured to be able to prevent the feeding of electrical power by the corresponding power-supplying device part (250 to 251) into the supply network (200) and/or a corresponding supply line section (245), and
wherein power-consuming device parts (210 to 213), which are configured to supply electrical power to other power-consuming device parts (220 to 223 and 230 to 233) with electrical power via sub-supply networks of the supply network (200), have a corresponding further electronic fuse in order to be able to shed the sub-supply networks of the supply network (200) supplied by them, in some cases by means of a corresponding circuit breaker (17) of this corresponding further electronic fuse.
   Fuse Box with Pluggable Electronic Fuses

1. A fuse box (400) for a supply network (200) of a vehicle, in particular according to one or more of the preceding features,
wherein the fuse box (400) comprises electronic fuses (405) and/or slots (410) for electronic fuses (405), and
wherein the fuse box comprises melting fuses (415) and/or slots (420) for melting fuses (415), and
wherein at least one electronic fuse (405) of the electronic fuses has a first terminal (18) and a second terminal (19), and
wherein this at least one electronic fuse (405) is configured to emulate the behavior of a melting fuse (415), and
wherein this electronic fuse (405) is configured to detect the value of the electrical current (29) flowing through this electronic fuse (405) from the first terminal (18) to the second terminal (19) or vice versa, and
wherein this electronic fuse (405) is configured to determine, by means of a polynomial of at least the second degree, an intermediate value from this detected current value and to temporally integrate it into an integrated intermediate value, and
wherein the electronic fuse (405) is configured to prevent the current flow between the first terminal (18) and the second terminal (19) if the integrated intermediate value exceeds a maximum value, and wherein the electronic fuse (405) is arranged in a fuse body (425) with plug-in connectors which mechanically fits in one of the slots (410) for electronic fuses (405).

2. The fuse box (400) according to feature 1,
wherein the fuse box (400) comprises a data bus (9).

3. The fuse box (400) according to feature 2,
wherein a slot (410) for an electronic fuse (405) has a first contact (430) of the slot (410), and
wherein this slot (410) for an electronic fuse (405) has a second contact (445) of the slot (410), and
wherein the first contact (430) of the slot (410) is configured to establish an electrical connection between this first contact (410) of the slot (410) and a first contact (450) of a plug-in connector of a fuse body (425) in order to electrically connect the first terminal (18, 450) of the fuse (405) of the fuse body (425) to the first contact (430) of the slot (410), and
wherein the second contact (445) of the slot (410) is configured to establish an electrical connection between this second contact (445) of the slot (410) and a second contact (470) of the plug-in connector (410) of the fuse body (425) in order to electrically connect the second terminal (19, 470) of the fuse (405) of the fuse body (425) to the second contact (445) of the slot (405).

4. The fuse box (400) according to feature 3,
wherein a slot (410) for an electronic fuse (405) has a third contact (440) of the slot (410), and
wherein the third contact (440) of the slot (405) is configured to establish an electrical connection between this third contact (440) of the slot (405) and a third contact (465) of the plug-in connector (410) of the fuse body (425) in order to electrically connect a data line (9) of a data interface (10) of a control circuit (4) of the electronic fuse (405) of the fuse body (425) to the third contact (440) of the slot (405).

5. The fuse box (400) according to feature 3 and/or 4,
wherein a slot (410) for an electronic fuse (405) comprises a fourth contact (435) of the slot (410), and
wherein the fourth contact (435) of the slot (410) is configured to establish an electrical connection between this fourth contact (435) of the slot (410) and a fourth contact (455) of the plug-in connector of the fuse body (425) in order to electrically connect a power supply of the control device (4) of the electronic fuse (405) to the fourth contact (455) of the slot (410).

6. A fuse body (425) of an electronic fuse (405) for a fuse box (400) according to one or more of features 1 to 5,
wherein the plug-in connector of the fuse body (425) has a first contact (450) for the first terminal (18) of the electronic fuse (405), and
wherein the plug-in connector of the fuse body (425) has a second contact (470) for the second terminal (19) of the electronic fuse (405), and
wherein the plug-in connector mechanically fits into at least one of the slots (410) for electronic fuses (405) of the fuse box (400).

7. The fuse body (425) according to feature 6,
wherein the plug-in connector of the fuse body (425) has a third contact (465) for a fuse data bus (9), and
wherein the third contact (465) is electrically connected to a data line (9) of a data interface (10) of a control device (4) of the electronic fuse (405) of the fuse body (425).

8. The fuse body (425) according to feature 6 or 7,
wherein the plug-in connector of the fuse body (425) has at least one fourth contact (455) for a voltage supply (6) of the control device (4) of the electronic fuse (405).

9. A melting fuse (415) for a fuse box (400) according to one or more of features 1 to 5,
wherein the melting fuse (415) has a fuse body (425), and
wherein the fuse body (425) has a plug-in connector (410), and
wherein the plug-in connector (410) of the fuse body (425) has a first contact (455) for the first terminal (18) of the melting fuse (415), and
wherein the plug-in connector (410) of the fuse body (425) has a second contact (470) for the second terminal (19) of the melting fuse (415), and
wherein the plug-in connector of the melting fuse (415) is configured to mechanically fit into at least one of the slots (410) for electronic fuses (405).

10. The melting fuse (415) according to feature 9,
wherein the plug-in connector of the melting fuse (415) is configured to mechanically fit into at least one of the slots (420) for melting fuses (415).
   Electronic Fuse with Monitoring of the Circuit Breaker

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters and to determine therefrom a value for an electrical current (29) through the circuit breaker (17) between the first terminal (26) of the circuit breaker (17) and the second terminal (28) of the circuit breaker (28).

2. The electronic fuse (1), in particular according to feature 1,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has an auxiliary circuit breaker (23), and
wherein the electronic fuse (1) has a shunt resistor (24), and
wherein the electronic fuse (1) has a control device (4), and
wherein the circuit breaker (17) has a first terminal (26), a control terminal (27) and a second terminal (28), and
wherein the auxiliary circuit breaker (23) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the first terminal (26) of the auxiliary circuit breaker (23) is electrically connected to the first terminal (18) of the fuse (1), and
wherein the control terminal (27) of the auxiliary circuit breaker (23) is electrically connected to the control device (4), and
wherein the second terminal (28) of the auxiliary circuit breaker (23) is connected to a first terminal (25) of the shunt resistor (24), and
wherein the second terminal of the shunt resistor is electrically connected to the second terminal (19) of the fuse (1), and
wherein the control device (4) of the electronic fuse (1) is configured to detect the voltage between the first terminal (25) of the shunt resistor (24) and the second terminal (21) of the shunt resistor (24) and/or functionally equivalent values of physical parameters and to determine therefrom a value for an electrical current (29) through the circuit breaker (17) between the first terminal (26) of the circuit breaker (17) and the second terminal (28) of the circuit breaker (28).

3. The electronic fuse (1), in particular according to feature 1 or 2,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the electronic fuse (1) comprises an electronic test current source (505), and
wherein the electronic test current source (505) is configured to be able to feed an additional test current (515) into the circuit breaker (17) between the first terminal (26) of the circuit breaker (17) and the second terminal (28) of the circuit breaker (17) and/or into the first terminal (26) of the circuit breaker (17) depending on a first control signal (510) of the control device (4), and wherein the control device (4) is configured to modulate the control signal (510) with a first modulation signal ({505}) and thus to modulate the additional test current (515), and
wherein the control device (4) is configured to detect or determine the temporal value characteristic of the electrical current (29) through the circuit breaker (17), and
wherein the control device (4) is configured to check whether the temporal value characteristic of the electrical current (29) comprises signal components of which the modulation correlates with the modulation of the modulation signal ({505}).

4. The electronic fuse (1) according to feature 3,
wherein the fuse (1) comprises a synchronous demodulator (525), and
wherein the synchronous demodulator (525) is configured to determine the correlation between the value characteristic of the electrical current (29) on the one hand and the modulation signal ({505}) on the other hand.

5. The electronic fuse (1) according to feature 4,
wherein the synchronous demodulator (525) is configured to multiply the modulation signal ({505}) or a signal derived therefrom or a signal that corresponds to the modulation signal ({505}) in a fixed temporal relationship, on the one hand with the temporal value characteristic of the electrical current (29) or, on the other hand, a signal derived therefrom, and
wherein the synchronous demodulator (525) is configured to subsequently filter, optionally by low-pass filter, the signal resulting from the multiplication to form a correlation signal (C₂₉ₘ(t)).

6. The electronic fuse (1) according to feature 4 or 5,
wherein the synchronous demodulator (525) or the control device (4) comprises a matched filter optimized for the modulation signal ((505)) and/or a matched filter and/or a Kalman filter or a different estimation filter which is configured to convert the temporal value characteristic of the electrical current (29) into a correlation signal (C₂₉ₘ(t)).
   Electronic Fuse with Potential Monitoring of the Circuit Breaker

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters and to determine therefrom a value for an electrical current (29) through the circuit breaker (17) between the first terminal (26) of the circuit breaker (17) and the second terminal (28) of the circuit breaker (28).

2. The electronic fuse (1) according to feature 1,
wherein the control device (4) is configured to detect the electrical voltage between the first terminal (18) of the fuse (1) and the second terminal (19) of the fuse (1), and
wherein the control device (4) switches the circuit breaker (17) to non-conductive if the sign of the electrical voltage between the first terminal (18) of the fuse (1) and the second terminal (19) of the fuse (1) does not correspond to a default value.

3. The electronic fuse (1) according to feature 1 or feature 2,
wherein the control device (4) is configured to detect the electrical voltage between the first terminal (18) of the fuse (1) and the second terminal (19) of the fuse (1), and
wherein the control device (4) switches the circuit breaker (17) to non-conductive if the electrical voltage between the first terminal (18) of the fuse (1) and the second terminal (19) of the fuse (1) falls below a first default value, and/or
wherein the control device (4) switches the circuit breaker (17) to non-conductive if the electrical voltage between the first terminal (18) of the fuse (1) and the second terminal (19) of the fuse (1) exceeds a second default value.

4. The electronic fuse (1) according to any of features 1 to 3,
wherein the control device (4) is configured to detect the electrical voltage between the first terminal (26) of the circuit breaker (17) of the fuse (1) and the second terminal (28) of the circuit breaker (17) of the fuse (1), and
wherein the control device (4) switches the circuit breaker (17) to non-conductive if the sign of the electrical voltage between the first terminal (26) of the circuit breaker (17) of the fuse (1) and the second terminal (28) of the circuit breaker (17) of the fuse (1) does not correspond to a default value.

5. The electronic fuse (1) according to any of features 1 to 4,
wherein the control device (4) is configured to detect the electrical voltage between the first terminal (26) of the circuit breaker (17) of the fuse (1) and the second terminal (28) of the circuit breaker (17) of the fuse (1), and
wherein the control device (4) switches the circuit breaker (17) to non-conductive if the electrical voltage between the first terminal (26) of the circuit breaker (17) of the fuse (1) and the second terminal (28) of the circuit breaker (17) of the fuse (1) falls below a third default value, and/or
wherein the control device (4) switches the circuit breaker (17) to non-conductive if the electrical voltage between the first terminal (26) of the circuit breaker (17) of the fuse (1) and the second terminal (28) of the circuit breaker (17) of the fuse (1) exceeds a fourth default value.

6. The electronic fuse (1) according to any of features 1 to 5,
wherein the electronic fuse (1) has a reference potential terminal (201) and
wherein the control device (4) is configured to detect the electrical voltage between the first terminal (18) of the fuse (1) and the reference potential terminal (201) of the fuse (1) and to switch the circuit breaker (17) to non-conductive if the electrical voltage between the first terminal (18) of the fuse (1) and the reference potential terminal (201) of the fuse (1) falls below a fifth default value and/or if the electrical voltage between the first terminal (18) of the fuse (1) and the reference potential terminal (201) of the fuse (1) exceeds a sixth default value, and/or
wherein the control device (4) is configured to detect the electrical voltage between the second terminal (19) of the fuse (1) and the reference potential terminal (201) of the fuse (1) and to switch the circuit breaker (17) to non-conductive if the electrical voltage between the second terminal (19) of the fuse (1) and the reference potential terminal (201) of the fuse (1) falls below a seventh default value and/or if the electrical voltage between the second terminal (19) of the fuse (1) and the reference potential terminal (201) of the fuse (1) exceeds an eighth default value.

7. The electronic fuse (1) according to any of features 1 to 6,
wherein the electronic fuse (1) has a reference potential terminal (201) and
wherein the control device (4) is configured to detect the electrical voltage between the first terminal (26) of the circuit breaker (17) of the fuse (1) and the reference potential terminal (201) of the fuse (1) and to switch the circuit breaker (17) to non-conductive if the electrical voltage between the first terminal (26) of the circuit breaker (17) of the fuse (1) and the reference potential terminal (201) of the fuse (1) falls below a ninth default value and/or if the electrical voltage between the first terminal (26) of the circuit breaker (17) of the fuse (1) and the reference potential terminal (201) of the fuse (1) exceeds a tenth default value, and/or
wherein the control device (4) is configured to detect the electrical voltage between the second terminal (28) of the circuit breaker (17) of the fuse (1) and the reference potential terminal (201) of the fuse (1) and to switch the circuit breaker (17) to non-conductive if the electrical voltage between the second terminal (19) of the fuse (1) and the reference potential terminal (201) of the fuse (1) falls below an eleventh default value and/or if the electrical voltage between the second terminal (28) of the circuit breaker (17) of the fuse (1) and the reference potential terminal (201) of the fuse (1) exceeds a twelfth default value.

### Optically Controlled Electronic Fuse

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the circuit breaker (17) and the control device (4) are accommodated in a housing (535), and
wherein the housing (535) has an optical window (545).

2. The electronic fuse (1) according to feature 1,
wherein the control device (4) has an optical data interface (550).

3. The electronic fuse (1) according to feature 2,
wherein the optical window (545) is a sub-device of one or more optical data interfaces (550) of the control device (4) of the relevant electronic fuse (1).

4. The electronic fuse (1) according to feature 3,
wherein the optical window (545) is configured to enable the entry and/or exit of electromagnetic radiation for the transport of data to the control device (4), and
wherein the control device (4) is located within the housing (535) and
wherein the optical data interface (550) of the control device (4) is configured to communicate through the optical window (545) with an optical interface (555) of a different device (12), for example a higher-level computer system (12), outside the housing (535) by means of the electromagnetic radiation.

5. The electronic fuse (1) according to feature 4,
wherein the electromagnetic radiation for the transport of data is laser radiation of a laser (560) or radiation of an LED (560).

6. The electronic fuse (1) according to any of features 1 to 5,
wherein the electronic fuse (1) comprises a laser or an LED (560), in particular as a transmitter of data of the optical data interface (550).

7. The electronic fuse (1) according to feature 6,
wherein the electronic fuse (1) has a silicon-based LED (560) as an LED.

8. The electronic fuse (1) according to feature 7,
wherein the silicon-based LED (560) is a silicon avalanche LED (560), in particular a SPAD diode (560) operated as an LED.

9. The electronic fuse (1) according to feature 7 or 8,
wherein the electronic fuse (1) comprises a driving device (565), and
wherein the driving device (565) generates, from the operating voltage of the electronic fuse (1), an operating voltage for the silicon-based LED (560) by means of a voltage converter of a voltage supply (5).

10. The electronic fuse (1) according to any of features 7 to 9,
wherein the electronic fuse (1) is configured to operate the silicon-based LED (560) at least at times as a receiver.

11. The electronic fuse (1) according to feature 10,
wherein the computer core (2) of the control device (4) of the electronic fuse (4) is configured to disconnect the silicon-based LED (560) from the electrical supply of the voltage converter of the voltage supply (5) by means of an isolating switch of the control device of the electronic fuse, and
wherein the computer core (2) is configured to detect the voltage signal (575) and/or the photocurrent of the silicon-based LED (560) by means of an analog-to-digital converter (570) of the control device (4) of the electronic fuse (1).

12. The electronic fuse (1) according to any of features 1 to 11,
wherein the computer core (2) is configured to detect the voltage signal (575) and/or the photocurrent of a photodetector (560) by means of an analog-to-digital converter (570) of the electronic fuse (1).

13. The electronic fuse (1) according to feature 11 or 12,
wherein the computer core (2) and/or the control device (4) are configured to use the detected value as an input data signal of an optical data interface (550).

14. The electronic fuse (1) according to any of features 1 to 13,
wherein the electronic fuse (1) comprises a photodetector, for example a photodiode (560), and evaluation electronics of the photodetector (560).

15. The electronic fuse (1) according to one or more of features 4 to 14,
wherein the fuse (1) is configured to be connected by means of an optical waveguide (580) to one or more other electronic fuses (1, 214 to 217, 225 to 223, 230 to 235, 225 to 256) via the corresponding optical data interface (550, 551) of the control devices (4) of these electronic fuses (1, 214 to 217, 225 to 223, 230 to 235, 225 to 256).

16. The electronic fuse (1) according to feature 15,
wherein the electronic fuse (1) is configured to be connected via its optical interface (550) and an optical waveguide (580) to an optical interface (555) of a higher-level controller (12), for example a higher-level computer system (12), and, where applicable, to one or more further electronic fuses (214 to 217, 225 to 223, 230 to 235, 225 to 256).
   Electronic Fuse with Data Connection

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the fuse (1) is connected via a data interface (10, 610, 551) to a higher-level computer system (12) and where applicable to one or more further electronic fuses (1, 214 to 217, 225 to 223, 230 to 235, 225 to 256).
   Electronic Fuse with Temperature Monitoring

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the control device of the electronic fuse comprises one or more temperature sensor evaluation devices (585), and
wherein the electronic fuse comprises a temperature sensor (586), and
wherein the control device (4) is configured to evaluate temperature measured values of the one or more temperature sensor evaluation devices (585) which are detected by means of temperature sensors external to the electronic control device (4) and/or with the aid of temperature sensors (586) of the electronic fuse (1), and
wherein the control device (4) is configured to open the circuit breaker (17) if the temperature measured value exceeds a temperature limit value, and/or
wherein the control device (4) is configured to signal a temperature excess to a higher-level computer system (12) via a data bus (9) if the temperature measured value exceeds a temperature limit value.
   Electronic Fuse with Optical Transmission of Measured Values

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the fuse (1) is connected via a data interface (10, 610, 551) to a higher-level computer system (12) and where applicable to one or more further electronic fuses (1, 214 to 217, 225 to 223, 230 to 235, 225 to 256).

2. The electronic fuse (1) according to feature 1,
wherein the electronic fuse (1) and/or the control device (4) of the electronic fuse (1) comprise means (20, 21, 22, 23, 24, 25, 525, 570) for capturing and detecting a reverse-flowing current (29).

3. The electronic fuse (1) according to feature 1 or 2,
wherein the control device (1) comprises a computer core (2), and
wherein the computer core (2) of the control device (4) of the electronic fuse (1) is configured to evaluate the measured values detected in this way, and
wherein the computer core (2) is configured to transfer the measured values and/or measured values derived therefrom to other computer cores of other electronic fuses via a fuse data bus (9, 540) or the like or to a higher-level controller (12), for example to a higher-level computer system (12).

4. The electronic fuse (1) according to any of features 1 to 3
wherein the electronic fuse (1) and/or the control device (4) of the electronic fuse (1) comprise two data interfaces (10, 610), which can each be optical data interfaces (550, 551).

5. A system comprising a plurality of electronic fuses according to features 1 to 4,
wherein the system comprises an optical waveguide (580), and
wherein the optical waveguide (580) is configured to connect an electronic fuse via an optical data interface (551, 550) of this electronic fuse to another device (12), for example to a higher-level computer system (12), or to a different electronic fuse.
   Electronic Fuse with Password and Authentication Protection

1. An electronic fuse (1) of a vehicle, in particular according to one or more of the preceding features,
wherein the electronic fuse (1) has a control device (4), and
wherein the electronic fuse (1) has a circuit breaker (17), and
wherein the control device (4) of the electronic fuse (1) has a data interface (10) for a fuse data bus (9), and
wherein the control device (4) is configured to control whether the circuit breaker (17) is conductive and thus is operating as a closed-circuit breaker, or whether the circuit breaker (17) is not conducting, and thus is operating as an open circuit breaker, and
wherein the control device (4) is configured to receive data messages via the fuse data bus (9), and
wherein whether the control device (1) closes or opens the circuit breaker (17) depends at least in part and at least at times on the content of these data messages.

2. The electronic fuse (1) according to feature 1,
wherein the control device (4) of the electronic fuse (1) is configured to change the switching state of the circuit breaker (17) based on the data message only,
if the data message comprises a password, and
if this password has one or more predetermined properties, in particular is a predetermined password.

3. The electronic fuse (1), in particular according to features 1 to 2,
wherein the electronic fuse (1) comprises a circuit breaker (17), and
wherein the electronic fuse (1) is configured to detect the voltage between this terminal (26) and a reference node (201)in the form of a voltage value at the terminal (26) of its circuit breaker (17) which is on the power-source side, and
wherein the electronic fuse (1) is configured to check this voltage value, and
wherein the electronic fuse (1) is configured to switch off the electrical supply of a supply sub-network of a supply network (200) by switching off its circuit breaker (17),
if the detected voltage value falls below a voltage minimum value.

4. The electronic fuse (1), in particular according to features 1 to 3,
wherein the electronic fuse (1) comprises a circuit breaker (17), and
wherein the electronic fuse (1) is configured to detect and/or determine the value of the current (29) through the circuit breaker (17), and
wherein the electronic fuse (1) is configured to check the determined current value, and
wherein the electronic fuse (1) is configured to switch off the electrical supply of a supply sub-network of a supply network (200) by switching off its circuit breaker (17),
if the detected current value exceeds a predetermined peak current value.

5. The electronic fuse (1), in particular according to features 1 to 4,
wherein the electronic fuse (1) comprises a circuit breaker (17), and
wherein the electronic fuse (1) is configured to detect the voltage between this terminal (26) and a reference node (201)in the form of a voltage value at the terminal (26) of its circuit breaker (17) which is on the power-source side, and
wherein the electronic fuse (1) is configured to check this voltage value, and
wherein the electronic fuse (1) is configured to detect and/or determine the value of the current (29) through the circuit breaker (17), and
wherein the electronic fuse (1) is configured to check the determined current value, and
wherein the electronic fuse (1) is configured to switch off the electrical supply of a supply sub-network of a supply network (200) by switching off its circuit breaker (17),
if the detected voltage value falls below a voltage minimum value, and
if at the same time the detected current value exceeds a predetermined peak current value.

6. The electronic fuse (1) according to feature 5,
wherein the control device (4) of the electronic fuse (1) is configured to carry out one or more switch-on attempts of the circuit breaker (17) temporally after the electrical supply of the supply sub-network of the supply network (200) is switched off by switching off its circuit breaker (17).

7. The electronic fuse (1) according to feature 6,
wherein, temporally after the electrical supply of the supply sub-network of the supply network (200) is switched off by switching off its circuit breaker (17), the control device (4) of the electronic fuse (1) is configured to increase a switch-on attempt counter of the control device (4), in particular a register value of a computer core (2) of the control device (4) of the electronic fuse (1), by one switch-on attempt increment value, which can also be negative and is different from 0, when there is a switch-on attempt of the circuit breaker (17).

8. The electronic fuse (1) according to feature 7,
wherein the control device (4) of the electronic fuse (1) is configured to transmit an error message to the computer core (2) of the control device (4) of a different electronic fuse and/or to a control device (4) of a different electronic fuse or to a higher-level computer system (12) if the number of unsuccessful switch-on attempts and/or the counter reading of the switch-on attempt counter of the control device (4) and/or of the computer core (2) crosses or reaches a predetermined number.

9. The electronic fuse (1) according to any of features 1 to 8,
wherein the control device (4) of the electronic fuse (1) and/or the computer core (2) of the control device (4) of the electronic fuse (1) are configured to receive or transmit-via a data interface (10, 550) of the control device (4) and via a fuse data bus (9, 540)—data, such as configuration data and/or switch commands and/or diagnostic data and/or measured values and/or comparison value settings and/or threshold values and/or authentication data and/or program code and/or passwords and/or encryption information and/or random numbers, in particular for writing into a memory of the control device (4) or the computer core (2) and/or for reading from a memory of the control device (4) or from a memory of the computer core (2).
   Electronic Fuse with One- or Two-Wire Data Bus and Auto Addressing Method

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters and to determine therefrom a value for an electrical current (29) through the circuit breaker (17) between the first terminal (26) of the circuit breaker (17) and the second terminal (28) of the circuit breaker (28).
wherein the fuse (1) is connected via a data interface (10, 610, 551) and a data bus (9) to a higher-level computer system (12) and where applicable to one or more further electronic fuses (1, 214 to 217, 225 to 223, 230 to 235, 225 to 256), and
wherein the data bus (9) is in parts or in its entirety a two-wire data bus.

2. The electronic fuse (1) according to feature 1,
wherein the data bus (9) is a differential data bus.

3. The electronic fuse (1) according to feature 2,
wherein the data bus (9) is a differential bidirectional data bus.

4. The electronic fuse (1) according to feature 3,
wherein the data bus (9) is a CAN data bus or a CAN FD data bus or a Flexray data bus or an LVDS data bus or a PSI5 data bus or a data bus (9) which requires a data interface (10) of the control device (4) having a physical interface of a CAN data bus and/or of a CAN FD data bus or of a Flexray data bus or of a PSI-5 data bus or of an LVDS data bus or the like.

5. The electronic fuse (1), in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters and to determine therefrom a value for an electrical current (29) through the circuit breaker (17) between the first terminal (26) of the circuit breaker (17) and the second terminal (28) of the circuit breaker (28).
wherein the fuse (1) is connected via a data interface (10, 610, 551) and a data bus (9) to a higher-level computer system (12) and where applicable to one or more further electronic fuses (1, 214 to 217, 225 to 223, 230 to 235, 225 to 256), and wherein the data bus (9) is in parts or in its entirety a one-wire data bus.

6. The electronic fuse (1) according to feature 5,
wherein the data bus (9) is a LIN data bus or a DSI3 data bus or a UART data bus or an SPI data bus.

7. The electronic fuse (1) according to any of features 1 to 5,
wherein the control device (4) of the electronic fuse comprises two data interfaces (610, 10) for the fuse data bus (9).

8. The electronic fuse (1) according to any of features 1 to 7,
wherein the control device (4) of the electronic fuse (1) comprises one or more data interfaces (10, 610), and
wherein data interfaces (10, 610) of the control device (4) of the electronic fuse (1) are configured to execute an auto addressing method for determining a fuse address of the control device (4) and/or of the computer core (2) of the control device (4) or to participate in this auto addressing method.

9. The electronic fuse (1, 825) according to any of features 1 to 7,
wherein the electronic fuse (1, 825) is configured to transmit parameters of the supply sub-trees (815) connected to the electronic fuse (1, 825) and/or of individual nodes of the connected supply sub-trees (815) and/or of individual connected supply line sections of the supply tree of the supply lines of the vehicle to a different electronic fuse (805) and/or to one or more controllers of the vehicle and/or to a higher-level computer system (12).

10. The electronic fuse (1, 825) according to feature 9,
wherein such a parameter is a directly accessible parameter, such as the temperature value of the temperature of a temperature sensor, and/or the voltage value of a voltage of a node (26, 27, 28) within the fuse (1) against a reference potential (201) and/or the voltage value of a voltage of a node of the supply network (200) against a reference potential (201) and/or the value of an electrical current (29) in a supply line section of the connected supply network (820).

11. The electronic fuse (1, 825) according to feature 9 or 10,
wherein the computer core (2) of the control device (4) of the electronic fuse (1) is configured,
in particular by applying Kirchhoff equations to data,
which the control device (4) of the electronic fuse has determined by means of measuring devices of this electronic fuse (1, 825), and/or
which the control device (4) of this electronic fuse (1, 825) has received from the control devices (4) of other electronic fuses (805) or from higher-level controllers (12), for example a higher-level computer system (12),
to detect and/or determine derived parameters, such as leakage currents against other electrical nodes in the vehicle or electrical resistances of supply voltage line sections.

12. The electronic fuse (1, 805) according to feature 10 or 11,
wherein the control device (4) of the electronic fuse (1, 825) and/or the computer core (2) of the control device (4) of the electronic fuse (1, 825) are configured to estimate the temperature value of the temperature of a downstream supply line section,
if its ohmic resistance and its heat capacity and its thermal leakage resistances and the ambient temperature in the region of the supply line section are known approximately to the control device (4) of the electronic fuse (1, 825) and/or to the computer core (2) of the control device (4) of the electronic fuse (1, 825), for example by estimation of the control device (4) of the electronic fuse (1, 825).
   Supply Network with Measurement Data Exchange Between Electronic Fuses

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the fuse (1) is connected via a data interface (10, 610, 551) to a higher-level computer system (12) and optionally to one or more further electronic fuses (1, 214 to 217, 225 to 223, 230 to 235, 225 to 256), and
wherein the electronic fuse (1, 825) is configured to transmit parameters of the supply sub-trees (815) connected to the electronic fuse (1, 825) and/or of individual nodes of the connected supply sub-trees (815) and/or of individual connected supply line sections of the supply tree of the supply lines of the vehicle to a different electronic fuse (805) and/or to one or more controllers of the vehicle and/or to a higher-level computer system (12).

2. The electronic fuse (1, 825) according to feature 1,
wherein such a parameter is a directly accessible parameter, such as the temperature value of the temperature of a temperature sensor, and/or the voltage value of a voltage of a node (26, 27, 28) within the fuse (1) against a reference potential (201) and/or the voltage value of a voltage of a node of the supply network (200) against a reference potential (201) and/or the value of an electrical current (29) in a supply line section of the connected supply network (820).

3. The electronic fuse (1, 825) according to feature 1 or 2,
wherein the computer core (2) of the control device (4) of the electronic fuse (1) is configured,
in particular by applying Kirchhoff equations to data,
which the control device (4) of the electronic fuse has determined (by means of measuring devices of this electronic fuse (1, 825), and/or
which the control device (4) of this electronic fuse (1, 825) has received from the control devices (4) of other electronic fuses (805) or from higher-level controllers (12), for example a higher-level computer system (12),
to detect and/or determine derived parameters, such as leakage currents against other electrical nodes in the vehicle or electrical resistances of supply voltage line sections.

4. The electronic fuse (1, 805) according to feature 2 or 3,
wherein the control device (4) of the electronic fuse (1, 825) and/or the computer core (2) of the control device (4) of the electronic fuse (1, 825) are configured to estimate the temperature value of the temperature of a downstream supply line section,
if its ohmic resistance and its heat capacity and its thermal leakage resistances and the ambient temperature in the region of the supply line section are known approximately to the control device (4) of the electronic fuse (1, 825) and/or to the computer core (2) of the control device (4) of the electronic fuse (1, 825), for example by estimation of the control device (4) of the electronic fuse (1, 825).
   Electronic Fuse with Output Control

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the fuse (1) is connected via a data interface (10, 610, 551) to a higher-level computer system (12) and where applicable to one or more further electronic fuses (1, 214 to 217, 225 to 223, 230 to 235, 225 to 256), and
wherein the control device (4) of the electronic fuse (1, 825) is configured to determine, by means of a voltage measuring device (16), the voltage value of the voltage of a node (22, 25, 21) on the circuit breaker (17) of the electronic fuse (1, 825) and/or of a node (25) associated therewith relative to a reference potential (201), and
wherein the control device (4) of the electronic fuse (1, 825) is configured to determine the value of the current (29) through the circuit breaker (17) of the electronic fuse (1, 825), and
wherein the control device (4) of the electronic fuse or a higher-level computer system (12) is configured to determine from the current value and the voltage value an output value of the electrical output flowing into the load or into a downstream supply tree (815, 820) or the electrical output flowing into a downstream supply line section, and
wherein the control device (4) of the electronic fuse (825) and/or the higher-level computer system (12) in cooperation with the control device (4) are configured to open the circuit breaker (17) of the electronic fuse (825) if the magnitude of this output value of the supplied output exceeds a power feed threshold value.

2. The electronic fuse (1), in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the fuse (1) is connected via a data interface (10, 610, 551) to a higher-level computer system (12) and where applicable to one or more further electronic fuses (1, 214 to 217, 225 to 223, 230 to 235, 225 to 256), and
wherein the control device (4) of the electronic fuse (1, 825) is configured to determine the voltage value of the voltage of a node (22, 25, 21) on the circuit breaker (17) of the electronic fuse (1, 805) or a node associated therewith relative to a reference potential (201) by means of a voltage measuring device, and wherein the control device (4) of the electronic fuse (1, 825) is configured to determine the value of the current (29) through the circuit breaker (17) of the electronic fuse (1, 825), and
wherein the control device (4) of the electronic fuse (1, 825) or a higher-level computer system (12) is configured to determine from the current value and the voltage value the output value of the electrical output flowing from the power source or from an upstream supply tree or from an upstream supply line section, and wherein the control device (4) of the electronic fuse (825) and/or the higher-level computer system (12) in cooperation with the control device (4) are configured to open the circuit breaker (17) of the electronic fuse (825) if the value of this drawn output exceeds a power extraction threshold value.

3. The electro nic fuse (1, 805) according to feature 1 or 2,
wherein the control device (4) of the electronic fuse (1, 805) is configured to transmit this output value via the fuse data bus (9) to the control device (4) of a different electronic fuse (825) and/or to the higher-level computer system (12).

4. The electronic fuse (1) according to feature 3,
wherein the higher-level computer system (12) is a server (750) of a power provider or of one of its subcontractors and/or the server (710) of a service provider or of an automobile manufacturer.
   Electronic Fuse with Timer

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters and to determine therefrom a value for an electrical current (29) through the circuit breaker (17) between the first terminal (26) of the circuit breaker (17) and the second terminal (28) of the circuit breaker (28).
wherein the fuse (1) is connected via a data interface (10, 610, 551) to a higher-level computer system (12) and optionally to one or more further electronic fuses (1, 214 to 217, 225 to 223, 230 to 235, 225 to 256), and
wherein the control device (4) of the electronic fuse (1, 825) has a clock or a timer (35), in particular for generating time stamps of a log table.

2. The electronic fuse (1, 825) according to feature 1,
wherein the clock or the timer (35) of the control device (4) of the electronic fuse (1, 825) has a synchronization option with the clocks and timers (35) of the control devices (4) of other electronic fuses (805, 810) and/or with the clocks and timers (1970) of a higher-level computer system (12).

3. The electronic fuse (1, 825) according to feature 1 or 2,
wherein the control device (4) of the electronic fuse (1) is configured to switch off the circuit breaker (17) of the fuse (1) after receiving a switch-off signal via a fuse data bus (9) only after a switch-off delay time has elapsed.

4. The electronic fuse (1, 825) according to feature 3,
wherein the switch-off delay time
   depends on the value of the electrical current (29) through the circuit breaker (17) and/or
   on the magnitude of the power feed into the downstream supply sub-network and/or into the downstream supply line section or into a downstream load and/or
   on the magnitude of the power extraction from the upstream supply sub-network and/or in the upstream supply line section or from an upstream power source.

5. The electronic fuse (1, 825) according to feature 4,
wherein the switch-off delay time depends on the value of the electrical current (29) through the circuit breaker (17) such that it drops in a parabolic manner when the value of the electrical current (29) through the circuit breaker (17) increases.
   Electronic Fuse with Power Output and Power Extraction Control

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters and to determine therefrom a value for an electrical current (29) through the circuit breaker (17) between the first terminal (26) of the circuit breaker (17) and the second terminal (28) of the circuit breaker (28).
wherein the fuse (1) is connected via a data interface (10, 610, 551) to a higher-level computer system (12) and optionally to one or more further electronic fuses (1, 214 to 217, 225 to 223, 230 to 235, 225 to 256), and
wherein the control device (4) of the electronic fuse (1) is configured to switch off the circuit breaker (17) of the fuse (1), in particular immediately,
   if the value of the electrical current (29) through the circuit breaker (17) of the electronic fuse (1, 825) exceeds a current threshold value, and/or
   if the magnitude of the power feed into the downstream supply sub-network and/or into the downstream supply line section and/or into a downstream load exceeds a power feed threshold value, and/or
   if the magnitude of the power extraction from the upstream supply sub-network and/or from the upstream supply line section or from an upstream power source exceeds a power extraction threshold value.

2. The electronic fuse (1), in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters and to determine therefrom a value for an electrical current (29) through the circuit breaker (17) between the first terminal (26) of the circuit breaker (17) and the second terminal (28) of the circuit breaker (28).
wherein the fuse (1) is connected via a data interface (10, 610, 551) to a higher-level computer system (12) and optionally to one or more further electronic fuses (1, 214 to 217, 225 to 223, 230 to 235, 225 to 256), and
wherein the control device (4) of the electronic fuse (1, 825) is configured to emulate the behavior of a melting fuse in cooperation with the circuit breaker (17).

3. The electronic fuse (1, 825) according to feature 2,
wherein the control device (4) of the electronic fuse (1, 825) is configured to detect and/or determine the value of the electrical current (29) through the circuit breaker (17), and
wherein the control device (4) of the electronic fuse (1, 825) is configured to square the detected value of the electrical current (29) through the circuit breaker (17), and
wherein the control device (4) of the electronic fuse (1, 825) is configured to integrate the detected and squared value of the electrical current (29) through the circuit breaker (17) over time, and wherein the control device (4) of the electronic fuse (1, 825) is configured to filter, in particular via low-pass filtering, the detected and squared value of the electrical current (29) that is integrated over time, and
wherein the control device (4) of the electronic fuse (1, 825) is configured to compare the detected and squared and filtered value of the electrical current (29) with a threshold value, and
wherein the control device (4) is configured to set the switching state of the circuit breaker (17) of the electronic fuse (1, 825), at least at times, depending on the result of this comparison.

4. The electronic fuse (1, 825) according to feature 2 and/or 3,
wherein the control device (4) of the electronic fuse (1, 825) is configured to detect and/or determine the value of the electrical current (29) through the circuit breaker (17), and
wherein the control device (4) of the electronic fuse (1, 825) is configured to convert the detected value of the electrical current (29) through the circuit breaker (17) by means of a polynomial having an order of the polynomial greater than one into a mapped value, and
wherein the control device (4) of the electronic fuse (1, 825) is configured to integrate this mapped value of the electrical current (29) through the circuit breaker (17) over time, and
wherein the control device (4) of the electronic fuse (1, 825) is configured to filter, in particular via low-pass filtering, the mapped value of the electrical current (29) that is integrated over time, and
wherein the control device (4) of the electronic fuse (1, 825) is configured to compare the mapped and filtered value of the electrical current (29) to a threshold value, and
wherein the control device (4) of the electronic fuse (1, 825) is configured to set the switching state of the circuit breaker (17) of the electronic fuse (1, 825), at least at times, depending on the result of this comparison.
   Electronic Fuse with Power Sink for Feedback Power

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the fuse (1) is connected via a data interface (10, 610, 551) to a higher-level computer system (12) and optionally to one or more further electronic fuses (1, 214 to 217, 225 to 223, 230 to 235, 225 to 256), and
wherein the electronic fuse (1, 825) and/or the control device (4) of the electronic fuse (1, 825) and/or the computer core (2) of the control device (4) of the fuse (1, 825) and/or the fuse (1) in cooperation with a higher-level computer system (12) are configured to allow the transport of electrical power, at least at times, from one or more power sources (250) to the load (835, 830), and
wherein the electronic fuse (1, 825) and/or the control device (4) of the electronic fuse (1, 825) and/or the computer core (2) of the control device (4) of the fuse (1, 825) and/or the fuse (1) in cooperation with a higher-level computer system (12) are configured to prevent the transport of electrical power from the load (835, 830) to one or more or all of the power sources (250).

2. The electronic fuse (1, 825) according to feature 1,
wherein the electronic fuse (1, 825) comprises means (24, 23) for detecting the direction of the electrical current (29) through the circuit breaker (17), and
wherein the control device (4) of the electronic fuse (1, 825) is configured to detect the direction of the flowing electrical current (29) with the aid of these means (24, 23).

3. The electronic fuse (1, 805) according to feature 2,
wherein the electronic fuse (1, 825) and/or the control device (4) of the electronic fuse (1, 825) and/or the computer core (2) of the control device (4) of the fuse (1, 825) and/or the fuse (1) in cooperation with a higher-level computer system (12) are configured to open the circuit breaker (17) of the fuse (1, 825) if the electrical current (29) from the load (830) to one or more power sources (250) flows through the circuit breaker (17) of the electronic fuse (1, 825).

4. The electronic fuse (1, 825) according to feature 3,
wherein the control device (4) of the electronic fuse (1, 825) and/or the fuse (1, 825) comprises a third circuit breaker (615) which is different from the circuit breaker (17) of the electronic fuse (1, 825), and
wherein the electronic fuse (1, 825) and/or the control device (4) of the electronic fuse (1, 825) and/or the computer core (2) of the control device (4) of the fuse (1, 825) and/or the fuse (1) in cooperation with a higher-level computer system (12) are configured to close this third circuit breaker (615) if the electrical current (29) from the load (835) to one or more power sources (250) flows through the circuit breaker (17) of the electronic fuse (1, 825), and
this third circuit breaker (615) is configured to divert the electrical current (29) from the load (835) into a current sink, in particular a reference potential line (201), if the third circuit breaker (615) is closed.
   Electronic Fuse with Switchability Detection

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the fuse (1) is connected via a data interface (10, 610, 551) to a higher-level computer system (12) and optionally to one or more further electronic fuses (1, 214 to 217, 225 to 223, 230 to 235, 225 to 256), and
wherein the electronic fuse (1) comprises means for detecting the switchability of the circuit breaker (17) of the electronic fuse (1).

2. The electronic fuse (1) according to feature 1,
wherein the control device (4) of the electronic fuse (1) and/or the electronic fuse (1) comprise a first test current source (505), and
wherein the control device (4) of the electronic fuse (1) and/or the electronic fuse (1) comprise a second test current source (905), and
wherein the control device (4) of the electronic fuse (1) is configured to control the first test current source (505) and the second test current source (905), and
wherein the first test current source (505) is configured to feed a test current (515) into the first terminal (26) of the circuit breaker (17) when prompted by the control device (4), and
wherein the second test current source (905) is configured to then remove the test current (915) from the second terminal (28) of the circuit breaker (17), and
wherein the second test current source (905) comprises means to detect the value of the extracted test current (915), and
wherein the control device (4) is configured to deduce an error of the circuit breaker (17) of the electronic fuse (1) if the second current source (905), contrary to expectations, does not correspond to a value of the test current (915) and/or time characteristic of the value of the test current (915) in accordance with an expected value interval for the value of this test current (915) and/or the expected time characteristic of the expected value interval for the time characteristic of the value of the test current (915).

3. The electronic fuse (1) according to feature 2,
wherein the control device (4) of the electronic fuse (1) is configured—in particular for test purposes—to change one or more times the switching state of the circuit breaker (17) and to test the switching state of the circuit breaker (17).
   Electronic Fuse with Pattern Recognition and Arc Detection

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the fuse (1) is connected via a data interface (10, 610, 551) to a higher-level computer system (12) and where applicable to one or more further electronic fuses (1, 214 to 217, 225 to 223, 230 to 235, 225 to 256).
wherein the computer core (2) of the control device (4) of the electronic fuse (1) is configured to determine measured values—in particular, physical parameters and/or currents and/or voltages within the fuse (1)—by means of measuring means of the electronic fuse (1), and
wherein the computer core (2) of the control device (4) is configured to implement a neural network model, and
wherein the computer core (2) of the control device (4) is configured to use the determined measured values as input values of this neural network model, and
wherein the switching state of the circuit breaker (17) of the electronic fuse (1) and/or at least one data message and/or the content of a data message of the computer core (2) of the control device (4) of the electronic fuse (1) depends on an output signal of the neural network model, and
wherein the data message (9) is a data message (9) via the data bus (9)
   to a higher-level computer system (12) and/or
   to a computer core (2) of a different control device (4) of a different electronic fuse (805).

2. The electronic fuse (1) according to feature 1,
wherein the neural network model is trained with suitable training data from the development time of the electronic fuse (1).

3. The electronic fuse (1, 825) according to feature 1 or 2,
wherein the control device (4) of the electronic fuse (1, 825) is configured to detect a failure of one or more loads (835) or a failure of one or more power sources (250) or another defect of the system of the overall device of the supply network 200 by means of an output signal of the neural network model.
   Electronic Fuse with Power-Line Communication Via the Circuit Breaker

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the fuse (1) is connected via a data interface (10, 610, 551) to a higher-level computer system (12) and optionally to one or more further electronic fuses (1, 214 to 217, 225 to 223, 230 to 235, 225 to 256), and
wherein the control device (4) of the electronic fuse (1, 825) is configured to exchange data with a different computer system (12) and/or the control device (4) of a different electronic fuse (805) via a supply voltage line (6, 241, 242, 245).

2. The electronic fuse (1, 825) according to feature 1,
wherein the control device (4) of the electronic fuse (1) is configured to use the circuit breaker (17) of the electronic fuse (1, 825) as a transmitting transistor for data communication via the supply network (200).

3. The electronic fuse (1, 825) according to feature 2,
wherein the control device (4) of the electronic fuse (1) is configured to open the circuit breaker (17) of the electronic fuse (1, 825) in order to transmit a bit having a first logic value via the supply network (200).

4. The electronic fuse (1, 825) according to feature 2 or 3,
wherein the control device (4) of the electronic fuse (1) is configured to close the circuit breaker (17) of the electronic fuse (1, 825) in order to transmit a bit having a second logic value, which is different from the first logic value, via the supply network (200).

5. The electronic fuse (1, 825) according to any of features 2 to 4,
wherein the fuse comprises a second power reserve, and
wherein the second power reserve is configured to feed a current into the second terminal (19) of the fuse (1) at the second terminal (19) of the fuse for the duration of the transmission of a bit of a first logic value via the supply network (200), which current, instead of the current (29) through the circuit breaker (17), supplies electrical power to downstream supply sub-networks and/or loads of the supply network (200).

6. The electronic fuse (1, 825) according to any of features 2 to 5,
wherein the control device (4) of the fuse (1) is configured to detect and/or determine values of the current (29) through the circuit breaker (17), and
wherein the control device (4) of the fuse (1) is configured to extract data from the time characteristic of the values of the current (29) through the circuit breaker (17), which data the control device (4) of a different fuse (1) transmits via the supply network (200), in particular by means of the circuit breaker (17).
   Electronic Fuse with Rapid Shutdown of the Circuit Breaker

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the electronic fuse (1, 825) comprises means for detecting the time characteristic of the electrical current (29) through the circuit breaker (17) of the electronic fuse (1), and
wherein these means are configured to detect, at least at times, the time characteristic of the electrical current (29) through the circuit breaker (17) of the electronic fuse (1, 825), and
wherein these means can comprise an analog-to-digital converter (570) of the control device (4) of the electronic fuse (1, 825) and/or a memory of the computer core (2) of the control device (4) of the electronic fuse (1, 825).

2. The electronic fuse (1, 825), in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the electronic fuse (1, 825) comprises means for detecting the time characteristic of the voltage between a terminal (26, 27, 28) of the circuit breaker (17) of the electronic fuse (1, 825) and a reference potential (201), and
wherein these means are configured to detect, at least at times, the time characteristic of the voltage between a terminal (26, 27, 28) of the circuit breaker (17) of the electronic fuse (1, 825) and a reference potential (201).

3. The electronic fuse (1), in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the electronic fuse (1, 825) comprises means for detecting the time characteristic of the voltage between a terminal (26, 27, 25) of the auxiliary circuit breaker (23) of the electronic fuse (1, 825) and a reference potential (201), and
wherein these means are configured to detect, at least at times, the time characteristic of the voltage between a terminal (26, 27, 25) of the auxiliary circuit breaker (23) of the electronic fuse (1, 825) and a reference potential (201).

4. The electronic fuse (1), in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the electronic fuse (1, 825) comprises means for detecting the time characteristic of the voltage between a first terminal (25) of a shunt resistor (24) of the electronic fuse (1, 825) and a second terminal (21) of the shunt resistor (24) of the electronic fuse (1, 825), and
wherein these means are configured to detect, at least at times, the time characteristic of the voltage between a first terminal (25) of a shunt resistor (24) of the electronic fuse (1, 825) and a second terminal (21) of the shunt resistor (24) of the electronic fuse (1, 825).

5. The electronic fuse (1), in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the control device (4) of the electronic fuse (1) is configured to carry out a spectral analysis of the data of the time characteristics, for example by Fourier or Laplace transform or wavelet transform, and thus to determine values of the spectrum, and
wherein the control device (4) of the electronic fuse (1) is configured, in the event of substantial deviations of the values of this spectrum from expected value intervals, to deduce the necessity of preventive maintenance and/or to carry out a signaling to a higher-level computer system (12).

6. The electronic fuse (1), in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the electronic fuse (1, 925) comprises means for detecting the value of the electrical current (29) through the circuit breaker (17) of the electronic fuse (1, 825) and for detecting a voltage at a terminal (26, 27, 28) of the circuit breaker (17) of the electronic fuse (1, 825) against a reference potential (201), and
wherein the control device (4) of the electronic fuse (1, 825) is configured,
   in the event of a voltage drop in the measured voltage values, and,
   when there is a simultaneous increase in current,
to switch off the circuit breaker (17) of the electronic fuse (1, 825),
if a) the measured voltage value falls below a voltage threshold value and if the measured current value at the same time exceeds a current threshold value, and/or
if b) the temporal rate of change of the measured voltage value drop between a terminal (26, 27, 28) of the circuit breaker 17 of the fuse (1, 825) and a reference potential (201) exceeds a voltage drop rate of change threshold, and at the same time the rate of change in the electrical current 29 through the circuit breaker 17 exceeds a current increase rate threshold.

7. The electronic fuse (1, 825) according to feature 6,
wherein the control device (4) of the electronic fuse (1, 825) is configured to switch off the circuit breaker (17) of the electronic fuse (1, 825) faster than within 1 μs under such switch-off conditions.

### Emergengy Control of a First Electronic Fuse by a Second Electronic Fuse

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the electronic fuse (1, 825) comprises an emergency control (925) and
wherein the emergency control (925) is configured to transmit data via a data bus (540, 9) and to receive it via this data bus (9, 540), and
wherein the electronic fuse (1, 825) is configured such that the control device (4) of the electronic fuse (1, 825) is and/or can be under certain conditions a further control device (4) of a different electronic fuse (805), and
wherein the further control device (4) of the other electronic fuse (805) is configured to control the electronic fuse (825) by means of data communication via the data bus (9, 540) and by means of the emergency control (925) of the electronic fuse (825).

2. The electronic fuse (1, 825) according to feature 1,
wherein the emergency control (925) of the fuse (825) is configured to monitor the data communication between the control device (4) of the fuse (825) and the emergency control (925) of the other fuse (805), and

3. The electronic fuse (1, 825) according to feature 1 or 2,
wherein the emergency control (925) of the fuse (1, 825) is configured to emulate simple functions of the control device (4) of the fuse (1, 825) in the event of a failure of the data communication of the fuse (1, 825) and optionally to ensure at least basic protection of the connected supply line (19, 815, 820) by in this case taking control of the circuit breaker (17) of the fuse (1, 825).
   Electronic Fuse with Specific Data Transmission

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the fuse (1) is connected via a data interface (10, 610, 551) to a higher-level computer system (12) and optionally to one or more further electronic fuses (1, 214 to 217, 225 to 223, 230 to 235, 225 to 256), and
wherein the computer core (2) of the control device (4) of the electronic fuse (1, 825) is configured to transmit a signal to the higher-level computer system (12) via a fuse data bus (9, 540), which signal indicates:
a) the corresponding electronic fuse (1, 825) is still present, and/or
b) the corresponding electronic fuse (1, 825) is ready to operate, and/or
the fuse identification information which the fuse (1, 825) has and/or
the valid fuse address which the fuse (1, 825) has and/or
whether the fuse (1, 825) has a valid fuse address of the fuse (1, 825), and/or
the threshold values which the fuse (1, 825) uses and/or
the measured current value for the current (29) through the power transistor (17) which the control device (4) of the fuse (1, 825) has determined and/or
the measured current value for the current (36) through the shunt resistor (24) which the control device (4) of the fuse (1, 825) has determined and/or
the voltage values of the voltages relative to the reference potential (201) and/or to other nodes within the fuse (1, 825) which the control device (4) of the fuse (1, 825) has determined and/or
the power output via the second terminal (19) which the control device (4) of the fuse (1, 825) has determined, and/or
the temperature value which the control device (4) of the fuse (1, 825) has determined and/or
the time stamp value of an also transmitted value which the control device (4) of the fuse (1, 825) has stored and/or
the other operating parameters which the electronic fuse (1, 825) has.
   Electronic Fuse with Quantum Random Number Generator

1. The electronic fuse (1, 825) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the electronic fuse (1, 825) comprises a quantum random number generator (60, 4100), and
wherein the quantum random number generator (60, 4100) comprises the following device parts:
a first SPAD diode (4104.1)
a second SPAD diode (4104.3),
an optical waveguide (4104.2) optically coupling the first SPAD diode (4104.1) and the second SPAD
diode (4104.3) to one another,
an amplifier (4103) and/or filter,
an analog-to-digital converter (4103),
a comparator (4104.2),
a time-to-digital converter (4104.3),
an entropy extraction device (4104.4) that converts output values of the time-to-digital converter (4103) into first and second values and generates random bits (4111) therefrom.

2. The electronic fuse (1, 825) according to feature 1,
wherein the electronic fuse (1, 825) comprises a watchdog (4104.5) which is configured to monitor device parts of the quantum random number generator (60, 4100).

3. The electronic fuse (1, 825) according to feature 1 or 2,
wherein the electronic fuse (1, 825) has a voltage monitor (4113) which is configured to detect and monitor analog values of analog signals.

4. The electronic fuse (1, 825) according to any of features 1 to 3,
wherein the device comprises a pseudo-random number generator (4104.6), in particular in the form of a linear-feedback shift register (4104.6).

5. The electronic fuse (1, 825) according to any of features 1 to 4,
wherein the electronic fuse (1, 825) comprises a signal multiplexer (4104.7) which, in the event of an error from the signal of the output (4111) of the entropy extraction device (4104.4), switches to a signal of a replacement random number generator (60) or a signal (4117) of a replacement pseudo-random number generator (4104.6).

6. The electronic fuse (1, 825) according to any of features 1 to 5,
wherein the starting value of the pseudo-random number generator (4104.6) depends in the event of an error on previously correctly generated random bits (4111) of the quantum random number generator (4100, 60).

7. The electronic fuse (1, 825), in particular according to one or more of the preceding features,
which is configured to implement the following method for generating a random bit (4111): generating a pulse sequence (4106) with random time intervals by means of at least two SPAD diodes (3954, 3955, 4101.1, 4101.3),
wherein the pulse sequence (4106) comprises pulses of a first height class (4401) and a second height class (4402);
separating the pulses of the first height class (4401) from the pulses of the second height class (4402) by means of a cutoff level (4403, 4104.1);
detecting (4301) a first value (4110) of the time interval between a first pulse of the second height class (4402) and a second pulse of the second height class (4402), which is different from the first pulse; detecting (4301) a second value (4110) of the time interval between a third pulse of the second height class (4402), which is different from the first pulse, and a fourth pulse of the second height class (4402), which is different from the first pulse and from the second pulse and from the third pulse.
comparing (4302) the first value to the second value, and
outputting (4303) a first logic value as a random bit (4111) if the first value is greater than the second value, and
outputting (4303) a second logic value, which is different from the first logic value, as the random bit (4111) if the first value is less than the second value.

8. A higher-level computer system (12) of a supply network (200) with electronic fuses, in particular according to one or more of the preceding features, which is configured to execute the following method for generating a random bit (4111):
generating a pulse sequence (4106) with random time intervals by means of at least two SPAD diodes (3954, 3955, 4101.1, 4101.3),
wherein the pulse sequence (4106) comprises pulses of a first height class (4401) and a second height class (4402);
separating the pulses of the first height class (4401) from the pulses of the second height class (4402) by means of a cutoff level (4403, 4104.1);
detecting (4301) a first value (4110) of the time interval between a first pulse of the second height class (4402) and a second pulse of the second height class (4402), which is different from the first pulse;
detecting (4301) a second value (4110) of the time interval between a third pulse of the second height class (4402), which is different from the first pulse, and a fourth pulse of the second height class (4402), which is different from the first pulse and from the second pulse and from the third pulse.
comparing (4302) the first value to the second value, and
outputting (4303) a first logic value as a random bit (4111) if the first value is greater than the second value, and
outputting (4303) a second logic value, which is different from the first logic value, as the random bit (4111) if the first value is less than the second value.
   Electronic Fuse with Key Generation and Key Exchange

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the fuse (1) is connected via a data interface (10, 610, 551) to a higher-level computer system (12) and optionally to one or more further electronic fuses (1, 214 to 217, 225 to 223, 230 to 235, 225 to 256), and
wherein the fuse (1) and/or the control device (4) of the fuse (1) comprises a random number generator (60).

2. The electronic fuse (1, 825) according to feature 1,
wherein the random number generator (60) is a true random number generator (TRNG).

3. The electronic fuse (1, 825) according to feature 2,
wherein the random number generator (60) is a quantum random number generator (QRNG).

4. The electronic fuse (1, 825) according to feature 3,
wherein the quantum random number generator (QRNG) (60) comprises a first SPAD diode (3954, 4101.1) which can itself in turn comprise a plurality of first SPAD diodes (3954, 4101.1), and
wherein the quantum random number generator (QRNG) (60) comprises a second SPAD diode (3955, 4101.3), which can itself in turn comprise a plurality of second SPAD diodes (3955, 4101.3), and
wherein the quantum random number generator (QRNG) (60) comprises an optical waveguide (3944, 4101.2), and
wherein the voltage supply (5) of the control device (4) of the fuse (1, 825) is configured to bias the first SPAD diode (3954, 4101.1) in the reverse direction with a diode bias, and
wherein the voltage supply (5) of the control device (4) of the fuse (1, 825) is configured to bias the second SPAD diode (3955, 4101.3) in the reverse direction with a diode bias, and
wherein the first SPAD diode (3954, 4101.1) has the property of feeding random light pulses into the optical waveguide (3944, 4101.2) when there is biasing with the diode bias in the reverse direction, and
wherein the optical waveguide is configured to irradiate the second SPAD diode (3955, 4104.3) with light of these light pulses, and
wherein the second SPAD diode (5955, 4104.3) has the property of generating a diode current of the second SPAD diode in the form of signals of the current pulses (4105) when there is biasing with the diode bias in the reverse direction, which signals first comprise random current pulses of a first current pulse height and which signals secondly comprise current pulses of a second current pulse height, which are based on the reception of photons of the light pulses of the second SPAD diode (3955, 4101.3), and
wherein the second current pulse height is higher than the first current pulse height, and
wherein further device parts (4102, 4103, 4104.2, 4104.1) of the quantum random number generator (QRNG) (60) are configured to separate the signals of the current pulses (4105) at the second current pulse height from the signals of the current pulses (4105) at the first current pulse height and generate a cleaned pulse signal (4109), and
wherein further device parts of the quantum random number generator (QRNG)(60) detect the time interval between pulse pairs of two successive pulses of the cleaned pulse signal and generate time interval values therefrom, and
wherein further device parts of the quantum random number generator (QRNG) (60) compare two different time interval values of two different pulse pairs, a first time interval value and a second time interval value, and generate a random bit having a first logic value if the first time interval value is less than the second time interval value, and generate the random bit having a second logic value if the first time interval value is greater than the second time interval value, and
wherein further device parts of the quantum random number generator (QRNG) (60) generate a random number from a plurality of these random bits.

4. The electronic fuse (1, 825) according to feature 3,
wherein device parts of the quantum random number generator (QRNG) (60) are configured to discard and no longer use time interval values that are smaller than a minimum time interval value.

5. The electronic fuse (1, 825) according to feature 3 or 4,
wherein the first SPAD diode and the second SPAD diode are manufactured in a common silicon crystal as part of a microelectronic circuit in CMOS technology, and
wherein the optical waveguide in the metallization stack microelectronic circuit is made of optically transparent insulation layers on the surface of the silicon crystal.

6. The electronic fuse (1, 825) according to any of features 1 to 5,
wherein the control device (4) of the fuse (1, 825) and/or the computer core (2) of the control device (4) of the fuse (1, 825) are configured to encrypt data for the data communication via the data bus (9) using a random number of the random number generator (60).

7. The electronic fuse (1, 825) according to feature 6,
wherein the control device (4) of the fuse (1, 825) and/or the computer core (2) of the control device (4) of the fuse (1, 825) are configured to generate a key pair made up of a private key and a public key using a random number of the random number generator (60).

8. The electronic fuse (1, 825) according to feature 7,
wherein the control device (4) of the fuse (1, 825) and/or the computer core (2) of the control device (4) of the fuse (1, 825) are configured to transmit the public key to a control device (4) of a different fuse (805) and/or to a computer core (2) of a control device (4) of a different fuse (805) and/or to a higher-level computer system (12).

9. The electronic fuse (1, 825) according to feature 8,
wherein the control device (4) of the fuse (1, 825) and/or the computer core (2) of the control device (4) of the fuse (1, 825) is configured to decrypt, with the aid of the private key, data messages of a control device (4) of a different fuse (805) and/or of a computer core (2) of a control device (4) of a different fuse (805) and/or of a higher-level computer system (12) which the control device (4) of the fuse (1, 825) and/or the computer core (2) of the control device (4) of the fuse (1, 825) receive via the data bus (9).

10. The electronic fuse (1, 825) according to any of features 1 to 9,
wherein the control device (4) of the fuse (1, 825) and/or the computer core (2) of the control device (4) of the fuse (1, 825) are configured to receive a public key of a control device (4) of a different fuse (805) and/or of a computer core (2) of a control device (4) of a different fuse (805) and/or of a higher-level computer system (12).

9. The electronic fuse (1, 825) according to any of features 1 to 8,
wherein the control device (4) of the fuse (1, 825) and/or the computer core (2) of the control device (4) of the fuse (1, 825) are configured to exchange public keys with a different fuse (805) and/or with a computer core (2) of a control device (4) of a different fuse (805) and/or with a higher-level computer system (12) by means of a Diffie-Hellman key exchange method.

10. The electronic fuse (1, 825) according to feature 9,
wherein the control device (4) of the fuse (1, 825) and/or the computer core (2) of the control device (4) of the fuse (1, 825) are configured to decrypt data messages of a control device (4) of a different fuse (805) and/or of a computer core (2) of a control device (4) of a different fuse (805) and/or of a higher-level computer system (12), which data messages the control device (4) of the fuse (1, 825) and/or the computer core (2) of the control device (4) of the fuse (1, 825) receive via the data bus (9) with the aid of the private key of the Diffie-Hellman key exchange method.

11. The electronic fuse (1, 825) according to any of features 8 to 10,
wherein the control device (4) of the fuse (1, 825) and/or the computer core (2) of the control device (4) of the fuse (1, 825) are configured to encrypt data messages by means of a received public key to form encrypted data messages.

12. The electronic fuse (1, 825) according to feature 11,
wherein the control device (4) of the fuse (1, 825) and/or the computer core (2) of the control device (4) of the fuse (1, 825) are configured to encrypt data messages by means of a PQC encryption method and/or by means of an RSA method to form encrypted data messages.

13. The electronic fuse (1, 825) according to feature 12,
wherein the control device (4) of the fuse (1, 825) and/or the computer core (2) of the control device (4) of the fuse (1, 825) are configured to transmit such encrypted data messages to a control device (4) of a different fuse (805) and/or to a computer core (2) of a control device (4) of a different fuse (805) and/or to a higher-level computer system (12) via the data bus (9).
   Electronic Fuse with PQC Encryption

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the fuse (1) is connected via a data interface (10, 610, 551) to a higher-level computer system (12) and optionally to one or more further electronic fuses (1, 214 to 217, 225 to 223, 230 to 235, 225 to 256), and
wherein the control device (4) of the fuse (1, 825) and/or the computer core (2) of the control device (4) of the fuse (1, 825) are configured to encrypt data for the data communication via the data bus (9) using a random number.

2. The electronic fuse (1, 825) according to feature 1,
wherein the control device (4) of the fuse (1, 825) and/or the computer core (2) of the control device (4) of the fuse (1, 825) are configured to generate a key pair made up of a private key and a public key using the random number.

3. The electronic fuse (1, 825) according to feature 2,
wherein the control device (4) of the fuse (1, 825) and/or the computer core (2) of the control device (4) of the fuse (1, 825) are configured to transmit the public key to a control device (4) of a different fuse (805) and/or to a computer core (2) of a control device (4) of a different fuse (805) and/or to a higher-level computer system (12).

4. The electronic fuse (1, 825) according to feature 3,
wherein the control device (4) of the fuse (1, 825) and/or the computer core (2) of the control device (4) of the fuse (1, 825) is configured to decrypt, with the aid of the private key, data messages of a control device (4) of a different fuse (805) and/or of a computer core (2) of a control device (4) of a different fuse (805) and/or of a higher-level computer system (12) which the control device (4) of the fuse (1, 825) and/or the computer core (2) of the control device (4) of the fuse (1, 825) receive via the data bus (9).

5. The electronic fuse (1, 825) according to any of features 1 to 4,
wherein the control device (4) of the fuse (1, 825) and/or the computer core (2) of the control device (4) of the fuse (1, 825) are configured to receive a public key of a control device (4) of a different fuse (805) and/or of a computer core (2) of a control device (4) of a different fuse (805) and/or of a higher-level computer system (12).

6. The electronic fuse (1, 825) according to any of features 1 to 5,
wherein the control device (4) of the fuse (1, 825) and/or the computer core (2) of the control device (4) of the fuse (1, 825) are configured to exchange public keys with a different fuse (805) and/or with a computer core (2) of a control device (4) of a different fuse (805) and/or with a higher-level computer system (12) by means of a Diffie-Hellman key exchange method.

7. The electronic fuse (1, 825) according to feature 6,
wherein the control device (4) of the fuse (1, 825) and/or the computer core (2) of the control device (4) of the fuse (1, 825) are configured to decrypt data messages of a control device (4) of a different fuse (805) and/or of a computer core (2) of a control device (4) of a different fuse (805) and/or of a higher-level computer system (12), which data messages the control device (4) of the fuse (1, 825) and/or the computer core (2) of the control device (4) of the fuse (1, 825) receive via the data bus (9) with the aid of the private key of the Diffie-Hellman key exchange method.

8. The electronic fuse (1, 825) according to any of features 5 to 7,
wherein the control device (4) of the fuse (1, 825) and/or the computer core (2) of the control device (4) of the fuse (1, 825) are configured to encrypt data messages by means of a received public key to form encrypted data messages.

9. The electronic fuse (1, 825) according to feature 8,
wherein the control device (4) of the fuse (1, 825) and/or the computer core (2) of the control device (4) of the fuse (1, 825) are configured to encrypt data messages by means of a PQC encryption method and/or by means of an RSA method to form encrypted data messages.

10. The electronic fuse (1, 825) according to feature 9,
wherein the control device (4) of the fuse (1, 825) and/or the computer core (2) of the control device (4) of the fuse (1, 825) are configured to transmit such encrypted data messages to a control device (4) of a different fuse (805) and/or to a computer core (2) of a control device (4) of a different fuse (805) and/or to a higher-level computer system (12) via the data bus (9).
   Electronic Fuse that Receives a Public Key

1. An electronic fuse (1) of a vehicle, in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the fuse (1) is connected via a data interface (10, 610, 551) to a higher-level computer system (12) and optionally to one or more further electronic fuses (1, 214 to 217, 225 to 223, 230 to 235, 225 to 256), and
wherein the control device (4) of the fuse (1, 825) and/or the computer core (2) of the control device (4) of the fuse (1, 825) are configured to receive a public key of a control device (4) of a different fuse (805) and/or of a computer core (2) of a control device (4) of a different fuse (805) and/or of a higher-level computer system (12).

2. The electronic fuse (1), in particular according to one or more of the preceding features,
wherein the electronic fuse (1) has a first terminal (18), and
wherein the electronic fuse (1) has a second terminal (19), and
wherein the electronic fuse (1) has a circuit breaker (17), and
wherein the electronic fuse (1) has a control device (4), and
wherein the circuit breaker (17) has a first terminal (26), a control terminal (27) and a second terminal (28), and
wherein the first terminal (26) of the circuit breaker (17) is electrically connected to the first terminal (18) of the fuse (1), and
wherein the second terminal (28) of the circuit breaker (17) is electrically connected to the second terminal (19) of the fuse (1), and
wherein the control terminal (27) of the circuit breaker (17) is electrically connected to the control device (4), and
wherein the control device (4) of the electronic fuse (1) is configured to detect voltages between the terminals (26, 27, 28) of the circuit breaker and/or functionally equivalent values of physical parameters, and therefrom to determine a value for an electrical current (29) through the circuit breaker (17) between the first terminal (26) of the circuit breaker (17) and the second terminal (28) of the circuit breaker (28), and
wherein the fuse (1) is connected via a data interface (10, 610, 551) to a higher-level computer system (12) and optionally to one or more further electronic fuses (1, 214 to 217, 225 to 223, 230 to 235, 225 to 256), and
wherein the control device (4) of the fuse (1, 825) and/or the computer core (2) of the control device (4) of the fuse (1, 825) are configured to exchange public keys with a different fuse (805) and/or with a computer core (2) of a control device (4) of a different fuse (805) and/or with a higher-level computer system (12) by means of a Diffie-Hellman key exchange method.

3. The electronic fuse (1, 825) according to feature 2,
wherein the control device (4) of the fuse (1, 825) and/or the computer core (2) of the control device (4) of the fuse (1, 825) are configured to decrypt data messages of a control device (4) of a different fuse (805) and/or of a computer core (2) of a control device (4) of a different fuse (805) and/or of a higher-level computer system (12), which data messages the control device (4) of the fuse (1, 825) and/or the computer core (2) of the control device (4) of the fuse (1, 825) receive via the data bus (9) with the aid of the private key of the Diffie-Hellman key exchange method.

3. The electronic fuse (1, 825) according to any of features 1 to 3,
wherein the control device (4) of the fuse (1, 825) and/or the computer core (2) of the control device (4) of the fuse (1, 825) are configured to encrypt data messages by means of a received public key to form encrypted data messages.

4. The electronic fuse (1, 825) according to feature 3,
wherein the control device (4) of the fuse (1, 825) and/or the computer core (2) of the control device (4) of the fuse (1, 825) are configured to encrypt data messages by means of a PQC encryption method and/or by means of an RSA method to form encrypted data messages.

5. The electronic fuse (1, 825) according to feature 4,
wherein the control device (4) of the fuse (1, 825) and/or the computer core (2) of the control device (4) of the fuse (1, 825) are configured to transmit such encrypted data messages to a control device (4) of a different fuse (805) and/or to a computer core (2) of a control device (4) of a different fuse (805) and/or to a higher-level computer system (12) via the data bus (9).

### Cross-Over Fuse and Associated Supply Network

1. A power-side cross-over fuse (1000) of a vehicle, in particular according to one or more of the preceding features,
wherein the cross-over fuse (1000) comprises a power-source-side first supply line section (1005) of a first supply line, and
wherein the cross-over fuse (1000) comprises a load-side second supply line section (1010) of a first supply line, and
wherein the cross-over fuse (1000) comprises a power-source-side first supply line section (1015) of a second supply line, and
wherein the cross-over fuse (1000) comprises a load-side second supply line section (1020) of a second supply line, and
wherein the cross-over fuse (1000) comprises a first electrical node (1025), and
wherein the cross-over fuse (1000) comprises a second electrical node (1030), and
wherein the cross-over fuse (1000) comprises a first electronic fuse (1035), and
wherein the cross-over fuse (1000) comprises a second electronic fuse (1040), and
wherein the cross-over fuse (1000) comprises a third electronic fuse (1045), and
wherein the cross-over fuse (1000) comprises a fourth electronic fuse (1050), and
wherein the first electronic fuse (1035) is configured, depending on the switching state of the circuit breaker (17) of the first electronic fuse (1035), to connect the power-source-side first supply line section (1005) of the first supply line to the first node (1025), or to disconnect the power-source-side first supply line section (1005) of the first supply line from the first node (1025), and
wherein the second electronic fuse (1040) is configured, depending on the switching state of the circuit breaker (17) of the second electronic fuse (1040), to connect the power-source-side first supply line section (1015) of the second supply line to the first node (1025), or to disconnect the power-source-side first supply line section (1015) of the second supply line from the first node (1025), and
wherein the second electronic fuse (1040) is configured not to connect the power-source-side first supply line section (1015)of the second supply line to the first node (1025)ifthe first electronic fuse (1035) connects the power-source-side first supply line section (1005) of the first supply line to the first node (1025), and
wherein the first electronic fuse (1035) is configured not to connect the power-source-side first supply line section (1005) of the first supply line to the first node (1025) if the second electronic fuse (1040) connects the power-source-side first supply line section (1015) of the second supply line to the first node (1025), and
wherein the third electronic fuse (1045) is configured, depending on the switching state of the circuit breaker (17) of the third electronic fuse (1045), to connect the power-source-side first supply line section (1005) of the first supply line to the second node (1030), or to disconnect the power-source-side first supply line section (1005) of the first supply line from the second node (1030), and
wherein the fourth electronic fuse (1050) is configured, depending on the switching state of the circuit breaker (17) of the fourth electronic fuse (1050), to connect the power-source-side first supply line section (1015) of the second supply line to the second node (1030), or to disconnect the power-source-side first supply line section (1015) of the second supply line from the second node (1030), and
wherein the fourth electronic fuse (1050) is configured not to connect the power-source-side first supply line section (1015) of the second supply line to the second node(1030)if the third electronic fuse (1045) connects the power-source-side first supply line section (1005) of the first supply line to the second node, and
wherein the third electronic fuse (1045) is configured not to connect the power-source-side first supply line section of the first supply line to the second node (1030) if the fourth electronic fuse (1050) connects the power-source-side first supply line section (1015) of the second supply line to the second node (1030), and
wherein the load-side second supply line section (1055) of the first supply line is connected to the first node (1025), and
wherein the load-side second supply line section (1060) of the second supply line is connected to the second node (1030).

2. The load-side cross-over fuse (1000) of a vehicle, in particular according to one or more of the preceding features,
wherein the cross-over fuse (1000) comprises a power-source-side first supply line section (1005) of a first supply line, and
wherein the cross-over fuse (1000) comprises a load-side second supply line section (1055) of a first supply line, and
wherein the cross-over fuse (1000) comprises a power-source-side first supply line section (1015) of a second supply line, and
wherein the cross-over fuse (1000) comprises a load-side second supply line section (1060) of a second supply line, and
wherein the cross-over fuse (1000) comprises a third electrical node (1065), and
wherein the cross-over fuse (1000) comprises a fourth electrical node (1070), and
wherein the cross-over fuse (1000) comprises a first electronic fuse (1035), and
wherein the cross-over fuse (1000) comprises a second electronic fuse (1040), and
wherein the cross-over fuse (1000) comprises a third electronic fuse (1045), and
wherein the cross-over fuse (1000) comprises a fourth electronic fuse (1050), and
wherein the first electronic fuse (1035) is configured, depending on the switching state of the circuit breaker (17) of the first electronic fuse (1035), to connect the load-side second supply line section (1055) of the first supply line to the third node (1065), or to disconnect the load-side second supply line section (1055) of the first supply line from the third node (1065), and
wherein the second electronic fuse (1040) is configured, depending on the switching state of the circuit breaker (17) of the second electronic fuse (1040), to connect the load-side second supply line section (1055) of the first supply line to the fourth node (1070), or to disconnect the load-side second supply line section (1055) of the first supply line from the fourth node (1070), and
wherein the second electronic fuse (1040) is configured not to connect the load-side second supply line section (1055) of the first supply line to the fourth node (1070) if the first electronic fuse (1035) connects the load-side second supply line section (1055) of the first supply line to the third node (1065), and
wherein the first electronic fuse (1035) is configured not to connect the load-side second supply line section (1055) of the first supply line to the third node if the second electronic fuse (1040) connects the load-side second supply line section of the first supply line to the fourth node (1070), and
wherein the third electronic fuse (1045) is configured, depending on the switching state of the circuit breaker (17) of the third electronic fuse (1045), to connect the load-side second supply line section (1060) of the second supply line to the third node (1065), or to disconnect the load-side second supply line section (1060) of the second supply line from the third node (1065), and
wherein the fourth electronic fuse (1050) is configured, depending on the switching state of the circuit breaker (17) of the fourth electronic fuse (1050), to connect the load-side second supply line section of the second supply line (1060) to the fourth node (1070), or to disconnect the load-side second supply line section (1060) of the second supply line from the fourth node (1070), and
wherein the fourth electronic fuse (1050) is configured not to connect the load-side second supply line section (1060) of the second supply line to the fourth node (1070) if the third electronic fuse (1045) connects the load-side second supply line section (1060) of the second supply line to the third node (1065), and
wherein the third electronic fuse (1045) is configured not to connect the load-side second supply line section (1060) of the second supply line to the third node (1065) if the fourth electronic fuse (1050) connects the load-side second supply line section (1060) of the second supply line to the fourth node (1070), and
wherein the power-source-side first supply line section (1005) of the first supply line is connected to the third node (1065), and
wherein the power-source-side first supply line section (1015) of the second supply line is connected to the fourth node (1070).

3. The cross-over fuse (1000) according to feature 1 or 2
wherein the switching state of the circuit breakers (17) of the electronic fuses (1035, 1040, 1045, 1050) of the cross-over fuse (1000)
depends on a determined power requirement of one or more loads (830, 835) and/or
depends on a determined power supply capacity of one or more power sources (250, 251).

4. The cross-over fuse (1000) according to feature 3,
wherein the control devices (4) of the electronic fuses (1035, 1040, 1045, 1050) of the cross-over fuse (1000) are connected to a higher-level computer system (12) and/or to one another via a fuse data bus (9), and
wherein the higher-level computer system (12) is configured to determine the power requirement of one or more loads (835, 830) via which the supply lines (1005, 1010. 1015, 1020, 1055, 1060) of the cross-over fuse (1000) can be supplied with electrical power, and/or
wherein the higher-level computer system (12) is configured to determine the power supply capacity of one or more power sources (250, 251), via which the supply lines (1005, 1010. 1015, 1020, 1055, 1060) of the cross-over fuse (1000) can supply electrical power, and
wherein the higher-level computer system (12) is configured to transmit configuration commands to the control devices (4) of the fuses (1035, 1040, 1045, 1050) of the cross-over fuse (1000) via the fuse data bus (9), which commands depend on the determined power requirement of these loads (830, 831) and/or which depend on the determined power supply capacity of these power sources (250, 251), and
wherein these configuration commands cause the opening and closing of circuit breakers (17) of the electronic fuses (1035, 1040, 1045, 1050) of the cross-over fuse (1000).

5. A supply network (1100), in particular according to one or more of the preceding features, comprising a higher-level computer system (12) and
a plurality of supply lines, and
a plurality of cross-over fuses (1110 to 1118),
wherein the cross-over fuses (1110 to 1118) are inserted into supply lines of the supply network (1100), and
wherein the higher-level computer system (12) is connected to control devices (4) of the electronic fuses of the cross-over fuses (1110 to 1118) by means of a fuse data bus (9), and
wherein the electronic fuses of the cross-over fuses (1110 to 1118) have control devices (4), and wherein electronic fuses (4) of a corresponding cross-over fuse (1110 to 1118) can also jointly have a common control device (4), and
wherein the higher-level computer system (12) is configured to determine the power requirement of electrical power loads (1121 to 1124) in the supply network (1100), and/or
wherein the higher-level computer system (12) is configured to determine the power supply capacity of electrical power sources (1150 to 1155) in the supply network (1100), and/or
wherein the higher-level computer system (12) is configured to determine the current safety requirement in particular on the basis of the current driving situation and/or the current operating state of the vehicle and/or properties of the surroundings of the vehicle, and
wherein the computer system (12) is configured, by means of configuration commands via the fuse data bus (9) to the cross-over fuses (1110 to 1118), to dynamically adjust the electrically effective topology of the supply network of the supply lines according to the determined power requirement and/or according to the determined power supply capacity and/or according to the current safety requirement, in particular on the basis of the current driving situation and/or the current operating state of the vehicle and/or properties of the surroundings of the vehicle.

### Flag-Controlled Electronic Fuse for a Power Load

1. The method (1200) for operating a supply network of a vehicle, in particular according to one or more of the preceding features, comprising the steps of:
providing (1210) a supply network (250, 251, 210 to 213, 245) having a device part of the vehicle, hereinafter referred to as a power-supplying device part (210),
wherein the power-supplying supply part (210) comprises a control device (280, 4), and
wherein the power-supplying supply part (210) comprises a memory in a first logic state; supplying (1220) the power-supplying device part (210) with electrical power from a power source (251, 250) of the vehicle;
connecting (1230) a first terminal of a further line section (240) to the power-supplying device part (210) of the vehicle;
connecting (1240) a second terminal of the further line section (240) to a further device part (220, 221) of the vehicle;
signaling (1250) a switch-on signal to the control device (280, 4) of the power-supplying device part (210);
changing (1260) the logic state of the memory to a second logic state depending on the logic state of the memory;
supplying (1270) the further device part (220 to 221) of the vehicle with electrical power via the further line section (240) depending on the logic state of the memory.

2. The method according to feature 1,
wherein the signaling (1250) of the switch-on signal is performed via a fuse data bus (9).

3. The method according to feature 1 or 2,
wherein the power-supplying device part (210) has an electronic fuse (215) of the power-supplying device part (250, 251), and
wherein the supply (1270) of the further device part (220, 221) of the vehicle with electrical power is performed via the further line section (240) by means of the electronic fuse (215) of the power-supplying device part (210) being switched on depending on the logic state of the memory.

### Flag-Controlled Electronic Fuse for a Power Source

1. The method for operating a supply network (200) of a vehicle, in particular according to one or more of the preceding features, comprising the steps of:
providing (1210) a supply network (200) having a device part (210) of the vehicle, hereinafter referred to as a power-supplying device part (210), and supplying (1220) the power-supplying device part (210) with electrical power from a power source (250, 251) of the vehicle;
connecting (1230) a first terminal of a further line section (240) to the power-supplying device part (210) of the vehicle;
connecting (1240) a second terminal of a further line section (240) to a further device part (220 to 221) of the vehicle,
wherein the further supply part (220 to 221) comprises a control device (280, 4), and
wherein the further supply part (220 to 221) comprises a memory in a first logic state;
signaling (1250) a switch-on signal to the control device (280, 4) of the further device part (220 to 221);
changing (1260) the logic state of the memory to a second logic state depending on the logic state of the memory;
supplying (1270) the further device part (220 to 221) of the vehicle with electrical power via the further line section (240) depending on the logic state of the memory.

2. The method according to feature 1,
wherein the switch-on signal is signaled via a fuse data bus (9).

3. The method according to feature 1 or 2,
wherein the further device part has an electronic fuse (225) of the further device part (220), and
wherein the further device part (220) of the vehicle is supplied with electrical power via the further line section (240) by means of the electronic fuse (225) of the further device part (220) being switched on depending on the logic state of the memory.

### Authenticated Change in Topology of a Supply Network and Associated Billing

1. A method (1300) for operating a vehicle, in particular according to one or more of the preceding features, providing (1305) the vehicle,
wherein the vehicle comprises, among other things, device parts (210), and
wherein the vehicle comprises at least one cable harness with line sections (240, 241, 245), and
wherein the vehicle comprises at least one power source (250, 251) and
wherein the vehicle comprises at least one control computer (12), for example a higher-level computer system (12), and
wherein the vehicle comprises at least two electronic fuses (214, 225) and
wherein the device parts (220) are electrical loads, and
wherein the at least one or more power sources (250, 251) are configured to supply at least two of the device parts (210, 220) with electrical power via the cable harness with line sections (240, 241, 245), and
wherein the electronic fuses (214, 225) are inserted into the cable harness with line sections (240, 241, 245), and
wherein at least one electrical load (210, 225) is associated with each of the electrical fuses (214, 225) and is referred to below as an electrical load associated with the corresponding electronic fuse, and
wherein a fuse of the fuses (214, 215) is configured to be able to enable or prevent the power supply of the electrical load associated with this fuse depending on a control signal of the control computer;
preventing (1310) the power supply of an associated electrical load by means of the corresponding fuse with which this load is associated;
establishing (1315) an encrypted data connection (720) between the control computer (12) of the vehicle, for example a higher-level computer system (12), and a computer (710) of a service provider, in particular a computer system of the automobile manufacturer of the vehicle;
authentication (1320) of the vehicle by the control computer (12) of the vehicle, for example by a higher-level computer system (12), to the computer (710) of the service provider, wherein the authentication data of the vehicle can comprise, for example, the data of the vehicle and/or the car key and/or of a SIM card in the vehicle and/or a vehicle-specific password input or password generation and/or biometric user data of a vehicle owner, etc.;
authentication (1325) of the computer (710) of the service provider to the control computer (12) of the vehicle, for example to a higher-level computer system (12);
in some cases authentication (1330) of the requesting person (730) by the control computer (12) of the vehicle, for example by the higher-level computer system (12), to the computer (710) of the service provider, wherein the authentication data can comprise, for example, the data of the vehicle and/or of the personalized car key, a personalized SIM card, a personalized password input, biometric user data, etc.;
generation (1335) or provision of an activation code by the computer (710) of the service provider;
transmission (1340) of the activation code by the computer of the service provider (710) to the control computer (12) of the vehicle, in particular to the higher-level computer system (12);
verification (1345) of the admissibility and/or syntactical correctness and/or the situational admissibility of the activation code by the control computer (12) of the vehicle, in particular by the higher-level computer system (12);
enabling (1350) the supply of power to an associated electrical load (220) by means of the corresponding fuse (225) if the activation code is admissible and/or syntactically correct and/or is situationally admissible;
transmitting (1355) billing data to a or the computer (710) of a or the service provider, in particular to a or the computer system of the automobile manufacturer, wherein memory information in the computer (710) of the service provider marks that the invoice has not been paid;
creating (1360) an invoice depending on the transmitted billing data by a or the computer (710) of a or the service provider, in particular to a or the computer system of the automobile manufacturer;
transmitting (1365) the invoice to a or the computer (710) of a or the service provider, in particular to a or the computer system (740) of the ordering person (730), or to the ordering person (730);
settlement (1370) of the invoice by a or the computer (710) of a or the service provider and/or the requesting person (730);
marking (1375) of the memory information in the computer of the service provider (740) that the invoice is paid.

### Spectrum-Based Control of an Electronic Fuse

1. The method (1600) for detecting non-extinguishing arcs (1510) in the cable harness (1515) with line sections (485, 1505) of a vehicle, in particular according to one or more of the preceding features,
wherein, in the cable harness (1510), voltages of more than 40 V, for example 48 V and/or 800 V, occur at least at times between the line sections (485, 1505), and
wherein electronic fuses (810, 825, 805) are inserted into line sections (245, 246, 485, 1505) of the cable harness (1515), which electronic fuses are configured to be able to interrupt the current flow in individual line sections or a plurality of line sections (245, 246, 485, 1505) of the cable harness (1515),
wherein the cable harness (1515) is divided into line sections (485, 1505) to be protected, and
wherein at least one electronic fuse of the electronic fuses (825) is associated with a line section (1515) of these line sections (485, 1515)—hereinafter referred to as the line section (1505) to be protected—said electronic fuse being configured to be able to interrupt the current flow in this line section (1505) of the line sections (485, 1505) that is associated therewith, and
wherein a controller (12) of the vehicle, for example the higher-level computer system (12), is configured to control this fuse (825) of the electronic fuses (810, 825, 805),
comprising the steps of:
detecting (1605) a time segment of the time characteristic of the electrical current (1525) through the line section (1505) to be protected and generating an associated value characteristic (1610) of the detected value of the electrical current (1525) through the line section (1505) to be protected of this time segment, in particular by means of a current measuring device (1520) which is inserted into the line section (1505), wherein in particular the current measuring device (1520) can be the fuse (825) associated with the line section (1505) to be protected or a sub-device of the fuse (825) associated with the line section (1505) to be protected, and wherein in particular this detection (1605) and/or the generation of the associated value characteristic (1610) of this time segment is performed by means of a control device (4) of the electronic fuse or by means of a higher-level control device (12) or by means of a higher-level computer system (12) which communicate with the control device (4) of the fuse (825) via a data bus (9);
performing (1615) a spectral analysis of the detected value characteristic (1610) of this time segment depending on the generated temporal value characteristic (1610) of the time characteristic of the electrical current (1525) through the line section (1505) to be protected and generating a spectral analysis result (1620), in particular by means of the control device (4) of the electronic fuse (825) or by means of a higher-level control device (12) or by means of a higher-level computer system (12) which communicate with the control device (4) of the fuse (825) via a data bus (9);
using (1625) the values of the spectral analysis result (1620) of the detected value characteristic (1610) of this time segment and/or values derived therefrom as the current demand vector (1630);
mapping (1635) the current demand vector (1630) of the values of the spectral analysis result (1620) of the detected value characteristic (1610) of this time segment to predefined demand vectors (1640) of spectral base structures from a stored set of predefined demand vectors of spectral base structures (1650) in a base structure database (1645), in particular by means of scalar product formation between these demand vectors (1640), for generating a spectral parameter set (1655) having at least one, optionally one similarity value each, for the similarity between a predefined demand vector (1640) of exactly one spectral base structure of the stored set of predefined demand vectors of spectral base structures (1625) of the base structure database (1635) on the one hand, and the current demand vector, on the other hand, for predefined demand vectors, in particular all demand vectors of spectral base structures from the stored set of predefined demand vectors of spectral base structures (1625) in the base structure database (1635), wherein this mapping and generating optionally occurs by means of the control device (4) of the electronic fuse (825) or by means of a higher-level control device (12) or by means of a higher-level computer system (12), which communicate with the control device (4) of the fuse (825) via a data bus (9);
evaluating (1660) the spectral parameter set (1655) for generating an evaluation result (1665), wherein in particular this evaluation (1660) takes place by applying a neural network model, and wherein this evaluation (1660) takes place in particular by means of the control device (4) of the electronic fuse (825) or by means of a higher-level control device (12) or by means of a higher-level computer system (12) which communicate with the control device (4) of the fuse (825) via a data bus (9), wherein in particular the control device (4) of the electronic fuse (825) and/or the higher-level control device (12) and/or the higher-level computer system (12) execute the neural network model, and wherein in particular the spectral parameter set (1655) comprises input values of the neural network model, and wherein the evaluation result (1665) of the evaluation (1660) depends on output values of the neural network model;
interrupting (1670) the current flow (1525) through the line section to be protected (1505), by means of the electronic fuse (825), if the evaluation result (1665) of the spectral parameter set (1640) corresponds to or suggests the presence of a short circuit or a plasma discharge (1510), in particular an arc, wherein the interruption takes place by means of the control device (4) of the electronic fuse (825) and, where applicable, also by means of a higher-level control device (12) and/or, where applicable, by means of a higher-level computer system (12), which communicate with the control device (4) of the fuse (825) via a data bus (9), and wherein in particular the control device (4) of the electronic fuse (825) and/or a higher-level control device (12) and/or a higher-level computer system (12), which communicate with the control device (4) of the fuse (825) via a data bus (9), open the circuit breaker (17) of the electronic fuse (825).

### Reduction of the Power Extraction in a Supply Network of a Vehicle by Load Shedding

1. A method (1800) for operating a supply network (1700) of a vehicle, in particular according to one or more of the preceding features,
wherein the supply network (1700) has line sections (245), and
wherein the supply network (1700) comprises power-consuming device parts (210, 211,) of the supply network (1700), and
wherein the supply network (1700) comprises power-supplying device parts (250) configured to feed power into the supply network (1700), and
wherein power-consuming device parts (210, 211) of the supply network (1700) are configured to draw electrical power from the supply network (1700) via at least one line section (245), and
wherein power-consuming device parts (210) of the power-consuming device parts (210, 211) of the supply network (1700) are configured to be able to supply a further device part (220) of the vehicle with electrical power via a further line section (240), and
wherein the power-consuming device parts (210) have an electronic fuse (214), and
wherein the electronic fuse (255) of a device part (250) is configured to be able to prevent the supply of this power-consuming device part (210) and the further device parts (220, 221) supplied with electrical power by this device part (210),
comprising the steps of:
monitoring the total power requirement of device parts (210, 211, 220, 221, 222, 223) of the device parts of the vehicle
by detecting (1805) the total power requirement of these device parts (210, 211, 220, 221, 222, 223) and by means of the comparison (1810) of the determined total power requirement of these device parts (210, 211, 220, 221, 222, 223) of the vehicle to an upper power consumption threshold value;
preventing (1820) the supply of electrical power to a first power-consuming device part (210) and/or to the further device parts (220. 221) supplied with electrical power by this first device part (210), if the determined total power requirement of all device parts (210, 211, 220, 221, 222, 223) is or could be above the upper power consumption threshold value or if the operating state of the vehicle and/or the driving situation causes this to be expected,
wherein this prevention (1820) takes place by means of the electronic fuse (255) of this device part (250), in particular by means of a circuit breaker (17) of the fuse (255);
comparing (1830) the determined total power requirement of these device parts (210, 211, 220, 221, 222, 223) of the vehicle to a lower power consumption threshold value;
enabling (1840) the supply of electrical power to the first power-consuming device part (210) and/or to the further device parts (220, 221) supplied with electrical power by this first device part (210),
if the determined total power requirement of all device parts (210, 211, 220, 221, 222, 223) is below the lower power consumption threshold value,
wherein this enabling (1840) takes place by means of the electronic fuse (255) of this device part (250), in particular by means of a circuit breaker (17) of the fuse (255).

2. The method according to feature 1,
wherein the power supply of the device parts (220, 221) of the vehicle of which the power supply is prevented has a lower priority than the power supply of the device parts (222, 223) of the vehicle of which the power supply is not prevented.

### Priority-Controlled Power Supply in a Supply Network of a Vehicle

1. A method (1800) for operating a supply network (1700) of a vehicle, in particular according to one or more of the preceding features,
wherein the supply network (1700) has line sections (245), and
wherein the supply network (1700) comprises power-consuming device parts (210, 211,) of the supply network (1700), and
wherein the supply network (1700) comprises power-supplying device parts (250) configured to feed power into the supply network (1700), and
wherein power-consuming device parts (210, 211) of the supply network (1700) are configured to draw electrical power from the supply network (1700) via at least one line section (245), and
wherein power-consuming device parts (210) of the power-consuming device parts (210, 211) of the supply network (1700) are configured to be able to supply a further device part (220) of the vehicle with electrical power via a further line section (240), and
wherein the power-consuming device parts (210) have an electronic fuse (214), and
wherein the electronic fuse (255) of a device part (250) is configured to be able to prevent the supply of this power-consuming device part (210) and the further device parts (220, 221) supplied with electrical power by this device part (210),
comprising the steps of:
monitoring the total power requirement of device parts (210, 211, 220, 221, 222, 223) of the device parts of the vehicle
by detecting (1805) the total power requirement of these device parts (210, 211, 220, 221, 222, 223) and by means of the comparison (1810) of the determined total power requirement of these device parts (210, 211, 220, 221, 222, 223) of the vehicle to an upper power consumption threshold value;
preventing (1820) the supply of electrical power to a power-consuming device part of these device parts and to the further device parts supplied with electrical power by this device part if the total power requirement of all device parts is or could be above a power transport threshold for this line section or the operating state and/or the driving situation causes this to be expected,
wherein this prevention is accomplished by means of the electronic fuse of this device part.

2. The method according to feature 1,
wherein the power supply of the device parts of the vehicle of which the power supply is prevented has a lower priority than the power supply of the device parts of the vehicle of which the power supply is not prevented.
   Load Increase in a Supply Network of a Vehicle with Electronic Fuses

1. A method (1800) for operating a supply network (1700) of a vehicle, in particular according to one or more of the preceding features,
wherein the supply network (1700) has line sections (245), and
wherein the supply network (1700) comprises power-consuming device parts (210, 211,) of the supply network (1700), and
wherein the supply network (1700) comprises power-supplying device parts (250) configured to feed power into the supply network (1700), and
wherein power-consuming device parts (210, 211) of the supply network (1700) are configured to draw electrical power from the supply network (1700) via at least one line section (245), and
wherein power-consuming device parts (210) of the power-consuming device parts (210, 211) of the supply network (1700) are configured to be able to supply a further device part (220) of the vehicle with electrical power via a further line section (240), and
wherein the power-consuming device parts (210) have an electronic fuse (214), and
wherein the electronic fuse (255) of a device part (250) is configured to be able to prevent the supply of this power-consuming device part (210) and the further device parts (220, 221) supplied with electrical power by this device part (210),
comprising the steps of:
monitoring the total power requirement of device parts (210, 211, 220, 221, 222, 223) of the device parts of the vehicle
by detecting (1805) the total power requirement of these device parts (210, 211, 220, 221, 222, 223) and by means of the comparison (1810) of the determined total power requirement of these device parts (210, 211, 220, 221, 222, 223) of the vehicle to an upper power consumption threshold value;
enabling (1820) the supply of electrical power to a power-consuming device part of these device parts and the further device parts supplied with electrical power by this device part if the total power requirement of all device parts is or could be below a lower power transport threshold for this line section or the operating state and/or the driving situation causes this to be expected,
wherein this enabling takes place by means of the electronic fuse of this device part.

2. The method according to feature 1,
wherein the power supply of the device parts of the vehicle of which the power supply is enabled has a higher priority than the power supply of the device parts of the vehicle of which the power supply is not enabled.

### Reduction of the Power Extraction in a Supply Network of a Vehicle by Load Shedding

1. A method (1800) for operating a supply network (1700) of a vehicle, in particular according to one or more of the preceding features,
wherein the supply network (1700) has line sections (245, 240, 241), and
wherein the supply network (1700) comprises power-consuming device parts (210, 211) of the supply network (1700), and
wherein the supply network (1700) comprises power-supplying device parts (250) of the vehicle which are configured to feed power into the supply network (1700), and
wherein the supply network (1700) is configured to supply power-consuming device parts (210, 211) of the vehicle with electrical power from the supply network (1700) via at least one line section (245), and
wherein power-consuming device parts (210, 211) are configured to be able to supply a further device part (220, 221, 222, 223) of the vehicle with electrical power via a further line section (240, 241), and
wherein the power-consuming device parts (210, 211) have an electronic fuse (214, 215), and
wherein the electronic fuse (255) of a device part (250) is configured to be able to prevent the supply of power to this power-consuming device part (210, 211) and the further device parts (220, 221, 222, 223) supplied with electrical power by this device part (210, 211),
comprising the steps of:
monitoring the total power requirement of device parts (210, 211, 220, 221, 222, 223) of the device parts of the vehicle
by detecting (1805) the total power requirement of these device parts (210, 211, 220, 221, 222, 223) and by comparing (1810) the determined total power requirement of these device parts (210, 211, 220, 221, 222, 223) of the vehicle to a power consumption threshold value;
preventing (1820) the supply of electrical power to a power-consuming device part of these device parts and to the further device parts supplied with electrical power by this device part if the total power requirement of all device parts is or could be above a power transport threshold for this line section or the operating state and/or the driving situation causes this to be expected,
wherein this prevention is accomplished by means of the electronic fuse of this device part.

2. The method according to feature 1,
wherein the power supply of the device parts of the vehicle of which the power supply is prevented has a lower priority than the power supply of the device parts of the vehicle of which the power supply is not prevented.

### Priority-Controlled Loading of a Supply Network of a Vehicle

1. A method (1800) for operating a supply network (1700) of a vehicle, in particular according to one or more of the preceding features,
wherein the supply network (1700) has line sections (245, 240, 241), and
wherein the supply network (1700) comprises power-consuming device parts (210, 211) of the supply network (1700), and
wherein the supply network (1700) comprises power-supplying device parts (250) of the vehicle which are configured to feed power into the supply network (1700), and
wherein the supply network (1700) is configured to supply power-consuming device parts (210, 211) of the vehicle with electrical power from the supply network (1700) via at least one line section (245), and
wherein power-consuming device parts (210, 211) are configured to be able to supply a further device part (220, 221, 222, 223) of the vehicle with electrical power via a further line section (240, 241), and
wherein the power-consuming device parts (210, 211) have an electronic fuse (214, 215), and
wherein the electronic fuse (255) of a device part (250) is configured to be able to prevent the supply of power to this power-consuming device part (210, 211) and to the further device parts (220, 221, 222, 223) supplied with electrical power by this device part (210, 211),
comprising the steps of:
monitoring the total power requirement of device parts (210, 211, 220, 221, 222, 223) of the device parts of the vehicle
by detecting (1805) the total power requirement of these device parts (210, 211, 220, 221, 222, 223) and by means of the comparison (1810) of the determined total power requirement of these device parts (210, 211, 220, 221, 222, 223) of the vehicle with a lower power consumption threshold value;
enabling (1820) the supply of electrical power to a power-consuming device part of these device parts and the further device parts supplied with electrical power by this device part if the total power requirement of all device parts is or could be below a lower power transport threshold for this line section or the operating state and/or the driving situation causes this to be expected,
wherein this enabling takes place by means of the electronic fuse of this device part.
   Battery with Battery Cell Protected by Electronic Fuses

1. A method (1800) for operating a supply network (1700) of a vehicle, in particular according to one or more of the preceding features,
wherein the supply network (1700) has line sections (245), and
wherein the supply network (1700) comprises power-consuming device parts (210, 211) of the supply network (1700), and
wherein the supply network (1700) comprises power-supplying device parts (250) of the vehicle which are configured to feed power into the supply network (1700), and
wherein the supply network (1700) is configured to supply power-consuming device parts (210, 211) of the supply network (1700) of the vehicle with electrical power from the supply network (1700) via at least one line section (245), and
wherein power-consuming device parts (210) can supply an additional device part (220) of the vehicle with electrical power via a further line section (240), and
wherein the power-consuming device parts (210) have an electronic fuse (214), and
wherein the electronic fuse (255) of a device part (250) can prevent the supply of power to this power-consuming device part (210) and to the further device parts (220, 221) supplied with electrical power by this device part (210).
comprising the steps of:
monitoring the total power requirement of device parts (210, 211, 220, 221, 222, 223) of the device parts of the vehicle by means of
detecting (1805) the total power requirement of these device parts (210, 211, 220, 221, 222, 223);
comparing (1810) the determined total power requirement of these device parts (210, 211, 220, 221, 222, 223) of the vehicle to an upper power consumption threshold value;
increasing (1820) the generation of power of a power source 250 for supplying electrical power to a first power-consuming device part (210) and/or to the further device parts (220: 221) supplied with electrical power by this first device part (210),
if the determined total power requirement of all device parts (210, 211, 220, 221, 222, 223) is or could be above the upper power consumption threshold value or the operating state and/or the driving situation causes this to be expected,
wherein this increase (1820) takes place by means of the electronic fuse (255) of this device part (250), in particular by closing the circuit breaker (17) of this fuse (255) of this device part (250), and/or by changing operating parameters of this device part (250).

2 The method according to feature 1,
wherein the power supply of the device parts of the vehicle of which the power supply is impaired has a lower priority than the power supply of the device parts of the vehicle of which the power supply is not impaired.
   Battery Cell Module with Switch-Off and Shunting by Electronic Fuses

1. A method (1800) for operating a supply network (1700) of a vehicle, in particular according to one or more of the preceding features,
wherein the supply network (1700) has line sections (245), and
wherein the supply network (1700) comprises power-consuming device parts (210, 211,) of the supply network (1700), and
wherein the supply network (1700) comprises power-supplying device parts (250) of the vehicle which are configured to feed power into the supply network (1700), and
wherein the supply network (1700) is configured to supply power-consuming device parts (210, 211) of the supply network (1700) of the vehicle with electrical power from the supply network (1700) via at least one line section (245), and
wherein power-consuming device parts (210) are configured to be able to supply a further device part (220) of the vehicle with electrical power via a further line section (240), and
wherein the power-consuming device parts (210) have an electronic fuse (214), and
wherein the electronic fuse (255) of a device part (250) is configured to be able to prevent and/or enable the supply of power to this power-consuming device part (210) and to the further device parts (220, 221) supplied with electrical power by this device part (210),
comprising the steps of:
monitoring the total power requirement of device parts (210, 211, 220, 221, 222, 223) of the device parts of the vehicle
by detecting (1805) the total power requirement of these device parts (210, 211, 220, 221, 222, 223) and by means of the comparison (1810) of the determined total power requirement of these device parts (210, 211, 220, 221, 222, 223) of the vehicle with a lower power consumption threshold value;
reducing (1840) the generation of power of a power source (250) for supplying electrical power to a first power-consuming device part (210) and/or to the further device parts (220: 221) supplied with electrical power by this first device part (210),
if the determined total power requirement of all device parts (210, 211, 220, 221, 222, 223) is or could be below the lower power consumption threshold value or the operating state and/or the driving situation causes this to be expected, and
wherein this reducing (1840) is accomplished by means of the electronic fuse (255) of this device part (250), in particular by opening the circuit breaker (17) of this fuse (255) of this device part (250), and/or by changing operating parameters of this device part (250).

2. The method according to feature 1,
wherein the power supply of the device parts of the vehicle of which the power supply is impaired has a lower priority than the power supply of the device parts of the vehicle of which the power supply is not impaired.
   Distributed Measurement Method in a Supply Network with Electronic Fuses

1. A distributed measurement method (2000) for detecting the state of a cable harness (1515) of a vehicle, in particular according to one or more of the preceding features, comprising the steps of: where applicable, synchronization (2005) of a first timer (1950) of a first electronic fuse (825) with a time standard, in particular a timer (1970) of a higher-level computer system (12);
where applicable, synchronization (2010) of a second timer (1955) of a second electronic fuse (805) with the time standard, in particular the timer (1970) of a higher-level computer system (12);
initiating (2015) the following two detection processes at equal time values of the first timer (1950) of the first electronic fuse (825) and the second timer (1955) of the second electronic fuse (805);
detection (2020) of the first value of the current flow (1525) into a first line section (1505) to be protected of the cable harness (1515), in particular by the first electronic fuse (825) and/or a first current measuring device (1520) of the first electronic fuse (825);
detection (2025) of the second value of the current flow (1910) into a second, downstream line section (1905) to be protected of the cable harness (1515), in particular by the second electronic fuse (805) and/or a second current measuring device (1935) of the second electronic fuse (805);
determination (2030) of a first time stamp value, in particular by the first electronic fuse (825) and/or a first control device (4) of the first electronic fuse (825), and in particular with the aid of the first timer (1950) of the first electronic fuse (825), for each first measured current value or for a group of first measured current values of the current flow (1525);
determination (2035) of a second time stamp value, in particular by the second electronic fuse (805) and/or a second control device (4) of the second electronic fuse (805) and in particular with the aid of the second timer (1955) of the second electronic fuse (805), for every second measured current value or for a group of second measured current values of the current flow (1910);
transmission (2040) of at least one second measured current value together with the second time stamp value from the second fuse (805) to a higher-level computer system (12) or to the control device (4) of the first electronic fuse (825) and, in the event of the transmission of the second measured value to a higher-level computer system (12), transmission (2025) of the first measured current value together with the first time stamp value from the first fuse (825) to the higher-level computer system (12);
comparing (2045) the first measured current value to the second measured current value; and
deducing (2050) a power loss in line sections (1525) between two electronic fuses (825, 805), in particular if the difference between the first measured current value and the second measured current value lies outside of a permitted difference value interval and/or if a quotient of the first measured current value and the second measured current value lies outside of a permitted quotient interval.

2. The method according to feature 1 comprising the step of:
adoption (2055) of countermeasures, in particular by the higher-level computer system (12) or by the computer core (2) of the evaluating control device (4) of the evaluating electronic fuse (825) if the measured current values or the ratio of the measured current values to one another or a difference of such measured current values or variables derived therefrom do not correspond to one or more expected values and/or are not within an expected value interval.

3. The method according to feature 1 or 2,
wherein the data communication runs via
   a fuse data bus (9) or
   a fuse data bus (9) or
   a Lin data bus (9) or
   a DSI3 data bus (9) or
   a PSI5 data bus (9) or
   a CAN data bus (9) or
   a CAN FD data bus (9) or
   an Ethernet data bus or
   a Flexray data bus (9) or
   a LVDS data bus (9) or
   an Ethernet data bus (9) or
   an otherwise wired or wireless data transmission path, for example via a Bluetooth or WLAN data connection or an optical data connection (540),
   or another wired or wireless interface (610, 10, 551, 550).

4. The method according to any of features 1 to 3,
comprising the steps of:
detecting changes in the measured current values of the currents (1525, 1910, 1920, 1930) and/or changes in the spectra of the temporal voltage characteristic of the voltages between line sections (1505, 1905, 1915, 1920) to be protected of the cable harness (1515) on the one hand, and a reference potential on the other hand, of a change and/or of changes in the spectra of the current characteristic of the measured current values of the currents (1525, 1910, 1920, 1930) or the power transport via the line sections (1505, 1905, 1915, 1920) to be protected of the cable harness (1515);
evaluating these changes by comparison to expected characteristics and/or expected values.

5. The method according to feature 4,
comprising the steps of:
establishing (2060) a data connection (1990) to a server (1985) of a repair shop and/or of an automobile manufacturer and/or of a service provider;
transmitting (2065) vehicle data and/or operating data and/or measured values and/or damage data if the comparison of the detected changes to the expected characteristics and/or expected values resulted in a deviation beyond a predetermined amount.

6. The method according to feature 5,
comprising the step of:
transmitting (2065) the vehicle data and/or operating data and/or measured values and/or damage data to a server (1985) or a terminal of the repair shop or a different user of this data.

7. The method according to feature 5 or 6,
comprising the steps of:
predicting (2070) the failure probability of a device part of the vehicle by means of the vehicle data and/or operating data and/or measured values and/or damage data;
transmitting (2075) the prediction result to a server (1985) and/or a terminal of the repair shop and/or a terminal (740) and/or a computer of a vehicle owner (730) and/or a terminal (740) and/or a computer of a vehicle driver (730) or a terminal and/or a server (710) of an automobile manufacturer and/or a terminal and/or server of a logistics company and/or a terminal and/or a server of another user of this data.

8. The method according to feature 7,
comprising the step of:
providing (2080) a replacement part for the device part of the vehicle in the case of a prediction result that prompts expectation of a failure of the device part.

9. The method according to any of features 1 to 8,
comprising the step of:
deducing (2085) the temperature of a line section (1915, 1925, 1505, 1905) and/or an overtemperature of a line section (1915, 1925, 1505, 1905) by means of the detected values of the current flow (1920, 1925, 1525, 1910) in a plurality of line sections (1915, 1925, 1505, 1905) to be protected of the cable harness (1515).
   Battery with Electronic Fuses

1. A battery (2100) having a diagnostic function for a vehicle, in particular according to one or more of the preceding features,
wherein the battery (2100) comprises one or more battery cell modules (2105, 2155);
wherein the battery (2100) comprises one or more electronic fuses (825, 805);
wherein at least one terminal (2197) of the battery (2100) is connected to the first terminal (26) of the circuit breaker (17) of an electronic fuse (825);
wherein the battery (2100) comprises a supply tree and/or a supply network having one or more supply branches (2198, 2196, 2120, 2135, 2140, 2190, 2160, 2175, 2180, 2196);
wherein a plurality of electronic fuses (825, 805) is connected in series into a supply branch 2198, 2196, 2120, 2135, 2140, 2190, 2160, 2175, 2180, 2196) of the supply tree or the supply network;
wherein a supply tree or a supply network may also comprise only one supply branch having a plurality of electronic fuses which are inserted into the supply branch;
wherein one or more battery cell modules (2105, 2155) of the battery (2100) are electrically connected in series; and
wherein one or more electronic fuses (805) are connected between battery cell modules (2105, 2155) of the battery (2100).

2. The battery (2100) according to feature 1,
wherein precisely one electronic fuse (805) is connected between two battery cell modules (2105, 2155), which are interconnected in series.

3. The battery (2100) according to feature 2,
wherein an electronic fuse (825, 805) is provided in each case in each battery cell module (2105, 2155), and
wherein an electronic fuse (825, 805) is associated with each battery cell module (2105, 2155) or in each case one or more groups, in particular battery cell modules (2105, 2155) connected in series.

4. The battery (2100) according to one or more of features 1 to 3,
wherein one or more or all of these electronic fuses (825, 805) have a first circuit breaker (17) which is configured to prevent the current flow (2121, 2161) through one or more battery cell modules (2105, 2155) and/or the relevant group of battery cell modules, i.e., to disconnect the electrical connection (2140, 2190, 2160, 2175) between a first battery cell module (2105) and a second battery cell module (2155) or a first group of battery cell modules and a second group of battery cell modules connected in series with one another if the first circuit breaker (17) is open and/or
wherein one or more or all of these electronic fuses (825, 805) have a first circuit breaker (17) which is configured to enable the current flow (2121, 2161) through one or more battery cell modules (2105, 2155) and/or the relevant group of battery cell modules, i.e., to establish the electrical connection (2140, 2190, 2160, 2175) between a first battery cell module (2105) and a second battery cell module (2155) or a first group of battery cell modules and a second group of battery cell modules connected in series with one another if the first circuit breaker (17) is closed.

5. The battery (2200) according to feature 4,
wherein one or more or all of these electronic fuses (825) of the battery (2200) have a second circuit breaker (17′) which is configured to shunt the battery cell module (2105) and/or the group of battery cell modules when the second circuit breaker (17′) is closed.

6. The battery (2200) according to feature 5,
wherein a control device (4) of the electronic fuse (825) is configured to detect the switching state of the first circuit breaker (17) before the second circuit breaker (17′) is closed, and
wherein a control device (4) of the electronic fuse (825) is configured to detect whether the first circuit breaker (17) is open, and
wherein a control device (4) of the electronic fuse (825) is configured to close the second circuit breaker (17) only if the first circuit breaker (17) is open.

7. The battery (2200) according to feature 6,
wherein the control devices (4) are configured to cause the feeding of a test current (515) into the first circuit breaker (17) upstream (26) of the first circuit breaker (17) and to cause the extraction of this test current (915) downstream (28) of the first circuit breaker (17), and
wherein the control device (4) is configured to evaluate whether this feeding and extraction were successful.
   Battery Cell Module with Battery Cell Module and Electronic Fuses

1. A battery cell module (2300), in particular of a vehicle, in particular according to one or more of the preceding features,
wherein the battery cell module (2300) comprises at least one battery cell (2145) and/or interconnection of battery cells, and
wherein the battery cell module (2300) comprises a first circuit breaker (17), and
wherein the battery cell module (2300) comprises a second circuit breaker (17′), and
wherein the battery cell module (2300) comprises a first electrical node (2120), and
wherein the battery cell module (2300) comprises a second electrical node (2135), and
wherein the battery cell module (2300) comprises a third electrical node (2140), and
wherein the battery cell (2300) comprises a first battery cell terminal (2305), and
wherein the battery cell (2300) comprises a second battery cell terminal (2310), and
wherein the first battery cell terminal (2305) is connected to the second node (2135), and
wherein the second battery cell terminal (2310) is connected to the third node (2140), and
wherein the first circuit breaker (17) comprises a first terminal (26) and a second terminal (28) and a control terminal (27), and
wherein the second circuit breaker (17′) comprises a first terminal (26′) and a second terminal (28′) and a control terminal (27′), and
wherein the battery cell (2105) and/or the interconnection of battery cells comprises a first terminal (2125) and a second terminal (2130), and
wherein the first circuit breaker (17) is connected by its first terminal (26) of the first circuit breaker (17) to the first node (2120), and
wherein the first circuit breaker (17) is connected by its second terminal (28) of the first circuit breaker (17) to the second node (2135), and
wherein the second circuit breaker (17′) is connected by its first terminal (26′) of the second circuit breaker (17′) to the first node (2120), and
wherein the second circuit breaker (17′) is connected by its second terminal (28′) of the second circuit breaker (17′) to the third node (2140), and
wherein a first terminal (2305) of the battery cell (2145) or the group of battery cells is connected to the second node (2135), and
wherein a second terminal (2310) of the battery cell (2145) or the group of battery cells is connected to the third node (2140),
characterized in that:
the battery cell module (2105) comprises a control device (4) or is connected to such a control device (4), and
the control device (4) is configured to control the control terminal (27) of the first circuit breaker (17), and
the control device (4) is configured to control the control terminal (27′) of the second circuit breaker (17′), and
the control device (4) is configured to lock the control terminal (27) of the first circuit breaker (17) relative to the control terminal (27′) of the second circuit breaker (17′) in such a way that it is ruled out that the first circuit breaker (17) is conductive if the second circuit breaker (17′) is conductive.

2. The battery cell module (2300) according to feature 1,
wherein the control device (4) comprises means (16, 525, 520, 920, 530, 21, 22, 28, 26, 27, 915, 515, 510, 910, 905 and 16′, 525′, 520′, 920′, 530′, 21′, 22′, 28′, 26′, 27′, 915′, 515′, 510′, 910′, 905′) for detecting the switching state of the circuit breakers (17, 17′), and
wherein the control device (4) is configured to detect the switching state of at least one of the circuit breakers (17, 17′), in particular as “on” or “off,” by means of these means (16, 525, 520, 920, 530, 21, 22, 28, 26, 27, 915, 515, 510, 910, 905 and 16′, 525′, 520′, 920′, 530′, 21′, 22′, 28′, 26′, 27′, 915′, 515′, 510′, 910′, 905′).

3. The battery cell module (2300) according to feature 2,
wherein the control device (4) for shunting the battery cell module (2105) is configured to: first open the first circuit breaker (17) and thus to prevent a current flow (2121) through the battery cell (2145);
then, in particular by means of the means (16, 525, 520, 920, 530, 21, 22, 28, 26, 27, 915, 515, 510, 910, 905) for detecting the switching state of the first circuit breaker (17), to check whether the first circuit breaker (17) is open;
then, if the second circuit breaker is open, to close the second circuit breaker (17′); and
then, to check the means (16′, 525′, 520′, 920′, 530′, 21′, 22′, 28′, 26′, 27′, 915′, 515′, 510′, 910′, 905′) for detecting the switching state of the second circuit breaker (17′) as to whether the second circuit breaker (17′) is closed.

4. The battery cell module (2200), in particular according to one or more of the preceding features,
wherein the battery cell module (2200) itself in turn comprises at least one first battery cell module (2105) according to any of features 1 to 3, and
wherein the battery cell module (2200) itself in turn comprises at least one second battery cell module (2155) according to any of features 1 to 3, and
wherein the second terminal (2130) of the first battery cell module (2105) is connected to the first terminal (2165) of the second battery cell module (2155).

5. The battery cell module (2600) according to any of features 1 to 4,
wherein the circuit breaker (17) and the control device (4) of the fuse (825) and the fuse (825) are accommodated in a housing (2605) with the actual battery cell module (2105).

6. The battery cell module (2600) according to any of features 1 to 5,
wherein the control device (4) of the fuse (825) comprises an optical data interface (550, 551).

7. The battery cell module (2300) according to features 5 and 6,
wherein the housing (2605) has an optical window (545), which allows the entry of electromagnetic radiation (540) for the optical transport of data away from the optical data interface (550, 551) of the control device (4) and toward the optical data interface (550, 551) of the control device (4), and can communicate via the optical interface (550, 551) of the control device (4) within the housing (2605) with an optical interface (555) of another device, for example a higher-level computer system (12) outside the housing (2665).

8. The battery cell module (2600) according to one or more of features 4 to 7
wherein the housing (2605) has an optical window (545) and/or an optical plug-in connector (2640) that allows electromagnetic radiation (540) to exit for the transport of data from the optical data interface (550, 551) of the control device (4) to a device (555, 12) outside the housing (2605) and/or from a device (555, 12) outside the housing (2605) to the optical data interface (550, 551) of the control device (4), and
so that in particular the optical interface (510) of the control device (4) within the housing (2605) of the control device (4) can communicate with an optical interface (555) of a different device (12), in particular of a higher-level computer system (12), outside the housing (2605).

9. The battery cell module (2600) according to feature 7 and/or 8,
wherein the electromagnetic radiation (540) is laser radiation or radiation of an LED.
   Battery Cell Module with Electronic Fuse

1. A battery cell module (2700), in particular of a vehicle, in particular according to one or more of the preceding features,
wherein the battery cell module or a group of battery cell modules comprising the battery cell module are configured to supply a control device (4) of an electronic fuse (825) and the possible other parts of this electronic fuse (825) with electrical power for operation of the electronic fuse.

2. The battery cell module (2700) according to feature 1,
wherein the tapping point for supplying the control device (4) of the electronic fuse (825) with electrical power is located between the circuit breaker (17) of the electronic fuse (825) and the first terminal (2135) of the first battery cell (2145), of the first battery cell module (2105) or of the group of battery cells, so that the control device (4) is supplied with electrical power of the battery cell (1245) if the circuit breaker (17) of the electronic fuse (17) is open.

3. The battery cell module (2800) according to feature 1 or 2,
wherein the circuit breaker (17) of the electronic fuse (825) is located between the tapping point for supplying the control device (4) of the electronic fuse (825) with electrical power and the first terminal (2135) of the first battery cell (2145), of the first battery cell module (2105) or of the group of battery cells, so that the control device (4) is no longer supplied with electrical power of the battery cell (1245) if the circuit breaker (17) of the electronic fuse (17) is open.

4. The battery cell module (2200, 2300, 2600, 2700, 2800), in particular according to one or more of features 1 to 3,
wherein the battery cell module (2700) comprises an electronic fuse (825), and
wherein the electronic fuse (2700) is configured to detect voltage values and/or current values, and
wherein the electronic fuse (825) is configured to execute a fuse function, and
wherein the electronic fuse (825) is configured to interrupt the current flow (2121) if a disconnect condition is satisfied.

5. The battery cell module (2200, 2300, 2600, 2700, 2800) according to feature 4,
wherein the electronic fuse (825) is configured to interrupt the current flow (2121) and to shunt the battery cell (1245) or the group of battery cells if a disconnect condition is satisfied and if a shunting condition is satisfied at the same time.

6. The battery cell module (2200, 2300, 2600, 2700, 2800), in particular according to one or more of features 1 to 5,
wherein one or more electronic fuses (825, 805) each have two data interfaces (10, 610, 550, 551), which may be optical.
   Battery with Electronic Fuse

1. A battery (2200), in particular of a vehicle, in particular according to one or more of the preceding features,
wherein the battery (2200) comprises one or more battery cells (2145, 2185), and
wherein the battery (2200) comprises one electronic fuse (825, 805) per battery cell (2145, 2185) or per group of battery cells.

2. The battery (2200) according to feature 1,
wherein one or more electronic fuses (825, 805) of the battery (2200) are configured to transmit one or more measured values and/or values derived therefrom and/or state values and/or state information of the electronic fuses (825, 805) to a higher-level controller (12), i.e., for example, a higher-level computer system (12), in particular via a fuse data bus (9).

3. The battery (2200) according to feature 2,
wherein one or more control devices (4) of one or more electronic fuses (825, 805) comprise one or more temperature sensor evaluation devices (585).

4. The battery (2200) according to feature 2 or 3,
wherein one or more control devices (4) of one or more electronic fuses (825, 805) comprise one or more temperature sensors (586).

5. The battery (2200) according to one or more of features 1 to 4,
wherein the battery (2200) comprises a fuse data bus (9) within the battery (2200), and
wherein control devices (4) of electronic fuses (825, 805) are connected to this fuse data bus via their corresponding data interfaces (10, 551, 550, 610) or are inserted into the fuse data bus (9) correspondingly by means of two such data interfaces (10, 551, 550, 610).

6. The battery (2200) according to feature 5,
wherein the electronic fuses comprise, as data interfaces (10, 551, 550, 610), two optical data interfaces (551, 550), and
wherein at least one part of the fuse data bus (9) comprises an optical data bus (540), in particular in the form of an optical data connection (540).

7. The battery (2200) according to feature 6,
wherein the optical data bus (540) comprises one or more optical waveguides (580), which are optionally electrically insulating.

8. The battery (2200) according to feature 6 or 7,
wherein the optical data bus (540) comprises an optical data bus ring (9′).

### Ideal Diode

1. An ideal diode (1) for use in a vehicle, in particular according to one or more of the preceding features,
having a first diode terminal (18) and a second diode terminal (19), and
comprising a circuit breaker (17) and
comprising a control device (4) and
wherein the circuit breaker (17) comprises a first terminal (26) and a second terminal (28) and a control terminal (27), and
wherein the first terminal (26) of the circuit breaker (17) is the first diode terminal (18), and
wherein the second terminal (28) of the circuit breaker (17) is the second diode terminal (19), and
wherein the control device (4) of the ideal diode (1) first is configured to detect measured current values of the electrical current (29) through the circuit breaker (17) in the direction from a power source (250) to a load (220 to 223), but also in the reverse flow direction of the electrical current (29), and
wherein the control device (4) is configured to detect the voltage measured values of the voltage drop across the circuit breaker (17), in particular between the first terminal (26) and the second terminal (28) and/or between the first terminal (26) and the control terminal (27) and/or between the control terminal (27) and the second terminal (28), and/or
wherein, secondly, the control device (4) is configured to detect the sign of the electrical current (29) through the circuit breaker (17), and
wherein the control device (4) is configured to switch off this circuit breaker (17) when the electrical current (29) through the circuit breaker (17) is reversed and/or when the direction of the power flow through the circuit breaker (17) is reversed.

2. The ideal diode (1) according to feature 1,
wherein the design and/or the operation of the ideal diode provide a preferred flow direction of the electric current (29), and
wherein the ideal diode (1) comprises means for capturing and detecting a current (29) flowing in reverse counter to the preferred flow direction.

3. The ideal diode (1) according to feature 1 or 2,
wherein the control device (4) comprises a computer core (2), and
wherein the computer core (2) of the control device (4) of the ideal diode is configured to evaluate the measured values thus detected, in particular measured current values and/or voltage measured values and/or power measured values and/or signs of the measured current value of the electrical current (29), and
wherein the computer core is configured to transfer the measured values, in particular measured current values and/or voltage measured values and/or power measured values and/or signs of the measured current value of the electrical current (29), and/or measured values derived therefrom, to other computer cores of other ideal diodes and/or to other computer cores of other electronic fuses via a fuse data bus (9) and/or the like and/or to a higher-level controller (12), i.e., for example a higher-level computer system (12).
   Electronic Fuse with Data Interface and Load Shedding

1. A supply network (200) for supplying electrical loads (210 to 213 and 220 to 223 and 230 to 233) of a vehicle with electrical power, in particular according to one or more of the preceding features, comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are interconnected in a tree structure or in a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network,
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical.

2. The supply network (200) according to feature 1,
wherein the data buses are connected together in a star-shaped or linear manner in a chain or a closed ring, and
wherein the data buses can have branches.

3. The supply network (200) according to feature 1 or 2,
wherein one or more electronic fuses (1, 214 to 217, 225 to 228, 235 to 238, 250, 251) each have two data interfaces (214 to 217, 225 to 228, 235 to 238, 250, 251, 610, 10) per electronic fuse (1, 214 to 217, 225 to 228, 235 to 238, 250, 251) which can be optical.

4. The supply network (200) according to one or more of features 1 to 3,
wherein two or more electronic fuses (214 to 217, 225 to 228, 235 to 238, 250, 251) are connected with data technology by an optical data bus (540) into which these electronic fuses (214 to 217, 225 to 228, 235 to 238, 250, 251) are each inserted.

5. The supply network (200) according to one or more of features 1 to 4,
wherein two or more electronic fuses (214 to 217, 225 to 228, 235 to 238, 250, 251) are connected with data technology by an electronic one-wire data bus (9) and/or an electronic two-wire data bus (9) and/or another data bus (9).

6. The supply network (200) according to feature 5,
wherein the electronic fuses (214 to 217, 225 to 228, 235 to 238, 250, 251) are inserted into the data bus (9).

7. The supply network (2900) according to one or more of features 1 to 6,
wherein one or more supply branches of the supply network (2900) are designed to supply electrical loads (2930 to 2933) with electrical power as a ring of a supply line (2910 to 2915), in particular if a body serves as a return ground line, and/or as two rings of two supply lines, and/or
wherein one or more supply branches of the supply network for power supply of electrical power from electrical power sources (2940, 2941) are designed as a ring of a supply line (2910 to 2915), in particular if a body serves as a return ground line, and/or as two rings of two supply lines.

8. The supply network (2900) according to feature 7,
wherein for loads of the loads (2930 to 2933) in each case two fuses (2960 to 2967) are inserted into the supply line (2910 to 2915) at the corresponding power extraction point (2920 to 2923) for this load of the loads (2930 to 2933) and/or
wherein, for power sources (2940, 2941), two fuses (2950 to 2953) are inserted into the supply line (2910 to 2915) at the power feed point (2924 to 2925) of the electrical power for these power sources (2940, 2941) into the supply line (2910 to 2915).

9. The supply network (2900) according to feature 8,
wherein precisely those two electronic fuses of the fuses (2950 to 2953 and 2960 to 2967) which are associated with a defective line section of the line sections (2910 to 2915) are configured to open their circuit breakers (17) in the event of an error on the line section, so that precisely these two electronic fuses of the fuses (2950 to 2953 and 2960 to 2967) thereby isolate this defective line section of the line sections (2910 to 2915).

10. The supply network (2900) according to feature 8 or 9,
wherein the two electronic fuses of the fuses (2960 to 2967) associated with this defective load are configured to open their circuit breakers (17) in the event of an error at a load of the loads (2930 to 2933), so that these two electronic fuses thereby isolate the defective load, and/or
wherein the two electronic fuses of the fuses (2950 to 2953) associated with this defective power source are configured to open their circuit breakers in the event of an error at a power source of the power sources (2940, 2941), so that these two electronic fuses thereby isolate the defective power source,
wherein this is in particular the case if the above errors impair and/or could impair the power supply of other loads of the loads (2930 to 2933) and/or high-priority loads of the loads (2930 to 2933), the power output of other power sources of the power sources (2940, 2941) and/or high-priority power sources of the power sources (2940, 2941).
   Supply Network with Electronic Fuses and Auto Addressing of the Fuses

1. A supply network (200) for supplying electrical loads (210 to 213 and 220 to 223 and 230 to 233) of a vehicle with electrical power, in particular according to one or more of the preceding features,
comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical, and
wherein the control device (4) of an electronic fuse of the fuses (2950 to 2953 and 2960 to 2967) is configured to receive and/or transmit data such as configuration data (read-write/program), switch commands (read-write/program), diagnostic data (read-write), measured values (read), comparison value settings (read-write/program) and programming code (read-write/program) via a data interface (10, 610, 550, 551) via a data bus (9).

2. The supply network (2900) according to feature 1,
wherein the data bus (9) is in parts or completely a two-wire data bus.

3. The supply network (2900) according to feature 2,
wherein the data bus (9) is a differential data bus.

4. The supply network (2900) according to feature 3,
wherein the data bus (9) is a differential bidirectional data bus (9).

5. The supply network (2900) according to any of features 1 to 4,
wherein the data bus (9) is a CAN data bus or a data bus (9) having a physical interface of a CAN data bus, a CAN FD data bus, or a Flexray data bus or an LVDS data bus or the like.

6. The supply network (2900) according to any of features 1 to 5,
wherein electronic fuses (2950 to 2953 and 2960 to 2967) of the supply network (2900) comprise two data interfaces (10, 610, 550, 551) for the data bus (9), and
wherein these are inserted into the data bus (9), and
wherein these form a linear chain of fuses (2950 to 2953 and 2960 to 2967) along at least a part of the data bus (9).

7. The supply network (2900) according to feature 6,
wherein a higher-level computer system (12), which is connected in particular at the beginning of this part of the data bus (9), is configured to determine, by means of auto addressing in cooperation with the control devices (4) of the electronic fuses for each of the control devices (4) of the electronic fuses (2950 to 2953 and 2960 to 2967), a fuse address for controlling the computer cores (2) of the control devices (4) and where applicable to transmit them to the computer cores (2) of the control devices (4) of the electronic fuses (2950 to 2953 and 2960 to 2967).
   Supply Network with Electronic Fuses and Separate Load Shedding

1. A supply network (2900) of a vehicle, in particular according to one or more of the preceding features,
wherein the supply network (2900) comprises a supply line (2910 to 2915), and
wherein the supply network (2900) is annular in parts, and
wherein loads (2920 to 2923) are connected to different power extraction points (2920 to 2923) of the annular supply network (2900), so that they can extract electrical power there from the supply line (2910 to 2915) of the supply network (2900), and/or
wherein power sources (2940 to 2941) are connected to different feed points (2924 to 2925) of the annular supply network (2900) so that they can feed electrical power there into the supply line (2910 to 2915) of the supply network (2900), and
wherein at least on one side in each case corresponding electronic fuses of the fuses (2950 to 2953 and 2960 to 2967), in particular in each case precisely one corresponding electronic fuse of the fuses (2950 to 2953 and 2960 to 2967), are inserted into the supply line (2910 to 2915) of the annular supply network (2900) to the left or right of the corresponding extraction points of electrical power or to the left or right of the corresponding feed points of electrical power, and
wherein the corresponding electronic fuse of the fuses (2950 to 2953 and 2960 to 2967) with its corresponding circuit breaker (17) is inserted into the supply line (2910 to 2915) of the supply line section,
is inserted between two corresponding extraction points of the extraction points (2920 to 2923) for electrical load power of the associated loads of the loads (2930 to 2933);
is inserted between two corresponding feed points of the feed points (2924 to 2924) for electrical power of the associated power sources of the power sources (2940 to 2941), or is inserted between a corresponding feed point of the feed points (2924 to 2924) for electrical power of the associated power source of the power sources (2940 to 2941) and a corresponding extraction point of the extraction points (2920 to 2923) for electrical load power of the associated load of the loads (2930 to 2933).

2. The supply network (2900) according to feature 1,
wherein the supply line of the annular supply network (2900) is interrupted on the left and right of the corresponding extraction points (2920 to 2923) for electrical power on each side of each extraction point of the extraction points (2920 to 2923) by a corresponding electronic fuse of the fuses (2960 to 2967), and/or
wherein the supply line of the annular supply network (2900) is interrupted on the left and right of the corresponding feed points (2924 to 2925) of electrical power on each side of each feed point of the feed points (2924 to 2925) by a corresponding electronic fuse of the fuses (2950 to 2953).

3. The supply network (2900) according to feature 2,
wherein the two electronic fuses which are closest to a feed point of the feed points (2924 to 2925) or an extraction point of the extraction points (2920 to 2923) or a supply line section of the supply sections (2910 to 2915) are configured to isolate this feed point or this extraction point or this supply line section by opening their circuit breakers (17) if an error of a load of the loads (2930 to 2933) occurs at this extraction point in this supply line section of the supply sections (2910 to 2915) and/or if an error of a power source of the power sources (2940 to 2941) occurs at this feed point in this supply line section of the supply sections (2910 to 2915).

4. The supply network (2900) according to feature 3,
wherein a higher-level computer system (12) is configured to determine the status of the electronic fuses (2960 to 2967 and 2950 to 2953) by response of the computer cores (2) of the control devices (4) of the electronic fuses (2960 to 2967 and 2950 to 2953) via the data bus (9), and
wherein, when a fault or an error is present, the higher-level computer system (12) is configured to determine the position of the fault or of the error in the supply network (2900), and
wherein the higher-level computer system (9) is configured to contain the fault or the error at the determined position by means of an intervention into the supply network (2900), in which the higher-level computer system (12) causes the two electronic fuses of the fuses (2960 to 2967 and 2950 to 2953) of the supply network (2900) which are closest to the position of the fault to open their circuit breakers (17).

5. The supply network (2900) according to feature 4,
wherein the intervention by the higher-level computer system (12) is faster than twice the longest time constant of the power extractions of the loads (2920 to 2923) drawing power from the supply network (2900) at the instant of intervention, and/or
wherein the intervention by the higher-level computer system (12) is faster than twice the longest time constant of the power feeds of the power sources (2940 to 2941) which feed power into the supply network (2900).

6. The supply network (2900) according to feature 4 or 5,
wherein an electronic fuse of the fuses (2950 to 2953 and 2960 to 2967) is configured to record the faults and/or errors in the form of a log table (2970), which may also comprise only a few bits, or a log file (2970), and/or
wherein a higher-level computer system (12) is configured to record the faults and/or the errors in the supply network (2900) and/or the faults and/or the errors of the fuses (2950 to 2953 and 2960 to 2967) in the form of a log table (2970), which may also comprise only a few bits, or a log file (2970).

7. The supply network (2900) according to feature 6,
wherein the control apparatus (4) of the electronic fuse is configured to provide the entries of the log table (2970) or the log file (2970) with a time stamp of a timer unit (35) of the control device (4) of the electronic fuse, and/or)
wherein the higher-level computer system (12) is configured to provide the entries of the log table (2970) or the log file (2970) with a time stamp of a timer unit (1970) of the higher-level computer system (12).

8. The supply network (2900) according to feature 7,
wherein the control device (4) of the electronic fuse is configured to also record with a time stamp in the log table (2970) or the log file (2970) the time from which the fault was no longer present, and/or wherein the higher-level computer system (12) is configured to also record with a time stamp in the log table (2970) or the log file (2970) the time from which the fault was no longer present.

9. The supply network (2900), in particular according to any of features 7 or feature 8,
wherein a higher-level computer system (12) is configured, regularly or in the event of a fault or an error, to read out the log table (2970) or the log file (2970) of a fuse of the fuses (2950 to 2953 and 2960 to 2963) from this electronic fuse via the data bus (9).

10. The supply network (2900) according to feature 9,
wherein the higher-level computer system (12) is configured to identify—with the aid of one or more of its log tables (2970) or one or more of its log files (2970) and/or with the aid of one or more log tables (2970) or one or more log files (2970) of one or more electronic fuses of the fuses (2950 to 2953 and 2960 to 2967)—potentially affected sensors and measuring systems supplied with electrical power by the supply network (2900) and to mark or discard the measured values acquired thereby in the relevant time period as potentially incorrect.
   Electronic Fuse with Hot Plug Detection

1. A supply network (200) for supplying electrical loads (210 to 213 and 220 to 223 and 230 to 233) of a vehicle with electrical power, in particular according to one or more of the preceding features,
comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical.
wherein a supply line (2910 to 2015 and 2920 to 2923) of the supply network (3100) has a plug connection of the plug connections (3020 to 2023), a plug or a socket, for the connection and the supply of a load of the loads (2930 to 2033), and/or
wherein a supply line (2910 to 2015 and 2924 to 2925) of the supply network (3100) has a plug connection of the plug connections (3024 to 2025), a plug or a socket for the connection and the power feed of a power source of the power sources (2940 to 2041), and
wherein an electronic fuse of the fuses (3110 to 3113) is inserted in the vicinity of the plug connection of the plug connections (3020 to 3023) for the extraction of power by the electrical load of the electrical loads (2930 to 2933) from the relevant supply line (2910 to 2915 and 2920 to 2925), and/or
wherein an electronic fuse of the fuses (3110 to 3113) is inserted in the vicinity of the plug connection of the plug connections (3020 to 3023) for the feeding of power by the power source of the power sources (2940 to 2941) into the relevant supply line (2910 to 2915 and 2920 to 2925), and
wherein this electronic fuse is configured to detect a hot plug event relating to this plug connection of the plug connections (3020 to 3023),
by the electronic fuse monitoring the transient time characteristic of the voltage of the potential of a node of the circuit breaker (17) of this fuse against the potential of a reference node, in particular relative to a ground potential, and/or
by this electronic fuse monitoring the transient characteristic of the current through the circuit breaker (17) of this electronic fuse, and
by the control device (4) of this electronic fuse monitoring one or more of these transient characteristics.

2. The supply network (3100) according to feature 1,
wherein this electronic fuse is configured to switch off the circuit breaker (17) in the event of a hot plug event.

3. The supply network (3100) according to feature 1 or 2,
wherein this electronic fuse is configured to signal a hot plug event via the data bus (9) to a higher-level computer system (12).

3. The supply network (3100), in particular according to feature 2,
wherein an electronic fuse is configured in normal operation to signal—at least at times and/or on request, in particular on request of the higher-level computer system (12) or of an operator (730) by means of the data input and data output means (740)—this normal operation in a manner that is visually recognizable for a human, in particular by means of an illuminant and/or an LED and/or an indicator and/or a display of a data output means (740) of the fuse or of the higher-level computer system (12) and/or as data information via the data bus (9), and/or
wherein an electronic fuse is configured, in the event of an error and/or a fault and/or a hot plug event, to signal this error or this fault or this hot plug event in a manner that is visually recognizable for a human, in particular by means of an illuminant and/or an LED and/or an indicator and/or a display of a data output means (740) of the fuse or of the higher-level computer system (12) and/or as data information via the data bus (9), at least at times and/or on request, in particular on request of the higher-level computer system (12) or of an operator (730) by means of the data input and data output means (740).

4. The supply network according to feature 2 or 3,
wherein the electronic fuse is configured in the event of a hot plug event in the supply network (3100) to transmit a message to a computer (710, 750) of a service provider, and/or
wherein the electronic fuse is configured in the event of a hot plug event in the supply network (3100) of a vehicle to transmit a message to a computer (710) of a vehicle manufacturer or of a service provider immediately or in a time-delayed manner.
   Supply Network with Synchronization of the Timers of the Electronic Fuses

1. A supply network (200) for supplying electrical loads (210 to 213 and 220 to 223 and 230 to 233) of a vehicle with electrical power, in particular according to one or more of the preceding features, comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
wherein control devices (4) of electronic fuses of the supply network (3100) have clocks or timers (35), in particular for creating time stamps for log tables and/or log files, and/or
wherein a higher-level computer system (12) of the supply network has one or more clocks or one or more timers (1970), in particular for creating time stamps for log tables and/or log files, and/or
wherein the higher-level computer system (12) is configured to regularly synchronize clocks and/or timers (35, 1970) in the supply network (3100) by means of a synchronization signal, in particular via the data bus (9).

2. The supply network (3100) according to feature 1,
wherein the synchronization of clocks and/or timers (35, 1970) in the supply network (3100) comprises resetting to a common starting value of these clocks and/or timers (35, 1970), and/or
wherein the synchronization of clocks and/or timers (35, 1970) in the supply network (3100) comprises a correction of the frequency and/or the phase of the oscillators (30) of the electronic fuses (2950 to 2953 and 2960 to 2967 and 3110 to 3113 and 3120 to 3121), in particular by means of a PLL.

3. The supply network (3100) according to feature 1 or 2,
wherein a higher-level computer system (12) causes control devices (4) of electronic fuses (2950 to 2953 and 2960 to 2967 and 3110 to 3113 and 3120 to 3121) to perform optionally the same measurements at the same instants by means of a command via the data bus (9) in broadcasting mode to a plurality of and/or all of these fuses (2950 to 2953 and 2960 to 2967 and 3110 to 3113 and 3120 to 3121), wherein “same instants” relates to the sameness of the clock states of the respective clocks and/or of the timer states of the timers (35) of the different control devices (4) of the different electronic fuses (2950 to 2953 and 2960 to 2967 and 3110 to 3113 and 3120 to 3121).

4. The supply network (3100) according to feature 3,
wherein at least two electronic fuses (2950 to 2953 and 2960 to 2967 and 3110 to 3113 and 3120 to 3121) of the supply network (3100), a first control device (4) of a first electronic fuse, and a second control device (4) of a second electronic fuse of these fuses (2950 to 2953 and 2960 to 2967 and 3110 to 3113 and 3120 to 3121) are configured to carry out a distributed measurement method with synchronous measurements by means of two synchronized local clocks (35) and/or timers (35), wherein the two local clocks (35) and/or timers (35) are each located within the corresponding control device (4) of the at least two electronic fuses.

5. The supply network (3100) according to feature 4,
wherein at least the control devices (4) are configured, if necessary, to transmit the measured values thus detected to a higher-level computer system (12) via the data bus (9), and
wherein a first of the control devices (4) of a first of the electronic fuses can be the higher-level computer system (12), and
wherein the first fuse and the second fuse are connected to one another via one or more supply line sections, and
wherein the higher-level computer system (12) is configured to deduce from the transmitted data a parameter of the supply line section between the first electronic fuse and the second electronic fuse.

6. The supply network (3100) according to feature 5,
wherein the higher-level computer system (12) is configured to deduce the temperature and/or the electrical resistance of one or more supply line sections between the first electronic fuse and the second electronic fuse from the data transmitted via the data bus (9).
   Supply Network with Power-Availability-Controlled Topology Adaptation

1. A supply network (200) for supplying electrical loads (210 to 213 and 220 to 223 and 230 to 233) of a vehicle with electrical power, in particular according to one or more of the preceding features,
comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
wherein the supply network (1100) comprises a higher-level computer system (12), and
wherein the higher-level computer system (12) is configured to determine the power requirement of loads (1121 to 1125) in the supply network (1100), and
wherein the higher-level computer system (12) is configured to determine the power supply capacity of power sources (1150 to 1155) in the supply network (1100), and
wherein the higher-level computer system (12) is configured to reconfigure the supply network (1100) by means of switching electronic fuses (1110 to 1118) via the data bus (9) depending on the determined power requirement and/or the determined power supply capacity and/or the safety requirement, in particular based on data of the vehicle state and/or the vehicle surroundings and/or the state of the occupants and/or other factors which are available to the higher-level computer system (12).
   Supply Network with Topology Control Via Authenticated Commands

1. A supply network (200) for supplying electrical loads (210 to 213 and 220 to 223 and 230 to 233) of a vehicle with electrical power, in particular according to one or more of the preceding features,
comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
wherein the supply network (1100) comprises a higher-level computer system (12), and
wherein the higher-level computer system (12) is configured to switch off sub-supply networks of the supply network (1100) by means of electronic fuses (1110 to 1118) which are inserted in supply branches of the supply network (1100) by means of data messages via the data bus (9), in particular for maintenance purposes.

2. The supply network (1100) according to feature 1,
wherein at least one of the data messages comprises a security code which enables the disconnection.

3. The supply network (1100) according to feature 2,
wherein a server (710) of a service provider or of the automobile manufacturer or of a subcontractor of the automobile manufacturer is configured to transmit the security code or data for generating the security code by means of the higher-level computer system (12) or control devices (4) of the electronic fuses (1110 to 1118) to the higher-level computer system (12) or a control device (4) of the electronic fuse (1110 to 1118).

4. The supply network (1100) according to any of features 1 to 3
wherein the data bus (9) is provided directly or indirectly, for example via gateways or the like, with a terminal (740) for an input to reconfigure the supply network (1100) by means of the electronic fuses.

5. The supply network (1100) according to feature 3 and 4,
wherein the terminal (740) is configured to serve also for the transmission of authentication data to a server (710) of the automobile manufacturer or a subcontractor of the automobile manufacturer,
wherein the authentication data may comprise, in particular, authentication data of the operating person (730) and/or authentication data of the organization for which the person (730) is employed, and/or authentication data of the vehicle, and/or authentication data of the car key of the vehicle, and/or similar authentication data, and
wherein the terminal (740) is configured to obtain the security code from the server (710) of the automobile manufacturer or a subcontractor of the automobile manufacturer depending on the authentication data.

### AI-Controlled Topology Adaptation of a Supply Network

1. A supply network (200) for supplying electrical loads (210 to 213 and 220 to 223 and 230 to 233) of a vehicle with electrical power, in particular according to one or more of the preceding features,
comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
wherein a control device (4) of a disconnecting electronic fuse of the supply network (1100) is configured to de-energize or be able to de-energize a sub-supply network of the supply network (1100), and thus to be able to isolate it, by means of a circuit breaker (17) of the electronic fuse.

2. The supply network (1100) according to feature 1,
wherein at least one electronic fuse is provided in the sub-supply network that can be isolated in this way, which electronic fuse is configured to short-circuit a sub-supply network isolated by opening the circuit breaker (17) of this electronic fuse, by closing the further circuit breaker (17′) of this electronic fuse with a reference voltage line, in particular a ground line, and thus discharge it or bring it to a defined potential.

3. A supply network (200) for supplying electrical loads (210 to 213 and 220 to 223 and 230 to 233) with electrical power, in particular according to one or more of the preceding features,
comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
comprising a higher-level computer system (12),
wherein, in the event of a system emergency operation scenario, the higher-level computer system (12) adapts the current consumption of a load of the loads (1121 to 1125) of the supply network (1100) to the weakest supply line in the path between one or more power sources of the power sources (1150 to 1155) of the supply network (1100) on the one hand, and this load of the loads (1121 to 1125), on the other hand, by reconfiguration or operating parameter change of this load by means of a or the data bus (9), and/or
wherein, in the event of a system emergency operation scenario, the higher-level computer system (9) adapts the current supply capacity of a power source of the power sources (1150 to 1155) of the supply network (1100) to the weakest supply line in the path between this power source of the power sources (1150 to 1155) of the supply network (1100), on the one hand, and loads of the loads (1121 to 1125) of the supply network (1100) by reconfiguration or operating parameter change of this power source of the power sources (1150 to 1155) of the supply network (1100).

4. The supply network (1100) according to feature 3,
wherein the higher-level computer system (12) initiates a configuration change of the supply network (1100) by corresponding commands via one or more data buses (9) to electronic fuses (1110 to 1118) of the supply network (1100), and
wherein the higher-level computer system (12) first determines how much power a load of the loads (1121 to 1125) of the supply network (1100), which load is affected by the configuration change of the supply network (1100), may consume in order not to overload the supply network (1100) at any point, and
wherein the higher-level computer system (12) communicates to this relevant load of the loads (1121 to 1125) of the supply network (1100) how much power this load of the loads (1121 to 1125) of the supply network (1100) may consume from the supply network (1100), and/or
wherein, secondly, the higher-level computer system (12) determines how much power a power source of the power sources (1150 to 1155) of the supply network (1100), which power source is affected by the configuration change of the supply network (1100), may supply in order not to overload the supply network (1100) at any point and
wherein the higher-level computer system (12) of this relevant power source of the power sources (1150 to 1155) of the supply network (1100) communicates how much power this power source of the power sources (1150 to 1155) of the supply network (1100) may supply.

5. The supply network (1100) according to feature 4,
wherein a load of the loads (1121 to 1125) of the supply network (1100) has a first state in which it consumes more power, and a second state in which it consumes less power than in the first state, and a third state in which it does not consume any power, and/or
wherein a power source of the power sources (1150 to 1155) of the supply network (1100) has a first state in which it supplies more power, and a second state in which it supplies less power than in the first state, and a third state in which it does not supply any power.

6. A supply network (200) for supplying electrical loads (210 to 213 and 220 to 223 and 230 to 233) with electrical power, in particular according to one or more of the preceding features, comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
wherein one or more computer cores (2) of control devices (4) of electronic fuses of the electronic fuses (1110 to 1118) in the supply network (1100) are configured to determine measured values by means of measuring means of these electronic fuses (1100 to 1118), and
wherein the computer cores (2) of these control devices (4) of these electronic fuses of the electronic fuses (1110 to 1118) in the supply network (1100) are configured to transmit these measured values to a higher-level computer system (12) via a data bus (9), and
wherein the higher-level computer system (12) is configured to implement a neural network model, and
wherein the higher-level computer system (12) is configured to use the determined measured values and/or values dependent thereon as input values of the neural network model, and
wherein at least the switching state of a circuit breaker (17) of an electronic fuse (1110 to 1118) in the supply network (1100) and/or at least one data message of the higher-level computer system (12) to a different computer system (710, 750, 740) or a signaling of the higher-level computer system (12) to a user (730) depends on an output signal and/or output value of the neural network model.

7. The supply network (1100) according to feature 6,
wherein the neural network model has been trained and parameterized prior to use in the higher-level computer system (2) of the fuse with suitable training data from the development time of one or more model laboratory supply networks.

8. The supply network (1100) according to feature 7,
wherein the higher-level computer system (12) is configured to detect, by means of an output signal and/or an output value of the neural network model, a possibly imminent or already occurred failure of one or more loads of the loads (1121 to 1125) and/or a possibly imminent or already occurred failure of one or more power sources (1150 to 1155) and/or a possibly imminent or already occurred failure of one or more supply lines and/or supply line sections (1160 to 1183), and/or a possibly imminent or already occurred failure of one or more electronic fuses (1110 to 1118), or a different possibly imminent or already occurred defect of the supply network (1100) and/or of one or more of the device parts of the supply network (1100).

### Spectral-Controlled Topology Adaptation of a Supply Network

1. A supply network (200) for supplying electrical loads (210 to 213 and 220 to 223 and 230 to 233) of a vehicle with electrical power (FIG. 7)
comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
wherein one or more electronic fuses of the electronic fuses (1110 to 1118) of the supply network (1100) comprise means for detecting the corresponding time characteristic of the corresponding electrical current (29) through the corresponding circuit breaker (17) of the corresponding electronic fuse of the electronic fuses (1110 to 1118), and
wherein these means are configured to detect, at least at times, the time characteristic of the corresponding electrical current (29) through the corresponding circuit breaker (17) of the relevant electronic fuse of the electronic fuses (1110 to 1118).

2. A supply network (200) for supplying electrical loads (210 to 213 and 220 to 223 and 230 to 233) with electrical power (FIG. 7)
comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
wherein at least one electronic fuse of the electronic fuses (1110 to 1118) of the supply network (1100) comprises means for detecting the time characteristic of the voltage between a terminal (26, 27, 28) of the corresponding circuit breaker (17) of the corresponding electronic fuse of the electronic fuses (1110 to 1118) on the one hand and a reference potential on the other hand, and
wherein these means are configured to detect, at least at times, the time characteristic of the voltage between the terminal (26, 27, 28) of the corresponding circuit breaker (17) of the corresponding electronic fuse of the electronic fuses (1110 to 1118) and the reference potential, and/or
wherein at least this electronic fuse of the electronic fuses (1110 to 1118) of the supply network (1100) comprises means for detecting the time characteristic of the voltage between a terminal (26, 27, 28) of the corresponding circuit breaker (17) of the corresponding electronic fuse of the electronic fuses (1110 to 1118), on the one hand, and a further terminal (26, 27, 28) of the corresponding circuit breaker (17) of the corresponding electronic fuse of the electronic fuses (1110 to 1118), on the other hand, and/or
wherein these means are configured to detect, at least at times, the time characteristic of the voltage between the terminal (26, 27, 28) of the corresponding circuit breaker (17) of the corresponding electronic fuse of the electronic fuses (1110 to 1118) and the further terminal (26, 27, 28) of the corresponding circuit breaker (17) of the corresponding electronic fuse of the electronic fuses (1110 to 1118).

2. The supply network (1100) according to feature 1 and/or 2,
wherein control devices (4) of electronic fuses (1110 to 1118) are configured to transmit the data of the detected characteristics via a data bus (9) to a higher-level computer system (12).

3. The supply network (1100, 1700) according to feature 2,
wherein the higher-level computer system (12) is configured to carry out spectral analyses of the data of the characteristics, for example by Fourier or Laplace transform or wavelet transform, and to determine values of the spectra, and
wherein the higher-level computer system (12) is configured, in the event of substantial deviations of the values of the spectra from expected value intervals for the values of the spectra, to deduce the need for preventive maintenance or to perform a signaling to a different computer system (750, 710) or an indicator (740).

4. The supply network (1100) according to feature 2 and/or 3,
wherein the higher-level computer system (12) is configured to carry out spectral analyses of the data of the characteristics, for example by Fourier or Laplace transform or wavelet transform, and to determine values of the spectra, and
wherein the higher-level computer system (2) is configured to evaluate the system availability of device parts of the supply network and/or of the supply network (1100) itself by means of determined spectra and, where applicable, to signal the evaluation result to other computer systems (710, 750, 740, 4) and/or changes parameters of the vehicle depending on this evaluation.

5. The supply network (1100) according to feature 4,
wherein the higher-level computer system (12) is configured to evaluate a load of the loads (1121 to 1125) of the supply network (1100) as “likely available” if the characteristic of current spectra or voltage spectra of measured values of an electronic fuse of the fuses (1110 to 1118) of the supply network (1100), which is associated with this load of the loads (1121 to 1125) of the supply network (1100), matches the expected values within permitted bandwidths, and/or
wherein the higher-level computer system (12) is configured to evaluate a power source of the power sources (1150 to 1155) of the supply network (1100) as “likely available” if the characteristic of current or voltage spectra of measured values of an electronic fuse of the fuses (1110 to 1118) of the supply network (1100), which is associated with this power source of the power sources (1150 to 1155) of the supply network (1100), matches the expected values within permitted bandwidths.

### Prioritized Topology Adaptation of a Supply Network Before an Anticipated Accident of a Vehicle

1. A supply network (200) for supplying electrical loads (210 to 213 and 220 to 223 and 230 to 233) of a vehicle with electrical power, in particular according to one or more of the preceding features, comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
wherein a higher-level computer system (12) is configured to switch off, by means of electronic fuses of the fuses (1110 to 1118) of the supply network (1100), supply sub-networks of the supply network (1100) which are not required and/or dangerous and/or endangered in the supply network (1100), by means of corresponding commands to control devices (4) of electronic fuses of the fuses (1110 to 1118) of the supply network (1100), which commands are transmitted via the data bus (9),
if a controller of the vehicle and/or the higher-level computer system (12) have come to the conclusion that an accident of the vehicle is likely.

2. The supply network (1100) according to feature 1,
wherein a higher-level computer system (12) or a controller is configured to calculate the probability of an accident of the vehicle and to conclude that an accident of the vehicle is likely if the calculated probability is above a threshold for such an accident.

3. A supply network (200) for supplying electrical loads (210 to 213 and 220 to 223 and 230 to 233) with electrical power, in particular according to one or more of the preceding features,
comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
wherein a higher-level computer system (12) is configured to pre-calculate a future current consumption of one or more loads of the loads (1121 to 1125) of the supply network (1100), and
wherein the higher-level computer system (12) is configured to open one or more circuit breakers (17) of one or more electronic fuses of the fuses (1110 to 1118) of the supply network (1100) in one or more sub-trees of the supply network (1100) via a data bus (9) if, for whatever reason, the higher-level computer system (12) expects a future increased current consumption of a load of the loads (1121 to 1125) of the supply network (1100) and/or
wherein a higher-level computer system (12) is configured to pre-calculate a future power supply of one or more power sources of the power sources (1150 to 1155) of the supply network (1100), and/or wherein the higher-level computer system (12) is configured to open one or more circuit breakers (17) of one or more electronic fuses of the fuses (1110 to 1118) of the supply network (1100) in one or more sub-trees of the supply network (1100) via a data bus (9) if, for whatever reason, the higher-level computer system (2) expects a future increased, possibly critical, current feed or voltage feed of a power source of the power sources (1150 to 1155) of the supply network (1100).

4. A supply network (200) for supplying electrical loads (210 to 213 and 220 to 223 and 230 to 233) with electrical power, in particular according to one or more of the preceding features,
comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
wherein electronic fuses of the fuses (1110 to 1118) of the supply network (1100) are configured to detect the voltage between a first terminal (26) of its circuit breaker (17), which is optionally on the power-source side, and a reference potential (201) by means of suitable measuring means of these fuses of the fuses (1110 to 1118) of the supply network (1100), and
wherein the control devices (4) of these electronic fuses of the fuses (1110 to 1118) of the supply network (1100) are configured to compare the measured voltage values to predefined threshold values, and
wherein the control devices (4) of these electronic fuses of the fuses (1110 to 1118) of the supply network (1100) are configured to open the circuit breaker of the electronic fuse when these threshold values are undershot,
wherein, the predefined threshold values first prioritize the disconnection of less important electrical loads of the loads (1121 to 1125) of the supply network (1100) prior to the disconnection of important and/or more important electrical loads of the loads (1121 to 1125) of the supply network (1100), in particular prior to the disconnection of safety-relevant electrical loads of the loads (1121 to 1125) of the supply network (1100), and/or
wherein, the predefined threshold values secondly prioritize the disconnection of less important electrical power sources of the power sources (1150 to 1155) of the supply network (1100) prior to the disconnection of important and/or more important electrical power sources of the power sources (1150 to 1155) of the supply network (1100), in particular prior to the disconnection of safety-relevant electrical power sources of the power sources (1150 to 1155) of the supply network (1100).

5. A supply network (200) for supplying electrical loads (210 to 213 and 220 to 223 and 230 to 233) with electrical power, in particular according to one or more of the preceding features,
comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
wherein the supply network (3200) has supply sub-networks (3202) with voltages less than 50 V (LV networks) and supply sub-networks (3201) with voltages greater than 50 V (HV networks), and
wherein the supply network (3200) comprises a data bus (9) which is implemented as an optical data bus (3290) in the range of the voltage domain limits between supply sub-networks (3202) with voltages less than 50 V, on the one hand, and supply sub-networks (3201) with voltages greater than 50 V.

6. A supply network (200) for supplying electrical loads (210 to 213 and 220 to 223 and 230 to 233) with electrical power, in particular according to one or more of the preceding features,
comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
wherein the supply network (3200) has supply sub-networks (3202) with voltages less than 50 V (LV networks) and supply sub-networks (3201) with voltages greater than 50 V (HV networks), and
wherein the supply network (3200) comprises a data bus (9) which is implemented in the range of the voltage domain limits between supply sub-networks (3202) having voltages less than 50 V on the one hand and supply sub-networks (3201) having voltages greater than 50 V as a data bus with potential isolation (3290).

7. A supply network (200) for supplying electrical loads (210 to 213 and 220 to 223 and 230 to 233) with electrical power, in particular according to one or more of the preceding features,
comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
wherein at least two electronic fuses (3210, 3211, 3212) are cascaded within a supply line (3260, 3262, 3263, 3264), which fuses divide the supply line (3260, 3262, 3263, 3264) into different supply line sections (3260, 3262, 3263, 3264).

8. The supply network (3300) according to feature 7,
wherein firstly the electrical connection point (2920) of a more important load (2930) to a supply line (2910) of the supply network (3300) is arranged in the part of the supply line (2910, 2911) located closer to the power source (2940), while the electrical connection point (2921) of a less important load (2931) to the supply line (2911) is arranged in the part of the supply line (2910, 2911) located further away from the power source (2940), and
wherein an electronic fuse (2961, 2962) is located between the electrical connection point (2920) of the more important load (2930) to the supply line (2910, 2911) and the electrical connection point (2921) of the less important load (2931) to the supply line (2915, 2910, 2911), and
wherein this electronic fuse (2961, 2962) is configured to disconnect the less important load (2931) and/or the supply line section (2911) of the less important load (2931) from the supply network (2915, 2910, 2911) in the event of an error or a fault of the less important load (2931) or in the event of an error or a fault of the supply line section (2911) of the less important load (2931), and
wherein the supply network is configured to continue to supply the more important load (2930) with electrical power in this case, and/or
wherein secondly the electrical connection point (2924) of a more important power source (2940) to a supply line (2915, 2910, 2911) of the supply network (3300) is arranged in the part of the supply line (2915, 2910, 2911) located closer to one or more loads (2930, 2931), while the electrical connection point (2925) of a less important power source (2925) to the supply line (2915, 2910, 2911) is arranged in the part of the supply line (2915, 2910, 2911) located further away from the one or more loads (2930, 2931), and
wherein an electronic fuse (2951, 2952) is located between the electrical connection point (2924) of the more important power source (2940) to the supply line (2915, 2910, 2911) and the electrical connection point (2925) of the less important power source (2941) to the supply line (2915, 2910, 2911), and
wherein this electronic fuse (2951, 2952) is configured to disconnect the less important power source (2941) from the supply network (3300) in the event of an error and/or a fault of the less important power source (2941) or the supply line section (2915) of the less important power source (2941), and
wherein the supply network (3300) is configured to continue to extract electrical power from the more important power source (2940) in this case.

9. A supply network (200) for supplying electrical loads (210 to 213 and 220 to 223 and 230 to 233) with electrical power, in particular according to one or more of the preceding features,
comprising one or more power sources (250, 251), and
comprising a plurality of loads (210 to 213 and 220 to 223 and 230 to 233), and
comprising a plurality of electronic fuses (214 to 217, 225 to 228, 235 to 238, 250, 251), and
wherein the loads (210 to 213 and 220 to 223 and 230 to 233) are connected to the one or more power sources (250, 251) by means of supply lines (245, 240, 241, 242, 243), and
wherein the loads (210 to 213 and 220 to 223 and 230 to 233) and the one or more power sources (250, 251) together with the supply lines (245, 240 to 243) are connected to one another in a tree structure or a network, and
wherein the tree structure or the network comprises sub-trees or sub-networks (e.g., 240, 220, 221), and
wherein fuses (214 to 217, 225 to 228, 235 to 238, 250, 251) are inserted into supply lines, so that these sub-trees of the tree structure can disconnect from the rest of the tree structure or can connect to this remaining tree structure, or wherein fuses (214 to 217, 225 to 228, 235 to 238, 250, 251) are inserted into supply lines, so that these sub-networks of the network can disconnect from the rest of the network or can connect to this remaining network, and
wherein one or more electronic fuses (214 to 217, 225 to 228, 235 to 238, 250, 251) each have at least one data interface (280 to 293) per electronic fuse (214 to 217, 225 to 228, 235 to 238, 250, 251) which can be optical and
wherein the supply network (3300) comprises at least one supply line (2915, 2910, 2911), and
wherein the supply network (3300) comprises a first electrical load (2930), and
wherein the supply network (3300) comprises a second electrical load (2931), and
wherein the supply network (3300) comprises a power source (2940), and
wherein the first electrical load (2930) is connected to the supply line (2915, 2910, 2911) at a first connection point (2920) via a first electronic fuse (3110), and
wherein the second electrical load (2931) is connected to the supply line (2915, 2910, 2911) at a second connection point (2921) via a second electronic fuse (3111), and
wherein the first connection point (2920) is spaced apart from the second connection point (2921), and
wherein the first connection point (2920) is closer to the power source (2940) than the second connection point (2921) and
wherein the control device (4) of the first electronic fuse (3110) is configured to switch off the circuit breaker (17) of the first electronic fuse (3110), in relation to the time of a switch-off event, with a shorter first delay time than the delay time with which the control device (4) of the second electronic fuse (3111) is configured, in relation to the time of the switch-off event, to switch off the circuit breaker (17) of the second electronic fuse (3111).

### Time-Constant-Controlled Load Shedding of Prioritized Loads of a Supply Network

1. A supply network (3300) of a vehicle, in particular according to one or more of the preceding features,
wherein the supply network comprises at least one supply line (2915, 2910, 2911), and
wherein the supply network (3300) comprises a first electrical power source (2940), and
wherein the supply network (3300) comprises a second electrical power source (2941), and
wherein the supply network (3300) comprises one or more electrical loads (2930, 2931), and
wherein the first electrical power source (2940) is connected to the supply line at a first connection point (2924), and
wherein the second electrical power source (2941) is connected to the supply line (2915, 2910, 2911) at a second connection point (2925), and
wherein the first connection point (2924) is spaced apart from the second connection point (2925), and
wherein the first connection point (2924) is closer to the one or more electrical loads (2930, 2931) than the second connection point (2925), and
wherein the control device (4) of the first electronic fuse (3110) is configured to switch off the circuit breaker (17) of the first electronic fuse (3110), in relation to the time of a switch-off event, with a longer delay time than the delay time with which the control device (4) of the second electronic fuse (3111) is configured, in relation to the time of the switch-off event, to switch off the circuit breaker (17) of the second electronic fuse (3111).

2. The supply network (3300), in particular according to one or more of the preceding features,
wherein the supply network comprises at least one supply line (2915, 2910, 2911), and
wherein the supply network (3300) comprises a first electrical power source (2940), and
wherein the supply network (3300) comprises a second electrical power source (2941), and
wherein the supply network (3300) comprises one or more electrical loads (2930, 2931), and
wherein the first electrical power source (2940) is connected to the supply line at a first connection point (2924), and
wherein the second electrical power source (2941) is connected to the supply line (2915, 2910, 2911) at a second connection point (2925), and
wherein the first connection point (2924) is spaced apart from the second connection point (2925), and
wherein the first connection point (2924) is closer to the one or more electrical loads (2930, 2931) than the second connection point (2925), and
wherein the control device (4) of the first electronic fuse (3110) is configured to switch off the circuit breaker (17) of the first electronic fuse (3110), in relation to the time of a switch-off event, with a shorter delay time than the delay time with which the control device (4) of the second electronic fuse (3111) is configured, in relation to the time of the switch-off event, to switch off the circuit breaker (17) of the second electronic fuse (3111).

### Ground Offset Compensation in a Supply Network for Correcting Voltage Measured Values

1. The method (3400) for active power management in a supply network (1100) of a vehicle with electrical fuses (1110 to 1118) for supplying electrical loads (1121 to 1125) in this supply network (1100) with electrical power of one or more electrical power sources (1150 to 1155), in particular according to one or more of the preceding features, comprising the steps of:
detecting (3410) the value of the electrical currents (29) through one or more circuit breakers (17) of one or more electronic fuses of the fuses (1110 to 1118) of the supply network (1100), and/or
detecting (3420) the value of the voltage difference between a terminal (26, 27, 28) of this circuit breaker (17) against a reference potential (201) of a reference potential contact, and
calculation (3430) of the theoretical ground offset as a result of the energization of the circuit breakers by the corresponding computer core of the corresponding control device of the corresponding fuse by means of modeling and
correcting (3440) the corresponding voltage measured values by the theoretical ground offset.

2. The method (3400) according to feature 1, comprising the step of:
deducing (3450) state parameters of supply line sections of the supply line sections (3260 to 3278) with the aid of the parameters thus detected, such as current values and voltage values.

3. The method (3400) according to feature 2, comprising the step of:
wherein a state parameter is a resistance load per unit length of a supply line section of the supply line sections (3260 to 3278).

4. The method (3400) according to feature 2 or 3,
wherein a state parameter is the temperature of a supply line section of the supply line sections (3260 to 3278).

5. The method according to any of features 2 to 4, comprising the step of:
determining (3460) the temperature with the aid of a known temperature coefficient of the line material of the supply line section of the supply line sections (3260 to 3278) and of the known design data.

### Setting Equipment Variants of a Supply Network

1. The method (3500) for operating a vehicle, in particular according to one or more of the preceding features, comprising the steps of:
providing (3505) the vehicle having a supply network (3300) for supplying electrical loads (2930, 2931) of the vehicle with electrical power
wherein the vehicle has one or more power sources (2940, 2941), one or more loads (2930, 2931) and a plurality of electronic fuses (2960 to 2963 and 2959 to 2953), and
wherein the loads (2930, 2931) are connected to the one power source or the plurality of power sources (2940, 2941) by means of supply lines (2915, 2910, 2911), and
wherein the loads (2930, 2931) and the power sources (2940, 2941) are interconnected together with the supply lines (2915, 2910, 2911) in a tree structure (3300) or a network, and
wherein the tree structure comprises sub-trees or the network comprises sub-networks ([2915, 3015, 3025, 2941]; [2940, 3024, 3014, 2910, 3010, 3020, 2930]; [2911, 3011, 2931]), and
wherein electronic fuses (2960 to 2963 and 2959 to 2953) are first inserted into supply lines so that these sub-trees of the tree structure can disconnect from the rest of the tree structure or can connect to this remaining tree structure, and/or
wherein the electronic fuses (2916, 2962, 2951, 2952) are secondly inserted into supply lines so that these sub-networks ([2915, 3015, 3025, 2941]; [2911, 3011, 3021, 2931]) of the network (3300) can disconnect from the rest of the network (3300) or connect to this remaining network (3300),
so that these sub-networks ([2915, 3015, 3025, 2941]; [2911, 3011, 3021, 2931]) and/or sub-trees after disconnection essentially no longer supply any power and/or consume any power;
programming (3510) of certain equipment variants,
wherein a first equipment variant of these equipment variants of the vehicle differs from a second equipment variant of these equipment variants of the vehicle,
in that at least one electronic fuse of these electronic fuses (2916, 2962, 2951, 2952) disconnects a sub-tree of the tree structure or a sub-network ([2915, 3015, 3025, 2941]; [2911, 3011, 3021, 2931]) of the network (3300) in the first equipment variant from the rest of the tree structure or the rest of the network (3300), and in the second equipment variant connects to the rest of the tree structure or to the rest of the network (3300),
so that the power source is configured to be able to completely supply this sub-tree or this sub-network ([2915, 3015, 3025, 2941]; [2911, 3011, 3021, 2931]) with electrical power of the power source only in the second equipment variant, or that this sub-tree or this sub-network ([2915, 3015, 3025, 2941]; [2911, 3011, 3021, 2931]) can have an electrical power consumption of one or more electrical loads (2931) of the relevant sub-network ([2915, 3015, 3025, 2941]; [2911, 3011, 3021, 2931]) only in the second equipment variant.

2. The method (3500) according to feature 1, comprising the step of:
programming (3510) of certain equipment variants by transmitting programming data to control devices (4) of electronic fuses via a data bus (9).

3. The method (3500) according to feature 2, comprising the step of:
encrypted communication via the control data bus (9) for programming the equipment variants and/or communication via the control data bus (9) for programming the equipment variants only after a password has been transmitted to the control device (4) of the corresponding electronic fuse.

4. The method (3500) according to feature 3,
wherein the communication between the control device (4) of the electronic fuse and its surroundings takes place with encryption via such data connections (9) with a PQC method. (PQC=post quantum cryptography);

5. The method (3500) according to any of features 1 to 4, characterized in that
the activation and/or deactivation of an electronic fuse, i.e., the switching on or off of the circuit breaker (17) of the electronic fuse, requires the transmission of at least one digital password from the computer core (2) of the control device (4) of a different electronic fuse and/or from the computer (12) of a controller, i.e., for example from the higher-level computer system (12), and/or from a server (710) of a service provider and/or of an automobile manufacturer via a data bus (9) to the control device (4) of the electronic fuse.

6. The method (3500) according to any of features 1 to 5,
wherein a supply voltage line (6) and/or a supply line section of the supply network is a part of the data bus (9), and
wherein the communication via this data bus (9) takes place at least in sections via power-line communication, and
wherein this communication of the at least two control devices (4) of two electronic fuses among one another and/or
between a control device (4) of an electronic fuse, on the one hand, and a higher-level computer system (12), on the other hand, takes place via this data bus (9).

7. The method (3500) according to any of features 1 to 6,
wherein, after the change of the equipment variant due to programming of a new equipment variant, at least two electronic fuses, better all electronic fuses affected by the change of the equipment variant, change their switching state in a time-delayed manner relative to one another, and essentially do not simultaneously change their switching state.

8. The method according to any of features 1 to 7,
wherein a higher-level computer system (12) of the vehicle programs a predefined sequence of equipment variants at certain time intervals in predetermined operating states.

9. The method according to feature 8,
wherein, after the vehicle is switched on, the higher-level computer system (12) transfers the vehicle from the parking state into the driving state by programming at least two equipment variants at two different programming instants within a time interval different from 0 s between the programming instants.

10. The method according to feature 9,
wherein the higher-level computer system (12) transmits a start signal to the control devices (4) of electronic fuses, whereupon they generate and set the sequence of the equipment variants for the corresponding electronic fuse.

11. The method according to feature 10,
wherein the higher-level computer system (12), before the start signal is transmitted, programs and/or transmits to the control devices (4) of the affected fuses beforehand the values of waiting times which the control devices (4) of the electronic fuses are intended to wait between the arrival of the start signal from the higher-level computer system (12) and the closing or opening of its corresponding circuit breaker (17).

12. The method according to feature 10 or 11,
wherein values of waiting times are programmed into a non-volatile memory (14) of the control devices (4) of electronic fuses,
wherein this programming is done at the factory and/or by another computer (710) and/or by the higher-level computer system (12) and/or a different computer of the vehicle, thus in some cases also by the control device (4) of a different electronic fuse.

13. The method (3500) according to any of features 1 to 12, comprising the additional steps of:
transmitting (3520) authentication data to a server (710) of an activation code provider;
verification (3525) of the transmitted authentication data;
generating (3530) an activation code with the aid of these or other authentication data according to an established method and/or providing the generated or a ready-at-hand activation code;
if necessary, purchasing (3535) an activation code via a data connection to the server 710 of the activation code provider;
transmitting (3540) the activation code to the vehicle, and/or
transmitting (3545) an activation code for an equipment variant on the basis of the received activation code to the control device (4) of the electronic fuse, and
programming (3510) the activated equipment variant.

14. The method according to feature 13, comprising the additional step of:
detecting (3550) and determining the power which flows through an electronic fuse in a supply sub-branch ([2915, 3015, 3025, 2941]; [2911, 3011, 3021, 2931]) of the supply tree (3300) as a measured value of the amount of power and/or the underlying measured values in the electronic fuse;
reading out (3555) the measured value of the determined amount of power and/or the underlying measured values from the electronic fuse;
transmitting (3560) the measured value of the determined amount of power and/or the underlying measured values via a data transmission path (720), which is optionally encrypted, from the higher-level computer system (12) to a computer (750) of a service provider, for example a utility company or a subcontractor thereof,
creating (3565) an invoice on the basis of the transmitted measured value of the determined amount of power and/or the underlying measured values.

15. The method according to any of features 1 to 14, comprising the additional steps of:
determining (3570) the topology of the supply network using electronic fuses of the supply network;
comparing (3575) the determined topology of the supply network to the valid or to-be-set equipment variant for plausibility checking of the equipment variant or for the admissibility of the determined topology of the supply network.

16. The method according to feature 15, comprising the additional step of:
detecting values for currents through circuit breakers of electronic fuses in the supply network;
calculating or providing expected value intervals for currents through circuit breakers of electronic fuses in the supply network;
plausibility checking of the supply network with the supply lines and the loads and the power sources and the electronic fuses by comparing the detected current values to those of the calculated or provided expected value intervals.

17. The method according to feature 15 or 16, comprising the additional step of:
deducing a manipulation of the supply network and/or deducing a manipulation of an electrical load in the supply network and/or deducing a manipulation of an electrical power source in the supply network and/or deducing a manipulation of a supply line in the supply network and/or deducing the manipulation of an equipment variant if the plausibility check has failed.

18. The method for lowering the starting current (in-rush current), in particular according to one or more of the preceding features,
detecting the start current by means of current measuring means;
changing the equipment variant to an equipment variant with increased current consumption of other loads if the magnitude of the starting current is below a threshold value after a waiting time has elapsed.
   Control Device for a Fuse with Emergency Power Supply

1. A control device (4) for the fuse (1) of a vehicle for operating an electronic fuse (1), in particular according to one or more of the preceding features,
wherein this system basis chip functionality provides all functions needed to be able to safely operate a computer core (2) in the control device (4) of the electronic fuse (1) and the data interface (10) of the control device (4) of the fuse (1), and
the system basis chip functionality comprises
a boost converter (5) for
the voltage supply of the safety-relevant device parts of the control device (4), and
charging an internal or external power reserve (8)
wherein, during normal operation, the boost converter (5) processes an externally provided operating voltage (6) of one or more external power sources, and
wherein, in the event of failure of the externally provided operating voltage (6), the control device (4) and/or the fuse (1) switches into an emergency operating mode, and the power reserve (8) takes over the supply of power to the control device (4) of the fuse (1), and
wherein, in the emergency operating mode, the boost converter (5) or a functionally equivalent second voltage regulating device provides an emergency power supply (7) to the safety-relevant device parts of the control device (4) of the fuse (1) and extracts the power required for this from the power reserve (8).

### Control of Electronic Fuses in a Load Network by Means of Encrypted Commands

1. An electronic fuse (1) of a vehicle, in particular according to one or more of the preceding features,
wherein the electronic fuse (1) comprises a control device (4), and
wherein the electronic fuse (1) comprises a circuit breaker (17), and
wherein the control device (4) comprises a computer core (2), and
wherein the control device (4) comprises a non-volatile memory (14), and
wherein the control device (4) comprises an internal data bus (11), and
wherein the computer core (2) is configured to be able to have at least reading access to the non-volatile memory (14) via the internal data bus (11), and
wherein commands of a program and/or program data are stored in the non-volatile memory, and
wherein the computer core is configured to execute the program with the program data in the non-volatile memory (14), and
wherein the commands of the program and/or the program data are encrypted and
wherein the computer core (2) is configured to read the encrypted commands of the program and/or the encrypted program data from the non-volatile memory (14) before the program execution of the commands of the program, and
wherein the computer core (2) is configured to decrypt the read encrypted commands of the program and/or the read encrypted program data before the program execution of the commands of the program to form decrypted commands of the program and/or to form decrypted program data, and
wherein the computer core (2) is configured to store the decrypted commands of the program and/or the decrypted program data in a memory (14, 15) of the control device (4) before the program execution, and
wherein the computer core (2) is configured to execute the decrypted commands of the program from the memory (14, 15) of the control device (4) and/or to use the decrypted program data from the memory (14, 15) of the control device (4) during the execution of program commands.

2. The electronic fuse (1) according to feature 1,
wherein the computer core (2) is configured to carry out the encryption using a random number generator (60) (RNG) and/or a pseudo-random number generator (60) (PRNG) and/or a true random number generator (TRNG) and/or a quantum random number generator (QRNG).

3. The electronic fuse (1) according to feature 1 or 2,
wherein the control device (4) comprises a data bus interface (10, 610, 550, 551), and
wherein an external computer, for example a higher-level computer system (12) and/or the server (710) of a service provider, can access the non-volatile memory (14) via the data bus interface (10, 610, 550, 551), and
wherein the external computer can read data, which can also comprise the commands of the program and/or the program data, from the non-volatile memory (14).

4. The electronic fuse (1) according to feature 3,
wherein the control device (4) is configured such that the external computer can have only reading access to predetermined regions of the non-volatile memory (14) if the external computer has previously transmitted a correct password to the computer core (2) of the control device (4) and/or to a different part of the control device (4), or if the external computer has previously authenticated itself in a different manner to the computer core (2) and/or to a different part of the control device (4) as authorized with regard to access to these predetermined regions of the non-volatile memory (14), and if a verification of this authentication by the computer core (2) and/or a different part of the control device (4) was successful.

5. The electronic fuse (1) according to any of features 1 to 4,
wherein the control device (4) comprises a data bus interface (10, 610, 550, 551), and
wherein an external computer, for example a higher-level computer system (12) and/or the server (710) of a service provider, can access the volatile memory (15) via the data bus interface (10, 610, 550, 551), and
wherein the external computer can read data, which can also comprise the commands of the program and/or the program data, from the volatile memory (15).

6. The electronic fuse (1) according to feature 5,
wherein the control device (4) is configured such that the external computer can have only reading access to predetermined regions of the volatile memory (15) if the external computer has previously transmitted a correct password to the computer core (2) of the control device (4) and/or to a different part of the control device (4), or if the external computer has previously authenticated itself in a different manner to the computer core (2) and/or to a different part of the control device (4) as authorized with regard to access to these predetermined regions of the non-volatile memory (14), and if a verification of this authentication by the computer core (2) and/or a different part of the control device (4) was successful.

7. The electronic fuse (1) according to any of features 1 to 6,
wherein the control device (4) comprises a data bus interface (10, 610, 550, 551), and
wherein an external computer, for example a higher-level computer system (12) and/or the server (710) of a service provider, can access the non-volatile memory (14) via the data bus interface (10, 610, 550, 551), and
wherein the external computer can write data, which can also comprise the commands of the program and/or the program data, to the non-volatile memory (14).

8. The electronic fuse (1) according to feature 7,
wherein the control device (4) is configured such that the external computer can have only write access to predetermined regions of the non-volatile memory (14) if the external computer has previously transmitted a correct password to the computer core (2) of the control device (4) and/or to a different part of the control device (4), or if the external computer has previously authenticated itself in a different manner to the computer core (2) and/or to a different part of the control device (4) as authorized with regard to access to these predetermined regions of the non-volatile memory (14), and if a verification of this authentication by the computer core (2) and/or a different part of the control device (4) was successful.

9. The electronic fuse (1) according to any of features 1 to 8,
wherein the control device (4) comprises a data bus interface (10, 610, 550, 551), and
wherein an external computer, for example a higher-level computer system (12) and/or the server (710) of a service provider, can access the volatile memory (15) via the data bus interface (10, 610, 550, 551), and
wherein the external computer can write data, which can also comprise the commands of the program and/or the program data, to the volatile memory (15).

10. The electronic fuse (1) according to feature 9,
wherein the control device (4) is configured such that the external computer can have only write access to predetermined regions of the volatile memory (15) if the external computer has previously transmitted a correct password to the computer core (2) of the control device (4) and/or to a different part of the control device (4), or if the external computer has previously authenticated itself in a different manner to the computer core (2) and/or to a different part of the control device (4) as authorized with regard to access to these predetermined regions of the non-volatile memory (14), and if a verification of this authentication by the computer core (2) and/or a different part of the control device (4) was successful.

### Access Control for Access by an External Computer to the Control Device of an Electronic Fuse

1. An electronic fuse (1) of a vehicle, in particular according to one or more of the preceding features,
wherein the electronic fuse (1) comprises a control device (4), in particular according to feature 1, and
wherein the electronic fuse (1) comprises a circuit breaker (17), and
wherein the control device (4) comprises a computer core (2), and
wherein the control device (4) comprises a non-volatile memory (14), and
wherein the control device (4) comprises an internal data bus (11), and
wherein the computer core (2) is configured to be able to have at least reading access to the non-volatile memory (14) via the internal data bus (11), and
wherein commands of a program and/or program data are stored in the non-volatile memory, and
wherein the computer core is configured to execute the program with the program data in the non-volatile memory (14), and
wherein the control device (4) comprises a data bus interface (10, 610, 550, 551), and
wherein an external computer, for example a higher-level computer system (12) and/or the server (710) of a service provider, can access the non-volatile memory (14) via the data bus interface (10, 610, 550, 551), and
wherein the external computer can read data, which can also comprise the commands of the program and/or the program data, from the non-volatile memory (14), and
wherein the control device (4) is configured such that the external computer can have only reading access to predetermined regions of the non-volatile memory (14) if the external computer has previously transmitted a correct password to the computer core (2) of the control device (4) and/or to a different part of the control device (4), or if the external computer has previously authenticated itself in a different manner to the computer core (2) and/or to a different part of the control device (4) as authorized with regard to access to these predetermined regions of the non-volatile memory (14), and if a verification of this authentication by the computer core (2) and/or a different part of the control device (4) was successful.

2. The electronic fuse (1), in particular according to one or more of the preceding features,
wherein the electronic fuse (1) comprises a control device (4), in particular according to feature 1, and
wherein the electronic fuse (1) comprises a circuit breaker (17), and
wherein the control device (4) comprises a computer core (2), and
wherein the control device (4) comprises a non-volatile memory (14), and
wherein the control device (4) comprises an internal data bus (11), and
wherein the computer core (2) is configured to be able to have at least write access to the non-volatile memory (14) via the internal data bus (11), and
wherein commands of a program and/or program data are stored in the non-volatile memory, and
wherein the computer core is configured to execute the program with the program data in the non-volatile memory (14), and
wherein the control device (4) comprises a data bus interface (10, 610, 550, 551), and
wherein an external computer, for example a higher-level computer system (12) and/or the server (710) of a service provider, can access the non-volatile memory (14) via the data bus interface (10, 610, 550, 551), and
wherein the external computer can write data, which can also comprise the commands of the program and/or the program data, to the non-volatile memory (14), and
wherein the control device (4) is configured such that the external computer can have only write access to predetermined regions of the non-volatile memory (14) if the external computer has previously transmitted a correct password to the computer core (2) of the control device (4) and/or to a different part of the control device (4), or if the external computer has previously authenticated itself in a different manner to the computer core (2) and/or to a different part of the control device (4) as authorized with regard to access to these predetermined regions of the non-volatile memory (14), and if a verification of this authentication by the computer core (2) and/or a different part of the control device (4) was successful.

3. An electronic fuse (1) of a vehicle, in particular according to one or more of the preceding features,
wherein the electronic fuse (1) comprises a control device (4), in particular according to feature 1, and
wherein the electronic fuse (1) comprises a circuit breaker (17), and
wherein the control device (4) comprises a computer core (2), and
wherein the control device (4) comprises a volatile memory (15), and
wherein the control device (4) comprises an internal data bus (11), and
wherein the computer core (2) is configured to be able to have at least reading access to the volatile memory (15) via the internal data bus (11), and
wherein the control device (4) comprises a data bus interface (10, 610, 550, 551), and
wherein an external computer, for example a higher-level computer system (12) and/or the server (710) of a service provider, can access the volatile memory (15) via the data bus interface (10, 610, 550, 551), and
wherein the external computer can read data, which can also comprise the commands of the program and/or the program data, from the volatile memory (15), and
wherein the control device (4) is configured such that the external computer can have only reading access to predetermined regions of the volatile memory (15) if the external computer has previously transmitted a correct password to the computer core (2) of the control device (4) and/or to a different part of the control device (4), or if the external computer has previously authenticated itself in a different manner to the computer core (2) and/or to a different part of the control device (4) as authorized with regard to access to these predetermined regions of the volatile memory (15), and if a verification of this authentication by the computer core (2) and/or a different part of the control device (4) was successful.

4. The electronic fuse (1) of a vehicle, in particular according to one or more of the preceding features
wherein the electronic fuse (1) comprises a control device (4), in particular according to feature 1, and
wherein the electronic fuse (1) comprises a circuit breaker (17), and
wherein the control device (4) comprises a computer core (2), and
wherein the control device (4) comprises a volatile memory (15), and
wherein the control device (4) comprises an internal data bus (11), and
wherein the computer core (2) is configured to be able to have at least write access to the volatile memory (15) via the internal data bus (11), and
wherein commands of a program and/or program data are stored in the non-volatile memory, and
wherein the computer core is configured to execute the program with the program data in the volatile memory (15), and
wherein the control device (4) comprises a data bus interface (10, 610, 550, 551), and
wherein an external computer, for example a higher-level computer system (12) and/or the server (710) of a service provider, can access the volatile memory (15) via the data bus interface (10, 610, 550, 551), and
wherein the external computer can write data, which can also comprise the commands of the program and/or the program data, to the volatile memory (15), and
wherein the control device (4) is configured such that the external computer can have only write access to predetermined regions of the volatile memory (15) if the external computer has previously transmitted a correct password to the computer core (2) of the control device (4) and/or to a different part of the control device (4), or if the external computer has previously authenticated itself in a different manner to the computer core (2) and/or to a different part of the control device (4) as authorized with regard to access to these predetermined regions of the volatile memory (15), and if a verification of this authentication by the computer core (2) and/or a different part of the control device (4) was successful.

5. The electronic fuse (1) according to one or more of features 1 to 4,
wherein the control device (4) comprises a non-volatile memory (14), and
wherein the control device (4) comprises an internal data bus (11), and
wherein the computer core (2) is configured to be able to have at least reading access to the non-volatile memory (14) via the internal data bus (11), and
wherein commands of a program and/or program data are stored in the non-volatile memory (14), and
wherein the computer core (2) is configured to execute the program with the program data in the non-volatile memory (14), and
wherein the commands of the program and/or the program data are encrypted and
wherein the computer core (2) is configured to read the encrypted commands of the program and/or the encrypted program data from the non-volatile memory (14) before the program execution of the commands of the program, and
wherein the computer core (2) is configured to decrypt the read encrypted commands of the program and/or the read encrypted program data before the program execution of the commands of the program to form decrypted commands of the program and/or to form decrypted program data, and
wherein the computer core (2) is configured to store the decrypted commands of the program and/or the decrypted program data in a memory (14, 15) of the control device (4) before the program execution, and
wherein the computer core (2) is configured to execute the decrypted commands of the program from the memory (14, 15) of the control device (4) and/or to use the decrypted program data from the memory (14, 15) of the control device (4) during the execution of program commands.

6. The electronic fuse (1) according to feature 5,
wherein the computer core (2) is configured to carry out the encryption using a random number generator (60) (RNG) and/or a pseudo-random number generator (60) (PRNG) and/or a true random number generator (TRNG) and/or a quantum random number generator (QRNG).

7. A system (55100) for providing an application by means of a SW program (55113) in a control device (55120, 4) of an electronic fuse (1) in a supply network (200), in particular according to one or more of the preceding features,
wherein the system (55100) comprises a first HW platform (55110, 12, 710) and the control device (55120, 4) of an electronic fuse (1);
   the control device (55120, 4) of an electronic fuse (1) (120) is subject to one or more safety measures to which the first HW platform (55110, 12, 710) is not subject;
   the SW program (55113) comprises at least one base module (55210) and at least one safety-relevant module (55121);
   the safety-relevant module (55121) accesses safety-relevant data and/or a safety-relevant function (55201, 55202) of the fuse (1);
   the base module (210) is executed on the first HW platform (55110, 12, 710); and
   the safety-relevant module (55121) is executed on the control device (55120, 4) of an electronic fuse (1).

8. The system (100) according to feature 7,
comprising one or more safety measures,
   a check of SW code of a SW module (55121) which is implemented on the control device (55120, 4) of the electronic fuse (1); and/or
   a limitation of data (55211, 55221) that can be transferred to or from a SW module (55121) which is executed on the control device (55120, 4) of the electronic fuse (1).

9. The system (100) according to feature 7 or 8,
wherein the first HW platform (55110) is designed such that a SW module (55210) executed on the first HW platform (55110) does not have access to a safety-relevant function (55201) of the supply network (200), and
wherein the control device (55120, 3) of the fuse (1) is designed such that a SW module (55121) executed on the control device (55120, 3) of the fuse (1) has access to a safety-relevant function (55201) of the supply network (200).

10. The system (100) according to any of features 7 to 9,
wherein the base module (55210) is configured, when the SW program (55113) is executed, to call up the safety-relevant module (55121) and to initiate an execution of the safety-relevant module (55121) on the control device (55120, 4) of the fuse (1).

11. The system (55100) according to feature 10,
wherein, when the SW program (55113) is executed, data (55211) are transferred from the base module (55210) to the safety-relevant module (55121), and/or data (55221) are transferred from the safety-relevant module (55121) to the base module (55210).

12. The system (100) according to any of features 7 to 11,
wherein the first HW platform (55110) and the control device (55120, 3) of the fuse (1) comprise separate computers and/or
the control device (55120, 3) of the fuse (1) comprises a non-volatile (14) and/or volatile memory (15) that is separated from the first HW platform (110).

13. The system (100) according to any of features 7 to 12,
wherein the first HW platform (110) is part of a higher-level computer system (12) of the supply network (200) which is connected to the control device (55120, 3) of the fuse (1) via a data interface (10, 610, 550, 551) and a data bus (9) of the supply network (200), and/or is part of a server (710) which is connected to the control device (55120, 3) of the fuse (1) via a data interface (10, 610, 550, 551) and a data bus (9) of the supply network (200).

14. The system (100) according to any of features 7 to 13,
wherein the at least one safety-relevant module (55121) comprises 20%, 10% or less of a SW code of the SW program (55113); and/or
the at least one base module (55210) comprises 80%, 90% or more of the SW code of the SW program (55113).

15. The system (100) according to any of features 7 to 14,
wherein the safety-relevant module (55121) has a standardized interface via which data (55211, 55221) can be transferred to the safety-relevant module (55121) or from the safety-relevant module (5121).

16. The method (55300) for executing a SW program (55113) in a supply network (200) with electronic fuses (1) in a vehicle, in particular according to one or more of the preceding features, wherein the method (55300) comprises
executing (55301) a base module (55210) of the SW program (55113) on a first HW platform (55110) of the supply network (200);
calling (55302) up, from the base module (55210), a safety-relevant module (55121) of the SW program (55113); wherein the safety-relevant module (55121) accesses safety-relevant data and/or a safety-relevant function (55201, 55202), and
executing (55303) the safety-relevant module (55121) on a control device (55120, 3) of the fuse (1) of the supply network (200);
wherein the control device (55120, 3) of the fuse (1) is subject to one or more safety measures to which the first HW platform (110) is not subject.
   Electronic Fuse with Thermal Protection

1. An electronic fuse (1) of a vehicle, in particular according to one or more of the preceding features,
wherein the electronic fuse (1) comprises a control device (4), and
wherein the electronic fuse (1) comprises a first circuit breaker (17) having a first terminal (26) and a second terminal (28) and a control terminal (27), and
wherein the electronic fuse (1) comprises a second circuit breaker (17′) having a first terminal (26′) and a second terminal (28′) and a control terminal (27′), and
wherein the electronic fuse (1) comprises a third circuit breaker (17″) having a first terminal (26″) and a second terminal (28″) and a control terminal (27″), and
wherein the first circuit breaker (17) and the second circuit breaker (17″) and the third circuit breaker (17″) and the control device (4) are located in a housing, and
wherein the fuse has a first terminal (18) which is connected to the first terminal (26) of the first circuit breaker (17), and
wherein the fuse has a first second terminal (19) which is connected to the second terminal (28) of the first circuit breaker (17), and
wherein the fuse has a second first terminal (18′) which is connected to the first terminal (26′) of the second circuit breaker (17′), and
wherein the fuse has a second terminal (19′) which is connected to the second terminal (28′) of the second circuit breaker (17′), and
wherein the fuse has a third first terminal (18″) which is connected to the first terminal (26″) of the third circuit breaker (17″), and
wherein the fuse has a third second terminal (19″) which is connected to the second terminal (28″) of the third circuit breaker (17″), and
wherein the control device (4) controls the control terminal (27) of the first circuit breaker (17) and the control terminal (27′) of the second circuit breaker (17′) and the control terminal (27″) of the third circuit breaker (17″).

2. The electronic fuse (1), in particular according to one or more of the preceding features,
wherein the electronic fuse (1) comprises a control device (4), and
wherein the electronic fuse (1) comprises a first circuit breaker (17) having a first terminal (26) and a second terminal (28) and a control terminal (27), and
wherein the electronic fuse (1) comprises a second circuit breaker (17′) having a first terminal (26′) and a second terminal (28′) and a control terminal (27′), and
wherein the electronic fuse (1) comprises a third circuit breaker (17″) having a first terminal (26″) and a second terminal (28″) and a control terminal (27″), and
wherein the first circuit breaker (17) and the second circuit breaker (17″) and the third circuit breaker (17″) and the control device (4) are located in a housing, and
wherein the fuse has a first terminal (18),
which is connected to the first terminal (26) of the first circuit breaker (17), and
which is connected to the first terminal (26′) of the second circuit breaker (17′), and
which is connected to the first terminal (26′) of the third circuit breaker (17″), and
wherein the fuse has a first second terminal (19) which is connected to the second terminal (28) of the first circuit breaker (17), and
wherein the fuse has a second terminal (19′) which is connected to the second terminal (28′) of the second circuit breaker (17′), and
wherein the fuse has a third second terminal (19″) which is connected to the second terminal (28″) of the third circuit breaker (17″), and
wherein the control device (4) controls the control terminal (27) of the first circuit breaker (17) and the control terminal (27′) of the second circuit breaker (17′) and the control terminal (27″) of the third circuit breaker (17″).

3. An electronic fuse (1) of a vehicle, in particular according to one or more of the preceding features,
wherein the electronic fuse (1) comprises a control device (4), and
wherein the electronic fuse (1) comprises a first circuit breaker (17) having a first terminal (26) and a second terminal (28) and a control terminal (27), and
wherein the electronic fuse (1) comprises a second circuit breaker (17′) having a first terminal (26′) and a second terminal (28′) and a control terminal (27′), and
wherein the electronic fuse (1) comprises a third circuit breaker (17″) having a first terminal (26″) and a second terminal (28″) and a control terminal (27″), and
wherein the electronic fuse (1) comprises a fourth circuit breaker (17″′) having a first terminal (26″′) and a second terminal (28″′) and a control terminal (27″′), and
wherein the first circuit breaker (17) and the second circuit breaker (17″) and the third circuit breaker (17″) and the fourth circuit breaker (17″′) and the control device (4) are located in a housing, and
wherein the fuse has a first terminal (18) which is connected to the first terminal (26) of the first circuit breaker (17), and
wherein the fuse has a first second terminal (19) which is connected to the second terminal (28) of the first circuit breaker (17), and
wherein the fuse has a second first terminal (18′) which is connected to the first terminal (26′) of the second circuit breaker (17′), and
wherein the fuse has a second terminal (19′) which is connected to the second terminal (28′) of the second circuit breaker (17′), and
wherein the fuse has a third first terminal (18″) which is connected to the first terminal (26″) of the third circuit breaker (17″), and
wherein the fuse has a third second terminal (19″) which is connected to the second terminal (28″) of the third circuit breaker (17″), and
wherein the fuse has a fourth first terminal (18″′) which is connected to the first terminal (26″′) of the fourth circuit breaker (17″′), and
wherein the fuse has a fourth second terminal (19″′) which is connected to the second terminal (28″′) of the fourth circuit breaker (17″′), and
wherein the control device (4) controls the control terminal (27) of the first circuit breaker (17) and the control terminal (27′) of the second circuit breaker (17′) and the control terminal (27″) of the third circuit breaker (17″) and the control terminal (27″′) of the fourth circuit breaker (17″′).

4. An electronic fuse (1) of a vehicle, in particular according to one or more of the preceding features,
wherein the electronic fuse (1) comprises a control device (4), and
wherein the electronic fuse (1) comprises a first circuit breaker (17) having a first terminal (26) and a second terminal (28) and a control terminal (27), and
wherein the electronic fuse (1) comprises a second circuit breaker (17′) having a first terminal (26′) and a second terminal (28′) and a control terminal (27′), and
wherein the electronic fuse (1) comprises a third circuit breaker (17″) having a first terminal (26″) and a second terminal (28″) and a control terminal (27″), and
wherein the electronic fuse (1) comprises a fourth circuit breaker (17″′) having a first terminal (26″′) and a second terminal (28″′) and a control terminal (27″′), and
wherein the first circuit breaker (17) and the second circuit breaker (17″) and the third circuit breaker (17″) and the fourth circuit breaker (17″′) and the control device (4) are located in a housing, and
wherein the fuse has a first terminal (18),
which is connected to the first terminal (26) of the first circuit breaker (17), and
which is connected to the first terminal (26″) of the third circuit breaker (17″), and
wherein the fuse has a first second terminal (19),
which is connected to the second terminal (28) of the first circuit breaker (17), and
which is connected to the second terminal (28′) of the second circuit breaker (17′), and
wherein the fuse has a second first terminal (18′),
which is connected to the first terminal (26′) of the second circuit breaker (17′), and
which is connected to the first terminal (26″′) of the fourth circuit breaker (17″′), and
wherein the fuse has a third second terminal (19″),
which is connected to the second terminal (28″) of the third circuit breaker (17″), and
which is connected to the second terminal (28″′) of the fourth circuit breaker (17″′), and
wherein the control device (4) controls the control terminal (27) of the first circuit breaker (17) and the control terminal (27′) of the second circuit breaker (17′) and the control terminal (27″) of the third circuit breaker (17″) and the control terminal (27″′) of the fourth circuit breaker (17″′).
   Electronic Fuse with AI-Based Compression of Fuse Data

1. A method for transmitting fuse data of an electronic fuse (1), from the fuse (1) to a higher-level computer system (12), in particular in a vehicle, in particular according to one or more of the preceding features,
having or comprising the steps of:
Step 1: detecting the parameter value characteristics of one or more physical parameters within the electronic fuse (1) within a temporal sampling window (Hamming window, temporal sampling window, time window) and forming at least one signal (62102) of this one of the parameter value characteristics of the one or more physical parameters;
Step 2: forming a signal of the feature vectors (62138) from the signal (62102) of this one of the parameter value characteristics of the one or more physical parameters and/or from a parameter signal (62103) derived therefrom and/or from a modified vector residual signal (73660) derived therefrom with feature vectors for this time sampling window;
Step 3: evaluating a feature vector of the signal of the feature vectors (62138)
   by forming at least one binary, digital or analog distance value between the current feature vector of the signal of the feature vectors (62138) and one or more prototypical feature vectors of a prototype database (62115) and assigning a prototypical feature vector of the prototype database (62115) as a detected signal basic object if the distance value falls below one or more predetermined distance values, and/or
   by assigning a prototypical signal basic object as a detected signal basic object, in particular by means of an estimator (73151) and/or in particular by means of a neural network model and/or in particular by means of a Petri net model, wherein in particular the input signal of the estimator (73151) comprises the feature vector of the signal of the feature vectors (62138), and in particular assigning a prototypical feature vector of a prototype database (62115) used for parameterization (training) of the estimator (73151) as a detected signal basic object, and/or in particular assigning a prototypical feature vector of a prototype database (62115) of the estimator (73151) as a detected signal basic object.

2. The method according to feature 1,
comprising the additional steps of:
   transmitting at least the symbol of a detected signal basic object 62121 and any associated parameters, hereinafter referred to as compressed fuse data, to a higher-level computer system (12) and/or to a control device (4) of a different electronic fuse (1);
   reconstruction of a reconstructed parameter signal model vector (74610) and/or a reconstructed parameter signal (70610) from detected signal basic objects (62121), in particular by the higher-level computer system (12) and/or in particular by the control device (4) of the other electronic fuse.

3. The method according to feature 1 or 2,
having or comprising the steps of:
extraction of a sequence of detected signal basic objects (62121) from the parameter signal (62103) of the fuse (1), in particular by one-time or repeated execution of steps 2 and 3 of feature 1;
determining a prototypical time sequence of prototypical signal basic objects corresponding to a data set of a signal object sequence database (62116), hereinafter the detected signal object, and of the index of this data set and/or of a symbol for this data set depending on the determined sequence of detected signal basic objects (62121) from the parameter signal (62103) of the fuse 1.

4. The method according to feature 3,
comprising the additional steps of:
transmitting at least the symbol and/or the index of the detected signal object and any associated parameters, likewise referred to below as compressed fuse data, to a higher-level computer system (12) and/or to a control device (4) of a different electronic fuse (1);
reconstruction of one or more reconstructed parameter signal model vectors (74610) and/or of a reconstructed parameter signal (70610) from detected signal objects (62121).

5. The method according to any of features 1 to 4,
comprising the additional steps of:
subtracting the reconstructed parameter signal model vector (70610) from the parameter signal (62103) to form a vector residual signal (73660);
use of the vector residual signal (73660) for forming one or more feature vectors of the signal of the feature vectors (62138).

6. The method according to feature 1,
comprising the additional step of:
terminating the detection of the signal objects and/or signal basic objects in the vector residual signal (73660) if the sampling values of the vector residual signal (73660) for this sampling window are below the magnitudes of a predetermined threshold curve and/or below at least one predetermined magnitude.

7. A decompression method for decompression of compressed fuse data, in particular by a higher-level computer system (12) or a control device (4) of a different fuse, in particular according to one or more of the preceding features,
wherein compressed fuse data have been compressed by means of a method according to one or more of features 1 to 6,
comprising the steps of:
reception of the fuse data to be decompressed of at least one sampling window of this fuse (1), in particular by the higher-level computer system (12) or the control device (4) of a different fuse;
provision of a reconstructed parameter signal model vector (74610) for a reconstructed sampling window of this fuse (1), in particular by the higher-level computer system (12) or the control device (4) of a different fuse,
   wherein the reconstructed parameter signal model vector (74610) comprises the reconstructed parameter signal (70610) as a value of the reconstructed parameter signal model vector (74610), and
   wherein the reconstructed parameter signal model vector (74610) as a reconstructed parameter signal (70610) during the provision does not have a signal as a value of the reconstructed parameter signal model vector (74610) (FIG. 71a), and
   wherein the reconstructed parameter signal model vector (74610) of the reconstruction of the reconstructed parameter signal (70610) is used for this sampling window of this fuse (1);
supplementing of this reconstructed parameter signal model vector (74610) of this sampling window of this fuse (1) by adding the parameter value characteristics of one or more prototypical signal objects (68160) of a prototype database which are contained in the compressed fuse data, in particular by the higher-level computer system (12) or the control device (4) of a different fuse;
formation of a reconstructed parameter signal (70610) from the content of the reconstructed parameter signal model vector (74610), in particular by the higher-level computer system (12) or the control device (4) of a different fuse;
use of the reconstructed parameter signal (70610), in particular by the higher-level computer system (12) or the control device (4) of a different fuse.

8. The decompression method according to feature 7,
wherein the supplementing of the parameter signal model vector (74610) of this sampling window of this fuse (1) by adding the parameter value characteristics of one or more prototypical signal objects (68160) of a prototype database, which objects are contained in the compressed fuse data, comprises the following steps:
   extraction of the symbol/index of at least one signal object from the decompressed fuse data, in particular by the higher-level computer system (12) or the control device (4) of a different fuse;
   determination of the parameter value characteristics of one or more prototypical signal objects (68160) of a prototype database which correspond to the extracted symbol/the extracted index of the at least one signal object, in particular by the higher-level computer system (12) or the control device (4) of a different fuse;
   supplementing of the parameter signal model vector (74610) of this sampling window of this fuse (1) by adding the determined parameter value characteristics of one or more prototypical signal objects (68160) of a prototype database which are contained in the compressed fuse data, in particular by the higher-level computer system (12) or the control device (4) of a different fuse.

9. The decompression method according to feature 7 or 8,
comprising the step of:
combining of the reconstructed parameter signal model vector (74610) of this sampling window of this fuse (1) by adding the determined parameter value characteristics of one or more prototypical signal objects (68160) of a prototype database which are contained in the compressed fuse data, in particular by the higher-level computer system (12) or the control device (4) of a second fuse, which is different from the first fuse (1), to form a combined reconstructed parameter signal model vector.

10. The decompression method according to feature 9,
comprising the step of:
formation of a combined reconstructed parameter signal from the content of the combined reconstructed parameter signal model vector, in particular by the higher-level computer system (12) or the control device (4) of a different fuse;
use of the combined reconstructed parameter signal, in particular by the higher-level computer system (12) or the control device (4) of a different fuse.

11. A fuse (1), in particular according to one or more of the preceding features,
which is configured to carry out a method according to one or more of features 1 to 6.

12. A higher-level computer system (12), in particular according to one or more of the preceding features,
which is configured to carry out a method according to one or more of features 7 to 10, or
is configured for use together with a fuse (1) according to feature 11, and is configured to receive fuse data from this fuse (1) via a data bus (1),
wherein the fuse data are compressed fuse data which have been compressed by means of a method according to one or more of features 1 to 6.

13. A supply network (200), in particular according to one or more of the preceding features,
comprising at least one higher-level computer system (12) according to feature 12, and
comprising at least one fuse according to feature 11,
wherein the higher-level computer system is configured to carry out a method according to one or more of features 7 to 10.

14. A supply network (200), in particular according to one or more of the preceding features,
comprising at least one higher-level computer system (12) according to feature 12, and
comprising at least two electronic fuses, a first electronic fuse and a second electronic fuse, according to feature 11,
wherein the first electronic fuse and the second electronic fuse and the higher-level computer system (12) are configured such that the data transmission between the first electronic fuse and the second electronic fuse and the higher-level computer system (12) runs at least partially corresponding to a method according to one or more of features 1 to 10.

15. The supply network (200) according to feature 14,
wherein the first electronic fuse is configured to compress, by means of a method according to one or more of features 1 to 6, fuse data of the first electronic fuse and/or one or more feature vectors of the first electronic fuse and/or a parameter signal (62103) of the first electronic fuse to form compressed fuse data of the first electronic fuse, and to transmit the compressed fuse data of the first electronic fuse to the higher-level computer system (12), and
wherein the higher-level computer system (12) is configured to receive, by means of a method according to one or more of features 7 to 10, compressed fuse data from the first electronic fuse and to reconstruct said data to form a reconstructed parameter signal (70610) of the first fuse and/or to form one or more reconstructed feature vectors of the first fuse and/or to form reconstructed fuse data of the first fuse, and
wherein the second electronic fuse is configured to compress, by means of a method according to one or more of features 1 to 6, fuse data of the second electronic fuse and/or a parameter signal (62103) of the second electronic fuse and/or one or more feature vectors of the second electronic fuse to form compressed fuse data of the second electronic fuse and to transmit the compressed fuse data of the second electronic fuse to the higher-level computer system (12), and
wherein the higher-level computer system (12) is configured to receive, by means of a method according to one or more of features 7 to 10, compressed fuse data of the second electronic fuse from the second electronic fuse and to reconstruct said data to form a reconstructed parameter signal (70610) of the second electronic fuse and/or to form one or more reconstructed feature vectors of the second electronic fuse and/or to form reconstructed fuse data of the second electronic fuse.

16. The supply network (200) according to feature 15,
wherein the higher-level computer system (12) is configured,
   firstly, with the aid of one of the reconstructed parameter signals (70610) of the first electronic fuse and/or of the one or more reconstructed feature vectors of the first electronic fuse and/or of the fuse data to be reconstructed of the first electronic fuse, and
   secondly, with the aid of one of the reconstructed parameter signals (70610) of the second electronic fuse and/or of the one or more reconstructed feature vectors of the second electronic fuse and/or of the fuse data to be reconstructed of the second electronic fuse,
to determine a state of the supply network (200) within the scope of a state determination, and
wherein in particular the higher-level computer system (12) is configured to deduce short circuits (1515) between supply lines (1915, 1505) in the course of the state determination, and/or
wherein in particular the higher-level computer system (12) is configured to deduce short circuits between supply lines and a reference potential line (201) and/or the vehicle body in the course of the state determination, and/or
wherein in particular the higher-level computer system (12) is configured to deduce power losses in monitored line sections (1915, 1505) in the course of the state determination.

17. The supply network (200) according to any of features 14 to 16,
wherein the higher-level computer system (12) is configured to determine a state of the supply network (200) within the scope of a state determination with the aid of reconstructed parameter signals of an electronic fuse and/or combined reconstructed parameter signals of a plurality of electronic fuses and/or reconstructed feature vectors of an electronic fuse and/or combined reconstructed feature vectors of a plurality of electronic fuses, and
wherein in particular the higher-level computer system (12) is configured to deduce short circuits (1515) between supply lines (1915, 1505) in the course of the state determination, and/or
wherein in particular the higher-level computer system (12) is configured to deduce short circuits between supply lines and a reference potential line (201) and/or the vehicle body in the course of the state determination, and/or
wherein in particular the higher-level computer system (12) is configured to deduce power losses in monitored line sections (1915, 1505) in the course of the state determination.

18. The supply network (200) according to one or more of features 13 to 17,
comprising at least one higher-level computer system (12) according to feature 12, and
comprising at least one first electronic fuse according to feature 11,
wherein the first electronic fuse is configured such that the data transmission between the first electronic fuse and the higher-level computer system (12) runs at least partially according to a method according to one or more of features 1 to 10, and
wherein the higher-level computer system (12) is configured to receive or detect one or more sensor signals of one or more sensors in the supply network (200) and/or in the vehicle, and
wherein the higher-level computer system (12) is configured,
   firstly, with the aid of one of the reconstructed parameter signals (70610) of the first electronic fuse and/or of the one or more reconstructed feature vectors of the first electronic fuse and/or of the fuse data to be reconstructed of the first electronic fuse, and
   thirdly, with the aid of one of the sensor signals
to determine a state of the supply network (200) within the scope of a state determination, and/or
wherein the higher-level computer system (12) is configured to determine a state of the vehicle within the scope of a state determination.

19. The method according to feature 18,
comprising at least one second electronic fuse according to feature 11,
wherein the higher-level computer system (12) is configured,
   secondly, with the aid of one of the reconstructed parameter signals (70610) of the second electronic fuse and/or of the one or more reconstructed feature vectors of the second electronic fuse and/or of the fuse data to be reconstructed of the second electronic fuse,
to determine the state of the supply network (200) within the scope of a state determination, and/or
to determine the state of the vehicle within the scope of a state determination.

20. The method according to feature 18 or 19,
wherein in particular the higher-level computer system (12) is configured to deduce short circuits (1515) between supply lines (1915, 1505) in the course of the state determination, and/or
wherein in particular the higher-level computer system (12) is configured to deduce short circuits between supply lines and a reference potential line (201) and/or the vehicle body in the course of the state determination, and/or
wherein in particular the higher-level computer system (12) is configured to deduce power losses in monitored line sections (1915, 1505) in the course of the state determination.
   Supply Network with Transmission of Compressed Fuse Data to a Higher-Level Computer System

1. A method for operating a supply network (200), in particular according to one or more of the preceding features,
wherein the supply network (200) comprises an electronic fuse (1) with a control device (4) and a circuit breaker (17), and
wherein the supply network (200) comprises a higher-level computer system (12), and
comprising the steps of:
detection (6200) of the temporal value characteristic of one or more physical parameters to be detected, in particular by the control device (4) of the fuse (1), in the form of one or more detected temporal parameter value characteristics;
analysis and compression (6030) of the one or more detected temporal parameter value characteristics of the one or more detected physical parameters, in particular by the control device (4) of the electronic fuse (1);
transmission (6040) of the one or more compressed, detected temporal parameter value characteristics of the one or more physical parameters to be signaled by the control device (4) of the electronic fuse (1) to the higher-level computer system (12);
decompression (6050) of the one or more received, compressed, detected temporal parameter value characteristics, in particular by the higher-level computer system (12), to form one or more decompressed, reconstructed, detected temporal parameter value characteristics, which are associated in particular with the control device (4) of the fuse (1) within the higher-level computer system (12).

2. The method for operating a supply network (200) according to feature 1,
comprising the additional step of:
comparing and/or correlating (6060) the one or more reconstructed, detected temporal parameter value characteristics, which are associated in particular with the control device (4) of the fuse (1) within the higher-level computer system (12), to one or more other reconstructed, detected temporal parameter value characteristics, which are associated in particular with the control devices (4) of other fuses (1) within the higher-level computer system (12), in particular by the higher-level computer system.

3. The method for operating a supply network (200) according to feature 2,
comprising the additional step of:
detection of events that can be attributed to the same causes, in particular in temporal correlation, in particular by the higher-level computer system (12).

4. The method for operating a supply network (200) according to feature 3,
comprising the additional step of:
adoption (6070) of measures depending on the detected events by the higher-level computer system 12, if necessary.

5. The method for operating a supply network (200) according to one or more of features 1 to 4,
comprising the additional step of:
closing (6010) of a circuit breaker (17) of the fuse (1), in particular by a control device (4) of a fuse (1).

6. The method for operating a supply network (200) according to one or more of features 1 to 5,
wherein the physical parameter to be detected, which the control device (4) of the fuse (1) detects using first means, which, for example, can comprise the analog-to-digital converter (570) of the control device (4) and/or the shunt resistor (24) and/or the auxiliary circuit breaker (23), takes place in a second step 6020.

7. The method for operating a supply network (200) according to one or more of features 1 to 5,
wherein the detection (6200) of the temporal value characteristic of one or more physical parameters to be detected as physical parameters to be detected comprises one or more of the parameters, one or more electrical voltages between circuit nodes, in particular within and outside of the electronic fuse (1), and/or one or more electrical currents through lines, in particular within the fuse (1), and/or temperatures, in particular in and/or in the surroundings of the fuse (1).

8. The method for operating a supply network (200) according to one or more of features 1 to 6 and feature 6,
wherein the detection (6200) of the temporal value characteristic of one or more physical parameters to be detected comprises a conversion (6021) of the electrical analog signals, which are generated by the means for detecting the physical parameters, by sampling, in particular by the control device (4) of the electronic fuse (1), in one or more sampled temporal parameter value characteristics.

9. The method for operating a supply network (200) according to feature 8,
wherein the one or more sampled temporal parameter value characteristics comprise a time-discrete flow of sampling values of the parameter values of the relevant physical parameter and any associated time stamps of these sampling values.

10. The method for operating a supply network (200) according to feature 9,
wherein a sampling instant is associated with a sampling value as a time stamp of this sampling value, in particular by the control device (4) of the fuse (1), and/or
wherein each sampling value is associated with a corresponding sampling instant as the corresponding time stamp of this corresponding sampling value, in particular by the control device (4) of the fuse (1), and/or
wherein sampling values are associated with a sampling instant at equal time intervals as a time stamp of these sampling values, in particular by the control device (4) of the fuse (1).

11. The method for operating a supply network (200) according to feature 10,
wherein the detection (6200) of the temporal value characteristic of one or more physical parameters to be detected comprises performing (6022) a wavelet transform and/or a Fourier transform or a Z-transform and/or a Laplace transform or a different transform and/or a different compression method.

12. The method for operating a supply network (200) according to feature 10 or 11,
wherein the detection (6200) of the temporal value characteristic of one or more physical parameters to be detected comprises the conversion (6022) of the sampled temporal parameter value characteristics into compressed temporal parameter value characteristics, in particular by the control device (4) of the fuse (1).

13. The method for operating a supply network (200) according to one or more of features 1 to 12,
wherein the analysis and compression (6030) of the one or more detected temporal parameter value characteristics of the one or more detected physical parameters comprises the analysis (6031) of the temporal parameter value characteristic of the parameters detected, in particular by the control device (4) of the electronic fuse (1), and/or of the time characteristic of parameters derived therefrom.

14. The method for operating a supply network (200) according to feature 13,
wherein the analysis (6031) of the temporal parameter value characteristic of the parameters detected, in particular by the control device (4) of the electronic fuse (1), and/or of the time characteristic of parameters derived therefrom, comprises the formation of a value of a vector component of a feature vector by a matched filter from the temporal parameter value characteristic of the parameters detected, in particular by the control device (4) of the electronic fuse (1), and/or of the time characteristic of parameters derived therefrom.

15. The method for operating a supply network (200) according to feature 13 or 14,
wherein the analysis (6031) of the temporal parameter value characteristic of the parameters detected, in particular by the control device (4) of the electronic fuse (1), and/or of the time characteristic of parameters derived therefrom, comprises the formation in each case of a value of a vector component of a feature vector by in each case a matched filter from the temporal parameter value characteristic of the parameters detected, in particular by the control device (4) of the electronic fuse (1), and/or of the time characteristic of parameters derived therefrom.

16. The method for operating a supply network (200) according to one or more of features 1 to 15,
wherein the analysis and compression (6030) of the one or more detected temporal parameter value characteristics of the one or more detected physical parameters comprises the extraction (6032) of a current feature vector from the detected temporal parameter value characteristics and/or from parameters derived from the prototypical time characteristics derived therefrom, in particular by the control device (4) of the fuse (1)

17. The method for operating a supply network (200) according to feature 16,
wherein the analysis and compression (6030) of the one or more detected temporal parameter value characteristics of the one or more detected physical parameters comprises the association (6032) of a corresponding time stamp optionally with each feature vector of these feature vectors, in particular by the control device (4) of the fuse (1).

18. The method for operating a supply network (200) according to one or more of features 1 to 17,
wherein the analysis and compression (6030) of the one or more detected temporal parameter value characteristics of the one or more detected physical parameters comprises determining (6033) a distance of the extracted current feature vector to a prototypical feature vector of the prototypical feature vectors of a prototype database (62115).

19. The method for operating a supply network (200) according to one or more of features 1 to 18,
wherein the analysis and compression (6030) of the one or more detected temporal parameter value characteristics of the one or more detected physical parameters comprises the detection (6034) of a prototypical feature vector of a or the prototype database (62115) as a detected prototypical feature vector of the prototype database (62115) if the determined distance for this pair made up of this current feature vector and this prototypical feature vector of the prototype database (62115) is less than a distance threshold value, and if at the same time this determined distance is less than or equal to any other distance between the current feature vector on the one hand and any other prototypical feature vector of the prototype database (62115).
   Electronic Fuse and Higher-Level Computer System with Compression and Decompression of the Fuse Measurement Signals During Data Transmission

1. The method (7600) for operating a supply network (200), in particular according to one or more of the preceding features,
comprising compression and encryption of the first fuse data of a first electronic fuse (1) in the first electronic fuse (1), and
comprising transmission of the compressed and encrypted first fuse data to a higher-level computer system (12), and
comprising decryption and decompression of the compressed and encrypted first fuse data to form received first fuse data of the first fuse (1) in the higher-level computer system (12).

2. The method according to feature 1,
comprising an adoption of measures depending on the received first fuse data of the first fuse (1) in the higher-level computer system (12) by the higher-level computer system (12).

3. The method (7600) for operating a supply network (200), in particular according to one or more of the preceding features,
comprising compression and encryption of first fuse data of a first electronic fuse (825) in the first electronic fuse (825), and
comprising compression and encryption of second fuse data of a second electronic fuse (805) in the second electronic fuse (805), and
comprising transmission of the compressed and encrypted first fuse data of the first fuse (825) to a higher-level computer system (12), and
comprising transmission of the compressed and encrypted second fuse data of the second fuse (805) to the higher-level computer system (12) and
comprising decryption and decompression of the compressed and encrypted first fuse data of the first fuse to form received first fuse data of the first fuse (825) in the higher-level computer system (12), and
comprising decryption and decompression of the compressed and encrypted second fuse data of the second fuse (805) to form received second fuse data of the second fuse (805) in the higher-level computer system (12), and
comprising an adoption of measures depending on the received first fuse data of the first fuse (825) and depending on the received second fuse data of the second fuse (805) in the higher-level computer system (12) by the higher-level computer system (12).
   Supply Network with Encrypted and Compressed Data Communication Between Fuses and Higher-Level Computer System

4. The method (7600) for operating a supply network (200), in particular according to one or more of the preceding features,
wherein the supply network (200) comprises an electronic fuse (1) with a control device (4) and a circuit breaker (17), and
wherein the supply network (200) comprises a higher-level computer system (12), and
comprising the steps of:
detection (6200) of the temporal value characteristic of one or more physical parameters to be detected, in particular by the control device (4) of the fuse (1), in the form of one or more detected temporal parameter value characteristics;
analysis and compression (6030) of the one or more detected temporal parameter value characteristics of the one or more detected physical parameters, in particular by the control device (4) of the electronic fuse (1);
encryption (7610) of the one or more compressed, detected temporal parameter value characteristics of the one or more physical parameters to be signaled, in particular by the control device (4) of the electronic fuse (1), to form one or more encrypted, compressed, detected temporal parameter value characteristics of the one or more physical parameters to be signaled;
transmission (6040) of the one or more encrypted, compressed, detected temporal parameter value characteristics of the one or more physical parameters to be signaled by the control device (4) of the electronic fuse (1) to the higher-level computer system (12);
decryption (7620) of the one or more received, encrypted, compressed, detected temporal parameter value characteristics of the one or more physical parameters to be signaled, in particular by the higher-level computer system (12), to form one or more decrypted, compressed, detected temporal parameter value characteristics of the one or more physical parameters to be signaled;
decompression (6050) of the one or more decrypted, received, compressed, detected temporal parameter value characteristics, in particular by the higher-level computer system (12), to form one or more decompressed, reconstructed, detected temporal parameter value characteristics, which are associated in particular with the control device (4) of the fuse (1) within the higher-level computer system (12).

5. The method for operating a supply network (200) according to feature 1,
comprising the additional step of:
comparing and/or correlating (6060) the one or more reconstructed, detected temporal parameter value characteristics, which are associated in particular with the control device (4) of the fuse (1) within the higher-level computer system (12), to one or more other reconstructed, detected temporal parameter value characteristics, which are associated in particular with the control devices (4) of other fuses (1) within the higher-level computer system (12), in particular by the higher-level computer system.

6. The method for operating a supply network (200) according to feature 2,
comprising the additional step of:
detection of events that can be attributed to the same causes, in particular in temporal correlation, in particular by the higher-level computer system (12).

7. The method for operating a supply network (200) according to feature 3,
comprising the additional steps of:
evaluation (6070) of the detected events by the higher-level computer system 12, and
adoption (6070) of measures depending on the detected events by the higher-level computer system 12, if necessary.

8. The method for operating a supply network (200) according to one or more of features 1 to 4,
comprising the additional step of:
closing (6010) of a circuit breaker (17) of the fuse (1), in particular by a control device (4) of a fuse (1).

9. The method for operating a supply network (200) according to one or more of features 1 to 5,
wherein the physical parameter to be detected, which the control device (4) of the fuse (1) detects using first means, which, for example, can comprise the analog-to-digital converter (570) of the control device (4) and/or the shunt resistor (24) and/or the auxiliary circuit breaker (23), takes place in a second step 6020.

10. The method for operating a supply network (200) according to one or more of features 1 to 5,
wherein the detection (6200) of the temporal value characteristic of one or more physical parameters to be detected as physical parameters to be detected comprises one or more of the parameters, one or more electrical voltages between circuit nodes, in particular within and outside of the electronic fuse (1), and/or one or more electrical currents through lines, in particular within the fuse (1), and/or temperatures, in particular in and/or in the surroundings of the fuse (1).

11. The method for operating a supply network (200) according to one or more of features 1 to 6 and feature 6,
wherein the detection (6200) of the temporal value characteristic of one or more physical parameters to be detected comprises a conversion (6021) of the electrical analog signals, which are generated by the means for detecting the physical parameters, by sampling, in particular by the control device (4) of the electronic fuse (1), in one or more sampled temporal parameter value characteristics.

12. The method for operating a supply network (200) according to feature 8,
wherein the one or more sampled temporal parameter value characteristics comprise a time-discrete flow of sampling values of the parameter values of the relevant physical parameter and any associated time stamps of these sampling values.

13. The method for operating a supply network (200) according to feature 9,
wherein a sampling instant is associated with a sampling value as a time stamp of this sampling value, in particular by the control device (4) of the fuse (1), and/or
wherein each sampling value is associated with a corresponding sampling instant as the corresponding time stamp of this corresponding sampling value, in particular by the control device (4) of the fuse (1), and/or
wherein sampling values are associated with a sampling instant at equal time intervals as a time stamp of these sampling values, in particular by the control device (4) of the fuse (1).

14. The method for operating a supply network (200) according to feature 10,
wherein the detection (6200) of the temporal value characteristic of one or more physical parameters to be detected comprises performing (6022) a wavelet transform and/or a Fourier transform or a Z-transform and/or a Laplace transform or a different transform and/or a different compression method.

15. The method for operating a supply network (200) according to feature 10 or 11,
wherein the detection (6200) of the temporal value characteristic of one or more physical parameters to be detected comprises the conversion (6022) of the sampled temporal parameter value characteristics into compressed temporal parameter value characteristics, in particular by the control device (4) of the fuse (1).

16. The method for operating a supply network (200) according to one or more of features 1 to 12,
wherein the analysis and compression (6030) of the one or more detected temporal parameter value characteristics of the one or more detected physical parameters comprises the analysis (6031) of the temporal parameter value characteristic of the parameters detected, in particular by the control device (4) of the electronic fuse (1), and/or of the time characteristic of parameters derived therefrom.

17. The method for operating a supply network (200) according to feature 13,
wherein the analysis (6031) of the temporal parameter value characteristic of the parameters detected, in particular by the control device (4) of the electronic fuse (1), and/or of the time characteristic of parameters derived therefrom, comprises the formation of a value of a vector component of a feature vector by a matched filter from the temporal parameter value characteristic of the parameters detected, in particular by the control device (4) of the electronic fuse (1), and/or of the time characteristic of parameters derived therefrom.

18. The method for operating a supply network (200) according to feature 13 or 14,
wherein the analysis (6031) of the temporal parameter value characteristic of the parameters detected, in particular by the control device (4) of the electronic fuse (1), and/or of the time characteristic of parameters derived therefrom, comprises the formation in each case of a value of a vector component of a feature vector by in each case a matched filter from the temporal parameter value characteristic of the parameters detected, in particular by the control device (4) of the electronic fuse (1), and/or of the time characteristic of parameters derived therefrom.

19. The method for operating a supply network (200) according to one or more of features 1 to 15,
wherein the analysis and compression (6030) of the one or more detected temporal parameter value characteristics of the one or more detected physical parameters comprises the extraction (6032) of a current feature vector from the detected temporal parameter value characteristics and/or from parameters derived from the prototypical time characteristics derived therefrom, in particular by the control device (4) of the electronic fuse (1).

20. The method for operating a supply network (200) according to feature 16,
wherein the analysis and compression (6030) of the one or more detected temporal parameter value characteristics of the one or more detected physical parameters comprises the association (6032) of a corresponding time stamp optionally with each feature vector of these feature vectors, in particular by the control device (4) of the electronic fuse (1).

21. The method for operating a supply network (200) according to one or more of features 1 to 17,
wherein the analysis and compression (6030) of the one or more detected temporal parameter value characteristics of the one or more detected physical parameters comprises determining (6033) a distance of the extracted current feature vector to a prototypical feature vector of the prototypical feature vectors of a prototype database (62115).

22. The method for operating a supply network (200) according to one or more of features 1 to 18,
wherein the analysis and compression (6030) of the one or more detected temporal parameter value characteristics of the one or more detected physical parameters comprises the detection (6034) of a prototypical feature vector of a or the prototype database (62115) as a detected prototypical feature vector of the prototype database (62115) if the determined distance for this pair made up of this current feature vector and this prototypical feature vector of the prototype database (62115) is less than a distance threshold value, and if at the same time this determined distance is less than or equal to any other distance between the current feature vector on the one hand and any other prototypical feature vector of the prototype database (62115).

23. The method for operating a supply network (200) according to one or more of features 1 to 19,
wherein the encryption (7610) of the one or more compressed, detected temporal parameter value characteristics of the one or more physical parameters to be signaled, in particular by the control device (4) of the electronic fuse (1), takes place to form one or more encrypted, compressed, detected temporal parameter value characteristics of the one or more physical parameters to be signaled, with the aid of a random number or pseudo-random number, in particular by the control device (4) of the electronic fuse (1).

24. The method for operating a supply network (200) according to feature 20,
wherein the random number is a true random number.

25. The method for operating a supply network (200) according to feature 21,
wherein the random number is a quantum random number of a quantum random number generator (60).

26. The method for operating a supply network (200) according to one or more of features 1 to 22,
wherein the encryption (7610) of the one or more compressed, detected temporal parameter value characteristics of the one or more physical parameters to be signaled, in particular by the control device (4) of the electronic fuse (1), to form one or more encrypted, compressed, detected temporal parameter value characteristics of the one or more physical parameters to be signaled, is accomplished by means of a PQC encryption method, in particular by the control device (4) of the electronic fuse (1).
   Electronic Fuse with Enerypted and Compressed Data Communication and Application and Developments Thereof

27. A method for transmitting fuse data of an electronic fuse (1), from the fuse (1) to a higher-level computer system (12), in particular in a vehicle, in particular according to one or more of the preceding features,
having or comprising the steps of:
Step 1: detecting the parameter value characteristics of one or more physical parameters within the electronic fuse (1) within a temporal sampling window (Hamming window, temporal sampling window, time window) and forming at least one signal (62102) of this one of the parameter value characteristics of the one or more physical parameters;
Step 2: forming a signal of the feature vectors (62138) from the signal (62102) of this one of the parameter value characteristics of the one or more physical parameters and/or from a parameter signal (62103) derived therefrom and/or from a modified vector residual signal (73660) derived therefrom with feature vectors for this time sampling window;
Step 3: evaluating a feature vector of the signal of the feature vectors (62138)
   by forming at least one binary, digital or analog distance value between the current feature vector of the signal of the feature vectors (62138) and one or more prototypical feature vectors of a prototype database (62115) and assigning a prototypical feature vector of the prototype database (62115) as a detected signal basic object if the distance value falls below one or more predetermined distance values, and/or
   by assigning a prototypical signal basic object as a detected signal basic object, in particular by means of an estimator (73151) and/or in particular by means of a neural network model and/or in particular by means of a Petri net model, wherein in particular the input signal of the estimator (73151) comprises the feature vector of the signal of the feature vectors (62138), and in particular assigning a prototypical feature vector of a prototype database (62115) used for parameterization (training) of the estimator (73151) as a detected signal basic object, and/or in particular assigning a prototypical feature vector of a prototype database (62115) of the estimator (73151) as a detected signal basic object.

28. The method according to feature 1,
comprising the additional steps of:
   transmitting at least the symbol of a detected signal basic object 62121 and any associated parameters, hereinafter referred to as compressed fuse data, to a higher-level computer system (12) and/or to a control device (4) of a different electronic fuse (1);
   reconstruction of a reconstructed parameter signal model vector (74610) and/or a reconstructed parameter signal (70610) from detected signal basic objects (62121), in particular by the higher-level computer system (12) and/or in particular by the control device (4) of the other electronic fuse.

29. The method according to feature 1 or 2,
having or comprising the steps of:
extraction of a sequence of detected signal basic objects (62121) from the parameter signal (62103) of the fuse (1), in particular by one-time or repeated execution of steps 2 and 3 of feature 1,
determining a prototypical time sequence of prototypical signal basic objects corresponding to a data set of a signal object sequence database (62116), hereinafter the detected signal object, and of the index of this data set and/or of a symbol for this data set depending on the determined sequence of detected signal basic objects (62121) from the parameter signal (62103) of the fuse 1.

30. The method according to feature 3,
comprising the additional steps of:
transmitting at least the symbol and/or the index of the detected signal object and any associated parameters, likewise referred to below as compressed fuse data, to a higher-level computer system (12) and/or to a control device (4) of a different electronic fuse (1);
reconstruction of one or more reconstructed parameter signal model vectors (74610) and/or of a reconstructed parameter signal (70610) from detected signal objects (62121).

31. The method according to any of features 1 to 4,
comprising the additional steps of:
subtracting the reconstructed parameter signal model vector (70610) from the parameter signal (62103) to form a vector residual signal (73660);
use of the vector residual signal (73660) for forming one or more feature vectors of the signal of the feature vectors (62138).

32. The method according to feature 1,
comprising the additional step of:
terminating the detection of the signal objects and/or signal basic objects in the vector residual signal (73660) if the sampling values of the vector residual signal (73660) for this sampling window are below the magnitudes of a predetermined threshold curve and/or below at least one predetermined magnitude.

33. A decompression method for decompression of compressed fuse data, in particular by a higher-level computer system (12) or a control device (4) of a different fuse, in particular according to one or more of the preceding features,
wherein compressed fuse data have been compressed by means of a method according to one or more of features 1 to 6,
comprising the steps of:
reception of the fuse data to be decompressed of at least one sampling window of this fuse (1), in particular by the higher-level computer system (12) or the control device (4) of a different fuse;
provision of a reconstructed parameter signal model vector (74610) for a reconstructed sampling window of this fuse (1), in particular by the higher-level computer system (12) or the control device (4) of a different fuse,
   wherein the reconstructed parameter signal model vector (74610) comprises the reconstructed parameter signal (70610) as a value of the reconstructed parameter signal model vector (74610), and
   wherein the reconstructed parameter signal model vector (74610) as a reconstructed parameter signal (70610) during the provision does not have a signal as a value of the reconstructed parameter signal model vector (74610) (FIG. 71a), and
   wherein the reconstructed parameter signal model vector (74610) of the reconstruction of the reconstructed parameter signal (70610) is used for this sampling window of this fuse (1);
supplementing of this reconstructed parameter signal model vector (74610) of this sampling window of this fuse (1) by adding the parameter value characteristics of one or more prototypical signal objects (68160) of a prototype database which are contained in the compressed fuse data, in particular by the higher-level computer system (12) or the control device (4) of a different fuse;
formation of a reconstructed parameter signal (70610) from the content of the reconstructed parameter signal model vector (74610), in particular by the higher-level computer system (12) or the control device (4) of a different fuse;
use of the reconstructed parameter signal (70610), in particular by the higher-level computer system (12) or the control device (4) of a different fuse.

34. The decompression method according to feature 7,
wherein the supplementing of the parameter signal model vector (74610) of this sampling window of this fuse (1) by adding the parameter value characteristics of one or more prototypical signal objects (68160) of a prototype database, which objects are contained in the compressed fuse data, comprises the following steps:
   extraction of the symbol/index of at least one signal object from the decompressed fuse data, in particular by the higher-level computer system (12) or the control device (4) of a different fuse;
   determination of the parameter value characteristics of one or more prototypical signal objects (68160) of a prototype database which correspond to the extracted symbol/the extracted index of the at least one signal object, in particular by the higher-level computer system (12) or the control device (4) of a different fuse;
   supplementing of the parameter signal model vector (74610) of this sampling window of this fuse (1) by adding the determined parameter value characteristics of one or more prototypical signal objects (68160) of a prototype database which are contained in the compressed fuse data, in particular by the higher-level computer system (12) or the control device (4) of a different fuse.

35. The decompression method according to feature 7 or 8,
comprising the step of:
combining of the reconstructed parameter signal model vector (74610) of this sampling window of this fuse (1) by adding the determined parameter value characteristics of one or more prototypical signal objects (68160) of a prototype database which are contained in the compressed fuse data, in particular by the higher-level computer system (12) or the control device (4) of a second fuse. which is different from the first fuse (1), to form a combined reconstructed parameter signal model vector.

36. The decompression method according to feature 9,
comprising the step of:
formation of a combined reconstructed parameter signal from the content of the combined reconstructed parameter signal model vector, in particular by the higher-level computer system (12) or the control device (4) of a different fuse;
use of the combined reconstructed parameter signal, in particular by the higher-level computer system (12) or the control device (4) of a different fuse.

37. A fuse (1), in particular according to one or more of the preceding features,
which is configured to carry out a method according to one or more of features 1 to 6.

38. A higher-level computer system (12), in particular according to one or more of the preceding features,
which is configured to carry out a method according to one or more of features 7 to 10, or
is configured for use together with a fuse (1) according to feature 11, and is configured to receive fuse data from this fuse (1) via a data bus (1),
wherein the fuse data are compressed fuse data which have been compressed by means of a method according to one or more of features 1 to 6.

39. A supply network (200), in particular according to one or more of the preceding features,
comprising at least one higher-level computer system (12) according to feature 12, and
comprising at least one fuse according to feature 11,
wherein the higher-level computer system is configured to carry out a method according to one or more of features 7 to 10.

40. A supply network (200),
comprising at least one higher-level computer system (12) according to feature 12, and
comprising at least two electronic fuses, a first electronic fuse and a second electronic fuse, according to feature 11,
wherein the first electronic fuse and the second electronic fuse and the higher-level computer system (12) are configured such that the data transmission between the first electronic fuse and the second electronic fuse and the higher-level computer system (12) runs at least partially corresponding to a method according to one or more of features 1 to 10.

41. The supply network (200) according to feature 14,
wherein the first electronic fuse is configured to compress, by means of a method according to one or more of features 1 to 6, fuse data of the first electronic fuse and/or one or more feature vectors of the first electronic fuse and/or a parameter signal (62103) of the first electronic fuse to form compressed fuse data of the first electronic fuse, and to transmit the compressed fuse data of the first electronic fuse to the higher-level computer system (12), and
wherein the higher-level computer system (12) is configured to receive, by means of a method according to one or more of features 7 to 10, compressed fuse data from the first electronic fuse and to reconstruct said data to form a reconstructed parameter signal (70610) of the first fuse and/or to form one or more reconstructed feature vectors of the first fuse and/or to form reconstructed fuse data of the first fuse, and
wherein the second electronic fuse is configured to compress, by means of a method according to one or more of features 1 to 6, fuse data of the second electronic fuse and/or a parameter signal (62103) of the second electronic fuse and/or one or more feature vectors of the second electronic fuse to form compressed fuse data of the second electronic fuse and to transmit the compressed fuse data of the second electronic fuse to the higher-level computer system (12), and
wherein the higher-level computer system (12) is configured to receive, by means of a method according to one or more of features 7 to 10, compressed fuse data of the second electronic fuse from the second electronic fuse and to reconstruct said data to form a reconstructed parameter signal (70610) of the second electronic fuse and/or to form one or more reconstructed feature vectors of the second electronic fuse and/or to form reconstructed fuse data of the second electronic fuse.

42. The supply network (200) according to feature 15,
wherein the higher-level computer system (12) is configured,
   firstly, with the aid of one of the reconstructed parameter signals (70610) of the first electronic fuse and/or of the one or more reconstructed feature vectors of the first electronic fuse and/or of the fuse data to be reconstructed of the first electronic fuse, and
   secondly, with the aid of one of the reconstructed parameter signals (70610) of the second electronic fuse and/or of the one or more reconstructed feature vectors of the second electronic fuse and/or of the fuse data to be reconstructed of the second electronic fuse,
to determine a state of the supply network (200) within the scope of a state determination, and
wherein in particular the higher-level computer system (12) is configured to deduce short circuits (1515) between supply lines (1915, 1505) in the course of the state determination, and/or
wherein in particular the higher-level computer system (12) is configured to deduce short circuits between supply lines and a reference potential line (201) and/or the vehicle body in the course of the state determination, and/or
wherein in particular the higher-level computer system (12) is configured to deduce power losses in monitored line sections (1915, 1505) in the course of the state determination.

43. The supply network (200) according to any of features 14 to 16,
wherein the higher-level computer system (12) is configured to determine a state of the supply network (200) within the scope of a state determination with the aid of reconstructed parameter signals of an electronic fuse and/or combined reconstructed parameter signals of a plurality of electronic fuses and/or reconstructed feature vectors of an electronic fuse and/or combined reconstructed feature vectors of a plurality of electronic fuses, and
wherein in particular the higher-level computer system (12) is configured to deduce short circuits (1515) between supply lines (1915, 1505) in the course of the state determination, and/or
wherein in particular the higher-level computer system (12) is configured to deduce short circuits between supply lines and a reference potential line (201) and/or the vehicle body in the course of the state determination, and/or
wherein in particular the higher-level computer system (12) is configured to deduce power losses in monitored line sections (1915, 1505) in the course of the state determination.

44. The supply network (200) according to one or more of features 13 to 17,
comprising at least one higher-level computer system (12) according to feature 12, and
comprising at least one first electronic fuse according to feature 11,
wherein the first electronic fuse is configured such that the data transmission between the first electronic fuse and the higher-level computer system (12) runs at least partially according to a method according to one or more of features 1 to 10, and
wherein the higher-level computer system (12) is configured to receive or detect one or more sensor signals of one or more sensors in the supply network (200) and/or in the vehicle, and
wherein the higher-level computer system (12) is configured,
   firstly, with the aid of one of the reconstructed parameter signals (70610) of the first electronic fuse and/or of the one or more reconstructed feature vectors of the first electronic fuse and/or of the fuse data to be reconstructed of the first electronic fuse, and
   thirdly, with the aid of one of the sensor signals
to determine a state of the supply network (200) within the scope of a state determination, and/or
wherein the higher-level computer system (12) is configured to determine a state of the vehicle within the scope of a state determination.

45. The method according to feature 18,
comprising at least one second electronic fuse according to feature 11,
wherein the higher-level computer system (12) is configured,
   secondly, with the aid of one of the reconstructed parameter signals (70610) of the second electronic fuse and/or of the one or more reconstructed feature vectors of the second electronic fuse and/or of the fuse data to be reconstructed of the second electronic fuse,
to determine the state of the supply network (200) within the scope of a state determination, and/or
to determine the state of the vehicle within the scope of a state determination.

46. The method according to feature 18 or 19,
wherein in particular the higher-level computer system (12) is configured to deduce short circuits (1515) between supply lines (1915, 1505) in the course of the state determination, and/or
wherein in particular the higher-level computer system (12) is configured to deduce short circuits between supply lines and a reference potential line (201) and/or the vehicle body in the course of the state determination, and/or
wherein in particular the higher-level computer system (12) is configured to deduce power losses in monitored line sections (1915, 1505) in the course of the state determination.

47. A method for operating a supply network (200), in particular according to one or more of the preceding features,
wherein the supply network (200) comprises an electronic fuse (1) with a control device (4) and a circuit breaker (17), and
wherein the supply network (200) comprises a higher-level computer system (12), and
comprising the steps of:
detection (6200) of the temporal value characteristic of one or more physical parameters to be detected, in particular by the control device (4) of the fuse (1), in the form of one or more detected temporal parameter value characteristics;
analysis and compression (6030) of the one or more detected temporal parameter value characteristics of the one or more detected physical parameters, in particular by the control device (4) of the electronic fuse (1);
transmission (6040) of the one or more compressed, detected temporal parameter value characteristics of the one or more physical parameters to be signaled by the control device (4) of the electronic fuse (1) to the higher-level computer system (12);
decompression (6050) of the one or more received, compressed, detected temporal parameter value characteristics, in particular by the higher-level computer system (12), to form one or more decompressed, reconstructed, detected temporal parameter value characteristics, which are associated in particular with the control device (4) of the fuse (1) within the higher-level computer system (12).

48. The method for operating a supply network (200) according to feature 1,
comprising the additional step of:
comparing and/or correlating (6060) the one or more reconstructed, detected temporal parameter value characteristics, which are associated in particular with the control device (4) of the fuse (1) within the higher-level computer system (12), to one or more other reconstructed, detected temporal parameter value characteristics, which are associated in particular with the control devices (4) of other fuses (1) within the higher-level computer system (12), in particular by the higher-level computer system.

49. The method for operating a supply network (200) according to feature 2,
comprising the additional step of:
detection of events that can be attributed to the same causes, in particular in temporal correlation, in particular by the higher-level computer system (12).

50. The method for operating a supply network (200) according to feature 3,
comprising the additional step of:
adoption (6070) of measures depending on the detected events by the higher-level computer system 12, if necessary.

51. The method for operating a supply network (200) according to one or more of features 1 to 4,
comprising the additional step of:
closing (6010) of a circuit breaker (17) of the fuse (1), in particular by a control device (4) of a fuse (1).

52. The method for operating a supply network (200) according to one or more of features 1 to 5,
wherein the physical parameter to be detected, which the control device (4) of the fuse (1) detects using first means, which, for example, can comprise the analog-to-digital converter (570) of the control device (4) and/or the shunt resistor (24) and/or the auxiliary circuit breaker (23), takes place in a second step 6020.

53. The method for operating a supply network (200) according to one or more of features 1 to 5,
wherein the detection (6200) of the temporal value characteristic of one or more physical parameters to be detected as physical parameters to be detected comprises one or more of the parameters, one or more electrical voltages between circuit nodes, in particular within and outside of the electronic fuse (1), and/or one or more electrical currents through lines, in particular within the fuse (1), and/or temperatures, in particular in and/or in the surroundings of the fuse (1).

54. The method for operating a supply network (200) according to one or more of features 1 to 6 and feature 6,
wherein the detection (6200) of the temporal value characteristic of one or more physical parameters to be detected comprises a conversion (6021) of the electrical analog signals, which are generated by the means for detecting the physical parameters, by sampling, in particular by the control device (4) of the electronic fuse (1), in one or more sampled temporal parameter value characteristics.

55. The method for operating a supply network (200) according to feature 8,
wherein the one or more sampled temporal parameter value characteristics comprise a time-discrete flow of sampling values of the parameter values of the relevant physical parameter and any associated time stamps of these sampling values.

56. The method for operating a supply network (200) according to feature 9,
wherein a sampling instant is associated with a sampling value as a time stamp of this sampling value, in particular by the control device (4) of the fuse (1), and/or
wherein each sampling value is associated with a corresponding sampling instant as the corresponding time stamp of this corresponding sampling value, in particular by the control device (4) of the fuse (1), and/or
wherein sampling values are associated with a sampling instant at equal time intervals as a time stamp of these sampling values, in particular by the control device (4) of the fuse (1).

57. The method for operating a supply network (200) according to feature 10,
wherein the detection (6200) of the temporal value characteristic of one or more physical parameters to be detected comprises performing (6022) a wavelet transform and/or a Fourier transform or a Z-transform and/or a Laplace transform or a different transform and/or a different compression method.

58. The method for operating a supply network (200) according to feature 10 or 11,
wherein the detection (6200) of the temporal value characteristic of one or more physical parameters to be detected comprises the conversion (6022) of the sampled temporal parameter value characteristics into compressed temporal parameter value characteristics, in particular by the control device (4) of the fuse (1).

59. The method for operating a supply network (200) according to one or more of features 1 to 12,
wherein the analysis and compression (6030) of the one or more detected temporal parameter value characteristics of the one or more detected physical parameters comprises the analysis (6031) of the temporal parameter value characteristic of the parameters detected, in particular by the control device (4) of the electronic fuse (1), and/or of the time characteristic of parameters derived therefrom.

60. The method for operating a supply network (200) according to feature 13,
wherein the analysis (6031) of the temporal parameter value characteristic of the parameters detected, in particular by the control device (4) of the electronic fuse (1), and/or of the time characteristic of parameters derived therefrom, comprises the formation of a value of a vector component of a feature vector by a matched filter from the temporal parameter value characteristic of the parameters detected, in particular by the control device (4) of the electronic fuse (1), and/or of the time characteristic of parameters derived therefrom.

61. The method for operating a supply network (200) according to feature 13 or 14,
wherein the analysis (6031) of the temporal parameter value characteristic of the parameters detected, in particular by the control device (4) of the electronic fuse (1), and/or of the time characteristic of parameters derived therefrom, comprises the formation in each case of a value of a vector component of a feature vector by in each case a matched filter from the temporal parameter value characteristic of the parameters detected, in particular by the control device (4) of the electronic fuse (1), and/or of the time characteristic of parameters derived therefrom.

62. The method for operating a supply network (200) according to one or more of features 1 to 15,
wherein the analysis and compression (6030) of the one or more detected temporal parameter value characteristics of the one or more detected physical parameters comprises the extraction (6032) of a current feature vector from the detected temporal parameter value characteristics and/or from parameters derived from the prototypical time characteristics derived therefrom, in particular by the control device (4) of the fuse (1)

63. The method for operating a supply network (200) according to feature 16,
wherein the analysis and compression (6030) of the one or more detected temporal parameter value characteristics of the one or more detected physical parameters comprises the association (6032) of a corresponding time stamp optionally with each feature vector of these feature vectors, in particular by the control device (4) of the fuse (1).

64. The method for operating a supply network (200) according to one or more of features 1 to 17,
wherein the analysis and compression (6030) of the one or more detected temporal parameter value characteristics of the one or more detected physical parameters comprises determining (6033) a distance of the extracted current feature vector to a prototypical feature vector of the prototypical feature vectors of a prototype database (62115).

65. The method for operating a supply network (200) according to one or more of features 1 to 18,
wherein the analysis and compression (6030) of the one or more detected temporal parameter value characteristics of the one or more detected physical parameters comprises the detection (6034) of a prototypical feature vector of a or the prototype database (62115) as a detected prototypical feature vector of the prototype database (62115) if the determined distance for this pair made up of this current feature vector and this prototypical feature vector of the prototype database (62115) is less than a distance threshold value, and if at the same time this determined distance is less than or equal to any other distance between the current feature vector on the one hand and any other prototypical feature vector of the prototype database (62115).

66. The method (7600) for operating a supply network (200), in particular according to one or more of the preceding features,
comprising compression and encryption of the first fuse data of a first electronic fuse (1) in the first electronic fuse (1), and
comprising transmission of the compressed and encrypted first fuse data to a higher-level computer system (12), and
comprising decryption and decompression of the compressed and encrypted first fuse data to form received first fuse data of the first fuse (1) in the higher-level computer system (12).

67. The method according to feature 1,
comprising an adoption of measures depending on the received first fuse data of the first fuse (1) in the higher-level computer system (12) by the higher-level computer system (12).

68. The method (7600) for operating a supply network (200), in particular according to one or more of the preceding features,
comprising compression and encryption of first fuse data of a first electronic fuse (825) in the first electronic fuse (825), and
comprising compression and encryption of second fuse data of a second electronic fuse (805) in the second electronic fuse (805), and
comprising transmission of the compressed and encrypted first fuse data of the first fuse (825) to a higher-level computer system (12), and
comprising transmission of the compressed and encrypted second fuse data of the second fuse (805) to the higher-level computer system (12) and
comprising decryption and decompression of the compressed and encrypted first fuse data of the first fuse to form received first fuse data of the first fuse (825) in the higher-level computer system (12), and
comprising decryption and decompression of the compressed and encrypted second fuse data of the second fuse (805) to form received second fuse data of the second fuse (805) in the higher-level computer system (12), and
comprising an adoption of measures depending on the received first fuse data of the first fuse (825) and depending on the received second fuse data of the second fuse (805) in the higher-level computer system (12) by the higher-level computer system (12).

### Supply Network Operation

1. A method (7600) for operating a supply network (200),
wherein the supply network (200) comprises an electronic fuse (1) with a control device (4) and a circuit breaker (17), and
wherein the supply network (200) comprises a higher-level computer system (12), and
comprising the steps of:
detection (6200) of the temporal value characteristic of one or more physical parameters to be detected, in particular by the control device (4) of the fuse (1), in the form of one or more detected temporal parameter value characteristics;
analysis and compression (6030) of the one or more detected temporal parameter value characteristics of the one or more detected physical parameters, in particular by the control device (4) of the electronic fuse (1);
encryption (7610) of the one or more compressed, detected temporal parameter value characteristics of the one or more physical parameters to be signaled, in particular by the control device (4) of the electronic fuse (1), to form one or more encrypted, compressed, detected temporal parameter value characteristics of the one or more physical parameters to be signaled;
transmission (6040) of the one or more encrypted, compressed, detected temporal parameter value characteristics of the one or more physical parameters to be signaled by the control device (4) of the electronic fuse (1) to the higher-level computer system (12);
decryption (7620) of the one or more encrypted, compressed, detected temporal parameter value characteristics of the one or more physical parameters to be signaled, in particular by the control device (4) of the electronic fuse (1), to form one or more decrypted, compressed, detected temporal parameter value characteristics of the one or more physical parameters to be signaled;
decompression (6050) of the one or more decrypted, received, compressed, detected temporal parameter value characteristics, in particular by the higher-level computer system (12), to form one or more decompressed, reconstructed, detected temporal parameter value characteristics, which are associated in particular with the control device (4) of the fuse (1) within the higher-level computer system (12).

2. The method for operating a supply network (200) according to feature 1,
comprising the additional step of:
comparing and/or correlating (6060) the one or more reconstructed, detected temporal parameter value characteristics, which are associated in particular with the control device (4) of the fuse (1) within the higher-level computer system (12), to one or more other reconstructed, detected temporal parameter value characteristics, which are associated in particular with the control devices (4) of other fuses (1) within the higher-level computer system (12), in particular by the higher-level computer system.

3. The method for operating a supply network (200) according to feature 2,
comprising the additional step of:
detection of events that can be attributed to the same causes, in particular in temporal correlation, in particular by the higher-level computer system (12).

4. The method for operating a supply network (200) according to feature 3,
comprising the additional steps of:
evaluation (6070) of the detected events by the higher-level computer system 12, and
adoption (6070) of measures depending on the detected events by the higher-level computer system 12, if necessary.

5. The method for operating a supply network (200) according to one or more of features 1 to 4,
comprising the additional step of:
closing (6010) of a circuit breaker (17) of the fuse (1), in particular by a control device (4) of a fuse (1).

6. The method for operating a supply network (200) according to one or more of features 1 to 5,
wherein the physical parameter to be detected, which the control device (4) of the fuse (1) detects using first means, which, for example, can comprise the analog-to-digital converter (570) of the control device (4) and/or the shunt resistor (24) and/or the auxiliary circuit breaker (23), takes place in a second step 6020.

7. The method for operating a supply network (200) according to one or more of features 1 to 5,
wherein the detection (6200) of the temporal value characteristic of one or more physical parameters to be detected as physical parameters to be detected comprises one or more of the parameters, one or more electrical voltages between circuit nodes, in particular within and outside of the electronic fuse (1), and/or one or more electrical currents through lines, in particular within the fuse (1), and/or temperatures, in particular in and/or in the surroundings of the fuse (1).

8. The method for operating a supply network (200) according to one or more of features 1 to 6 and feature 6,
wherein the detection (6200) of the temporal value characteristic of one or more physical parameters to be detected comprises a conversion (6021) of the electrical analog signals, which are generated by the means for detecting the physical parameters, by sampling, in particular by the control device (4) of the electronic fuse (1), in one or more sampled temporal parameter value characteristics.

9. The method for operating a supply network (200) according to feature 8,
wherein the one or more sampled temporal parameter value characteristics comprise a time-discrete flow of sampling values of the parameter values of the relevant physical parameter and any associated time stamps of these sampling values.

10. The method for operating a supply network (200) according to feature 9,
wherein a sampling instant is associated with a sampling value as a time stamp of this sampling value, in particular by the control device (4) of the fuse (1), and/or
wherein each sampling value is associated with a corresponding sampling instant as the corresponding time stamp of this corresponding sampling value, in particular by the control device (4) of the fuse (1), and/or
wherein sampling values are associated with a sampling instant at equal time intervals as a time stamp of these sampling values, in particular by the control device (4) of the fuse (1).

11. The method for operating a supply network (200) according to feature 10,
wherein the detection (6200) of the temporal value characteristic of one or more physical parameters to be detected comprises performing (6022) a wavelet transform and/or a Fourier transform or a Z-transform and/or a Laplace transform or a different transform and/or a different compression method.

12. The method for operating a supply network (200) according to feature 10 or 11,
wherein the detection (6200) of the temporal value characteristic of one or more physical parameters to be detected comprises the conversion (6022) of the sampled temporal parameter value characteristics into compressed temporal parameter value characteristics, in particular by the control device (4) of the fuse (1).

13. The method for operating a supply network (200) according to one or more of features 1 to 12,
wherein the analysis and compression (6030) of the one or more detected temporal parameter value characteristics of the one or more detected physical parameters comprises the analysis (6031) of the temporal parameter value characteristic of the parameters detected, in particular by the control device (4) of the electronic fuse (1), and/or of the time characteristic of parameters derived therefrom.

14. The method for operating a supply network (200) according to feature 13,
wherein the analysis (6031) of the temporal parameter value characteristic of the parameters detected, in particular by the control device (4) of the electronic fuse (1), and/or of the time characteristic of parameters derived therefrom, comprises the formation of a value of a vector component of a feature vector by a matched filter from the temporal parameter value characteristic of the parameters detected, in particular by the control device (4) of the electronic fuse (1), and/or of the time characteristic of parameters derived therefrom.

15. The method for operating a supply network (200) according to feature 13 or 14,
wherein the analysis (6031) of the temporal parameter value characteristic of the parameters detected, in particular by the control device (4) of the electronic fuse (1), and/or of the time characteristic of parameters derived therefrom, comprises the formation in each case of a value of a vector component of a feature vector by in each case a matched filter from the temporal parameter value characteristic of the parameters detected, in particular by the control device (4) of the electronic fuse (1), and/or of the time characteristic of parameters derived therefrom.

16. The method for operating a supply network (200) according to one or more of features 1 to 15,
wherein the analysis and compression (6030) of the one or more detected temporal parameter value characteristics of the one or more detected physical parameters comprises the extraction (6032) of a current feature vector from the detected temporal parameter value characteristics and/or from parameters derived from the prototypical time characteristics derived therefrom, in particular by the control device (4) of the electronic fuse (1).

17. The method for operating a supply network (200) according to feature 16,
wherein the analysis and compression (6030) of the one or more detected temporal parameter value characteristics of the one or more detected physical parameters comprises the association (6032) of a corresponding time stamp optionally with each feature vector of these feature vectors, in particular by the control device (4) of the electronic fuse (1).

18. The method for operating a supply network (200) according to one or more of features 1 to 17,
wherein the analysis and compression (6030) of the one or more detected temporal parameter value characteristics of the one or more detected physical parameters comprises determining (6033) a distance of the extracted current feature vector to a prototypical feature vector of the prototypical feature vectors of a prototype database (62115).

19. The method for operating a supply network (200) according to one or more of features 1 to 18,
wherein the analysis and compression (6030) of the one or more detected temporal parameter value characteristics of the one or more detected physical parameters comprises the detection (6034) of a prototypical feature vector of a or the prototype database (62115) as a detected prototypical feature vector of the prototype database (62115) if the determined distance for this pair made up of this current feature vector and this prototypical feature vector of the prototype database (62115) is less than a distance threshold value, and if at the same time this determined distance is less than or equal to any other distance between the current feature vector on the one hand and any other prototypical feature vector of the prototype database (62115).

20. The method for operating a supply network (200) according to one or more of features 1 to 19,
wherein the encryption (7610) of the one or more compressed, detected temporal parameter value characteristics of the one or more physical parameters to be signaled, in particular by the control device (4) of the electronic fuse (1), takes place to form one or more encrypted, compressed, detected temporal parameter value characteristics of the one or more physical parameters to be signaled, with the aid of a random number or pseudo-random number, in particular by the control device (4) of the electronic fuse (1).

21. The method for operating a supply network (200) according to feature 20,
wherein the random number is a true random number.

22. The method for operating a supply network (200) according to feature 21,
wherein the random number is a quantum random number of a quantum random number generator (60).

23. The method for operating a supply network (200) according to one or more of features 1 to 22,
wherein the encryption (7610) of the one or more compressed, detected temporal parameter value characteristics of the one or more physical parameters to be signaled, in particular by the control device (4) of the electronic fuse (1), to form one or more encrypted, compressed, detected temporal parameter value characteristics of the one or more physical parameters to be signaled, is accomplished by means of a PQC encryption method, in particular by the control device (4) of the electronic fuse (1).
   Electronic Fuse with Encrypted and Compressed Data Communication and Application and Developments Thereof

1. The method (7600) for operating a supply network (200), in particular according to one or more of the preceding features,
wherein the supply network (200) comprises an electronic fuse (1) with a control device (4) and a circuit breaker (17), and
wherein the supply network (200) comprises a further sensor (77010), and
wherein the supply network (200) comprises a higher-level computer system (12), and
comprising the steps of:
detection (6200) of the temporal value characteristics of one or more physical parameters to be detected, in particular by the control device (4) of the fuse (1) and by one or more further sensors (77010), in the form of one or more detected temporal parameter value characteristics;
analysis and compression (6030) of the one or more detected temporal parameter value characteristics of the one or more detected physical parameters, in particular by the control device (4) of the electronic fuse (1) and/or a control device of the further sensor (77010);
optionally encrypting (7610) the one or more compressed, detected temporal parameter value characteristics of the one or more physical parameters to be signaled, in particular by the control device (4) of the electronic fuse (1) and/or the control device of the further sensor (77010), to form one or more encrypted, compressed, detected temporal parameter value characteristics of the plurality of physical parameters to be signaled;
transmission (6040) of the plurality of encrypted, compressed, detected temporal parameter value characteristics of the one or more physical parameters to be signaled by the control device (4) of the electronic fuse (1) and/or the control device of the further sensor (77010) to the higher-level computer system (12);
where applicable, decryption (7620) of the plurality of encrypted, compressed, detected temporal parameter value characteristics of the one or more physical parameters to be signaled, in particular by the higher-level computer system (12), to form one or more decrypted, compressed, detected temporal parameter value characteristics of the one or more physical parameters to be signaled if an encryption (7610) has occurred beforehand;
decompression (6050) of the plurality of decrypted, received, compressed, detected temporal parameter value characteristics, in particular by the higher-level computer system (12), to form a plurality of decompressed, reconstructed, detected temporal parameter value characteristics in the form of reconstructed parameter signals (70610, 70610′, 77610), which are associated in particular with the control device (4) of the fuse (1) within the higher-level computer system 12 and/or the control device of the further sensor (77010).

2. The method for operating a supply network (200) according to feature 1, merging the reconstructed parameter signals (70610, 70610′, 77610) with the merged parameter signal (75103), in particular by a combiner (75101) and/or in particular by the higher-level computer system (12).

3. The method for operating a supply network (200) according to feature 2,
wherein merging of the reconstructed parameter signals (70610, 70610′, 77610) with the merged parameter signal (75103), in particular by the higher-level computer system (12),
comprises, when sampling values are missing and/or sampling instants are different, the interpolation of the reconstructed parameter value characteristics (70610, 70610′, 77610) to form interpolated, reconstructed parameter value characteristics with complete reconstructed sampling values at the same sampling instants, in particular by the higher-level computer system (12).

4. The method for operating a supply network (200) according to feature 3,
wherein at least one sampling value of the reconstructed parameter value characteristics of those parameters that the further sensors and sensor systems detect corresponds in time to each sampling value of the interpolated, reconstructed parameter value characteristics.

5. The method for operating a supply network (200) according to feature 3 or 4, comprising the step of:
correlating the interpolated, reconstructed parameter value characteristics and/or the reconstructed parameter value characteristics among one another, in particular by the higher-level computer system (12).

6. The method for operating a supply network (200) according to feature 5, comprising the step of:
detecting conspicuous, typically more or less synchronous events in different reconstructed parameter value characteristics on the basis of correlations of the interpolated, reconstructed parameter value characteristics and/or of the reconstructed parameter value characteristics among one another, in particular by the higher-level computer system (12).

7. The method for operating a supply network (200) according to feature 6, comprising the step of:
deduction of mechanical defects of mechanical devices, in particular by the higher-level computer system (12).

8. The method for operating a supply network (200) according to one or more of features 1 to 7,
comprising the additional step of:
comparison and/or correlation (6060) of the one or more reconstructed, detected temporal parameter value characteristics, which are associated in particular with the control device (4) of the fuse (1) and/or a further sensor (77010) within the higher-level computer system (12), to one or more other reconstructed, detected temporal parameter value characteristics, which are associated in particular with the control devices (4) of other fuses (1) and/or other sensors within the higher-level computer system (12), in particular by the higher-level computer system (12).

9. The method for operating a supply network (200) according to feature 8,
comprising the additional step of:
detection of events that can be attributed to the same causes, in particular in temporal correlation, in particular by the higher-level computer system (12).

10. The method for operating a supply network (200) according to feature 9,
comprising the additional step of:
adoption (6070) of measures depending on the detected events by the higher-level computer system 12, if necessary.

11. The method for operating a supply network (200) according to one or more of features 1 to 10,
comprising the additional step of:
closing (6010) of a circuit breaker (17) of the fuse (1), in particular by a control device (4) of a fuse (1).

12. The method for operating a supply network (200) according to one or more of features 1 to 11,
wherein the physical parameter to be detected, which the control device (4) of the fuse (1) detects using first means, which, for example, can comprise the analog-to-digital converter (570) of the control device (4) and/or the shunt resistor (24) and/or the auxiliary circuit breaker (23), takes place in a second step 6020.

13. The method for operating a supply network (200) according to one or more of features 1 to 12,
wherein the detection (6200) of the temporal value characteristic of one or more physical parameters to be detected as physical parameters to be detected comprises one or more of the parameters, one or more electrical voltages between circuit nodes, in particular within and outside of the electronic fuse (1), and/or one or more electrical currents through lines, in particular within the fuse (1), and/or temperatures, in particular in and/or in the surroundings of the fuse (1).

14. The method for operating a supply network (200) according to one or more of features 1 to 13 and feature 12,
wherein the detection (6200) of the temporal value characteristic of one or more physical parameters to be detected comprises a conversion (6021) of the electrical analog signals, which are generated by the means for detecting the physical parameters, by sampling, in particular by the control device (4) of the electronic fuse (1) or the control device of the further sensor (77010), in one or more sampled temporal parameter value characteristics.

15. The method for operating a supply network (200) according to feature 14,
wherein the one or more sampled temporal parameter value characteristics comprise a time-discrete flow of sampling values of the parameter values of the relevant physical parameter and any associated time stamps of these sampling values.

16. The method for operating a supply network (200) according to feature 15,
wherein a sampling instant is associated with a sampling value as a time stamp of this sampling value, in particular by the control device (4) of the fuse (1) or the control device of the further sensor (77010), and/or
wherein a corresponding sampling instant is associated with each sampling value as the corresponding time stamp of this corresponding sampling value, in particular by the control device (4) of the fuse (1) or the control device of the further sensor (77010), and/or
wherein sampling values are associated with a sampling instant at equal time intervals as a time stamp of these sampling values, in particular by the control device (4) of the fuse (1) or the control device of the further sensor (77010).

17. The method for operating a supply network (200) according to feature 16,
wherein the detection (6200) of the temporal value characteristic of one or more physical parameters to be detected comprises performing (6022) a wavelet transform and/or a Fourier transform or a Z-transform and/or a Laplace transform or a different transform and/or a different compression method, in particular by the control device (4) of the fuse (1) or the control device of the further sensor (77010).

18. The method for operating a supply network (200) according to feature 16 or 17,
wherein the detection (6200) of the temporal value characteristic of one or more physical parameters to be detected comprises the conversion (6022) of the sampled temporal parameter value characteristics into compressed temporal parameter value characteristics, in particular by the control device (4) of the fuse (1) or the control device of the further sensor (77010).

19. The method for operating a supply network (200) according to one or more of features 1 to 18,
wherein the analysis and compression (6030) of the one or more detected temporal parameter value characteristics of the one or more detected physical parameters comprises the analysis (6031) of the temporal parameter value characteristic of the parameters detected, in particular by the control device (4) of the fuse (1) or the control device of the further sensor (77010), and/or of the time characteristic of parameters derived therefrom.

20. The method for operating a supply network (200) according to feature 19,
wherein the analysis (6031) of the temporal parameter value characteristic of the parameters detected, in particular by the control device (4) of the fuse (1) or the control device of the further sensor (77010), and/or of the time characteristic of parameters derived therefrom, comprises the formation of a value of a vector component of a demand vector by a matched filter from the temporal parameter value characteristic of the parameters detected, in particular by the control device (4) of the fuse (1) or the control device of the further sensor (77010), and/or of the time characteristic of parameters derived therefrom.

21. The method for operating a supply network (200) according to feature 19 or 20,
wherein the analysis (6031) of the temporal parameter value characteristic of the parameters detected, in particular by the control device (4) of the electronic fuse (1), and/or of the time characteristic of parameters derived therefrom, comprises the formation in each case of a value of a vector component of a demand vector by in each case a matched filter from the temporal parameter value characteristic of the parameters detected, in particular by the control device (4) of the fuse (1) or the control device of the further sensor (77010), and/or of the time characteristic of parameters derived therefrom.

22. The method for operating a supply network (200) according to one or more of features 1 to 21,
wherein the analysis and compression (6030) of the one or more detected temporal parameter value characteristics of the one or more detected physical parameters comprises the extraction (6032) of a current demand vector from the detected temporal parameter value characteristics and/or from parameters derived from the prototypical time characteristics derived therefrom, in particular by the control device (4) of the fuse (1) or the control device of the further sensor (77010),

23. The method for operating a supply network (200) according to feature 22,
wherein the analysis and compression (6030) of the one or more detected temporal parameter value characteristics of the one or more detected physical parameters comprises the association (6032) of a corresponding time stamp optionally with each demand vector of these demand vectors, in particular by the control device (4) of the fuse (1) or the control device of the further sensor (77010).

24. The method for operating a supply network (200) according to one or more of features 1 to 23,
wherein the analysis and compression (6030) of the one or more detected temporal parameter value characteristics of the one or more detected physical parameters comprises determining (6033) a distance of the extracted current demand vector to a prototypical demand vector of the prototypical demand vectors of a prototype database (62115).

25. The method for operating a supply network (200) according to one or more of features 1 to 24,
wherein the analysis and compression (6030) of the one or more detected temporal parameter value characteristics of the one or more detected physical parameters comprises the detection (6034) of a prototypical demand vector of a or the prototype database (62115) as a detected prototypical demand vector of the prototype database (62115) if the determined distance for this pair made up of this current demand vector and this prototypical demand vector of the prototype database (62115) is less than a distance threshold value, and if at the same time this determined distance is less than or equal to any other distance between the current demand vector on the one hand and any other prototypical demand vector of the prototype database (62115).

26. The method for operating a supply network (200) according to one or more of features 1 to 25,
wherein the encryption (7610) of the one or more compressed, detected temporal parameter value characteristics of the one or more physical parameters to be signaled, in particular by the control device (4) of the electronic fuse (1), to form one or more encrypted, compressed, detected temporal parameter value characteristics of the one or more physical parameters to be signaled is accomplished with the aid of a random number or pseudo-random number, in particular by the control device (4) of the fuse (1) or the control device of the further sensor (77010).

27. The method for operating a supply network (200) according to feature 26,
wherein the random number is a true random number.

28. The method for operating a supply network (200) according to feature 27,
wherein the random number is a quantum random number of a quantum random number generator (60).

29. The method for operating a supply network (200) according to one or more of features 1 to 28,
wherein the encryption (7610) of the one or more compressed, detected temporal parameter value characteristics of the one or more physical parameters to be signaled, in particular by the control device (4) of the fuse (1) or the control device of the further sensor (77010), to form one or more encrypted, compressed, detected temporal parameter value characteristics of the one or more physical parameters to be signaled, is accomplished by means of a PQC encryption method, in particular by the control device (4) of the fuse (1) or the control device of the further sensor (77010).

### LIST OF REFERENCE CHARACTERS

1 electronic fuse;
2 computer core, in particular microcontroller;
3 control system;
4 control device;
5 voltage supply/boost converter;
6 operating voltage;
7 emergency power supply;
8 power reserve;
9 external data bus;
9′ external data bus ring;
10 data bus interface. The data bus interface can be a data bus transceiver to a wired data bus or a wireless data interface, in particular an optical data interface with an optical data connection.
11 internal data bus;
12 higher-level computer system, in particular of the vehicle. The higher-level computer system can be identical to a control device (4) of a fuse of the fuses of a supply network;
13 watchdog, in particular watchdog timer. It can be the watchdog 4104.5 of the quantum random number generator 60, 4100;
14 non-volatile memory. The non-volatile memory can, for example, comprise a flash memory or an EEPROM or a ROM or the like. volatile read-write memory. The read-write memory can be, for example, a RAM or an SRAM or a DRAM or an FRAM or an MRAM or the like;
16 gate drive circuit for controlling and monitoring the circuit breaker (17);
16′ gate drive circuit for controlling and monitoring the second circuit breaker (17′);
16″ gate drive circuit for controlling and monitoring the third circuit breaker (17″);
16″′ gate drive circuit for controlling and monitoring the fourth circuit breaker (17″′);
17 circuit breaker, also referred to as circuit breaker;
17′ second circuit breaker;
17″ third circuit breaker;
17″′ fourth circuit breaker;
18 first terminal of the circuit breaker (17);
18′ first terminal of the second circuit breaker (17′);
18″ first terminal of the third circuit breaker (17″);
18″′ first terminal of the fourth circuit breaker (17″′);
19 second terminal of the circuit breaker (17);
19′ second terminal of the second circuit breaker (17′);
19″ second terminal of the third circuit breaker (17″);
19″′ second terminal of the fourth circuit breaker (17″′);
20 control line for controlling the circuit breaker (17);
20′ control line for controlling the second circuit breaker (17′);
20″ control line for controlling the third circuit breaker (17″);
20″′ control line for controlling the fourth circuit breaker (17″′);
21 monitoring line for detecting the voltage between the second terminal (19) of the circuit breaker (17) and the control line (20) of the circuit breaker (17);
21′ monitoring line for detecting the voltage between the second terminal (19′) of the second circuit breaker (17′) and the control line (20′) of the second circuit breaker (17′);
21″ monitoring line for detecting the voltage between the second terminal (19″) of the third circuit breaker (17″) and the control line (20″) of the third circuit breaker (17″);
21″′ monitoring line for detecting the voltage between the second terminal (19″′) of the fourth circuit breaker (17″′) and the control line (20″′) of the fourth circuit breaker (17″′);
22 monitoring line for detecting the voltage between the first terminal (18) of the circuit breaker (17) and the control line (20) of the second circuit breaker (17);
22′ monitoring line for detecting the voltage between the first terminal (18′) of the second circuit breaker (17′) and the control line (20′) of the second circuit breaker (17′);
22″ monitoring line for detecting the voltage between the first terminal (18″) of the third circuit breaker (17″) and the control line (20″) of the third circuit breaker (17″′);
22″′ monitoring line for detecting the voltage between the first terminal (18″′) of the fourth circuit breaker (17″′) and the control line (20″′) of the fourth circuit breaker (17″′);
23 auxiliary circuit breaker for detecting a current which is proportional to the current (29) through the circuit breaker (17) or corresponds to it in a different way;
23′ second auxiliary circuit breaker for detecting a current which is proportional to the current (29′) through the second circuit breaker (17′) or corresponds to it in a different way;
23″ third auxiliary circuit breaker for detecting a current which is proportional to the current (29″) through the third circuit breaker (17″) or corresponds to it in a different way;
23″′ fourth auxiliary circuit breaker for detecting a current which is proportional to the current (29″′) through the fourth circuit breaker (17″′) or corresponds to it in a different way;
24 shunt resistor for detecting the current through the auxiliary circuit breaker 23;
24′ second shunt resistor for detecting the current through the second auxiliary circuit breaker
23′ of the second circuit breaker 17′;
24″ third shunt resistor for detecting the current through the third auxiliary circuit breaker 23″ of the third circuit breaker 17″;
24″′ fourth shunt resistor for detecting the current through the fourth auxiliary circuit breaker 23″′ of the fourth circuit breaker 17″′;
25 measuring line for detecting the voltage drop across the shunt resistor 24;
25′ second measuring line for detecting the voltage drop across the second shunt resistor 24′;
25″ third measuring line for detecting the voltage drop across the third shunt resistor 24″;
25″′ fourth measuring line for detecting the voltage drop across the fourth shunt resistor 24″;
26 first terminal of the circuit breaker 17;
26′ first terminal of the second circuit breaker 17′;
26″ first terminal of the third circuit breaker 17″;
26″′ first terminal of the fourth circuit breaker 17″′;
27 control terminal of the circuit breaker 17;
27′ control terminal of the second circuit breaker 17′;
27″ control terminal of the second circuit breaker 17″;
27″′ control terminal of the second circuit breaker 17″′;
28 second terminal of the circuit breaker 17;
28′ second terminal of the second circuit breaker 17′;
28″ second terminal of the third circuit breaker 17″;
28″′ second terminal of the fourth circuit breaker 17″′;
29 current through the circuit breaker 17;
29′ current through the second circuit breaker 17′;
29″ current through the third circuit breaker 17″;
29″′ current through the fourth circuit breaker 17″′;
30 oscillator and clock-pulse generation, which supply the control device (4) of the relevant fuse with a clock pulse;
35 timer and/or clock of the control device (4);
36 electrical current through the shunt resistor (24);
36′ electrical current through the second shunt resistor 24′ for detecting the current through the second auxiliary circuit breaker 23′ of the second circuit breaker 17′;
36″′ electrical current through the third shunt resistor 24″ for detecting the current through the third auxiliary circuit breaker 23″ of the third circuit breaker 17″;
36″′ electrical current through the fourth shunt resistor 24″′ for detecting the current through the fourth auxiliary circuit breaker 23″′ of the fourth circuit breaker 17″′;
40 temperature sensor;
50 system made up of electronic fuse (1), data bus (9) and higher-level computer system (12);
60 quantum random number generator (QRNG) or true random number generator (TRNG) or random number generator (RNG) or pseudo-random number generator (PRNG)
70 one or more cryptography accelerators 7, for example a DES accelerator and/or an AES accelerator 7;
71 one or more manufacturer memory firewalls 8;
72 manufacturer memory;
73 supplier memory firewalls;
74 supplier-manufacturer memory
75 semiconductor-manufacturer memory firewalls;
76 semiconductor-manufacturer manufacturer memory
77 one or more CRC modules (cyclic redundancy check);
78 one or more timer modules;
79 one or more safety monitoring circuits and safety control circuits;
80 one or more reset circuits;
81 one or more ground circuits;
82 one or more input/output circuits;
200 supply network;
201 reference potential nodes. The reference potential node is typically the ground of the vehicle. In the figures, the reference potential node is not always shown for better clarity and is also not always denoted by the reference character. The circuit symbol for the ground denotes the reference potential node in the figures, if shown.
210 first device part of the supply network (200);
211 second device part of the supply network (200);
212 third device part of the supply network (200);
213 fourth device part of the supply network (200);
214 first fuse of the first device part (210) of the supply network (200), which fuse can electrically connect the third line section (245) to the first line section (240) or can locally disconnect the third line section (245) from the first line section (240);
215 second fuse of the second device part (211) of the supply network (200), which fuse can electrically connect the third line section (245) to the first line section (240) or can locally disconnect the third line section (245) from the first line section (240);
216 third fuse of the third device part (212) of the supply network (200), which fuse can electrically connect the third line section (245) to the second line section (241) or can locally disconnect the third line section (245) from the first line section (240);
217 fourth fuse of the fourth device part (213) of the supply network (200), which fuse can electrically connect the third line section (245) to the second line section (241) or can locally disconnect the third line section (245) from the first line section (240);
220 fifth device part of the supply network (200);
221 sixth device part of the supply network (200);
222 seventh device part of the supply network (200);
223 eighth device part of the supply network (200);
225 fifth fuse, which can disconnect the fifth device part (220) of the supply network (200) from the first line section (240) or can connect the fifth device part (220) of the supply network (200) to the first line section (240);
226 sixth fuse, which can disconnect the sixth device part (221) of the supply network (200) from the first line section (240) or can connect the sixth device part (222) of the supply network (200) to the first line section (240);
227 seventh fuse, which can disconnect the seventh device part (222) of the supply network (200) from the first line section (240) or can connect the seventh device part (223) of the supply network (200) to the first line section (240);
228 eighth fuse, which can disconnect the eighth device part (223) of the supply network (200) from the first line section (240) or can connect the eighth device part (224) of the supply network (200) to the first line section (240);
230 ninth device part of the supply network (200);
231 tenth device part of the supply network (200);
232 eleventh device part of the supply network (200);
233 twelfth device part of the supply network (200);
235 ninth fuse, which can disconnect the ninth device part (230) of the supply network (200) from the second line section (241) or can connect the ninth device part (230) of the supply network (200) to the second line section (241);
236 tenth fuse, which can disconnect the tenth device part (231) of the supply network (200) from the second line section (241) or can connect the tenth device part (231) of the supply network (200) to the second line section (241);
237 eleventh fuse, which can disconnect the eleventh device part (232) of the supply network (200) from the second line section (241) or can connect the eleventh device part (232) of the supply network (200) to the second line section (241);
238 twelfth fuse, which can disconnect the twelfth device part (233) of the supply network (200) from the second line section (241) or can connect the twelfth device part (233) of the supply network (200) to the second line section (241);
240 first line section;
241 second line section;
242 fifth line section;
243 sixth line section;
245 third line section
246 fourth line section
250 first power source;
251 second power source;
255 thirteenth fuse, which can disconnect the first power source (255) of the supply network (200) from the third line section (245) or can connect the first power source (255) of the supply network (200) to the third line section (245);
256 fourteenth fuse, which can disconnect the second power source (256) of the supply network (200) from the third line section (245) or can connect the second power source (256) of the supply network (200) to the third line section (245) or fourth line section (246);
262 plug-in option (262) for an electronic fuse (216) of a device part (212)
270 tree starting point of the tree structure of the supply network (200);
280 first control device 4 of the first fuse (214);
281 second control device 4 of the second fuse (215);
282 third control device 4 of the third fuse (216);
283 fourth control device 4 of the fourth fuse (217);
284 fifth control device 4 of the fifth fuse (220);
285 sixth control device 4 of the sixth fuse (221);
286 seventh control device 4 of the seventh fuse (222);
287 eighth control device 4 of the eighth fuse (223);
288 ninth control device 4 of the ninth fuse (230);
289 tenth control device 4 of the tenth fuse (231);
290 eleventh control device 4 of the eleventh fuse (232);
291 twelfth control device 4 of the twelfth fuse (233);
292 thirteenth control device 4 of the thirteenth fuse (255);
293 fourteenth control device 4 of the fourteenth fuse (256);
400 fuse box;
405 electronic fuse
410 slot for an electronic fuse (405) The slot has a first contact for the first terminal (18) of the circuit breaker (17) of the electronic fuse (405). The slot has a second contact for the operating voltage terminal (6) of the electronic fuse (405). The slot has a third contact for the reference potential terminal (201) of the electronic fuse (405). The slot has a fourth contact for the external data bus (9) of the electronic fuse (405). The slot has a fifth contact for the second terminal (19) of the circuit breaker (17) of the electronic fuse (405).
415 melting fuse;
420 slot for a melting fuse (415);
425 fuse body of the electronic fuse (415);
430 first contact (430) of the slot (410) for an electronic fuse (405), wherein the first contact serves for the connection of the first terminal (18) of an electronic fuse (405);
435 fourth contact (435) of the slot (410) for an electronic fuse (405), wherein the fourth contact serves for the connection of a supply voltage line to supply power to the control device (4) of the electronic fuse (405);
440 third contact (440) of the slot (410) for an electronic fuse (405), wherein the third contact serves for the connection of the data line (9) of a data interface (10) of the control circuit (4) of the electronic fuse (405);
445 fourth contact (445) of the slot (410) for an electronic fuse (405), wherein the second contact serves for the connection of the second terminal (19) of an electronic fuse (405);
450 first contact of the plug-in connector of the fuse body (425) of the electronic fuse (405), wherein the first contact serves for the connection of the first terminal (18) of an electronic fuse (405);
455 fourth contact (455) of the plug-in connector of the fuse body (425), wherein the fourth contact serves for the connection of a supply voltage line (6) to electrically connect a power supply of the control device (4) of the electronic fuse (405)to this fourth contact (455) of the slot (410);
460 fifth contact (460) of the plug-in connector of the fuse body (425), wherein the fifth contact serves for the connection of a reference potential line (201) to electrically connect a power supply of the control device (4) of the electronic fuse (405) to this fifth contact (460) of the slot (410) and to provide a reference potential;
470 second contact (470) of the plug-in connector (410) of the fuse body (425), wherein the second contact serves for the connection of the second terminal (19) of an electronic fuse (405);
475 fifth contact (475) of the slot (410) for an electronic fuse (405), wherein the fifth contact serves for the connection of a reference potential line to supply power to the control device (4) of the electronic fuse (405) and as a potential reference point;
475 control computer, which controls the fuse box (400) and/or the electronic fuses (405) via the fuse bus (9) and/or reads measured values and/or data from the fuses (405);
480 operating voltage source for the operation of the control devices (4) of the electronic fuses (405);
485 output of the fuse box (400) for supplying a load;
505 first test current source which by means of the first control signal (510) is provided with a first modulation signal {505} of a first signal generator (520). In this case, the curly brackets are supposed to indicate that {505} is the first modulation signal with which the first current (515) of the first test current source is modulated;
{505} first modulation signal with which the first current (515) of the first test current source (505) is modulated;
505′ third test current source which is provided with a second modulation signal {505′} of a second signal generator (520′) by means of the second control signal (510′). In this case, the curly brackets are supposed to indicate that {505′} is the second modulation signal with which the current (515) of the third test current source is modulated. Optionally, the second modulation signal {505′} is orthogonal to the first modulation signal {505} with respect to the scalar product ({505}|{505′})=∫₀^{T}{505}×{505′}dt, wherein T is the period of the first modulation signal {505} or the second modulation signal {505′}. The period T of the first modulation signal {505} is optionally equal to the period T of the second modulation signal {505′}. This enables the two modulation signals to be separated ({505}, {505′}). Optionally, therefore,
   {{505}|{505′})=∫₀^{T}{505}×{505′},dt=0, which means orthogonality;
{505′} second modulation signal with which the second current (515′) of the third test current source (505) is modulated;
510 first control signal of the first electronic test current source (505);
510′ third control signal of the third electronic test current source (505′};
515 first additional current which the first test current source (510) introduces into the circuit breaker (17);
515′ second additional current which the test current source (510) introduces into the circuit breaker (17);
520 first signal generator of the first modulation signal {505};
520′ second signal generator of the second modulation signal {505′};
525 first correlator. The first correlator optionally comprises one or more input amplifiers which detect, filter, and process the voltages between the first measuring contacts (21, 25, 27, 28, 22). Optionally, the first correlator comprises, for example, a first synchronous demodulator which checks one of the measurable voltages for first components of the first modulation signal {505} of the first current (515) of the first test current source (505). Optionally, the first synchronous demodulator of the first correlator uses a correlation in the form of a scalar product, for example according to the formula:

$$A = 〈 \{ 505 \} \vert {V}_{x v} ( t ) 〉 = {\int }_{0}^{T} \{ 505 \} \times {V}_{xy} ( t ) dt$$

A here represents the value of the first component, and V_{xy} represents a voltage between the first measuring contacts (21, 25, 27, 28, 22). The first correlator optionally uses a voltage V_{xy} between the second terminal (28) of the first circuit breaker (17) and the first control terminal (27) of the first circuit breaker (17);
525′ second correlator. The second correlator optionally comprises one or more input amplifiers which detect, filter, and process the voltages between the second measuring contacts (21′, 25′, 27′, 28′, 22′). Optionally, the second correlator comprises, for example, a second synchronous demodulator which checks one of the measurable voltages for second components of the second modulation signal {505′} of the second current (515′) of the third test current source {505′}. Optionally, the second synchronous demodulator of the second correlator uses a correlation in the form of a scalar product, for example according to the formula:

$${A}^{′} = 〈 \{ {505}^{′} \} \vert {V}_{x y}^{′} ( t ) 〉 = {\int }_{0}^{T} \{ 50 {5}^{′} \} \times {V}_{x y} ( {t}^{′} ) d t$$

A′ here represents the value of the second component, and V′_{xy} represents a voltage between the second measuring contacts (21′, 25′, 27′, 28′, 22). The second correlator optionally uses a voltage V_{xy} between the second terminal (28′) of the second circuit breaker (17′) and the second control terminal (27′) of the second circuit breaker (17′);
530 first gate drive of the control contact (27) of the first circuit breaker (17) and first control signal generation for the control signal of the control line (20) of the first circuit breaker (17) for controlling the first circuit breaker (17);
530′ second gate drive of the control contact (27′) of the second circuit breaker (17′) and second control signal generation for the control signal of the control line (20′) of the second circuit breaker (17′) for controlling the second circuit breaker (17′);
535 housing of the fuse (1);
540 optical data connection;
545 optical window;
550 optical data interface;
551 further optical data interface;
555 optical data interface, for example of the higher-level system, in particular of the higher-level computer system (12);
556 first data interface, for example of the higher-level system, in particular of the higher-level computer system (12)
556′ second data interface, for example of the higher-level system, in particular of the higher-level computer system (12)
557 sensor data interface, for example of the higher-level system, in particular of the higher-level computer system (12), for example for sensor data of a further sensor 77010, which is transmitted by this sensor 77010 to the higher-level computer system 12 via a sensor data bus 77020;
560 laser or an LED, in particular a silicon-based LED, in particular a silicon avalanche LED, in particular a SPAD diode operated as an LED;
561 second laser or second LED, in particular a silicon-based LED, in particular a silicon avalanche LED, in particular a SPAD diode operated as an LED;
565 driving device;
570 analog-to-digital converter;
575 voltage signal (575) of the silicon LED (560);
576 voltage signal (576) of the second silicon LED (560);
580 optical waveguide;
585 temperature sensor evaluation devices;
586 temperature sensor;
610 second data bus interface;
615 switch for diverting currents of the load flowing to the power source into a current sink;
710 computer (server) of a service provider, in particular a computer system of an automobile manufacturer and thus possibly also a repair shop;
720 optionally encrypted data connection between the control computer of the vehicle—e.g., a higher-level computer system 12—and a computer 710 of a service provider, in particular a computer system of the automobile manufacturer of the vehicle;
730 requesting/operating person;
740 data input means and data output means, in particular a terminal or a PC or a laptop or a tablet or a smartphone etc.;
750 computer (750) of a further service provider or further computer of the service provider that controls the computer (710);
805 further fuse;
810 second further fuse;
815 first connected distribution tree;
820 second connected distribution tree;
825 electronic fuse;
830 load
835 further load;
905 second test current source which is provided with a modulation signal of a second signal generator (920) by means of the control signal (910).
905′ second test current source, which is provided with a modulation signal of a second signal generator (920′) by means of the control signal (910′).
910 second control signal of the second electronic test current source (905);
910′ fourth control signal of the fourth electronic test current source (905′);
915 additional current which the second test current source (910) extracts from the circuit breaker (17);
915′ additional current which the second test current source (910′) extracts from the second circuit breaker (17′);
920 second signal generator of the modulation signal;
920′ fourth signal generator of the modulation signal;
925 emergency control;
1000 cross-over fuse;
1005 first supply line section of a first supply line;
1010 second supply line section of a first supply line;
1015 first supply line section of a second supply line;
1020 second supply line section of a second supply line;
1025 first electrical node;
1030 second electrical node;
1035 first electronic fuse;
1040 second electronic fuse;
1045 third electronic fuse;
1050 fourth electronic fuse;
1055 second supply line section of first supply line;
1060 second supply line section of second supply line;
1065 third node;
1070 fourth node;
1110 first cross-over fuse
1111 second cross-over fuse
1112 third cross-over fuse
1113 fourth cross-over fuse
1114 fifth cross-over fuse
1115 sixth cross-over fuse
1116 seventh cross-over fuse
1117 eighth cross-over fuse
1118 ninth cross-over fuse
1150 first power source;
1151 second power source;
1152 third power source;
1153 fourth power source;
1154 fifth power source;
1155 sixth power source;
1160 to 1183
   supply line section;
1200 method for operating a fuse;
1210 providing a supply network (250, 251, 210 to 213, 245) having a power-supplying device part of the vehicle;
1220 supplying electrical power to the power-supplying device part (210) from a power source (251, 250) of the vehicle;
1230 connecting (1230) a first terminal of a further line section (240) to the power-supplying device part (210) of the vehicle;
1240 connecting (1240) a second terminal of the further line section (240) to a further device part (220, 221) of the vehicle;
1250 signaling a switch-on signal to the control device (280, 4) of the power-supplying device part (210);
1260 changing the logic state of the memory to a second logic state depending on the logic state of the memory;
1270 supplying the further device part (220 to 221) of the vehicle with electrical power via the further line section (240) depending on the logic state of the memory;
1280 providing (1280) a supply network (200) having a device part (210) of the vehicle, hereinafter referred to as a power-supplying device part (210);
1300 method for operating a vehicle, with payment for the admissibility of setting a configuration of electronic fuses;
1305 provision of the vehicle;
1310 preventing (1310) the supply of power to an associated electrical load by means of the corresponding fuse associated with this load;
1315 establishing (1315) an encrypted data connection (720) between the control computer (12) of the vehicle, i.e., a higher-level computer system (12), and a computer (710) of a service provider, in particular a computer system of the automobile manufacturer of the vehicle;
1320 authentication (1320) of the vehicle by the control computer of the vehicle, i.e., a higher-level computer system (12), to the computer (710) of the service provider, wherein the authentication data of the vehicle can comprise, for example, the data of the vehicle and/or of the car key and/or of a SIM card in the vehicle and/or of a vehicle-specific password input or password generation and/or biometric user data of a vehicle owner, etc.;
1325 authentication (1325) of the computer (710) of the service provider to the control computer of the vehicle, i.e., a higher-level computer system (12);
1330 authentication (1330) of the requesting person (730) by the control computer of the vehicle, i.e., a higher-level computer system (12), to the computer (710) of the service provider, wherein the authentication data can comprise, for example, the data of the vehicle and/or of the personalized car key, of a personalized SIM card, of a personalized password input, biometric user data, etc.
1335 generation (1335) or provision of an activation code by the computer (710) of the service provider;
1340 transmission (1340) of the activation code by the computer of the service provider (710) to the control computer of the vehicle, i.e., to a higher-level computer system (12);
1345 verification (1345) of the admissibility and/or syntactical correctness and/or the situational admissibility of the activation code by the control computer of the vehicle, i.e., by the higher-level computer system (12);
1350 enabling (1350) the supply of power to an associated electrical load (220) by means of the corresponding fuse (225) if the activation code is admissible and/or syntactically correct and/or is situationally admissible;
1355 transmission (1355) of billing data to a or the computer (710) of a or the service provider, in particular to a or the computer system of the automobile manufacturer, wherein memory information in the computer (710) of the service provider marks that the invoice is not paid;
1360 creation (1360) of an invoice depending on the transmitted billing data by a or the computer (710) of a or the service provider, in particular to a or the computer system of the automobile manufacturer;
1365 transmission (1365) of the invoice at a or the computer (710) of a or the service provider, in particular to a or the computer system (740) of the ordering person (730), or to the ordering person (730);
1370 settlement (1370) of the invoice by a or the computer (710) of a or the service provider and/or the requesting person (730);
1375 marking (1375) of the memory information in the computer of the service provider (740) that the invoice is paid;
1400 method (1400) for operating a vehicle; activation of power sources in the vehicle;
1405 provision of the vehicle;
1410 preventing (1410) the supply of power to an associated electrical power source (250, 251) by means of the corresponding associated fuse (255, 260);
1415 establishing (1415) an encrypted connection (720) between the control computer of the vehicle, i.e., the higher-level computer system (12), and a computer (710) of a service provider, in particular a computer system (710) of the automobile manufacturer;
1420 authentication (1420) of the vehicle by the control computer of the vehicle, i.e., by the higher-level computer system (12), to the computer (710) of the service provider, wherein the authentication data of the vehicle can comprise, for example, the data of the vehicle and/or of the car key and/or of a SIM card in the vehicle and/or of a vehicle-specific password input or password generation and/or biometric user data of a vehicle owner, etc.;
1425 authentication (1430) of the computer of the service provider to the control computer of the vehicle, i.e., to the higher-level computer system (12);
1430 authentication (1430) of the requesting person (730) by the control computer of the vehicle, i.e., by the higher-level computer system (12), to the computer (710) of the service provider, wherein the authentication data can comprise, for example, the data of the vehicle and/or of the personalized car key, of a personalized SIM card, of a personalized password input, biometric user data, etc.;
1435 generation (1435) or provision of an activation code by the computer (710) of the service provider;
1440 transmission (1440) of the activation code by the computer (710) of the service provider to the control computer of the vehicle, i.e., to the higher-level computer system (12);
1445 verification (1445) of the admissibility and/or syntactical correctness and/or the situational admissibility of the activation code by the control computer (12) of the vehicle, i.e., by the higher-level computer system (12);
1450 enabling (1450) the supply of power to an associated electrical power source (250, 251) by means of the corresponding associated fuse (255, 260);
1455 transmission (1455) of billing data to a or the computer (710) of a or the service provider, in particular to a or the computer system of the automobile manufacturer, wherein memory information in the computer (710) of the service provider marks that the invoice is not paid;
1460 creation (1460) of an invoice depending on the transmitted billing data by a or the computer (710) of a or the service provider, in particular to a or the computer system of the automobile manufacturer;
1465 transmission (1465) of the invoice, in particular by a or the computer (710) of a or the service provider to a or the computer (750) of a or the service provider, in particular to a or the computer system of the ordering person, or to the ordering person (730);
1470 settlement (1470) of the invoice by a or the computer (750) of a or the service provider and/or the requesting person (730);
1475 marking (1475) of the memory information in the computer (710) of the service provider that the invoice is paid;
1505 line section to be protected;
1510 arc;
1515 cable harness;
1520 current measuring device (1520) inserted into the line section (1505) to be protected;
1525 electrical current (1525) through the line section (1505) to be protected;
1600 method (1600) for detecting non-extinguishing arcs (1510) in the cable harness (1515) with line sections (485, 1505) of a vehicle;
1605 detecting (1605) a time segment of the time characteristic of the electrical current (1525) through the line section (1505) to be protected and generating an associated value characteristic (1610) of the detected value of the electrical current (1525) through the line section (1505) to be protected of this time segment, in particular by means of a current measuring device (1520) which is inserted into the line section (1505);
1610 value characteristic (1610) of the detected value of the electrical current (1525) through the line section (1505) to be protected of this time segment;
1615 performing (1615) a spectral analysis of the detected value characteristic (1610) of this time segment depending on the generated temporal value characteristic (1610) of the time characteristic of the electrical current (1525) through the line section (1505) to be protected and generating a spectral analysis result (1620), in particular by means of the control device (4) of the electronic fuse (825) or by means of a higher-level computer system (12) or by means of a higher-level control device (12) which communicates with the control device (4) of the fuse (825) via a data bus (9) and which assumes the role of a higher-level computer system (12);
1620 spectral analysis result. The spectral analysis result is optionally a vector with numerical values. Each of the numerical values of this vector essentially comprises an amplitude value of the result of the Fourier transform and/or of the Laplace transform and/or of the wavelet transform and/or of a different integral transform and/or of the Z-transform of the detected temporal value characteristic (1610) of this time segment of the time characteristic of the electrical current (1525) through the line section (1505) to be protected for a transform parameter value of the relevant transform, for example a frequency or an extent for wavelets, etc. The Fourier transform and the Laplace transform are particularly preferred. In this case, the spectral analysis result is a vector with numerical values, wherein each of the numerical values of this vector essentially indicates an amplitude value for a frequency or a frequency range;
1625 using (1625) the values of the spectral analysis result (1620) of the detected value characteristic (1610) of this time segment and/or values derived therefrom as the current feature vector (1630);
1630 current feature vector;
1635 mapping (1635) the current feature vector (1630) of the values of the spectral analysis result (1620) of the detected value characteristic (1610) of this time segment onto predefined feature vectors (1640) of spectral base structures from a stored set (1650) of predefined feature vectors (1640) of spectral base structures in a base structure database (1645). This mapping is optionally carried out by means of scalar product formation between these feature vectors (1640). The mapping serves to generate a spectral parameter set (1655). Such a spectral parameter set (1655) is a vector and typically comprises at least one, optionally in each case a similarity value for a pairing, but as much as possible for all possible pairings from a data set of the base structure database (1645) per pairing on the one hand and the current feature vector (1640) per pairing on the other hand. The data set (1640) of the base structure database (1645) is a prototypical feature vector (1640), for example for an event of normal operation or for example for a prototypical arc (1510). The base structure database (1645) thus optionally comprises a plurality of such prototypical feature vectors (1640) of different prototypical arcs (1510), which were optionally measured beforehand in the laboratory. For example, the control device (4) of the fuse (825) can then calculate the similarity value for such a pairing by means of a scalar product from the similarity between a predefined feature vector (1640) of the data set of the base structure database (1645) on the one hand and the current feature vector (1630) on the other hand. This similarity value is thus optionally the similarity value of precisely one spectral base structure from the stored set (1650) of predefined feature vectors (1640) of spectral base structures of the base structure database (1645) on the one hand and the current feature vector (1630) on the other hand. The mapping described here optionally comprises the calculation of the similarity values for a predefined feature vector (1640), better all predefined feature vectors of spectral base structures (1640) in the base structure database (1645). The control device (4) of the electronic fuse (825) and/or a higher-level control device (12), which communicates with the control device (4) of the fuse (825) via a data bus (9) and which assumes the role of a higher-level computer system (12), optionally perform this mapping and generation. The similarity values calculated in this way then form a new vector, wherein each value of this new vector corresponds to a predefined feature vector (1640) of the predefined feature vectors (1640) of spectral base structures of the base structure database (1645), and the proportion of this predefined feature vector of the predefined feature vectors of spectral base structures (1640) of the base structure database (1645) is reproduced in the current feature vector (1630);
1640 predefined feature vector (1640) of a spectral base structure within a stored set (1650) of predefined feature vectors (1640) of spectral base structures in a base structure database (1645). Each of these predefined feature vectors (1640) of a spectral base structure corresponds to a prototypical event. Such events can also mean “no event” or can be admissible events of normal operation, but can also be inadmissible events. Optionally, training programs generate the prototypical feature vectors in the laboratory by provocation of the event by the training programs recording the current feature vectors that are then occurring and, if necessary, storing them as prototypical vectors after post-processing. Post-processing can be, for example, clustering of a plurality of feature vectors for such a prototypical feature vector;
1645 base structure database (1645). The base structure database (1645) optionally comprises a stored set (1650) of a single or plurality of predefined feature vectors (1640) of spectral base structures;
1650 stored set (1650) of predefined feature vectors (1640) of spectral base structures in a base structure database (1645);
1655 spectral parameter set (1655) having at least one, optionally one similarity value each, for the similarity between a predefined feature vector (1640) of exactly one spectral base structure of the stored set of predefined feature vectors of spectral base structures (1625) of the base structure database (1635), on the one hand, and the current feature vector, on the other hand, for predefined, in particular all, feature vectors of spectral base structures from the stored set of predefined feature vectors of spectral base structures (1625) in the base structure database (1635). Optionally, the control device (4) or a higher-level computer system (12) or the higher-level control device (12) form these similarity values by corresponding mapping (1635) of the current feature vector (1630) of the values of the spectral analysis result (1620) of the detected value characteristic (1610) of this time segment onto predefined feature vectors (1640) of spectral base structures from a stored set of predefined feature vectors of spectral base structures (1650)in a base structure database (1645). This mapping can be performed in particular by means of scalar product formation between these feature vectors (1640). By calculating the similarity values, a spectral parameter set (1655) results having at least one, optionally one similarity value each, for the similarity between a predefined feature vector (1640) of exactly one spectral base structure of the stored set of predefined feature vectors of spectral base structures (1625) of the base structure database (1635), on the one hand, and the current feature vector, on the other hand, for predefined, in particular all, feature vectors of spectral base structures from the stored set of predefined feature vectors of spectral base structures (1625) in the base structure database (1635);
1660 evaluation (1660) of the spectral parameter set (1655) for generating an evaluation result (1665).
1665 evaluation result (1665). For example, the control device (4) of the fuse (825) and/or the higher-level computer system (12) and/or the higher-level control device (12) can perform this evaluation (1660) by applying and executing a neural network model. The control device (4) of the electronic fuse (825) can communicate with the higher-level control device (12) and/or the higher-level computer system (12), for example via the data bus (9). Optionally, similarity values of the spectral parameter set (1655) or values derived therefrom form the input values of the neural network model. The evaluation result (1665) of the evaluation (1660) then depends on output values of the neural network model which is typically calculated by the control device (4) of the fuse (825) and/or the higher-level computer system (12) and/or the higher-level control device (12);
1670 interrupting (1670) the current flow (1525) through the line section (1505) to be protected by means of the electronic fuse (825)if the evaluation result (1665) of the spectral parameter set (1640) corresponds to or suggests the presence of a short circuit or a plasma discharge (1510), in particular an arc. This is the case in particular if an evaluation result is within an expected interval for such a case. The expected interval can also be limited only on one side. The control device (4) of the electronic fuse (825) and/or also the higher-level control device (12) and/or the higher-level computer system (12) optionally interrupt the current flow (1525). If necessary, communication via the data bus (9) between the control device (4) of the fuse (825) and the higher-level control device (12) and/or the higher-level computer system (12) takes place for this purpose. Optionally, the control device (4) of the electronic fuse (825) or a higher-level control device (12) or a higher-level computer system (12), which communicate with the control device (4) of the fuse (825) via a data bus (9), open the circuit breaker (17) of the electronic fuse (825) in the event of such an error;
1800 method (1800) for power-dependent configuration of a supply network (1700)(FIG. 17, 18);
1805 detecting (1805) the total power requirement of these device parts (210, 211, 220, 221, 222, 223);
1810 comparing (1810) the determined total power requirement of these device parts (210, 211, 220, 221, 222, 223) of the vehicle to an upper power consumption threshold value;
1820 preventing (1820) the supply of electrical power to a lower priority power-consuming device part (210) and/or to the further device parts (220. 221) supplied with electrical power by this lower priority device part (210) if the determined total power requirement of all device parts (210, 211, 220, 221, 222, 223) is or could be above the upper power consumption threshold value or the operating state and/or the driving situation causes this to be expected. This prevention (1820) is accomplished by means of the electronic fuse (255) of this device part (250);
1830 comparing (1830) the determined total power requirement of these device parts (210, 211, 220, 221, 222, 223) of the vehicle to a lower power consumption threshold value;
1840 enabling (1840) the supply of electrical power to this lower priority power-consuming device part (210) and/or to the further device parts (220. 221) supplied with electrical power by this lower priority device part (210) if the determined total power requirement of all device parts (210, 211, 220, 221, 222, 223) is below the lower power consumption threshold value, wherein this enabling (1840) takes place by means of the electronic fuse (255) of this device part (250).
1900 supply network (200);
1905 second, downstream line section (1905) to be protected of the cable harness (1515);
1910 second current flow (1910) into a second, downstream line section (1905) to be protected of the cable harness (1515);
1915 third line section to be protected;
1920 third current flow (1920) into a third, upstream, to-be-protected line section (1915) of the cable harness (1515);
1925 fourth line section to be protected;
1930 fourth current flow (1930) into a fourth, downstream line section (1925) to be protected of the cable harness (1515);
1935 second current measuring device;
1940 third current measuring device;
1945 fourth current measuring device;
1950 first timer (35) of the first electronic fuse (825);
1955 second timer (35) of the second electronic fuse (805);
1960 third timer (35) of the third electronic fuse (1975);
1965 fourth timer (35) of the fourth electronic fuse (1980);
1970 timer of the higher-level computer system (12);
1975 third electronic fuse;
1980 fourth electronic fuse;
1985 server (1985, 710) or terminal of a repair shop and/or of an automobile manufacturer and/or of a service provider and/or of another user of the data determined by the supply network or a higher-level computer system (12);
1990 data connection (1990, 740) to a server (1985, 710) of a repair shop and/or of an automobile manufacturer and/or of a service provider;
2000 distributed measurement method (2000) for detecting the state of a cable harness (1515) of a vehicle;
2005 synchronization (2005) of a first timer (1950) of a first electronic fuse (825) with a time standard, in particular a timer (1970) of a higher-level computer system (12);
2010 synchronization (2010) of a second timer (1955) of a second electronic fuse (805) with the time standard, in particular the timer (1970) of a higher-level computer system (12);
2015 initiating (2015) the following two detection processes at equal time values of the first timer (1950) of the first electronic fuse (825) and the second timer (1955) of the second electronic fuse (805)
2020 detection (2020) of the first value of the current flow (1525) into a first line section (1505) to be protected of the cable harness (1515), in particular through a first electronic fuse (825) and/or a first current measuring device (1520), wherein the first control device (4) of the first electronic fuse (825) has a first timer (1950);
2025 detection (2025) of the second value of the current flow (1910) into a second downstream line section (1905) to be protected of the cable harness (1515), in particular by a second electronic fuse (805) and/or a second current measuring device (1935), wherein the second control device (4) of the second electronic fuse (805) has a second timer (1955);
2030 determination (2030) of a first time stamp value, in particular by the first control device (4) of the first electronic fuse (825) and in particular with the aid of the first timer (1950) of the first electronic fuse (825) for each measured value or for a group of measured values of the values of the current flow (1525);
2035 determination (2035) of a second time stamp value, in particular by the second control device (4) of the second electronic fuse (805) and in particular with the aid of the first timer (1955) of the first electronic fuse (805), for each measured value or for a group of measured values of the values of the current flow (1910);
2040 transmission (2040) of at least one second measured value together with the second time stamp value from the second fuse (805) to a higher-level computer system (12) or to the control device (4) of the first electronic fuse (825) and, in the event of the transmission of the second measured value to a higher-level computer system (12), transmission (2025) of the first current measured value together with the first time stamp value from the first fuse (825) to the higher-level computer system (12);
2045 comparing (2045) the first measured value to the second measured value;
2050 deduction (2050) of a power loss in line sections (1525) between two electronic fuses (825, 805), in particular if the difference between the first measured value and the second measured value lies outside of a permitted difference value interval and/or if a quotient of the first measured value and the second measured value lies outside of a permitted quotient interval.
2055 adoption (2055) of countermeasures, in particular by the higher-level computer system (12) or the computer core (2) of the evaluating control device (4) of the evaluating electronic fuse (825) if the measured values or the ratio of the measured values to one another or a difference of such measured values or variables derived therefrom do not correspond to one or more expected values and/or are not within an expected value interval;
2060 establishing (2060) a data connection to a server (710) of a repair shop and/or of an automobile manufacturer and/or of a service provider;
2065 transmitting (2065)the vehicle data and/or operating data and/or measured values and/or damage data to a server (1985) or a terminal of the repair shop or to a different user of this data;
2070 predicting (2070) the failure probability of a device part of the vehicle by means of the vehicle data and/or operating data and/or measured values and/or damage data;
2075 transmitting (2075) the prediction result to a server (1985) and/or a terminal of the repair shop and/or a terminal (740) and/or a computer of a vehicle owner (730) and/or a terminal (740) and/or a computer of a vehicle driver (730) or a terminal and/or a server (710) of an automobile manufacturer and/or a terminal and/or server of a logistics company and/or a terminal and/or a server of another user of this data;
2080 providing (2080) a replacement part for the device part of the vehicle in the case of a prediction result that prompts expectation of a failure of the device part;
2085 deduction (2085) of the temperature of a line section (1915, 1925, 1505, 1905) and/or an excess temperature of a line section (1915, 1925, 1505, 1905) by means of the detected values of the current flow (1920, 1925, 1525, 1910) in a plurality of line sections (1915, 1925, 1505, 1905) to be protected of the cable harness (1515).
2100 battery (2100) with diagnostics function for a vehicle;
2105 first battery cell module (2105);
2120 connection between the first terminal (2125) and the first terminal (18) of the circuit breaker (17) of the first fuse (825) of the battery (2100, 2200);
2121 electrical current in the connection (2120) between the first terminal (2125) and the first terminal (18) of the circuit breaker (17) of the first fuse (825) of the battery (2100, 2200);
2125 first terminal (2125) of the first battery cell module (2105);
2130 second terminal (2130) of the first battery cell module (2105);
2135 first terminal of the first electrochemical cell of the first battery cell (2145), of the first battery cell module (2105);
2140 second terminal of the first electrochemical cell of the first battery cell (2145) of the first battery cell module (2105);
2145 first electrochemical cell, the first battery cell of the first battery cell module (2105);
2155 second battery cell module (2155);
2160 connection between the first terminal (2165) and the first terminal (18) of the circuit breaker (17) of the second fuse (805) of the battery (2100, 2200);
2161 electrical current in the connection (2160) between the first terminal (2165) and the first terminal (18) of the circuit breaker (17) of the second fuse (805) of the battery (2100, 2200);
2165 first terminal (2165) of the second battery cell module (2155);
2170 second terminal (2170) of the second battery cell module (2155);
2175 first terminal of the second electrochemical cell of the second battery cell (2184) of the second battery cell module (2155);
2180 second terminal of the second electrochemical cell of the second battery cell (2185) of the second battery cell module (2155);
2185 second electrochemical cell, the second battery cell of the second battery cell module (2155);
2190 connection between the second terminal (2130) of the first battery cell module (2105) and the first terminal (2165) of the second battery cell module (2155);
2196 connection of the second terminal (2195) of the battery (2100, 2200) to the second terminal (2170) of the second battery cell module (2155);
2197 first terminal (2197) of the battery (2100);
2198 connection of the first terminal (2197) of the battery (2100, 2200) to the first terminal (2125) of the first battery cell module (2105);
2199 battery housing;
2200 battery (2200), in which an electronic fuse (825) of the battery (2200) has a second circuit breaker (17′) which is suitable for shunting the battery cell module (2105) associated with the fuse when the second circuit breaker (17′) is closed.
2220 housing of the battery or of the battery cell module;
2225 terminal of the battery (2200) of the battery cell module for the operating voltage (6) of the electronic fuses (825, 805);
2230 terminal of the battery (2200) of the battery cell module for the reference potential node (201) of the electronic fuses (825, 805);
2235 terminal of the battery (2200) of the battery cell module for the external data bus (9) of the electronic fuses (825, 805);
2300 battery cell module having a battery cell (2145);
2305 first battery cell terminal (2305);
2310 second battery cell terminal (2310);
2320 terminal of the battery cell module (2105) for the operating voltage (6) of the electronic fuse (825);
2325 terminal of the battery cell module (2105) for the reference potential node (201) of the electronic fuse (825);
2330 terminal of the battery cell module (2105) for the external data bus (9) of the electronic fuse (825);
2500 battery cell module having a plurality of battery cells (2145, 2185). In the context of the disclosure, the battery cell module corresponds to the battery cell module (2105);
2505 plug-in connector. The exemplary plug-in connector has a first contact (6) for the operating voltage terminal (6) of the electronic fuses (825, 805). The plug-in connector has a second contact (201) for the reference potential terminal (201) of the electronic fuses (805, 815). The plug-in connector has a third contact (9) for the external data bus (9) of the electronic fuses (805, 815);
2600 housed battery cell module;
2605 common housing of the battery cell module (2600) for an electronic fuse (825) and an inner battery cell module (2105);
2610 first terminal of the battery cell module (2600), which terminal is typically connected to the first terminal (2125) of the inner battery cell module (2105) within the housing (2605) of the battery cell module (2600);
2615 second terminal of the battery cell module (2600), which terminal is typically connected to the second terminal (2130) of the inner battery cell module (2105) within the housing (2605) of the battery cell module (2600);
2620 terminal of the battery cell module (2600) for the operating voltage (6) of the electronic fuse (825) of the inner battery cell module (2105);
2625 terminal of the battery cell module (2600) for the reference potential node (201) of the electronic fuse (825) of the inner battery cell module (2105);
2630 terminal of the battery cell module (2600) for the external data bus (9) of the electronic fuse (825) of the inner battery cell module (2105);
2635 exemplary optical waveguide within the housing (2605);
2640 optical plug system for the pluggable optical connection between the external optical waveguide (580) outside the housing (2605) and the optical waveguide (2635) within the housing (2605);
2700 battery (2700), in which an electronic fuse (825) of the battery (2200) has a second circuit breaker (17′) which is suitable for shunting the battery cell module (2105) associated with the fuse when the second circuit breaker (17′) is closed and in which the control device is supplied from the battery cell (2145), even if the circuit breaker (17) is open.
2800 battery (2800) in which an electronic fuse (825) of the battery (2200) has a second circuit breaker (17′) which is suitable for shunting the battery cell module (2105) associated with the fuse when the second circuit breaker (17′) is closed and in which the control device (4) is further supplied from the battery cell (2145), even if the circuit breaker (17) is open.
2900 supply network (2900), wherein one or more supply branches of the supply network (2900) for supplying electrical loads (2930 to 2933) with electrical power are designed as a ring of a supply line (2910 to 2915), in particular if, for example, a body is used as a return ground line, and/or is designed as two rings of two supply lines, and/or wherein one or more supply branches of the supply network for power supply of electrical power from electrical power sources (2940 to 2941) are designed as a ring of a supply line (2910 to 2915), if e.g., a body is used as a return ground line, and/or are designed as two rings of two supply lines.
2910 first line section (2910) of the supply line ring, wherein the first line section electrically connects the power feed point (2924) of the first power source (2940) to the first power extraction point (2920) of the first load (2930) in the example of FIG. 29, wherein the return line can be, for example, the vehicle body;
2911 second line section (2911) of the supply line ring, wherein the second line section electrically connects the first power extraction point (2920) of the first load (2930) to the second power extraction point (2921) of the second load (2931) in the example of FIG. 29, wherein the return line can be, for example, the vehicle body;
2912 third line section (2912) of the supply line ring, wherein the third line section electrically connects the second power extraction point (2921) of the second load (2931) to the third power extraction point (2922) of the third load (2932) in the example of FIG. 29, wherein the return line can be, for example, the vehicle body;
2913 fourth line section (2913) of the supply line ring, wherein the fourth line section electrically connects the third power extraction point (2922) of the third load (2932) to the third power extraction point (2922) of the third load (2933) in the example of FIG. 29, wherein the return line can be, for example, the vehicle body;
2914 fifth line section (2914) of the supply line ring, wherein the fifth line section electrically connects the fourth power extraction point (2923) of the fourth load (2933) to the second power feed point (2925) of the second power source (2941) in the example of FIG. 29, wherein the return line can be, for example, the vehicle body;
2915 sixth line section (2915) of the supply line ring, wherein the sixth line section electrically connects the second power feed point (2925) of the second power source (2941) to the first power feed point (2924) of the first power source (2940) in the example of FIG. 29, wherein the return line can be, for example, the vehicle body;
2920 first power extraction point for supplying the first load (2930) with electrical power from the supply line ring (2910 to 2915), wherein the return line can be, for example, the vehicle body;
2921 second power extraction point for supplying the second load (2931) with electrical power from the supply line ring (2910 to 2915), wherein the return line can be, for example, the vehicle body;
2922 third power extraction point for supplying the third load (2932) with electrical power from the supply line ring (2910 to 2915), wherein the return line can be, for example, the vehicle body;
2923 fourth power extraction point for supplying the fourth load (2933) with electrical power from the supply line ring (2910 to 2915), wherein the return line can be, for example, the vehicle body;
2924 first power feed point for feeding the power of the first power source (2940) into the supply line ring (2910 to 2915), wherein the return line can be, for example, the vehicle body;
2925 second power feed point for feeding the power of the second power source (2941)into the supply line ring (2910 to 2915), wherein the return line can be, for example, the vehicle body;
2930 first load of the exemplary FIG. 29;
2931 second load of the exemplary FIG. 29;
2932 third load of the exemplary FIG. 29;
2933 fourth load of the exemplary FIG. 29;
2940 first power source of the exemplary FIG. 29;
2941 second power source of the exemplary FIG. 29;
2950 first fuse of the first power source (2940), wherein the first fuse can disconnect the first power feed point (2924) from the first line section (2910) of the supply line ring (2910 to 2915) or wherein the first fuse can connect the first power feed point (2924) to the first line section (2910) of the supply line ring (2910 to 2915), and wherein this disconnection or connection depends on the electrical current through the first fuse and/or the electrical voltage of the supply line ring (2910 to 2915) in the region of the first fuse relative to a reference potential and/or on a data command via the fuse data bus (9);
2951 second fuse of the first power source (2940), wherein the second fuse can disconnect the first power feed point (2924) from the sixth line section (2915) of the supply line ring (2910 to 2915) or wherein the second fuse can connect the first power feed point (2924)to the sixth line section (2915) of the supply line ring (2910 to 2915), and wherein this disconnection or connection depends on the electrical current through the second fuse and/or the electrical voltage of the supply line ring (2910 to 2915) in the region of the second fuse relative to a reference potential and/or on a data command via the fuse data bus (9);
2952 third fuse of the second power source (2941), wherein the third fuse can disconnect the second power feed point (2925) from the sixth line section (2915) of the supply line ring (2910 to 2915) or wherein the third fuse can connect the second power feed point (2925) to the sixth line section (2915) of the supply line ring (2910 to 2915), and wherein this disconnection or connection depends on the electrical current through the third fuse and/or the electrical voltage of the supply line ring (2910 to 2915) in the region of the third fuse relative to a reference potential and/or on a data command via the fuse data bus (9);
2953 fourth fuse of the second power source (2941), wherein the fourth fuse can disconnect the second power feed point (2925) from the fifth line section (2914) of the supply line ring (2910 to 2915) or wherein the fourth fuse can connect the second power feed point (2925)to the fifth line section (2914) of the supply line ring (2910 to 2915), and wherein this disconnection or connection depends on the electrical current through the fourth fuse and/or the electrical voltage of the supply line ring (2910 to 2915) in the region of the fourth fuse relative to a reference potential and/or on a data command via the fuse data bus (9);
2950 thirteenth fuse of the first power source (2940), wherein the thirteenth fuse can disconnect the first power feed point (2924) from the first line section (2910) of the supply line ring (2910 to 2915) or wherein the thirteenth fuse can connect the first power feed point (2924) to the first line section (2910) of the supply line ring (2910 to 2915), and wherein this disconnection or connection depends on the electrical current through the thirteenth fuse and/or the electrical voltage of the supply line ring (2910 to 2915) in the region of the thirteenth fuse relative to a reference potential and/or on a data command via the fuse data bus (9). The thirteenth fuse (2950) and the fourteenth fuse (2951) can have a common control device (4);
2951 fourteenth fuse of the first power source (2940), wherein the fourteenth fuse can disconnect the first power feed point (2924) from the sixth line section (2915) of the supply line ring (2910 to 2915) or wherein the fourteenth fuse can connect the first power feed point (2924) to the sixth line section (2915) of the supply line ring (2910 to 2915), and wherein this disconnection or connection depends on the electrical current through the fourteenth fuse and/or the electrical voltage of the supply line ring (2910 to 2915) in the region of the fourteenth fuse relative to a reference potential and/or on a data command via the fuse data bus (9). The thirteenth fuse (2950) and the fourteenth fuse (2951) can have a common control device (4);
2952 fifteenth fuse of the second power source (2941), wherein the fifteenth fuse can disconnect the second power feed point (2925) from the sixth line section (2915) of the supply line ring (2910 to 2915) or wherein the fifteenth fuse can connect the second power feed point (2925) to the sixth line section (2915) of the supply line ring (2910 to 2915), and wherein this disconnection or connection depends on the electrical current through the fifteenth fuse and/or the electrical voltage of the supply line ring (2910 to 2915) in the region of the fifteenth fuse relative to a reference potential and/or on a data command via the fuse data bus (9). The fifteenth fuse (2952) and the sixteenth fuse (2953) can have a common control device (4);
2953 sixteenth fuse of the second power source (2941), wherein the sixteenth fuse can disconnect the second power feed point (2925) from the fifth line section (2914) of the supply line ring (2910 to 2915) or wherein the sixteenth fuse can connect the second power feed point (2925) to the fifth line section (2914) of the supply line ring (2910 to 2915), and wherein this disconnection or connection depends on the electrical current through the sixteenth fuse and/or the electrical voltage of the supply line ring (2910 to 2915) in the region of the sixteenth fuse relative to a reference potential and/or on a data command via the fuse data bus (9). The fifteenth fuse (2952) and the sixteenth fuse (2953) can have a common control device (4);
2960 fifth fuse of the first load (2930), wherein the fifth fuse can disconnect the first power extraction point (2920) from the first line section (2910) of the supply line ring (2910 to 2915) or wherein the fifth fuse can connect the first power extraction point (2930) to the first line section (2910) of the supply line ring (2910 to 2915), and wherein this disconnection or connection depends on the electrical current through the fifth fuse and/or the electrical voltage of the supply line ring (2910 to 2915) in the region of the fifth fuse relative to a reference potential and/or on a data command via the fuse data bus (9). The fifth fuse (2960) and the sixth fuse (2961) can have a common control device (4);
2961 sixth fuse of the first load (2930), wherein the sixth fuse can disconnect the first power extraction point (2920) from the second line section (2911) of the supply line ring (2910 to 2915) or wherein the sixth fuse can connect the first power extraction point (2930) to the second line section (2911) of the supply line ring (2910 to 2915), and wherein this disconnection or connection depends on the electrical current through the sixth fuse and/or the electrical voltage of the supply line ring (2910 to 2915) in the region of the sixth fuse relative to a reference potential and/or on a data command via the fuse data bus (9). The fifth fuse (2960) and the sixth fuse (2961) can have a common control device (4);
2962 seventh fuse of the second load (2931), wherein the seventh fuse can disconnect the second power extraction point (2921) from the second line section (2911) of the supply line ring (2910 to 2915) or wherein the seventh fuse can connect the second power extraction point (2921) to the second line section (2911) of the supply line ring (2910 to 2915), and wherein this disconnection or connection depends on the electrical current through the seventh fuse and/or the electrical voltage of the supply line ring (2910 to 2915) in the region of the seventh fuse relative to a reference potential and/or on a data command via the fuse data bus (9). The seventh fuse (2962) and the eighth fuse (2963) can have a common control device (4);
2963 eighth fuse of the second load (2931), wherein the eighth fuse can disconnect the second power extraction point (2921) from the third line section (2912) of the supply line ring (2910 to 2915) or wherein the eighth fuse can connect the second power extraction point (2921) to the third line section (2912) of the supply line ring (2910 to 2915), and wherein this disconnection or connection depends on the electrical current through the eighth fuse and/or the electrical voltage of the supply line ring (2910 to 2915) in the region of the eighth fuse relative to a reference potential and/or on a data command via the fuse data bus (9). The seventh fuse (2962) and the eighth fuse (2963) can have a common control device (4);
2964 ninth fuse of the third load (2932), wherein the ninth fuse can disconnect the third power extraction point (2922) from the third line section (2912) of the supply line ring (2910 to 2915) or wherein the ninth fuse can connect the third power extraction point (2922) to the third line section (2912) of the supply line ring (2910 to 2915), and wherein this disconnection or connection depends on the electrical current through the ninth fuse and/or the electrical voltage of the supply line ring (2910 to 2915) in the region of the ninth fuse relative to a reference potential and/or on a data command via the fuse data bus (9). The ninth fuse (2964) and the tenth fuse (2965) can have a common control device (4);
2965 tenth fuse of the third load (2932), wherein the tenth fuse can disconnect the third power extraction point (2922) from the fourth line section (2913) of the supply line ring (2910 to 2915) or wherein the tenth fuse can connect the third power extraction point (2922) to the fourth line section (2913) of the supply line ring (2910 to 2915), and wherein this disconnection or connection depends on the electrical current through the tenth fuse and/or the electrical voltage of the supply line ring (2910 to 2915) in the region of the tenth fuse relative to a reference potential and/or on a data command via the fuse data bus (9). The ninth fuse (2964) and the tenth fuse (2965) can have a common control device (4);
2966 eleventh fuse of the fourth load (2933), wherein the eleventh fuse can disconnect the fourth power extraction point (2923) from the fourth line section (2913) of the supply line ring (2910 to 2915) or wherein the eleventh fuse can connect the fourth power extraction point (2923) to the fourth line section (2913) of the supply line ring (2910 to 2915), and wherein this disconnection or connection depends on the electrical current through the eleventh fuse and/or the electrical voltage of the supply line ring (2910 to 2915) in the region of the eleventh fuse relative to a reference potential and/or on a data command via the fuse data bus (9). The eleventh fuse (2966) and the twelfth fuse (2967) can have a common control device (4);
2967 twelfth fuse of the fourth load (2933), wherein the twelfth fuse can disconnect the fourth power extraction point (2923) from the fifth line section (2914) of the supply line ring (2910 to 2915) or wherein the twelfth fuse can connect the fourth power extraction point (2923) to the fifth line section (2914) of the supply line ring (2910 to 2915), and wherein this disconnection or connection depends on the electrical current through the twelfth fuse and/or the electrical voltage of the supply line ring (2910 to 2915) in the region of the twelfth fuse relative to a reference potential and/or on a data command via the fuse data bus (9). The eleventh fuse (2966) and the twelfth fuse (2967) can have a common control device (4);
2970 log table or log file for the errors and faults, and possibly further operating parameters;
2971 timer of the higher-level computer system (12);
3010 first fuse slot for the first load (2930) with two fuses (2960, 2961) and first plug connection (3020);
3010′ first triple fuse and/or first fuse slot for the first load (2930) with two fuses (2960, 2961) and first plug connection (3020);
3011 second fuse slot for the second load (2931) with two fuses (2962, 2963) and second plug connection (3021);
3011′ second triple fuse and/or second fuse slot for the second load (2931) with two fuses (2962, 2963) and second plug connection (3021);
3012 third fuse slot for the third load (2932) with two fuses (2964, 2965) and third plug connection (3022);
3012′ third triple fuse and/or third fuse slot for the third load (2932) with two fuses (2964, 2965) and third plug connection (3022);
3013 fourth fuse slot for the fourth load (2933) with two fuses (2966, 2967) and fourth plug connection (3023);
3013′ fourth triple fuse and/or fourth fuse slot for the fourth load (2933) with two fuses (2966, 2967) and fourth plug connection (3023);
3014 fifth fuse slot for the first power source (2940) with two fuses (2950, 2951) and fifth plug connection (3024);
3014′ fifth triple fuse and/or fifth fuse slot for the first power source (2940) with two fuses (2950, 2951) and fifth plug connection (3024);
3015 sixth fuse slot for the second power source (2941) with two fuses (2952, 2953) and sixth plug connection (3025);
3015′ sixth triple fuse and/or sixth fuse slot for the second power source (2941) with two fuses (2952, 2953) and sixth plug connection (3025);
3020 first plug connection with a first plug and first socket for the connection and the supply of the first load (2930);
3021 second plug connection with a second plug and second socket for the connection and the supply of the second load (2931);
3022 third plug connection with a third plug and third socket for the connection and the supply of the third load (2932);
3023 fourth plug connection with a fourth plug and fourth socket for the connection and the supply of the fourth load (2933);
3024 fifth plug connection with a fifth plug and fifth socket for the connection and feed-in of the first power source (2940);
3025 sixth plug connection with a sixth plug and sixth socket for the connection and feed-in of the second power source (2941);
3100 supply network with isolation capacity of line sections (2910 to 2915) and isolation capacity of loads (2930 to 2933) and isolation capacity of power sources (2940 to 2941);
3110 seventeenth fuse of the first load (2930), wherein the seventeenth fuse can disconnect the first power extraction point (2920), on the one hand, from the first load (2930) or, on the other hand, from the first plug connection (3020) with the first plug and the first socket for the connection and the supply of the first load (2930), or wherein the seventeenth fuse can connect the first power extraction point (2920), on the one hand, to the first load (2930) or, on the other hand, to the first plug connection (3020) with the first plug and the first socket for the connection and the supply of the first load (2930), and wherein this disconnection or connection depends on the electrical current through the seventeenth fuse and/or the electrical voltage of the supply line ring (2910 to 2915) in the region of the seventeenth fuse or in the region of the first plug connection (3020) relative to a reference potential and/or depends on a data command via the fuse data bus (9). The seventeenth fuse and the fifth fuse (2960) and the sixth fuse (2961) can have a common control device (4);
3111 eighteenth fuse of the second load (2931), wherein the eighteenth fuse can disconnect the second power extraction point (2921), on the one hand, from the second load (2931) or, on the other hand, from the second plug connection (3021) with the second plug and the second socket for the connection and the supply of the second load (2931), or wherein the eighteenth fuse can connect the second power extraction point (2921), on the one hand, to the second load (2931) or, on the other hand, to the second plug connection (3021) with the second plug and the second socket for the connection and the supply of the second load (2931), and wherein this disconnection or connection depends on the electrical current through the eighteenth fuse and/or the electrical voltage of the supply line ring (2910 to 2915) in the region of the eighteenth fuse or in the region of the second plug connection (3021) relative to a reference potential and/or depends on a data command via the fuse data bus (9). The eighteenth fuse and the seventh fuse (2962) and the eighth fuse (2963) can have a common control device (4);
3112 nineteenth fuse of the third load (2932), wherein the nineteenth fuse can disconnect the third power extraction point (2922), on the one hand, from the third load (2932) or, on the other hand, from the third plug connection (3022) with the third plug and the third socket for the connection and the supply of the third load (2932), or wherein the nineteenth fuse can connect the third power extraction point (2922), on the one hand, to the third load (2932) or, on the other hand, to the third plug connection (3022) with the third plug and the third socket for the connection and the supply of the third load (2932), and wherein this disconnection or connection depends on the electrical current through the nineteenth fuse and/or the electrical voltage of the supply line ring (2910 to 2915) in the region of the nineteenth fuse or in the region of the third plug connection (3022) relative to a reference potential and/or depends on a data command via the fuse data bus (9). The nineteenth fuse and the ninth fuse (2964) and the tenth fuse (2965) can have a common control device (4);
3113 twentieth fuse of the fourth load (2933), wherein the twentieth fuse can disconnect the fourth power extraction point (2923), on the one hand, from the fourth load (2933) or, on the other hand, from the fourth plug connection (3023) with the fourth plug and the fourth socket for the connection and the supply of the fourth load (2933), or wherein the twentieth fuse can connect the fourth power extraction point (2923), on the one hand, to the fourth load (2933) or, on the other hand, to the fourth plug connection (3023) with the fourth plug and the fourth socket for the connection and the supply of the fourth load (2933), and wherein this disconnection or connection depends on the electrical current through the twentieth fuse and/or the electrical voltage of the supply line ring (2910 to 2915) in the region of the twentieth fuse or in the region of the fourth plug connection (3023) relative to a reference potential and/or depends on a data command via the fuse data bus (9). The twentieth fuse and the eleventh fuse (2966) and the twelfth fuse (2966) can have a common control device (4);
3120 twenty-first fuse of the first power source (2940), wherein the twenty-first fuse can disconnect the first power feed point (2924), on the one hand, from the first power source (2940) or, on the other hand, from the fifth plug connection (3024) with the fifth plug and the fifth socket for the connection and the supply of the first power source (2940), or wherein the twenty-first fuse can connect the fifth power extraction point (2924), on the one hand, to the first power source (2940) or, on the other hand, to the fifth plug connection (3024) with the fifth plug and the fifth socket for the connection and the supply of the first power source (2940), and wherein this disconnection or connection depends on the electrical current through the twenty-first fuse and/or the electrical voltage of the supply line ring (2910 to 2915) in the region of the twenty-first fuse or in the region of the fifth plug connection (3024) relative to a reference potential and/or depends on a data command via the fuse data bus (9). The twenty-first fuse and the thirteenth fuse (2950) and the fourteenth fuse (2951) can have a common control device (4);
3121 twenty-second fuse of the second power source (2941), wherein the twenty-second fuse can disconnect the second power feed point (2925), on the one hand, from the second power source (2941) or, on the other hand, from the sixth plug connection (3025) with the sixth plug and the sixth socket for the connection and the supply of the second power source (2941), or wherein the twenty-second fuse can connect the sixth power extraction point (2925), on the one hand, to the second power source (2941) or, on the other hand, to the sixth plug connection (3025) with the sixth plug and the sixth socket for the connection and the supply of the second power source (2941), and wherein this disconnection or connection depends on the electrical current through the twenty-second fuse and/or the electrical voltage of the supply line ring (2910 to 2915) in the region of the twenty-second fuse or in the region of the sixth plug connection (3025) relative to a reference potential and/or depends on a data command via the fuse data bus (9). The twenty-first fuse and the fifteenth fuse (2952) and the sixteenth fuse (2953) can have a common control device (4);
3200 supply network, which has a first sub-supply network (3201) and a second sub-supply network (3202). The first sub-supply network (3201) has, for example, high voltage values of greater than 50 V of the voltage between supply line sections (3260 to 3265) of the first sub-supply network (3201), on the one hand, and a reference potential (201) or the supply line sections (3260 to 3265) of the second sub-supply network (3202), on the other hand. The second sub-supply network (3202) has, for example, low voltage values of less than 50 V of the voltage between supply line sections (3266 to 3278) of the second sub-supply network (3202) on the one hand and a reference potential (201);
3201 first sub-supply network of the supply network (3200). The first sub-supply network (3201) has, for example, high voltage values of greater than 50 V of the voltage between supply line sections (3260 to 3265) of the first sub-supply network (3201), on the one hand, and a reference potential (201) or the supply line sections (3260 to 3265) of the second sub-supply network (3202), on the other hand;
3202 second sub-supply network of the supply network (3200). The second sub-supply network (3202) has, for example, low voltage values of less than 50 V of the voltage between supply line sections (3266 to 3278) of the second sub-supply network (3202) on the one hand and a reference potential (201);
3206 operating voltage for the fuses in the HV supply sub-network (3201);
3210 first cross-over fuse in the first supply sub-network (3201) for voltages greater than 50 V;
3211 second cross-over fuse in the first supply sub-network (3201) for voltages greater than 50 V
3212 third cross-over fuse in the first supply sub-network (3201) for voltages greater than 50 V
3213 fourth cross-over fuse in the second supply sub-network (3202) for voltages less than 50 V;
3214 fifth cross-over fuse in the second supply sub-network (3202) for voltages less than 50 V;
3215 sixth cross-over fuse in the second supply sub-network (3202) for voltages less than 50 V;
3216 seventh cross-over fuse in the second supply sub-network (3202) for voltages less than 50 V;
3217 eighth cross-over fuse in the second supply sub-network (3202) for voltages less than 50 V;
3218 ninth cross-over fuse in the second supply sub-network (3202) for voltages less than 50 V;
3250 first power source in the first supply sub-network (3201) for voltages greater than 50 V;
3251 second power source in the first supply sub-network (3201) for voltages greater than 50 V;
3252 third power source in the second supply sub-network (3202) for voltages less than 50 V;
3253 fourth power source in the second supply sub-network (3202) for voltages less than 50 V;
3254 fifth power source in the second supply sub-network (3202) for voltages less than 50 V;
3255 sixth power source in the second supply sub-network (3202) for voltages less than 50 V;
3260 to 3265
   supply line section in the first supply sub-network (3201) for voltages greater than 50 V;
3266 to 3278
   supply line section in the second supply sub-network (3202) for voltages less than 50 V;
3280 operating voltage source for operating the control devices (4) of the electronic fuses (405) in the first HV supply sub-network (3201);
3290 optical data bus for galvanic isolation;
3300 supply network (3300) similar to FIG. 31 for explaining the prioritization of loads and power sources and a favorable topology of the supply network to support this prioritization capability;
3400 method (3400) for active power management in a supply network (1100) with electrical fuses (1110 to 1118) for supplying electrical loads (1121 to 1125) in this supply network (1100) with electrical power of one or more electrical power sources (1150 to 1155);
3410 detecting (3410) the value of the electrical currents (29) through one or more circuit breakers (17) of one or more electronic fuses of the fuses (1110 to 1118) of the supply network (1100);
3420 detecting (3420) the value of the voltage difference between a terminal (26, 27, 28) of this circuit breaker (17) against a reference potential (201) of a reference potential contact;
3430 calculation (3430) of the theoretical ground offset as a result of the energization of the circuit breakers by the corresponding computer core of the corresponding control device of the corresponding fuse by means of modeling;
3440 correction (3440) of the corresponding voltage measured values by the theoretical ground offset;
3450 deduction (3450) of state parameters of supply line sections of the supply line sections (3260 to 3278) with the aid of the parameters thus detected, such as current values and voltage values;
3460 determination (3460) of the temperature with the aid of a known temperature coefficient of the line material of the supply line section of the supply line sections (3260 to 3278) and of the known design data;
3500 method (3500) for operating a vehicle with configuration variants that adjust the fuses.
3505 providing (3505) a vehicle having a supply network (3300) for supplying electrical loads (2930, 2931) of the vehicle with electrical power. The vehicle has one or more power sources (2940, 2941), one or more loads (2930, 2931) and a plurality of electronic fuses (2960 to 2963 and 2959 to 2953). The loads (2930, 2931) are optionally connected by means of supply lines (2915, 2910, 2911) to the one power source or the plurality of power sources (2940, 2941). The loads (2930, 2931)and the power sources (2940, 2941) are optionally interconnected together with the supply lines (2915, 2910, 2911) in a tree structure (3300) or a network. The tree structure of sub-trees or the network optionally comprise sub-networks ([2915, 3015, 3025, 2941]; [2940, 3024, 3014, 2910, 3010, 3020, 2930]; [2911, 3011, 2931]). First, electronic fuses (2960 to 2963 and 2959 to 2953) are optionally inserted into supply lines, so that these sub-trees of the tree structure can disconnect from the rest of the tree structure or can connect to this remaining tree structure, and/or electronic fuses (2916, 2962, 2951, 2952) are secondly inserted into supply lines, so that these sub-networks ([2915, 3015, 3025, 2941]; [2911, 3011, 3021, 2931]) of the network (3300) can disconnect from the rest of the network (3300) or connect to this remaining network (3300). These sub-networks ([2915, 3015, 3025, 2941]; [2911, 3011, 3021, 2931]) and/or sub-trees then typically have essentially no power supply and/or no power consumption after a disconnection;
3510 programming (3510) of specific equipment variants. A first equipment variant of these equipment variants of the vehicle optionally differs here from a second equipment variant of these equipment variants of the vehicle in that at least one electronic fuse of these electronic fuses (2916, 2962, 2951, 2952) disconnects a sub-tree of the tree structure or a sub-network ([2915, 3015, 3025, 2941], [2911, 3011, 3021, 2931]) of the network (3300) in the first equipment variant from the rest of the tree structure or the rest of the network (3300), and in the second equipment variant connects it to the rest of the tree structure or to the rest of the network (3300), so that the power source can completely supply this sub-tree or this sub-network ([2915, 3015, 3025, 2941]; [2911, 3011, 3021, 2931]) with electrical power of the power source only in the second equipment variant, or this sub-tree or this sub-network ([2915, 3015, 3025, 2941]; [2911, 3011, 3021, 2931]) can have an electrical power consumption of one or more electrical loads (29319 of the relevant sub-network ([2915, 3015, 3025, 2941]; [2911, 3011, 3021, 2931]) only in the second equipment variant. In some cases, programming (3510)of certain equipment variants by transmission of programming data to control devices (4) of electronic fuses via a data bus (9);
3515 encrypted communication (3515) via the control data bus (9) for programming the equipment variants and/or communication via the control data bus (9) for programming the equipment variants only after a password has been transmitted to the control device (4) of the corresponding electronic fuse;
3520 transmitting (3520) authentication data to a server (710) of an activation code provider;
3525 verification (3525) of the transmitted authentication data;
3530 generating (3530) an activation code with the aid of these or other authentication data according to an established method and providing the activation code;
3535 where applicable, purchase (3535) of an activation code via a data connection to the server of the activation code provider,
3540 transmitting (3540) the activation code to a higher-level computer system (12) of the vehicle;
3545 transmission (3545) of an activation code for an equipment variant on the basis of the received activation code from the higher-level computer system (12) to the control device (4) of the electronic fuse and programming (3510) of the activated equipment variant.
3550 detecting (3550) and determining the power which flows through an electronic fuse in a supply sub-branch ([2915, 3015, 3025, 2941]; [2911, 3011, 3021, 2931]) of the supply tree (3300) as a measured value of the amount of power and/or the underlying measured values in the electronic fuse;
3555 reading out (3555) the measured value of the determined amount of power and/or the underlying measured values from the electronic fuse;
3560 transmission (3560) of the measured value of the determined amount of power and/or of the underlying measured values via a data transmission path (720), which is optionally encrypted, from the higher-level computer system (12) to a computer (750) of a service provider, for example a utility company or its subcontractor;
3665 creation (3565) of an invoice on the basis of the transmitted measured value of the determined amount of power and/or of the underlying measured values;
3570 determining (3570) the topology of the supply network using electronic fuses of the supply network;
3575 comparison (3575) of the determined topology of the supply network to the valid or to-be-set equipment variant for plausibility checking of the equipment variant or the admissibility of the determined topology of the supply network.
3900 exemplary SPAD diode 30 for use as a sensor element of a single-photon detector;
3941 isolation, for example shallow trench isolation STI 3941 of the exemplary SPAD diode
3954, 3955 or LOCOS isolation;
3942 anode contact 3942 of the exemplary SPAD diode 3954, 3955;
3943 cathode contact 3943 of the exemplary SPAD diode 3954, 3955. The cathode contact
3943 of the exemplary SPAD diode 3954, 3955 is optionally made of indium tin oxide (ITO) or another transparent and electrically conductive material;
3944 optical waveguide 3944 for the transport of the photons of the first SPAD diode 3954 to the second SPAD diode 3955. The optical waveguide 3944 is made of a cap oxide 3944 or optically transparent isolation layer 3944 of the exemplary SPAD diode 3954, 3955;
3945 highly doped first terminal region 3945 of a first conductivity type, also referred to as n+S/D implantation. In CMOS technology with a p-doped wafer material it can, for example, be an n+-doped region in the semi-conducting substrate material of the SPAD diode 3954, 3955;
3946 first doped well 3946 of a second conductivity type. In CMOS technology with a p-doped wafer material it can, for example, be a p−-doped region in the semi-conducting substrate material of the SPAD diode 3944, 3955;
3947 second doped well 3947 of a second conductivity type. In CMOS technology with a p-doped wafer material it can, for example, be a p−-doped region in the semi-conducting substrate material of the SPAD diode 3954, 3955;
3948 epitaxial layer 3948 of a second conductivity type. In CMOS technology with a p-doped wafer material it can, for example, be a p-doped epitaxial layer in the semi-conducting substrate material of the SPAD diode 3954, 3955;
3949 base material 3949 of the semi-conducting monocrystalline wafer, which has a second conductivity type. In CMOS technology with a p-doped wafer material it is, for example, a p-doped monocrystalline semiconductor wafer;
3950 second doped well of a second conductivity type below the anode contact. In CMOS technology with a p-doped wafer material it can, for example, be a p-doped region in the semi-conducting substrate material of the SPAD diode 3954, 3955;
3951 highly doped second terminal region of a second conductivity type, also referred to as p+S/D implantation. In CMOS technology with a p-doped wafer material it can, for example, be a p+-doped region in the semi-conducting substrate material of the SPAD diode 3954, 3955;
3952 isolation, for example an optically transparent oxide, in particular silicon dioxide, or the like;
3953 metal cover of the optical waveguide 3944;
3954 first SPAD diode. The first SPAD diode 3955 serves at least at times as a light source for irradiating the second SPAD diode 3955 with photons of the first SPAD diode 3954;
3955 second SPAD diode 3955. The second SPAD diode 3955 serves, for example, at least at times as a photodetector for the light of the first SPAD diode 3954.
3956 surface 3956 of the wafer within the meaning of the disclosure;
3957 light 3957 of the first SPAD diode 3954 emitted vertically upward in a direction perpendicular to the surface 3956;
3958 light 3958 transported horizontally in the optical waveguide 3944 which is a part of the light 3957 radiated vertically from the first SPAD diode 3954 into the optical waveguide 3944;
3959 light 3959 of the first SPAD diode 3954 which is radiated vertically downwardly in the direction perpendicular to the surface 3956 from the optical waveguide 3944 into the second SPAD diode 3955 and which was emitted as perpendicular light 3957 into the optical waveguide 3944 from the first SPAD diode 3954 and then was transported from the optical waveguide 3944 horizontally to the second SPAD diode 3955.
4040 contact;
4041 metal 1 lines;
4042 metal 2 lines/metal 2 cover;
4043 first insulation layer;
4044 second insulation layer;
4100 quantum random number generator QRNG;
4101 entropy source;
4101.1 one or more first SPAD diodes;
4101.2 optical waveguide;
4101.3 one or more second SPAD diodes;
4102 high-frequency amplifier;
4103 analog-to-digital converter (ADC);
4104 evaluation device which essentially comprises sub-devices of the control device 4 of the fuse 1;
4104.1 constant;
4104.2 comparator;
4104.3 time-to-digital converter (TDC);
4104.4 entropy extraction device 4104.4
4104.5 watchdog of the quantum random number generator 4100, 60 or of the control device 4 of the fuse 1;
4104.6 pseudo-random number generator, in particular linear-feedback shift register LFSR. The feedback of the LFSR is optionally a simple primitive polynomial in order to generate pseudo-random bit sequences. Other implementations of a pseudo-random number generator, such as the output of pre-generated and stored random bits, which are interlaced with one or more true random bits, e.g., by means of an XOR linking, are possible. It is important that the seed of such a PRNG depends as far as possible on a quantum random number or a random number of a true random number generator (TRNG);
4104.7 signal multiplexer;
4104.8 finite state machine;
4104.9 RAM. The RAM can be identical to the volatile memory 15;
4104.10 finish flag;
4104.11 microcontroller. The microcontroller can be identical to the computer core 2;
4105 voltage/current signal of the entropy source 4101, signals of the current pulses;
4106 amplifier output signal 4106 of the high-frequency amplifier 4102;
4107 digital 14-bit value 4107 of the analog-to-digital converter 4103. Other bit widths are conceivable. The analog-to-digital converter can be identical to the analog-to-digital converter 570;
4108 signal of the constants 4104.1;
4109 output signal 4109 of the comparator 4104.2, cleaned pulse signal;
4110 output 4110 of the time-to-digital converter 4104.3;
4111 output of the entropy extraction 4104.4;
4112 seed S;
4113 voltage monitor;
4114 signal lines;
4116 selection signal;
4117 pseudo-random signal line;
4118 random data words;
4119 internal data bus of the quantum random number generator 60, 4100. It is optionally the internal data bus 11 of the control device 4;
4120 interrupt signal of the watchdog 4104.5 of the quantum random number generator 4100 or of the control device 4 of the fuse 1;
4300 flowchart 4300 of the entropy extraction method;
4301 first step 4301 with determination of the first value of the output 410 of the time-to-digital converter 4104.3 and the second value of the output 4110 of the time-to-digital converter 4104.3 and storage in a shift register of the entropy extraction 4104.4;
4302 second step of comparing the first value to the second value;
4303 third step of evaluating the first value and the second value and generating the random bit;
4401 first spikes;
4402 second spikes;
4403 cutoff level;
4500 generation of a socket descriptor;
4510 binding the socket descriptor to a port and an IP address;
4520 passive waiting state and waiting for connection requests of a microcontroller 2 of a client;
4530 establishing a connection from the computer core 2 of the control device 4 of the fuse 1 (server) to the computer core 2 of the control device 4 of a different fuse 1 (client) or to the higher-level computer system 12(client) by the computer core 2 of the control device 4 of the fuse 1 (server) (or vice versa);
4540 generation of a quantum random number 4111 and generation of a public and a private key by means of an RSA method by the computer core 2 of the control device 4 of the fuse 1 (server) by means of a quantum random number generator 60 QRNG and an RSA method;
4550 waiting for an encrypted message of the computer core 2 of the control device 4 of the other fuse (client) or for an encrypted message of the higher-level computer system 12 (client) by the computer core 2 of the control device 4 of the fuse 1 (server);
4560 decrypting the message of the private key temporarily stored in a memory of the computer core 2 of the control device 4 of the fuse 1 from step 3540 according to the RSA method;
4570 encryption of the message of the computer core 2 of the control device 4 of the fuse 1 (server) by means of the public key of the computer core 2 of the control device 4 of the other fuse 1 (client) from step 4540 or by means of the public key of the higher-level computer system 12 (client) from step 4540 according to the RSA method by the computer core 2 of the control device 4 of the fuse 1 (server);
4580 transmission of the encrypted message stored in the cache memory of the computer core 2 of the control device 4 of the fuse 1 (server) to the computer core 2 of the control device 4 of the other fuse 1 (client) or to the higher-level computer system 12 (client) via the data bus interface 10, 610, 550, 551 of the computer core 2 of the control device 4 of the fuse 1 (server) and via the data bus 9 and via the data interface 10. 610, 550, 551 of the computer core 2 of the control device 4 of the other fuse 1 (client) or via the data bus interface 555 of the higher-level computer system 12 (client);
4590 execution of the close( ) function and closing of the open connection to a socket, in this case the socket of the client, and termination of the communication with the computer core 2 of the control device 4 of the other fuse 1 (client) and/or with the higher-level computer system 12 (client) by the computer core 2 of the control device 4 of the fuse 1 (server);
4600 generation of a socket descriptor by the computer core 2 of the control device 4 of the other fuse 1 (client) and/or by the higher-level computer system 12 (client) and placing a connection request to the computer core 2 of the control device 4 of the fuse 1 using the port and the IP address, which were defined in step 4510, by the computer core 2 of the control device 4 of the other fuse (client) or the higher-level computer system 12 (client);
4610 establishing a connection between the server socket from step 4510 and the client socket from step 4600;
4620 generating a quantum random number 4111 and generating a public and a private key by means of an RSA method by the computer core 2 of the control device 4 of the other fuse 1 (client) or by the higher-level computer system 12 (client) by means of a quantum random number generator 60 QRNG and an RSA method;
4630 encryption of the client's own message by means of the public key for the computer core 2 of the control device 4 of the fuse 1 (server) from step 4540 by means of the RSA method by the computer core 2 of the control device 4 of the other fuse 1 (client) or by the higher-level computer system 12 (client);
4640 transmission of the encrypted message of the client to the computer core 2 of the control device 4 of the fuse 1 (server) by the computer core 2 of the control device 4 of the other fuse (client) or by the higher-level computer system 12 (client);
4650 waiting for an encrypted message of the computer core 2 of the control device 4 of the fuse 1 (server) by the computer core 2 of the control device 4 of the other fuse 1 (client) or by the higher-level computer system 12 (client) and reception of a message of the computer core 2 of the control device 4 of the fuse 1 (server) by the computer core 2 of the control device 4 of the other fuse 1 (client) or by the higher-level computer system 12 (client) and storage of the thus received and typically encrypted message of the computer core 2 of the control device 4 of the fuse 1 (server) in a temporary cache memory of the computer core 2 of the control device 4 of the other fuse (client) or of the higher-level computer system 12 (client) by the computer core 2 of the control device 4 of the other fuse 1 (client) or by the higher-level computer system 12 (client), and reading of the incoming data of the computer core 2 of the control device 4 of the fuse 1 (server) by the computer core 2 of the control device 4 of the other fuse (client) or by the higher-level computer system 12 (client) by means of execution of the recv( ) function by a socket descriptor, in this case by the socket descriptor of the computer core 2 of the control device 4 of the other fuse 1 (client) or of the higher-level computer system 12(client) from step 4600, and storing the read data optionally into a temporary cache memory of the computer core 2 of the control device 4 of the other fuse 1 (client) or of the higher-level computer system 12(client) by the computer core 2 of the control device 4 of the other fuse 1 (client) or by the higher-level computer system 12 (client);
4660 decryption of an encrypted message of the computer core 2 of the control device 4 of the fuse 1 (server) received by computer core 2 of the control device 4 of the other fuse 1 (client) or by the higher-level computer system 12 (client) by the computer core 2 of the control device 4 of the other fuse 1 (client) or by the higher-level computer system 12 (client) by means of the execution of the Decrypt( ) function by the computer core 2 of the control device 4 of the other fuse 1 (client) or by the higher-level computer system 12 (client) using the private key of the computer core 2 of the control device 4 of the other fuse 1 (client) or the private key of the higher-level computer system 12 (client) from step 4620 by means of the RSA method and subsequently storing the message decrypted in this way into a temporary cache memory of the computer core 2 of the control device 4 of the other fuse 1 (client) or by the higher-level computer system 12 (client) by the computer core 2 of the control device 4 of the other fuse 1 (client) or by the higher-level computer system 12 (client);
4670 closing of the open connection to the socket by the computer core 2 of the control device 4 of the other fuse 1 (client) or by the higher-level computer system 12 (client) and termination of the communication with the computer core 2 of the control device 4 of the fuse 1 (server) by the computer core 2 of the control device 4 of the other fuse 1 (client) or by the higher-level computer system 12 (client);
4700 generation of two different prime numbers p and q and of the product n=p*q and the result of Euler's phi function phi=(p−1×q−1) by the computer core 2 of the control device 4 of the fuse 1 (server) by means of the KeyExchangeServer( ) function;
4710 generation of a number that is relatively prime to phi by means of calling up the setE(function by the computer core 2 of the control device 4 of the fuse 1 (server), wherein the number phi is the one from step 3200 and wherein relatively prime within the meaning of the present document means that there is no natural number, except for the number one, which simultaneously divides the number e and the number phi into whole numbers;
4720 calculation of the multiplicative inverse to the number e by means of the computer core 2 of the control device 4 of the fuse 1 (server) using the findD( ) function, so that (e*d)mod phi=1 applies;
4730 waiting for an incoming message of the computer core 2 of the control device 4 of the other fuse 1 (client) or of the higher-level computer system 12 (client), which should typically comprise the public key of the client or of the higher-level computer system 12 (client), by the computer core 2 of the control device 4 of the fuse 1 (server), and reading of the incoming data from a socket descriptor, in this case the socket descriptor of the client, by the computer core 2 of the control device 4 of the fuse 1 (server) and storing of the read data optionally in a temporary cache memory of the computer core 2 of the control device 4 of the fuse 1 (server);
4740 transmission of the public key (d, n) of the computer core 2 of the control device 4 of the fuse 1 (server) from steps 4700 and 4720 d by the computer core 2 of the control device 4 of the fuse 1 (server) to the computer core 2 of the control device 4 of the other fuse 1 (client) or to the higher-level computer system 12 (client) via a socket descriptor, in this case the socket descriptor of the client from step 4530;
4745 exiting of the KeyExchangeServer( ) function by the computer core 2 of the control device 4 of the fuse 1 (server);
4750 generation of the prime number p and generation of the prime number q, which is different from q, and generation of the product n=p*q and generation of Euler's phi function phi=(p−1)×q−1) respectively by the computer core 2 of the control device 4 of the other fuse 1 (client) or by the higher-level computer system 12 (client) by means of the KeyExchangeCliento function;
4760 generation of an integer e that is relatively prime to the number phi from step 4750 by the computer core 2 of the control device 4 of the other fuse 1 (client) or by the higher-level computer system 12 (client) by means of the setE( ) function, wherein relatively prime within the meaning of the present document means that there is no natural number, except for the number one, which simultaneously divides the numbers e and phi without a remainder;
4770 calculation of the multiplicative inverse to the number e by the computer core 2 of the control device 4 of the other fuse 1 (client) or by the higher-level computer system 12 (client) by means of the findD( ) function, so that (e*d)mod phi=1;
4780 transmission of the public key (d, n) of the computer core 2 of the control device 4 of the fuse 1 (client) or of the higher-level computer system 12 (client) from steps 4750 and 4770 to the computer core 2 of the control device 4 of the fuse 1 (server) by the computer core 2 of the control device 4 of the other fuse 1 (client) or by the higher-level computer system 12 (client), wherein the computer core 2 of the control device 4 of the other fuse 1 (client) or the higher-level computer system 12 (client) transmits data by means of the send(function via a socket descriptor, in this case the socket descriptor of the client from step 4600;
4790 waiting on an incoming message of the computer core 2 of the control device 4 of the fuse 1 (server), which is encrypted with the public key of the computer core 2 of the control device 4 of the fuse 1 (server), by the computer core 2 of the control device 4 of the other fuse 1 (client) or by the higher-level computer system 12 (client) and reading of incoming data of the computer core 2 of the control device 4 of the fuse 1 (server) by a socket descriptor, in this case by the socket descriptor of the client from step 4600, by the computer core 2 of the control device 4 of the other fuse 1 (client) or by the higher-level computer system 12 (client) by means of the recv( ) function and storing of these data in a temporary cache memory of the computer core 2 of the control device 4 of the other fuse 1 (client) or of the higher-level computer system 12 (client) by the computer core 2 of the control device 4 of the other fuse 1 (client) or by the higher-level computer system 12 (client);
4795 exiting of the KeyExchangeClient( ) function by the computer core 2 of the control device 4 of the other fuse 1 (client) or by the higher-level computer system 12 (client);
4800 generation of a random number by means of a quantum random number generator 28 QRNG by the calling computer core 2 of the calling control device of the calling fuse 1 or by the calling higher-level computer system 12 and determination of a prime number depending on this random number by the calling first processor 10-1 and storing of this prime number as a variable p in the memory of the computer, the part of the calling computer core 2 of the calling control device of the calling fuse 1 or of the calling higher-level computer system 12, respectively;
4810 generation of a second random number by means of a quantum random number generator 60 by the calling computer core 2 of the calling control device of the calling fuse 1 or by the calling higher-level computer system 12 and determination of a prime number depending on this random number by the calling computer core 2 of the calling control device of the calling fuse 1 or by the calling higher-level computer system 12 and storing of this prime number as a variable q in the memory of the computer, the part of the calling computer core 2 of the calling control device of the calling fuse 1 or of the calling higher-level computer system 12, respectively;
4820 checking of whether the logic statement q==p applies, by the calling computer core 2 of the calling control device of the calling fuse 1 or by the calling higher-level computer system 12 and repetition of the steps starting from step 4810 by the calling computer core 2 of the calling control device of the calling fuse 1 or by the calling higher-level computer system 12 if this statement applies;
4830 calculation of the product n=p*q by the calling computer core 2 of the calling control device of the calling fuse 1 or by the calling higher-level computer system 12;
4840 calculation of Euler's phi function phi=(q−1)*(p−1) by the calling computer core 2 of the calling control device of the calling fuse 1 or by the calling higher-level computer system 12;
4850 exiting of the setPrimes( ) function by the calling computer core 2 of the calling control device of the calling fuse 1 or by the calling higher-level computer system 12;
4900 sequence of the SetE(function, when the setE( ) function is called in step 3400, the calling computer, in the case of the present document the computer core 2 of the control device of the fuse 1 (server) or the computer core 2 of the control device of the other fuse 1 (client) or the higher-level computer system 12 (client), generates a random number e for which it applies that e is relatively prime to the number phi. Relatively prime within the meaning of the present document means that there is no natural number, except for the number one, which simultaneously divides the number e and phi. The calling computer, in the case of the present document the computer core 2 of the control device of the fuse 1 (server) or the computer core 2 of the control device of the other fuse 1 (client) or the higher-level computer system 12 (client), can generate the number e both by a random number of the quantum random number generator 60 QRNG and by a pseudo-random number generator PRNG and by a true random number generator TRNG or a random number generator RNG and also by more and more integrating of an integer number starting with 2. However, the generation by means of the quantum random number generator 60 QRNG is preferred;
4910 checking of whether the logic statement gcd(e,phi) !=1 is satisfied, by the calling computer, in the case of the present document the computer core 2 of the control device of the fuse 1 (server) or the computer core 2 of the control device of the other fuse 1 (client) or the higher-level computer system 12(client), and repetition of the step 4905 by the calling computer if the logic statement is satisfied. By means of this gcd(a,b) function, the calling computer calculates the greatest common divisor of the transfer parameters a, b and returns the result to the calling computer,
4920 exiting of the setE( ) function and returning of the current value of e as a return value to the calling computer by the calling computer if the logic statement gcd(e,phi) !=1 is not satisfied. The calling computer here is either the computer core 2 of the control device of the fuse 1 (server) or the computer core 2 of the control device of the other fuse 1 (client) or the higher-level computer system 12 (client);
5000 initializing of a variable d with 0 by the calling computer, here in the case of the present document the computer core 2 of the control device of the fuse 1 (server) or the computer core 2 of the control device of the other fuse 1 (client) or the higher-level computer system 12 (client);
5010 addition of the number 1 to the number d by the calling computer;
5020 checking of whether the logic statement (e*d) (mod phi)=1 is satisfied, by the calling computer, and repetition of the steps starting from step 3510 if the logic statement (e*d) (mod phi)=1 is not satisfied;
5030 exiting of the findD( ) function by the calling computer if the logic statement (e*d) (mod phi)=1 is satisfied, and returning of the current value of d as a return value to the calling computer, in the case of the present document the computer core 2 of the control device of the fuse 1 (server) or the computer core 2 of the control device of the other fuse 1 (client) or the higher-level computer system 12 (client);
5100 server;
5110 client;
5120 transmission of the public key of the server 5100 based on a first quantum random number of the quantum random number generator 60 QRNG of the computer core 2 of the control device 4 of the fuse 1 (server) 5100 via a non-bug-proof channel to the computer core 2 of the control device 4 of the other fuse 1 (client) 5110 by the computer core 2 of the control device 4 of the fuse 1 (server) 5100;
5130 generating a pseudo-random number PZ, or a random number generated differently, by the computer core 2 of the control device 4 of the other fuse (client) 5110 and storing the pseudo-random number PZ or the random number generated differently in a memory of the computer core 2 of the control device 4 of the other fuse 1 (client) 5110 by the computer core 2 of the control device 4 of the other fuse (client) 5110 and generating a first private key of the client 5110 and a first public key of the client 5110 using this pseudo-random number PZ or this random number generated differently, by the computer core 2 of the control device 4 of the other fuse 1 (client) 5110, and encrypting this first public key of the client 5110 by means of the public key of the server 5100 by the computer core 2 of the control device 4 of the other fuse (client) 5110, and transmitting the encrypted first public key of the client 5110 to the computer core 2 of the control device 4 of the fuse (server) 5100 by the computer core 2 of the control device 4 of the other fuse 1 (client) 5110;
5140 decryption of the message of the computer core 2 of the control device 4 of the other fuse 1 (client) 5110 with the first private key of the computer core 2 of the control device 2 of the other fuse 1 (client) 5110, so that the computer core 2 of the control device 4 of the fuse 1 (server) 5100 has the first public key of the client 5110, without said key being known to third parties, and generation of a further, second quantum random number QZ2 by the computer core 2 of the control device 4 of the fuse 1 (server) 5100 by means of the quantum random number generator 60 QRNG, wherein the bit width of this second quantum random number is optionally equal to the bit width of the random number PZ of the client 5110, and encryption of the second quantum random number QZ2 with the first public key of the computer core 2 of the control device 4 of the other fuse (client) 5110 to form an encrypted second quantum random number QZ2′ by the computer core 2 of the control device 4 of the fuse (server)5100, wherein, for example, the first public key of the client 5110 can be the random number PZ of the client, and wherein, in this case the computer core 2 of the control device 4 of the fuse 1 (server)5100 can encrypt the second quantum random number QZ2, for example by bit-wise XOR linking of the second quantum random number QZ2 with PZ, to form an encrypted second quantum random number QZ2′, and transmission of the encrypted second quantum random number QZ2′ to the computer core 2 of the control device 4 of the other fuse 1(5110) by the computer core 2 of the control device 4 of the fuse 1 (server) 5100;
5150 decryption of the encrypted second quantum random number QZ2′ using the first private key of the computer core 2 of the control device 4 of the fuse (server) 5100 to the second quantum random number QZ2 by the computer core 2 of the control device 4 of the other fuse 1 (client) 5110. If the computer core 2 of the control device 4 of the fuse (server) has determined the second encrypted quantum random number QZ2′ by bit-wise XOR-linking of the random number PZ with the second quantum random number QZ2, the computer core 2 of the control device 4 of the other fuse 1 (client) 5110 can decrypt, for example, by means of bit-wise XOR-linking of the encrypted second quantum random number QZ2′ with the random number PZ known to it to form the second quantum random number QZ2. The computer core 2 of the control device 4 of the other fuse (client) 5110 optionally uses the second quantum random number QZ2 now present as a basis for generating a second private and a second public key according to an asymmetric encryption method. The asymmetric encryption method can be, for example, the RSA method. The computer core 2 of the control device 4 of the other fuse 1 (client) 3610 now transmits its second public key via the non-bug-proof channel to the server 5100. In this case, it optionally encrypts this second public key of the client 5110 with the public key of the server 5100. The server 5100 decrypts the encrypted second public key of the client 5110 and then uses this second public key of the client for encrypting further messages to the computer core 2 of the control device 4 of the other fuse 1 (client) 5110. Optionally, the computer core 2 of the control device 4 of the fuse 1 (server) 5100 generates and transmits a new public key on the basis of a new quantum random number of its quantum random number generator 60 QRNG encrypted with the second public key of the client 5110 after a predetermined time or after the transmission of a predetermined volume of data to the computer core 2 of the control device 4 of the other fuse 1 (client) 5110. Optionally, the computer core 2 of the control device 4 of the fuse (server) 5100 and the computer core 2 of the control device 4 of the other fuse 1 (client) 5110 then carry out the previously described method again, so that the keys change permanently. This makes it impossible even for a quantum computer to break the keys. The supply network is thus protected against attacks from the outside;
5200 method for generating a quantum random number QZ with m random bits;
5210 generating a random single-photon current (57, 58, 59, 401.2) by means of one or more first SPAD diodes (401.1, 54);
5220 transmission of the random single-photon current (57, 58, 59, 401.2) by means of an optical waveguide (44, 401.2) different from the semiconductor substrate (49, 48) to one or more second SPAD diodes (401.3, 55);
5230 conversion of the random single-photon current (57, 58, 59, 401.2) into a detection signal in the form of a voltage signal 405 of the entropy source 401, which optionally comprises the first SPAD diodes 401.1 and the optical waveguide 401.2 and the second SPAD diodes 401.3;
5240 conditioning, in particular amplification and/or filtering and/or analog-to-digital conversion, of the detection signal into a conditioned detection signal, in particular a digital 14-bit value 407 of the analog-to-digital converter 403;
5250 separation of the pulses of the conditioned detection signal that are generated by coupling the emissions of a first SPAD diode 401.1 and of a second SPAD diode 401.3 from the pulses of the conditioned detection signal that are generated by spontaneous emission by comparing the conditioned detection signal to a threshold value, in particular in a comparator 404.2, and generation of a corresponding output signal 409, in particular of the comparator 404.2;
5260 determination of a first time interval between the first pulse and the second pulse of a first pulse pair from two successive pulses of the conditioned detection signal that are generated by coupling the emissions of a first SPAD diode 401.1 and of a second SPAD diode 401.3, and determination of a second time interval between a third pulse and a fourth pulse of a second pulse pair from two successive pulses of the conditioned detection signal that are generated by coupling the emissions of a first SPAD diode 401.1 and of a second SPAD diode 401.3, in particular for determining the first value of the output 410 of the time-to-digital converter 404.3 and the second value of the output 410 of the time-to-digital converter 404.3;
5710 temperature switch;
5720 temperature path of action between the first circuit breaker 17 and the temperature switch
5710 or the temperature fuse 5740;
5730 temperature path of action between the second circuit breaker 17′ and the temperature switch 5710 or the temperature fuse 5740;
5740 temperature fuse;
5750 temperature switch/thermal fuse monitoring device;
5910 first motor coil of the motor;
5920 second motor coil of the motor;
5930 third motor coil of the motor;
5940 motor controller;
6000 method for the transmission of compressed data from the fuse 1 to the higher-level computer system 12, wherein, within the meaning of the technical teaching presented here in connection with this data transmission, a compressed transmission from the control device 4 of the fuse to a different control device 4 of a different fuse is included in the disclosure of the disclosure. The corresponding technical teaching is arrived at by replacing the higher-level computer system 12 with the control device 4 of a fuse in the corresponding texts regarding compressed data communication of this document.
6010 closing of the circuit breaker 17 of the fuse 1 by a control device 4 of a fuse 1 in a first step;
6020 detection of the physical parameter to be detected which the control device 4 of the fuse 1 detects in second step 6020 using first means, which can comprise, for example, the analog-to-digital converter 570 of the control device 4 and/or the shunt resistor 24 and/or the auxiliary circuit breaker 23. The physical parameters to be detected can comprise, for example, voltages between circuit nodes within and outside the fuse 1 and/or electrical currents through lines within the fuse 1 and/or temperatures within and/or in the surroundings of the fuse 1;
6021 conversion of the electrical analog signals, which are generated by the means for detecting the physical parameters (e.g., temperature sensors 586 for detecting the temperature, shunt resistors 24 for detecting electrical currents 36, potential lines for detecting electrical potentials, analog-to-digital converters 570, etc.), by sampling in a first sub-step 6021 of the second step 6020 (see FIG. 61) by means of the control device 4 of the electronic fuse 1, into sampled temporal parameter value characteristics, which comprise a time-discrete flow of sampling values of the parameter values of the relevant physical parameter and any associated time stamps of these sampling values. Typically, the control device 4 of the fuse 1 optionally assigns to each sampling value and/or each of the sampling values a sampling instant as a time stamp of this sampling value at optionally equal time intervals.
6022 performing an exemplary wavelet transform or a different compression method and conversion of the sampled temporal parameter value characteristics into compressed temporal parameter value characteristics by the control device 4 of the fuse in a second sub-step 6022 of the second step 6020.
6030 analysis and compression of the detected temporal parameter value characteristic of the detected physical parameter by the control device 4 of the electronic fuse 4 in a third step
6030 in order to minimize the data bus capacity of the data bus 9 necessary for the data transmission and to provide free space for status messages and further control commands of the higher-level computer system 12 to the control device 4 of the fuse 1 or for status messages and further data transmissions of the control device 4 of the fuse 1 to the higher-level computer system 12;
6031 analysis of the temporal parameter value characteristic of the parameters detected by the control device 4 of the electronic fuse 1 and/or of the time characteristic of parameters derived therefrom, for example by the matched filter of the control device 4 of the electronic fuse 1 in a first sub-step 6031 of the third step, and preferred formation optionally in each case of a value of a vector component of a feature vector by optionally in each case a matched filter;
6032 extraction of a current feature vector from the detected temporal parameter value characteristics and/or from parameters derived from the prototypical time characteristics derived therefrom, by the control device 4 of the fuse and, where applicable, association of a corresponding time stamp, optionally with each of these feature vectors in a third sub-step 6023 of the second step 6020, by the control device 4 of the fuse;
6033 determining a distance of the extracted current feature vector from a prototypical feature vector of the prototype database 62115 in a third sub-step 6033 of the third step 6030;
6034 detection of a prototypical feature vector of the prototype database 62115 as a detected prototypical feature vector of the prototype database if the determined distance for this pair made up of this current feature vector and this prototypical feature vector of the prototype database 62115 is less than a distance threshold value and if at the same time this determined distance is less than or equal to any other distance between the current feature vector on the one hand and any other prototypical feature vector of the prototype database 62115;
6040 transmission of the compressed, detected temporal parameter value characteristic of the physical parameter to be signaled, by the control device 4 of the electronic fuse 1, in a fourth step 6040 to the higher-level computer system 12;
6050 decompression of the compressed, detected temporal parameter value characteristic received via the data bus 9 from the control device 4 of the fuse 1 by the higher-level computer system 12 in a fifth step 6050 to form a decompressed, detected temporal parameter value characteristic, which is ultimately a reconstructed, detected temporal parameter value characteristic that is associated with the control device 4 of the fuse 1 within the higher-level computer system 12;
6060 comparison and/or correlation of the reconstructed, detected temporal parameter value characteristic associated with the control device 4 of the fuse 1 within the higher-level computer system 12, with one or more other reconstructed, detected temporal parameter value characteristics associated with the control devices 4 of other fuses 1 within the higher-level computer system 12, by the higher-level computer system 12 in a sixth step 6060. In this case, the higher-level computer system 12 optionally detects events which can optionally be attributed to the same causes in temporal correlation;
6070 adoption of measures depending on the detected events by the higher-level computer system 12, if necessary, in a seventh step 6070;
7600 method (7600) for operating a supply network (200) with compression and encryption of the fuse data in the electronic fuse 1 and decryption and decompression of the fuse data in the higher-level computer system 12.
7610 encryption of the one or more compressed, detected temporal parameter value characteristics of the one or more physical parameters to be signaled, in particular by the control device (4) of the electronic fuse (1), to form one or more encrypted, compressed, detected temporal parameter value characteristics of the one or more physical parameters to be signaled;
7620 decryption of the one or more encrypted, compressed, detected temporal parameter value characteristics of the one or more physical parameters to be signaled, in particular by the control device (4) of the electronic fuse (1), to form one or more decrypted, compressed, detected temporal parameter value characteristics of the one or more physical parameters to be signaled;
55100 system 55100 for providing SW programs in a supply network 200;
55110 first HW platform (e.g., a higher-level computer system 12 or a server 710 of a service provider or a terminal 740 for inputs of a user 730, etc.);
55111 SW program implemented on the first HW platform 55110;
55112 SW program implemented on the first HW platform 55110;
55113 SW program implemented on the first HW platform 55110, for example a payment application 55113 or an equipment variant configuration program 55113;
55120 control device 4 of a fuse 1;
55121 safety-relevant SW module and safety-critical part of a SW program 55111. A safety-relevant SW module 55121, 55122 can comprise, for example, safety-relevant data and/or safety-relevant program code and/or SW modules 55121, 55122, which change the switching state of the circuit breaker 17 of the fuse 1 and/or SW modules 55121, 55122, which enable access to memories 14, 15 of the control device 55120, 4 of the electronic fuse 1, and/or SW modules 55121, 55122, which enable the downloading and/or the execution of SW in the memory 14, 15 of the control device 55120, 4 of the fuse 1, and/or SW modules 55121, 55122, which enable the reading of measured values and/or data of the memories of the control device 55120, 4 of the fuse 1, and/or SW modules 55121, 55122, which enable the configuration of parameters and/or threshold values and the like in the control device 55120, 4 of the fuse 1. For example, it can be the safety-critical part 55121 of a payment application 55113;
55122 safety-relevant SW module;
55130 operating system;
55131 HW driver, e.g., in order to enable data communication via a communication unit 55141, 55142, 55143;
55141 communication unit for a cellular network (GSM, UMTS, LTE);
55142 communication unit for WLAN;
55143 communication unit for Bluetooth;
55150 communication network (e.g., the Internet 720) with which it is possible to communicate directly (e.g., via a communication unit 55141 for a cellular network) or indirectly via a smartphone 55160 with one or more SW applications 55161.
55160 smartphone 55160 or other terminal 740 for inputs of the user 730 and/or, for example, for entering passwords and/or authentication data of the user 730 and/or biometric data, such as fingerprint data of a fingerprint sensor system and/or facial recognition data of a camera-based facial recognition system and/or voice recognition data of a speech and/or voice recognition system of the smartphone;
55200 exemplary sequence 55200 of a SW program 55111, 55112, 55113;
55201 safety-relevant supply-network-internal function/safety-critical component of the supply network;
55202 safety-relevant supply-network-external function/safety-critical component outside the supply network
55210 base module, e.g., safety-uncritical part 55210 of the SW program 55113 implemented on the first HW platform 55110;
55211 input data;
55221 output data;
55300 method for executing a SW program 55113 in a supply network 200;
55301 executing a base module 55210 of the SW program 55113 on a first HW platform 55110 of the vehicle (for example on the higher-level computer system 12 of the supply network 200);
55302 calling up a safety-relevant module 55121 of the SW program 55113 from the base module 55210 when the SW program 55113 is executed;
55303 executing the safety-relevant module 55121 on a control device 55120, 4 of the supply network 200;
62100 means 62100 for detecting physical parameters of the fuse 1. These means can comprise, for example, shunt resistors 24, auxiliary circuit breakers 23, the circuit breaker 17 of the fuse 1 and/or the gate drive circuit 16 of the control device 4 of the fuse and/or the analog-to-digital converter 570 of the control device 4 of the fuse 1 and/or a temperature sensor 586, where applicable together with a temperature sensor evaluation device 585. The detected physical parameters can comprise, for example, the voltage values of electrical voltages between nodes of the fuse 1 and/or the control circuit 4 of the fuse 1 (e.g., 20, 21, 22, 25, 26, 27, 28, 18, 19, 201, 6) and/or values of electrical currents (e.g., 29, 36) and/or other physical parameters, such as a temperature;
62101 physical interface 62101 of the control device 4. The physical interface 62101 of the control device 4 controls means 62100 for detecting the physical parameters of the fuse 1. The physical interface 62101 can comprise, for example, the analog-to-digital converter 570 of the control device 4 and/or the gate drive circuit 16 of the control device 4 for controlling and monitoring the circuit breaker 17. The physical interface typically detects the temporal parameter value characteristics and/or the corresponding time characteristics of the parameters derived from these parameter value characteristics of the physical parameters and provides them in the form of a parameter signal 62103 for conditioning by the subsequent feature vector extraction for signal object classification;
60102 signals of the temporal parameter value characteristics and/or the corresponding time characteristics of the parameters derived from these parameter value characteristics of the physical parameters. Even if “signal” is mentioned in the features or claims, such a signal can be composed of a plurality of signals, in particular analog voltage signals and/or analog current signals, etc. In this case, voltage signals can in particular comprise signals of voltages between the nodes 6, 7, 20, 21, 22, 25, 26, 27, 28, 201 and the like, etc. Current signals can thereby comprise, for example, values for electrical currents 36, 29. Further signals for physical parameters can comprise, for example, temperature signals of a temperature sensor 586, etc.;
62103 parameter signal. The parameter signal can comprise a plurality of lines (e.g., 22, 27, 25, 21, etc.);
62104.1 first matched filter of the control device 4 of the fuse 1;
62104.2 second matched filter of the control device 4 of the fuse 1;
62104.(m−1)
   (m−1)th matched filter of the control device 4 of the fuse 1;
62104.m
   m-th matched filter of the control device 4 of the fuse 1;
62111 feature vector extraction;
62112 distance determination device or classifier;
62113 Viterbi estimator.
62115 prototype database;
62116 signal object sequence database;
62121 the signal basic object sequence from the temporal sequence of the detected signal basic objects;
62122 probably detected signal objects with signal object parameters;
62123 intermediate parameter signal bundle comprising the m intermediate parameter signals 62123.1 to 62123.m;
62123.1 first intermediate parameter signal of the first matched filter 62104.1;
62123.2 second intermediate parameter signal of the second matched filter 62104.2;
62123.(m−1)
   (m−1)th intermediate parameter signal of the (m−1)th matched filter 62104. (m−1);
62123.m
   m-th intermediate parameter signal of the m-th matched filter 62104.m;
62125 significance increase unit;
62126 LDA matrix;
62138 signal of the current feature vector;
62150 estimator with an HMM model;
63141 centroid coordinate of a first exemplary prototypical signal basic object of the prototype database 62115;
63142 centroid coordinate of a second exemplary prototypical signal basic object of the prototype database 62115;
63143 centroid coordinate of a third exemplary prototypical signal basic object of the prototype database 62115;
63144 centroid coordinate of a fourth exemplary prototypical signal basic object of the prototype database 62115;
63145 exemplary current feature vector of the signal of the feature vectors 62138 in the overlapping region of the variation ranges of the two exemplary signal basic objects of the prototype database 62115 with the centroid coordinates 63142 and 63143;
63146 exemplary feature vector that is too far away from the exemplary centroid coordinates (63141, 63142, 63143, 63144) of the centroid of any exemplary signal basic object prototypes of the prototype database 62115;
63147 variation range (threshold ellipsoid) 63147 around the centroid 63141 of a single exemplary signal basic object prototype 63141;
63148 exemplary current feature vector which lies in the variation range (threshold ellipsoid) 63147 around the centroid 63141 of a single exemplary signal basic object prototype 63141) and which thus can be reliably detected by the distance determination device (112) and can be passed on to the Viterbi estimator (113) as a detected signal basic object (121).
67151 estimator with a neural network model;
68160 first exemplary signal object in triangular form and data transmission priority 1;
68161 second exemplary signal object in triangular form and data transmission priority 2;
68162 third exemplary signal object in dual peak form and data transmission priority 3;
68163 fourth exemplary signal object in triangular form and data transmission priority 4;
68164 fifth exemplary signal object in triangular form and data transmission priority 5;
68165 sixth exemplary signal object in triangular form and data transmission priority 6;
68166 parameter signal transmitted and decompressed with the aid of signal objects;
70000 decompression method;
70010 receiving new data 70160 to be decompressed in the higher-level computer system 12, which originates from the control computer 4 of the fuse 1. With the reception of new data 70160 to be decompressed, the higher-level computer system 12 starts the exemplary decompression method 70000 presented here;
70020 providing a reconstructed parameter signal model 69610 for a sampling window;
70030 determination of the next object to be reconstructed in the received data of the control device 4 of the fuse 1 by the higher-level computer system 12;
70040 checking of whether the next object to be reconstructed is a signal object by the higher-level computer system 12, if not fixed from the outset, whether the control device 4 of the fuse transmits only signal basic objects or only signal objects to the higher-level computer system 12. In this case, this test step would be omitted.
70050 determination of the sequence of signal basic objects corresponding to the index of the signal object sequence database 62116 of the control device 4 of the fuse 1 by the higher-level computer system 12;
70060 sequence 70060 of signal basic objects;
70070 determination of the next signal basic object of the sequence 70060 of signal basic objects that the higher-level computer system 12 is intended to reconstruct by the higher-level computer system 12;
70080 test step 70080 as to whether the relevant data set 70090, 70100 of the prototype database 70115 of the higher-level computer system 12 comprises a prototypical feature vector 70090 and no parameter value characteristics or prototypical parameter value characteristics 70100 for the parameter value characteristics of the physical parameters and/or the parameters derived therefrom.
70090 data set of the prototype database 70115 of the higher-level computer system 12. Optionally, this data set 70090 of the prototype database 70115 of the higher-level computer system 12, which data set is marked by the signal basic object to be reconstructed, comprises a prototypical feature vector 70090.
70100 data set 70100 of the prototype database 70115 of the higher-level computer system 12. Optionally, this data set 70100 of the prototype database 70115 of the higher-level computer system 12, which data set is marked by the signal basic object to be reconstructed, comprises prototypical parameter value characteristics 70100 for the parameter value characteristics of the physical parameters and/or the parameters derived therefrom.
70110 signal reconstruction method 70110, which is optionally executed by a signal construction device of the higher-level computer system 12 or which is executed by the computer system 12, which converts the prototypical feature vector 70100 into prototypical parameter value characteristics 70100 for the parameter value characteristics of the physical parameters and/or the parameters derived therefrom;
70120 parameterization of the prototypical parameter value characteristics 70100 for the parameter value characteristics of the physical parameters and/or the parameters derived therefrom to form parameterized parameter value characteristics 70130 for the parameter value characteristics of the physical parameters and/or the parameters derived therefrom by the higher-level computer system 12;
70115 prototype database of the higher-level computer system 12;
70116 signal object sequence database of the higher-level computer system 12;
70125 addition of the parameterized parameter value characteristics 70130 for the parameter value characteristics of the physical parameters, and/or the parameters derived therefrom, to the parameter signal model 69610. The higher-level computer system 12 optionally carries out this addition. As a result, the parameter signal model 69610 is filled with each addition by a further signal basic object;
70130 parameterized parameter value characteristics 70130 for the parameter value characteristics of the physical parameters and/or the parameters derived therefrom;
70140 checking whether the higher-level computer system 12 has already processed all signal basic objects of the sequence 70060 of signal basic objects;
70150 test step 70150, in which, for example, the higher-level computer system 12 checks whether it has already taken into account all signal objects of the data 70160 to be decompressed for the reconstructed parameter signal model 69610 for this sampling window. The higher-level computer system 12 optionally performs this check if the higher-level computer system 12 has already processed all signal basic objects of the sequence 70060 of signal basic objects.
70160 data 70160 to be decompressed, which typically comprise the signal objects and/or the signal basic objects and possibly their associated parameters, and which are in the higher-level computer system 12 for decompression and which originate from the control computer 4 of the fuse 1. (FIG. 75: first compressed fuse data of the first fuse 825).
70160′ second data 70160′ to be decompressed, which typically comprise the signal objects and/or the signal basic objects and possibly the associated parameters thereof, and which are in the higher-level computer system 12 for decompression, and which originate from the control computer 4 of the further fuse 805. (FIG. 75: second compressed fuse data of the second fuse 805).
70170 end of the decompression method for a sampling window. This end is reached if the higher-level computer system 12 has already taken into account all signal objects of the data 70160 to be decompressed for the reconstructed parameter signal model 69610 for this sampling window. The reconstructed parameter signal model 69610 for this sampling window is then completed;
70610 reconstructed parameter signal. Given a suitable choice of the signal basic objects and/or the signal objects, the reconstructed parameter signal essentially corresponds to the signal components to be transmitted of the parameter signal 62103 of the electronic fuse 1;
70610′ further reconstructed parameter signal. Given a suitable choice of the signal basic objects and/or the signal objects, the reconstructed parameter signal essentially corresponds to the signal components to be transmitted of the parameter signal 62103 of the electronic fuse 1;
74600 reconstructor;
74601 first sampling value memory for q sampling values of the parameter signal 62103. The first sampling value memory optionally comprises the data of the parameter value characteristic of the physical parameters detected by the fuse 1 and/or of the characteristic of the values of parameters derived therefrom. The first sampling value memory therefore optionally comprises the sampling values of the parameter signal 62103. The first sampling value memory outputs the sampling values in its memory cells as the first sampling value vector 74620;
74602 vector subtractors for the subtraction of the reconstructed sampling value vector of the parameter signal 62103 calculated by the reconstructor 74600, which subtractors form the reconstructed parameter signal model vector 74610, from the second sampling value vector 74630 of the parameter signal 62103 stored in the second sampling memory 74625, in order to form the vector residual signal 73660, which serves as an alternative input signal for the feature vector extraction 62111 in place of the parameter signal 62103;
74603 reconstruction memory for the reconstructed parameter signal model vector 74610. The reconstruction memory is generally executed as part of the reconstructor 74600.
74610 reconstructed parameter signal model vector;
74620 first sampling value vector of the q sampling values of the parameter signal 62103 stored in the first sampling value memory 74602, wherein q indicates the dimension of the first sampling value vector;
74625 second sampling value memory for q sampling values of the parameter signal 62103. The second sampling value memory typically always adopts the values of the vector components of the first sampling value vector 74620 at the end of a sampling window into its memory cells. The second sampling value memory outputs the sampling values in its memory cells as the second sampling value vector 74630;
74630 second sampling value vector of the q sampling values of the parameter signal 62103 stored in the second sampling value memory 74625, wherein q indicates the dimension of the second sampling value vector;
74635 stored parameter signal model vector 74635;
74660 vector residual signal. The vector residual signal represents the compression error. The more signal objects the control device 4 detects as likely detected signal objects 62122 with signal object parameters, the lower the compression error. The compression is usually terminated if the amounts of all sampling values of the vector residual signal 73660 are below a threshold value curve and/or below a threshold value and/or if a maximum number of signal objects and/or signal basic objects is detected;
75101 combination device. The combination device interpolates the value characteristics of the reconstructed parameter signals of different sampling instants of the reconstructed parameter signals and generates a merged parameter signal 75103 in which all sampling values of the different sub-signals of the reconstructed parameter signals 75103 are related to synchronous sampling instants. For example, a sensor fusion in the combination device can appear such that the higher-level computer system 12 correlates the time characteristics of value characteristics of parameters that detect further sensors and sensor systems with reconstructed parameter value characteristics of reconstructed parameter signals 70610, 70610′ of control devices 4 of fuses. For this purpose, the higher-level computer system 12 interpolates missing sampling values on the basis of valid sampling values of the reconstructed parameter value characteristics of reconstructed parameter signals 70610, 70610′ to form interpolated, reconstructed parameter value characteristics of a merged parameter signal 75103. Furthermore, on the basis of valid sampling values of the value characteristics of those parameters that the further sensors and sensor systems detect, the higher-level computer system 12 interpolates interpolated value characteristics of those parameters that the further sensors and sensor systems detect. At least one sampling value of the interpolated value characteristics of those parameters that the further sensors and sensor systems detect optionally corresponds in time to each sampling value of the interpolated, reconstructed parameter value characteristics. As a result, the higher-level computer system 12 can search correlations in the form of conspicuous, typically more or less synchronous events both in the reconstructed parameter value characteristics and in the value characteristics of those parameters that the further sensors and sensor systems detect. For example, mechanical defects of mechanical devices—e.g., electric motors—can become noticeable in acceleration values—e.g., vibrations, torque vibrations, etc.—and at the same time in corresponding fluctuations of currents 29, 36 through the electronic fuses associated with these mechanical devices.(See also FIG. 59). In this context, the disclosure points to the document by Wolfgang Koch, “Tracking and Sensor Data Fusion: Methodological Framework and Selected Applications (Mathematical Engineering),” Springer 1st ed. 2014 Edition (Aug. 23, 2016) ISBN-10: 3662520168, ISBN-13: 978-3662520161 as an arbitrary example from the vast amount of publications on sensor fusion;
75103 merged parameter signal which the combination device 75101 merges from the first reconstructed parameter signal 70610 of the first fuse 825 and the second reconstructed parameter signal 70610′ of the second fuse 825 and optionally from further reconstructed parameter signals of the further fuses to form the merged parameter signal 75103.
75104.1 first matched filter of the higher-level computer system 12;
75104.2 second matched filter of the higher-level computer system 12;
75104.(m−1)
   (m−1)th matched filter of the higher-level computer system 12;
75104.m
   m-th matched filter of the higher-level computer system 12;
75111 feature vector extraction of the higher-level computer system 12;
76112 distance determination device or classifier of the higher-level computer system 12;
75113 Viterbi estimator of the higher-level computer system 12.
75115 merged prototype database of the higher-level computer system 12 of prototypical merged signal basic objects of the higher-level computer system 12;
75116 merged signal object sequence database of the higher-level computer system 12 of prototypical sequences of prototypical merged signal basic objects of the higher-level computer system 12;
75121 determined merged signal basic object sequence from the temporal sequence of the detected merged signal basic objects of the higher-level computer system 12;
75122 likely detected merged signal objects of the higher-level computer system 12 with signal object parameters;
75123 intermediate parameter signal bundle of the higher-level computer system 12 comprising the m intermediate parameter signals 75123.1 to 75123.m of the higher-level computer system 12;
75123.1
   first merged intermediate parameter signal of the higher-level computer system 12 of the first matched filter 75104.1 of the higher-level computer system 12;
75123.2
   second merged intermediate parameter signal of the higher-level computer system 12 of the second matched filter 62104.2 of the higher-level computer system 12;
75123.(m−1)
   (m−1)th merged intermediate parameter signal of the higher-level computer system 12 of the (m−1)th matched filter 62104.(m−1) of the higher-level computer system 12;
75123.m
   m-th merged intermediate parameter signal of the higher-level computer system 12 of the m-th matched filter 62104.m of the higher-level computer system 12;
75125 merged significance increase unit of the higher-level computer system 12;
75126 merged LDA matrix of the higher-level computer system 12;
75138 merged signal of the current merged feature vector of the higher-level computer system 12;
75150 merged estimator with an HMM model of the higher-level computer system 12;
75600 reconstructor of the higher-level computer system 12;
75601 first sampling value memory of the higher-level computer system 12 for q sampling values of the merged parameter signal 75103. The first sampling value memory therefore optionally comprises the sampling values of the merged parameter signal 75103. The first sampling value memory outputs the sampling values in its memory cells as the first sampling value vector 75620 of the higher-level computer system 12;
75602 vector subtractors of the higher-level computer system 12 for the subtraction of the reconstructed sampling value vector of the merged parameter signal 75103 calculated by the reconstructor 75600 of the higher-level computer system 12, which subtractors form the reconstructed merged parameter signal model vector 75610, from the second sampling value vector 75630 of the merged parameter signal 75103 stored in the second sampling memory 75625 of the higher-level computer system 12, in order to form the vector new signal 75660 of the higher-level computer system 12, which serves as an alternative input signal for the feature vector extraction 75111 of the higher-level computer system 12 in place of the merged parameter signal 75103;
75603 reconstruction memory of the higher-level computer system 12 for the reconstructed merged parameter signal model vector 75610. The reconstruction memory of the higher-level computer system 12 is generally implemented as part of the reconstructor 75600 of the higher-level computer system 12.
75610 reconstructed merged parameter signal model vector;
75620 first sampling value vector of the higher-level computer system 12 of the q sampling values of the merged parameter signal 75103 stored in the first sampling value memory 75602 of the higher-level computer system 12, wherein q indicates the dimension of the first sampling value vector of the higher-level computer system 12;
75625 second sampling value memory of the higher-level computer system 12 for q sampling values of the parameter signal 75103. The second sampling value memory of the higher-level computer system 12 typically assumes the values of the vector components of the first sampling value vector 75620 of the higher-level computer system 12 into its memory cells typically whenever the merging of the reconstructed parameter signals for this sampling window is complete. The second sampling value memory of the higher-level computer system 12 outputs the sampling values in its memory cells as the second sampling value vector 75630 of the higher-level computer system 12;
75630 second sampling value vector of the higher-level computer system 12 of the q sampling values of the merged parameter signal 75103 stored in the second sampling value memory 75625 of the higher-level computer system 12, wherein q indicates the dimension of the second sampling value vector of the higher-level computer system 12;
75635 stored parameter signal model vector 75635 of the higher-level computer system 12;
75660 vector residual signal of the higher-level computer system 12. The vector residual signal of the higher-level computer system 12 represents the compression error. The more signal objects the higher-level computer system 12 detects as likely detected signal objects 75122 with signal object parameters, the lower the compression error. The higher-level computer system 12 usually cancels the compression if the amounts of all sampling values of the vector residual signal 75660 of the higher-level computer system 12 are below a threshold value curve and/or below a threshold value and/or if a maximum number of signal objects and/or signal basic objects is detected by the higher-level computer system 12;
77010 exemplary sensor in the vehicle and/or in the supply network 200;
77020 sensor data bus for the exemplary sensor 77010 in the vehicle and/or in the supply network 200. The sensor data bus can be identical to the data bus 9;
77610 parameter signal 77610 of a further sensor 77010;
78151 neural network model that the higher-level computer system implements in order to classify the merged parameter signal 75103 into merged signal basic objects 75121 and/or merged signal objects 75122;
ADRD address information within the data information DATA of a bit stream packet BP on the data bus 9;
BP bit stream packet (or frame), also referred to as a data packet;
CHKD check information within the data information DATA of a bit stream packet BP. It is optionally a CRC checksum and/or parity bits etc.;
CLK clock pulse within the higher-level computer system 12;
CLKAⱼ sampling signal within the j-th data interface 10 of the control device 4 of the jth fuse—wherein j is to be a positive integer;
DATA data information within a bit stream packet BP;
ILD configuration information;
INFO useful information within the data information DATA of a bit stream packet BP. Optionally, these are configuration data for the corresponding fuse. For example, these can be parameters for setting switching thresholds and/or delay times or for setting the switching state of the circuit breaker 17 of the electronic fuse and/or program data for the computer core 2 of the control device 4 of the fuse or the like;
START start signal;
SYNC synchronization information;
t_{B} length of an individual bit within a bit stream packet BP;
Z1 first logic state in which the first one-wire data bus of the data bus 9 or the second one-wire data bus of the data bus 9 can be if the data bus 9 is a differential, bidirectional data bus 9. This is also referred to in this disclosure as high.
z1 first differential state in which a serial, bidirectional, differential data bus 9 can be. This is also referred to in this disclosure as high.
Z2 second logic state in which the first one-wire data bus of the data bus 9 or the second one-wire data bus of the data bus 9 can be if the data bus 9 is a differential, bidirectional data bus 9. This is also referred to in this disclosure as low.
z2 second differential state in which a serial, bidirectional, differential data bus 9 can be. This is also referred to in this disclosure as low.
Z3 third logic state in which the first one-wire data bus of the data bus 9 or the second one-wire data bus of the data bus 9 can be if the data bus 9 is a differential, bidirectional data bus 9. This is also referred to in this disclosure as “Idle.” Optionally, but not necessarily, the corresponding physical level of the first one-wire data bus of the data bus 9 or of the second one-wire data bus of the data bus 9 has a value around a common mean value.
z3 third differential state in which the serial, bidirectional, differential data bus 9 can be. This is also referred to in this disclosure as “Idle.” Optionally, but not necessarily, the corresponding differential physical level has a value around zero.

### FINAL REMARKS

The above description does not raise any claim to completeness and does not limit this disclosure to the examples shown. Those who have ordinary technical knowledge in the field can develop, under-stand, and implement different incorporated variations of the random-sample-type individual examples specifically described in this document on the basis of the drawings, the disclosure, and the claims. The indefinite articles “a” or “an” do not exclude a plurality, while the mention of a certain number of elements does not exclude the possibility that more or fewer elements are present. A single unit can perform the functions of a plurality of elements mentioned in the disclosure and, conversely, a plurality of elements can perform the function of one unit. Numerous alternatives, equivalents, variations, and combinations are possible without departing from the scope of the present disclosure.

Unless stated otherwise, those who have ordinary technical knowledge in the field can freely combine all features of the present disclosure with one another, if such combinations are expedient. This relates to the entire disclosure. Those who have ordinary technical knowledge in the field can also freely combine the features described in the description of the figures, unless otherwise indicated, as features of the disclosure with the other features. A limitation of individual features of the exemplary examples to the combination with other features of the exemplary examples is expressly not provided here. In addition, physical features of the device can also be reformulated as method features, and method features can be reformulated as physical features of the device. Such a reformulation is thus automatically disclosed.

In the preceding detailed description, reference is made to the accompanying figures. Those who have ordinary technical knowledge in the field should consider the examples in the description and the figures as illustrative and are not considered as limiting for the described specific example or element. Those who have ordinary technical knowledge in the field can derive a plurality of examples from the preceding description and/or the figures and/or the claims by modification, combination, or variation of certain elements. Furthermore, a person skilled in the art can derive examples or elements that the disclosure does not literally describe from the description and/or the drawings and/or the claims.

Those who have ordinary technical knowledge in the field can combine features which are disclosed at different locations in this document, and in particular in the feature list, with one another if this combination is expedient. The references used in the feature list are exemplary and do not explicitly limit the disclosure of the possible features and sub-feature combinations. The scope of protection results from the claims. Those who have ordinary technical knowledge in the field should use the relevant text passages for the interpretation of the claims. Even if, at the corresponding locations in this text regarding methods and method steps, no device should be disclosed which carries out this method step, a device and/or a device part which can execute this method step is hereby described in this document. Those who have ordinary technical knowledge in the field can combine this device part with other devices and/or device parts if this is expedient. Method steps that these device parts carry out correspond to the functions of the devices and device parts disclosed in this document. Those who have ordinary technical knowledge in the field can combine these method steps with one another and with method steps to form methods. Such methods are an explicit part of the disclosure.

What is claimed is:

1-62. (canceled)

63. An electronic fuse comprising:
a housing,
a first housing terminal and a second housing terminal,
a circuit breaker comprising a first terminal of the circuit breaker and a second terminal of the circuit breaker,
wherein the first terminal of the circuit breaker is electrically connected to the first housing terminal of the electronic fuse,
wherein the second terminal of the circuit breaker is electrically connected to the second housing terminal of the electronic fuse,
wherein a thermal protection is arranged in a current path between the first housing terminal and the second housing terminal in series with the circuit breaker, and
wherein the thermal protection interrupts the current path when a temperature of the circuit breaker and/or a temperature within the housing of the electronic fuse and/or a temperature of the housing of the electronic fuse exceeds a switch-off temperature.

64. The electronic fuse according to claim 63, wherein the thermal protection is a temperature fuse.

65. The electronic fuse according to claim 63, wherein the thermal protection is a temperature switch.

66. The electronic fuse according to claim 63, wherein the electronic fuse has a temperature path of action between the circuit breaker and the thermal protection, so that a temperature of the circuit breaker can change a switching state of the thermal protection, so that an overtemperature leads to switching off by the thermal protection.

67. The electronic fuse according to claim 63, wherein the electronic fuse comprises a control device, and wherein the control device detects a switching state of the thermal protection.

68. The electronic fuse according to claim 67, wherein the control device signals a detected state of the thermal protection and/or data derived from these data, to a higher-level computer system and/or to a server of a service provider, and/or to a server of an automobile manufacturer, and/or to a terminal of a user, and/or to a terminal of a fire department or a server of the fire department or similar rescue services via a data bus of a vehicle supply network included in a vehicle, the vehicle supply network including the electronic fuse, wherein, where applicable, the signaling can be modified by any other computers present in a signaling path.

69. The electronic fuse according to claim 68, wherein the detected state of the thermal protection and/or the data derived therefrom signaled by the control device is an alarm.

70. The electronic fuse according to claim 68, wherein:
a computer core of the control device of the electronic fuse in the vehicle supply network and/or a higher-level computer system in the vehicle supply network and/or a different computer in the vehicle can determine, by use of a position detection system, and/or different information present in the vehicle supply network, a position information of the vehicle supply network or of the vehicle, and
the computer core of the control device of the electronic fuse in the vehicle supply network and/or the higher-level computer system in the vehicle supply network and/or the different computer in the vehicle signals the position information to the higher-level computer system and/or the server of a service provider, and/or the server of the automobile manufacturer, and/or to the terminal of the user, and/or to the terminal of the fire department or the server of the fire department or similar rescue services.

71. The electronic fuse according to claim 70, wherein the position detection system uses a GPS sensor.

72. An electronic fuse for a vehicle, comprising:
a first housing terminal and a second housing terminal,
an electronic circuit breaker comprising a control terminal, and a conduction path connected between the first housing terminal and the second housing terminal and a control terminal,
a control device having a computer core, such as a CPU, which control device is connected to the control terminal of the electronic circuit breaker for switching on and off the electronic circuit breaker, the control device including a data interface for connection to a data communication bus of a higher-level control or computer system,
a measuring device for detecting an operating parameter of the electronic circuit breaker and/or an electrical connection in which the electronic circuit breaker is arranged, wherein the operating parameter represents a magnitude of a current and/or a magnitude of a voltage and/or a magnitude of an electrical output and/or a magnitude of an electrical power and/or a temperature and/or a deformation of the electrical connection,
a temperature sensor for determining a temperature of the electronic fuse or for determining a temperature of a component, assembly, or unit, arranged externally of the electronic fuse,
wherein the control device receives an evaluation signal representing a measured value of the temperature sensor and compares the evaluation signal to a reference signal representing a temperature limit value, and
wherein the control device signals an exceeding of the reference signal by the evaluation signal to the higher-level control or computer system via the data interface.

73. The electronic fuse according to claim 72, wherein the temperature sensor is protected by the electronic fuse.

74. An electronic fuse for a vehicle, comprising:
a first housing terminal and a second housing terminal,
an electronic circuit breaker comprising a control terminal, and a conduction path connected between the first housing terminal and the second housing terminal,
a control device having a computer core, the control device connected to the control terminal of the electronic circuit breaker for switching on and off the electronic circuit breaker, the control device including a data interface for connection to a data communication bus of a higher-level control or computer system,
a measuring device for detecting an operating parameter of the electronic circuit breaker and/or an electrical connection in which the electronic circuit breaker is arranged, wherein the operating parameter represents a magnitude of a current and/or a magnitude of a voltage and/or a magnitude of an electrical output and/or a magnitude of an electrical power and/or a temperature and/or a deformation of an electrical connection,
a temperature sensor for determining a temperature of the electronic fuse or for determining a temperature of a component, assembly, or unit, arranged externally of the electronic fuse,
wherein the control device receives an evaluation signal representing a measured value of the temperature sensor and compares this evaluation signal to a reference signal representing a temperature limit value, and
wherein, when the evaluation signal exceeds the reference signal, the control device, when the electronic circuit breaker is switched on, switches off the electronic circuit breaker and/or switches off a safety switch situated in series with the conduction path of the electronic circuit breaker.

75. The electronic fuse according to claim 74, wherein the temperature sensor is protected by the electronic fuse.

76. The electronic fuse according to claim 74, wherein the control device signals the exceeding of the reference signal by the evaluation signal to the higher-level control or computer system via the data interface.
